(19) United States
(12) Patent Application Publication
(10) Pub. No.: US 2023/0026518 A1
(43) Pub. Date: Jan. 26, 2023

(54) IMPURITY-CENTER-BASED QUANTUM COMPUTER

(71) Applicant: QUANTUM TECHNOLOGIES UG (HAFTUNGSBESCHRÄNKT), Leipzig (DE)

(72) Inventor: Bernd Burchard, Essen (DE)

(73) Assignee: QUANTUM TECHNOLOGIES UG HAFTUNGSBESCHRANKT, Leipzig (DE)

(21) Appl. No.: 17/772,228

(22) PCT Filed: Sep. 27, 2020
(86) PCT No.: PCT/DE2020/100827

§ 371 Date: Apr. 27, 2022

(30) Foreign Application Priority Data
Oct. 28, 2019 (DE) 10 2019 129 092.9
Nov. 7, 2019 (DE) 10 2019 130 115.7
Dec. 8, 2019 (DE) 10 2019 133 466.7

(51) Int. Cl. G06N 10/40

(52) U.S. Cl. CPC G06N 10/40

(57) ABSTRACT

A quantum bit including a quantum dot may in particular include an NV center. A nuclear quantum bit includes at least one nuclear quantum dot, which is typically a nuclear spin afflicted isotope. The quantum dot and nuclear quantum dot include a device for controlling the quantum dot and nuclear quantum dot. Compounded therefrom, a quantum register includes at least two quantum bits, and a nuclear quantum register includes at least two nuclear quantum bits. A nucleus-electron quantum register includes one quantum bit and one nuclear quantum bit, and a nucleus-electron-nucleus-electron quantum register includes at least one quantum register and at least two nucleus-electron registers. A higher-level structure, a quantum bus, for transporting a quantum information and a quantum computer composed thereof are part of the disclosure. Also included are methods necessary to fabricate and operate the device.

### CROSS REFERENCE TO RELATED APPLICATIONS

This application is a US National Phase of International Application Number PCT/DE2020/100827, filed Sep. 27, 2020, claiming priority to DE102019129092.9, filed Oct. 28, 2019, DE102019130115.7, filed Nov. 7, 2019, and DE102019133466.7, filed Dec. 8, 2019, the contents of which are incorporated into the subject matter of the present application by reference.

### TECHNICAL FIELD

The disclosure is directed to concept for a quantum computer based on NV centers in diamond or other centers in other materials, for example, G centers in silicon or V_{Si} centers in silicon carbide. The concept includes its elements as well as the necessary procedures for its operation and their interaction. A quantum ALU consists of a quantum bit that serves as a terminal together with several nuclear quantum dots that serves the actual execution of quantum operations. In particular, the disclosure includes a quantum bus for entangling remotely located quantum dots of different quantum ALUs and selection mechanisms and selective gating methods. Herein, entanglement of two nuclear quantum dots in different quantum ALUs that are remote from each other is enabled by means of this quantum bus. A method with associated device elements is also given to read out a computation result.

### BACKGROUND

Regarding State of the Art of Reading and Controlling Quantum Bits.

From the paper Gurudev Dutt, Liang Jiang, Jeronimo R. Maze, A. S. Zibrov “Quantum Register Based on Individual Electronic and Nuclear Spin Qubits in Diamond”, Science. Vol. 316, 1312-1316, Jan. 6, 2007, DOI: 10.1126/science.1139831, a method for coupling the nuclear spin of C13 nuclei with the electron spins of the electron configuration of NV centers is known.

From the paper Thiago P. Mayer Alegre, Antonio C. Torrezan de Souza, Gilberto Medeiros-Ribeiro. “Microstrip resonator for microwaves with controllable polarization”, arXiv:0708.0777v2 [cond-mat.other] Nov. 10, 2007 a cross-shaped electrically conductive microwave resonator is known. In this regard, reference is made to their FIG. 2. One application of the cross-shaped microwave resonator named by the authors in the first section of the paper is the controlling of paramagnetic centers by means of optically detected magnetic resonance (OMDR). A dedicated named application is quantum information processing (QIP). The substrate of the electrically conductive microwave resonator is a PCB (=printed circuit board). The dimensions of the resonator are 5.5 cm, which is in the order of magnitude of the wavelength of the microwave radiation to be coupled in. The microwave resonator is powered by voltage control. The two beams of the resonator cross are electrically connected. Selective controlling of individual paramagnetic centers (NV1) while not controlling other paramagnetic centers (NV1) is not possible with the technical teachings of the paper Thiago P. Mayer Alegre, Antonio C. Torrezan de Souza, Gilberto Medeiros-Ribeiro, “Microstrip resonator for microwaves with controllable polarization,” arXiv:0708.0777v2 [cond-mat.other] Oct. 11, 2007.

From the paper Benjamin Smeltzer, Jean McIntyre, Lilian Childress “Robust control of individual nuclear spins in diamond”, Phys. Rev. A 80, 050302(R)-25 Nov. 2009, a method for accessing individual nucleus 13C spins using NV cents in diamond is known.

From the paper Petr Siyushev, Milos Nesladek, Emilie Bourgeois, Michal Gulka, Jaroslav Hmby, Takashi Yamamoto, Michael Trupke, Tokuyuki Teraji. Junichi Isoya, Fedor Jelezko, “Photoelectrical imaging and coherent spin-state readout of single nitrogen-vacancy centers in diamond” Science 15 Feb. 2019, Vol. 363, Issue 6428. pp. 728-731, DOI: 10.1126/science.aav2789 electronic readout of spin states of NV centers is known.

From the paper Timothy J. Proctor, Erika Andersson, Viv Kendon “Universal quantum computation by the unitary control of ancilla qubits and using a fixed ancilla-register interaction”, Phys. Rev. A 88, 042330-24 Oct. 2013, a method for using so-called ancilla quantum bits to entangle a first nuclear spin with a second nuclear spin using ancilla bits is known.

None of the above stated writings disclose a complete proposal for a quantum computer or quantum computing system based on impurities in crystals.

### SUMMARY

The disclosure disclosed herein sets out to provide a design, production, and operation proposal for a quantum computer that has the potential to operate at room temperature, particularly in the case of using NV centers.

Of course, such quantum computers can also be operated at lower temperatures down to near absolute zero.

The following technical teaching was developed in connection with the design of a NV center in diamond-based quantum computer. NV centers are nitrogen vacancy defect centers of the diamond crystal lattice. It was recognized that the principles can be extended to mix crystals and element-pure crystals of the VI main group. Exemplary features of diamond-based systems, silicon-based systems, silicon-carbide-based systems and systems based on said mixed systems with one, two, three or four different elements of the fourth main group of the periodic table are described herein. The solutions based on NV centers in diamond are in the foreground, since development has progressed furthest here.

Quantum bit according to the disclosure An idea according to the disclosure is a quantum bit (QUB) comprising a particularly efficient and relatively easy to realize device, for example by means of e-beam lithography, for controlling a quantum dot (NV). Particularly preferably, the quantum dot (NV) is a point-like lattice defect in a crystal whose atoms preferably have no magnetic moment. Preferably, the material of the crystal is a wide bandgap material to minimize coupling of phonons with the quantum dot (NV). It is particularly preferred to use an impurity center, for example an NV center or an ST1 center or an L2 center, in diamond as the material of the substrate (D) or another impurity center in another material, for example a G center in silicon as the material of the substrate (D), in particular a GI1 center, as the quantum dot (NV). In the case of an impurity center in diamond, the NV center is the best known and studied impurity center for this purpose. In the case of silicon as a substrate (D), the G center is the best-known center. Reference is made to the paper by A. M. Tyryshkin, S. Tojo. J. J. L. Morton, H. Riemann, N. V. Abrosimov, P. Becker, H.-J. Pohl, Th. Schenkel, Mi. L. W. Thewalt, K. M. Itoh, S. A. Lyon, “Electron spin coherence exceeding seconds in high-purity silicon” NatureMat.11, 143 (2012). In the case of silicon carbide, V-centers and, in fact, preferably V_{Si} impurities are particularly suitable as impurity centers. Reference is made to the publication Stefania Castelletto and Alberto Boretti, “Silicon carbide color centers for quantum applications” 2020 J. Phys. Photonics2 022001. Furthermore, the use of other paramagnetic centers as quantum dots is conceivable. For example, NV centers or SiV centers or GeV centers in diamond can also be used as quantum dots (NV) in the substrate (D). Reference is made here to the book Alexander Zaitsev, “Optical Properties of Diamond”, Springer; edition: 2001 (Jun. 20, 2001) with respect to paramagnetic centers in diamond. Other materials can be used instead of silicon or diamond. Semiconductor materials are particularly preferred. Especially preferred are so-called wide-bandgap materials with a larger bandgap, since these make the coupling between the phonons of the lattice and the electron configurations of the interference sites more difficult. Such materials are, without giving a complete list here, for example BN, GaN. SiC, SiGe. However, GaAs can also be considered. III/V and II/VI mixed crystals are also possible.

Research is progressing rapidly here, so that other substrates (D) with other paramagnetic interference centers will certainly be developed here in the future. These are to be encompassed by the claimed technical teaching here.

Epitaxial Layer and Freedom of Nucleus Magnetic Momentum

The proposed quantum bit (QUB) typically comprises a substrate (D) preferably provided with an epitaxial layer (DEP1). Later in the present disclosure, analogously constructed nuclear quantum bits (CQUB) with nuclear quantum dots (CI) interacting by means of nucleus magnetic momentum are described in addition. Preferably, the epitaxial layer (DEP1) or even the whole substrate (D) is made of an isotopic mixture in which the individual isotopes of this isotopic mixture preferably have no magnetic moment. In the case of diamond as substrate (D), the ¹²C carbon isotope is particularly suitable for producing the epitaxial layer (DEP1) and/or the substrate (D) because it has no magnetic moment. In the case of silicon as the material of the substrate (D), the silicon isotope ²⁸Si is particularly suitable for fabricating the epitaxial layer (DEP1) and/or the substrate (D), since it also has no magnetic moment. If silicon carbide (designation SiC) is used as the material of the substrate (D) and/or the epitaxial layer (DEP1), the isotopic compound ²⁹Si¹²C is particularly suitable as the material of the substrate (D) and/or the epitaxial layer (DEP1). So, in general, it can be required that the atoms of the material of the epitaxial layer (DEP1) or of the substrate (D), and preferably at least in the vicinity of the paramagnetic centers or the quantum dots (NV) or the paramagnetic nucleus centers and thus the nuclear quantum dots (CI), also described below, should comprise only isotopes without magnetic moment of the atomic nucleus. Since the atoms of the III^{rd} main group of the periodic table and of the V^{th} main group of the periodic table generally do not have stable isotopes without magnetic moment, mixtures and/or compounds of isotopes without magnetic moment, e.g. of isotopes of the VI^{th} main group—e.g. ¹²C, ¹⁴C, ²⁸Si, ³⁰Si, ⁷⁰Ge, ⁷²Ge, ⁷⁴Ge, ⁷⁶Ge, ¹¹²Zn, ¹¹⁴Zn, ¹¹⁶Zn, ¹¹⁸Zn, ¹²⁰Zn, ¹²²Zn, ¹²⁴Zn and/or of the VI^{th} main group ¹⁶O, ¹⁸O, ³²S, ³⁴S, ³⁶S, ⁷⁴Se, ⁷⁶Se, ⁷⁸Se, ⁸⁰Se, ⁸²Se, ¹²⁰Te, ¹²²Te, ¹²⁴Te, ¹²⁶Te, ¹²⁸Te, ¹³⁰Te, and/or of the II^{nd} main group main group ²⁴Mg, ²⁶Mg, ⁴⁰Ca, ⁴²Ca, ⁴⁴Ca, ⁴⁶Ca, ⁴⁸Ca, ⁸⁴Sr, ⁸⁶Sr, ⁸⁸Sr, ¹³⁰Sr, ¹³²Ba, ¹³⁴Ba, ¹³⁶Ba, ¹³⁸Ba, and/or of the II^{nd} subgroup ⁴⁶Ti, ⁴⁸Ti, ⁵⁰Ti, ⁹⁰Zr, ⁹²Zr, ⁹⁴Zr, ⁹⁶Zr, ¹⁷⁴Hf, ¹⁷⁶Hf, ¹⁷⁸Hf, and/or of the IV^{th} subgroup ⁵⁰Cr, ⁵²Cr, ⁵³Cr, ⁹²Mo, ⁹⁴Mo, ⁹⁶Mo, ⁹⁸Mo, ¹⁰⁰Mo, ¹⁸⁰W, ¹⁸²W, ¹⁸⁴W, ¹⁸⁶W, and/or VI^{th} subgroup ⁵⁴Fe, ⁵⁶Fe, ⁵⁸Fe, ⁹⁶Ru, ⁹⁸Ru, ¹⁰⁰Ru, ¹⁰²Ru, ¹⁰⁴Ru, ¹⁸⁴Os, ¹⁸⁶Os, ¹⁸⁸Os, ¹⁹⁰Os, ¹⁹²Os, and/or VIII^{th} subgroup ⁵⁸Ni, ⁶⁰Ni, ⁶²Ni, ⁶⁴Ni, ¹⁰²Pd, ¹⁰²Pd, ¹⁰⁴Pd, ¹⁰⁶Pd, ¹⁰⁸Pd, ¹¹⁰Pd, ¹⁹⁰Pt, ¹⁹²Pt, ¹⁹⁴Pt, ¹⁹⁶Pt, ¹⁹⁸Pt and/or X^{th} subgroup ⁶⁴Zn, ⁶⁶Zn, ⁶⁸Zn, ⁷⁰Zn, ¹⁰⁶Cd, ¹⁰⁸Cd, ¹¹⁰Cd, ¹¹²Cd, ¹¹⁴Cd, ¹¹⁶Cd, ¹⁹⁶Hg, ¹⁹⁸Hg, ²⁰⁰Hg, ²⁰²Hg, ²⁰⁴Hg and/or the lanthanides ¹³⁶Ce, ¹³⁸Ce, ¹⁴⁰Ce, ¹⁴²Ce, ¹⁴²Nd, ¹⁴⁴Nd, ¹⁴⁶Nd, ¹⁴⁸Nd, ¹⁵⁰Nd, ¹⁴⁴Sm, ¹⁴⁶Sm, ¹⁴⁸Sm, ¹⁵⁰Sm, ¹⁵²Sm, ¹⁵⁴Sm, ¹⁵²Gd, ¹⁵⁴Gd, ¹⁵⁶Gd, ¹⁵⁸Gd, ¹⁶⁰Gd, ¹⁵⁶Dy, ¹⁵⁸Dy, ¹⁶⁰Dy, ¹⁶²Dy, ¹⁶⁴Dy, ¹⁶²Er, ¹⁶⁴Er, ¹⁶⁶Er, ¹⁶⁸Er, ¹⁷⁰Er, ¹⁶⁸Yb, ¹⁷⁰Yb, ¹⁷²Yb, ¹⁷⁴Yb, ¹⁷⁶Yb and/or the actinides ²³²Th, ²³⁴Pa, ²³⁴U, ²³⁸U, ²⁴⁴Pu are in question. It should be taken in to account that some of the possible materials, for example some crystal structures of the ⁵⁴Fe, and/or ⁵⁶Fe and/or ⁵⁸Fe isotopes, may exhibit ferromagnetic properties or other interfering collective magnetic effects, which should typically be avoided as well. Preferably, stable isotopes with a half-life longer than 10⁶ years are used. Of course, the use of non-stable isotopes without magnetic moment is also possible. Therefore, the above list and the following tables include only those stable isotopes that are preferably used. The claimed technical teaching also includes non-stable magnetic isotopes without nucleus magnetic moment.

For the natural isotope mixture, the following distribution of the fractions KOG of isotopes without magnetic moment and the fractions KIG of isotopes with magnetic moment relative to the total amount of atoms of the respective elements is taken as the basis as the natural isotope distribution of the respective element for the claims:

List of the Natural Distribution of the Fractions of Isotopes without Nucleus Magnetic Moment μ in the Total Amount of Isotopes of an Element

When in this paper isotopes without magnetic moment or isotopes without nucleus magnetic moment p are mentioned, it is meant that the isotopes essentially have a nucleus magnetic moment p which is nearly zero. Conversely, isotopes with magnetic moment, or conceptually equivalent to nucleus magnetic moment μ, have a non-zero nucleus magnetic moment. With this, they can interact with other isotopes with nucleus magnetic moment and thus couple and/or entangle with them.

IVth Main group

For Carbon (C):

| | Fraction K₀ of isotopes without |
|---|---|
| Isotope | magnetic moment at 100% C |
| Isotope ¹²C | 98.94% |
| Isotope ¹⁴C | Traces |
| Total fraction K_{0G} of isotopes without | 98.94% |
| magnetic moment at 100% C | |
| Total fraction K_{1G} of isotopes with | 1.06% |
| magnetic moment at 100% C | |

For Silicon (Si):

| | Fraction K₀ of isotopes without |
|---|---|
| Isotope | magnetic moment at 100% Si |
| Isotope ²⁸Si | 92.25% |
| Isotope ³⁰Si | 3.07% |
| Total fraction K_{0G} of isotopes without | 95.33% |
| magnetic moment at 100% Si | |
| Total fraction K_{1G} of isotopes with | 4.67% |
| magnetic moment at 100% Si | |

For Germanium (Ge):

| | Fraction K₀ of isotopes without |
|---|---|
| Isotope | magnetic moment at 100% Ge |
| Isotope ⁷⁰Ge | 20.52% |
| Isotope ⁷²Ge | 27.45% |
| Isotope ⁷⁴Ge | 36.52% |
| Isotope ⁷⁶Ge | 7.75% |
| Total fraction K_{0G} of isotopes without | 92.24% |
| magnetic moment at 100% Ge | |
| Total fraction K_{1G} of isotopes with | 7.76% |
| magnetic moment at 100% Ge | |

For Tin (Sn):

| | Fraction K₀ of isotopes without | |
|---|---|---|
| Isotope | magnetic moment at 100% Sn | |
| Isotope ¹¹²Sn | 0.97(1) | % |
| Isotope ¹¹⁴Sn | 0.66(1) | % |
| Isotope ¹¹⁶Sn | 14.54(9) | % |
| Isotope ¹¹⁸Sn | 24.22(9) | % |
| Isotope ¹²⁰Sn | 32.58(9) | % |
| Isotope ¹²²Sn | 4.63(3) | % |
| Isotope ¹²⁴Sn | 5.79(5) | % |

| | |
|---|---|
| Total fraction K_{0G} of isotopes without | 83% |
| magnetic moment at 100% Sn | |
| Total fraction K_{1G} of isotopes with | 17% |
| magnetic moment at 100% Sn | |

VIth main group

For Oxygen (O):

| | Fraction K₀ of isotopes without |
|---|---|
| Isotope | magnetic moment at 100% O |
| Isotope ¹⁶O | 99.76% |
| Isotope ¹⁸O | 0.20% |
| Total fraction K_{0G} of isotopes without | 99.96% |
| magnetic moment at 100% O | |
| Total fraction K_{1G} of isotopes with | 0.04% |
| magnetic moment at 100% O | |

For Sulfur (S):

| | Fraction K₀ of isotopes without |
|---|---|
| Isotope | magnetic moment at 100% S |
| Isotope ³²S | 94.90% |
| Isotope ³⁴S | 4.30% |
| Isotope ³⁶S | 0.01% |
| Total fraction K_{0G} of isotopes without | 99.21% |
| magnetic moment at 100% S | |
| Total fraction K_{1G} of isotopes with | 0.79% |
| magnetic moment at 100% S | |

For Selenium (Se):

| | Fraction K₀ of isotopes without |
|---|---|
| Isotope | magnetic moment at 100% Se |
| Isotope ⁷⁴Se | 0.86% |
| Isotope ⁷⁶Se | 9.23% |
| Isotope ⁷⁸Se | 23.69% |
| Isotope ⁸⁰Se | 49.80% |
| Isotope ⁸²Se | 8.82% |
| Total fraction K_{0G} of isotopes without | 92.40% |
| magnetic moment at 100% Se | |
| Total fraction K_{1G} of isotopes with | 7.60% |
| magnetic moment at 100% Se | |

For Tellurium (Te):

| | Fraction K₀ of isotopes without |
|---|---|
| Isotope | magnetic moment at 100% Te |
| Isotope ¹²⁰Te | 0.09% |
| Isotope ¹²²Te | 2.55% |
| Isotope ¹²⁴Te | 4.74% |
| Isotope ¹²⁶Te | 18.84% |
| Isotope ¹²⁸Te | 31.74% |
| Isotope^{130Te} | 34.08% |
| Total fraction K_{0G} of isotopes without | 92.04% |
| magnetic moment at 100% Te | |
| Total fraction K_{1G} of isotopes with | 7.96% |
| magnetic moment at 100% Te | |

II. Main group

For Magnesium (Mg):

| | Fraction K₀ of isotopes without |
|---|---|
| Isotope | magnetic moment at 100% Mg |
| Isotope ²⁴Mg | 78.97% |
| Isotope ²⁶Mg | 11.02% |
| Total fraction K_{0G} of isotopes without | 89.99% |
| magnetic moment at 100% Mg | |
| Total fraction K_{1G} of isotopes with | 10.01% |
| magnetic moment at 100% Mg | |

For Calcium (Ca):

| | Fraction K₀ of isotopes without |
|---|---|
| Isotope | magnetic moment at 100% Ca |
| Isotope ⁴⁰Ca | 96.9410% |
| Isotope ⁴²Ca | 0.6470% |
| Isotope ⁴⁴Ca | 2.0860% |
| Isotope ⁴⁶Ca | 0.0040% |
| Isotope ⁴⁸Ca | 0.1870% |
| Total fraction K_{0G} of isotopes without | 99.8650% |
| magnetic moment at 100% Ca | |
| Total fraction K_{1G} of isotopes with | 0.1350% |
| magnetic moment at 100% Ca | |

For Strontium (Sr):

| | Fraction K₀ of isotopes without |
|---|---|
| Isotope | magnetic moment at 100% Sr |
| Isotope ⁸⁴Sr | 0.57% |
| Isotope ⁸⁶Sr | 9.87% |
| Isotope ⁸⁸Sr | 82.52% |
| Total fraction K_{0G} of isotopes without | 92.96% |
| magnetic moment at 100% Sr | |
| Total fraction K_{1G} of isotopes with | 7.04% |
| magnetic moment at 100% Sr | |

For Barium (Ba):

| | Fraction K₀ of isotopes without |
|---|---|
| Isotope | magnetic moment at 100% Ba |
| Isotope ¹³⁰Ba | 0.11% |
| Isotope ¹³²Ba | 0.10% |
| Isotope ¹³⁴Ba | 2.42% |
| Isotope ¹³⁶Ba | 7.85% |
| Isotope ¹³⁸Ba | 71.70% |
| Total fraction K_{0G} of isotopes without | 82.18% |
| magnetic moment at 100% Ba | |
| Total fraction K_{1G} of isotopes with | 17.82% |
| magnetic moment at 100% Ba | |

II^{nd} Subgroup

For Titanium (Ti):

| | Fraction K₀ of isotopes without |
|---|---|
| Isotope | magnetic moment at 100% Ti |
| Isotope ⁴⁶Ti | 8.25% |
| Isotope ⁴⁸Ti | 73.72% |
| Isotope ⁵⁰Ti | 5.18% |
| Total fraction K_{0G} of isotopes without | 87.15% |
| magnetic moment at 100% Ti | |
| Total fraction K_{1G} of isotopes with | 12.85% |
| magnetic moment at 100% Ti | |

For Zirconium (Zr):

| | Fraction K₀ of isotopes without |
|---|---|
| Isotope | magnetic moment at 100% Zr |
| Isotope ⁹⁰Zr | 51.45% |
| Isotope ⁹²Zr | 17.15% |
| Isotope ⁹⁴Zr | 17.38% |
| Isotope ⁹⁶Zr | 2.80% |
| Total fraction K_{0G} of isotopes without | 88.78% |
| magnetic moment at 100% Zr | |
| Total fraction K_{1G} of isotopes with | 11.22% |
| magnetic moment at 100% Zr | |

For Hafnium (Hf):

| | Fraction K₀ of isotopes without |
|---|---|
| Isotope | magnetic moment at 100% Hf |
| Isotope ¹⁷⁴Hf | 0.16% |
| Isotope ¹⁷⁶Hf | 5.21% |
| Isotope ¹⁷⁸Hf | 27.30% |
| Total fraction K_{0G} of isotopes without | 67.77% |
| magnetic moment at 100% Hf | |
| Total fraction K_{1G} of isotopes with | 32.24% |
| magnetic moment at 100% Hf | |

IVth Subgroup

For Chrome (Cr):

| | Fraction K₀ of isotopes without |
|---|---|
| Isotope | magnetic moment at 100% Cr |
| Isotope ⁵⁰Cr | 4.35% |
| Isotope ⁵²Cr | 83.79% |
| Isotope ⁵⁴Cr | 2.37% |
| Total fraction K_{0G} of isotopes without | 90.50% |
| magnetic moment at 100% Cr | |
| Total fraction K_{1G} of isotopes with | 9.50% |
| magnetic moment at 100% Cr | |

For Molybdenum (Mo):

| | Fraction K₀ of isotopes without |
|---|---|
| Isotope | magnetic moment at 100% Mo |
| ⁹²Mo | 14.84% |
| ⁹⁴Mo | 9.25% |
| ⁹⁶Mo | 16.68% |
| ⁹⁸Mo | 24.13% |
| ¹⁰⁰Mo | 9.63% |
| Total fraction K_{0G} of isotopes without | 74.53% |
| magnetic moment at 100% Mo | |
| Total fraction K_{1G} of isotopes with | 25.47% |
| magnetic moment at 100% Mo | |

For tungsten (W):

| | Fraction K₀ of isotopes without |
|---|---|
| Isotope | magnetic moment at 100% W |
| Isotope ¹⁸⁰W | 0.12% |
| Isotope ¹⁸²W | 26.50% |
| Isotope ¹⁸⁴W | 30.64% |
| Isotope ¹⁸⁶W | 28.43% |
| Total fraction K_{0G} of isotopes without | 85.69% |
| magnetic moment at 100% W | |
| Total fraction K_{1G} of isotopes with | 14.31% |
| magnetic moment at 100% W | |

VI^{th} Subgroup

For Iron (Fe):

| | Fraction K₀ of isotopes without |
|---|---|
| | magnetic moment at 100% Fe |
| Isotope ⁵⁴Fe | 5.85% |
| Isotope ⁵⁶Fe | 91.75% |
| Isotope ⁵⁸Fe | 0.28% |
| Total fraction K_{0G} of isotopes without | 97.88% |
| magnetic moment at 100% Fe | |
| Total fraction K_{1G} of isotopes with | 2.12% |
| magnetic moment at 100% Fe | |

For Ruthenium (Ru):

| | Fraction K₀ of isotopes without |
|---|---|
| | magnetic moment at 100% Ru |
| ⁹⁶Ru | 5.52% |
| ⁹⁸Ru | 1.88% |
| ¹⁰⁰Ru | 12.60% |
| ¹⁰²Ru | 31.60% |
| ¹⁰⁴Ru | 18.70% |
| Total fraction K_{0G} of isotopes without | 70.30% |
| magnetic moment at 100% Ru | |
| Total fraction K_{1G} of isotopes with | 29.70% |
| magnetic moment at 100% Ru | |

For Osmium (Os):

| | Fraction K₀ of isotopes without |
|---|---|
| | magnetic moment at 100% Os |
| Isotope ¹⁸⁴Os | 0.02% |
| Isotope ¹⁸⁶Os | 1.59% |
| Isotope ¹⁸⁸Os | 13.24% |
| Isotope ¹⁹⁰Os | 26.26% |
| Isotope ¹⁹²Os | 40.78% |
| Total fraction K^{0G} of isotopes without | 81.89% |
| magnetic moment at 100% Os | |
| Total fraction K_{1G} of isotopes with | 18.11% |
| magnetic moment at 100% Os | |

VIII^{th} Subgroup

For Nickel (Ni):

| | Fraction K₀ of isotopes without |
|---|---|
| | magnetic moment at 100% Ni |
| Isotope ⁵⁸Ni | 68.08% |
| Isotope ⁶⁰Ni | 26.22% |
| Isotope ⁶²Ni | 3.63% |
| Isotope ⁶⁴Ni | 0.93% |
| Total fraction K_{0G} of isotopes without | 98.86% |
| magnetic moment at 100% Ni | |
| Total fraction K_{1G} of isotopes with | 1.14% |
| magnetic moment at 100% Ni | |

For Palladium (Pd):

| | Fraction K₀ of isotopes without |
|---|---|
| | magnetic moment at 100% Pd |
| Isotope ¹⁰²Pd | 1.02% |
| Isotope ¹⁰⁴Pd | 11.14% |
| Isotope ¹⁰⁶Pd | 27.33% |
| Isotope ¹⁰⁸Pd | 26.46% |
| Isotope ¹¹⁰Pd | 11.72% |
| Total fraction K_{0G} of isotopes without | 77.67% |
| magnetic moment at 100% Pd | |
| Total fraction K_{1G} of isotopes with | 22.33% |
| magnetic moment at 100% Pd | |

For Platinum (Pt):

| | Fraction K₀ of isotopes without |
|---|---|
| | magnetic moment at 100% Pt |
| Isotope ¹⁹⁰Pt | 0.01% |
| Isotope ¹⁹²Pt | 0.78% |
| Isotope ¹⁹⁴Pt | 32.86% |
| Isotope ¹⁹⁶Pt | 25.21% |
| Isotope ¹⁹⁸Pt | 7.36% |
| Total fraction K_{0G} of isotopes without | 66.23% |
| magnetic moment at 100% Pt | |
| Total fraction K_{1G} of isotopes with | 33.78% |
| magnetic moment at 100% Pt | |

X. Subgroup

For Zinc (Zn):

| | Fraction K₀ of isotopes without |
|---|---|
| | magnetic moment at 100% Zn |
| Isotope ⁶⁴Zn | 49.17% |
| Isotope ⁶⁶Zn | 27.73% |
| Isotope ⁶⁸Zn | 18.45% |
| Isotope ⁷⁰Zn | 0.61% |
| Total fraction K_{0G} of isotopes without | 95.96% |
| magnetic moment at 100% Zn | |
| Total fraction K_{1G} of isotopes with | 4.04% |
| magnetic moment at 100% Zn | |

For Cadmium (Cd):

| | Fraction K₀ of isotopes without |
|---|---|
| | magnetic moment at 100% Cd |
| Isotope ¹⁰⁶Cd | 1.25% |
| Isotope ¹⁰⁸Cd | 0.89% |
| Isotope ¹¹⁰Cd | 12.47% |
| Isotope ¹¹²Cd | 24.11% |
| Isotope ¹¹⁴Cd | 28.75% |
| Isotope ¹¹⁶Cd | 7.51% |
| Total fraction K_{0G} of isotopes without | 74.98% |
| magnetic moment at 100% Cd | |
| Total fraction K_{1G} of isotopes with | 25.02% |
| magnetic moment at 100% Cd | |

For Mercury (Hg):

| | Fraction K₀ of isotopes without |
|---|---|
| | magnetic moment at 100% Hg |
| Isotope ¹⁹⁶Hg | 0.15% |
| Isotope ¹⁹⁸Hg | 10.04% |
| isotope ²⁰⁰Hg | 23.14% |
| Isotope ²⁰²Hg | 29.74% |
| Isotope ²⁰⁴Hg | 6.82% |
| Total K_{0G} of isotopes without | 69.89% |
| magnetic moment at 100% Hg | |
| Total fraction K_{1G} of isotopes with | 30.11% |
| magnetic moment at 100% Hg. | |

Lanthanides:

For Cerium (Ce):

| | Fraction K₀ of isotopes without |
|---|---|
| | magnetic moment at 100% Ce |
| Isotope ¹³⁶Ce | 0.19% |
| Isotope ¹³⁸Ce | 0.25% |
| Isotope ¹⁴⁰Ce | 88.45% |
| Isotope ¹⁴²Ce | 11.11% |
| Total fraction K_{0G} of isotopes without | 100.00% |
| magnetic moment at 100% Ce | |
| Total fraction K_{1G} of isotopes with | 0% |
| magnetic moment at 100% Ce | |

For Neodyminum (Nd):

| | Fraction K₀ of isotopes without |
|---|---|
| | magnetic moment at 100% Nd |
| Isotope ^{142Nd} | 27.15% |
| Isotope ¹⁴⁴Nd | 23.80% |
| Isotope ¹⁴⁶Nd | 17.19% |
| Isotope ¹⁴⁸Nd | 5.76% |
| Isotope ¹⁵⁰Nd | 5.64% |
| Total fraction K_{0G} of isotopes without | 79.53% |
| magnetic moment at 100% Nd | |
| Total fraction K_{1G} of isotopes with | 20.47% |
| magnetic moment at 100% Nd | |

For Samarium (Sm):

| | Fraction K₀ of isotopes without |
|---|---|
| | magnetic moment at 100% Sm |
| Isotope ¹⁴⁴Sm | 3.08% |
| Isotope ¹⁴⁶Sm | 0% |
| Isotope ¹⁴⁸Sm | 11.25% |
| Isotope ¹⁵⁰Sm | 7.37% |
| Isotope ¹⁵²Sm | 26.74% |
| Isotope ¹⁵⁴Sm | 22.74% |
| Total fraction K_{0G} of isotopes without | 71.18% |
| magnetic moment at 100% Sm | |
| Total fraction K_{1G} of isotopes with | 28.82% |
| magnetic moment at 100% Sm | |

For Gadolinium (Gd):

| | Fraction K₀ of isotopes without |
|---|---|
| | magnetic moment at 100% Gd |
| Isotope ¹⁵²Gd | 0.20% |
| Isotope ¹⁵⁴Gd | 2.18% |
| Isotope ¹⁵⁶Gd | 20.47% |
| Isotope ¹⁵⁸Gd | 24.84% |
| Isotope ¹⁶⁰Gd | 21.86% |
| Total fraction K_{0G} of isotopes without | 69.55% |
| magnetic moment at 100% Gd | |
| Total fraction K_{1G} of isotopes with | 30.45% |
| magnetic moment at 100% Gd | |

For Dysprosium (Dy):

| | Fraction K₀ of isotopes without |
|---|---|
| | magnetic moment at 100% Dy |
| Isotope ¹⁵⁶Dy | 0.06% |
| Isotope ¹⁵⁸Dy | 0.10% |
| Isotope ¹⁶⁰Dy | 2.33% |
| Isotope ¹⁶²Dy | 25.48% |
| Isotope ¹⁶⁴Dy | 28.26% |
| Total fraction K_{0G} of isotopes without | 56.22% |
| magnetic moment at 100% Dy | |
| Total fraction K_{1G} of isotopes with | 43.79% |
| magnetic moment at 100% Dy | |

For Erbium (Er):

| | Fraction K₀ of isotopes without |
|---|---|
| | magnetic moment at 100% Er |
| Isotope ¹⁶²Er | 0.14% |
| Isotope ¹⁶⁴Er | 1.60% |
| Isotope ¹⁶⁶Er | 33.50% |
| Isotope ¹⁶⁸Er | 26.98% |
| Isotope ¹⁷⁰Er | 14.91% |
| Total fraction K_{0G} of isotopes without | 77.13% |
| magnetic moment at 100% Er | |
| Total fraction K_{1G} of isotopes with | 22.87% |
| magnetic moment at 100% He | |

For Ytterbium (Yb):

| | Fraction K₀ of isotopes without |
|---|---|
| | magnetic moment at 100% Yb |
| Isotope ¹⁶⁸Yb | 0.13% |
| Isotope ¹⁷⁰Yb | 3.02% |
| Isotope ¹⁷²Yb | 21.75% |
| Isotope ¹⁷⁴Yb | 31.90% |
| Isotope ¹⁷⁶Yb | 12.89% |
| Total fraction K_{0G} of isotopes without | 69.69% |
| magnetic moment at 100% Yb | |
| Total fraction K_{1G} of isotopes with | 30.31% |
| magnetic moment at 100% Yb | |

Actinides

For Thorium (Tb)

| | Fraction K₀ of isotopes without |
|---|---|
| | magnetic moment at 100% Th |
| Isotope ²³²Th | 100% |
| Total fraction K_{0G} of isotopes without | 100% |
| magnetic moment at 100% Th | |
| Total fraction K_{1G} of isotopes with | 0% |
| magnetic moment at 100% Th | |

For Proactinium (Pa):

| | Fraction K₀ of isotopes without |
|---|---|
| | magnetic moment at 100% Pa |
| Isotope ²³⁴Pa | 0% (traces) |
| Total fraction K_{0G} of isotopes without | 0% (traces) |
| magnetic moment at 100% Pa. | |
| Total fraction K_{1G} of isotopes with | 100% |
| magnetic moment at 100% Pa. | |

For Uranium (U):

| | Fraction K₀ of isotopes without |
|---|---|
| | magnetic moment at 100% U |
| Isotope ²³⁴U | 0.01% |
| Isotope ²³⁸U | 99.27% |
| Total fraction K_{0G} of isotopes without | 99.28% |
| magnetic moment at 100% U | |
| Total fraction K_{1G} of isotopes with | 0.72% |
| magnetic moment at 100% U | |

For Plutonium (Pu):

| | Fraction K₀ of isotopes without |
|---|---|
| | magnetic moment at 100% Pu |
| Isotope ²⁴⁴Pu | 100% |
| Total fraction K_{0G} of isotopes without | 100% |
| magnetic moment at 100% Pu | |
| Total fraction K_{1G} of isotopes with | 0% |
| magnetic moment at 100% Pu | |

Structure of an Exemplary Substrate According to the Proposal (D)

The substrate (D) thus comprises elements. The isotopes of these elements of the substrate (D) preferably do not have a nucleus magnetic moment p, at least in some areas. If necessary, the substrate (D) can have, for example, a natural composition of isotopes and thus isotopes with a magnetic moment if the substrate (D) is covered with a functional layer, for example in the form of an epitaxial layer (DEP1) of the same material, which instead has the property that the isotopes of these elements of the epitaxial layer (DEP1) have, at least regionally, essentially no magnetic nucleus moment p. The quantum dots (NV) and nuclear quantum dots (CI) described below are then fabricated in this epitaxial layer (DEP1), the thickness of which should then be greater than the electron-electron coupling distance between two quantum dots (NV) and greater than the nucleus-electron coupling distance between a quantum dot (NV) and a nuclear quantum dot (CI). The term “essentially” means here that the total fraction K_{IG} of isotopes with magnetic moment of an element that is part of the substrate (D) or epitaxial layer (DEP1) relative to 100% of this element that is part of the substrate (D) or of the isotopes with magnetic moment of an element which is a component of the substrate (D) or of the epitaxial layer (DEP1) is reduced in relation to the total natural fraction K_{IG} indicated in the above tables to a fraction K_{IG}′ of the isotopes with magnetic moment of an element which is a component of the substrate (D) or of the epitaxial layer (DEP1) in relation to 100% of this element which is a component of the substrate (D) or of the epitaxial layer (DEP1). Whereby this fraction K_{IG}′ is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the respective element of the substrate (D) or of the epitaxial layer (DEP1) in the region of action of the paramagnetic perturbations (NV) used as quantum dots (NV) and/or of the nuclear spins used as nuclear quantum dots (CI).

Here the atoms of the nuclear quantum dots are not considered, because their magnetic moment is intended.

In the case of silicon carbide as the material of the substrate (D) or epitaxial layer (DEP1), V-centers in a substrate of ²⁸Si atoms are preferred. Reference is made to the paper by D. Riedel, F. Fuchs, H. Kraus, S. Vath, A. Sperlich, V. Dyakonov, A. A. Soltamova, P. G. Baranov, V. A. Ilyin, G. V. Astakhov, “Resonant addressing and manipulation of silicon vacancy qubits in silicon carbide” arXiv:1210.0505v1 [cond-mat.mtrl-sci] 1 Oct. 2012. In the case of industrial diamonds as substrates (D), which are drawn from a molten metal as a carbon solvent by a high-pressure process, these substrates (D) often still contain, in particular, ferromagnetic impurities in the form of impurity atoms such as iron or nickel, which have a strong magnetic moment. This parasitic magnetic field would massively influence the quantum dots (NV) and render them unusable. Thus, when using paramagnetic impurities (NV1) in diamond, an isotopically pure diamond made of ¹²C atoms is preferable, since these also have no magnetic moment. Since a wafer of isotopically pure ²⁸Si silicon or an isotopically pure diamond of atoms without magnetic moment, for example of ¹²C carbon atoms, is very expensive, it is reasonable to grow an isotopically pure epitaxial layer (DEP1) of the desired material of the desired isotopes without nucleus magnetic moment on the surface of a standard silicon wafer or a standard SiC wafer or an industrial diamond. The thickness of this epitaxial layer (DEP1) has not been studied in detail by the authors. Several μm seem appropriate, but possibly a few atomic layers are sufficient, since the range of interaction of the nuclear spins is very small. Thus, the thickness of the epitaxial layer (DEP1) should be at least larger than this range of the interaction of the nuclear spins of the nuclear quantum dots (CI) and/or better larger than twice the range of the interaction of the nuclear spins he nuclear quantum dots (CI) and/or better larger than five times the range of the interaction of the nuclear spins of the nuclear quantum dots (CI) and/or better larger than ten times the range of the interaction of the nuclear spins of the nuclear quantum dots (CI) and/or better be greater than twenty times the range of the interaction of the nuclear spins of the nuclear quantum dots (CI) and/or better be greater than fifty times the range of the interaction of the nuclear spins of the nuclear quantum dots (CI) and/or better be greater than one hundred times the range of the interaction of the nuclear spins of the nuclear quantum dots (CI). Depending on the type of substrate (D), experiments to minimize the thickness of the epitaxial layer (DEP1) should be undertaken with different thicknesses of the epitaxial layer (DEP1) as pan of a rework to determine the optimum layer thickness for the intended application. Preferably, the epitaxial layer (DEP1) is isotopically pure or free of isotopes with a nucleus magnetic moment. This makes an interaction between the quantum dots of the paramagnetic centers (NV1) and the nuclear quantum dots (CI) of nuclear spins on the one hand and atoms of the substrate (D) in the vicinity of these quantum dots (NV) from paramagnetic centers or these nuclear quantum dots (CI) from nuclear spins on the other hand less likely. This then increases the coherence time of the quantum dots (NV) or nuclear quantum dots (C). During the deposition of this epitaxial layer (DEP1), for example with a CVD process, the material of the epitaxial layer (DEP1) can be selectively doped with impurity atoms to achieve a favorable position of the Fermi level and to increase the yield of the quantum dots (NV) during their fabrication. Preferably, this doping is done with isotopes that have no magnetic moment or at such a distance that the magnetic moment p of the nucleus of the doping atoms has essentially no effect on the quantum dots (NV) and/or the nuclear quantum dots (CI) anymore. Preferably, the smallest distance (d_{dot}) between a region of the substrate (D) doped with impurity atoms exhibiting a nucleus magnetic moment μ, on the one hand, and a relevant quantum dot (NV) and/or a nuclear quantum dot (CI), on the other hand, is at least larger than the interaction range of the magnetic moment of the quantum dots (NV) with each other and/or of the nuclear quantum dots (CI) with each other and/or between a nuclear quantum dot and a quantum dot. The largest of the interaction ranges mentioned here, namely firstly the interaction range of the magnetic moment of the quantum dots (NV) among each other and secondly the interaction range of the nuclear quantum dots (CI) among each other and thirdly the largest interaction range between a nuclear quantum dot (CI) and a quantum dot (NV) thus determines the minimum distance (d_{dotmin}) of the spacing (d_{dot}) between a region of the substrate (D), doped with impurity atoms having a nucleus magnetic moment s, on the one hand, and a relevant quantum dot (NV) and/or a nuclear quantum dot (CI), on the other hand, at least greater than the interaction range of the magnetic moment of the quantum dots (NV) among themselves and/or of the nuclear quantum dots (CI) among themselves and/or between a nuclear quantum dot and a quantum dot For this purpose, more later. Preferably, this distance (d_{dot}) is greater than the minimum distance (d_{dotmin}) and/or better than twice the minimum distance (d_{dotmin}) and/or better than five times the minimum distance (d_{dotmin}) and/or better than ten times the minimum distance (d_{dotmin}) and/or better than twenty times of the minimum distance (d_{dotmin}) and/or better greater than fifty times the minimum distance (d_{dotmin}) and/or better than one hundred times the minimum distance (d_{dotmin}) and/or better than two hundred times the minimum distance (d_{dotmin}) and/or better than five hundred times the minimum distance (d_{dotmin}). However, if the distance is too large, the Fermi level at the location of the quantum dots (NV) and/or at the location of the nuclear quantum dots (CI) will no longer be affected. It is recommended by means of a design-of-experiment (statistical design of experiments) for the particular constructive case to achieve a good result. During the elaboration of the disclosure, it has been proven to dope the region of quantum dots (NV) and/or nuclear quantum dots with impurity atoms without magnetic moment and to perform contact doping or contact implantation at a larger distance from the quantum dots (NV) and/or nuclear quantum dots (CI) if these contacts are not to be placed between two coupled quantum dots (NV1, NV2). In the case of ¹²C diamond, for example, doping with ³²S sulfur isotopes in the vicinity of NV centers as quantum dots (NV) is particularly advantageous.

Quantum Bit in the Sense of the Disclosure

A quantum bit (QUB) in accordance with the present disclosure comprises at least one quantum dot (NV) having a quantum dot type. The quantum dot type determines what type the quantum dot is. For example, a G-center in this sense is a different quantum dot type than a SiV center. The quantum dot (NV) is preferably a paramagnetic center preferably in a single crystal of preferably magnetically neutral atoms. Very preferably it is an impurity center in a crystal as substrate (D). Due to the non-magnetic properties, a silicon crystal, respectively a silicon carbide crystal, respectively a diamond crystal is preferred as material of the substrate (D), which in turn are preferably isotopically pure, respectively free of magnetic nucleus momentum of the isotopes of the material of the substrate (D), at least in the region of the quantum dots (NV), respectively of the nuclear quantum dots (CI). Although the focus here is on NV centers in diamond, or G centers in silicon, or V centers in silicon carbide, other combinations of impurity centers and crystals and materials are included if they are suitable. A feature of the suitability of crystals and materials as substrate (D) and/or epitaxial layer material (DEP1) is that they have essentially no isotopes with a nucleus magnetic moment p different from zero for such undesirable isotopes, at least in the region of quantum dots (NV) and/or nuclear quantum dots (CI) in their material. Preferably, for example, a diamond crystal in the relevant region of quantum dots (NV) and/or nuclear quantum dots (CI) consists of ¹²C carbon isotopes. Preferably, for example, a silicon crystal in the relevant region of quantum dots (NV) and/or nuclear quantum dots (CI) consists of ²⁸Si silicon isotopes. Preferably, for example, a silicon carbide crystal in the relevant region of quantum dots (NV) and/or nuclear quantum dots (CI) consists of ¹²C carbon isotopes and ²⁸Si silicon isotopes and thus preferably represents the stoichiometric isotopic formula ²⁸Si¹²C. Preferably, the diamond crystal in question or the silicon crystal in question or the silicon carbide crystal in question does not have any other interferences in the region of the quantum dot (NV). In the case of a diamond crystal as substrate (D), the quantum dot is preferably an NV center (NV). In the case of a silicon crystal, the quantum dot is preferably a G center (NV). The quantum dot is preferably a V center (NV) in the case of a silicon carbide crystal. Other centers, such as a SiV center and/or a ST1 center or other suitable paramagnetic impurities can also be used as quantum dots (NV) in diamond. Centers other than G centers and suitable paramagnetic interference sites in silicon can also be used as quantum dots (NV) in silicon. Centers other than V centers and suitable paramagnetic interference sites in silicon carbide can also be used as quantum dots (NV) in silicon carbide. If silicon is used as substrate (D), phosphorus atoms, for example, can also be considered as quantum dots (NV).

In order to be able to use less suitable materials for the substrate (D) after all, for example usual standard silicon wafers for CMOS wafer production, which have silicon atoms with magnetic momentum, the epitaxial layer (DEP1) is preferably, but not necessarily, deposited on the substrate (D), for example by means of CVD deposition. Preferably, this epitaxial layer (DEP1) is isotopically pure and/or free of isotopes with magnetic momentum, excluding isotopes forming the nuclear quantum dots (CI) discussed later. Preferably, in the case of a silicon crystal as substrate (D), this epitaxial layer (DEP1) is isotopically pure and/or free of nucleus magnetic momentum, for example, made of ²⁸Si silicon isotopes. Preferably, in the case of a diamond crystal as substrate (D), this epitaxial layer (DEP1) is isotopically pure and/or free of nucleus magnetic momentum, for example, made of ¹²C carbon isotopes. Preferably, in the case of a silicon carbide crystal as substrate (D), this epitaxial layer (DEP1) is isotopically pure and/or free of nucleus magnetic momentum, for example, made of ²⁸Si silicon isotopes and ¹²C carbon isotopes.

Device for Manipulation of the Quantum Dot

The decisive factor is now the combination with a device suitable for generating a circularly polarized electromagnetic radiation field, in particular a circularly polarized microwave field (B_{MW}), at the location of the quantum dot (NV). In the prior art, macroscopic coils are generally used for this purpose. This technique has the advantage that the field of a Helmholtz coil can be calculated very well and is very homogeneous. However, the disadvantage of such a technique is that the circularly polarized electromagnetic wave field affects multiple quantum dots (NVs) that are typically closely spaced compared to the wavelength of the circularly polarized wave field. In the prior art, these devices, which are typically used to irradiate a microwave radiation into the quantum dot, usually equally affecting all quantum dots of the device in the same way. This is avoided in the proposal presented here. Here, the quantum dots are placed in the near field of one or more electrical lines (LH, LV).

Such a device is shown in FIG. 1.

The substrate (D) and/or the epitaxial layer (DEP1), if present, have a surface (OF). For the purposes of this disclosure, leads (LH, LV) and their insulation layers (IS) are generally located above the surface (OF).

The quantum dot (NV), as described, is preferably a paramagnetic center (NV) placed as a quantum dot (NV) in the substrate (D) and/or in the epitaxial layer (DEP1), if present. Preferably, the substrate (D) is diamond and the quantum dot (NV) is an NV center or an ST1 center or an L2 center or preferably silicon and the quantum dot (NV) is a G center or preferably silicon carbide and the quantum dot (NV) is a V center.

To describe the geometry, it is necessary to be able to precisely describe the distance (d1) between the quantum dot (NV) and the surface (OF) and the devices located there for manipulating and entangling the quantum dot (NV) with other quantum objects.

For this purpose, an imaginary perpendicular is introduced along an imaginary perpendicular line (LOT) from the location of the quantum dot (NV) to the surface (OF) of the substrate (D) and/or to the surface (OF) of the epitaxial layer (DEP1), if present, which can be precipitated along this imaginary perpendicular line (LOT). The imaginary perpendicular line (LOT) then virtually pierces the surface (OF) of the substrate (D) and/or the epitaxial layer (DEP1), if present, at a perpendicular point (LOTP).

The device suitable for generating a circularly polarized electromagnetic wave field, in particular a circularly polarized microwave field (B_{MW}), is then preferably located on the surface of the substrate (D) and/or the epitaxial layer (DEP1), if present, and specifically in the proximity of the perpendicular point (LOTP) or at the perpendicular point (LOTP). Here, proximity means that the device is placed so close to the quantum dot (NV) that it can influence the quantum dot (NV) as intended in such a way that the quantum mechanical operations are possible in finite time, so that enough operations can be performed before the coherence fails. Preferably, then, the device is located just above the quantum dot (NV) on the surface (OF) at the perpendicular point (LOTP).

A second feature now concerns the specific example of this device suitable for generating a circularly polarized electromagnetic wave field, in particular a circularly polarized microwave field (B_{MW}). It is proposed to realize the device in the form of a horizontal line (LH) and a vertical line (LV). Here, the terms “horizontal” and “vertical” should be understood rather as part of a name for certain terminologies. Later, associated horizontal and vertical flows will be introduced, which are associated with these lines.

The horizontal line (LH) and the vertical line (LV) are now, since they constitute said device, on the surface (OF) of the substrate (D) and/or on the surface (OF) of the epitaxial layer (DEP1), if present. The horizontal line (LH) and the vertical line (LV) cross near the perpendicular point (LOTP) or at the perpendicular point (LOTP) at a non-zero crossing angle (α). Preferably, the crossing angle (a) is a right angle of 90° or π/2. The horizontal line (LH) and the vertical line (LV) preferably have an angle of 45° with respect to the axis of the quantum dot (NV) to add the magnetic field lines of the horizontal line and the vertical line (LV).

Example Orientation of the Crystal of the Substrate (D)

In the case of using diamond as a substrate (D) and a NV center as a quantum dot (NV), (111), (100) or (113) diamonds are preferred. To these crystallographic surface normal directions, the directions of the NV center are inclined 53°.

In the case of using silicon as a substrate (D) and a G-center as a quantum dot (NV), (111), (100) or (113) silicon crystals are preferably used. To these crystallographic surface normal directions, the directions of the G center are inclined by an angle.

In the case of using silicon carbide as a substrate (D) and a V-center as a quantum dot (NV), (111), (100) or (113) silicon carbide crystals are preferably used. To these crystallographic surface normal directions, the directions of the V-center are inclined by an angle.

Lead Insulation

It is useful for the horizontal line (LH) to be electrically insulated from the vertical line (LV) by means of electrical insulation, for example. Preferably, the horizontal line (LH) is electrically insulated from the vertical line (LV) by means of electrical insulation (IS). It is further useful that the horizontal line (LH) is electrically insulated from the substrate (D), for example by means of further insulation. Thus, it is typically also useful that the vertical line (LV) is electrically insulated with respect to the substrate (D), for example by a further insulation. In this context, two insulations can preferably also fulfill the insulation function of one of the three aforementioned insulations.

Back Contact

Preferably, the substrate (D) is electrically connected to an optional backside contact (BSC) with a defined potential. The backside contact (BSC) is preferably located on the surface of the substrate (D) opposite to the surface (OF) with the horizontal line (LH) and the vertical line (LV). Via the backside contact (BSC), the photocurrent (Iₚₕ) mentioned in the following can be read out alternatively or in parallel to the contacts of the shield lines (SH1, SH2, SH3, SH4, SV1, SV2) mentioned in the following and can be supplied to an evaluation by the control device (μC) mentioned in the following and the measuring means assigned to it.

Green Light as Excitation Radiation

In the operating procedures described below, “green light” is used to reset the quantum dots (NV). The term “green light” is to be understood functionally here. If other impurity centers are used than NV centers in diamond, for example G centers in silicon or V centers in silicon carbide, light or electromagnetic radiation of other wavelengths can be used, but then this is also referred to here as “green light”. In order for this green light to reach the quantum dots (NV), the structure of the horizontal line (LH) and the vertical line (LV) should allow the green light to pass in the direction of the respective quantum dot (NV). Alternatively, it is conceivable to feed the “green light” from the back side of the substrate (D) so that the “green light” does not have to pass the horizontal line (LH) and the vertical line (LV).

### Table of the Wavelengths of the ZPL and of Exemplariric Wavelegths of the Excitation Ra Diation

The table is only an exemplary compilation of some possible paramagnetic centers. The functionally equivalent use of other paramagnetic centers in other materials is explicitly possible. The wavelengths of the excitation radiation are also exemplary. Other wavelengths are usually possible if they are shorter than the wavelength of the ZPL to be excited.

| | | | | example | |
|---|---|---|---|---|---|
| | | | | Wavelength | |
| | | | | for “green light | |
| | | | | as excitation radiation | |
| | | | | in the sense of this | |
| Material | Defect Center | ZPL | | writing | reference |
| Diamond | NV Center | | | 520 nm, 532 nm | |
| Diamond | SiV center | 738 | nm | 685 nm | /2/, /3/, /4/ |
| Diamond | GeV center | 602 | nm | 532 nm | /4/, /5/ |
| Diamond | SnV Center | 620 | nm | 532 nm | /4/, /6/ |
| Diamond | PbV center | 520 | nm, | 450 nm | /4/, /7/ |
| | | 552 | nm | | /4/, /7/ |
| | | 715 | nm | 532 nm | /7/ |
| Silicon | G center | 1278.38 | nm | 637 nm | /8/ |
| Silicon carbide | V_{SI} center | 862 | nm(V1) 4H, | 730 nm | /1/, /9/, /10/ |
| | | 858.2 | nm(V1′) 4H | 730 nm | /1/, /9/, /10/ |
| | | 917 | nm(V2) 4H, | 730 nm | /1/, /9/, /10/ |
| | | 865 | nm(V1) 6H, | 730 nm | /1/, /9/, /10/ |
| | | 887 | nm(V2) 6H, | 730 nm | /1/, /9/, /10/ |
| | | 907 | nm(V3) 6H | 730 nm | /1/, /9/, /10/ |
| Silicon Carbide | DV Center | 1078-1132 | nm 6H | 730 nm | /9/ |
| Silicon Carbide | V_{C}V_{SI} Center | 1093-1140 | nm 6H | 730 nm | /9/ |
| Silicon Carbide | CAV_{Si} Center | 648.7 | nm 4H, 6H, 3C | 730 nm | /9/ |
| | | 651.8 | nm 4H, 6H, 3C | 730 nm | /9/ |
| | | 665.1 | nm 4H, 6H, 3C | 730 nm | /9/ |
| | | 668.5 | nm 4H, 6H, 3C | 730 nm | /9/ |
| | | 671.7 | nm 4H, 6H, 3C | 730 nm | /9/ |
| | | 673 | nm 4H, 6H, 3C | 730 nm | /9/ |
| | | 675.2 | nm 4H, 6H, 3C | 730 nm | /9/ |
| | | 676.5 | nm 4H, 6H, 3C | 730 nm | /9/ |

| | | | | |
|---|---|---|---|---|
| Silicon carbide | N_{C}V_{SI} center | 1180 nm-1242 nm 6H | 730 nm | /9/, /13/, /14/ |

List of Reference Literature for the Above Table
/1/Marina Radulaski, Matthias Widmann, Matthias Niethammer, Jingyuan Linda Zhang, Sang-Yun Lee, Torsten Rendler, Konstantinos G. Lagoudakis, Nguyen Tien Son, Erik Janzén, Takeshi Ohshima, Jörg Wrachtrup, Jelena Vučković, “Scalable Quantum Photonics with Single Color Centers in Silicon Carbide”, Nano Letters 17 (3), 1782-1786 (2017), DOI: 10.1021/acs.nanolett.6.b05102, arXiv:1612.02874
/2/C. Wang, C. Kurtsiefer, H. Weinfurter, and B. Burchard, “Single photon emission from SiV centres in diamond produced by ion implantation” J. Phys. B: At. Mol. Opt. Phys., 39(37), 2006
/3/Björn Tegetmeyer, “Luminescence properties of SiV-centers in diamond diodes” PhD thesis. University of Freiburg. Jan. 30, 2018.
/4/Carlo Bradac, Weibo Gao, Jacopo Foneris, Matt Trusheim, Igor Aharonovich, “Quantum Nanophotonics with Group IV defects in Diamond”, DOI: 10.1038/s41467-020-14316-x, arXiv:1906.10992
/5/Rasmus Hey Jensen. Erika Janitz, Yannik Fontana, Yi He, Olivier Gobron, Ilya P. Radko, Mihir Bhaskar, Ruffin Evans, Cesar Daniel Rodriguez Rosenblueth. Lilian Childress, Alexander Huck, Ulrik Lund Andersen. “Cavity-Enhanced Photon Emission from a Single Germanium-Vacancy Center in a Diamond Membrane”, arXiv:1912.05247v3 [quant-ph] 25 May 2020
/6/Takayuki Iwasaki, Yoshiyuki Miyamoto, Takashi Taniguchi, Petr Siyushev, Mathias H. Metsch, Fedor Jelezko, Mutsuko Hatano, “Tin-Vacancy Quantum Emitters in Diamond,” Phys. Rev. Lett. 119, 253601 (2017), DOI: 10.1103/PhysRevLett.119.253601, arXiv:1708.03576 [quant-ph].
/7/Matthew E. Trusbeim, Noel H. Wan. Kevin C. Chen, Christopher J. Ciccarino, Ravishankar Sundararaman, Girish Malladi, Eric Bersin, Michael Walsh, Benjamin Lienhard, Hassaram Bakhru. Prineha Narang, Dirk Englund, “Lead-Related Quantum Emitters in Diamond” Phys. Rev. B 99, 075430 (2019), DOI: 10.1103/PhysRevB.99.075430, arXiv:1805.12202 [quant-ph]
/8/M. Hollenbach, Y. Berencin, U. Kentsch, M. Helm, G. V. Astakhov “Engineering telecom single-photon emitters in silicon for scalable quantum photonics” Opt. Express 28, 26111 (2020), DOI: 10.1364/OE.397377, arXiv:2008.09425 [physics.app-ph]
/9/Castelletto and Alberto Boretti, “Silicon carbide color centers for quantum applications” 2020 J. Phys. Photonics2 022001
/10/V. Iv\dot{a}dy, J. Davidsson, N. T. Son, T. Ohshima, I. A. Abrikosov, A. Gali, “identification of Si-vacancy related room-temperature qubits in 4H silicon carbide”, Phys. Rev. B. 2017, 96, 161114
/11/J. Davidsson, V. Ividy, R. Armiento, N. T. Son, A. Gali, I. A. Abrikosov, “First principles predictions of magneto-optical data forsemiconductor point defect identification: the case of divacancy defects in 4H—SiC”, New J. Phys., 2018, 20, 023035
/12/J. Davidsson, V. Ividy, R. Armiento, T. Ohshima, N. T. Son, A. Gali, I. A. Abrikosov “Identification of divacancy and silicon vacancyqubits in 6H—SiC.” Appl. Opt. Phys. Lett. 2019, 114, 112107
/13/S. A. Zargaleh, S. Hameau, B. Eble, F. Margaillan, H. J. von Bardeleben, J. L. Cantin, W. Gao, “Nitrogen vacancy center in cubic silicon carbide: a promising qubit in the 1.5 μm spectral range for photonic quantum networks” Phys. Rev. B, 2018, 98, 165203
/14/S. A. Zargaleh et al “Evidence for near-infrared photoluminescence of nitrogen vacancy centers in 4H—SiC” Phys. Rev. B, 2016, 94, 060102

### Transparency of the Control Lines

Another simple option is for the horizontal line (LH) and/or the vertical line (LV) to be transparent to “green light”. For this purpose, in particular the horizontal line (LH) and/or the vertical line (LV) preferably comprise an electrically conductive material that is optically transparent to green light. In particular, the use of indium tin oxide (common abbreviation ITO) is recommended. Here it is important that the distance between the quantum dot (NV) or the nuclear quantum dot (CI) described later and the material of the leads (LH, LV) is larger than the maximum interaction distance between nucleus magnetic momentum of the isotopes of the material of the leads (LH. LV) and the quantum dot (NV). Indeed, it is unfortunate that both indium (IN) and tin (Sn) do not have natural stable isotopes without nucleus magnetic moment. A suitable distance can be established, for example, by a sufficiently thick silicon dioxide layer of ²⁸Si isotopes and ¹⁶O isotopes as insulation between the leads (LH, LV) on the one hand and the substrate (D) on the other hand, whose atomic nuclei have no nucleus magnetic moment.

Furthermore, it is conceivable that the horizontal line (LH) and/or the vertical line (LV) are made of material that becomes superconducting when the temperature falls below a critical temperature, the transition temperature (Tₑ). Typically, superconductors are not transparent. If the light is to be supplied from the top side, openings can be provided in the horizontal line (LH) and/or the vertical line (LV) instead of using ITO to allow the light to pass through. However, due to the small dimensions, this is only possible to a very limited extent. It is also conceivable to manufacture the horizontal line (LH) and/or the vertical line (LV) as a section-by-section composite of several parallel-guided lines. The introduction of openings and/or the parallel routing of several lines is important when using superconductors for the manufacture of the horizontal line (LH) and/or the vertical line (LV), particularly in order to prevent so-called pinning. This serves to prevent a freezing of flux quanta and thus to enable a complete magnetic reset.

As described earlier, the proposed quantum bit (QUB) has a surface (OF) with the horizontal line (LH) and with the vertical line (LV). Similarly, the proposed quantum bit (QUB) has a bottom surface (US) opposite to the surface (OF). Another way to ensure light access to the quantum dot (NV) of the quantum bit (QUB) is to mount the quantum bit (QUB) so that the bottom surface (US) of the quantum bit (QUB) can be irradiated with “green light” in such a way that the “green light” can reach and affect the quantum dot (NV). For this, the transparency of the material of the substrate (D) for the pump radiation wavelength of the “green light” is of course a prerequisite. If necessary, the substrate (D) must be thinned at least locally, e.g., by polishing and/or wet chemical etching and/or plasma etching, so that the total attenuation of the “green light” on entry from the surface opposite the surface (OF) to the quantum dot (NV) is sufficiently low.

In the examples discussed herein, preference is given to substrates (D) of diamond and silicon and silicon carbide as three examples, which already establishes a preferred class of quantum dot types. Furthermore, it is assumed that a quantum dot (NV) is preferably a paramagnetic center (NV). It is also assumed that the substrate (D) comprises, according to the particular example, diamond or silicon or silicon carbide, and that a quantum dot (NV) is an exemplary NV center in the case of exemplary diamond or is an exemplary G center in the case of exemplary silicon or is an exemplary V center in the case of exemplary silicon carbide. However, the disclosure is not limited to these three examples. In this paper, the same reference sign (NV) of the superset quantum dot (NV) is always used for the term quantum dot (NV) and the term paramagnetic center (NV) and the term NV center (NV) or G center or V center, respectively. As described above, other substrates (D) made of other materials with other paramagnetic centers can be used, which in turn define other quantum object types. Also, other impurity centers in silicon or silicon carbide or diamond can be used, which in turn define other quantum object types. The wavelengths and frequencies may then need to be adjusted. Here, as an example, a system with NV centers in diamond is preferably described as representative of the other possible combinations of materials of the substrate (D) or epitaxial layer (DEP1) on the one hand and paramagnetic impurities in these materials on the other hand.

Thus, instead, it is also conceivable that the substrate (D) comprises silicon and a quantum dot (NV) is a G center or other suitable impurity center.

Thus, instead, it is also conceivable that the substrate (D) comprises silicon carbide and a quantum dot (NV) is a V-center or other suitable impurity center.

Thus, instead, it is also conceivable that the substrate (D) comprises diamond and a quantum dot (NV) is a SiV center or a ST1 center or a L2 center or other suitable impurity center.

In general, other impurity centers and impurities and lattice defects in diamond are thus also considered. Various results indicate that if the substrate (D) comprises diamond, the quantum dot (NV) should preferably comprise a vacancy. Accordingly, a quantum dot (NV) in diamond as an exemplary substrate (D) should then comprise, for example, a Si atom or a Ge atom or a N atom or a P atom or an As atom or a Sb atom or a Bi atom or a Sn atom or a Mn atom or an F atom or another atom that generates an impurity center with a paramagnetic behavior in the exemplary diamond.

Accordingly, the quantum dot (NV) in silicon as substrate (D) should then have, for example, a Si atom on an interstitial site and/or a C atom on an interstitial site or as an atom substituting a silicon atom, which generates an impurity center with a paramagnetic behavior in the exemplary silicon crystal. Reference is made to the paper D. D. Berhanuddin, “Generation and characterization of the carbon G-center in silicon”, PhD-thesis URN: 1456601S, University of Surrey, March 2015.

Accordingly, the quantum dot (NV) in silicon carbide as substrate (D), for example, should then have a V_{Si} center or other impurity center with a paramagnetic behavior.

Later in this disclosure, nuclear quantum bits (CQUB) are further described using nuclear quantum dots (CI).

In the case of using NV centers in diamond as quantum dots (NV), in order to fabricate these nuclear quantum bits (CQUB) with nuclear quantum dots (CI) together with an NV center (NV) in diamond as a substrate (D), it is useful if the quantum dot (NV) in question is an NV center with a ¹⁵N isotope as a nitrogen atom or with a ¹⁴N isotope as a nitrogen atom. In this case, the use of a ¹⁵N isotope is particularly preferred. It is also conceivable to use isotopically pure ¹²C diamonds and to implant or deposit or place one or more ¹³C carbon isotopes in the proximity. i.e., in the effective range, of the quantum dot (NV). Quite preferably. 10-100 of these ¹³C isotopes are placed there. Proximity is understood here to mean that the magnetic field of the nuclear spin of the one or more ¹³C atoms can affect the spin of an electron configuration of the quantum dot (NV), and that the spin of the electron configuration of the quantum dot (NV) can affect the nuclear spin of one or more of these ¹³C isotopes. This makes a nucleus-electron quantum register (CEQUREG) in diamond possible.

In the case of using G centers in silicon as quantum dots (NV), in order to fabricate these nuclear quantum bits (CQUB) with nuclear quantum dots (CI) together with a G center (NV) in silicon as a substrate (D), it is useful if the quantum dot (NV) in question is a G center with one or two ¹³C isotopes as carbon atoms and/or with a ²⁹Si isotope as a silicon atom in the influence area of the G center as a quantum dot (NV). The use of a ¹³C isotope is particularly preferred. It is also conceivable to use isotopically pure ²⁸Si wafers or epitaxial isotopically pure ²⁸Si (DEP1) layers and to implant or deposit or place one or more ²⁹Si silicon isotopes in the proximity, i.e., in the influence area of the quantum dot (NV). Very special preference is given to place 10-100 of these ²⁹Si isotopes there. Proximity is understood here to mean that the magnetic fid of the nuclear spin of the one or more ²⁹Si atoms can affect the spin of an electron configuration of the quantum dot (NV), and that the spin of the electron configuration of the quantum dot (NV) can affect the nuclear spin of one or more of these ²⁹Si isotopes. Thus, a nucleus-electron quantum register (CEQUREG) in silicon becomes possible.

In the case of using V-centers in silicon carbide as quantum dots (NV), in order to fabricate these nuclear quantum bits (CQUB) with nuclear quantum dots (CI) together with a V-center (NV) in silicon carbide as substrate (D), it is useful if the quantum dot (NV) in question is a V-center with one or more ¹³C isotopes as carbon atoms and/or with one or more ²⁹Si isotopes as silicon atoms in the area of action of the V-center as quantum dot (NV). The use of a ¹³C isotope and/or a ²⁹Si isotope is particularly preferred. It is also conceivable to use isotopically pure ²⁸Si¹²C silicon carbide wafers or epitaxial isotopically pure ²⁸Si¹²C (DEP1) layers and to implant or deposit or place one or more ²⁹Si silicon isotopes and/or ¹³C carbon isotopes in the proximity. i.e., in the area of action of the quantum dot (NV). Quite preferably, 10-100 of these ²⁹Si silicon isotopes and/or ¹³C carbon isotopes are placed there. Proximity is understood here to mean that the magnetic field of the nuclear spin of the one or more ²⁹Si atoms and/or C atoms can influence the spin of an electron configuration of the quantum dot (NV), and that the spin of the electron configuration of the quantum dot (NV) can influence the nuclear spin of one or more of these ²⁹Si silicon isotopes and/or ¹³C carbon isotopes. Thus, a nucleus-electron quantum register (CEQUREG) in silicon carbide becomes possible. Reference is made here to the paper Stefania Castelleto and Alberto Boretti, “Silicon carbide color centers for quantum applications” 2020 J. Phys. Photonics2 022001, where other possible impurity centers are mentioned. If other elements are used to create the impurity centers, isotopes of these elements with a magnetic moment can be used to create the nuclear quantum dots in an analogous manner.

More generally, a diamond-based quantum bit (QUB) can thus be defined in which the quantum dot type of the quantum bit (QUB) is characterized in that the substrate (D) comprises a diamond material and one or more isotopes having a nuclear spin are located in proximity to the quantum dot (NV). Here proximity is to be understood then again in such a way that the magnetic field of the nuclear spin of the one or more isotopes can influence the spin of an electron configuration of the quantum dot (NV) and that the spin of the electron configuration of the quantum dot (NV) can influence the nuclear spin of one or more of these isotopes.

Thus, in a very general analogous way, a silicon-based quantum bit (QUB) can be defined in which the quantum dot type of the quantum bit (QUB) is characterized in that the substrate (D) comprises a silicon material and one or more isotopes having a nuclear spin are located in proximity to the quantum dot (NV). Here proximity is to be understood then again in such a way that the magnetic field of the nuclear spin of the one or more isotopes can influence the spin of an electron configuration of the quantum dot (NV) and that the spin of the electron configuration of the quantum dot (NV) can influence the nuclear spin of one or more of these isotopes.

Likewise, then, in a general manner, a silicon carbide-based quantum bit (QUB) can thus be defined in an analogous manner, in which the quantum dot type of the quantum bit (QUB) is characterized in that the substrate (D) comprises a silicon carbide material and one or more isotopes having a nuclear spin are located in proximity to the quantum dot (NV). Here, proximity is again to be understood as meaning that the magnetic field of the nuclear spin of the one or more isotopes can influence the spin of an electron configuration of the quantum dot (NV) and that the spin of the electron configuration of the quantum dot (NV) can influence the nuclear spin of one or more of these isotopes.

Since isotopically pure diamonds are extremely expensive, it is useful if the quantum dot type of the quantum dot (NV) of the quantum bit (QUB) is characterized in that the substrate (D) comprises a diamond material and that the diamond material comprises an epitaxially grown isotopically pure layer (DEP1) essentially of ¹²C isotopes. This can be deposited, for example, by CVD and other deposition methods on the original surface of a silicon wafer used as substrate (D). In this context, essentially means that the total fraction K_{IG′} of the C isotopes with magnetic moment that are part of the substrate (D), based on 100% of the C atoms that are part of the substrate (D), is reduced in comparison to the natural total fraction K_{IG} indicated in the above tables to a fraction K_{IG′} of the C isotopes with magnetic moment that are part of the substrate (D), based on 100% of the C isotopes that are part of the substrate (D), compared with the natural total fraction K_{IG} given in the above tables. Thereby, preferably, this fraction K_{IG′} is smaller than 50%, better smaller than 20%, better smaller than 10%, better smaller than 5%, better smaller than 2%, better smaller than 1%, better smaller than 0.5%, better smaller than 0.2%, better smaller than 0.1% of the natural total fraction K_{IG} for C isotopes with magnetic moment on the C isotopes of the substrate (D) in the action region of the paramagnetic impurities (NV) used as quantum dots (NV) and/or the nuclear spins used as nuclear quantum dots (CI). In the determination of the fraction K_{IG′}, the C atoms with magnetic moment of the nuclear quantum dots (CI) are not considered, since their magnetic moment is, after all, intentional and not parasitic.

Since isotopically pure silicon wafers are extremely expensive, it is useful if the quantum dot type of the quantum dot (NV) of the quantum bit (QUB) is characterized in that the substrate (D) comprises a silicon material and that the silicon material comprises an epitaxially grown isotopically pure layer (DEP1) essentially of ²⁸Si isotopes. This can be deposited, for example, by CVD and other deposition methods on the original surface of a silicon wafer used as substrate (D). Here, essentially means that the total fraction K_{IG′} of Si isotopes having magnetic moment, which are part of the substrate (D), relative to 100% of the Si atoms which are part of the substrate (D), is reduced compared with the natural total fraction K_{IG} indicated in the above tables to a fraction K_{IG′} of the Si isotopes with magnetic moment, which are part of the substrate (D), relative to 100% of the Si isotopes which are part of the substrate (D), compared with the natural total fraction K_{IG} shown in the above tables. Thereby, preferably, this fraction K_{IG′} is smaller than 50%, better smaller than 20%, better smaller than 10%, better smaller than 5%, better smaller than 2%, better smaller than 1%, better smaller than 0.5%, better smaller than 0.2%, better smaller than 0.1% of the natural total fraction K_{IG} for Si isotopes with magnetic moment on the Si isotopes of the substrate (D) in the area of influence of the paramagnetic impurities (NV) used as quantum dots (NV) and/or the nuclear spins used as nuclear quantum dots (CI). In the determination of the fraction K_{IG′}, the Si atoms of the nuclear quantum dots (CI) with magnetic moment are not taken into account, since their magnetic moment is intended and not parasitic.

Since isotopically pure silicon carbide wafers are also extremely expensive, it is useful if the quantum dot type of the quantum dot (NV) of the quantum bit (QUB) in a silicon carbide substrate (D) is characterized in that the substrate (D) comprises a silicon carbide material and that the silicon carbide material comprises an epitaxially grown isotopically pure layer (DEP1) essentially of ²⁸Si isotopes and ¹²C isotopes. This can be deposited, for example, by CVD and other deposition methods on the original surface of a silicon carbide wafer used as substrate (D). In essence, this means that the total fraction K_{IG′} of Si isotopes with magnetic moment and C isotopes with magnetic moment that are part of the substrate (D), based on 100% of the Si atoms and 100% of the C atoms that are part of the substrate (D), is reduced with respect to the total natural fraction K_{IG} indicated in the above tables to a fraction K_{IG′} of the Si isotopes with magnetic moment and of the C isotopes with magnetic moment, both of which are part of the substrate (D), with respect to 100% of the Si isotopes which are part of the substrate (D) and simultaneously with respect to 100% of the C isotopes which are part of the substrate (D). Preferably, this fraction K_{IG}′ is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for Si isotopes with magnetic moment related to the Si isotopes of the substrate (D) in the action region of the paramagnetic perturbations (NV) used as quantum dots (NV) and/or the nuclear spins used as nuclear quantum dots (CI) and for C-isotopes with magnetic moment related to the C-isotopes of the substrate (D) in the action region of the paramagnetic impurities (NV) used as quantum dots (NV) and/or the nuclear spins used as nuclear quantum dots (CI). In the determination of the fraction K_{IG′}, the Si atoms of the nuclear quantum dots (CI) with magnetic moment or the C atoms of the nuclear quantum dots (CT) with magnetic moment are not taken into account, since their magnetic moment is, after all, required for the shaping of the nuclear quantum dots (CI) and is thus intended and not parasitic.

For the NV centers (NV) to function properly in a diamond as substrate (D), it is important that the substrate (D). i.e., the diamond, is n-doped in the proximity of the NV center (NV) so that the NV center is most likely to be in a negatively charged state as it captures the excess electrons. This realization is one of the most essential to ensure the producibility of the proposal presented here. In order not to disturb the quantum dot (NV) regardless of the substrate and the paramagnetic center (NV) used or regardless of the type of q turn dot used as quantum dot (NV), dopants used should have no nuclear spin or only insignificant it nuclear spin. For NV centers in diamond, doping in the region of the quantum dot (NV) with nuclear spin-free and, in particular, with ³²S isotopes is recommended, since these have proven heir worth. In general, nuclear spin-free isotopes should be used for doping in the quantum dc (NV) area. The term “area” is to be understood here as an interaction area for a direct or indirect interaction. A direct interaction occurs from one quantum object—e.g., a quantum dot-directly to the other quantum object—e.g., another quantum dot. An indirect interaction takes place with the aid of at least one further quantum object—e.g., a third quantum dot. For this, reference is made to the explanations on the “quantum bus” described later in the following. Preferably, the quantum dot (NV) is located at a more or less predetermined first distance (d1) along the virtual perpendicular line (LOT) below the surface (OF) of the substrate (D) and/or the epitaxial layer (DEP1), if present. Preferably, this first distance (d1) is 2 nm to 60 nm and/or more preferably is 5 nm to 30 nm and/or is 10 nm to 20 nm, with a first distance (d1) of 5 nm to 30 nm being particularly preferred.

In the semiconductor industry, the dopants B, Al, Ga and In are mainly used for various purposes to create a p-doping in a silicon substrate (D). Boron, aluminum, gallium and indium do not have a sufficiently long-lived isotope without nucleus magnetic moment. In the semiconductor industry, dopants P, As, Sb, Bi, Li are mainly used for various purposes to create an n-dopant in a silicon substrate (D). Phosphorus, arsenic, antimony, bismuth and lithium also do not have a sufficiently long-lived isotope without nucleus magnetic moment. Thus, doping ²⁸Si silicon substrates (D) without introducing parasitic magnetic momentum is a serious problem.

Also, for G-centers in silicon, n-doping in the quantum dot (NV) region is possible with nuclear spin-free and in particular with stable isotopes of the six main group. For example. ¹²⁰Te isotopes and/or ¹²²Te isotopes and/or ¹²⁴Te isotopes and/or ¹²⁶Te isotopes and/or ¹²⁸Te isotopes and/or ¹³⁰Te isotopes, do not exhibit nucleus magnetic moment. Tellurium is a donor in silicon with a distance of 0.14 eV to the conduction band edge. The titanium isotopes ⁴⁶Ti, ⁴⁸Ti, ⁵⁰Ti also appear suitable at a distance to the conduction band edge of 0.21 eV in silicon. The carbon isotopes ¹²C and ¹⁴C, which are part of the G centers anyway, can be considered as further donors. Furthermore, the Se isotopes ⁷⁴Se, ⁷⁶Se, ⁷⁸Se, ⁸⁰Se can be considered as donors with an activation energy of 0.25 eV. Likewise, the Ba isotopes ¹³⁰Ba, ¹³²Ba, ¹³⁴Ba, ¹³⁶Ba, ¹³⁸Ba with a distance of 0.32 eV from the conduction band edge are also possible. Thereby, the barium isotope ¹³⁰Ba has a half-life of 1.6×1021 years and is thus stable in the technical sense in the same way as the other Ba isotopes mentioned. The sulfur isotopes ³²S, ³⁴S, and ³⁶S are also suitable with an energetic distance of 0.26 eV from the valence band edge. The other common stable isotopes of n-dopants in silicon such as all the stable isotopes of antimony ¹²¹Sb and ¹²³Sb and the stable isotope of phosphorus. ³¹P, and the stable isotope of arsenic, ⁷⁵As, and the stable isotope of bismuth, ²⁰⁹Bi, and two of the stable isotopes of tellurium, ¹²³Te and ¹²⁵Te, exhibit nucleus magnetic moment and are thus not suitable for the purpose of shifting the Fermi level near the quantum dot (NV) or the nuclear quantum dot (CI). However, they can be considered as a potential nuclear quantum dot (CI), which will be explained later. If a silicon substrate (D) is doped as part of a CMOS process, a distance should be maintained between the regions of the silicon substrate (D) doped with the standard dopants of silicon-based semiconductor technology from the III^{rd} and V^{th} main groups and the quantum dots (NV) or nuclear quantum dots (CI), which precludes any disruptive parasitic coupling of the magnetic momentum of the doping atoms with the quantum dots (NV) and/or the nuclear quantum dots (CI). Such standard dopants for doping silicon include B, Al, Ga, In, P, As, Sb, Bi, and Li. It has been shown that a distance of several μm between the quantum dot (NV) or the nuclear quantum dot (CI) on the one hand and the silicon region doped with these standard dopants on the other hand is sufficient, taking in to account the out-diffusion in the CMOS process. If necessary, a Design of Experiment (DoE) experiment is recommended to minimize the gap according to the semiconductor technology used and the application requirements. Thus, ¹²⁰Te, ¹²²Te, ¹²⁴Te, ¹²⁶Te, ¹²⁸Te, ¹³⁰Te, ⁴⁶Ti, ⁴⁸Ti, ⁵⁰Ti, ¹²C, ¹⁴C, ⁷⁴Se, ⁷⁶Se, ⁷⁸Se, ⁸⁰S, ¹³⁰Ba, ¹³²Ba, ¹³⁴Ba, ¹³⁶Ba, ¹³⁸Ba, ³²S, ³⁴S, and ³⁶S are particularly suitable as n-dopants for doping silicon substrates (D) in the quantum dot (NV) and/or nuclear quantum dot (CI) coupling region. For G centers in silicon, p-doping of the silicon substrate (D) material in the quantum dot (NV) region with nuclear spin-free isotopes is very difficult. Instead of the standard doping atoms of the III, main group, other isotopes have to be used, since these standard dopant atoms of the III^{rd} main group all have a nucleus magnetic moment. Some less energetically poor potential dopants are only quasi-stable and have no nucleus magnetic moment. ²⁰⁴Tl has a half-life of 3.783(12)×10¹² years, making it quasi-stable. The magnetic moment μ of ²⁰⁴Tl is only 0.09. With 0.3 eV, however, the acceptor level is already somewhat further away from the band edge. Thus, doping with ²⁰⁴Tl is a very poor, but possibly still applicable compromise. Stable palladium isotopes ¹⁰²Pd, ¹⁰⁴Pd, ¹⁰⁶Pd, ¹⁰⁸Pd, ¹¹⁰Pd, lead to a p-doping free of nucleus magnetic momentum with an energetic distance to the valence band edge of 0.34 eV. Palladium is thus a better compromise. Also metastable is the beryllium isotope ¹⁰Be, which is free of nucleus magnetic momentum, with a half-life of 1.51(4)×10⁶ years. In silicon, beryllium acts as an acceptor with two energy levels in the band gap at 0.42 eV and 0.17 eV distance from the valence band edge. Thus, the radioactive beryllium ¹⁰Be is a very good compromise for p-doping the silicon of a silicon substrate (D) in the quantum dot (NV) or nuclear quantum dot (CI) region. Therefore, a key finding in the preparation of this paper is the doping of the material of the silicon substrate (D) in the coupling region of the quantum dots (NV) and/or the nuclear quantum dots (CI) with an isotope that does not have a nucleus magnetic moment, or that has a nucleus moment smaller than μ=0.1 as a compromise. It has been recognized that the doping of the silicon material of the silicon substrate (D) with metastable isotopes of the third main group with a half-life longer than 10⁵ years, when these isotopes do not have a nucleus magnetic moment μ, is particularly preferred to achieve a p-doping of the material of the silicon substrate (D) in the coupling region of the quantum dots (NV) and/or in the coupling region of the nuclear quantum dots (CI).

Other stable isotopes, such as the boron isotope ¹⁰B or the aluminum isotope, ²⁶Al, exhibit an integer magnetic moment p and therefore couple parasitically with the quantum dot (NV) and the nuclear quantum dot (CI).

Thus, ¹⁰Be, ¹⁰²Pd, ¹⁰⁴Pd, ¹⁰⁶Pd, ¹⁰⁸Pd, ¹¹⁰Pd, ²⁰⁴Tl are suitable for generating p-doping of silicon substrates (D), especially ²⁸Si silicon substrates and ²⁸Si epitaxial layers (DEP1), since they are free of magnetic momentum (¹⁰Be, ¹⁰²Pd, ¹⁰⁴Pd, ¹⁰⁶Pd, ¹⁰⁸Pd, ¹¹⁰Pd) or, like ²⁰⁴Tl, have very low magnetic moment.

The other common stable isotopes of p-dopants in silicon, such as the stable isotope of boron, ¹¹B and the stable isotopes of gallium, ⁶⁹Ga and ⁷¹Ga, and the stable isotope of indium, ¹¹³In, and the stable isotopes of thallium, ²⁰³Tl and ²⁰⁵Tl, exhibit significant nucleus magnetic moment and are not readily suitable for the purpose of shifting the Fermi level near the quantum dot (NV) or in the vicinity of a nuclear quantum dot (C) are thus not readily suitable. However, they do qualify as a potential nuclear quantum dot (CI), which will be explained later. Reference is made to the paper by H. R. Vydyanath, J. S. Lorenzo, F. A. Kröger, “Defect pairing diffusion, and solubility studies in selenium-doped silicon,” Journal of Applied Physics 49, 3928 (1978), httpsJ/doi.org/10.1063/1.324560.

In general, isotopes without magnetic moment are to be used for doping in the region of the quantum dot (NV) or the nuclear quantum dot (CI). The term “region” is to be understood here as an interaction region for a direct or indirect interaction in the form of a coupling. A direct interaction takes place from one quantum object—e.g., a quantum dot (NV) or a nuclear quantum dot (CI)-directly to the other quantum object—e.g., another quantum dot. An indirect interaction occurs with the aid of at least one other quantum object—e.g., a third quantum dot. For this, reference is made to the explanations on the “quantum bus” described later in the following. Preferably, the quantum dot (NV) is located at a more or less predetermined first distance (d1) along the virtual perpendicular line (LOT) below the surface (OF) of the substrate (D) and/or the epitaxial layer (DEP1), if present. Preferably, this first distance (d1) is 2 nm to 60 nm and/or more preferably is 5 nm to 30 nm and/or is 10 nm to 20 nm, with a first distance (d1) of 5 nm to 30 nm being particularly preferred.

In order to reduce or even avoid the coupling of control signals of the quantum bit (QUB) into other quantum bits (QUB2) of a device, it is useful to reduce the field expansion to the minimum by microstrip lines, also called microstrip lines. Therefore, a quantum bit (QUB) is proposed herein in which the horizontal line (LH, LH1) and the vertical line (LV, LV1) are each part of a respective microstrip line and/or part of a respective tri-plate line. In the case where microstrip lines are used, the vertical microstrip line then comprises a first vertical shield line (SV1) and the vertical line (LV), and the horizontal microstrip line comprises a first horizontal shield line (SH1) and the horizontal line (LH).

In the case of a tri-plate line, the vertical tri-plate line comprises a first vertical shield line (SV1) and a second vertical shield line (SV2) and the vertical line (LV). In this case, the vertical line (LV) preferably runs at least partially between the first vertical shield line (SV1) and the second vertical shield line (SV2).

In this case, the horizontal tri-plate line preferably comprises a first horizontal shield line (SH1) and a second horizontal shield line (SH2) and the horizontal line (LV) extending at least partially between the first horizontal shield line (SH1) and the second horizontal shield line (SH2).

Preferably, but not necessarily, in the case of using tri-plate lines, the sum of the currents (ISV1, IV, ISV2) through the tri-plate line (SV1, LV, SV2) is zero, which limits the magnetic field of these currents to the vicinity of these lines.

This limitation of the magnetic field can be better defined (See FIG. 16). For this purpose, a first further vertical perpendicular line is precipitated along a first further vertical perpendicular line (VLOT1) parallel to the first perpendicular line (LOT) from the location of a first virtual vertical quantum dot (VVNV1) to the surface (OF) of the substrate (D) and/or the epitaxial layer (DEP1), if present. This first virtual vertical quantum dot (VVNV1) would now also be located at the first distance (d1) from the surface (OF) and thus at the same depth as the quantum dot (NV). The first further vertical perpendicular line (VLOT1) then pierces the surface (OF) of the substrate (D) and/or the epitaxial layer (DEP1), if present, at a first further vertical perpendicular point (VLOTP1). The horizontal line (LH) and the first vertical shield line (SV1) are again located on the surface of the substrate (D) and/or the epitaxial layer (DEP1), if present. The horizontal line (LH) and the first vertical shield line (SV1) now preferably cross near the first vertical perpendicular point (VLOTP1) or at the first vertical perpendicular point (VLOTP1) at the non-zero crossing angle (α). Similarly, on the opposite side of the quantum dot (NV), a second further vertical perpendicular line can be precipitated along a second further vertical perpendicular line (VLOT2) parallel to the first perpendicular line (LOT) from the location of a second virtual vertical quantum dot (VVNV2) to the surface (OF) of the substrate (D) and/or the epitaxial layer (DEP1), if present. The second virtual vertical quantum dot (VVNV2) is thereby also located at the first distance (d1) from the surface (OF) below the same. The second further vertical perpendicular line (VLOT2) pierces the surface (OF) of the substrate (D) and/or the epitaxial layer (DEP1), if present, at a second further vertical perpendicular point (VLOTP2). The horizontal line (LH) and the second vertical shield line (SV2) are again located on the surface of the substrate (D) and/or the epitaxial layer (DEP1), if present. The horizontal line (LH) and the second vertical shield line (SV2) cross in an analogous manner near the second vertical perpendicular point (VLOTP2) or at the second vertical perpendicular point (VLOTP2) at the non-zero crossing angle (α). The individual currents (ISV1, IV, ISV2) through the individual lines (SV1, LV, SV2) of the triplate line are now preferably selected such, that the magnitude of the first virtual vertical magnetic flux density vector (B_{VVNV1}) at the location of the first virtual vertical quantum dot (VVNV1) is nearly zero and that the magnitude of the second virtual vertical magnetic flux density vector (B_{VVNV2}) at the location of the second virtual vertical quantum dot (VVNV2) is nearly zero and that the magnitude of the magnetic flux density vector (B_{NV}) at the location of the quantum dot (NV) is different from zero. As can be easily seen, this ends up being a polynomial approximation problem with each shielding line parallel to a line (LH, LV) more, another shielding current can be freely chosen, improving the approximation. The disadvantage is that this increases the minimum distance between two quantum bits (QUB1, QUB2) and thus decreases the coupling frequency and thus decreases the number of operations that can be performed.

In an analogous manner, the approximation of the field along the horizontal line can be performed. In this case, a first further horizontal plumb line can be precipitated along a first further horizontal plumb line (HLOT1) parallel to the first plumb line (LOT) from the location of a first virtual horizontal quantum dot (VHNV1) to the surface (OF) of the substrate (D) and/or the epitaxial layer (DEP1), if present. The first virtual horizontal quantum dot (VHNV1) is located at the first distance (d1) from the surface (OF) below the same. The first further horizontal plumb line (VLOT1) pierces the surface (OF) of the substrate (D) and/or the epitaxial layer (DEP1), if any, at a first further horizontal plumb point (HLOTP1). The vertical line (LV) and the first horizontal shield line (SH1) are located on the surface of the substrate (D) and/or the epitaxial layer (DEP1), if present. The vertical line (LV) and the first horizontal shield line (SH1) cross near the first horizontal perpendicular point (HLOTP1) or at the first horizontal perpendicular point (HLOTP1) at the non-zero crossing angle (a). A second further horizontal plumb line may be precipitated along a second further horizontal plumb line (HLOT2) parallel to the first plumb line (LOT) from the location of a second virtual horizontal quantum dot (VHNV2) to the surface (OF) of the substrate (D) and/or the epitaxial layer (DEP1), if present. The second virtual horizontal quantum dot (VHNV2) is located at the first distance (d1) from the surface (OF) below the same. The second further horizontal plumb line (HLOT2) pierces the surface (OF) of the substrate (D) and/or the epitaxial layer (DEP1), if present, at a second further horizontal plumb point (HLOTP2). The vertical line (LV) and the second horizontal shield line (SH2) are located on the surface of the substrate (D) and/or the epitaxial layer (DEP1), if present. The vertical line (LV) and the second horizontal shield line (SH2) cross near the second horizontal plumb point (HLOTP2) or at the second horizontal plumb point (HLOTP2) at the non-zero crossing angle (α). The individual currents (ISH1, IH, ISH2) through the individual lines (SH1, LH, SH2) of the triplate line are also selected here in such a way, that the magnitude of the first virtual horizontal magnetic flux density vector (B_{VHNV1}) at the location of the first virtual horizontal quantum dot (VHNV1) is almost zero and that the magnitude of the second virtual horizontal magnetic flux density vector (B_{VHNV2}) at the location of the second virtual horizontal quantum dot (VHNV2) is almost zero and that the magnitude of the magnetic flux density vector (B_{NV}) at the location of the quantum dot (NV) is different from zero.

In order to be able to extract generated photoelectrons, it is useful, if in the region or in the vicinity of the perpendicular point (LOTP) the substrate (D) is connected by means of at least one first horizontal ohmic contact (KH11) to the first horizontal shielding line (SH1) and/or if in the region or in the vicinity of the perpendicular point (LOTP) the substrate (D) is connected by means of at least one second horizontal ohmic contact (KH12) to the second horizontal shielding line (SH2) and/or if in the region or in the vicinity of the perpendicular point (LOTP) the substrate (D) is connected by means of at least one at least one first vertical ohmic contact (KV11) to the first vertical shield line (SV1) and/or if, in the region or in the vicinity of the perpendicular point (LOTP), the substrate (D) is connected to the second vertical shield line (SV2) by means of at least one second vertical ohmic contact (KV12) and/or if, in the region or in the vicinity of the perpendicular point (LOTP), the substrate (D) is connected to an extraction line by means of at least one second vertical ohmic contact (KV12). Preferably, a resistive contact (KV11, KV12, KH11, KH12) comprises a high n or p doping, the doping being preferably obtained by means of a use of the previously mentioned isotopes without magnetic moment μ. Preferably, the leads are made of a material that preferably comprises essentially no isotopes with a nucleus magnetic moment. For example, a metallization of titanium with the isotopes ⁴⁶Ti, ⁴⁸Ti and ⁵⁰Ti may be considered. Preferably, the insulations between the lines (LH, LV) among themselves and between the lines (LH, LV) on the one hand and the material of the substrate (D) on the other hand are also made of a material comprising essentially no isotopes with magnetic moments. For example, in many cases the use of ²⁸Si¹⁶O₂ silicon oxide is particularly recommended. The use of ohmic contacts other than titanium contacts is of course possible.

Nuclear Quantum Bit (CQUB) According to the Disclosure

In the previous section, it was mentioned that in addition to quantum dots (NV), nuclear quantum dots (CI) can also be fabricated.

The now following section is in its core a repetition of the previous section with the difference that the quantum bit is now structurally based not on electron spins but on nuclear spins. Reference is made here to the preceding section, which dealt in detail with the isotopes that can be used.

As mentioned above, 13C isotopes, among others, can be used as nuclear quantum dots (CI) in the case of a diamond substrate (D).

In the case of a silicon substrate (D), 29Si isotopes, for example, can be used as the nuclear quantum dot (CI).

For example, in the case of a silicon carbide substrate (D), 29Si isotopes and/or 13C isotopes may be used as the nuclear quantum dot (CI).

### Diamond

It is important here that the ¹³C isotopes in the case of a diamond substrate (D) can be brought as close as possible to the quantum dots (NV)—for example in the form of the NV centers—in the manufacturing process and assume different positions to the quantum dot (NV), e.g., an NV center.

### Silicon

In the case of a silicon substrate (D), it is important in an analogous way that the ²⁹Si isotopes can be brought as close as possible to the quantum dots (NV) in the form of the G centers in the fabrication process and occupy different positions with respect to the quantum dot (NV), e.g., a G center.

### Silicon Carbide

In the case of a silicon carbide substrate (D), it is important in an analogous way that the ²⁹Si isotopes or the ¹³C isotopes can be brought as close as possible to the quantum dots (NV) in the form of the V centers in the fabrication process and occupy different positions with respect to the quantum dot (NV). i.e., a V center, for example.

General Information about Coupling

It is possible to implant a large number of ¹³C isotopes or ²⁹Si isotopes because they do not interfere with each other due to the short coupling range. In contrast to electric spins of electron configurations of quantum dots (NV), which have a long coupling range, the nuclear spins of nuclear quantum dots (CI) have only a very short coupling range. Therefore, it is preferred to establish a connection between nuclear quantum dots (CI) that have a spatial distant from each other larger further than the nucleus coupling range via a chain of one or more quantum dots (NV) that are spaced at least in pairs form each other such that both quantum dots (NV1, NV2) of such a quantum dot pair have a distance smaller than the electron-electron coupling range between these two quantum dots (NV1, NV2), and wherein the quantum dot pairs result in a closed chain of quantum dots coupled to each other at least in pairs, so that the nuclear quantum dots (CI) spatially distant from each other can be coupled to each other via these ancilla quantum dots. This is done by the quantum bus (QUBUS) described later.

Implantation of Molecules in Diamond

For example, to fabricate suitable structures in a diamond substrate (D), one can implant heptamine or another suitable carbon compound with a nitrogen atom. Suitably fabricated heptamine may include an N-nitrogen atom and 5 ¹³C isotopes. In that case, the nitrogen atom can be implanted together with the ¹³C isotopes. The nitrogen atom then preferably forms the NV center. i.e., the quantum dot (NV), while the ¹³C isotopes form the nuclear quantum dots (CI). This has the advantage that in this way a more complex register can be produced in one fabrication step in diamond as substrate (D).

Preferably, this is a method for producing a quantum ALU in the material of a diamond substrate (D) comprising the step of implanting a carbon-containing molecule, wherein the molecule comprises at least one or two or three or four or five or six or seven or more ¹³C isotopes, and wherein the molecule comprises at least one nitrogen atom.

Basic Control Device

A nuclear quantum dot (CI) based nuclear quantum bit (CQUB) therefore preferably comprises a device for controlling the nuclear quantum dot (CI), a substrate (D), optionally with an epitaxial layer (DEP1), the nuclear quantum dot (CI) and a device suitable for generating an electromagnetic preferably circularly polarized wave field (Baw) at the location of the nuclear quantum dot (CI). Preferably, as described above, the epitaxial layer (DEP1), if present, is deposited on the substrate (D). The substrate (D) and/or the epitaxial layer (DEP1), if present, has a surface (OF). The nuclear quantum dot (CI) exhibits a magnetic moment, in particular a nuclear spin. The device suitable for generating an electromagnetic, in particular circularly polarized, wave field (Baw) is preferably located on the surface of the substrate (D) and/or the epitaxial layer (DEP1), if present. The device suitable for generating an electromagnetic, in particular circularly polarized, wave field (Baw) is preferably firmly connected to the substrate (D) and/or the epitaxial layer (DEP1), if present.

As with the quantum bit (QUB), a plumb line can again be precipitated along a perpendicular line (LOT) from the location of the nuclear quantum dot (CI) to the surface (OF) of the substrate (D) and/or the epitaxial layer (DEP1), if present. The perpendicular line (LOT) breaks through the surface (OF) of the substrate (D) and/or the epitaxial layer (DEP1), if present, at a perpendicular point (LOTP). The device suitable for generating an electromagnetic wave field, in particular a circularly polarized electromagnetic wave field, in particular a radio wave field (Baw), is preferably located in the vicinity of the perpendicular point (LOTP) or at the perpendicular point (LOTP).

The proposed nuclear quantum bit (CQUB) preferably comprises a horizontal line (LH) and a vertical line (LV), which are preferably located on the surface of the substrate (D) and/or the epitaxial layer (DEP1), if present. Preferably, the horizontal line (LH) and the vertical line (LV) form the aforementioned device suitable for generating an electromagnetic wave field, in particular a circularly polarized electromagnetic wave field, in particular a radio wave field (B_{RW}), at the location of the nuclear quantum dot (CI).

Preferably, a virtual plump line can be precipitated along a virtual perpendicular line (LOT) from the location of the nuclear quantum dot (CI) to the surface (OF) of the substrate (D) and/or the epitaxial layer (DEP1), if present, wherein the perpendicular line (LOT) pierces the surface (OF) of the substrate (D) and/or the epitaxial layer (DEP1), if present, at a perpendicular point (LOTP) and wherein the horizontal line (LH) and the vertical line (LV) are located near the perpendicular point (LOTP), present epitaxial layer (DEP1) at a perpendicular point (LOTP) and wherein the horizontal line (LH) and the vertical line (LV) cross in the vicinity of the perpendicular point (LOTP) or at the perpendicular point (LOTP) at a non-zero crossing angle (α).

The horizontal line (LH) is preferably electrically insulated from the vertical line (LV) by means of an electrical insulation (IS). Preferably, the horizontal line (LH) and/or the vertical line (LV) is transparent to “green light” and preferably made of an electrically conductive material that is optically transparent to green light, in particular indium tin oxide (common abbreviation ITO).

The angle (α) is preferably essentially a right angle. Preferably, the substrate (D) comprises a paramagnetic center and/or a quantum dot (NV). Furthermore, the substrate (D) preferably comprises diamond or alternatively silicon or alternatively silicon carbide. The use of other materials as substrate is conceivable.

Variants according to the material of the substrate (D)

In a preferred example, the substrate (D) comprises diamond with a NV center and/or a ST1 center and/or a L2 center and/or a SiV center as a quantum dot (NV).

In another preferred example, the substrate (D) comprises silicon with a G-center quantum dot (NV).

In another preferred example, the substrate (D) comprises silicon carbide with a V-center as a quantum dot (NV).

Diamond

In a diamond example, the substrate (D) comprises diamond and a quantum dot (NV), wherein the quantum dot (NV) comprises a vacancy or other impurity. Preferably, the substrate (D) comprises diamond and a quantum dot (NV), wherein the quantum dot (NV) comprises a Si atom or a Ge atom or a N atom or a P atom or an As atom or a Sb atom or a Bi atom or a Sn atom or a Mn atom or an F atom or any other atom that generates an impurity center and/or an impurity with a paramagnetic behavior in diamond. In another sub-variation, the substrate (D) comprises diamond and a nuclear quantum dot (CI) comprising an atomic nucleus of a ¹³C isotope or a ¹⁴N isotope or a ¹⁵N isotope or other atom whose atomic nucleus has a magnetic moment. In an important sub-variation, the NV center itself is formed as a nuclear quantum dot (CI) and as a quantum dot (NV) simultaneously In this case, the substrate (D) comprises diamond and preferably, as the nuclear quantum dot (CI), the atomic nucleus of a ¹⁴N isotope or a ¹⁵N isotope of the nitrogen atom, which is the nitrogen atom of the NV center in question.

### Silicon

In a silicon example, the substrate (D) comprises silicon and a quantum dot (NV), wherein the quantum dot (NV) comprises a vacancy or other impurity, for example carbon atoms. Preferably, the substrate (D) comprises silicon and a quantum dot (NV), wherein the quantum dot (NV) comprises a C atom or a Ge atom or a N atom or a P atom or an As atom or a Sb atom or a Bi atom or a Sn atom or a Mn atom or a F atom or another atom that generates an impurity center and/or an impurity with a paramagnetic behavior in silicon. In another sub-variant, the substrate (D) comprises silicon and a nuclear quantum dot (CI) comprising an atomic nucleus of a ²⁹Si isotope or a ¹³C isotope or a ¹⁴N isotope or a ¹⁵N isotope or another atom whose atomic nucleus has a magnetic moment. In an important sub-variation of this variant, the G-center itself is formed as a nuclear quantum dot (CI) and as a quantum dot (NV) simultaneously in this case, the substrate (D) comprises silicon and preferably as a nuclear quantum dot (CI) the atomic nucleus of a ¹³C isotope or of a ²⁹Si isotope.

### Silicon Carbide

In a silicon carbide example, the substrate (D) comprises silicon carbide and a quantum dot (NV), wherein the quantum dot (NV) comprises a vacancy or other impurity. Preferably, the substrate (D) comprises silicon carbide and a quantum dot (NV), wherein the quantum dot (NV) comprises a Si atom at a C position or a C atom at a Si position or a Ge atom or a N atom or a P atom or an As atom or a Sb atom or a Bi atom or a Sn atom or a Mn atom or an F atom or other atom, which generates in silicon carbide an impurity center and/or an impurity having a paramagnetic behavior in silicon carbide. In another sub-variant, the substrate (D) comprises silicon carbide and a nuclear quantum dot (CI) comprising a nucleus of a ²⁹Si isotope or a ¹³C isotope or a ¹⁴N isotope or a ¹⁵N isotope or other atom whose atomic nucleus has a magnetic moment. In an important sub-variation of this variant, the V-center itself is formed as a nuclear quantum dot (CI) and as a quantum dot (NV) simultaneously in this case, the substrate (D) comprises silicon and preferably as a nuclear quantum dot (CI) the atomic nucleus of a ¹³C isotope or of a Si isotope.

### Diamond

In the case of nuclear quantum dots in diamond based on ¹³C isotopes as the material of the substrate (D), the substrate (D) preferably comprises diamond and the nuclear quantum dot (CI) is preferably the nucleus of a ¹³C isotope. The quantum dot is then preferably a NV center or an ST1 center or an L2 center or other paramagnetic center, which is then preferably located in proximity to the ¹³C isotope. Here, proximity is again to be understood as meaning that the magnetic field of the nuclear spin of the ¹³C atom can influence the spin of the electron configuration of the NV center or the ST1 center or the L2 center or the other paramagnetic center in question, and that the spin of the electron configuration of the NV center or the ST1 center or the L2 center or the other paramagnetic center in question can influence the nuclear spin of said ¹³C isotope.

### Silicon

In the case of nuclear quantum dots in silicon based on ²⁹Si isotopes as the material of the substrate (D), the substrate (D) preferably comprises silicon and the nuclear quantum dot (CI) is preferably the atomic nucleus of a ²⁹Si isotope. The quantum dot is then preferably a G center or other paramagnetic center, which is then preferably located in proximity to the ²⁹Si isotope. Here, proximity is again to be understood as meaning that the magnetic field of the nuclear spin of the ²⁹Si atom can influence the spin of the electron configuration of the G center or the other paramagnetic center in question, and that the spin of the electron configuration of the G center or the other paramagnetic center can influence the nuclear spin of said ²⁹Si isotope.

### Silicon Carbide

In the case of nuclear quantum dots in silicon carbide based on ²⁹Si isotopes and ¹²C isotopes as the material of the substrate (D), the substrate (D) preferably comprises silicon carbide (²⁸Si¹²C) and the nuclear quantum dot (CI) is preferably the atomic nucleus of a ²⁹Si isotope or the atomic nucleus of a ¹³C isotope. The quantum dot (NV) is then preferably a V center or other paramagnetic center, which is then preferably located in the proximity of the ²⁹Si isotope or the ¹³C isotope. Here, proximity is again to be understood as meaning that the magnetic field of the nuclear spin of the ²⁹Si atom or the ¹³C atom can influence the spin of the electron configuration of the V center or the other paramagnetic center in question, and that the spin of the electron configuration of the V center or the other paramagnetic center can influence the nuclear spin of said ²⁹Si isotope or said ¹³C isotope

At this point it should be mentioned only for the sake of completeness that a nuclear spin is a nuclear spin with a nuclear spin magnitude greater than 0.

### Diamond

More generally, a nuclear quantum bit (CQUB) may be defined as a structure in which the substrate (D) comprises diamond and wherein the nuclear quantum dot (CI) is an isotope having a nuclear spin and wherein an NV center or an ST1 center or an L2 center or other paramagnetic center is located in proximity to the isotope having the nuclear spin and wherein proximity is also to be understood here as, that the magnetic field of the nuclear spin of the isotope can influence the spin of the electron configuration of the NV center and that the spin of the electron configuration of the NV center resp. of the ST1 center or the L2 center or the other paramagnetic center, respectively, can influence the nuclear spin of the isotope.

Multiple nuclear spins can also be used. The corresponding nuclear quantum bit (CQUB) is then defined such that the substrate (D) comprises diamond, wherein the nuclear quantum dot (CI) is an isotope with a magnetic moment μ and wherein at least one further nuclear quantum dot (CI′) is an isotope with a magnetic moment μ and wherein an NV center or an ST1 center or an L2-center or another paramagnetic center is arranged in the vicinity of the nuclear quantum dot (CI) and wherein the NV center or the ST1 center or the L2 center or the other paramagnetic center is arranged in the vicinity of the at least one further nuclear quantum dot (CI′) and wherein vicinity is to be understood here in such a way that the magnetic field of the nuclear quantum dot (CI) is such that the spin of the electron configuration of the NV center or of the ST1 center or of the L2 center or of the other paramagnetic center, respectively, and that the magnetic field of the at least one further nuclear quantum dot (CI′) can likewise influence the spin of the electron configuration of the NV center or of the ST1 center or of the L2 center or of the other paramagnetic center, respectively, and that the spin of the electron configuration of the NV center or of the ST1 center or the L2 center or the other paramagnetic center, respectively, can influence the nuclear spin of the nuclear quantum dot (CI) and that the spin of the electron configuration of the NV center or the ST1 center or the L2 center or the other paramagnetic center, respectively, can influence the nuclear spin of the at least one other nuclear quantum dot (CI′). This is a simple diamond-based quantum ALU (QUALU).

Preferably, the coupling strength between a nuclear quantum bit (CI, CI′) and the electron configuration of the NV center or the ST1 center or the L2 center or the other paramagnetic center is in a range from 1 kHz to 200 GHz and/or better 10 kHz to 20 GHz and/or better 100 kHz to 2 GHz and/or better 0.2 MHz to 1 GHz and/or better 0.5 MHz to 100 MHz and/or better 1 MHz to 50 MHz, in particular preferably 10 MHz.

Preferably, a quantum dot or a paramagnetic center (NV1), for example an NV center, with a charge carrier, in the case of the NV center with an electron, or with a charge carrier configuration, in the case of the NV center with an electron configuration, is located in the vicinity of the nuclear quantum dot (CI). The negative charge of the quantum dot (NV center), in the case of the NV, center as a quantum dot, results from the preferential sulfur doping of the diamond mentioned earlier. In the case of using quantum dot types other than NV centers in diamond, the charge carrier or charge carrier configuration, color center, i.e., quantum dot type, and doping of the substrate (D) or epitaxial layer (DEP1) can be adjusted accordingly. The charge carrier or charge carrier configuration—here exemplarily an electron or electron configuration—exhibit a charge carrier spin state. The nuclear quantum dot (CI) exhibits a nuclear spin state. The term “proximity” is to be understood here as meaning that the nuclear spin state can influence the charge carrier spin state and/or that the charge carrier spin state can influence the nuclear spin state.

### Silicon

More generally, a nuclear quantum bit (CQUB) may be defined as a structure in which the substrate (D) comprises silicon and in which the nuclear quantum dot (CI) is an isotope having a magnetic moment and in which a G center or other paramagnetic center is located in proximity to the isotope having the nonzero magnetic moment p and in which proximity is also to be understood here as meaning that the magnetic field of the nuclear spin of the isotope can influence the spin of the electron configuration of the G center and that the spin of the electron configuration of the G center or of the other paramagnetic center can influence the nuclear spin of the isotope.

Multiple isotopes with non-zero magnetic momentum can also be used. The corresponding nuclear quantum bit (CQUB) is then defined such that the substrate (D) comprises silicon, wherein the nuclear quantum dot (CI) is an isotope with a non-zero magnetic moment p and wherein at least one further nuclear quantum dot (CI′) is an isotope with a non-zero magnetic moment p and wherein a G-center or another paramagnetic center is arranged in the vicinity of the nuclear quantum dot (CI) and wherein the G-center or the other paramagnetic center is arranged in the vicinity of the at least one further nuclear quantum dot (CI′) and wherein vicinity is to be understood here as meaning that the magnetic field of the nuclear quantum dot (CI) is such that the spin of the electron configuration of the G-center or of the other paramagnetic center, respectively, and that the magnetic field of the at least one further nuclear quantum dot (CI′) can likewise influence the spin of the electron configuration of the G center or of the other paramagnetic center, respectively, and that the spin of the electron configuration of the G center or of the other paramagnetic center, respectively, can influence the nuclear spin of the nuclear quantum dot (CI) and that the spin of the electron configuration of the G center or the other paramagnetic center, respectively, can influence the nuclear spin of the at least one further nuclear quantum dot (CI′). This is a simple silicon-based quantum ALU (QUALU).

Preferably, the coupling strength between a nuclear quantum bit (CI, CI′) and the electron configuration of the G center or the other paramagnetic center is in a range from 1 kHz to 200 GHz and/or better 10 kHz to 20 GHz and/or better 100 kHz to 2 GHz and/or better 0.2 MHz to 1 GHz and/or better 0.5 MHz to 100 MHz and/or better 1 MHz to 50 MHz, in particular preferably 10 MHz.

Preferably, a quantum dot or a paramagnetic center (NV1), for example a G-center, with a charge carrier, in the case of the G-center with an electron, or with a charge carrier configuration, in the case of the G-center with an electron configuration, is arranged in the vicinity of the nuclear quantum dot (CI). The negative charge of the quantum dot (G-center) results in the case of the G-center as a quantum dot due to the preferred n-doping of the silicon mentioned earlier. In the case of using other quantum dot types than that of G-centers in diamond, charge carrier or charge carrier configuration, impurity center, i.e., quantum dot type, and doping of the substrate (D) or epitaxial layer (DEP1) can be adjusted accordingly. The charge carrier or charge carrier configuration—here exemplified by an electron or electron configuration—exhibits a charge carrier spin state. The nuclear quantum dot (CI) exhibits a nuclear spin state. The term “vicinity” is to be understood here as meaning that the nuclear spin state can influence the charge carrier spin state and/or that the charge carrier spin state can influence the nuclear spin state.

### Silicon Carbide

More generally, a nuclear quantum bit (CQUB) may be defined as a structure in which the substrate (D) comprises silicon carbide and in which the nuclear quantum dot (CI) is an isotope having a non-zero magnetic moment and a nuclear spin, and in which a V-center or other paramagnetic center is located in proximity to the isotope having the non-zero magnetic moment μ and the nuclear spin, and in which proximity is also understood here to mean, that the magnetic field of the nuclear spin of the isotope can influence the spin of the electron configuration of the V center and that the spin of the electron configuration of the V center or of the other paramagnetic center can influence the nuclear spin of the isotope.

Multiple nuclear spins can also be used. The corresponding nuclear quantum bit (CQUB) is then defined such that the substrate (D) comprises silicon carbide, wherein the nuclear quantum dot (C) is an isotope having a nuclear spin and a non-zero magnetic moment μ, and wherein at least one further nuclear quantum dot (CI′) is an isotope having a nuclear spin and a non-zero magnetic moment μ, and wherein a V-center or other paramagnetic center is arranged in the vicinity of the nuclear quantum dot (CI), and wherein the V-center or other paramagnetic center is arranged in the vicinity of the at least one further nuclear quantum dot (CI′), and wherein vicinity is to be understood here as meaning that the magnetic field of the nuclear quantum dot (CI) is such that the spin of the electron configuration of the V-center or of the other paramagnetic center, respectively, and that the magnetic field of the at least one further nuclear quantum dot (CI′) can also influence the spin of the electron configuration of the V center or the other paramagnetic center, respectively, and that the spin of the electron configuration of the V center or the other paramagnetic center, respectively, can influence the nuclear spin of the nuclear quantum dot (CI) and that the spin of the electron configuration of the V center or the other paramagnetic center, respectively, can influence the nuclear spin of the at least one further nuclear quantum dot (CI′). This is a simple silicon carbide-based quantum ALU (QUALU).

Preferably, the coupling strength between a nuclear quantum bit (CI, CI′) and the electron configuration of the V center or the other paramagnetic center is in a range from 1 kHz to 200 GHz and/or better 10 kHz to 20 GHz and/or better 100 kHz to 2 GHz and/or better 0.2 MHz to 1 GHz and/or better 0.5 MHz to 100 MHz and/or better 1 MHz to 50 MHz, in particular preferably 10 MHz.

Preferably, a quantum dot or a paramagnetic center (NV1), for example a V-center, with a charge carrier, in the case of the V-center with an electron, or with a charge carrier configuration, in the case of the V-center with an electron configuration, is arranged in the proximity of the nuclear quantum dot (CI). The negative charge of the quantum dot (V-center) results in the case of the V-center as a quantum dot due to the preferred n-doping of the silicon carbide material mentioned earlier. In the case of using other quantum dot types than that of V-centers in silicon carbide, charge carrier or charge carrier configuration, color center, i.e., quantum dot type, and doping of the substrate (D) or epitaxial layer (DEP1) can be adjusted accordingly. The charge carrier or charge carrier configuration—here exemplarily an electron or electron configuration—exhibit a charge carrier spin state. The nuclear quantum dot (CI) exhibits a nuclear spin state. The term “proximity” is to be understood here as meaning that the nuclear spin state can influence the charge carrier spin state and/or that the charge carrier spin state can influence the nuclear spin state.

### Epitaxial Diamond Layer on a Diamond Substrate (D)

The description presented here focuses on a quantum computer in which the substrate (D) comprises diamond without being limited to it. To prevent parasitic coupling between the NV centers or other impurity centers used and the nuclear spins of the substrate (D), it is useful if the diamond has an epitaxially grown isotopically pure layer of ¹²C isotopes. For the purposes of the present disclosure, isotopic purity exists when the fraction of ¹³C atoms in the 1 μm radius, better in the 0.5 μm radius, better in the 0.2 μm radius, better in the 0.1 μm radius, better in the 50 nm radius, better in the 20 nm radius around the NV center is less than 1%, better less than 0.1%, better less than 0.01%, better less than 0.001%. Here, such ¹³C isotopes that are themselves part of the quantum computer or are used in the operation of the quantum computer, or are intended for such use, are not counted and are counted as ¹²C isotopes, since this material quality consideration is concerned with minimizing unintended sources of interference to the operation of the quantum computer. To enable coupling of the nuclear quantum bit (CQUB) via a quantum bus (QBUS) described later, it is preferred if the substrate (D) is n-doped in the region of the nuclear quantum dot (CI). In the case of an NV center (NV) in diamond, this increases the likelihood that an NV center (NV) will indeed form at the predetermined location upon implantation of a nitrogen atom. Similar mechanisms take effect in the case of other substrates and centers. As described above, the substrate (D) is then preferably diamond and doped with sulfur in the region of the nuclear quantum dot (CI), and more preferably with nuclear spin-free sulfur, and more preferably with ³²S isotopes. Since the effect on the vacancies (English vacancies) is decisive here, which repel from each other by a negative charge, an effect is achieved here which reduces the agglomeration of the vacancies in the crystal. When using other isotopes or atoms to achieve this effect, it is important that the substrate (D) is doped with nuclear spin-free isotopes in the region of the nuclear quantum dot (CI) so that the quantum bits (QUB) and the nuclear quantum bit (CQUB) are not disturbed by additional interactions.

### Epitaxial Silicon Layer an a Silicon Substrate (D)

The description presented here also focuses on a quantum computer in which the substrate (D) comprises silicon without being limited to it, to prevent parasitic coupling between the G centers or other impurity centers used and the nuclear spins of the substrate (D), it is useful if the silicon of the substrate (D) has an epitaxially grown isotopically pure layer of ²⁸Si isotopes (DEP1). For the purposes of the present disclosure, isotopic purity exists when the fraction of ²⁹Si atoms in the 1 μm radius, better in the 0.5 μm radius, better in the 0.2 μm radius, better in the 0.1 μm radius, better in the 50 nm radius, better in the 20 nm radius around the G center is less than 1% better less than 0.1%, better less than 0.01%, better less than 0.001%. Here, such ²⁹Si isotopes that are pan of the quantum computer themselves as nuclear quantum dots (CI) or are used in the operation of the quantum computer or are intended for such use are not counted and are counted as ²⁸Si isotopes, since this quality consideration of the material concerned with minimizing unintended sources of interference to the operation of the quantum computer. To enable coupling of the nuclear quantum bit (CQUB) via a quantum bus (QBUS) described later, it is preferred if the substrate (D) is suitably doped in the region of the nuclear quantum dot (CI). In the case of a G-center as a quantum dot (NV) in silicon, this increases the probability that a G-center (NV) will indeed form at the predetermined location upon implantation of a carbon atom. As described above, the substrate (D) is then preferably silicon and in the region of the nuclear quantum dot (CI) doped with sulfur, and more preferably with nuclear spin-free sulfur, and more preferably with isotopes. If other isotopes or atoms are used to achieve this effect, it is important that the substrate (D) is doped with nuclear spin-free isotopes in the region of the nuclear quantum dot (CI) so that the quantum bits (QUB) and the nuclear quantum bit (CQUB) are not disturbed by additional interactions.

### Nuclear Quantum Dot Arrangement

Preferably, the nuclear quantum bit (CQUB) is constructed in such a way that at least one of its nuclear quantum dots (CI) is located at a first nucleus spacing (d1′) along the perpendicular line (LOT) under the surface (OF) of the substrate (D) and/or the epitaxial layer (DEP1), if present. This first nucleus spacing (d1′) is preferably 2 nm to 60 nm and/or more preferably 5 nm to 30 nm and/or more preferably 10 nm to 20 nm, whereby in particular a first nucleus spacing (d1′) of 5 nm to 30 nm is very particularly preferred and should be aimed for.

The control of the nuclear quantum bit (CQUB) can now be done in an analogous way as the control of the quantum bits (QUB). However, the frequency of the current pulses is lower because the nuclei of the nuclear quantum dots (CI) have a larger mass.

A nuclear quantum bit (CQUB) according to the disclosure therefore preferably again comprises a horizontal line (LH, LH1), which is preferably again part of a microstrip line and/or pan of a tri-plate line, and/or a vertical line (LV, LV1), which is also preferably again part of a microstrip line and/or part of a tri-plate line (SV1, LH, SV2).

The vertical microstrip line of the nuclear quantum bit (CQUB) again preferably comprises a first vertical shield line (SV1) and the vertical line (LV). The horizontal microstrip line again preferably comprises a first horizontal shield line (SH1) and the horizontal line (LH).

In an analogous manner, a vertical tri-plate line preferably comprises a first vertical shield line (SV1) and a second vertical shield line (SV2) and the vertical line (LV) extending between the first vertical shield line (SV1) and the second vertical shield line (SV2). A horizontal tri-plate line preferably again comprises a first horizontal shield line (SH1) and a second horizontal shield line (SH2) and the horizontal line (LV) running between the first horizontal shield line (SH1) and the second horizontal shield line (SH2).

As in the case of the previously described quantum bit (QUB), the controlling device of the nuclear quantum bit (CQUB) discussed here is preferably designed such that the sum of the currents through the tri-plate line (SV1, LV, SV2) is zero. This, like the quantum bit (QUB) before, confines the magnetic flux density field to the region in the immediate vicinity of the tri-plate line. The nuclear quantum dot (CI) should be located in this region in order to be directly influenced.

As in the case of the quantum register (QUREG) consisting of a compilation of several quantum bits (QUB) to be described later, the current feeding of all lines of the nuclear quantum bits (CQUB) of a nuclear quantum register (CQUREG) consisting of a composition of several nuclear quantum bits (CQUB) to be described later can be designed in such a way that the magnetic flux density B caused by the current feeding of the horizontal and vertical lines is essentially different from zero only at the location of a nuclear quantum dot (CI). In this case, the current feeding of the shield lines is preferably selected such that the magnetic flux density B under the crossing points additionally created by the insertion of the shield lines is also essentially zero at a depth in the substrate (D) corresponding to said first distance (d1). For this purpose, a first further virtual vertical plumb line may be precipitated along a first further vertical perpendicular line (VLOT1) parallel to the first perpendicular line (LOT) from the location of a first virtual vertical nuclear quantum dot (VVCI1) to the surface (OF) of the substrate (D) and/or the epitaxial layer (DEP1), if present. The first virtual vertical nuclear quantum dot (VVCI1) is located at the first distance (d1) from the surface (OF). The first further vertical perpendicular line (VLOT1) virtually pierces the surface (OF) of the substrate (D) and/or the epitaxial layer (DEP1), if any, at a rust further vertical perpendicular point (VLOTP1). The horizontal line (LH) and the first vertical shield line (SV1) are preferably located on the surface of the substrate (D) and/or the epitaxial layer (DEP1), if present. They cross each other and near the first vertical perpendicular point (VLOTP1) or at the first vertical plumb point (VLOTP1) at the non-zero crossing angle (a). A second further virtual vertical plumb line along a second further vertical perpendicular line (VLOT2) may be precipitated parallel to the first perpendicular line (LOT) from the location of a second virtual vertical nuclear quantum dot (VVCI2) to the surface (OF) of the substrate (D) and/or the epitaxial layer (DEP1), if present. The second virtual vertical nuclear quantum dot (VVCI2) is also located at the first distance (d1) from the surface (OF). The second further vertical perpendicular line (VLOT2) again penetrates the surface (OF) of the substrate (D) and/or the epitaxial layer (DEP1), if present, at a second further vertical perpendicular point (VLOTP2). The horizontal line (LH) and the second vertical shield line (SV2) are also located on the surface of the substrate (D) and/or the epitaxial layer (DEP1), if present. The horizontal line (LH) and the second vertical shield line (SV2) cross again near the second vertical perpendicular point (VLOTP2) or at the second vertical perpendicular point (VLOTP2) at the non-zero crossing angle (α). As before, the individual currents (ISV1, IV, ISV2) through the individual lines (SV1, LV, SV2) of the tri-plate line are preferably selected, so that the magnitude of the first virtual vertical magnetic flux density vector (B_{VVCH}) at the location of the first virtual vertical nuclear quantum dot (VVCI1) is nearly zero and that the magnitude of the second virtual vertical magnetic flux density vector (B_{VVCI2}) at the location of the second virtual vertical nuclear quantum dot (VVCI2) is nearly zero and that the magnitude of the magnetic flux density vector (B_{CI}) at the location of the nuclear quantum dot (CI) is different from zero.

We imagine a two-dimensionally arranged nuclear quantum register (CQUREG) with m columns and n rows. Let the nuclear quantum register (CQUREG) contain n×m nuclear quantum bits with 1 nuclear quantum dot (CI) per nuclear quantum bit (CQUB) assumed here in a simplified way. Let the nuclear quantum register (CQUREG) be organized in such a way that the m nuclear quantum bits (CQUBi1 to CQUBim) of an i-th row of the nuclear quantum register (CQUREG), have in common with 1≤i≤n the horizontal line (LHi) and that the n nuclear quantum bits (CQUBlj to CQUBnj) of a j-th column of the nuclear quantum register (CQUREG), have in common with 1≤j≤m the vertical line (LVj).

Each nuclear quantum bit (CQUBij) of the n×m nuclear quantum bits (CQUB) of the nuclear quantum register (CQUREG) has a nuclear quantum dot (Clij) with an associated local magnetic flux density (Bij) at the location of the nuclear quantum dot (Clij). These associated local magnetic flux densities (Bij) at the locations of the nuclear quantum dots (Clij) form a magnetic flux density vector, to generate a predetermined magnetic flux density vector, an individual current signal must now be injected in to each of the lines. These current signals together form a vector current signal. The dimension of this current density vector grows only linearly with the sum of the number of rows n and columns m. In contrast, the number of nuclear quantum dots grows proportionally to the product of the number of columns m and rows n. It is easy to understand that therefore a nuclear quantum register (CQUREG) is preferably fabricated as a one-dimensional array of nuclear quantum bits (CQUREG) with nuclear quantum dots (CI).

This result can be applied to the previously introduced quantum bits (QUB).

In an analogous way, we imagine a two-dimensionally arranged quantum register (QUREG) with m columns and n rows. The quantum register (QUREG) contains in analogous manner n×m quantum bits (QUBij) with here simplified assumed 1 quantum dot (NVij) per nuclear quantum bit (QUBij). Let the quantum register (QUREG) again be organized in such a way that them quantum bits (QUBi1 to QUBim) of an i-th row of the quantum register (QUREG), have in common with 1≤i≤n the horizontal line (LHi) and that the n quantum bits (QUBlj to QUBnj) of a j-th column of the quantum register (QUREG), have in common with 1≤j≤m the vertical line (LVj).

Each quantum bit (QUBij) of the n×m nuclear quantum bits (CQUB) of the nuclear quantum register (CQUREG) has a quantum dot (NVj) with an associated local magnetic flux density (Bij) at the location of the quantum dot (NVij). These associated local magnetic flux densities (Bij) at the quantum dot (NVij) locations form a magnetic flux density vector. To generate a predetermined magnetic flux density vector, an individual current signal must now be injected into each of the lines. These current signals together form a vector current signal. The dimension of this current density vector also grows only linearly with the sum of the number of lines n and columns m. In contrast, the number of quantum dots grows proportionally to the product of the number of columns m and lines n. It is easy to understand that therefore a quantum register (QUREG) is preferably fabricated as a one-dimensional array of quantum bits (NV) with quantum dots (NV).

We return to the nuclear quantum bit (CQUB) described earlier.

Preferably, a first further virtual horizontal perpendicular line can be precipitated along a first further horizontal perpendicular line (HLOT1) parallel to the first perpendicular line (LOT) from the location of a first virtual horizontal nuclear quantum dot (VHCI1) to the surface (OF) of the substrate (D) and/or the epitaxial layer (DEP1), if present. The first virtual horizontal nuclear quantum dot (VHCIV1) is preferably located at the first distance (d1) from the surface (OF). The first further horizontal perpendicular line (HLOT1) again pierces the surface (OF) of the substrate (D) and/or the epitaxial layer (DEP1), if present, at a first further horizontal perpendicular point (HLOTP1). The vertical line (LV) and the first horizontal shield line (SH1) are again preferably located on the surface of the substrate (D) and/or the epitaxial layer (DEP1), if present. The vertical line (LV) and the first horizontal shield line (SH1) again preferably cross near the first horizontal perpendicular point (HLOTP1) or at the first horizontal plumb point (HLOTP1) at the non-zero crossing angle (α). A second further virtual horizontal perpendicular line may be precipitated along a second further horizontal perpendicular line (HLOT2) parallel to the first perpendicular line (LOT) from the location of a second virtual horizontal nuclear quantum dot (VHCOI2) to the surface (OF) of the substrate (D) and/or the epitaxial layer (DEP1), if present. The second virtual horizontal nuclear quantum dot (VHCI2) is preferably located at the first distance (d1) from the surface (OF). The second further horizontal perpendicular line (HLOT2) again preferably pierces the surface (OF) of the substrate (D) and/or the epitaxial layer (DEP1), if present, at a second further horizontal perpendicular point (HLOTP2). The vertical line (LV) and the second horizontal shield line (SH2) are thereby also preferably located on the surface of the substrate (D) and/or the epitaxial layer (DEP1), if present. The vertical line (LV) and the second horizontal shield line (SH2) cross each other in an analogous manner preferably in the vicinity of the second horizontal perpendicular point (HLOTP2) or at the second horizontal perpendicular point (HLOTP2) at the non-zero crossing angle (α). Again, the individual currents (ISH1, IH, ISH2) through the individual lines (SH1, LH, SH2) of the tri-plate line are preferably selected, that the magnitude of the first virtual horizontal magnetic flux density vector (B_{VHCH}) at the location of the first virtual horizontal nuclear quantum dot (VHCI1) is nearly zero and that the magnitude of the second virtual horizontal magnetic flux density vector (B_{VHCI2}) at the location of the second virtual horizontal quantum dot (VHCI2) is nearly zero and that the magnitude of the magnetic flux density vector (B_{NV}) at the location of the nuclear quantum dot (CI) is different from zero.

In order to be able to extract generated photoelectrons, in the region or in the vicinity of the perpendicular point (LOTP) the substrate (D) is connected to the first horizontal shield line (SH1) by means of at least one first horizontal ohmic contact (KH11). Furthermore, preferably in the region or in the vicinity of the perpendicular point (LOTP), the substrate (D) is connected to the second horizontal shield line (SH2) by means of at least one second horizontal ohmic contact (KHI2). Furthermore, preferably in the region or in the proximity of the perpendicular point (LOTP), the substrate (D) is connected to the first vertical shield line (SV1) by means of at least one first vertical ohmic contact (KV11). Finally, preferably in the region or in the vicinity of the perpendicular point (LOTP), the substrate (D) is connected to the second vertical shield line (SV2) by means of at least one second vertical ohmic contact (KVI2).

Preferably, such ohmic contacts (KV11, KV12, KH11, KH12) comprise titanium.

Register Constructions According to the Disclosure

Construction of a Quantum Register (CEQUREG) from a Quantum Dot (CI)

The basic nucleus-electron quantum register (CEQUREG), hinted at earlier, includes a nuclear quantum bit (CQUB) and a quantum bit (QUB).

The general nucleus-electron quantum register (CEQUREG) includes at least one nuclear quantum bit (CQUB) and at least one quantum bit (QUB).

In the following, a nucleus-electron quantum register (CEQUREG) comprising n but at least two nuclear quantum bits (CQUB1 to CQUBn) and one quantum bit (QUB) is referred to as a quantum ALU (QUALU).

The device for controlling a nuclear quantum dot (CI) of the nuclear quantum bit (CQUB) of the nucleus-electron quantum register (CEQUREG) preferably comprises a sub-device (LH, LV), which is preferably also a sub-device (LH, LV) of the device for controlling the quantum dot (NV) of the quantum bit (QUB) of the nucleus-electron quantum register (CEQUREG).

The nucleus-electron quantum register (CEQUREG) according to the disclosure therefore comprises a device for controlling the nuclear quantum dot (CI) of the nuclear quantum bit (CQUB) of the nucleus-electron quantum register (CEQUREG) and for simultaneously controlling the quantum dot (NV) of the quantum bit (QUB) of the nucleus-electron quantum register (CEQUREG), comprising a common substrate (D) of the nuclear quantum bit (CQUB) and of the quantum bit (QUB) and optionally comprising a common epitaxial layer (DEP1) of the nuclear quantum bit (CQUB) and the quantum bit (QUB) and comprising a common device of the nuclear quantum bit (CQUB) and the quantum bit (QUB) suitable for generating an electromagnetic wave field (B_{RW}, B_{MW}) at the site of the nuclear quantum dot (CI) and at the site of the quantum dot (CI). The common epitaxial layer (DEP1), if present, is preferably deposited on the common substrate (D). If applicable, the nuclear quantum dots (CI) are deposited together with the epitaxial layer (DEP1). The common substrate (D) and/or the common epitaxial layer (DEP1), if present, has a surface (OF). The nuclear quantum dot (CI) typically exhibits a magnetic moment. The quantum dot (NV) is preferably a paramagnetic center in the common substrate (D) and/or in the common epitaxial layer (DER), if present.

### Quantum Dots

In particular, the quantum dot (NV) may again be an NV center in diamond or an ST1 center or an L2 center or other paramagnetic impurity center if diamond is used.

In particular, the quantum dot (NV) may again be a G-center in silicon or another paramagnetic impurity center if silicon is used.

In particular, the quantum dot (NV) may again be a V-center in silicon carbide or another paramagnetic impurity center if silicon carbide is used.

### Control Device

The common device suitable for generating an electromagnetic wave field (B_{RW}, B_{MW}) and preferably for controlling the nuclear quantum dots (CI) and the quantum dot identical, is again preferably located on the surface of the common substrate (D) and/or the common epitaxial layer (DEP1), if present.

Preferably, the device comprising horizontal lines and vertical lines is suitable for generating a circularly polarized electromagnetic wave field (B_{RW}, B_{MW}). This can be achieved in the horizontal line (LH) and the vertical line (LV) by the fact that the current in the horizontal line (LH) has a horizontal current component with a frequency and that the current in the vertical line (LV) has a vertical current component with this frequency. Thereby, the vertical current component in the vertical line (LV) is preferably shifted by +/−90° with respect to the horizontal current component in the horizontal line (LH). The components of the magnetic flux density of the magnetic field generated by these current components then overlap in the region of the nuclear quantum dots) (CI) or quantum dot (NV) in such a way that a left- or right-hand circularly polarized magnetic field results there.

Similarly, as before in the case of the nuclear quantum bit (CQUB) or the quantum bit (QUB), a virtual plumb line can now again be precipitated along a virtual perpendicular line (LOT) from the location of the nuclear quantum dot (CI) and/or from the location of the quantum dot (NV) to the surface (OF) of the substrate (D) and/or the epitaxial layer (DEP), if present. The virtual plumb line (LOT) again pierces the surface (OF) of the substrate (D) and/or the epitaxial layer (DEP1), if present, at a plumb point (LOTP). As before, the device suitable for generating a circularly polarized electromagnetic wave field, in particular a radio and/or microwave field, is preferably located in the proximity of the plumb point (LOTP) or at the plumb point (LOTP).

Thus, a proposed nucleus-electron quantum register (CEQUREG) preferably comprises a horizontal line (LH) and a vertical line (LV) as a device suitable for generating a circularly polarized electromagnetic wave field, in particular a radio and/or microwave field.

As before, the horizontal line (LH) and the vertical line (LV) are preferably located on the surface of the substrate (D) and/or the epitaxial layer (DEP1), if present. Preferably, the horizontal line (LH) and the vertical line (LV) cross near the virtual plumb point (LOTP) or at the plumb point (LOTP) at a non-zero crossing angle (α). Preferably, the horizontal line (LH) is sufficiently electrically isolated from the vertical line (LV) by means of electrical insulation (IS).

If the “green light” for resetting the quantum dots is not irradiated from the bottom side (US), the horizontal line (LH) and/or the vertical line (LV) should be transparent to “green light”. Preferably, the horizontal line (LH) and/or the vertical line (LV) should be made of an electrically conductive material that is optically transparent to green light, in particular of indium tin oxide (commonly abbreviated to ITO).

Preferably, the angle (α) is essentially a right angle.

Preferably, the substrate (D) of the nucleus-electron quantum register (CEQUREG) comprises diamond.

### Diamond

Preferably, the material of the substrate (D) is isotopically pure diamond of 12C isotopes that do not exhibit a nucleus magnetic spin. In that case, in a preferred variant, the nuclear quantum dot (CI) is the atomic nucleus of a 13C isotope, which then, in contrast to most other 12C atoms of the substrate (D), has a nucleus magnetic spin and thus a non-zero magnetic moment μ and can thus interact with the quantum dot, for example with an NV center. For this purpose, the quantum dot (NV) should be located in the proximity of the 13C isotope, which is a nuclear quantum dot (CI). As mentioned, the quantum dot (NV) is preferably an NV center. Again, the use of ST1 and L2 centers or other paramagnetic impurity centers is also conceivable. The term “proximity” here is to be understood as meaning that the magnetic field of the nuclear spin of the 13C atom can influence the spin of an electron configuration of the quantum dot (NV), for example the electron configuration of a NV center (NV), and that the spin of an electron configuration of the quantum dot (NV) can influence the nuclear spin of the 13C isotope, in particular via a dipole-dipole interaction.

### Silicon

Preferably, the material of the substrate (D) is isotopically pure silicon of ²⁸Si isotopes that do not exhibit nucleus magnetic spin. In that case, in a preferred variant, the nuclear quantum dot (CI) is the atomic nucleus of a ²⁹Si isotope, which then, in contrast to most other ²⁸Si atoms of the substrate (D), has a magnetic nuclear spin and thus a non-zero magnetic moment μ and thus can interact with the quantum dot (NV), for example with a G center. For this, the quantum dot (NV) should be located in the proximity of the ²⁹Si isotope, which is a nuclear quantum dot (CI). As mentioned, the quantum dot (NV) is preferably a G center. Again, the use of other paramagnetic impurity centers is also conceivable. The semi “proximity” here is to be understood as meaning that the magnetic field of the nuclear spin of the ²⁹Si atom can influence the spin of an electron configuration of the quantum dot (NV), i.e., for example, the electron configuration of a G center, and that the spin of an electron configuration of the quantum dot (NV) can influence the nuclear spin of the ²⁹Si isotope, in particular via a dipole-dipole interaction.

### Silicon Carbide

Preferably, the material of the substrate (D) is isotopically pure silicon carbide of ²⁸Si isotopes and ¹²C isotopes, both of which have no nucleus magnetic spin. In that case, in a preferred variant, the nuclear quantum dot (CI) is the nucleus of a ²⁹Si isotope or the nucleus of a DC isotope, which then, unlike most of the other ²⁸Si atoms and ¹²C atoms of substrate (D), has a nucleus magnetic spin and thus can have a nonzero magnetic moment μ and thus interact with the quantum dot (NV), for example with a V center. For this purpose, the quantum dot (NV) should be located near the ²⁹Si isotope or near the ¹³C isotope, which is a nuclear quantum dot (CI). As mentioned, the quantum dot (NV) is preferably a V center. Again, the use of other paramagnetic impurity centers is also conceivable. The term “proximity” here is to be understood in such a way that the magnetic field of the nuclear spin of the ²⁹Si atom or of the ¹³C atom can influence the spin of an electron configuration of the quantum dot (NV), i.e., for example, the electron configuration of a V center, and that the spin of an electron configuration of the quantum dot (NV) can influence the nuclear spin of the ²⁹Si isotope or of the ¹³C isotope, in particular via a dipole-dipole interaction.

More generally, the nucleus-electron quantum register (CEQUREG) may have a quantum dot (NV) in which the quantum dot (NV) is a paramagnetic center with a charge carrier or charge carrier configuration and is located near the nuclear quantum dot (CI). In this case, the charge carrier or charge carrier configuration exhibits a charge carrier spin state. The nuclear quantum dot (CI) exhibits a nuclear spin state. The term “proximity” in this context, as above, is to be understood here as meaning that the nuclear spin state can influence the charge carrier spin state and/or, conversely, that the charge carrier spin state can influence the nuclear spin state. Preferably, the frequency range of the coupling strength is at least 1 kHz and/or more preferably at least 1 MHz and less than 20 MHz. In other words, preferably the frequency range of the coupling strength is 1 kHz to 200 GHz and/or better 10 kHz to 20 GHz and/or better 100 kHz to 2 GHz and/or better 0.2 MHz to 1 GHz and/or better 0.5 MHz to 100 MHz and/or better 1 MHz to 50 MHz, especially preferably about 10 MHz.

### Construction of a Quantum Alu

Now that the terms quantum bit (QUB), nuclear quantum bit (CQUB), quantum register (QUREG) and nuclear quantum register (CQUREG) and nucleus-electron quantum register (CEQUREG) have been described, the first quantum computer component will be defined. It will be called quantum ALU (QUALU) in the following. It has a first quantum dot (NV), in the case of diamond as the material of the substrate (D), for example, an NV center (NV), or in the case of silicon as the material of the substrate (D), for example, a G center, or in the case of silicon carbide as the material of the substrate (D), for example, a V center, which serves as a terminal, so to speak, for the standard block “quantum ALU (QUALU)”. This terminal can then be coupled to another quantum dot (NV) of another quantum ALU (QUALU) via an overlapping chain of quantum registers (QUREG) of at least two quantum dots (NV). This other quantum ALU (QUALU) may be spaced so far away from the first quantum ALU that the nuclear quantum dots of the first quantum ALU do not couple directly with the nuclear quantum dots of the second quantum ALU. This coupling can be done only with the help of the overlapping chain of quantum registers (QUREG), whose quantum dots (NV) as ancilla bits allow indirect coupling of the nuclear quantum dots of the first quantum ALU with the nuclear quantum dots of the second quantum ALU (QUALU). Thus, in the architecture proposed here, the overlapping chain of quantum registers (QUREG) plays the role of a quantum bus (QUBUS) analogous to a data bus in a normal microcomputer. However, it is not data that is transported over this quantum bus (QUBUS), but dependencies. The actual computations are then performed in the respective quantum ALUs (QUALU), which are connected to the quantum bus (QUBUS) via their quantum dots (NV). This is the basic idea of the quantum computer presented here. It is a combination of quantum ALUs consisting of nucleus-electron quantum registers (CEQUREG) connected via quantum buses (QUBUS) consisting of quantum registers (QUREG) in a wide variety of topologies.

Such a quantum ALU (QUALU) therefore preferably comprises a first nuclear quantum bit (CQUB1) and typically at least a second nuclear quantum bit (CQUB2). Preferably, such a quantum ALU (QUALU) has a massively higher number p of nuclear quantum bits (CQUB1 to CQUBp). Since the distances from the respective nuclear quantum dot (CIj) of the j-th nucleus-electron quantum register (CEQUREGj) of the p nucleus-electron quantum registers (CEQUREG1 to CEQUREGp) of the quantum ALU (QUALU) to the preferably common quantum dot (NV) of the p nucleus-electron quantum registers (CEQUREG1 to CEQUREGp) are usually different, the coupling strengths and thus the electron-nucleus resonance frequencies and the nucleus-electron resonance frequencies explained below are different for the respective nucleus-electron quantum registers (CEQUREGj) (1≤j≤p) of the p nucleus-electron quantum registers (CEQUREG1 to CEQUREGp). Thus, addressing of the individual nucleus-electron quantum dots (CIj) of the p nucleus-electron quantum dots (CI1 to CIp) of the quantum ALU (QUALU) is possible by means of these different nucleus-electron resonance frequencies and electron-nucleus resonance frequencies.

Thus, a quantum ALU (QUALU) preferably comprises a quantum bit (QUB) that forms a first nucleus-electron quantum register (CEQUREG1) with the first nuclear quantum bit (CQUB1) and forms a second nucleus-electron quantum register (CEQUREG2) with the second nuclear quantum bit (CQUB2).

Particularly preferably, the device for controlling the first nuclear quantum dot (CI1) of the first nuclear quantum bit (CQUB1) of the first nucleus-electron quantum register (CEQUREG1) has a sub-device (LH, LV) which is also the sub-device (LH, LV) of the device for controlling the quantum dot (NV) of the quantum bit (QUB) of the first nucleus-electron quantum register (CEQUREG1) and which is also the device for controlling the second nuclear quantum dot (CI2) of the second nuclear quantum bit (CQUB2) of the second nucleus-electron quantum register (CEQUREG2).

### Construction of a Homogeneous Quantum Register (QUREG)

A homogeneous quantum register (QUREG) or in short only quantum register (QUREG) comprises only quantum dots (NV) of one quantum dot type. Such a quantum register preferably comprises a first quantum bit (QUB1) and at least one second quantum bit (QUB2). A chain of such quantum registers (QUB) is the essential part of the quantum bus (QUBUS) explained below, which allows the transport of dependencies. According to the proposal, the property of homogeneity of the quantum register (QUREG) is expressed such that the first quantum dot type of the first quantum dot (NV1) of the first quantum bit (QUB1) of the quantum register (QUREG) is equal to the second quantum dot type of the second quantum dot (NV2) of the second quantum bit (QUB2) of the quantum register (QUREG). For example, the first quantum dot type may be an NV center in diamond as the substrate and the second quantum dot type may also be an NV center in the same substrate. For example, in an analogous manner, the first quantum dot type may be a G center in silicon as the material of the substrate (D) and the second quantum dot type may also be a G center in the same substrate (D). For example, in an analogous manner, the first quantum dot type may be a V-center in silicon carbide as the material of the substrate (D) and the second quantum dot type may also be a V-center in the same substrate (D)

Typically, the substrate (D) is common to the first quantum bit (QUB1) of the quantum register (QUREG) and the second quantum bit (QUB2) of the quantum register (QUREG). In the following, for better clarity, the quantum dot (NV) of the first quantum bit (QUB1) of the quantum register (QUREG) is called the first quantum dot (NV1) and the quantum dot (NV) of the second quantum bit (QUB2) of the quantum register (QUREG) is called the second quantum dot (NV2). Similarly, for clarity, in the following, the horizontal line (LH) of the first quantum bit (QUB1) of the quantum register (QUREG) will be referred to as the first horizontal line (LH1) and the horizontal line (LH) of the second quantum bit (QUB2) of the quantum register (QUREG) will be referred to as the second horizontal line (LH2). Similarly, the vertical line (LV) of the first quantum bit (QUB1) is hereinafter referred to as the first vertical line (LV1) and the vertical line (LV) of the second quantum bit (QUB2) is hereinafter referred to as the second vertical line (LV2). It is useful if, for example, the first horizontal line (LH1) is identical to the second horizontal line (LH2). Alternatively, it is useful if, for example, the first vertical line (LV1) is identical to the second vertical line (LV2).

Preferably, the first horizontal line (LH1) and the second horizontal line (LH2) and the first vertical line (LV) and the second vertical line are essentially made of isotopes without magnetic moment μ. In this case, essentially means that the total fraction K1G of isotopes with magnetic moment of an element which is a component of one or more of the lines, with respect to 100% of this element which is a component of these lines, is reduced with respect to the natural total fraction K1G indicated in the above tables to a fraction K1G′ of isotopes with magnetic moment of an element which is a component of one or more of these lines, with respect to 100% of this element which is a component of one or more of these lines. Whereby this fraction K1G′ is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K1G for the element in question of one or more of the lines in the region of influence of the paramagnetic perturbations (NV) used as quantum dots (NV) and/or of the nuclear spins used as nuclear quantum dots (CI).

The quantum register (QUREG) should be built small enough to fulfill its intended function, that the magnetic field of the second quantum dot (NV2) of the second quantum bit (QUB2) of the quantum register (QUREG) influences the behavior of the first quantum dot (NV1) of the first quantum bit (QUB1) of the quantum register (QUREG) at least temporarily and/or that the magnetic field of the first quantum dot (NV1) of the first quantum bit (QUB1) influences the behavior of the second quantum dot (NV2) of the second quantum bit (QUB2) at least temporarily.

Preferably, the spatial distance (sp12) between the first quantum dot (NV1) of the first quantum bit (QUB1) of the quantum register (QUREG) and the second quantum dot (NV2) of the second quantum bit (QUB2) of the quantum register (QUREG) is so small for this purpose, that the magnetic field of the second quantum dot (NV2) of the second quantum bit (QUB2) of the quantum register (QUREG) influences the behavior of the first quantum dot (NV1) of the first quantum bit (QUB1) of the quantum register (QUREG) at least temporarily, and/or in that the magnetic field of the first quantum dot (NV1) of the first quantum bit (QUB1) of the quantum register (QUREG) influences the behavior of the second quantum dot (NV2) of the second quantum bit (QUB2) of the quantum register (QUREG) at least temporarily.

Preferably, for this purpose the second distance (sp12) between the first quantum dot (NV1) of the first quantum bit (QUB1) of the quantum register (QUREG) and the second quantum dot (NV2) of the second quantum bit (QUB2) of the quantum register (QUREG) is less than 50 nm and/or less than 30 nm and/or less than 20 nm and/or less than 10 nm and/or less than 10 nm and/or less than 5 nm and/or less than 2 nm, and/or the second distance (sp12) between the first quantum dot (NV1) of the first quantum bit (QUB1) of the quantum register (QUREG) and the second quantum dot (NV2) of the second quantum bit (QUB2) of the quantum register (QUREG) is between 30 nm and 2 nm and/or less than 10 nm and/or less than 3 nm and/or less than 2 nm.

Such a quantum register can be concatenated. The two-bit quantum register described above was strung along the horizontal line (LH) common to the two quantum bits (QUB1, QUB2). Instead of horizontal stringing, vertical stringing along the vertical line is equally conceivable. The horizontal and the vertical line then exchange the function. A two-dimensional stringing together is also conceivable, which corresponds to a combination of these possibilities.

Instead of a two-bit quantum register (QUREG), the stringing together of n quantum bits (QUB1 to QUBn) is also conceivable. As an example, a three-bit quantum register is described here, which is continued along the horizontal line (LH) as an example. For the following quantum bits (QUB4 to QUBn) the same applies. The quantum register can of course be extended in the other direction by m quantum bits (QUB to QUB(m−1)). To simplify the description, the text presented here is limited to positive values of the indices from 1 to n.

By an exemplary linear concatenation of the n quantum bits (QUB1 to QUBn) along an exemplary one-dimensional line within an n-bit quantum register (QUREG), for example along said vertical line (LV) or along said horizontal line (LH), the spatial distance (spin) between the first quantum dot (NV1) of the first quantum bit (QUB1) of the n-bit quantum register (QUREG) and the n-th quantum dot (NVn) of the n-th quantum bit (QUBn) of the n-bit quantum register (QUREG) can be so large, that the first quantum dot (NV1) of the first quantum bit (QUB1) of the n-bit quantum register (QUREG) is no longer coupled with the n-th quantum dot (NVn) of the n-th quantum bit (QUBn) of the n-bit quantum register (QUREG) or can be directly entangled. For simplicity, we assume that the n quantum dots (NV1 to NVn) of the n quantum bits (QUB1 to QUBn) are countably lined up along the said one-dimensional line. This one-dimensional line can also be curved or angular. Thus, the n quantum dots (NV1 to NVn) and hence their respective quantum bits (QUB1 to QUBn) in this example are said to represent a chain of n quantum dots (NV1 to NVn) starting with the first quantum dot (NV1) and ending with the n-th quantum dot (NVn). Within this chain of n quantum dots (NV1 to NVn), the quantum dots (NV1 to NVn) and thus also the quantum bits (QUB1 to QUBn) are countable and can thus be numbered consecutively from 1 to n with whole positive numbers.

Thus, within the chain, a (j−1)-th quantum dot (NVj) is preceded by a (j−1)-th quantum dot (NV(j−1)), which will be called the predecessor quantum dot (NV(j−1)) in the following. Thus, within the chain, a (j−1)-th quantum bit (QUB(j−1)) with the (j−1)-th quantum dot (NV(j−1)) precedes a (j−1)-th quantum bit (QUB(j−1)) with the (j−1)-th quantum dot (NV(j−1)), which is called the predecessor quantum bit (QUB(j−1)) in the following.

Thus, within the chain a j-th quantum dot (NVj) is followed by a (j+1)-th quantum dot (NV(j+1)) which is called the successor quantum dot (NV(j+1)) in the following. Thus, within the chain, a (j+1)-th quantum bit (QUB(j+1)) with the (j+1)-th quantum dot (NVj) is followed by a (j+1)-th quantum bit (QUB(j+1)) with the (j+1)-th quantum dot (NV(j+1)), which is called the successor quantum bit (QUB(j−1)) in the following. Here, the index j with respect to this exemplary chain shall be here any integer positive number with 1<j<n, where n shall be an integer positive number with n>2.

Within the chain, the j-th quantum dot (NVj) then has a distance (sp(j−1)j), its predecessor distance. Preferably, this spatial distance (sp(j−1)j) between the j-th quantum dot (NVj) of the j-th quantum bit (QUBj) of the quantum register (QUREG) and the preceding (j−1)-th quantum dot (NV(j−1)) of the (j−1)-th quantum bit (QUB(j−1)) of the quantum register (QUREG) is so small, that the magnetic field of the preceding (j−1)-th quantum dot (NV(j−1)) of the (j−1)-th quantum bit (QUB(j−1)) of the n-bit quantum register (QUREG) influences the behavior of the j-th quantum dot (NVj) of the j-th quantum bit (QUBj) of the n-bit quantum register (QUREG) at least temporarily, and/or in that the magnetic field of the j-th quantum dot (NVj) of the j-th quantum bit (QUBj) of the n-bit quantum register (QUREG) influences the behavior of the preceding (j−1)-th quantum dot (NV(j−1)) of the (j−1)-th quantum bit (QUB(j−1)) of the quantum register (QUREG) at least temporarily. Preferably, the distance (sp(j−1)1) between the j-th quantum dot (NVj) of the j-th quantum bit (QUBj) of the n-bit quantum register (QUREG) and the preceding (j−1)-th quantum dot (NV(j−1)) of the (j−1)-th quantum bit (QUB(j−1)) of the n-bit quantum register (QUREG) is less than 50 nm and/or less than 30 nm and/or less than 20 nm and/or less than 10 nm and/or less than 5 nm and/or less than 2 nm, and/or the distance (sp(j−1)j) between the j-th quantum dot (NVj) of the j-th quantum bit (QUBj) of the n-bit quantum register (QUREG) and the preceding (j−1)-th quantum dot (NV(j−1)) of the (j−1)-th quantum bit (QUB(j−1)) of the n-bit quantum register (QUREG) is between 30 nm and 2 nm and/or less than 10 nm and/or less than 5 nm and/or less than 2 nm.

Within the chain, the j-th quantum dot (NVj) then has a distance (spj(j+1)), its successor distance. Preferably, this spatial distance (spj(j+1)) between the j-th quantum dot (NVj) of the j-th quantum bit (QUBj) of the quantum register (QUREG) and the subsequent U+1)-th quantum dot (NV(j+1)) of the (j+1)-th quantum bit (QUB(j+1)) of the quantum register (QUREG) is so small, that the magnetic field of the subsequent (j+1)-th quantum dot (NV(j+1)) of the (j+1)-th quantum bit (QUB(j+1)) of the n-bit quantum register (QUREG) influences the behavior of the j-th quantum dot (NVj) of the j-th quantum bit (QUBj) of the n-bit quantum register (QUREG) at least temporarily, and/or in that the magnetic field of the j-th quantum dot (NVj) of the j-th quantum bit (QUBj) of the n-bit quantum register (QUREG) influences the behavior of the subsequent (j+1)-th quantum dot (NV(j+1)) of the (j+1)-th quantum bit (QUB(j+1)) of the n-bit quantum register (QUREG) at least temporarily. Preferably, the distance (spj(j+1)) between the j-th quantum dot (NVj) of the j-th quantum bit (QUBj) of the n-bit quantum register (QUREG) and the subsequent (j+1)-th quantum dot (NV(j+1)) of the (j+1)-th quantum bit (QUB(j+1)) of the n-bit quantum register (QUREG) is less than 50 nm and/or less than 30 nm and/or less than 20 nm and/or less than 10 nm and/or less than 10 nm and/or less than 5 nm and/or less than 2 nm, and/or the distance (spj(j+1)) between the j-th quantum dot (NVj) of the j-th quantum bit (QUBj) of the n-bit quantum register (QUREG) and the subsequent (j+1)-th quantum dot (NV(j+1)) of the (j+1)-th quantum bit (QUB(j+1)) of the n-bit quantum register (QUREG) is between 30 nm and 2 nm and/or less than 10 nm and/or less than 5 nm and/or less than 2 nm.

Within the chain, the first quantum dot (NV1) then has a first distance (sp12), its successor distance. Preferably, this first spatial distance (sp12) between the first quantum dot (NV1) of the first quantum bit (QUB1) of the quantum register (QUREG) and the subsequent second quantum dot (NV2) of the second quantum bit (QUB2) of the quantum register (QUREG) is so small, that the magnetic field of the subsequent second quantum dot (NV2) of the second quantum bit (QUB2) of the n-bit quantum register (QUREG) influences the behavior of the first quantum dot (NV1) of the first quantum bit (QUB1) of the n-bit quantum register (QUREG) at least temporarily, and/or in that the magnetic field of the first quantum dot (NV1) of the first quantum bit (QUB1) of the n-bit quantum register (QUREG) influences the behavior of the subsequent second quantum dot (NV2) of the second quantum bit (QUB2) of the n-bit quantum register (QUREG) at least temporarily. Preferably, for this purpose the distance (sp12) between the first quantum dot (NV1) of the first quantum bit (QUB1) of the n-bit quantum register (QUREG) and the subsequent second quantum dot (NV2) of the second quantum bit (QUB2) of the n-bit quantum register (QUREG) is less than 50 nm and/or less than 30 nm and/or less than 20 nm and/or less than 10 nm and/or less than 10 nm and/or less than 5 nm and/or less than 2 nm, and/or the distance (sp12) between the first quantum dot (NV1) of the first quantum bit (QUB1) of the n-bit quantum register (QUREG) and the subsequent second quantum dot (NV2) of the second quantum bit (QUB2) of the n-bit quantum register (QUREG) is between 30 nm and 2 nm and/or less than 10 nm and/or less than 5 nm and/or less than 2 nm.

Within the chain, the n-th quantum dot (NVn) then has a distance (sp(n−1)n), its predecessor distance. Preferably, this spatial distance (sp(n−1)n) between the n-th quantum dot (NVn) of the n-th quantum bit (QUBn) of the quantum register (QUREG) and the preceding (n−1)-th quantum dot (NV(n−1)) of the (n−1)-th quantum bit (QUB(n−1)) of the quantum register (QUREG) is so small, that the magnetic field of the preceding (n−1)-th quantum dot (NV(n−1)) of the (n−1)-th quantum bit (QUB(n−1)) of the n-bit quantum register (QUREG) influences the behavior of the n-th quantum dot (NVn) of the n-th quantum bit (QUBn) of the n-bit quantum register (QUREG) at least temporarily, and/or in that the magnetic field of the j-th quantum dot (NVn) of the n-th quantum bit (QUBn) of the n-bit quantum register (QUREG) influences the behavior of the preceding (n−1)-th quantum dot (NV(n−1)) of the (n−1)-th quantum bit (QUB(n−1)) of the quantum register (QUREG) at least temporarily. Preferably, the distance (sp(n−1)) between the n-th quantum dot (NVn) of the n-th quantum bit (QUBn) of the n-bit quantum register (QUREG) and the preceding (n−1)-th quantum dot (NV(n−1)) of the (n−1)-th quantum bit (QUB(n−1)) of the n-bit quantum register (QUREG) is less than 50 nm and/or less than 30 nm and/or less than 20 nm and/or less than 10 nm and/or less than 5 nm and/or less than 2 nm, and/or the distance (sp(n−1)n) between the n-th quantum dot (NVn) of the n-th quantum bit (QUBn) of the n-bit quantum register (QUREG) and the preceding (n−1)-th quantum dot (NV(n−1)) of the (n−1)-th quantum bit (QUB(n−1)) of the n-bit quantum register (QUREG) is between 30 nm and 2 nm and/or less than 10 nm and/or less than 5 nm and/or less than 2 nm.

Within the chain, the first quantum dot (NV1) can then have a distance (sp1n), its chain length, in relation to the n-th quantum dot (NVn). Preferably, this spatial distance (sp1n) between the first quantum dot (NV1) of the first quantum bit (QUB1) of the quantum register (QUREG) at the beginning of the chain and the n-th quantum dot (NVn) of the n-th quantum bit (QUBn) of the n-bit quantum register (QUREG) at the end of the chain is such, that the magnetic field of the first quantum dot (NV1) of the first quantum bit (QUB1) of the n-bit quantum register (QUREG) at the beginning of the chain can no longer significantly influence the behavior of the n-th quantum dot (NVn) of the n-th quantum bit (QUBn) of the n-bit quantum register (QUREG) at the end of the chain, and/or that the magnetic field of the n-th quantum dot (NVn) of the n-th quantum bit (QUBn) of the n-bit quantum register (QUREG) at the end of the chain can no longer directly influence the behavior of the first quantum dot (NV1) of the first quantum bit (QUB1) of the n-bit quantum register (QUREG) at the beginning of the chain, but only with the help of the n−2 quantum dots (NV2 to NV(n−1)) between the first quantum dot (NV1) and the n-th quantum dot (NVn).

The principles described below for a three-bit quantum register can therefore be applied to an n-bit quantum register with more than three quantum bits (n>3). Therefore, these principles are no longer elaborated for a multi-bit quantum register, since they are readily apparent to those skilled in the art from the following description of a three-bit quantum register. Such multi-bit quantum registers are explicitly included in the claim.

A three-bit quantum register is then a quantum register as previously described with at least a third quantum bit (QUB3) according to the previous description. Preferably, the first quantum dot type of the first quantum dot (NV1) of the first quantum bit (QUB1) and the second quantum dot type of the second quantum dot (NV2) of the second quantum bit (QUB2) are then equal to the third quantum dot type of the third quantum dot (NV3) of the third quantum bit (QUB3).

Preferably, in such an exemplary three-bit quantum register, the substrate (D) is common to the first quantum bit (QUB1) and the second quantum bit (QUB2) and the third quantum bit (QUB3). The quantum dot (NV) of the third quantum bit (QUB3) will be referred to as the third quantum dot (NV3) in the following. Preferably, the horizontal line (LH) of the third quantum bit (QUB3) is the said first horizontal line (LH1) and thus in common with the horizontal line (LH) of the second quantum bit (QUB2) and the horizontal line (LH) of the first quantum bit (QUB1). The vertical line (LV) of the third quantum bit (QUB3) will be referred to as the third vertical line (LV3) in the following. Instead of this lining up of the quantum bits along the first horizontal line (LH1), other lining ups are conceivable, u already mentioned.

In order to now enable a transport of dependencies of quantum information, it is useful if the magnetic field of the second quantum dot (NV2) of the second quantum bit (QUB2) can influence the behavior of the third quantum dot (NV3) of the third quantum bit (QUB3) at least temporarily and/or if the magnetic field of the third quantum dot (NV3) of the third quantum bit (QUB3) can influence the behavior of the second quantum dot (NV2) of the second quantum bit (QUB2) at least temporarily. This gives rise to what is referred to below as a quantum bus and is used to transport dependencies of the quantum information of the quantum dots of the quantum bus (QUBUS) thus created.

To enable these dependencies, it is useful if the spatial distance (sp23) between the third quantum dot (NV3) of the third quantum bit (QUB3) and the second quantum dot (NV2) of the second quantum bit (QUB2) is so small, that the magnetic field of the second quantum dot (NV2) of the second quantum bit (QUB2) can influence the behavior of the third quantum dot (NV3) of the third quantum bit (QUB3) at least temporarily, and/or that the magnetic field of the third quantum dot (NV3) of the third quantum bit (QUB3) can influence the behavior of the second quantum dot (NV2) of the second quantum bit (QUB2) at least temporarily.

To achieve this coupling, it is again useful, if the spatial distance (sp23) between the third quantum dot (NV3) of the third quantum bit (QUB3) and the second quantum dot (NV2) of the second quantum bit (QUB2) is less than 50 nm and/or less than 30 nm and/or less than 20 nm and/or less than 10 nm and/or less than 10 nm and/or less than 5 nm and/or less than 2 nm and/or if the spatial distance (sp23) between the third quantum dot (NV3) of the third quantum bit (QUB3) and the second quantum dot (NV2) of the second quantum bit (QUB2) is between 30 nm and 2 nm and/or less than 10 nm and/or less than 5 nm and/or less than 2 nm, is.

As explained above, the quantum bits (QUB) of the quantum register (QUREG) are preferably arranged in a one-dimensional lattice. An arrangement in a two-dimensional lattice is possible, but not so advantageous, since then the current equations can no longer be solved unambiguously without further ado.

Preferably, the quantum bits (QUB) of the quantum register (QUREG) are thus arranged in a one- or two-dimensional lattice of elementary cells of arrays of one or more quantum dots (NV) with a second spacing (sp12) as lattice constant for the distance between the respective elementary cells.

### Construction of an Inhomogeneous Quantum Register

Now, an inhomogeneous quantum register (IHQUREG), unlike a homogeneous quantum register (QUREG), consists of quantum dots (NV) of different quantum dot types.

For example, one quantum dot (NV) of the inhomogeneous quantum register (IHQUREG) may be an NV center (NV) in diamond as a first quantum dot type and another quantum dot (NV) a quantum dot (NV) of the inhomogeneous quantum register (IHQUREG) may be an SiV center in diamond as a second quantum dot type.

An inhomogeneous quantum register (IHQUREG) thus preferably comprises a first quantum bit (QUB1) and at least a second quantum bit (QUB2), wherein the first quantum dot type of the first quantum dot (NV1) of the first quantum bit (QUB1) of the inhomogeneous quantum register (IHQUREG) is different from the second quantum dot type of the second quantum dot (NV2) of the second quantum bit (QUB2) of the inhomogeneous quantum register (IHQUREG).

Preferably, however, the substrate (D) is common to the first quantum bit (QUB1) and the second quantum bit (QUB2). Again, in the following, the quantum dot (NV) of the first quantum bit (QUB1) of the inhomogeneous quantum register (IHQUREG) is called the first quantum dot (NV1) of the inhomogeneous quantum register (IHQUREG) and the quantum dot (NV) of the second quantum bit (QUB2) of the inhomogeneous quantum register (IHQUREG) is called the second quantum dot (NV2) of the inhomogeneous quantum register (IHQUREG). Similarly, again, the horizontal line (LH) of the first quantum bit (QUB1) of the inhomogeneous quantum register (IHQUREG) is referred to as the first horizontal line (LH1) in the following, and the horizontal line (LH) of the second quantum bit (QUB2) is referred to as the second horizontal line (LH2).

In an analogous manner, the vertical line (LV) of the first quantum bit (QUB1) of the inhomogeneous quantum register (IHQUREG) is preferably referred to hereinafter as the first vertical line (LV1) and the vertical line (LV) of the second quantum bit (QUB2) is preferably referred to hereinafter as the second vertical line (LV2). It is useful if, for example, the first horizontal line (LH1) is identical to the second horizontal line (LH1). Alternatively, it is useful if, for example, the first vertical line (LV1) is identical to the second vertical line (LV1).

Preferably, the first horizontal line (LH1) and the second horizontal line (LH2) and the first vertical line (LV) and the second vertical line are essentially made of isotopes without magnetic moment μ. In this case, essentially means that the total fraction K_{IG} of isotopes with magnetic moment of an element which is a component of one or more of the lines, with respect to 100% of this element which is a component of these lines, is reduced with respect to the natural total fraction K_{IG} indicated in the above tables to a fraction K_{IG}′ of isotopes with magnetic moment of an element which is a component of one or more of these lines, with respect to 100% of this element which is a component of one or more of these lines. Whereby this fraction K_{IG}′ is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the element in question of one or more of the lines in the region of influence of the paramagnetic perturbations (NV) used as quantum dots (NV) and/or of the nuclear spins used as nuclear quantum dots (CI).

Preferably, the inhomogeneous quantum register (IHQUREG) is designed in such a way, that the magnetic field of the second quantum dot (NV2) of the second quantum bit (QUB2) of the inhomogeneous quantum register (IHQUREG) influences the behavior of the first quantum dot (NV1) of the first quantum bit (QUB1) of the inhomogeneous quantum register (IHQUREG) at least temporarily and/or in that the magnetic field of the first quantum dot (NV1) of the first quantum bit (QUB1) of the inhomogeneous quantum register (IHQUREG) influences the behavior of the second quantum dot (NV2) of the second quantum bit (QUB2) of the inhomogeneous quantum register (IHQUREG) at least temporarily.

For this purpose, again preferably the spatial distance (sp12) between the first quantum dot (NV1) of the first quantum bit (QUB1) of the inhomogeneous quantum register (IHQUREG) and the second quantum dot (NV2) of the second quantum bit (QUB2) of the inhomogeneous quantum register (IHQUREG) is chosen to be so small, that the magnetic field of the second quantum dot (NV2) of the second quantum bit (QUB2) of the inhomogeneous quantum register (IHQUREG) influences the behavior of the first quantum dot (NV1) of the first quantum bit (QUB1) of the inhomogeneous quantum register (IHQUREG) at least temporarily, and/or in that the magnetic field of the first quantum dot (NV1) of the first quantum bit (QUB1) of the inhomogeneous quantum register (IHQUREG) influences the behavior of the second quantum dot (NV2) of the second quantum bit (QUB2) of the inhomogeneous quantum register (IHQUREG) at least temporarily. Preferably, the second distance (sp12) between the first quantum dot (NV1) of the first quantum bit (QUB1) of the inhomogeneous quantum register (IHQUREG) and the second quantum dot (NV2) of the second quantum bit (QUB2) of the inhomogeneous quantum register (IHQUREG) is less than 50 nm and/or preferably less than 30 nm and/or preferably less than 20 nm and/or preferably less than 10 nm and/or preferably less than 5 nm and/or preferably less than 2 nm, and/or the second distance (sp12) between the first quantum dot (NV1) of the first quantum bit (QUB1) of the inhomogeneous quantum register (IHQUREG) and the second quantum dot (NV2) of the second quantum bit (QUB2) of the inhomogeneous quantum register (IHQUREG) is preferably between 30 nm and 2 nm and/or better less than 10 nm and/or better less than 5 nm and/or better less than 2 nm.

Preferably, the quantum bits of the inhomogeneous quantum register (IHQUREG) are composed of unit cells of arrays of two or more quantum bits arranged in a one- or two-dimensional lattice for the respective unit cell.

Preferably, the quantum bits of the inhomogeneous quantum register (IHQUREG) are arranged in a one- or two-dimensional lattice of unit cells of arrays consisting of one or more quantum bits with a second spacing (sp12) as lattice constant for the respective unit cell.

### Construction of a Nuclear Quantum Register (CCOUREG)

Another aspect of the concept relates to a nucleus-nuclear quantum register (CCQUREG). The nucleus-nuclear quantum register (CCQUREG) comprises a first nuclear quantum bit (CQUB1) and, as previously described, at least a second such nuclear quantum bit (CQUB2). It is important to note here that the nuclear quantum dots (CI1, CI2) of the nuclear quantum bits (CQUB1, CQUB2) should be positioned so close to each other that they can interact with each other without the need for a quantum dot (NV), for example a NV center (NV) in the case of diamond as the material of the substrate (D) or a G center in the case of silicon as the material of the substrate (D). Because of the difficulties in this very dense placement, this nuclear quantum register (CCQUREG) is included here only for completeness. Currently, fabrication is only possible by a random process in which the nuclear quantum dots (CI1, CI2) happen to be close enough to each other. It is also conceivable to use an STM to arrange the isotopes of the subsequent nuclear quantum dots side by side on the surface of a substrate, for example as a dense line of such isotopes, and then to deposit the surrounding material.

Nevertheless, such nuclear quantum registers (CCQUREG) can already be fabricated today with very low yields by implantation of nuclear spin-bearing isotopes into the substrate (D).

If diamond is used as substrate (D), chemical compounds with several 13C atoms, for example organic molecules, can be implanted. This brings the 13C isotopes close together. If the molecule also includes a nitrogen atom, a quantum ALU (QUALU), as described above, can be very easily fabricated in this way in diamond as substrate (D). The substrate (D) is preferably prepared beforehand by placing alignment marks. This can be done by lithography and more specifically by electron and/or ion beam lithography. The molecule is implanted, followed by a temperature step to cure the crystal, e.g., the diamond substrate. Later in the process, the location of the resulting quantum dot, for example an NV center, is optically detected by irradiation with “green light”, that in the case of NV centers in diamond, for example, the NV centers are excited to red fluorescence. Preferably, this is done in a STED microscope. This allows localization with sufficient accuracy relative to the previously applied alignment marks. Preferably, depending on the localization result, the horizontal and vertical lines (LV, LH) are then manufactured, e.g., by means of electron beam lithography.

The same applies to other materials of the substrate (D) and/or other paramagnetic interference centers.

As before, the substrate (D) is typically common to the first nuclear quantum bit (CQUB1) and the second nuclear quantum bit (CQUB2). The nuclear quantum dot (CI) of the first nuclear quantum bit (CQUB1) is hereinafter referred to as the first nuclear quantum dot (CI1) and the nuclear quantum dot (CI) of the second quantum bit (CQUB2) is hereinafter referred to as the second nuclear quantum dot (CI2). Analogous to the previously described registers, the horizontal line (LH) of the first nuclear quantum bit (CQUB1) is hereinafter referred to as the first horizontal line (LH1) and the horizontal line (LH) of the second nuclear quantum bit (CQUB2) is hereinafter referred to as the said first horizontal line (LH1) and the vertical line (LV) of the first nuclear quantum bit (CQUB1) hereinafter referred to as the first vertical line (LV1) and the vertical line (LV) of the second nuclear quantum bit (CQUB2) hereinafter referred to as the second vertical line (LV2).

If the nuclear quantum dots (CI1, CI2) of the nuclear quantum register (CCQUREG) are close enough to each other, then the magnetic field of the second nuclear quantum dot (CI2) of the second nuclear quantum bit (CQUB2) can influence the behavior of the first nuclear quantum dot (CI1) of the first nuclear quantum bit (CQUB1) at least temporarily and/or the magnetic field of the first nuclear quantum dot (CI1) of the first nuclear quantum bit (CQUB1) can influence the behavior of the second nuclear quantum dot (CI2) of the second nuclear quantum bit (CQUB2) at least temporarily. This can be used for quantum operations.

For this purpose, the spatial distance (sp12) between the first nuclear quantum dot (CI1) of the first nuclear quantum bit (CQUB1) and the second nuclear quantum dot (CI2) of the second nuclear quantum bit (CQUB2) should preferably be so small, that the magnetic field of the second nuclear quantum dot (CI2) of the second nuclear quantum bit (CQUB2) can influence the behavior of the first nuclear quantum dot (CI1) of the first nuclear quantum bit (CQUB1) at least temporarily, and/or that the magnetic field of the first nuclear quantum dot (CI1) of the first nuclear quantum bit (CQUB1) can influence the behavior of the second nuclear quantum dot (CI2) of the second nuclear quantum bit (CQUB2) at least temporarily.

For this purpose, preferably the fourth distance (sp12′) between the first nuclear quantum dot (CI1) of the first nuclear quantum bit (CQUB1) and the second nuclear quantum dot (CI2) of the second nuclear quantum bit (CQUB2) should be less than 100 μm and/or better less than 50 μm and/or better less than 30 μm and/or better less than 20 μm and/or better less than 10 μm.

Where possible, the nuclear quantum bits of the nucleus-nuclear quantum register (CCQUREG) should be arranged in a one- or two-dimensional lattice.

Preferably, the nuclear quantum bits of the nucleus-nuclear quantum register (CCQUREG) are arranged in a one- or two-dimensional lattice of elementary cells of arrays of one or more nuclear quantum bits with a second spacing (sp12) as lattice constant for the respective elementary cell. With a typically occurring suitable asymmetric positioning of the quantum dot (NV) relative to the one- or two-dimensional lattice of nuclear quantum dots (CI), the coupling energies of the pairs of one nuclear quantum dot each of the nuclear quantum dots (CI1, CI2) of the one- or two-dimensional nuclear quantum dot lattice with the quantum dot (NV) are then different from pair to pair. This then allows selection or addressing of the individual pairs of nuclear quantum dot (CI) and quantum dot (NV) that differ from each other. This allows quantum operations to be restricted to the relevant pair of nuclear quantum dot (CI) and quantum dot (NV).

Nucleus-nuclear quantum registers (CCQUREG) can also be made inhomogeneous. Such an inhomogeneous nucleus-nuclear quantum register (CCQUREG) is characterized by at least one nuclear quantum dot having a different isotope than another nuclear quantum dot of the nucleus-nuclear quantum register (CCQUREG). For example, a nucleus-nuclear quantum register (CCQUREG) in diamond as the material of the substrate (D) may have a 13C isotope as a first nuclear quantum dot (CI1) and a 15N isotope as a second nuclear quantum dot (CI2), which interact with each other when sufficiently close.

Such a nucleus-nuclear quantum register (CCQUREG), can be concatenated. The two-bit nucleus-nuclear quantum register (CCQUREG) described earlier was strung along the horizontal line (LH) common to the two nuclear quantum bits (CQUB1, CQUB2). Instead of horizontal stringing, vertical stringing along the vertical line is equally conceivable. The horizontal and the vertical line then exchange the function. A two-dimensional stringing together is also conceivable, which corresponds to a combination of these possibilities.

Instead of a two-bit nucleus-nuclear quantum register (CCQUREG), the stringing together of n nuclear quantum bits (CQUB1 to CQUBn) is also conceivable. As an example, a three-bit nucleus-nuclear quantum register (CCQUREG) is described here, which is continued along the horizontal line (LH) as an example. For the following nuclear quantum bits (QUB4 to QUBn), the same applies. The nucleus-nuclear quantum register (CCQUREG) can of course be extended in the other direction by m nuclear quantum bits (CQUB0 to CQUB(m−1)). To simplify the description, the text presented here is limited to positive values of the indices from 1 to n.

By an exemplary linear concatenation of the n nuclear quantum bits (CQUB1 to CQUBn) along an exemplary one-dimensional line within an n-bit nuclear quantum register (CCQUREG), for example along said vertical line (LV) or along said horizontal line (LH), the spatial distance (spln) between the first nuclear quantum dot (CI1) of the first nuclear quantum bit (QUB1) of the n-bit nuclear quantum register (QUREG) and the n-th nuclear quantum dot (CIn) of the n-th nuclear quantum bit (CQUBn) of the n-bit nuclear quantum register (CCQUREG) can be so large, that the first nuclear quantum dot (CI1) of the first nuclear quantum bit (CQUB1) of the n-bit nucleus-nuclear quantum register (CCQUREG) is no longer coupled with the n-th nuclear quantum dot (CIn) of the n-th nuclear quantum bit (CQUBn) of the n-bit nucleus-nuclear quantum register (CCQUREG) or can be directly entangled. For simplicity, we assume that the n nuclear quantum dots (CI1 to CIn) of the n nuclear quantum dots (CQUB1 to CQUBn) are countably lined up along said one-dimensional line. This one-dimensional line can also be curved or angular. Thus, in this example, the n nuclear quantum dots (CI1 to CIn), and thus typically their respective nuclear quantum bits (CQUB1 to CQUBn), are said to represent a chain of n nuclear quantum dots (CI1 to CIn) starting with the first nuclear quantum dot (CI1) and ending with the n-th nuclear quantum dot (CIn). Within this chain of n nuclear quantum dots (CI1 to CIn), the nuclear quantum dots (CI1 to CIn) and thus typically the nuclear quantum bits (CQUB1 to CQUBn) of the nucleus-nuclear quantum register (CCQUREG) are countable and thus can be numbered consecutively from 1 to n with integer positive numbers.

Thus, within the chain, a j-th nuclear quantum dot (CIj) is preceded by a (j−1)-th nuclear quantum dot (CI(j−1)), which will be called the predecessor nuclear quantum dot (CI(j−1)) in the following. Thus, typically also within the chain, a (j−1)-th nuclear quantum bit (CQUBj) with the j-th nuclear quantum dot (CIj) is preceded by a (j−1)-th nuclear quantum bit (CQUB(j−1)) of the nucleus-nuclear quantum register (CCQUREG) with the (j−1)-th nuclear quantum dot (CI(j−1)), which is called the predecessor nuclear quantum bit (CQUB(j−1)) in the following.

Thus, within the chain, a j-th nuclear quantum dot (CIj) is followed by a (j+1)-th nuclear quantum dot (CI(j+1)), which will be called the successor nuclear quantum dot (CI(j+1)) in the following. Thus, within the chain, a (j+1)-th nuclear quantum bit (CQUBj) with the (j)-th nuclear quantum dot (CIj) is succeeded by a (j+1)-th nuclear quantum bit (CQUB(j+1)) with the (j+1)-th nuclear quantum dot (CI(j+1)), which is called the successor nuclear quantum bit (CQUB(j−1)) in the following. Here the subscript j with respect to this exemplary chain shall be here any integer positive number with 1<j<n, where n shall be an integer positive number with n>2.

Within the chain, the j-th nuclear quantum dot (CIj) then has a distance (sp′(j−1)j), its predecessor distance. Preferably, this spatial distance (sp′(j−1)j) between the j-th nuclear quantum dot (CIj) of the j-th nuclear quantum bit (CQUBj) of the n-bit nucleus-nuclear quantum register (CCQUREG) and the preceding (j−1)-th nuclear quantum dot (CI(j−1)) of the (j−1)-th nuclear quantum bit (CQUB(j−1)) of the nucleus-nuclear quantum register (CCQUREG) is so small, that the magnetic field of the preceding (j−1)-th nuclear quantum dot (CI(j−1)) of the (j−1)-th nuclear quantum bit (CQUB(j−1)) of the n-bit nucleus-nuclear quantum register (CCQUREG) influences the behavior of the j-th nuclear quantum dot (CID of the j-th nuclear quantum bit (CQUBj) of the n-bit nucleus-nuclear quantum register (CCQUREG) at least temporarily, and/or in that the magnetic field of the j-th nuclear quantum dot (CID of the j-th nuclear quantum bit (CQUBj) of the n-bit nucleus-nuclear quantum register (CCQUREG) influences the behavior of the preceding (j−1)-th nuclear quantum dot (CI(j−1)) of the (j−1)-th nuclear quantum bit (CQUB(j−1)) of the nucleus-nuclear quantum register (CCQUREG) at least temporarily. Preferably, for this purpose the distance (sp′(j−1)1) between the j-th nuclear quantum dot (CID of the j-th nuclear quantum bit (CQUB1) of the n-bit nucleus-nuclear quantum register (CCQUREG) and the preceding (j−1)-th nuclear quantum dot (CI(j−1)) of the (j−1)-th nuclear quantum bit (CQUB(j−1)) of the n-bit nuclear quantum register (CCQUREG) is less than 200 μm and/or better than 100 μm and/or better than 50 μm and/or better than 30 μm and/or better than 20 μm and/or better than 10 μm, and/or the distance (sp′(j−1)j) between the j-th nuclear quantum dot (CID of the j-th nuclear quantum bit (CQUBj) of the n-bit nuclear quantum register (CCQUREG) and the preceding (j−1)-th nuclear quantum dot (CI(j−1)) of the (j−1)-th nuclear quantum bit (CQUB(j−1)) of the n-bit nuclear quantum register (CCQUREG) between 200 μm and 2 μm and/or better between than 100 μm and 5 μm and/or better less than 50 μm and/or better less than 30 μm and/or better less than 20 μm and/or better less than 10 μm and 2 μm.

For example, a chain of 13C isotopes can be fabricated by means of the displacement of individual 13C atoms on a diamond surface of a 12C diamond as substrate (D) with such distances of adjacent 13C atoms from each other, which is then covered and stabilized with a 12C layer by means of a CVO process. The 13C atoms of this chain of 13C atoms are then coupled together.

Within the chain, the j-th nuclear quantum dot (CU) then has a distance (sp′j(j+1)), its successor distance. Preferably, this spatial distance (sp′j(j+1)) between the j-th nuclear quantum dot (CID of the j-th nuclear quantum bit (CQUBj) of the nucleus-nuclear quantum register (CCQUREG) and the subsequent (j+1)-th nuclear quantum dot (CI(j+1)) of the (j+1)-th nuclear quantum bit (CQUB(j+1)) of the nucleus-nuclear quantum register (CCQUREG) is so small for this purpose, that the magnetic field of the subsequent (j+1)-th nuclear quantum dot (CI(j+1)) of the (J+1)-th nuclear quantum bit (CQUB(j+1)) of the n-bit nucleus-nuclear quantum register (CCQUREG) influences the behavior of the j-th nuclear quantum dot (CIj) of the j-th nuclear quantum bit (CQUBj) of the n-bit nucleus-nuclear quantum register (CCQUREG) at least temporarily, and/or in that the magnetic field of the j-th nuclear quantum dot (CIj) of the j-th nuclear quantum bit (CQUBj) of the n-bit nucleus-nuclear quantum register (CCQUREG) influences the behavior of the subsequent (j+1)-th nuclear quantum dot (CI(j+1)) of the (j+1)-th nuclear quantum bit (CQUB(j+1)) of the n-bit nucleus-nuclear quantum register (CCQUREG) at least temporarily. Preferably, for this purpose the distance (sp′j(j+1)) between the j-th nuclear quantum dot (CIj) of the j-th nuclear quantum bit (CQUB1) of the n-bit nuclear quantum register (CCQUREG) and the subsequent (j+1)-th nuclear quantum dot (CI(j+1)) of the (j+1)-th nuclear quantum bit (CQUB(j+1)) of the n-bit nuclear quantum register (CCQUREG) is less than 200 μm and/or less than 100 μm and/or less than 50 μm and/or less than 20 μm and/or less than 10 μm and/or less than 5 μm and/or less than 2 μm, and/or the distance (sp′j(j+1)) between the j-th nuclear quantum dot (CIj) of the j-th nuclear quantum bit (CQUBj) of the n-bit nuclear quantum register (CCQUREG) and the subsequent (j+1)-th nuclear quantum dot (CI(j+1)) of the (j+1)-th nuclear quantum bit (CQUB(j+1)) of the n-bit nuclear quantum register (CCQUREG) between 200 μm and 2 μm and/or less than 100 μm and/or less than 50 μm and/or less than 20 μm.

Within the chain, the first nuclear quantum dot (CI1) then has a first distance (sp′12), its successor distance. Preferably, this first spatial distance (sp′12) between the first nuclear quantum dot (CI1) of the first nuclear quantum bit (CQUB1) of the n-bit nuclear quantum register (CCQUREG) and the subsequent second nuclear quantum dot (CI2), typically of the second nuclear quantum bit (CQUB2) of the n-bit nuclear quantum register (CCQUREG), is so small for this purpose, that the magnetic field of the subsequent second nuclear quantum dot (CI2) of the second nuclear quantum bit (CQUB2) of the n-bit nuclear quantum register (CCQUREG) influences the behavior of the first nuclear quantum dot (CI1) of the first nuclear quantum bit (CQUB1) of the n-bit nuclear quantum register (CCQUREG) at least temporarily, and/or in that the magnetic field of the first nuclear quantum dot (CI1) of the first nuclear quantum bit (CQUB1) of the n-bit nuclear quantum register (CCQUREG) influences the behavior of the subsequent second nuclear quantum dot (CI2) of the second nuclear quantum bit (CQUB2) of the n-bit nuclear quantum register (CCQUREG) at least temporarily. Preferably, the distance (sp′12) between the first nuclear quantum dot (CI1) of the first nuclear quantum bit (CQUB1) of the n-bit nucleus-nuclear quantum register (CCQUREG) and the subsequent second nuclear quantum dot (CI2) of the second nuclear quantum bit (CQUB2) of the n-bit nucleus-nuclear quantum register (CCQUREG) is less than 200 μm and/or less than 100 μm and/or less than 30 μm and/or less than 20 μm and/or less than 10 μm and/or less than 5 μm and/or less than 2 μm, and/or the distance (sp′12) between the first nuclear quantum dot (CI1) of the first nuclear quantum bit (CQUB1) of the n-bit nuclear quantum register (CCQUREG) and the subsequent second nuclear quantum dot (CI2) of the second nuclear quantum bit (CQUB2) of the n-bit nuclear quantum register (CCQUREG) is between 200 μm and 2 μm and/or less than 100 μm and/or less than 50 μm and/or less than 20 μm.

Within the chain, the n-th nuclear quantum dot (CIn) then has a distance (sp′(n−1)n), its predecessor distance. Preferably, this spatial distance (sp′(n−1)n) between the n-th nuclear quantum dot (CIn) of the n-th nuclear quantum bit (CQUBn) of the n-bit nuclear quantum register (CCQUREG) and the preceding (n−1)-th nuclear quantum dot (CI(n−1)) of the (n−1)-th nuclear quantum bit (CQUB(n−1)) of the n-bit nuclear quantum register (CCQUREG) is so small, that the magnetic field of the preceding (n−1)-th nuclear quantum dot (CI(n−1)) of the (n−1)-th nuclear quantum bit (CQUB(n−1)) of the n-bit nuclear quantum register (CCQUREG) influences the behavior of the n-th nuclear quantum dot (CIn) of the n-th nuclear quantum bit (CQUBn) of the n-bit nuclear quantum register (CCQUREG) at least temporarily, and/or in that the magnetic field of the j-th nuclear quantum dot (CIn) of the n-th nuclear quantum bit (CQUBn) of the n-bit nuclear quantum register (CCQUREG) influences the behavior of the preceding (n−1)-th nuclear quantum dot (CI(n−1)) of the (n−1)-th nuclear quantum bit (CQUB(n−1)) of the n-bit nuclear quantum register (CCQUREG) at least temporarily. Preferably, the distance (sp′(n−1)1) between the n-th nuclear quantum dot (CIn) of the n-th nuclear quantum bit (CQUBn) of the n-bit nuclear quantum register (CCQUREG) and the preceding (n−1)-th nuclear quantum dot (CI(n−1)) of the (n−1)-th nuclear quantum bit (CQUB(n−1)) of the n-bit nuclear quantum register (CCQUREG) is less than 200 μm and/or less than 100 μm and/or less than 50 μm and/or less than 20 μm and/or less than 10 μm and/or less than 5 μm and/or less than 2 μm, and/or the distance (sp′(n−1)n) between the n-th nuclear quantum dot (CIn) of the n-th nuclear quantum bit (CQUBn) of the n-bit nuclear quantum register (CCQUREG) and the preceding (n−1)-th nuclear quantum dot (CI(n−1)) of the (n−1)-th nuclear quantum bit (CQUB(n−1)) of the n-bit nuclear quantum register (CCQUREG) is between 200 μm and 2 μm and/or less than 100 μm and/or less than 50 μm and/or less than 20 μm and/or less than 10 μm and/or less than 5 μm and/or less than 2 μm.

Within the chain, the first nuclear quantum dot (CI1) can then have a distance (sp′1n), its chain length, in relation to the n-th nuclear quantum dot (CIn). Preferred for this purpose is this spatial distance (sp′1n) between the first nuclear quantum dot (CI1), typically of the first nuclear quantum bit (QUB1), of the n-bit nuclear quantum register (CCQUREG) at the beginning of the chain and the n-th nuclear quantum dot (CIn), typically of the n-th quantum bit (QUBn), of the n-bit nucleus-nuclear quantum register (CCQUREG) at the end of the chain be so large that the magnetic field of the first nucleus-nuclear quantum dot (CI1), typically of the first nucleus-nuclear quantum bit (CQUB1), of the n-bit nucleus-nuclear quantum register (CCQUREG) at the beginning of the chain no longer significantly influences the behavior of the n-th nuclear quantum dot (CIn), typically of the n-th nuclear quantum bit (CQUBn), of the n-bit nuclear quantum register (CCQUREG) at the end of the chain can no longer significantly influence the behavior of the n-th nuclear quantum dot (CIn), typically of the n-th nuclear quantum bit (CQUBn), of the n-bit nuclear quantum register (CCQUREG) at the end of the chain, and/or that the magnetic field of the n-th nuclear quantum dot (CIn), typically of the n-th nuclear quantum bit (CQUBn), of the n-bit nuclear quantum register (CCQUREG) at the end of the chain can no longer significantly directly influence the behavior of the first nuclear quantum dot (CI1), typically of the first nuclear quantum bit (CQUB1) of the n-bit nuclear quantum register (CCQUREG) at the beginning of the chain can no longer be influenced directly, but only with the aid of the n−2 nuclear quantum dots (CI2 to CI(n−1)) between the first nuclear quantum dot (CI1) and the n-th nuclear quantum dot (CIn).

The principles described below for a three-bit nucleus-nuclear quantum register can therefore be transferred to a nucleus-nuclear quantum register (CCQUREG) with more than three nuclear quantum dots (CI1 to CIn). Therefore, these principles are no longer elaborated for an n-bit nucleus-nuclear quantum register (CCQUREG) with n>3, since they are readily apparent to those skilled in the an from the following description of a three-bit nucleus-nuclear quantum register. Such multi-bit nucleus-nuclear quantum registers are explicitly included in the claim.

A three-bit nucleus-nuclear quantum register (CCQUREG) is then a nucleus-nuclear quantum register (CCQUREG) as previously described, with at least a third nuclear quantum bit (CQUB3) according to the previous description. Preferably, then, the first nuclear quantum dot type of the first nuclear quantum dot (CI1), typically the first nuclear quantum bit (CQUB1), and the second nuclear quantum dot type of the second nuclear quantum dot (CI2), typically the second nuclear quantum bit (CQUB2), are equal to the third nuclear quantum dot type of the third nuclear quantum dot (CI3), typically the third nuclear quantum bit (CQUB3).

Preferably, in such an exemplary three-bit nuclear quantum register, the substrate (D) is common to the first nuclear quantum dot (CI1) and the second nuclear quantum dot (CI2) and the third quantum dot (CI3). The nuclear quantum dot (CI), typically of the third nuclear quantum bit (CQUB3), will be referred to as the third nuclear quantum dot (CI3) in the following. Preferably, the horizontal line (LH) of the third nuclear quantum bit (CQUB3) is the said first horizontal line (LH1) and thus is common with the horizontal line (LH) of the second nuclear quantum bit (CQUB2) and the horizontal line (LH) of the first nuclear quantum bit (CQUB1). The vertical line (LV) of the third nuclear quantum bit (CQUB3) will be referred to as the third vertical line (LV3) in the following. Instead of this lining up of the nuclear quantum bits along the first horizontal line (LH1), other line ups are conceivable, as already mentioned.

Now, to enable transport of dependencies of quantum information, it is useful if the magnetic field of the second nuclear quantum dot (CI2), typically of the second nuclear quantum bit (CQUB2), can influence the behavior of the third nuclear quantum dot (CI3), typically of the third nuclear quantum bit (CQUB3), at least temporarily and/or if the magnetic field of the third nuclear quantum dot (CI3) of the third nuclear quantum bit (CQUB3) can influence the behavior of the second nuclear quantum dot (CI2), typically of the second nuclear quantum bit (CQUB2), at least temporarily. This gives rise to what is referred to below as the nuclear quantum bus, which is used to transport dependencies of the quantum information of the nuclear quantum dots of the nuclear quantum bus (CQUBUS) thus created.

To enable these dependencies, it is useful if the spatial distance (sp′23) between the third nuclear quantum dot (CD), typically of the third nuclear quantum bit (CQUB3), and the second nuclear quantum dot (CI2) of the second nuclear quantum bit (CQUB2) is preferably so small that the magnetic field of the second nuclear quantum dot (CI2), typically of the second nuclear quantum bit (CQUB2), can influence the behavior of the third nuclear quantum dot (CI3), typically the third nuclear quantum bit (CQUB3), at least temporarily, and/or that the magnetic field of the third nuclear quantum dot (CI3), typically the third nuclear quantum bit (CQUB3), can influence the behavior of the second nuclear quantum dot (CI2), typically the second nuclear quantum bit (CQUB2), at least temporarily.

To achieve this coupling, it is again useful if the spatial distance (sp′23) between the third nuclear quantum dot (CI3) of the third nuclear quantum bit (CQUB3) and the second nuclear quantum dot (CI2), typically of the second nuclear quantum bit (CQUB2), is less than 200 μm and/or less than 100 μm and/or less than 50 μm and/or less than 20 μm and/or less than 10 μm and/or less than 5 pm and/or less than 2 μm and/or if the spatial distance (sp′23) between the third nuclear quantum dot (CI3), typically of the third nuclear quantum bit (CQUB3) and the second nuclear quantum dot (CI2), typically of the second nuclear quantum bit (CQUB2), is between 200 μm and 2 μm and/or less than 100 μm and/or less than 50 μm and/or less than 20 μm and/or less than 10 μm and/or less than 5 μm and/or less than 2 μm.

As explained above, the nuclear quantum dots (CI) of the nucleus-nuclear quantum register (CCQUREG) are preferably arranged in a one-dimensional lattice. An arrangement in a two-dimensional lattice is possible, but not so advantageous, since then the current equations cannot be solved unambiguously without further ado.

Preferably, the nuclear quantum dots (CI) of the nucleus-nuclear quantum register (CCQUREG) are thus arranged in a one- or two-dimensional lattice of elementary cells of arrays of one or more nuclear quantum dots (CI) with a second spacing (spar) as lattice constant for the distance between the respective elementary cells.

### Construction of a Nucleus-Electron-Nucleus-Electron Quantum Register (CECEQUREG)

A nucleus-electron-nucleus-electron-quantum register (CECEQUREG) can now be assembled from the previously described registers.

According to the disclosure, such a nucleus-electron-nucleus-electron quantum register (CECEQUREG) comprises a first nuclear quantum bit (CQUB1) and at least a second nuclear quantum bit (CQUB2) as previously described. The nucleus-electron-nucleus-electron quantum register (CECEQUREG) further comprises a first quantum bit (QUB1) and at least one second quantum bit (QUB2) as previously described. Such a nucleus-electron-nucleus-electron quantum register (CECEQUREG) is the simplest form of a quantum bus (QUBUS).

For simplicity, we assume that the first nuclear quantum dot (CI1) of the first nuclear quantum bit (CQUB1) is farther than the nucleus-nucleus coupling distance from the second nuclear quantum dot (CI2) of the second nuclear quantum bit (CQUB2), and thus that the first nuclear quantum dot (CI1) is not directly coupled to the second nuclear quantum dot (CI2).

Furthermore, we assume that the first nuclear quantum dot (CI1) of the first nuclear quantum bit (CQUB1) is closer than the electron-nucleus coupling distance from the first quantum dot (NV1) of the first quantum bit (QUB1), and thus that the first nuclear quantum dot (CI1) is or can be directly coupled to the first quantum dot (NV1).

Furthermore, we assume that the second nuclear quantum dot (CI2) of the second nuclear quantum bit (CQUB2) is closer than the electron-nucleus coupling distance from the second quantum dot (NV2) of the second quantum bit (QUB2), and thus the second nuclear quantum dot (CI2) is or can be directly coupled to the second quantum dot (NV2).

Finally, assume that the first quantum dot (NV1) of the first quantum bit (QUB1) is closer than the electron-electron coupling distance from the second quantum dot (NV2) of the second quantum bit (QUB2), and thus that the first quantum dot (NV) is or can be directly coupled to the second quantum dot (NV2).

Thus, coupling of the first nuclear quantum dot (CI1) with the second nuclear quantum dot (CI2) is possible only indirectly via the first quantum dot (NV1) and the second quantum dot (NV2).

Preferably, the first nuclear quantum bit (CQUB1) and the first quantum bit (QUB1) now form a nucleus-electron quantum register (CEQUREG), hereinafter referred to as first nucleus-electron quantum register (CEQUREG1), in the form previously described.

The second nuclear quantum bit (CQUB2) and the second quantum bit (QUB2) preferably form a nucleus-electron quantum register (CEQUREG), hereinafter referred to as second nucleus-electron quantum register (CEQUREG2), in an analogous manner as previously described.

Theoretically, the first nuclear quantum bit (CQUB1) and the second nuclear quantum bit (CQUB2) can form a nucleus-nuclear quantum register (CCQUREG) according to the preceding corresponding description. In the vast majority of cases, however, this will not be the case. We assume here as already described for simplicity that this is not the case, since the nucleus-nucleus coupling range is much smaller than the electron-electron coupling range.

More importantly, preferably, the first quantum bit (QUB1) and the second quantum bit (CQUB2) form an electron-electron quantum register (QUREG), as described previously, because this enables the transport of dependencies between the first nucleus-electron quantum register (CEQUREG1) and the second nucleus-electron quantum register (CEQUREG2). The electron-electron coupling range between the first quantum dot (NV1) of the first quantum bit (QUB1) of an electro-electron quantum register (QUREG) and the second quantum dot (NV2) of the second quantum bit (QUB2) of this electro-electron quantum register (QUREG), on the one hand, is typically larger than the nucleus-nucleus coupling distance between the first nuclear quantum dot (CI1) of the first nuclear quantum bit (CQUB1) of a nucleus-nuclear quantum register (CQUREG) and the second nuclear quantum dot (CI2) of the second nuclear quantum bit (CQUB2) of a nucleus-nuclear quantum register (CQUREG) on the other hand. Therefore, because of this higher electron-electron coupling range, an electron-electron quantum register (QUREG) can perform the function that the data bus has in a conventional computer. The electron-electron quantum register (QUREG) can thus also be replaced by a closed chain of n−1 electron-electron quantum registers (QUREG) with n as an integer positive number, which can also include branches and loops. Thus, the creation of complex quantum networks (QUNET) interconnecting the different nucleus-electron quantum registers (CEQUREG2) and comprising more than one n-bit electron-electron quantum register (QUREG) becomes possible. Here, the n-th quantum dot (NVn) of the n-th quantum bit (QUBn) may be spaced farther than the electron-electron coupling distance from the first quantum dot (NV1) of the first quantum bit (QUB1), so that direct coupling of the first quantum dot (NV1) of the first quantum bit (QUB1) with the n-th quantum dot (NVn) of the n-th quantum bit (QUBn) is no longer possible. However, due to the closed chain of n−1 two-bit electron-electron quantum registers (QUREG1 to QUREG(n−1)) between the first quantum bit (QUB1) and the n-th quantum bit (QUBn), indirect coupling is possible with the aid of this chain of n−1 two-bit electron-electron quantum registers (QUREG1 to QUREG(n−1)). Within such a chain of n-bit electron-electron quantum register (NBQUREG), two consecutive two-bit electron-electron quantum registers (QUREG) always comprise at least one quantum bit (QUB), more precisely the quantum dot (NV) of this quantum bit (QUB), in common.

Example of a Nucleus Electron Nucleus Electron Quantum Register (CECEQUREG) with Widely Spaced Nucleus Electron Quantum Registers

This possibility of long-distance coupling will now be illustrated in more detail using an example of two widely spaced nucleus-electron quantum registers, a first nucleus-electron quantum register (CEQUREG1) and an n-th nucleus-electron quantum register (CEQUREGn).

In this example, the first nucleus-electron quantum register (CEQUREG1) again comprises, as described above, a first quantum bit (QUB1) with a first quantum dot (NV1) and a first nuclear quantum bit (CQUB1) with a first nuclear quantum dot (CI1).

In this example, the n-th nucleus-electron quantum register (CEQUREGn) again comprises an n-th quantum bit (QUBn) with an n-th quantum dot (NVn) and an n-th nuclear quantum bit (CQUBn) with an n-th nuclear quantum dot (CIn), as described above.

The first quantum bit (QUB1) of the first nuclear quantum register (CEQUREG1) and its first quantum dot (NV1) in this example also represent the beginning of an n-bit electron-electron quantum register (NBQUREG). We can thereby think of this n-bit electron-electron quantum register (NBQUREG) as part of a larger quantum network (QUNET) of multiple n-bit electron-electron quantum registers (NBQUREG), wherein the number n of quantum bits (QB1 to QUBn) of the respective n-bit electron-electron quantum register (NBQUREG) may be different from one n-bit electron-electron quantum register (NBQUREG) of the quantum network (QUNET) to another n-bit electron-electron quantum register (NBQUREG) of the quantum network (QUNET).

In this example, the first quantum bit (QUB1) of the first nucleus-electron quantum register (CEQUREG1) and its first quantum dot (NV1) are thus also part of the n-bit electron-electron quantum register (NBQUREG) with n quantum bits (QUB1 to QUBn) and associated n quantum dots (NV1 to NVn). Through this, the first nuclear quantum dot (CI1) of the first nucleus-electron quantum register (CEQUTEG1) is connected to the n-bit electron-electron quantum register (NBQUREG) and thus to the quantum network (QUNET). The idea is, to exploit the typically long coherence time of the nuclear spins of the first nuclear quantum bit (CI1) and the n-th nuclear quantum bit (CIn) for performing quantum operations and to exploit the spatially long range of the coupling of the n quantum dots (NV1 to NVn) of the n quantum bits (QUB1 to QUBn) of the n-bit quantum register (NBQUREG) for transporting the dependencies over larger spatial distances than the nucleus-nucleus coupling range of the nuclear quantum dots (CI1, CIn).

Transferred to the concepts of a conventional computer system, the n-bit electron-electron quantum register (NBQUREG) with its n quantum dots (NV1 to NVn) in preferably n quantum bits (QUB1 to QUBn) thus represents what the data bus does in a conventional computer. However, while logical values are transported in a conventional data bus, dependencies are transported here in the construct called quantum bus (QUBUS), so that the connected nuclear quantum dots (CI1, CIn) can also be entangled with each other over greater distances. This has the advantage that the resulting quantum computer becomes scalable and a much larger number of quantum dots and nuclear quantum dots can be entangled with each other. In this process, even those nuclear quantum dots (CI1, CIn) can be entangled with each other using ancilla quantum dots, which cannot be directly entangled with each other due to their distance from each other. By a concatenation of several quantum dots (NV1 to NVn) also quantum dots (NV1. NVn) can be coupled and entangled with each other by the other quantum dots (NV2 to NV(n−1)) as Ancilla quantum dots, which cannot be directly entangled with each other because of their large distance to each other, in case of very long chains. Such a quantum bus (QUBUS) can also be called a long quantum bus (QUBUS). Due to the possibility of selectively controlling individual quantum dots (NV1 to NVn) and individual nuclear quantum dots and their pairings, it is thus possible to build a scalable quantum computer, in contrast to the state of the art.

Of course, each of the n quantum bits (QUB1 to QUBn) and thus each of the n quantum dots (NV1 to NVn) can itself be part of one of, say, n nucleus-electron quantum registers (CEQUREG1 to CEQUREGn). For the understanding of the proposal, however, the consideration of the quantum bits (QUB2 to QUB(n−1)) lying between the first quantum bit (QUB1) and the n-th quantum bit (QUBn) is perfectly sufficient, so we restrict ourselves to this here and, if necessary, neglect the nucleus-electron quantum registers of the n−2 quantum dots (NV2 to NV(n−1)) existing between the first quantum dot (NV1) and the n-th quantum dot (NVn).

In the simplest case, the quantum network (QUNET) thus consists of a single chain of interconnected two-bit electron-electron quantum registers (QUREG), which together form an n-bit quantum register (NBQREG) with n quantum bits (QUB1 to QUBn) and associated n quantum dots (NV1 to NVn). For better delineation, a quantum network (QUNET) is defined in this paper to include at least two n-bit electron-electron quantum registers (NBQUREG).

By means of the quantum network (QUNET) resp, the quantum bus (QUBUS), a first nuclear quantum dot (CI1) of the first nucleus-electron quantum register (CEQUREG1) and the n-th nucleus-electron quantum register (CEQUREGn) can now be coupled to or entangled with the n-th nucleus-electron quantum register (CEQUREGn) despite the smaller nucleus-nucleus coupling range of the first nuclear quantum dot (CI1) and the n-th nuclear quantum dot (CIn) of an n-th nucleus-electron quantum register (CEQUREGn), a first nuclear quantum dot (CI1) of the first nucleus electron quantum register (CEQUREG1) is coupled or entangled with the n-th nuclear quantum dot (CIn) of an n-th nucleus electron quantum register (CEQUREGn). In this context, the quantum bus (QUBUS) of the quantum network (QUNET) concerned comprises, as described earlier, in this example a concatenation of n−1 interconnected two-bit electron quantum registers (QUREG), all of which together form one n-bit quantum register (NBQREG) each. In this example, due to an exemplary spatial distance between the first nuclear quantum dot (CI1) and the n-th nuclear quantum dot(CIn) being assumed to be too large, the entanglement or coupling of the first nuclear quantum dot (CI1) and the n-th nuclear quantum dot (CIn) does not occur by direct coupling between them, but by using the n-bit electron-electron register (NBQUREG) for the transport of this dependence from the first nuclear quantum dot (CI1) to the n-th nuclear quantum dot (CIn) or in the reverse direction.

By such exemplary linear concatenation of then quantum dots (NV1 to NVn) of the n quantum bits (QUB1 to QUBn) of the n-bit electron-electron quantum register (NBQUREG) along an exemplary one-dimensional line within an n-bit quantum register (NBQUREG), for example along said vertical line (LV) or along said horizontal line (LH), the spatial distance (spin) between the first quantum dot (NV1) of the first quantum bit (QUB1) of the n-bit quantum register (NBQUREG) and the n-th quantum dot (NVn) of the n-th quantum bit (QUBn) of the n-bit quantum register (NBQUREG) may even be so large that even the first quantum dot (NV1) of the first quantum bit (QUB1) of the n-bit quantum register (NBQUREG) can no longer be directly coupled to the n-th quantum dot (NVn) of the n-th quantum bit (QUBn) of the n-bit quantum register (NBQUREG) or can be directly entangled.

For simplification, we again assume that the n quantum dots (NV) to NVn) of the n quantum dots (QUB1 to QUBn) are countably lined up along the said one-dimensional line. This one-dimensional line, as described, can also be curved or angular and also annularly closed. Thus, in this example, the n quantum dots (NV1 to NVn) and thus their respective quantum bits (QUB1 to QUBn) are to represent a quantum bus (QUBUS) of a quantum network (QUNET) in the form of a chain of n quantum dots (NV1 to NVn), which starts with the first quantum dot (NV1) of the first nucleus-electron quantum register (CEQUREG1) and ends with the n-th quantum dot (NVn) of the n-th nucleus-electron quantum register (CEQUREGn).

Here, the first quantum dot (NV1) of the first nucleus-electron quantum register (CEQUREG1) is also the first quantum dot (NV1) of the first quantum bit (QUB1) at the beginning of the n-bit electron-electron quantum register (NBQUREG).

Here, the n-th quantum dot (NVn) of the n-th nucleus-electron quantum register (CEQUREGn) is also the n-th quantum dot (NVn) of the n-th quantum bit (QUBn) at the end of the n-bit electron-electron quantum register (NBQUREG).

Within this quantum bus (QUBUS) of the quantum network (QUNET) in the form of the said chain of n quantum dots (NV1 to NVn) then quantum dots (NV1 to NVn) of the n-bit electron-electron-quantum register (NBQUREG) and thus also then quantum bits (QUB1 to QUBn) of the n-bit electron-electron quantum register (NBQUREG) are countable and can thus be numbered consecutively front 1 to n with whole positive numbers.

Thus within the chain of quantum dots (NV1 to NVn) of the quantum bus (QUBUS) of the quantum network (QUNET) a (j−1)-th quantum dot (NV(j−1)) precedes a j-th quantum dot (NVj), which in the following is called the predecessor quantum dot (NV(j−1)). Thus, within the chain, a (j−1)-th quantum bit (QUB(j−1)) with the (j)-th quantum dot (NVj) is preceded by a (j−1)-th quantum bit (QUB(j−1)) with the (j−1)-th quantum dot (NV(j−1)), which is called the predecessor quantum bit (QUB(j−1)) in the following.

Thus, within the chain of quantum dots (NV1 to NVn) of the quantum bus (QUBUS) of the quantum network (QUNET), a j-th quantum dot (NVj) is followed by a (j+1)-th quantum dot (NV(j+1)), which is called the successor quantum dot (NV(j+1)) in the following. Thus, within the chain, a (j+1)-th quantum bit (QUB(j+1)) with the (j+1)-th quantum dot (NVj) is followed by a (j+1)-th quantum bit (QUB(j+1)) with the (j+1)-th quantum dot (NV(j+1)), which is called the successor quantum bit (QUB(j−1)) in the following. Here, the index j with respect to this exemplary chain shall be here any integer positive number with 1<j<n, where n shall be an integer positive number with n>2.

Within the chain, the j-th quantum dot (NVj) then has a distance (sp(j−1)j), its predecessor distance. Preferably, this spatial distance (sp(j−1)j) between the j-th quantum dot (NVj) of the j-th quantum bit (QUBj) of the quantum register (QUREG) and the preceding (j−1)-th quantum dot (NV(j−1)) of the (j−1)-th quantum bit (QUB(j−1)) of the n-bit quantum register (NBQUREG) is so small, that the magnetic field of the preceding (j−1)-th quantum dot (NV(j−1)) of the (j−1)-th quantum bit (QUB(j−1)) of the n-bit quantum register (NBQUREG) influences the behavior of the j-th quantum dot (NVj) of the j-th quantum bit (QUBj) of the n-bit quantum register (NBQUREG) at least temporarily, and/or in that the magnetic field of the j-th quantum dot (NVj) of the j-th quantum bit (QUBj) of the n-bit quantum register (QUREG) influences the behavior of the preceding (j−1)-th quantum dot (NV(j−1)) of the (j−1)-th quantum bit (QUB(j−1)) of the n-bit quantum register (NBQUREG) at least temporarily. Preferably, the distance (sp(j−1)1) between the j-th quantum dot (NVj) of the j-th quantum bit (QUBj) of the n-bit quantum register (NBQUREG) of the quantum bus (QUBUS) of the quantum network (QUNET) and the preceding (j−1)-th quantum dot (NV(j−1)) of the (j−1)-th quantum bit (QUB(j−1)) of the n-bit quantum register (NBQUREG) of the quantum bus (QUBUS) of the quantum network (QUNET) is less than 50 nm and/or less than 30 nm and/or less than 20 nm and/or less than 10 nm and/or less than 10 nm and/or less than 5 nm and/or less than 2 nm, and/or the distance (sp(j−1)j) between the j-th quantum dot (NVj) of the j-th quantum bit (QUBj) of the n-bit quantum register (NBQUREG) of the quantum bus (QUBUS) of the quantum network (QUNET) and the preceding (j−1)-th quantum dot (NV(j−1)) of the (j−1)-th quantum bit (QUB(j−1)) of the n-bit quantum register (NBQUREG) of the quantum bus (QUBUS) of the quantum network (QUNET) between 30 nm and 2 nm and/or less than 10 nm and/or less than 5 nm and/or less than 2 nm.

Within the chain of quantum dots (NV1 to NVn) of the quantum bus (QUBUS) of the quantum network (QUNET), the j-th quantum dot (NVj) then has a distance (spj(j+1)), its successor distance. Preferably, for this purpose, this spatial distance (spj(j+1)) between the j-th quantum dot (NVj) of the j-th quantum bit (QUBj) of the n-bit quantum register (QUREG) of the quantum bus (QUBUS) of the quantum network (QUNET) and the subsequent (j+1)-th quantum dot (NV(j+1)) of the (j+1)-th quantum bit (QUB(j+1)) of the quantum register (QUREG) is so small, that the magnetic field of the subsequent (j+1)-th quantum dot (NV(j+1)) of the (j+1)-th quantum bit (QUB(j+1)) of the n-bit quantum register (NBQUREG) of the quantum bus (QUBUS) of the quantum network (QUNET) influences the behavior of the j-tenth quantum dot (NVj) of the j-th quantum bit (QUBj) of the n-bit quantum register (NBQUREG) of the quantum bus (QUBUS) of the quantum network (QUNET) is influenced at least temporarily, and/or in that the magnetic field of the j-th quantum dot (NVj) of the j-th quantum bit (QUBj) of the n-bit quantum register (NBQUREG) of the quantum bus (QUBUS) of the quantum network (QUNET) influences the behavior of the following (j+1)-(j+1)) of the (j+1)-th quantum bit (QUB(j+1)) of the n-bit quantum register (NBQUREG) of the quantum bus (QUBUS) of the quantum network (QUNET) at least temporarily. Preferably, for this purpose the distance (spj(j+1)) between the j-th quantum dot (NVj) of the j-th quantum bit (QUBj) of the n-bit quantum register (NBQUREG) of the quantum bus (QUBUS) of the quantum network (QUNET) and the subsequent (j+1)-th quantum dot (NV(j+1)) of the (j+1)-th quantum bit of the (j+1)-th quantum bit (QUB(j+1)) of the n-bit quantum register (NBQUREG) of the quantum bus (QUBUS) of the quantum network (QUNET) is less than 50 nm and/or less than 30 nm and/or less than 20 nm and/or less than 10 nm and/or less than 10 nm and/or less than 5 nm and/or less than 2 nm, and/or the distance (spj(j+1)) between the j-th quantum dot (NVj) of the j-th quantum bit (QUBj) of the n-bit quantum register (NBQUREG) of the quantum bus (QUBUS) of the quantum network (QUNET) and the subsequent (j+1)-th quantum dot (NV(j+1)) of the (j+1)-th quantum bit (QUBj) is less than 50 nm and/or less than 20 nm and/or less than 10 nm and/or less than 10 nm and/or less than 5 nm and/or less than 2 nm.

Within the chain of quantum dots (NV1 to NVn) of the quantum bus (QUBUS) of the quantum network (QUNET), the first quantum dot (NV1) then has a first distance (sp12), its successor distance. Preferably, this first spatial distance (sp12) between the first quantum dot (NV1) of the first quantum bit (QUB1) of the quantum register (QUREG) of the quantum bus (QUBUS) of the quantum network (QUNET) and the subsequent second quantum dot (NV2) of the second quantum bit (QUB2) of the n-bit quantum register (NBQUREG) of the quantum bus (QUBUS) of the quantum network (QUNET) is so small for this purpose, that the magnetic field of the subsequent second quantum dot (NV2) of the second quantum bit (QUB2) of the n-bit quantum register (NBQUREG) of the quantum bus (QUBUS) of the quantum network (QUNET) influences the behavior of the first quantum dot (NV1) of the first quantum bit (QUB1) of the n-bit quantum register (NBQUREG) of the quantum bus (QUBUS) of the quantum network (QUNET) at least temporarily, and/or in that the magnetic field of the first quantum dot (NV1) of the first quantum bit (QUB1) of the n-bit quantum register (NBQUREG) of the quantum bus (QUBUS) of the quantum network (QUNET) influences the behavior of the subsequent second quantum dot (NV2) of the second quantum bit (QUB2) of the n-bit quantum register (NBQUREG) of the quantum bus (QUBUS) of the quantum network (QUNET) at least temporarily. Preferably, the distance (sp12) between the first quantum dot (NV1) of the first quantum bit (QUB1) of the n-bit quantum register (NBQUREG) of the quantum bus (QUBUS) of the quantum network (QUNET) and the subsequent second quantum dot (NV2) of the second quantum bit (QUB2) of the n-bit quantum register (NBQUREG) of the quantum bus (QUBUS) of the quantum network (QUNET) is less than 50 nm and/or less than 30 nm and/or less than 20 nm and/or less than 10 nm and/or less than 10 nm and/or less than 5 nm and/or less than 2 nm, and/or the distance (sp12) between the first quantum dot (NV1) of the first quantum bit (QUB1) of the n-bit quantum register (NBQUREG) of the quantum bus (QUBUS) of the quantum network (QUNET) and the subsequent second quantum dot (NV2) of the second quantum bit (QUB2) of the n-bit quantum register (NBQUREG) of the quantum bus (QUBUS) of the quantum network (QUNET) between 30 nm and 2 nm and/or less than 10 nm and/or less than 5 nm and/or less than 2 nm.

Within the chain of the n quantum dots (NV1 to NVn) of the quantum bus (QUBUS) of the quantum network (QUNET), the n-th quantum dot (NVn) then has a distance (sp(n−1)n), its predecessor distance. Preferably, this spatial distance (sp(n−1)n) between the n-th quantum dot (NVn) of the n-th quantum bit (QUBn) of the n-bit quantum register (NBQUREG) of the quantum bus (QUBUS) of the quantum network (QUNET) and the preceding (n−1)-th quantum dot (NV(n−1)) of the (n−1)-th quantum bit (QUB(n−1)) of the n-bit quantum register (NBQUREG) of the quantum bus (QUBUS) of the quantum network (QUNET) is so small, that the magnetic field of the preceding (n−1)-th quantum dot (NV(n−1)) of the (n−1)-th quantum bit (QUB(n−1)) of the n-bit quantum register (NBQUREG) of the quantum bus (QUBUS) of the quantum network (QUNET) influences the behavior of the n-th quantum dot (NVn) of the n-th quantum bit (QUBn) of the n-bit quantum register (NBQUREG) of the quantum bus (QUBUS) of the quantum network (QUNET) is influenced at least temporarily, and/or that the magnetic field of the j-th quantum dot (NVn) of the n-th quantum bit (QUBn) of the n-bit quantum register (NBQUREG) of the quantum bus (QUBUS) of the quantum network (QUNET) influences the behavior of the preceding (n−1)-th quantum dot (NV(n−1)) of the (n−1)-th quantum bit (QUB(n−1)) of the n-bit quantum register (NBQUREG) of the quantum bus (QUBUS) of the quantum network (QUNET) is influenced at least temporarily. Preferably, the distance (sp(n−1)1) between the n-th quantum dot (NVn) of the n-th quantum bit (QUBn) of the n-bit quantum register (NBQUREG) of the quantum bus (QUBUS) of the quantum network (QUNET) and the preceding (n−1)-th quantum dot (NV(n−1)) of the (n−1)-th quantum bit (QUB(n−1)) of the n-bit quantum register (NBQUREG) of the quantum bus (QUBUS) of the quantum network (QUNET) is less than 50 nm and/or less than 30 nm and/or less than 20 nm and/or less than 10 nm and/or less than 5 nm and/or less than 2 nm, and/or the distance (sp(n−1)n) between the n-th quantum dot (NVn) of the n-th quantum bit (QUBn) of the n-bit quantum register (NBQUREG) of the quantum bus (QUBUS) of the quantum network (QUNET) and the preceding (n−1)-th quantum dot (NV(n−1)) of the (n−1)-th quantum bit (QUB(n−1)) of the n-bit quantum register (NBQUREG) of the quantum bus (QUBUS) of the quantum network (QUNET) is between 30 nm and 2 nm and/or less than 10 nm and/or less than 5 nm and/or less than 2 nm.

Within the chain of the n quantum dots (NV1 to NVn) of the quantum bus (QUBUS) of the quantum network (QUNET), the first quantum dot (NV1) can then have a distance (spin), its chain length, in relation to the n-th quantum dot (NVn). In this example, let this spatial distance (sp1n) be between the first quantum dot (NV1) of the first quantum bit (QUB1) of the n-bit quantum register (NBQUREG) of the quantum bus (QUBUS) of the quantum network (QUNET) at the beginning of the chain and the n-nth quantum dot (NVn) of the n-th quantum bit (QUBn) of the n-bit quantum register (NBQUREG) of the quantum bus (QUBUS) of the quantum network (QUNET) at the end of the chain of the n quantum dots (NV1 to NVn) of the quantum bus (QUBUS) of the quantum network (QUNET) must be so large that the magnetic field of the first quantum dot (NV1) of the first quantum bit (QUB1) of the n-bit quantum register (NBQUREG) of the quantum bus (QUBUS) of the quantum network (QUNET) at the beginning of the chain of the n quantum dots (NV1 to NVn) of the quantum bus (QUBUS) of the quantum network (QUNET) does not significantly directly influence the behavior of the n-th quantum dot (NVn) of the n-th quantum bit (QUBn) of the n-bit quantum register (NBQUREG) of the quantum bus (QUBUS) of the quantum network (QUNET) at the end of the chain of the n quantum dots (NV1 to NVn) of the quantum bus (QUBUS) of the quantum network (QUNET), and/or in that the magnetic field of the n-th quantum dot (NVn) of the n-th quantum bit (QUBn) of the n-bit quantum register (NBQUREG) of the quantum bus (QUBUS) of the quantum network (QUNET) at the end of the chain cannot significantly directly influence the behavior of the first quantum dot (NV1) of the first quantum bit (QUB1) of the n-bit quantum register (NBQUREG) of the quantum bus (QUBUS) of the quantum network (QUNET) at the beginning of the chain of then quantum dots (NV1 to NVn) of the quantum bus (QUBUS) of the quantum network (QUNET), but only with the help of the further n−2 quantum dots (NV2 to NV(n−1)) of the quantum bus (QUBUS) of the quantum network (QUNET) between the first quantum dot (NV1) and the n-th quantum dot (NVn).

The distances are now preferably such that the first nuclear quantum dot (CI1) of the first nucleus-electron quantum register (CEQUREG1) can no longer directly influence the n-th quantum dot (NVn) and the n-th nuclear quantum dot (CIn) of the n-th nucleus-electron quantum register (CEQUREG2). In particular, these distances are now preferably chosen such that a magnetic moment of the first nuclear quantum dot (CI1) of the first nucleus-electron quantum register (CEQUREG1) can no longer directly influence the magnetic moment of the n-th quantum dot (NVn) and/or the magnetic moment of the n-th nuclear quantum dot (CIn) of the n th nucleus-electron quantum register (CEQUREG2). Thus, the first nuclear quantum dot (CI1) of the first nucleus-electron quantum register (CEQUREG1) can no longer be readily entangled with the n-th quantum dot (NVn) and with the n-th nuclear quantum dot (CIn) of the n-th nucleus-electron quantum register (CEQUREG2), to entangle the first nuclear quantum dot (CI1) of the first nucleus-electron quantum register (CEQUREG1) with the n-th quantum dot (NVn) and/or with the n-th nuclear quantum dot (CIn) of the n-th nucleus-electron quantum register (CEQUREG2), but the state of the first nuclear quantum dot (CI1) of the first nucleus-electron quantum register (CEQUREG1) can be entangled with the state of the first quantum dot (NV1) of the first nucleus-electron quantum register (CQUREG1). Then, the state of the second quantum dot (NV2) of the second quantum bit (QUB2) of the n-bit electron-electron quantum register (NBQUREG) of the quantum bus (QUBUS) of the quantum network (QUNET) can be entangled with the state of the first quantum dot (NV1) of the first quantum bit (QUB1) of the n-bit electron-electron quantum register (NBQUREG) of the quantum bus (QUBUS) of the quantum network (QUNET). Then, the state of the third quantum dot (NV3) of the third quantum bit (QUB3) of the n-bit electron-electron quantum register (NBQUREG) of the quantum bus (QUBUS) of the quantum network (QUNET) can be entangled with the state of the second quantum dot (NV2) of the second quantum bit (QUB2) of the n-bit electron-electron quantum register (NBQUREG) of the quantum bus (QUBUS) of the quantum network (QUNET) to be entangled. This can thus be continued within the chain of n quantum dots (NV1 to NVn) of the quantum bus (QUBUS) of the quantum network (QUNET) in the form of the exemplary n-bit electron-electron quantum register (NBQUREG), until finally the state of the n-th quantum dot (NVn) of the n-th quantum bit (QUBn) of the n-bit electron-electron quantum register (NBQUREG) of the quantum bus (QUBUS) of the quantum network (QUNET) is entangled with the state of the (n−1)-th quantum dot (NV(n−1)) of the (n−1)-th quantum bit (QUB(n−1)) of the n-bit electron-electron quantum register (NBQUREG) of the quantum bus (QUBUS) of the quantum network (QUNET). In this way, the state of the n-th quantum dot (NVn) of the n-th quantum bit (QUBn) of the n-bit electron-electron-quantum register (NBQUREG) of the quantum bus (QUBUS) of the quantum network (QUNET) can be entangled with the state of the first quantum dot (NV1) of the first quantum bit (QUB1) of the n-bit electron-electron quantum register (NBQUREG) of the quantum bus (QUBUS) of the quantum network (QUNET). Thus, the state of the n-th quantum dot (NVn) of the n-th quantum bit (QUBn) of the n-bit electron-electron quantum register (NBQUREG) of the quantum bus (QUBUS) of the quantum network (QUNET) can also be entangled with the state of the first nuclear quantum dot (CI1) of the first nuclear quantum bit (CQUB1), if previously the state of the first quantum dot (NV1) of the first quantum bit (QUB1) of the n-bit electron-electron quantum register (NBQUREG) of the quantum bus (QUBUS) of the quantum network (QUNET) has been entangled with the state of the first nuclear quantum dot (CI1) of the first nuclear quantum bit (CQUB1). Finally, the state of the n-th nuclear quantum dot (an) of the n-th nuclear quantum bit (CQUBn) can then be entangled with the state of the n-th quantum dot (NVn) of the n-th quantum bit (QUBn) of the n-bit electron-electron quantum register (NBQUREG) of the quantum bus (QUBUS) of the quantum network (QUNET). As a result, the state of the n-th nuclear quantum dot (CIn) of the n th nucleus-electron quantum register (CQUREGn) is then also indirectly entangled with the state of the first nuclear quantum dot (CI1) of the first nuclear quantum bit (CQUB1) of the first nucleus-electron quantum register (CQUREG1) via the quantum bus (QUBUS) of the quantum network (QUNET) in the form of the exemplary n-bit electro-electron quantum register (NBQUREG), although a direct coupling and thus a direct entanglement of the state of the n-th nuclear quantum dot (CIn) of the n-th nucleus-electron quantum register (CQUREGn) with the state of the first nuclear quantum dot (CI1) of the first nuclear quantum bit (CQUB1) of the first nucleus-electron quantum register (CQUREG1) is not possible due to the too large spatial distance between the first nuclear quantum dot (CI1) and the n-th nuclear quantum dot (CIn).

Instead of the nucleus-electron quantum registers (CEQUREG1, CEQUREG2), two quantum ALUs (QUALU1, QUALU2) can also be used, which are interconnected by the electron-electron quantum register (QUREG) or the quantum bus (QUBUS) of the quantum network (QUNET). Preferably, a quantum network (QUNET) comprises at least two quantum buses (QUBUS) that are interconnected. In the broadest sense, however, a single quantum bus (QUBUS) can also already be regarded as a quantum network (QUNET).

What is particularly advantageous about the quantum bits (QUB) presented here is that they each have the described vertical line (LV) and horizontal line (LH). These lines can be applied with an electrical constant potential in addition to and superimposed on the control signals applied, if any, which detune the resonance frequencies of the associated quantum dots (NV) of the respective quantum bits (QUB) at a quantum dot position in the n-bit electron-electron quantum register (NBQUREG) of a quantum bus (QUBUS) and thus prevent further transport of dependencies from a nuclear quantum dot (CI1) beyond this position of the detuned quantum dot. Hereby, by applying static potential patterns to the control lines (LH, LV) of the quantum bits (QUB) of a quantum network (QUNET) with their quantum dots (NV), it is possible to detune individual quantum dots of this quantum network (QUNET) and thus make them insensitive to manipulation of their quantum states by control signals applied to the lines (LH, LV). By this, a subset of quantum bits (QUB) with their quantum dots (NV) can be made sensitive to the control signals within the quantum network, while the remaining set of quantum bits (QUB) with their quantum dots (NV) is made insensitive to these control signals. This can be used, for example, to divide an n-bit quantum register into an m-bit quantum register and a p-bit quantum register, where m+p=n should hold. This selectability of individual quantum bits (QUB) and their quantum dots (NV) or entire quantum bus sections and the scalability of the approach presented here together form a major advantage of the proposal.

Quantum Dot Arrays

### Construction of a Quantum Dot Array According to the Disclosure

As presented above, an important possible basis of the quantum computer system described herein is a one-dimensional army (FIG. 25) of quantum dots (QREG1D, QREG2D), which may have kinks (FIG. 26), branches (FIG. 27), and loops (FIG. 28) as part of a quantum bus system. In the mentioned figures, the quantum dots are part of the quantum ALUs shown in these figures. The quantum dots (NV11, NV12, NV13, NV21, NV22, NV23, NV31, NV32, NV33) are preferably arranged in a one-dimensional grid (QREG1D) or in a two-dimensional grid (QREG2D). Individual lattice sites of this one-dimensional lattice (QREG1D) or two-dimensional lattice (QREG2D) may not be occupied by quantum dots. It is important to note that preferably the remaining quantum dots form a graph of electron-electron quantum registers (QUREG).

For this to be possible, the arrangement of quantum dots (NV) presented herein should preferably be designed such that the distance (sp12) between two immediately adjacent quantum dots of the quantum dots (NV11, NV12, NV13, NV21, NV22, NV23, NV31, NV32, NV33) is smaller than 100 nm and/or is better smaller than 50 nm and/or is better smaller than 30 nm and/or is better smaller than 20 nm and/or is better smaller than 10 nm.

Preferably, all, but at least two quantum dots of the quantum dots (NV11, NV12, NV13, NV21, NV22, NV23, NV31, NV32, NV33) are each individually part of exactly one quantum bit as described before. As mentioned, several times before, when diamond is used as substrate (D), one or more quantum dots of the quantum dots (NV11, NV12, NV13, NV21, NV22, NV23, NV31, NV32, NV33) are an NV center or an SiV center or an ST1 center or an L2 center. Particularly preferred is the use of NV centers in diamond or G centers in silicon or V centers in silicon carbide due to better knowledge at the time of filing of this paper.

### Construction of a Nuclear Quantum Dot Array

Analogous to the arrangement of quantum dots, an arrangement of nuclear quantum dots (CQREG1D, CQREG2D) can be defined. Preferably, the nuclear quantum dots (CI11, CI12, CI13, CI21, CI22, CI23, CI31, CI32, CI33) are arranged at least approximately in a one-dimensional lattice (CQREG1D) or in a two-dimensional lattice (CQREG2D). Thereby, a unit cell of this lattice can be formed by several nuclear quantum dots. This is useful, for example, when a lattice of quantum ALUs is to be constructed. In this case, a lattice of quantum dots (NV11, NV12, NV13, NV21, NV22, NV23, NV31, NV32, NV33) is built. Preferably each of these quantum dots (NV11, NV12, NV13, NV21, NV22, NV23, NV31, NV32, NV33) is then assigned a group of nuclear quantum dots, the number of which is preferably but not necessarily always equal. Preferably, the arrangement of the nuclear quantum dots associated with such a quantum dot is also similar or the same from quantum ALU to quantum ALU. More importantly, the first coupling strength, and thus the associated first resonance frequency, between a quantum dot to a first nuclear quantum dot, of the nuclear quantum dots associated with that quantum dot, is different from the second coupling strength, and thus the associated second resonance frequency, between that quantum dot to a second nuclear quantum dot, of the nuclear quantum dots associated with that quantum dot.

As explained above, it is conceivable that the nuclear spins of the nuclear quantum dots are directly coupled to each other. For this, the nucleus spacing (sp12′) of two immediately adjacent nuclear quantum dots of the nuclear quantum dots (CI11, CI12, CI13, CI21, CI22, CI23, CI31, CI32, CI33) must be smaller than 200 μm and/or better smaller than 100 μm and/or better smaller than 50 μm and/or better smaller than 30 μm and/or better smaller than 20 μm and/or better smaller than 10 μm.

For the formation of a quantum ALU, which is a core element of the quantum computer concept presented here, it is particularly recommended that at least two nuclear quantum dots of the nuclear quantum dots (CI11, CI12, CI13, CI21, CI22, CI23, CI31, CI32, CI33) are each individually part of exactly one nuclear quantum bit (CQUB) as described above.

As described above, when diamond is used as substrate (D), it is useful if one or more nuclear quantum dots of the nuclear quantum dots (CI11, CI12, CI13, CI21, CI22, CI23, CI31, CI32, CI33) are one or more atomic nuclei of a ¹³C isotope.

As described above, when silicon is used as substrate (D), it is useful if one or more nuclear quantum dots of the nuclear quantum dots (CI11, CI12, CI13, CI21, CI22, CI23, CI31, CI32, CI33) are one or more atomic nuclei of a ²⁹Si isotope.

As described above, when silicon carbide is used as substrate (D), it is useful if one or more nuclear quantum dots of the nuclear quantum dots (CI11, CI12, CI13, CI21, CI22, CI23, CI31, CI32, CI33) are one or more atomic nuclei of a ²⁹Si isotope or one or more nuclear quantum dots of the nuclear quantum dots (CI11, CI12, CI13, CI21, CI22, CI23, CI31, CI32, CI33) are one or more atomic nuclei of a ¹³C isotope.

Since NV centers are a preferred variant of realization of the quantum dots here when diamond is used as the material of the substrate (D), it is preferred if then one or more nuclear quantum dots of the nuclear quantum dots (CI11, CI12, CI13, CI21, CI22, CI23, CI31, CI32, CI33) are an atomic nucleus of a ¹⁵N isotope placed in diamond as the substrate (D). This makes it possible, for example, by means of implantation in diamond of a molecule having a ¹⁵N isotope and multiple ¹³C isotopes, to fabricate in a single step a quantum ALU with a NV center and multiple nuclear quantum bits of ¹³C isotopes and a nuclear quantum bit in the form of the ¹⁵N isotope as the nitrogen atom of the NV center in diamond. Also, it is possible that in this case one nuclear quantum dot of the nuclear quantum dots (CI11, CI12, CI13, CI21, CI22, CI23, CI31, CI32, CI33) is an atomic nucleus of ¹⁴N isotope in diamond as substrate (D).

Method of Operation of the Quantum Computer

In the following, various procedures are described that are required for the operation of the described quantum computer, or are useful for it.

Preferably, the following methods for operating a quantum computer are controlled and performed by a control device (μC). The control device (μC) may be, for example, a microcomputer or a finite state machine. For operation, binary codes are stored in a memory of the control device (μC) via a data bus (DA). The storage is done according to an order parameter. This can be, for example, a memory address. These binary codes symbolize one of the following procedures or combination and/or sequences (which is also a combination) of these. These binary codes are then retrieved from memory depending on the ordering parameter. For example, it may be a quantum computer program counter that is incremented by a value of 1 with each process step. This then points directly or indirectly to the next memory location in memory and thus to the binary code of the process to be executed next. The control device (μC) thus then processes at least a subset of these binary codes as a function of the order parameter. The control device (μC) then executes the symbolized procedures and/or combinations thereof with the aid of the further auxiliary devices. Preferably, each binary code thereby corresponds to a partial procedure for manipulating the quantum dots or the nuclear quantum dots.

### Prepratory Processes

The preparatory processes described below are needed to determine the different coupling strengths within the previously described registers. These coupling strengths are expressed in different resonance frequencies. In order to be able to operate the quantum computer and/or its components, these resonance frequencies are measured once and preferably stored in a memory of a control computer (μC) or a memory to which the control computer (μC) has access. When selectively controlling the quantum dots, or nuclear quantum dots, or quantum registers, or nuclear quantum registers, or nucleus-electron quantum registers, these determined frequencies are used by the control device (μC) to selectively drive these device components.

### Frequency Determination Method

The first method determines the resonance frequency of each individual drivable quantum dot (NV) of the quantum computer or sub-device as described above.

This resonance frequency is hereinafter referred to as electron1-electron1 microwave resonance frequency (f_{MW}). The applied method is therefore a method for preparing the change of the quantum information of a first quantum dot (NV1), in particular the electron configuration of the first quantum dot (NV1), of a first quantum bit (QUB1), as described before, depending on the quantum information of this first quantum dot (NV1), in particular the first spin of the first electron configuration of the first quantum dot (NV1), of the first quantum bit (QUB1). For this purpose, the determination of the energy shift of the first quantum dot (NV1), in particular of its first electron configuration, in particular when the spin of the first electron configuration is spin-up or when the spin of the first electron configuration is spin-down, is carried out by means of an ODMR experiment by means of the tuning of the frequency (f) of an electromagnetic radiation incident on the quantum dot and the determination of an electron1-electron1 microwave resonance frequency (f_{MW}).

The second method determines the resonance frequency of each single drivable pair of two quantum dots (NV1, NV2) of the quantum computer or sub-device as described above. Thus, in contrast to the preceding procedure, this procedure does not involve the manipulation of a single quantum dot, but now involves the coupling of a first quantum dot with a second quantum dot that is different from the first quantum dot.

This resonance frequency is hereinafter referred to as electron1-electron2 microwave resonance frequency (f_{MWEF}). The applied method is therefore a method for preparing the change of the quantum information of a first quantum dot (NV1), in particular the spin of the electron configuration of the quantum dot (NV1), of a first quantum bit (QUB1) of a quantum register (QUREG), as previously described, as a function of the quantum information of a second quantum dot (NV2), in particular of the second spin of the second electron configuration of the second quantum dot (NV2), of a second quantum bit (QUB2) of this quantum register (QUREG). The method comprises determining the energy shift of the first quantum dot (NV1), in particular its first electron configuration, in particular when the spin of the second electron configuration is spin-up or when the spin of the second electron configuration is spin-down, by means of an ODMR experiment by tuning the frequency (f) and determining an electron1-electron2 microwave resonance frequency (f_{MWEF}).

The third method determines the resonance frequency of each single drivable pair of a quantum dot (NV1) and a nuclear quantum dot (CI) of the quantum computer or sub-device as described above. Thus, in contrast to the preceding procedure, this procedure does not involve the manipulation of a single quantum dot or a pair of two quantum dots, but now involves the coupling of a first quantum dot to a first nuclear quantum dot.

The resonance frequency for changing the quantum information of a quantum dot (NV), in particular the spin of its electron configuration, of a quantum bit (QUB) of a nucleus-electron quantum register (CEQUREG) as a function of the quantum information of a nuclear quantum dot (CI) is denoted hereafter by nucleus-electron microwave resonance frequency (f_{MWCE}).

The resonance frequency for changing the quantum information of a nuclear quantum dot (CI) as a function of the quantum information of a quantum dot (NV), in particular the spin of its electron configuration, of a quantum bit (QUB) of a nucleus-electron quantum register (CEQUREG) is denoted hereafter by electron-nucleus radio wave resonance frequencies (f_{RWEC}).

The method for determining the nucleus-electron microwave resonance frequency (f_{MWCE}) is therefore a method for preparing the change of the quantum information of a quantum dot (NV), in particular the spin of its electron configuration, of a quantum bit (QUB) of a nucleus-electron quantum register (CEQUREG), as described above, as a function of the quantum information of a nuclear quantum dot (CI), in particular the nuclear spin of its nucleus, of a nuclear quantum bit (CQUB) of this nucleus-electron quantum register (CEQUREG). The method comprises determining the energy shift of the quantum dot (NV), in particular its electron, especially when the nuclear spin is spin up or when the nuclear spin is spin down, by means of an ODMR experiment by tuning the frequency (f) and determining a nucleus-electron microwave resonance frequency (f_{MWCE}).

The electron-nucleus radio wave resonance frequency (fame) determination method, on the other hand, is a method for preparing the change of the quantum information of a nuclear quantum dot (CI), in particular the nuclear spin of its atomic nucleus, of a nuclear quantum bit (CQUB) of a nucleus-electron quantum register (CEQUREG), as described above, as a function of the quantum information of a quantum dot (NV), in particular the spin of its electron configuration, of a quantum bit (QUB) of said nucleus-electron quantum register (CEQUREG). The method comprises determining the energy shift of a quantum dot (NV), in particular its electron configuration, especially when the nuclear spin is spin up or when the nuclear spin is spin down, by means of an ODMR experiment by tuning the frequency (f) and determining the electron-nucleus radio wave resonance frequencies (f_{RWEC}).

For the sake of completeness, the coupling of two nuclear spins is also discussed here. Here, the method is a method for preparing the change of the quantum information of a first nuclear quantum dot (CI1), in particular the nuclear spin of its atomic nucleus, of a first nuclear quantum bit (CQUB) of a nucleus-nuclear quantum register (CCQUREG) depending on the quantum information of a second nuclear quantum dot (CI2), in particular the nuclear spin of the second nuclear quantum dot (Ci2), of a second nuclear quantum bit (CQUB2) of this nucleus-nuclear quantum register (CCQUREG). The method comprises determining the energy shift of a first nuclear quantum dot (CI1), in particular its first nuclear spin, in particular when the second nuclear spin of the second nuclear quantum dot (CI2) is spin up or when the second nuclear spin is spin down, by means of an ODMR experiment by tuning the frequency (f) and determining the nucleus-nucleus radio wave resonance frequencies (f_{RWCC}).

In the following, it is now assumed that the previously described nucleus-nucleus radio wave resonance frequencies (f_{RWCC}), electron-nucleus radio wave resonance frequencies (f_{RWEC}), nucleus-electron microwave resonance frequencies (f_{MWCE}), electron1-electron2-microwave resonance frequencies (f_{MWEF}), and electron1-electron1-microwave resonance frequencies (f_{MW}) for the electromagnetic control fields and thus for the electrical control currents of the horizontal and vertical lines (LH. LV) are known. The corresponding values for the quantum computer components to be manipulated, which was described before, are preferably stored in a memory of the control computer (μC) or a memory accessible to it.

The control computer (μC) then configures means (HD1, HD2, HD3, VD1, HS1, HS2, HS3, VS1) for each operation in such a way that these means (HD1, HD2, HD3, VD1, HS1, HS2, HS3, VS1) preferably start with the start signal of the control computer (μC) or another, preferably controlled by the control computer (μC), generate the necessary current bursts and/or electromagnetic wave bursts with the correct frequency and the correct envelope.

### Individual Operations

In the following, important single operations are described which are necessary to use the quantum computer proposed here. Preferably, certain binary codes symbolize these single operations. These single operations can be combined into sequences of instructions. These instruction sequences correspond to sequences of binary codes executed by the control computer (μC). Preferably, a control device, for example a control computer (μC), controls the time sequence of the individual operations presented here. Preferably, the control computer (μC) or the control device executes a program code of binary numbers in which at least a part of the binary numbers represents a predetermined sequence of individual operations.

A single operation code of said binary program of the control computer (μC) triggers an operation of the control computer (μC), which may preferably consist of one or more single operations, which are preferably executed sequentially in time or in parallel. For this purpose, the control computer (μC) increments a program counter (PCN) and determines the binary value of the current single operation code at the memory location corresponding to the program counter (PCN) in its program memory containing the binary code. The control computer (μC) is preferably a conventional computer in von Neumann or Harvard architecture. The control computer (μC) then generates the temporally correct sequences of the various control signals for the horizontal and vertical lines (LH, LV) of the quantum bits (QUB) of the quantum computer and the relevant auxiliary aggregates, such as luminous means for generating “green light” for irradiating the quantum dots (NV) of the quantum bits (QUB) with green light according to the binary value of the program code at the memory location. Preferably, such binary value of the program code refers to sub-routines of single operation codes to be able to generate more complex sequences.

In the following, we assume that the quantum computer has n quantum bits (QUB1 to QUBn) linearly arranged along a horizontal line (LH1). Let each j-th quantum bit (QUBj), with 1≤j≤n, of the n quantum bits (QUB1 to QUBn) be associated with a j-th vertical line (LVj), with 1≤j≤n, of the n vertical lines (LV1 to LVn). To then quantum bits (QUB1 to QUBn) correspond their n quantum dots (NV11 to NV1n). For the situation n=3 a linear arrangement of the quantum bits (QUB1 to QUBn) in the form of a one-dimensional quantum register (QREG1D) is simplified as a schematic sketch of FIG. 10 exemplarily given here to clarify what is meant.

### Quantum Bit Reset Method

One of the most important single operations of a quantum computer in this context is a procedure for resetting a quantum dot (NV) of a previously described quantum bit (QUB) to a predefined state. The procedure is preferably triggered, for example, by a reset code in said binary program of the control computer (μC).

For this purpose, the control computer (μC) activates a light emitting device (LED) that can irradiate the respective j-th quantum dot (QUBj) of the n quantum dots (QUB1 to QUBn) with green light. Here, the device can have optical functional means such as mirrors, lenses, optical waveguides, etc., which guide the green light of the illuminant (LED) to the respective j-th quantum dot (QUBj) of then quantum dots (QUB1 to QUBn). Preferably, the resetting is performed in such a way that all quantum dots (NV1 to NVn) of all quantum bits (QUB1 to QUBn) of the quantum computer are reset simultaneously by irradiation with “green light” of one or more illuminants (LED) or a function-equivalent radiation. Thus, irradiation of at least one quantum dot (NV) of the quantum dots (NV1 to NVn) with light functionally equivalent to irradiation of an NV center in diamond when using this NV center as a quantum dot (NV) with “green light” is performed with respect to the effect of this irradiation on the quantum dot (NV).

In the case of an NV center (NV) in diamond as the material of the substrate (D), irradiation with “green light” in accordance with the present disclosure leads to a reset of the quantum information. In the exemplary use of a NV center (NV) in diamond as a quantum dot (NV), the “green light” preferably has a wavelength in a wavelength range of 400 nm to 700 nm wavelength and/or better 450 nm to 650 nm and/or better 500 nm to 550 nm and/or better 515 nm to 540 nm. In the course of developing the technical content of this paper, a wavelength of 532 nm of electromagnetic reset radiation generated by a laser (LED) gave good results. Also, good results were obtained with a green laser diode with 520 nm wavelength. In the case of using other substrates (D) and/or other quantum dots, an electromagnetic radiation is called “green light” in the sense of this writing if this irradiation with this electromagnetic radiation has a functionally similar effect on the quantum dot (NV) in question, such as the previously described irradiation of an NV center in diamond with electromagnetic radiation in a wavelength range from 400 nm to 700 nm wavelength and/or better 450 nm to 650 nm and/or better 500 nm to 550 nm and/or better 515 nm to 540 nm and/or optimally with a wavelength of 532 nm. In the case of NV centers in diamond, a laser diode of the company Osram of the type PLT5 520B with 520 nm wavelength has proven to be an exemplary source of “green light” for the irradiation of NV centers in diamond as the material of the substrate (D). This functionally equivalent light is referred to in this paper quite generally as “green light” and is therefore defined not by visual impression but by its functionality in the proposed device.

### Nuclear Quantum Bit Reset Method or Quantum ALU Reset Method

In the following section, the resetting of a nucleus-electron quantum register (CEQUREG) as described above is illustrated. As described previously, the quantum bit (QUB) of the of a nucleus-electron quantum register (CEQUREG) can be understood as a terminal for the connection of a chain of quantum registers (QUREG), for example, in the form of an n-bit quantum register (NBQUREG). Via this terminal of the quantum dot (NV) of the quantum bit (QUB) of the nucleus-electron quantum register (CEQUREG), the erasing operation of the nuclear quantum bit (CQUB) of the nucleus-electron quantum register (CEQUREG) is preferably performed, since the direct access to the nuclear quantum dot (CI) of the nuclear quantum bit (CQUB) of the nucleus-electron quantum register (CEQUREG) is difficult, to reset this nuclear quantum dot (CI) of the nuclear quantum bit (CQUB) of the nucleus-electron quantum register (CEQUREG), the quantum dot (NV) of the quantum bit (QUB) of the nucleus-electron quantum register (CEQUREG) is first reset. This is done as described above by irradiating the quantum dot (NV) of the quantum bit (QUB) of the nucleus-electron quantum register (CEQUREG) with green light. The first step is thus the single operation of erasing the quantum information of the quantum dot (NV) of the quantum bit (QUB) of the nucleus-electron quantum register (CEQUREG).

Now, in a second quantum operation, the control computer (NC) preferably changes the quantum information of the nuclear quantum dot (CI) of the nuclear quantum bit (CQUB) of the nucleus-electron quantum register (CEQUREG) depending on the quantum information of the quantum dot (NV). In particular, the preferred nuclear spin of the nucleus of the nuclear quantum dot (CI) of the nuclear quantum bit (CQUB) of the nucleus-electron quantum register (CEQUREG) is changed in this case. Preferably, the change occurs as a function of the electron spin of the electron configuration of the quantum dot (NV) of the quantum bit (QUB) of this nucleus-electron quantum register (CEQUREG) or the electron spin of an electron of the quantum dot (NV) of the quantum bit (QUB) of this nucleus-electron quantum register (CEQUREG). Preferably, the change of the quantum information of the nuclear quantum dot (CI), in particular of the nuclear spin of its atomic nucleus, of the nuclear quantum bit (CQUB) of the nucleus-electron quantum register (CEQUREG) is carried out as a function of the quantum information of the quantum dot (NV), in particular of the electron spin of its electron or its electron configuration, of the quantum bit (QUB) of this nucleus-electron quantum register (CEQUREG) by means of a method as described previously.

Single Bit Manipulations

### Quantum Bit Manipulation Method

We now describe a method for manipulating a single quantum bit (QUB). We assume here that the quantum bit (QUB) corresponds in particular to one of the previously described quantum bit constructions. Now, to drive the quantum dot (NV) of the quantum bit (QUB), a temporary energization of the horizontal line (LH) is performed. Here, the associated horizontal driver stage (HD) preferentially feeds a horizontal microwave current in to the horizontal line (LH) modulated at the electron1-electron1 microwave resonance frequency (fMW). This is only the centroid frequency of the current signal. In reality it is a burst. The timing of the burst alone, with a start time and an end time, results in a modification of the spectrum that will not be considered further here. The start time and the end time correspond to a temporary energization. The horizontal current (IH) injected by the horizontal driver stage (HD) thus has a horizontal current component modulated by an electron1-electron1 microwave resonance frequency (fMW) with a horizontal modulation. In an analogous manner, the vertical line (LV) is energized intermittently with a vertical current (IV) having a vertical current component modulated with the electron-electron microwave resonance frequency (fMW) with a vertical modulation. Here, the associated vertical driver stage (VD) preferably feeds a vertical microwave current in to the horizontal line (LH) modulated with the electron1-electron1 microwave resonance frequency (fMW). Again, a current burst is used that has a temporal onset and a temporal termination. Thus, the vertical current is also only temporal. Preferably, however, the temporal onset of the vertical current burst is shifted in time relative to the temporal onset of the horizontal current burst. Thus, the horizontal modulation of the horizontal current component is preferably phase-shifted in time by +/−90° with respect to the vertical modulation of the vertical current component. This results in a left or right polarized microwave field at the location of the quantum dot (NV), which can then be manipulated using this microwave field. The temporal difference between the temporal end of the vertical current burst and the temporal beginning of the vertical current burst is the vertical pulse duration. The temporal difference between the temporal end of the horizontal current burst and the temporal beginning of the horizontal current burst is the horizontal pulse duration. Preferably, the vertical pulse duration and the horizontal pulse duration are approximately equal. Thus, the vertical current component is preferably pulsed with a vertical current pulse having a pulse duration and the horizontal current component is preferably pulsed with a horizontal current pulse having a pulse duration. In order to generate the circular polarization of the microwave electromagnetic field at the quantum dot (NV) location of the quantum bit (QUB), the vertical current pulse is preferably phase shifted with respect to the horizontal current pulse by +/−π/2 of the period of the electron-electron microwave resonance frequency (fMW). The control computer (KC) thereby sets the horizontal driver stage (HD) and the vertical driver stage (VD) in such a way that these are preferably synchronized with the aid of a synchronization signal and generate the respective horizontal current pulse and vertical current pulse in the correct phase.

Preferably, the temporal pulse duration of the horizontal current pulse and the temporal pulse duration of the vertical current pulse correspond to a temporal pulse duration corresponding to a temporal phase difference of π/4 or π/2 (Hadamard gate) or 3π/4 or it (not-gate) of the Rabi oscillation of the quantum dot (NV). In the case of a pulse duration of π/2, the term Hadamard gate or Hadamard operation is used in the following. In the case of a pulse duration of π, the term NOT gate or NOT operation is used in the following. Alternatively, an operation can preferably be defined such that the temporal pulse duration of the horizontal current pulse and the temporal pulse duration of the vertical current pulse correspond to a temporal pulse duration corresponding to a phase difference of an integer multiple of π/4 of the Rabi oscillation of the quantum dot (NV).

If a quantum bit (QUBj) (1≤j≤n) of several quantum bits (QUB1 to QUBn) (n>1, n∈N) of an overall device must be driven, the spectrum of the microwave burst to be used is decisive in that it decides on the coupling with other quantum bits of the n quantum bits (QUB1 to QUBn). This is achieved by a suitable design of the transient phase and the decay phase of the microwave burst. Thus, a current pulse for generating a microwave pulse preferably has a transient phase and a decay phase, and the current pulse has an amplitude envelope. The pulse duration of the current pulse then refers to the time interval of the instants of the 70% amplitude of the amplitude envelope relative to the maximum amplitude of the amplitude envelope of the current pulse for generating the microwave signal.

### Nuclear Quantum Bit Manipulation Method

In the preceding section, we discussed how to directly manipulate the quantum state of an electron or the electron configuration of a quantum dot (NV) of a quantum bit (QUB). Now, the analogous procedure for a nuclear quantum bit (CQUB), as previously described, will be considered.

As is readily apparent by comparison of FIGS. 1 and 2, the device for directly controlling the nuclear quantum dot (CI) of a nuclear quantum bit (CQUB) is virtually the same as the device for controlling the quantum dot (NV) of a quantum bit (QUB). In the devices of FIGS. 1 and 2, this device consists of a horizontal line (LH) and a vertical line (LV) that cross over the quantum dot (NV) and the nuclear quantum dot (CI), respectively.

The control of a nuclear quantum dot (CI) is therefore analogous to the control of a quantum dot (NV). Since the mass of an electron or electron configuration of a quantum dot (NV) is less than the mass of an atomic nucleus of a nuclear quantum dot (CI), manipulations of the nuclear quantum dot (CI) require a second nucleus-nucleus radio wave frequency (fRWCC2) that is smaller in magnitude than the magnitude of the electron-electron microwave resonance frequency (fMW) used to manipulate the quantum dot (NV).

The method for manipulating the quantum information of the nuclear quantum dot (CI) therefore comprises, analogously to controlling the quantum dot (NV) of a quantum bit (QUB), energizing the horizontal line (LH) of the nuclear quantum bit (CQUB) with a horizontal current (IH) having a horizontal current component modulated with a first nucleus-nucleus radio wave frequency (fRWCC) and/or with a second nucleus-nucleus radio wave frequency (fRWCC2) as modulation frequency with a horizontal modulation. Further, in an analogous manner, the method comprises energizing the vertical line (LV) of the nuclear quantum bit (CQUB), preferably slightly delayed, with a vertical current (IV) having a vertical current component modulated with the modulation frequency with a vertical modulation. As in the case of controlling a quantum dot (NV), it is useful to use left or right polarized electromagnetic waves at the location of the nuclear quantum dot (CI) to manipulate the nuclear quantum dot (CI). For this purpose, the horizontal modulation of the horizontal current component is preferably phase-shifted in time by +/−90° with respect to the vertical modulation of the vertical current component. Here, +/−π/2 refers to the phase position of the modulation components of the vertical current component and die horizontal current component with nucleus-nucleus radio wave frequency (fRWCC2) relative to each other. As before in the case of manipulating a quantum dot (NV), the vertical current component is pulsed with a vertical current pulse having a pulse duration and the horizontal current component is pulsed with a horizontal current pulse having a pulse duration. Alternatively, this can be expressed as preferably the vertical current pulse is phase shifted relative to the horizontal current pulse by +/−π/4 or better+/−π/2 of the period of the first nucleus-to-nucleus radio wave frequency (fRWCC) or by +/−π/4 or better +/−π/2 of the period of the second nucleus-to-nucleus radio wave frequency (fRWCC2). Preferably, the temporal pulse duration of the horizontal current pulse and the vertical current pulse has a pulse duration corresponding to a phase difference of π/4 or π/2 (Hadamard gate) or 3π/4 or π (not-gate) of the period of the Rabi oscillation nuclear quantum dot (CI) of the first nuclear quantum bit (CQUB). In other words, the temporal pulse duration of the horizontal current pulse and the vertical current pulse has a pulse duration corresponding to a phase difference of an integer multiple of π/4 of the period duration of the Rabi oscillation nuclear quantum dot (CI) of the first nuclear quantum bit (CQUB).

Preferably, the temporal pulse duration of the horizontal current pulse and the temporal pulse duration of the vertical current pulse correspond to a temporal pulse duration corresponding to a temporal phase difference of π/4 or π/2 (Hadamard gate) or 3π/4 or π (not-gate) of the Rabi oscillation of the nuclear quantum dot (CI). In the case of a pulse duration of π/2, the term Hadamard gate or Hadamard operation is used in the following. In the case of a pulse duration of π, the term NOT gate or NOT operation is used in the following. Alternatively, an operation can preferably be defined such that the temporal pulse duration of the horizontal current pulse and the temporal pulse duration of the vertical current pulse correspond to a temporal pulse duration corresponding to a phase difference of an integer multiple of π/4 of the Rabi oscillation of the nuclear quantum dot (CI).

If a nuclear quantum dot (CIj) of several nuclear quantum dots (CI1 to CIn) of an overall device, e.g., a quantum ALU as will be explained in the following, has to be driven, the spectrum of the radio wave burst to be used is decisive in that it decides on the coupling with other nuclear quantum dots of the n nuclear quantum dots (CI1 to CIn). This is achieved by a suitable design of the transient phase and the decay phase of the radio wave burst. A current pulse for generating a radio wave pulse (=radio wave burst) therefore preferably has a transient phase and a decay phase, with the current pulse having an amplitude envelope. The pulse duration of the current pulse then refers to the time interval between the times of the 70% amplitude of the amplitude envelope relative to the maximum amplitude of the amplitude envelope of the current pulse for generating the radio wave signal.

The nuclear quantum bit manipulation method is listed here only for the sake of completeness. For the operation of the quantum computer, it has a minor importance at the time of filing this paper.

Quantum Register Single Operations

### Selective Manipulation Methods for Single Quantum Bits in Quantum Registers

Selective Drive Method for Controlling a Single Quantum Bit of a Quantum Resister without

### Essentially Affecting the Other Quantum Bits of the Quantum Register in Question

In this section, we discuss how the quantum information of a single quantum bit (QBj) of an n-bit quantum register (NBQUREG) with n quantum bits (QUB) to QUBn) can be changed with 1≤j≤n with high probability without changing the quantum information of the n−1 other quantum bits (QUB1 to QUB(i−1) and QUB(j+1) to QUBn) of the n quantum bits (QUB1 to QUBn). This is thus a very basic operation as it describes the addressing of individual quantum bits (QUBj) of the n quantum bits (QUB1 to QUBn) of the n-bit quantum register (NBQUREG).

To describe the process, it is assumed that j=1, i.e., it is the first quantum bit (QUB1). However, the procedure can also be applied to all other quantum bits of a one- or two-dimensional quantum register. The quantum register and the quantum bits preferably correspond to the quantum bits and quantum registers described previously.

Thus, the exemplary method described herein is an exemplary method for selectively controlling a first quantum bit (QUB1) of an exemplary n-bit quantum register (NBQUREG) as previously described. Previously, it was exemplarily assumed that the quantum bits (QUB1 to QUBn) are arranged along the first horizontal line (LH1) to be common to the exemplary n quantum bits (QUB1 to QUBn) of the exemplary n-bit quantum register (NBQUREG). It is expressly noted that this arrangement is used herein only as an example to simplify the description and that other arrangements are possible and are encompassed by the claim.

For addressing, the method comprises the step of temporarily energizing the exemplary common first horizontal line (LH1) of the n-bit quantum register (NBQUREG) with a first horizontal current component of the first horizontal current (IH1) modulated at a first horizontal electron1-electron1 microwave resonance frequency (fMWH1) with a first horizontal modulation. Thus, a first horizontal current burst or current pulse is injected into the first horizontal line (LH1). According to the exemplary design, all quantum bits of the n-bit quantum register (NBQUREG) along the first horizontal line (LH1) are thus exposed to the resulting magnetic field. Further, the exemplary method comprises temporarily energizing the first vertical line (LV1) of the n-bit quantum register (NBQUREG) with a first vertical current component of the first vertical current (IV1) modulated at the first vertical electron1-electron1 microwave resonance frequency (fMWV1) with a first vertical modulation. The magnetic field of this first vertical current stream component of the first vertical current (IV1) thus mainly affects the first quantum dot (NV1) of the first quantum bit (QUB1) and, to a much lesser extent, the neighboring quantum dots of the neighboring quantum bits, with the influence decreasing rapidly with increasing distance. Thus, a first vertical current burst or current pulse is injected into the first vertical line (LV1).

In order not to address the other quantum dots of the other quantum bits of the n quantum bits (QUB1 to QUBn) and in particular the immediately adjacent quantum dots of the adjacent quantum bits by the vertical current pulse and/or the horizontal current pulse, the resonance frequencies of these quantum bits not to be addressed are deliberately detuned. This detuning can be done, for example, by static DC currents in the associated vertical lines of these quantum bits not to be addressed, or by electrostatic potentials on these vertical lines resulting in electric field strengths at the location of the quantum dots of these quantum bits not to be addressed that detune these resonance frequencies. This detuning causes these detuned quantum dots to no longer resonate with the vertical electron1-electron1 microwave resonance frequency (fMWV1) and/or the horizontal electron1-electron1 microwave resonance frequency (fMWH1). Thus, the quantum information of the quantum dots of these detuned quantum bits of the n quantum bits (QUB1 to QUBn) is not affected by the vertical current pulse and/or the horizontal current pulse.

Thus, the function is disclosed here, which corresponds to the function of an address decoder in a conventional computer with Von Neumann or Harvard architecture.

This method for selecting one or more individual quantum bits in the set of n-quantum bits of an n-bi-quantum register (NBQUREG) is an essential aspect of the technical teaching presented here. By means of this methodology, single quantum bits but also groups of two or more quantum bits, for example single two-bit quantum registers within multi-bit quantum registers, can be addressed by detuning the quantum bits not to be addressed and controlling them at the appropriate resonance frequency.

The detuning is explained on the pairing of a first quantum bit (QUB1) and a second quantum bit (QUB2). It can be extended to other pairings of, for example, an i-th quantum bit (QUBi) with a j-th quantum bit (QUBj). Thus, for example, k quantum bits can then be addressed and n-k quantum bits of an exemplary n-bit quantum register (NBQUREG) can be detuned so that only k quantum bits of said exemplary n-bit quantum register (NBQUREG) are addressed with n quantum bits (QUB1 to QUBn). Particularly preferably, k=1 is selected.

This detuning of the resonance frequencies is preferably performed, for example, by additionally energizing the first horizontal line (LH1) with a first horizontal DC component (IHG1) of the first horizontal current (IH1), where the first horizontal DC component (IHG1) can have a first horizontal current value of 0A, and/or by additionally energizing the first vertical line (LV1) with a first vertical direct current component (IVG1) of the first vertical current (IV1), wherein the first vertical direct current component (IVG1) can also have a first vertical current value of 0A. In order to now detune the other quantum bits of the n quantum bits (QUB1 to QUBn), for example, an additional energization of the second vertical line (LV2) with a second vertical direct current component (IVG2) takes place, whereby the second vertical direct current component has a second vertical current value which deviates from the first vertical current value. This deviation of the second vertical current value from the first vertical current value causes the resonance frequency of the first quantum dot (NV1) of the first quantum bit (QUB1) to deviate from the resonance frequency of the second quantum dot (NV2) of the second quantum bit (QUB2).

As mentioned before, this method can also be used for other quantum bit pairings. The basis of the selective controlling method is, as already mentioned, the selection of the first quantum bit (QUB1) or the second quantum bit (QUB2) by detuning the first vertical electron1-electron1 microwave resonance frequency (fMWV1) of the first quantum bit (QUB1) with respect to the second vertical electron1-electron1 microwave resonance frequency (fMWV2) of the second quantum bit (QUB2).

As before, the use of circularly polarized electromagnetic waves to manipulate the quantum dots of the quantum bits is useful. It is therefore convenient if the first horizontal modulation is phase shifted by +/−π/2 of the period of the first horizontal electron1-electron1 microwave resonance frequency (fMWH1) with respect to the first vertical modulation.

It is particularly preferred, for the same reason, that the first vertical electron1-electron1 microwave resonance frequency (fMWV1) is equal to the first horizontal electron1-electron1 microwave resonance frequency (fMWH1).

Similarly, it is particularly advantageous if the first vertical current component is pulsed with a first vertical current pulse having a first pulse duration and the first horizontal current component is also pulsed with a first horizontal current pulse having the first pulse duration.

As mentioned previously, it is useful if the first vertical current pulse is phase shifted relative to the first horizontal current pulse by +/−π/2 of the period of the first horizontal electron1-electron1 microwave resonance frequency (fMWH1).

It is again particularly convenient if the first temporal pulse duration has a first pulse duration corresponding to a phase difference of π/4 or π/2 (Hadamard gate) or 3π/4 or it (not-gate) of the Rabi oscillation of the first quantum dot (NV1) and/or if the first temporal pulse duration has a first pulse duration corresponding to a phase difference of an integer multiple of π/4 of the Rabi oscillation of the first quantum dot (NV1).

Control Method for Different. Simultaneous Control of a First Single Quantum Bit and a Second Single Quantum Bit of a Quantum Register

In this section, we will now discuss how the control of a single quantum bit (QUBj) of an n-bit quantum register (NBQUREG) described in the previous sections can be parallelized with n quantum bits (QUB1 to QUBn) so that two quantum bits of the n-bit quantum register (NBQUREG) that are different from each other can be addressed differently without significantly modifying the other n−2 quantum bits of the n-bit quantum register (NBQUREG). Here, mutual interference will still have to be accepted for the time being. The focus of this section is thus initially only on the control of a second quantum bit. Here, the method is based on the method described immediately before. As an example, it is assumed here that the first quantum bit (QUB land the second quantum bit (QUB2) of an n-bit quantum register (NBQUREG) are to be driven and the other quantum bits (QUB3 to QUBn) of the n-bit quantum register (NBQUREG) are to remain unaffected. Instead of these quantum bits (QUB1, QUB2), other quantum bit pairings and/or more than two quantum bits can be manipulated. In this respect, the combination of first quantum bit (QUB1) and second quantum bit (QUB2) discussed here is only exemplary. What is described in the following then applies accordingly. Thus, a method for differentially controlling a first quantum bit (QUB1) and a second quantum bit (QUB2) of an n-bit quantum register (NBQUREG), as previously described, with n as an integer positive number, is described herein. In addition to the currents described in the previous section for controlling the first quantum bit (QUB1), additional lines are now energized. The method therefore comprises the step of additionally energizing the second horizontal line (LH2) with a second horizontal current component of the second horizontal current (IH2) modulated with a second horizontal electron1-electron1 microwave resonance frequency (fMWH2) with a second horizontal modulation, and of additionally energizing the second vertical line (LV2) with a second vertical current component of the second vertical current (IV2) modulated with a second vertical electron1-electron1 microwave resonance frequency (IMWV2) with a second vertical modulation.

To generate a left or right polarized electromagnetic wave at the location of the second quantum dot (NV2) of the second quantum bit (QUB2), it is again useful that preferably the second horizontal modulation is phase shifted by +/−π/2 of the period of the second horizontal electron1-electron1 microwave resonance frequency (fMWH2) with respect to the second vertical modulation.

Similarly, preferably, the second vertical electron1-electron1 microwave resonance frequency (fMWV2) is equal to the second horizontal electron1-electron1 microwave resonance frequency (fMWH2) to ensure this phase relationship.

It is therefore suggested that preferably the second vertical current component is pulsed with a second vertical current pulse having a second pulse duration, and the first horizontal current component is pulsed with a second horizontal current pulse having the second pulse duration.

Preferably, the second vertical current pulse is phase shifted with respect to the second horizontal current pulse by +/−π/2 of the period of the second vertical electron1-electron1 microwave resonance frequency (fMWV2), resulting in said circular polarization of the electromagnetic field at the location of the second quantum dot (NV2) of the second quantum bit (QUB2).

Now, in order to be able to perform quantum operations, it is necessary to choose the second pulse duration appropriately. It is therefore preferred that the second temporal pulse duration has a second pulse duration corresponding to a phase difference of π/4 or π/2 (Hadamard gate) or 3π/4 or it (not-gate) of the Rabi oscillation of the second quantum dot (NV2) and/or that the second temporal pulse duration has a second pulse duration corresponding to a phase difference of an integer multiple of π/4 of the Rabi oscillation of the second quantum dot (NV2).

A pulse duration of π/2 corresponds thereby to a Hadamard gate, which is also called Hadamard operation. It rotates the quantum information of the second quantum dot (NV2) of the second quantum bit (QUB2) by 90°.

### A Selective Controlling Q

In this section, we now discuss how to parallelize the controlling of a single quantum bit (QUBj) of an n-bit quantum register (NBQUREG) with n quantum bits (QUB1 to QUBn) described in the previous section without significantly affecting the n−1 quantum bits that are not addressed. Here, the method builds on the method described immediately above. As an example, it is assumed here that the first quantum bit (QUB1) and the second quantum bit (QUB2) of an n-bit quantum register (NBQUREG) are to be addressed. Instead of these quantum bits, other quantum bit pairings and/or more than two quantum bits can be manipulated. What is described in the following then applies accordingly.

The method described here for now synchronously controlling an exemplary first quantum bit (QUB1) and an exemplary second quantum bit (QUB2) of an n-bit quantum register (NBQUREG) is based on a method as described previously. It is now assumed that the vertical lines are equally energized and the horizontal lines are independent. The method then comprises the additional step of additionally energizing the second horizontal line (LH2) of the second quantum bit (QUB2) with a second horizontal current component of the second horizontal current (IH2) modulated with the second horizontal electron1-electron1 microwave resonance frequency (fMWH2) with the second horizontal modulation and additionally energizing the first vertical line (LV1) with a second vertical current component of the first vertical current (IV1), which is modulated with a second vertical electron1-electron1 microwave resonance frequency (fMWV2) with a second vertical modulation Preferably, the second horizontal modulation is phase-shifted by +/−π/2 of the period of the second horizontal electron1-electron1 microwave resonance frequency (fMWH2) with respect to the second vertical modulation. Equally preferably, the second vertical electron1-electron1 microwave resonance frequency (fMWV2) is equal to the second horizontal electron1-electron1 microwave resonance frequency (fMWH2). The second vertical current component is preferably pulsed with a second vertical current pulse having a second pulse duration. The first horizontal current component is preferably pulsed with a second horizontal current pulse having the second pulse duration.

Preferably, the second vertical current pulse is phase shifted with respect to the second horizontal current pulse by +/−π/2 of the period of the second vertical electron1-electron1 microwave resonance frequency (fMWV2). The second temporal pulse duration preferably has a second pulse duration corresponding to a phase difference of π/4 or π/2 (Hadamard gate) or 3π/4 or π (Not gate) of the Rabi oscillation of the second quantum dot (NV2) and/or a second pulse duration corresponding to a phase difference of an integer multiple of π/4 of the Rabi oscillation of the second quantum dot (NV2).

A Selective Controlling Method for Synchronously Controlling a Second Single Quantum Bit of a Quantum Register and a First Single Ouantum Bit of Said Quantum Register without Substantially Affecting the Other Ouantum Bits of Said Register

The procedure now described is the same as that described immediately before, except that the first quantum bit (QUB1) and the second quantum bit (QUB2) swap roles. Thus, this is a method for differentially controlling a first quantum bit (QUB1) and a second quantum bit (QUB2) of an n-bit quantum register (NBQUREG) as previously described. The method comprises the step of energizing the first horizontal line (LH1) with a second horizontal current component of the first horizontal current (IH1) modulated with a second horizontal electron1-electron1 microwave resonance frequency (fMWH2) with a second horizontal modulation, and of additionally energizing the second vertical line (LV2) with a second vertical current component of the second vertical current (IV2) modulated with a second vertical electron1-electron1 microwave resonance frequency (fMWV2) with a second vertical modulation.

As before, preferably the second horizontal modulation is phase shifted by +/−90° of the period of the second vertical electron1-electron1 microwave resonance frequency (fMWV2) and/or the second horizontal electron1-electron1 microwave resonance frequency (fMWH2) relative to the second vertical modulation.

Preferably, the second vertical electron1-electron1 microwave resonance frequency (fMWV2) is equal to the second horizontal electron1-electron1 microwave resonance frequency (fMWH2). As before, preferably the second vertical current component is pulsed with a second vertical current pulse having a second pulse duration and the first horizontal current component is pulsed with a second horizontal current pulse having the second pulse duration.

Preferably, again, the second vertical current pulse is phase shifted with respect to the second horizontal current pulse by +/−π/2 of the period of the second vertical electron1-electron1 microwave resonance frequency (fMWV2). Preferably, the second temporal pulse duration has a second pulse duration corresponding to a phase difference of π/4 or π/2 (Hadamard gate) or 3π/4 or a (Not gate) of the Rabi oscillation of the second quantum dot (NV2) and/or a second pulse duration corresponding to a phase difference of an integer multiple of π/4 of the Rabi oscillation of the second quantum dot (NV2).

### Exchange Operation Between a First Ouantum Dot of a First Quantum Bit of a Quantum Register and a Second Ouantum Dot of a Second Ouantum Bit of a Quantum Register Non-Selective NV1 NV2 Ouantum Bit Coupling Method

In the following of this section, a method for controlling the pair of a first quantum bit (QUB1) and a second quantum bit (QUB2) of a two-bit quantum register (QUREG) of this n-bit quantum register (NBQUREG) as previously described is presented. The proposed method preferably comprises at least temporarily energizing the first horizontal line (LH1) of the quantum register (QUREG) with a first horizontal current component of the first horizontal current (IH1) modulated with a first horizontal electron1-electron2 microwave resonance frequency (fMWHEE1) with a first horizontal modulation. Here, for simplicity of description, it is again exemplarily assumed that the exemplary n quantum bits (QUB1 to QUBn) with their n quantum dots (NV1 to NVn) are again exemplarily arranged along the first horizontal line (LH1) and that each of the n quantum bits (QUB1 to QUBn) has one of the n vertical lines (LV1 to LVn). This exemplary arrangement is used here for clarification only. Other arrangements and interconnections of the horizontal lines and vertical lines are expressly possible and expressly encompassed by the claim. Furthermore, the method preferably comprises at least temporarily energizing the first vertical line (LV1) of the quantum register (QUREG) with a first vertical current component of the first vertical current (IV1) modulated with a first vertical electron1 electron2 microwave resonance frequency (fMWVEE1) with a first vertical modulation, and energizing, at least temporarily, the second horizontal line (LH2) of the quantum register (QUREG) with a second horizontal current component of the second horizontal current (IH2) modulated with the first horizontal electron1-electron2 microwave resonance frequency (fMWHEE1) with the second horizontal modulation. Further, the exemplary method comprises at least temporarily energizing the second vertical line (LV2) of the quantum register (QUREG) with a second vertical current flow component of the second vertical current (IV2) modulated with the first vertical electron1-electron2 microwave resonance frequency (fMWVEE1) with the second vertical modulation. Preferably, as mentioned above, for example, the second horizontal line (LH2) is equal to the first horizontal line (LH). The second horizontal current (IH2) is then, of course, equal to the first horizontal current (IH1). The second horizontal current (IH2) is then consequently already fed in when the first horizontal current (IH1) is fed in.

In the example presented here, it is exemplarily assumed that the n−2 other horizontal lines (LH3 to LHn) of the quantum register (QUREG) with n quantum bits (QUB1 to QUBn) are sequentially connected to form and use a common first horizontal line (LH1). As before, only the first quantum bit (QUB1) and the second quantum bit (QUB2) are considered here as representative of other quantum bit pairings. The stress explicitly includes other functional pairings. If the distance between two different quantum bits (QUBj, QUBi with i≠j) is too large, i.e., larger than the electron-electron coupling distance, coupling of these two different quantum bits (QUBj, QUBi with i≠j) is not possible.

Of course, a lining up of the quantum bits can also be done alternatively and/or partially simultaneously along the vertical lines. In such a case, the second vertical line (LV2) would then be equal to the first vertical line (LV2). The second vertical current (IV2) would then be equal to the first vertical current (IV1) and the second vertical current (IV2) would then already be injected with the injection of the first vertical current (IV1).

Particularly preferably, the first horizontal modulation is phase shifted by +/−π/2 of the period of the first horizontal electron1-electron2 microwave resonance frequency (fMWHEE1) relative to the first vertical modulation and/or the second horizontal modulation is phase shifted by +/−π/2 of the period of the second horizontal electron1-electron2 microwave resonance frequency (fMWHEE2) relative to the second vertical modulation.

Preferably, the first horizontal line (LH1) is additionally energized at least intermittently with a first horizontal direct current component (IHG1) of the first horizontal current (IH1), the first horizontal direct current component (IHG1) having a first horizontal current value. The first horizontal DC current component (IHG1) may thereby have a first horizontal current value of 0A. Such a DC current offset can be used to change the second horizontal electron1-electron2 microwave resonance frequency (fMWHEE2) and the first electron1-electron1 microwave resonance frequency (fMWH1) and to detune these resonance frequencies with respect to the other resonance frequencies of the proposed device. These additional DC components in the horizontal and vertical lines thus provide the critical means for addressing the individual quantum bits and/or quantum sub-registers within a larger quantum register and suppressing interference with the other quantum bits and/or quantum sub-registers of the larger quantum register. As used herein, a quantum sub-register refers to a subset of the quantum bits of a larger quantum register that form at least another quantum register among themselves. Thus, a quantum register with three quantum bits has, if all these three quantum bits can be coupled together, at least three quantum sub-registers.

The proposed method further preferably comprises at least temporarily additionally energizing the first vertical line (LV1) with a first vertical direct current component (IVG1) of the first vertical current (IV1). The first vertical direct current component (IVG1) has a first vertical current value in analogy to the previously described. In this context, the first vertical DC current component (IVG1) may have a first vertical current value of 0A.

The proposed method further preferably comprises at least temporarily additionally energizing the second horizontal line (LH2) with a second horizontal DC component (IHG2) of the second horizontal current (IH2), wherein the second horizontal DC component (IHG2) has a second horizontal current value and wherein the second horizontal DC component (IHG2) may have a second horizontal current value of 0A.

The proposed method further preferably comprises at least temporarily additionally energizing the second vertical line (LV2) with a second vertical DC component (IVG2) of the second vertical current (IV2), wherein the second vertical DC component (IVG2) has a second vertical current value and wherein the second vertical DC component (IVG2) may have a first vertical current value of 0A.

Preferably, the first horizontal current value is equal to the second horizontal current value and/or the first vertical current value is equal to the second vertical current value.

Preferably, the first vertical electron1-electron1 microwave resonance frequency (IMWV1) is equal to the first horizontal electron1-electron2 microwave resonance frequency (fMWHEE1).

Preferably, the first vertical current component is pulsed with a first vertical current pulse having a first pulse duration and/or the first horizontal current component is pulsed with a first horizontal current pulse having the first pulse duration.

Typically, the second vertical current component is pulsed with a second vertical current pulse having a second pulse duration and/or the second horizontal current component is pulsed with a second horizontal current pulse having the second pulse duration.

Typically, in an analogous manner, the first vertical current component is pulsed with a first vertical current pulse having a first pulse duration and the first horizontal current component is pulsed with a first horizontal current pulse having the first pulse duration.

Preferably, the second vertical current component is pulsed with a second vertical current pulse having a second pulse duration and/or the second horizontal current component is pulsed with a second horizontal current pulse having the second pulse duration.

Preferably, the first vertical current pulse is phase shifted relative to the first horizontal current pulse by +/−π/2 of the period of the first electron electron2 microwave resonance frequency (IMWHEE1) and/or the second vertical current pulse is phase shifted relative to the second horizontal current pulse by +/−π/2 of the period of the second electron1 electron2 microwave resonance frequency (fMWHEE2).

Preferably, the first temporal pulse duration has a first pulse duration corresponding to a phase difference of π/4 or π/2 (Hadamard gate) or 3π/4 or π (Not gate) of the Rabi oscillation of the quantum dot pair of the first quantum dot (NV1) and the second quantum dot (NV2) and/or a first pulse duration corresponding to a phase difference of an integer multiple of π/4 of the Rabi oscillation of the quantum dot pair of the first quantum dot (NV1) and the second quantum dot (NV2).

Preferably, the second temporal pulse duration has a second pulse duration corresponding to a phase difference of π/4 or π/2 (Hadamard gate) or 3π/4 or π (not gate) of the Rabi oscillation of the quantum dot pair of the first quantum dot (NV1) and the second quantum dot (NV2) and/or the second temporal pulse duration has a second pulse duration corresponding to a phase difference of an integer multiple of π/4 of the Rabi oscillation of the quantum dot pair of the first quantum dot (NV1) and the second quantum dot (NV2).

Preferably, the first temporal pulse duration is equal to the second temporal pulse duration.

### Selective Quantum Bit Coupling Method for a First Quantum Dot and a Second Quantum Dot

A modification of the method for controlling the pair of a first quantum bit (QUB1) and a second quantum bit (QUB2) of an n-bit quantum register (NBQUREG) is now described. Thereby, the gating is selective with respect to further quantum bits (QUBj) of this n-bit quantum register (NBQUREG). The method comprises the additional steps of at least temporarily additionally energizing the first horizontal line (LH1) with a first horizontal DC component (IHG1) of the first horizontal current (IH1), wherein the first horizontal DC component (IHG1) has a first horizontal current value and wherein the first horizontal DC component (IHG1) may have a first horizontal current value of 0A, and at least temporarily additionally energizing the first vertical line (LV1) with a first vertical direct current component (IVG1) of the first vertical current (IV1), wherein the first vertical direct current component (IVG1) has a first vertical current value and wherein the first vertical direct current component (IVG1) can have a first vertical current value of 0A. Further, the proposed process modification comprises at ken temporarily additionally energizing the second horizontal line (LH2) with a second horizontal DC current component (IHG2) of the second horizontal current (IH2), wherein the second horizontal DC current component (IHG2) has a second horizontal current value and wherein the second horizontal DC current component (IHG2) can have a second horizontal current value of 0A. Furthermore, the process extension preferably comprises additionally energizing, at least temporarily, the second vertical line (LV2) with a second vertical direct current component (IVG2) of the second vertical current (IV2), wherein the second vertical direct current component (IVG2) has a second vertical current value and wherein the second vertical direct current component (IVG2) may have a first vertical current value of 0A. Likewise, the proposed method enhancement comprises at least temporarily additionally energizing the j-th horizontal line (LHj) of a further j-th quantum bit (QUBj), if present, of the n-bit quantum register (NBQUREG) with a j-th horizontal direct current component (IHGj), wherein the j-th horizontal direct current component (IHGj) has a j-th horizontal current value. Finally, the proposed process variant preferably comprises an at least temporary additional energization of the j-th vertical line (LVj) of a further j-th quantum bit (QUBj), if present, of the n-bit quantum register (NBQUREG) with a j-th vertical direct current component (IVGj), the j-th vertical direct current component (IHGj) having a j-th vertical current value.

Preferably, the first vertical current value differs from the j-th vertical current value and/or the second vertical current value differs from the j-th vertical current value and/or the first horizontal current value differs from the j-th horizontal current value and/or the second horizontal current value differs from the j-th horizontal current value. Hereby, the resonance frequencies are detuned with respect to each other, which allows a targeted addressing of a quantum dot and/or a quantum sub-register of the quantum register.

Method for the General Entanglement of Two Quantum Dots

Here, a method is now described for entangling the quantum information of a first quantum dot (NV1), in particular the spin of its first electron configuration, of a first quantum bit (QUB1) of an n-bit quantum register (NBQUREG) resp. of an inhomogeneous n-bit quantum register (NBIQUREG) with the quantum information of a second quantum dot (NV2), in particular of the second spin of the second electron configuration of the second quantum dot (NV2), of a second quantum bit (QUB2) of this n-bit quantum register (QUREG) or of this inhomogeneous n-bit quantum register (NBIQUREG), hereinafter referred to as electron-emission operation.

In this example, the first quantum dot (NV1) of a first quantum bit (QUB1) of the n-bit quantum register (NBQUREG) and the second quantum dot (NV1) of a second quantum bit (QUB2) of the n-bit quantum register (NBQUREG) are arbitrarily chosen for illustration. However, the stress refers to all couplable pairs or n-tuples of two or more quantum dots of two or more quantum bits of the n-bit quantum register (NBQUREG).

The method for entangling the quantum information of a first quantum dot (NV1) with that of the quantum information of a second quantum dot (NV2) typically comprises a method for resetting the electron-electron quantum register (NBQUREG) or the inhomogeneous quantum register (IQUREG) to bring the first quantum bit and the second quantum bit in to a defined state. After this initialization, typically a Hadamard gate is executed as a step for the quantum partial register from the first quantum bit and the second quantum bit. Then, preferably, a CNOT gate is executed for this quantum sub-register. Instead, another method can theoretically be used to entangle the quantum information of the first quantum dot (NV1), in particular the first spin of the first electron configuration of the first quantum dot (NV1), the first quantum bit (QUB1) of the quantum register (QUREG) resp. of the inhomogeneous quantum register (IQUREG) with the quantum information of a second quantum dot (NV2), in particular the second spin of the second electron configuration of this second quantum dot (NV2), a second quantum bit (QUB2) of this electron-electron quantum register (QUREG) or of this inhomogeneous quantum register (IQUREG). For example, it is conceivable to use other quantum dots for this purpose, for example in a quantum bus (QUBUS).

### Electron-Nucleus Exchange Operation

### Nucleus-Electron CNOT Operation

In the following section, we describe a nucleus-electron CNOT operation for changing the quantum information of a quantum dot (NV), in particular its electron or its electron configuration, of a quantum bit (QUB) of a nucleus-electron quantum register (CEQUREG) as a function of the quantum information of a nuclear quantum dot (CI), in particular the nuclear spin of its nucleus, of a nuclear quantum bit (CQUB) of this nucleus-electron quantum register (CEQUREG), hereinafter referred to as nucleus-electron CNOT operation. As in the previously described selective gating methods for gating a single quantum bit of a quantum register without significantly affecting the other quantum bits of the quantum register in question, the horizontal and vertical lines are again used for gating. Thus, the nucleus-electron CNOT operation includes the step of injecting a horizontal current component of the horizontal current (IH) into the horizontal line (LH) of the quantum bit (QUB), the horizontal current component having a horizontal modulation with the nucleus-electron microwave resonance frequency (f_{MWCE}), and injecting a vertical current component of the vertical current (IV) in to the vertical line (LV) of the quantum bit (QUB), the vertical current component having a vertical modulation with the nucleus-electron microwave resonance frequency (f_{MWCE}).

Preferably, again to produce a preferred left or right polarized electromagnetic field, the vertical modulation is shifted relative to the horizontal modulation by +/−π/2 of the period of the nucleus-electron microwave resonance frequency (f_{MWCE}).

Preferably, the first vertical current component is pulsed with a first vertical current pulse having a first pulse duration and/or the first horizontal current component is pulsed with a first horizontal current pulse having the first pulse duration.

Preferably, again to produce a preferred left or right polarized electromagnetic field, the first vertical current pulse is phase shifted relative to the horizontal current pulse by +/−π/2 of the period of the microwave resonance frequency (f_{MWCE}).

Preferably, the first temporal pulse duration has a first pulse duration corresponding to a phase difference of π/4 or π/2 (Hadamard gate) or 3π/4 or π (not-gate) of the Rabi oscillation of the quantum pair of the quantum dot (NV1) of the nucleus-electron quantum register (CEQUREG) and the nuclear quantum dot (CQUB) of the nucleus-electron quantum register (CEQUREG) and/or a first pulse duration corresponding to a phase difference of an integer multiple of π/4 of the Rabi oscillation of the quantum pair of the quantum dot (NV1) of the nucleus-electron quantum register (CEQUREG) and the nuclear quantum dot (CQUB) of the nucleus-electron quantum register (CEQUREG).

### Electron-Nucleus CNOT Operation

In the following, an electron-nucleus CNOT operation is described for changing the quantum information of a nuclear quantum dot (CI), in particular the nuclear spin of the atomic nucleus, of a nuclear quantum bit (CQUB) of a nucleus-electron quantum register (CEQUREG) as a function of the quantum information of a quantum dot (NV), in particular its electron or its electron configuration, of a quantum bit (QUB) of this nucleus-electron quantum register (CEQUREG), hereinafter referred to as electron-nucleus CNOT operation. The electron-nucleus CNOT operation comprises the step of injecting a horizontal current component of the horizontal current (IH) in to the horizontal line (LH) of the quantum bit (QUB), the horizontal current component having a horizontal modulation with the electron-nucleus radio wave resonance frequency (f_{RWEC}), and of injecting a current component of the vertical current (IV) in to the vertical line (LV) of the quantum bit (QUB), the vertical current component having a vertical modulation with the electron-nucleus radio wave resonance frequency (f_{RWEC}).

To generate a left or right circularly polarized electromagnetic field, the vertical modulation is preferably shifted relative to the horizontal modulation by +/−π/2 with respect to the period of the electron-nucleus radio wave resonance frequency (f_{RWEC}).

Preferably, the vertical current component is pulsed with a vertical current pulse having a pulse duration and the horizontal current component is pulsed with a horizontal current pulse having the pulse duration.

To generate a left or right circularly polarized electromagnetic field, the vertical current pulse is preferably phase shifted relative to the horizontal current pulse by +/−π/2 of the period of the electron-nucleus radio wave resonance frequency (f_{RWEC}).

Preferably, the first temporal pulse duration has a first pulse duration corresponding to a phase difference of π/4 or π/2 (Hadamard) or 3π/4 or π (not-gate) of the Rabi oscillation of the quantum pair of the quantum dot (NV1) of the nucleus-electron quantum register (CEQUREG) and the nuclear quantum dot (CQUB) of the nucleus-electron quantum register (CEQUREG) and/or a first pulse duration corresponding to a phase difference of an integer multiple of π/4 of the Rabi oscillation of the quantum pair of the quantum dot (NV1) of the nucleus-electron quantum register (CEQUREG). quantum register (CEQUREG) and the nuclear quantum dot (CQUB) of the nucleus-electron quantum register (CEQUREG).

### Electron-Nucleus Exchange Operation

In the following, a method for entangling the quantum information of a nuclear quantum dot (CI), in particular the nuclear spin of its atomic nucleus, of a nuclear quantum bit (CQUB) of a nucleus-electron quantum register (CEQUREG) according to one or more of features 203 to 215 with the quantum information of a quantum dot (NV), in particular its electron, of a quantum bit (QUB) of this nucleus-electron quantum register (CEQUREG), hereinafter referred to as electron-nucleus exchange operation, is described. This method thereby has the step of performing an electron-nucleus CNOT operation and the immediately or not immediately subsequent step of performing a nucleus-electron CNOT operation the immediately or not immediately subsequent step of performing an electron-nucleus CNOT operation.

### Alternative Method for Spin Exchange Between Nucleus and Electron

An alternative method for entangling the quantum information of a nuclear quantum dot (CI), in particular the nuclear spin of its nucleus, of a nuclear quantum bit (CQUB) of a nucleus-electron quantum register (CEQUREG) with the quantum information of a quantum dot (NV), in particular its electron or its electron configuration, of a quantum bit (QUB) of this nucleus-electron quantum register (CEQUREG), hereinafter referred to as electron-nucleus exchange delay operation, is described below. The method comprises the step of changing the quantum information of the quantum dot (NV), in particular the quantum information of the spin state of the electron or the electron configuration of the quantum dot (NV), and then waiting for a nuclear spin relaxation timeτK. Here, it is exploited that the spin of the electron configuration or the electron interacts with the spin of the nucleus. By radiation and precision, the nucleus tilts in dependence of the spin of the electron configuration in to the new state within the said nuclear spin relaxation time TIC.

### Method for the General Entanglement of a Nucleus and an Electron (Nucleus-Electron Entanglements

A proposed method for entangling the quantum information of a nuclear quantum dot (CI), in particular the nuclear spin of its nucleus, of a nuclear quantum bit (CQUB) of a nucleus-electron quantum register (CEQUREG) with the quantum information of a quantum dot (NV), in particular that of the spin of the electron configuration of the quantum dot (NV), of a quantum bit (QUB) of said nucleus-electron quantum register (CEQUREG), hereinafter referred to as nucleus-electron de-embedding operation, is characterized in that it comprises a method for resetting a nucleus-electron quantum register (CEQUREG) and in that it comprises a method for performing a Hadamard gate. Further, the method comprises a method for executing a CNOT gate. Alternatively, the method may comprise another method for entangling the quantum information of a nuclear quantum dot (CI), in particular the nuclear spin of its nucleus, a nuclear quantum bit (CQUB) of a nucleus-electron quantum register (CEQUREG), in particular that of the spin of the electron configuration or the electron of a quantum dot (NV), a quantum bit (QUB) of said nucleus-electron quantum register (CEQUREG).

### General Ouantum Information Exchange Process Between Nucleus and Electron

Of particular importance is a method for exchanging the quantum information of a nuclear quantum dot (CI), in particular the nuclear spin of its atomic nucleus, of a nuclear quantum bit (CQUB) of a nucleus-electron quantum register (CEQUREG) with the quantum information of a quantum dot (NV), in particular its electron or its electron configuration, of a quantum bit (QUB) of this nucleus-electron quantum register (CEQUREG), hereinafter referred to as a nucleus-election exchange operation. Such a nucleus-electron exchange operation in the sense of this writing is characterized in that it is an electron-nucleus exchange delay operation or in that it is an electron-nucleus exchange operation or in that it is another method for entangling the quantum information of a nuclear quantum dot (CI), in particular the nuclear spin of its nucleus, of a nuclear quantum bit (CQUB) of a nucleus-electron quantum register (CEQUREG) with the quantum information of a quantum dot (NV), in particular its electron, of a quantum bit (QUB) of this nucleus-electron quantum register (CEQUREG).

### Electron-Nuclear Quantum Register Radio Wave Control Method

A method is now described here for changing the quantum information of a nuclear quantum dot (CI), in particular the nuclear spin of its atomic nucleus, of a nuclear quantum bit (CQUB) of a nucleus-electron quantum register (CEQUREG) as a function of the quantum information of a quantum dot (NV), in particular its electron or its electron configuration, of a quantum bit (QUB) of this nucleus-electron quantum register (CEQUREG). The method preferably comprises the steps of energizing the horizontal line (LH) of the quantum bit (QUB) with a horizontal current (IH) having a horizontal current component, modulated by an electron-nucleus radio wave resonance frequency (fRWEC) with a horizontal modulation, and of energizing the vertical line (LV) of the quantum bit (QUB) with a vertical current (IV) with a vertical current component modulated by the electron-nucleus radio wave resonance frequency (fRWEC) with a vertical modulation. Thus, as before, the horizontal line and the vertical line are again used to drive the nucleus-electron quantum register (CEQUREG). By selecting the electron-nucleus radio wave resonance frequency (fRWEC), the correct nucleus-electron quantum register (CEQUREG) is selected when the combination of the respective horizontal line and the respective vertical line can drive multiple nucleus-electron quantum registers (CEQUREG). Since the nuclear quantum dots (CI) have different distances from the quantum dot (NV) in reality, the coupling strengths between quantum dot (NV) and nuclear quantum dot (CI) differ from nuclear quantum dot to nuclear quantum dot. Thus, the electron-nucleus radio wave resonance frequencies (fRWEC) also differ from pair to pair of these quantum dot (NV) pairs and nuclear quantum dot (CI) for multiple pairs of quantum dot (NV) and nuclear quantum dot (CI) that can be addressed by the horizontal line and the vertical line. Thus, this can be used to target individual nuclear quantum dots.

To again generate a left or right polarized electromagnetic field, it is again advantageous if the horizontal modulation of the horizontal current component is phase shifted in time by +/−π/2 of the period of the electron-nucleus radio wave resonance frequency (fRWEC) with respect to the vertical modulation of the vertical current component.

Preferably, the vertical current component is pulsed with a vertical current pulse and/or the horizontal current component is pulsed with a horizontal current pulse.

Preferably, the second vertical current pulse is out of phase with respect to the second horizontal current pulse by +/−π/2 of the period of the electron-nucleus radio wave resonance frequency (fRWEC).

Preferably, the temporal pulse duration τRCE of the horizontal current pulse and of the vertical current pulse has the pulse duration corresponding to a phase difference of π/4 or π/2 (Hadamard gate) or 3π/4 or π (not-gate) of the period of the Rabi oscillation of the system consisting of the quantum dot (NV) of the quantum bit (QUB) of the nucleus-electron quantum register (CEQUREG) and the nuclear quantum dot (CI) of the nuclear quantum bit (CQUB) of the nucleus-electron quantum register (CEQUREG). quantum register (CEQUREG) and/or the temporal pulse duration τRCE of the horizontal current pulse and the vertical current pulse is the pulse duration corresponding to a phase difference of an integer multiple of π/4 of the period duration of the Rabi oscillation of the system consisting of the quantum dot (NV) of the quantum bit (QUB) of the nucleus-electron quantum register (CEQUREG) and the nuclear quantum dot (CI) of the nuclear quantum bit (CQUB) of the nucleus-electron quantum register (CEQUREG).

### Electron Ouantum Register Microwave Actuation Method

In contrast to the method described immediately before, a method for the reverse direction of influence is now described here. It is thus a method for changing the quantum information of a quantum dot (NV), in particular its electron or its electron configuration, of a quantum bit (QUB) of a nucleus-electron quantum register (CEQUREG) as a function of the quantum information of a nuclear quantum dot (CI), in particular the nuclear spin of its atomic nucleus, of a nuclear quantum bit (CQUB) of this nucleus-electron quantum register (CEQUREG). In particular, the method presented herein preferably comprises the steps of energizing the horizontal line (LH) of the quantum bit (QUB) with a horizontal current (IH) having a horizontal current component, modulated with a nucleus-electron microwave resonance frequency (fMWCE) with a horizontal modulation, and of energizing the vertical line (LV) of the quantum bit (QUB) with a vertical current (IV) with a vertical current component modulated with the nucleus-electron microwave resonance frequency (fMWCE) with a vertical modulation.

To again produce a left or right circularly polarized electromagnetic field, again preferably the horizontal modulation of the horizontal current component is out of phase in time by +/−π/2 of the period of the nucleus-electron microwave resonance frequency (fMWCE) relative to the vertical modulation of the vertical current component.

Preferably, the vertical current component is pulsed with a vertical current pulse and the horizontal current component is pulsed with a horizontal current pulse.

Preferably, again, the second vertical current pulse is out of phase with respect to the second horizontal current pulse by +/−π/2 of the period of the nucleus-electron microwave resonance frequency (fMWCE).

Preferably again, the temporal pulse duration τCE of the horizontal current pulse and the vertical current pulse has the pulse duration corresponding to a phase difference of π/4 or π/2 (Hadamard gate) or 3π/4 or π (not-gate) of the period of the Rabi oscillation of the quantum pair of the quantum dot (NV) of the quantum bit (QUB) of the nucleus-electron quantum register (CEQUREG) and the nuclear quantum dot (CI) of the nuclear quantum bit (CQUB) of the nucleus-electron quantum register (CEQUREG) and/or the temporal pulse duration τCE of the horizontal current pulse and the vertical current pulse is the pulse duration corresponding to a phase difference of an integer multiple of π/4 of the period duration of the Rabi oscillation of the quantum pair of the quantum dot (NV) of the quantum bit (QUB) of the nucleus-electron quantum register (CEQUREG) and the nuclear quantum dot (CI) of the nuclear quantum bit (CQUB) of the nucleus-electron quantum register (CEQUREG).

### Nucleus-to-Nuclear Ouantum Register Radio Wave Control Method

Now a method is considered for changing the quantum information of a first nuclear quantum dot (CI1), in particular the nuclear spin of its nucleus, of a first nuclear quantum bit (CQUB) of a nucleus-nuclear quantum register (CCQUREG) as a function of the quantum information of a second nuclear quantum dot (CI2), in particular the nuclear spin of the second nuclear quantum dot (Ci2), of a second nuclear quantum bit (CQUB2) of said nucleus-nuclear quantum register (CCQUREG). The method in turn comprises the steps of energizing the first horizontal line (LH1) of the first nuclear quantum bit (CQUB1) with a first horizontal current component (IH1) modulated with a first nucleus-nucleus radio wave resonance frequency (fRWECC) with a horizontal modulation, and of energizing the first vertical line (LV1) nuclear quantum bits (CQUB1) with a first vertical current component (IV1) modulated with the first nucleus-nucleus radio wave resonance frequency (fRWECC) with a vertical modulation.

Preferably, horizontal modulation is again phase shifted in time by +/−π/2 of the period of the first nucleus-to-nucleus radio wave resonance frequency (fRWECC) relative to the vertical modulation to again produce a left or right circularly polarized electromagnetic field, as in other previously described cases.

Preferably, the horizontal current component is pulsed at least intermittently with a horizontal current pulse component and the vertical current component is pulsed at least intermittently with a vertical current pulse component.

Preferably, the second vertical current pulse is out of phase with respect to the second horizontal current pulse by +/−π/2 of the period of the first nucleus-to-nucleus radio wave resonance frequency (fRWECC).

Preferably, the temporal pulse duration τRCC of the horizontal and vertical current pulse component has the duration corresponding to a phase difference of π/4 or π/2 or (Hadamard gate) or 3π/4 or π (not-gate) of the period Rabi-oscillation of the quantum pair of the first nuclear quantum dot (CI1) of the first nuclear quantum bit (CQUB1) and of the second nuclear quantum dot (CI2) of the second nuclear quantum bit (CQUB2) and/or the temporal pulse duration τRCC of the horizontal and vertical current pulse component the duration corresponding to a phase difference of an integer multiple of π/4 of the period Rabi oscillation of the quantum pair of first nuclear quantum dot (CI1) of the first nuclear quantum bit (CQUB1) and of the second nuclear quantum dot(CI2) of the second nuclear quantum bit (CQUB2).

Composite Methods

Now that the basic procedures have been described in the preceding sections, more complex procedures can be assembled from these basic procedures to be applied to the proposed device. This combination is preferably done by sequentially applying these procedures to one or more quantum dots and/or nuclear quantum dots. Parallelization is possible in parts as described. Only the combination of all these individual pans and steps leads to a fully functional system.

### Quantum Bit Rating

One of the most important methods is for reading out the result of the calculations of the device. It is a method for evaluating the quantum information, in particular the spin state, of the first quantum dot (NV1) of a first quantum bit (QUB1) of a nucleus-electron-nucleus-electron quantum register (CECEQUREG) to be read out. Here, again, the first quantum bit (QUB1) is representative of any quantum bit of the nucleus-electron-nucleus-electron quantum register (CECEQUREG).

In a first step, the quantum dot (NV) of the quantum bit (QUB1) to be read out of the nucleus-electron-nucleus-electron quantum register (CECEQUREG) is set to a defined start state. This is preferably done by irradiating the quantum dot (NV1) of the quantum bit (QUB1) to be read out of the nucleus-electron-nucleus-electron quantum register (CECEQUREG) with “green light”. As already explained, the term “green light” stands here for light that realizes a certain function in interaction with the quantum dot (NV).

In the exemplary case of an NV center in diamond as substrate (D), the light is thus preferably of a wavelength of 500 nm wavelength to 700 nm wavelength. Experience has shown that the use of light of typically 532 nm wavelength is optimal here. The greater the wavelength distance from this wavelength value, the worse the results typically.

When using other impurity centers and impurities, which in particular can still be located in other materials, corresponding other wavelengths must then be used as green light in order to then produce the functional effect of “green light” for these impurity centers, impurities and substrates.

In the proposed process, a voltage is then typically applied simultaneously between at least one first electrical extraction line, in particular a shielding line (SH1, SV1) used as the first electrical extraction line, and a second electrical extraction line, in particular a further shielding line (SH2, SV2) used as the second electrical extraction line and adjacent to the shielding line (SH1, SV1) used. Through this, charge carriers generated during irradiation with “green light” are extracted. This assumes that the quantum dots change to an uncharged state by the irradiation with green light and that these then recharge themselves by capturing a charge carrier.

In the case of using diamond as the material of the substrate (D) and the case of a NV center as a quantum dot (NV1), this means that the Fermi level should preferably be above the level of the NV center in the band gap. Irradiation with “green light” causes the NV center to donate an electron to the conduction band, where it is extracted by the electrostatic field applied externally through the contacts of the extraction lines. Since the Fermi level is above the energetic level of the NV center, this is again recharged by the absorption of an electron from the valence band, making it charged again. For this purpose, the diamond should preferably be n-doped. Therefore, n-doping with, for example, nuclear spin-free sulfur is advantageous. Crucially, this readout process depends on the quantum state.

For more details on this process, see Petr Siyushev, Milos Nesladek, Emilie Bourgeois, Michal Gulka, Jaroslav Hruby, Takashi Yamamoto, Michael Trupke, Tokuyuki Teraji, Junichi Isoya, Fedor Jelezko, “Photoelectrical imaging and coherent spin-state readout of single nitrogen-vacancy centers in diamond”, Science 363, 728-731 (2019) 15 Feb. 2019.

In the case of using silicon as the material of the substrate (D) and the case of a G-center as a quantum dot (NV1), this means that the Fermi level should preferably be above the level of the G-center in the band gap. Irradiation with “green light” causes the G-center to donate an electron to the conduction band, where it is extracted by the electrostatic field applied externally through the contacts of the extraction lines. Since the Fermi level is above the energetic level of the G center, it is again recharged by taking an electron from the valence band, making it charged again. For this purpose, the silicon should preferably be n-doped. Therefore, n-doping with, for example, nuclear spin-free isotopes is advantageous. As described above, in the range of quantum dots, for example, the isotopes 120Te, 122Te, 124Te, 126Te, 128Te, 130Te, 46Ti, 48Ti, 50Ti, 2C, 14C, 74Se, 76Se, 78Se, 80Se, 130Ba, 132Ba, 134Ba, 136Ba, 138Ba, 32S, 34S and 36S are suitable for n-doping of silicon with isotopes without nucleus magnetic moment μ. Crucially, this readout also depends on the quantum state in this case.

Only the combination of the quantum bit construction with selective addressing and the previously described read-out with this method results in a realization possibility for a quantum computer.

For the method proposed herein to work, the quantum dot (NV1) of the quantum bit (QUB1) of the nucleus-electron-nucleus-electron quantum register (CECEQUREG) to be read out must be located in the electric field between these two electric exhaust lines. Preferably, the quantum dots (NV2) of the remaining quantum bits (QUB2) of the nucleus-electron-nucleus-electron quantum register (CECEQUREG) that are not to be read out are not located in the electric field between these two electrical exhaust lines. Preferably, the quantum dots (NV1) of the respective quantum bits (QUB1) of the nucleus-electron-nucleus-electron quantum register (CECEQUREG) to be read out are selectively driven as described above.

Using the mechanism described in Petr Siyushev, Milos Nesladek, Emilie Bourgeois. Michal Gulka, Jaroslav Hruby, Takashi Yamamoto, Michael Trupke, Tokuyuki Teraji, Junichi Isoya, Fedor Jelezko, “Photoelectrical imaging and coherent spin-state readout of single nitrogen-vacancy centers in diamond,” Science 363, 728-731 (2019) 15 Feb. 2019 mechanism described above, photoelectrons are then transmitted through the quantum dot to be read out (NV1) of the quantum bit to be read out (QUB1) of the nucleus-electron-nucleus-electron quantum register (CECEQUREG) by means of a two-photon process depending on the nuclear spin of the nuclear quantum dot (CI1) of the nuclear quantum bit (CQUB1), which forms a nucleus-electron quantum register (CQUREG) with the quantum bit (QUB1) to be read out. This is followed by the extraction of the photoelectrons, if any, of the quantum dot (NV1) to be read out of the quantum bit (QUB1) to be read out of the quantum register (QUREG) via a contact (KV11, KH11) between the first electrical extraction line, in particular the shielding line (SH1, SV1), and the substrate (D) or the epitaxial layer (DEP1) as an electron current. In an analogous manner, the extraction of the holes, if any, of the quantum dot (NV1) to be read out of the quantum bit (QUB1) to be read out of the quantum register (QUREG) is performed via a contact (KV12, KH22) between the second electrical extraction line, in particular the further shielding line (SH2, SV2), and the substrate (D) or the epitaxial layer (DEP1) as hole current. Whether photo-electrons or photo-holes are used depends on the substrate material and the impurity center used as quantum dot. An evaluation circuit evaluates the thus generated photocurrent and generates an evaluation signal with a first logical value if the total current of hole current and electron current has a total current amount of current value below a first threshold value (SW1) and with a second logical value if the total current of hole current and electron current has a total current amount of current value above the first threshold value (SW1). Of course, the second logical value is preferably different from the first logical value. Preferably, the shielding and exhaust lines are also made of isotopes without magnetic moment μ. The titanium isotopes mentioned above are particularly suitable for this purpose.

### Quantum Computing Result Extraction

Thus, in a simplified manner, a method for reading out the state of a quantum dot (NV) of a quantum bit (QUB) can be given comprising the steps of evaluating the charge state of the quantum dot (NV) and generating an evaluation signal having a first logic level if the quantum dot (NV) is negatively charged at the start of the evaluation, and generating an evaluation signal having a second logic level different from the first logic level if the quantum dot (NV) is not negatively charged at the start of the evaluation.

### Electron-Electron-CNOT-Operation

Now we give here a CNOT operation, which is one of the most important quantum computing operations. This is a procedure for performing a CNOT manipulation for a quantum register (QUREG), hereafter called ELEKTRON-ELEKTRON-CNOT. Here, the substrate (D) of the quantum register (QUREG) shall be common to the first quantum bit (QUB1) of the quantum register (QUREG) and the second quantum bit (QUB2) of the quantum register (QUREG). The quantum dot (NV) of the first quantum bit (QUB1) of the quantum register (QUREG) will be referred to as the first quantum dot (NV1) in the following. The quantum dot (NV) of the second quantum bit (QUB2) of the quantum register (QUREG) will be referred to as the second quantum dot (NV2) in the following. The horizontal line (LH) of the first quantum bit (QUB1) of the quantum register (QUREG) is hereinafter referred to as the first horizontal line (LH1). The horizontal line (LH) of the second quantum bit (QUB2) of the quantum register (QUREG) is hereinafter referred to as the second horizontal line (LH2). The vertical line (LV) of the first quantum bit (QUB1) of the quantum register (QUREG) is hereinafter referred to as the first vertical line (LV1). The vertical line (LV) of the second quantum bit (QUB2) of the quantum register (QUREG) is hereinafter referred to as the second vertical line (LV2). The first horizontal line (LH1) is preferably equal to the second horizontal line (LH2). This leads to a possible topology of an n-bit quantum register (NBQUREG) in which the quantum dots (NV1, NV2) are lined up along this horizontal line (LH1) as if on a string of pearls, if this is true for all quantum registers (QUREG) of a device with multiple quantum registers (QUREG). This has the advantage that selective control of individual quantum dots of this device then becomes easier. Of course, vertical line-up is also possible. Thus, the first vertical line (LV1) can also be equal to the second vertical line (LH2). Preferably, the first horizontal line (LH1) is not equal to the second horizontal line (LH2).

As before, the proposed method then comprises energizing the first horizontal line (LH1) with a first horizontal current component of the first horizontal current (IH1) for a time duration corresponding to a first phase angle of φ1, in particular of π/4 or π/2 (Hadamard gate) or 3π/4 or π (not-gate) or an integer multiple of π/4, of the period of the Rabi oscillation of the first quantum dot (NV1) of the first quantum bit (QUB1).

Preferably, the first horizontal current component is modulated with a first microwave resonance frequency (fMW1) with a first horizontal modulation.

Equally preferably, the energization of the first vertical line (LV1) is performed with a first vertical current component of the first vertical current (IV1) for a time duration corresponding to the first phase angle of φ1, in particular of π/4 or π/2 (Hadamard gate) or 3π/4 or π (not-gate) or an integer multiple of π/4, the period of the Rabi oscillation of the first quantum dot (NV1) of the first quantum bit (QUB1), preferably the first vertical current component being modulated with a first microwave resonance frequency (NW) with a first vertical modulation.

Preferably, the first horizontal line (LH1) is energized in parallel with the first vertical line (LV1) except for said phase shift.

The energization of the first horizontal line (LH1) is preferably performed with a first horizontal direct current (IHG1) with a first horizontal current value, where the first horizontal current value may have an amount of 0A.

The energization of the first vertical line (LV1) is preferably performed with a first vertical direct current (IVG1) with a first vertical current value, where the first vertical current value may have a magnitude of 0A.

The second horizontal line (LH2) is preferably energized with a two horizontal direct current (IHG2) with the first horizontal current value, where the first horizontal current value can have an amount of 0A.

The second vertical line (LV2) is preferably supplied with a second vertical direct current (IVG2) whose second vertical current value differs from the first vertical current value. Preferably, the second vertical current value and the first vertical current value are selected in such a way that the phase vector of the first quantum dot (NV1) of the first quantum bit (QUB1) executes a phase rotation about the first phase angle φ1, in particular of π/4 or π/2 (Hadamard gate) or 3π/4 or π (not-gate) or an integer multiple of π/4, if the phase vector of the second quantum dot (NV2) of the second quantum bit (QUB2) is in a first position and that the phase vector of the first quantum dot (NV1) of the first quantum bit (QUB1) does not execute a phase rotation about the phase angle φ1, in particular of π/4 or π/2 (Hadamard gate) or 3π/4 or π (not-gate) or an integer multiple of π/4, if the phase vector of the second quantum dot (NV2) of the second quantum bit (QUB2) is not in the first position but in a second position, and in that the phase vector of the second quantum dot (NW) of the second quantum bit (QUB2) does not execute any or only an insignificant phase rotation.

Preferably, the second horizontal line (LH2) is then energized with a second horizontal current component (IHM2) for a time duration corresponding to a phase angle of φ2, in particular of π/4 or π/2 (Hadamard gate) or 3π/4 or π (not-gate) or an integer multiple of π/4, the period of the Rabi oscillation of the second quantum dot (NV2) of the second quantum bit, the second horizontal current component (IHM2) being modulated with a second microwave resonance frequency (fMW2) with a second horizontal modulation.

The energization of the second vertical line (LV2) is preferably performed with a second vertical current component (IVM2) for a time duration corresponding to a phase angle of φ2, in particular of π/4 or π/2 (Hadamard gate) or 3π/4 or π (not-gate) or an integer multiple of π/4, of the period of the Rabi oscillation of the second quantum dot (NV2) of the second quantum bit, wherein the second vertical current component (IVM2) is modulated with a second vertical microwave resonance frequency (fMW2) with a second vertical modulation and wherein the energization of the second horizontal line (LH2) takes place in parallel in time with the energization of the second vertical line (LV2) except for said phase shift.

Preferably, energizing the second horizontal line (LH2) with a second horizontal DC current component (IHG2) is performed with a second horizontal current value, wherein the second horizontal current value may be from 0A.

Preferably, energizing the second vertical line (LV2) with a second vertical DC current component (IVG2) is performed with a second vertical current value, wherein the second vertical current value may be from 0A.

Preferably, the energization of the first horizontal line (LH1) is performed with a first horizontal DC current component (IHG1) with a first horizontal current value, wherein the first horizontal current value may be from 0A.

Preferably, the first vertical line (LV1) is energized with a first vertical direct current component (IVG1) with a first vertical current value, whereby the first vertical current value differs from the second vertical current value. Only by this an addressing takes place.

Preferably, the first vertical current value and the second vertical current value are now selected such that the phase vector of the second quantum dot (NV2) of the second quantum bit (QUB2) executes a phase rotation by the angle φ2, in particular of π/4 or π/2 (Hadamard gate) or 3π/4 or π (not-gate) or an integer multiple of π/4, when the phase vector of the first quantum dot (NV1) of the first quantum bit (QUB1) is in a first position and that the phase vector of the second quantum dot (NV2) of the second quantum bit (QUB2) does not execute a phase rotation about the angle φ2, in particular of π/4 or π/2 (Hadamard gate) or 3π/4 or π (not-gate) or an integral multiple of π/4, if the phase vector of the first quantum dot (NV1) of the first quantum bit (QUB1) is not in the first position but in a second position and that the phase vector of the first quantum dot (NV1) of the first quantum bit (QUB1) then does not perform a phase rotation.

to generate a left or right polarized electromagnetic field, again preferably the first horizontal modulation is phase shifted by +/−π/2 of the period of the first microwave resonance frequency (fMW1) relative to the first vertical modulation and/or the second horizontal modulation is phase shifted by +/−π/2 of the period of the second microwave resonance frequency (fMW2) relative to the second vertical modulation.

### Quantum Computing

A simple basic procedural scheme for performing simple calculations is now described below. It is a method for operating a nucleus-electron-nucleus-electron quantum register (CECEQUREG). It preferably comprises the steps of resetting the quantum dots (NV) of the quantum bits (QUB1, QUB2) of the nucleus-electron-nucleus-electron quantum register (CECEQUREG) and manipulating the quantum dots (NV) of the quantum bits (QUB1, QUB2) of the nucleus-electron-nucleus-electron quantum register (CECEQUREG) and storing the manipulation result and resetting the quantum dots (NV) of the quantum bits (QUB1, QUB2) of the nucleus-electron-nucleus-electron quantum register (CECEQUREG) and reading back the stored manipulation results and reading out the state of the quantum dots (NV) of the quantum bits (QUB1. QUB2) of the nucleus-electron-nucleus-electron quantum register (CECEQUREG).

Preferably, the resetting of the quantum dots (NV) of the quantum bits (QUB1, QUB2) of the nucleus-electron-nucleus-electron quantum register (CECEQUREG) is performed by means of one of the described quantum bit resetting methods.

Preferably, the single or multiple manipulation of the quantum states of the of the quantum dots (NV) of the quantum bits (QUB1, QUB2) of the nucleus-electron-nucleus-electron quantum register (CECEQUREG) is performed by means of one of the described quantum bit manipulation methods.

Preferably, storing the manipulation result is performed using one of the methods described previously for affecting the quantum state of a nuclear quantum dot as a function of the quantum state of a quantum dot.

Preferably, the second reset of the quantum dots (NV) of the quantum bits (QUB1, QUB2) of the nucleus-electron-nucleus-electron quantum register (CECEQUREG) is performed by means of one of the described quantum bit reset methods.

Preferably, the read back of the stored manipulation results is performed by a method using one of the previously described methods for influencing the quantum state of a quantum dot as a function of the quantum state of a nuclear quantum dot.

Preferably, the readout of the state of the quantum dots (NV) of the quantum bits (QUB1, QUB2) of the quantum register (QUREG) and/or the quantum dot (NV) of the quantum bit (QUB) is performed by a quantum bit weighting method and/or a quantum computing result extraction method.

An alternative method for operating a quantum register (QUREG) and/or a quantum bit (QUB) comprises the steps of resetting the quantum dots (NV) of the quantum bits (QUB1, QUB2) of the nucleus-electron-nucleus-electron quantum register (CECEQUREG) by means of one of the described quantum bit resetting methods and the step of manipulating the quantum states of the quantum dots (NV) of the quantum bits (QUB1, QUB2) of the nucleus-electron-nucleus-electron quantum register (CECEQUREG) by means of one of the described quantum bit manipulation methods, and the step of storing the manipulation result by means of one of the previously described methods for influencing the quantum state of a nuclear quantum dot depending on the quantum state of a quantum dot, and the step of resetting the quantum dots (NV) of the quantum bits (QUB1, QUB2) of the nucleus-electron-nucleus-electron quantum register (CECEQUREG) by means of one of the described quantum bit resetting methods, and reading back the stored manipulation results by means of one of the previously described methods for influencing the quantum state of a quantum dot in dependence on the quantum state of a nuclear quantum dot and reading out the state of the quantum dots (NV) of the quantum bits (QUB1, QUB2) of the quantum register (QUREG) and/or the quantum dot (NV) of the quantum bit (QUB) by a quantum bit evaluation method and/or a quantum computing result extraction method.

Quantum Hardware

### Quantum Bus

The now following section is of special importance. In a quantum computer, not charge carriers but dependencies are transported. This is unusual in that here the absolute state of the quantum bits is irrelevant in many cases. Rather, dependencies, i.e., information, now play the role of charge carriers. The transport of these charge carriers requires a transport bus for the interdependencies of the quantum information. This transport bus is called quantum bus (QUBUS) in the following and is the crucial element for linking several quantum dots several quantum bits among each other. Via the quantum dots of the quantum bits, the nuclear quantum dots assigned to these quantum bits can then be reached even and especially at larger distances from each other, so that dependencies from one nuclear quantum dot can be transported via this quantum bus to another nuclear quantum dot. This enables the coupling of two nuclear quantum dots that are not placed so close to each other that they can be coupled directly. Preferably, the quantum bus is implemented as a chain of quantum dots, for example as an n-bit quantum register (NBQUREG). Thus, it is preferably, but not necessarily, a stretched linear chain, which is de fac to a dependence line. The quantum dots of this chain form a large quantum register. It is exploited here that the range of the couplings of the quantum dots-here also called electron-electron coupling range-, e.g., of the NV centers in diamond or of the G centers in silicon or of the V centers in silicon carbide among themselves, is larger than the range of the couplings of the nuclear quantum dots with the quantum dots-here also called nucleus-electron coupling range-. Such a quantum bus (QUBUS) therefore preferably has n quantum bits (QUB1 to QUBn), with n as a positive integer. In order to form a quantum bus (QUBUS), n must be ≥2. For example, suppose that the quantum bus (QUBUS) has a first nuclear quantum bit (CQUB1) and has an n-th nuclear quantum bit (CQUBn). Let the fast nuclear quantum bit (CQUB1) be associated with the first quantum bit (QUB1) of the quantum bus (QUBUS) by way of example. Let the n-th nuclear quantum bit (CQUBn) be associated with the n-th quantum bit (QUBn) of the quantum bus (QUBUS) by way of example. This is just an example. Each quantum bit of the quantum bits (QUB1 to QUBn) of the quantum bus (QUBUS) may have no or one or more nuclear quantum dots. Just as well, the quantum bus example described here may represent only a partial quantum bus of a larger quantum bus (QUBUS) or a quantum bus network (QUNET). Therefore, for clarification and simplification only, and as an example, we assume that the first quantum bit (QUB1) is located at one end of an exemplary linear branch-free quantum bus, and that the n-th quantum bit (QUBn) is located at the other end of this exemplary model quantum bus. More complex topologies of the quantum bus are explicitly possible and are included in the stress. In this respect, this is only an example to illustrate the dependence transport over the quantum bus.

We number the n quantum bits (QUB1 to QUBn) along the exemplary quantum bus assumed to be linear from 1 to n for better clarity of the description. Obviously, in this example, these n quantum bits (QUB1 to QUBn) form an exemplary n-bit quantum register (NBQUREG).

Here, a j-th quantum bit (QUBj) is any of these n quantum bits (QUB1 to QUBn) with 1<j<n, which is to be considered only if n>2 holds.

Every j-th quantum bit (QUBj) has a predecessor quantum bit (QUB(j−1)) and a successor quantum bit (QUB(j+1)).

The first quantum bit (QUB1) forms a first nucleus-electron quantum register (CEQUREG1) with the first nuclear quantum bit (CQUB1).

The n-th quantum bit (QUBn) forms an n-th nucleus-electron quantum register (CEQUREGn) with the n-th nuclear quantum bit (CQUBn).

The first quantum bit (QUB1) now forms a first electron-electron quantum register (QUREG1) with the second quantum bit (QUB2), which is located at the beginning of the quantum bus assumed to be linear here as an example.

The n-th quantum bit (QUBn) forms with the (n−1)-th quantum bit (QUB(n−1)) an (n−1)-th electron-electron quantum register (QUREG(n−1)) located at the other end of the quantum bus.

Between these two quantum registers (QUREG1, QUREG(n−1)), there is now a chain of two-bit quantum registers along the quantum bus (QUBUS), which preferentially overlap.

Each of the other n−2 quantum bits will now be referred to as a j-th quantum bit (QUBj) with 1<j<n when n>2 for clarity. Each of these j-th quantum bits then forms a (j−1)-th quantum register (QUREG(j−1)) with its predecessor quantum bit (QUB(j−1)). Similarly, each of these j-th quantum bits with its successor quantum bit (QUB(j+1)) forms a j-th quantum register (QUREGj). Thus, a closed chain with two nucleus-electron quantum registers (CEQUREG1, CEQUREGn) and n−1 two-bit quantum registers (QUREG1 to QUREG(n−1)) between the first nuclear quantum bit (CQUB1) and the n-th nuclear quantum bit (CQUBn) is then obtained. This closed chain with two nucleus-electron quantum registers (CEQUREG1, CEQUREGn) and n−1 two-bit quantum registers (QUREG1 to QUREG(n−1)) between the first nuclear quantum bit (CQUB1) and the n-th nuclear quantum bit (CQUBn) then enables the transport of dependencies between the nuclear quantum bits (CQUB1, CQUBn) even if the first nuclear quantum bit (CQUB1) cannot couple directly with the n-th nuclear quantum bit (CQUBn) without the aid of the n quantum bits (QUB1 to QUBn) due to a too large spatial distance.

At this point, we now recall that a quantum bit can form a quantum ALU with a plurality of nuclear quantum bits. The quantum bit of one quantum ALU can then be connected to the quantum bit of another quantum ALU by means of such a quantum bus. As before, we restrict our example to the direct connection of two quantum ALUs by a chain of quantum registers. It is obvious that more complex topologies with branches, loops, and multiple quantum ALUs and nuclear quantum bits are possible. Such devices are included by the stress. For simplicity, we again assume for the explanation as an example that a quantum bus (QUBUS) with n quantum bits (QUB1 to QUBn) is formed by the chain of quantum registers. Again, let n represent a positive integer, with n≥2. Let the exemplary quantum bus (QUBUS) have a first quantum ALU (QUALU1) and an n-th quantum ALU (QUALUn). As before, we number the n quantum bits (QUB1 to QUBn) of the exemplar simple quantum bus from 1 to n for clarity. Let the first quantum bit (QUB1) be the quantum bit (QUB1) of the first quantum ALUs (QUALU1) as an example, and let the n-th quantum bit (QUBn) be the quantum bit (QUBn) of the n-th quantum ALUs (QUALUn). For simplicity, the intervening quantum bits are lumped together as the j-th quantum bit (QUBj), which thus represents any one of these n quantum bits (QUB1 to QUBn) with 1<j<n, to be considered only when n>2 holds. Each j-th quantum bit (QUBj) in this example has a predecessor quantum bit (QUB(j−1)) and a successor quantum bit (QUB(j+1)). The first quantum bit (QUB1) forms a first electron-electron quantum register (QUREG1) with the second quantum bit (QUB2) in this example. The n-th quantum bit (QUBn) forms an (n−1)th electron-electron quantum register (QUREG(n−1)) with the (n−1)-th quantum bit (QUB(n−1)) in this example. Each of the other n−2 quantum bits, hereafter referred to as a j-th quantum bit (QUBj) with 1<j<n when n>2, forms in this example with its predecessor quantum bit (QUB(j−1)) a (j−1)-th quantum register (QUREG(j−1)) and with its successor quantum bit (QUB(j+1)) a j-th quantum register (QUREGj). This again results in a closed chain of n−1 quantum registers (QUREG1 to QUREG(n−1)) between the first nuclear quantum bit (CQUB1) and the n-th nuclear quantum bit (CQUBn). Thus, the transport of dependencies between the nuclear quantum bits of the quantum ALUs becomes possible. First, the transport of the dependencies within a quantum ALU between two nuclear quantum bits of this quantum ALU can be performed via the quantum bit of the quantum ALU in question. Second, the transport of the dependencies between the nuclear quantum bit of one quantum ALU and the nuclear quantum bit of another quantum ALU can be done via the said chain of two-bit quantum registers. This enables the entanglement of all nuclear quantum bits with each other. Therefore, the nuclear quantum bits preferentially serve the quantum computation process while preferentially the quantum dots serve the transport of the dependencies between the nuclear quantum bits.

As mentioned above, the proposed quantum bus has linear sections (FIG. 25) and/or a branch (FIG. 27) and/or a kink (FIG. 26) or a loop (FIG. 28).

Preferably, the quantum bus is provided with means (HD1 to HDn, HS1 to HSn, and HD1 to VDn, VS1 to VSn, CBA, CBB, μC), in order to determine the spin of the electron configuration of the n-th quantum dot (NVn) of the n-th quantum ALU (QUALUn) and/or the nuclear spin of a nuclear quantum dot (CIn) of the n-th quantum ALU (QUALUn) depending on the electron configuration of the first quantum dot (NV1) of the first quantum ALU (QUALU1) and/or to change the nuclear spin of a nuclear quantum dot (CI1) of the first quantum ALU (QUALUn) by means of quantum bits of the n quantum bits (QUB1 to QUBn). Of course, this also applies to other pairings of nuclear quantum dots of the device in an analogous way.

### Quantum Bus Operation

To the previously described quantum bus (QUBUS), which serves the transport of dependencies between the nuclear quantum dots of the nuclear quantum bits or the nuclear quantum dots of the quantum ALUs, which are connected to the quantum bus via quantum dots of the associated quantum bits, belongs a method for the operation of such a quantum bus. Since the quantum ALUs consist of nucleus-electron quantum registers (CEQUREG), it is sufficient to describe the transport using a simple example. The possible, more complex quantum bus topologies with branches and rings of quantum dot chains of concatenated two-bit quantum registers (QUREG) are explicitly included by the claim. The method for operating such a quantum bus (QUBUS) is preferably a method for exchanging, in particular spin-exchanging, the quantum information, in particular the spin information, of the j-th quantum dot (NVj) of a j-th quantum bit (QUBj) with the quantum information, in particular the spin information, of the (j+1)-th quantum dot (NV(j+1)) of the subsequent (j+1)-th quantum bit (QUB(j+1)) of a quantum bus (QUBUS). Here, the j-th quantum dot (NVj) of a j-th quantum bit (QUBj) exemplifies a quantum dot of the chain of quantum dots of the quantum bus. The method is based on performing an electron-electron CNOT operation as described previously. Here, the electron-electron CNOT operation is performed with the j-th quantum bit (QUBj) as the first quantum bit (QUB1) of the electron-electron CNOT operation and with the (j+1)-th quantum bit (QUB(j+1)) as the second quantum bit (QUB2) of the electron-electron CNOT operation. So, in summary, it is nothing else than the application of an electron-electron CNOT operation to a quantum dot pair of quantum dots of the quantum bus (QUBUS).

With the help of this operation, the transport of dependencies via the quantum bus (QUBUS) can already be ensured. However, the coupling of the nuclear quantum dots to the chain of quantum dots is still missing. This is now done with the following procedure.

to this end, we disclose herein an exemplary method for entangling the exemplary first quantum dot (NV1) of the first quantum bit (QUB1) with the exemplary first nuclear quantum dot (CI1) of the first nuclear quantum bit (CQUB1) of a quantum bus (QUBUS). A first step of this method is to perform an electron-nucleus exchange operation, in particular a nucleus-electron de-entanglement operation, as described above. Here, the first quantum bit (QUB1) is the quantum bit (QUB) of said electron-nucleus exchange operation and the first nuclear quantum bit (CQUB1) is the nuclear quantum bit (CQUB) of said electron-nucleus exchange operation. Here, the first quantum bit (QUB1) exemplarily stands for any first quantum bit of the quantum bus (QUBUS) and the first nuclear quantum bit (CQUB1) stands for any nuclear quantum bit of the quantum bus (QUBUS) which can interact with the first quantum bit (QUB1). Thus, with the help of this operation, the coupling of the nuclear quantum dots to the chain of quantum dots can now be ensured.

However, it is also the goal to change the quantum information of a nuclear quantum bit depending on another nuclear quantum bit, which is also accessible via the quantum bus (QUBUS).

to this end, we give here another exemplary method for entangling the exemplarily chosen n-th quantum dot (NVn) of the n-th quantum bit (QUBn) with the likewise exemplarily chosen n-th nuclear quantum dot (On) of the n-th nuclear quantum bit (CQUBn) of a quantum bus (QUBUS). Thus, it is the application of the immediately previously described method to the n-th quantum bit (QUBn) and the n-th nuclear quantum bit (CQUBn) instead of the first quantum bit (QUB1) and the first nuclear quantum bit (CQUB). Here, the n-th quantum bit (QUBn) exemplifies any other quantum bit of the quantum bus (QUBUS) and the n-th nuclear quantum bit (CQUBn) exemplifies any other nuclear quantum bit of the quantum bus that can interact with the n-th quantum bit (QUBn). What is important for the example discussed here is only that the first quantum bit (QUB1) is different from the n-th quantum bit (QUBn) and that the first nuclear quantum bit (CQUB1) is different from the n-th nuclear quantum bit (CQUBn). For better understanding, indices 1 and n were chosen as arbitrary examples. Indices i and j with i≠j could also have been chosen instead of 1 and n. The method then involves performing an electron-nucleus exchange operation, in particular a nucleus-electron de-entanglement operation, as described above. Here, the n-th quantum bit (QUBn) represents the quantum bit (QUB) of said electron-nucleus exchange operation and the n-th nuclear quantum bit (CQUBn) represents the nuclear quantum bit (CQUB) of said electron-nucleus exchange operation. Thus, the connection of the further nuclear quantum dot to the quantum bus is now possible. We now assume that a chain of n quantum dots connects the first quantum dot (NV1) and thus the first quantum bit (QUB1) to the n-th quantum dot (NVn) and thus to the n-th quantum bit (QUBn). The quantum bus may furthermore comprise further quantum bits and further nuclear quantum bits, which are not considered further here as an example.

Before the exemplary first nuclear quantum dot (CI1) of the first nuclear quantum bit (CQUB1) can be entangled with the exemplary n-th nuclear quantum dot (CIn) of the n-th nuclear quantum bit (CQUBn), the quantum dots of the chain of quantum dots of the quantum bus (QUBUS) between these two nuclear quantum dots and possibly further quantum dots are preferably reset. The method for entangling the first nuclear quantum bit (CQUB1) with the n-th nuclear quantum bit (CQUBn) of a quantum bus (QUBUS) therefore comprises, if necessary, the preceding erasure of then quantum bits (QUB1 to QUBn) of the quantum bus (QUBUS), in particular by means of a quantum bit reset method, for initializing the quantum bus (QUBUS). Then, the entanglement of the first quantum dot (NV1) of the first quantum bit (QUB1) with the first nuclear quantum dot (CI1) of the first nuclear quantum bit (CQUB1) of the quantum bus (QUBUS) is performed, in particular by using the previously described method for entangling the first quantum dot (NV1) of the first quantum bit (QUB1) with the first nuclear quantum dot (CI1) of the first nuclear quantum bit (CQUB1) of a quantum bus (QUBUS). This operation places the change information on the first quantum bit (QUB1) of the quantum bus (QUBUS). The change information can now be transported from the first quantum bit (QUB1) of the quantum bus (QUBUS) to the other end of the quantum bus (QUBUS). This is done by then repeatedly performing the following step until all n−1 quantum dots (NV2 to NVn) are entangled with their predecessor quantum dot (NV1 to NV(n−1)) and thus with the first nuclear quantum dot (CI1) of the first nuclear quantum bit (CQUB1).

For this purpose, starting with the first quantum dot (QUB1) of the quantum bus (QUBUS), the following step is executed for all subsequent quantum bits (QUBj), with the index j being increased by 1 with each step execution until j=n is reached. This following step involves interleaving the j-th quantum dot (NVj) of a j-th quantum bit (QUBj) with the (j+1)-th quantum dot (NV(j+1)) of the subsequent (j+1)-th quantum bit (QUB(j+1)) of the quantum bus (QUBUS). In the first application of this step, j=1 is logically chosen to entangle the first quantum dot (NV1) with the second quantum dot (NV2). In subsequent applications of this step until the previously named loop termination condition of j=n is reached, after the step is performed, the new index j is chosen to be increased by one with j=j+1 and the j-th quantum dot (NVj) is entangled with the (j+1)-th quantum dot (NV(j+1)). The method used in each of these steps is preferably the method described above for the exchange, in particular spin exchange, of the quantum information, in particular spin information, of the j-th quantum dot (NVj) of a j-th quantum bit (QUBj) with the quantum information, in particular the spin information, of the (j+1)-th quantum dot (NV(j+1)) of the subsequent (j+1)-th quantum bit (QUB(j+1)) of a quantum bus (QUBUS). Subsequently, the step is repeated until all n−1 quantum dots (NV2 to NVn) are entangled with their predecessor quantum dot (NV1 to NV(n−1)) and thus with the quantum infatuation of the first nuclear quantum dot (CI1) of the first nuclear quantum bit (CQUB1).

In this way, the change information is now transported from the first quantum dot (NV1) of the first quantum bit (QUB1) via the other quantum dots (NV2 to NV(n−1)) of the quantum bus (QUBUS) to the n-th quantum dot (NVn) of the n-th quantum bit (QUBn) of the quantum bus (QUBn). Now the task remains to perform a final entanglement of the quantum information of the n-th quantum dot (NVn) of the n-th quantum bit (QUBn) with the quantum information of the n-th nuclear quantum dot (CIn) of the n-th nuclear quantum bit (CQUBn) to complete the transport of the change information.

Therefore, the temporally subsequent entanglement of the n-th quantum dot (NVn) of the n-th quantum bit (QUBn) with the n-th nuclear quantum dot (CIn) of the n-th nuclear quantum bit (CQUBn) of the quantum bus (QUBUS) follows, in particular by using a method for entangling the n-th quantum dot (NVn) of the n-th quantum bit (QUBn) with the n-th nuclear quantum dot (CIn) of the n-th nuclear quantum bit (CQUBn) of a quantum bus (QUBUS).

It is now useful to transport the entanglement once again in the other direction, if necessary. For this purpose, if necessary, the following step of entanglement of the quantum information, in particular of the spin exchange, of the j-th quantum dot (NVj) of a j-th quantum bit (QUBj) with the (j+1)-th quantum dot (NV(j+1)) of the following (j+1)-th quantum bit (QUB(j+1)) of the quantum bus (QUBUS) is executed several times. Now, in the first application of this step, since it is to go back, j=n is chosen. In the following applications of this step, with each step compared to the previous step until the previously named loop termination condition of j=1 is reached, the new index is chosen to be j=j−1. Then, after the change information has been transported back from the n-th quantum bit (QUBn) to the first quantum bit (QUB1), the first quantum dot (NV1) of the first quantum bit (QUB1) is now entangled with the first nuclear quantum dot (CI1) of the first nuclear quantum bit (CQUB1). An entanglement of the quantum information, in particular a spin exchange, of the first quantum dot (NV1) of the first quantum bit (QUB1) with the quantum information of the first nuclear quantum dot (CI1) of the first nuclear quantum bit (CQUB1) of the quantum bus (QUBUS) takes place.

If necessary, a final erasure of the n quantum bits (QUB1 to QUBn) of the quantum bus (QUBUS) takes place.

Now a further method for entangling the first nuclear quantum bit (CQUB1) with the n-th nuclear quantum bit (CQUBn) of a quantum bus (QUBUS) is given here. In this further method, a preceding erasure of the n quantum bits (QUB1 to QUBn) of the quantum bus (QUBUS) for initialization of the quantum bus (QUBUS) takes place first, if necessary. If necessary, a preceding erasure of the first nuclear quantum bit (CQUB1) and/or a preceding erasure of the n-th nuclear quantum bit (CQUBn) is also performed beforehand. If this erasing process should have modified quantum bits of the n quantum bits of the quantum bus, it may make sense to perform another preceding erasing of the first quantum bit (QUB1) and of the n-th quantum bit (up to QUBn) of the quantum bus (QUBUS) to initialize the quantum bus (QUBUS).

Then, preferably, performing a Hadamard gate with the first quantum bit (QUB1) as the quantum bit (QUB) of said Hadamard gate and performing an electron-nucleus CNOT operation with the quantum bit (QUB1) and the first nuclear quantum bit (CQUB1) is performed. Now the change information, which was put on the quantum bus (QUBUS) with the last step, is transported via the quantum bus (QUBUS). For this purpose, the following step is executed repeatedly until all n−1 quantum dots (NV2 to NVn) are entangled with their predecessor quantum dot (NV1 to NV(n−1)). This following step is thereby the entanglement of the j-th quantum dot (NVj) of a j-th quantum bit (QUBj) with the (j+1)-th quantum dot (NV(j+1)) of the subsequent (j+1)-th quantum bit (QUB(j+1)) of the quantum bus (QUBUS), in particular by means of an electron-electron CNOT as described before. In the first application of this step, j=1 is again chosen. In subsequent applications of this step until the previously named loop termination condition of j=n is reached, the new index is then chosen again with j=j+1 in each new step. This then entangles all n quantum dots (NV1 to NVn) of the quantum bus (QUBUS).

Now, in order to also entangle the n-th nuclear quantum dot (CIn) with the n quantum dots (QUB1 to QUBn) of the quantum bus (QUBUS), an electron-nucleus CNOT operation is then performed with the n-th nuclear quantum bit (QUBn) and the n-th nuclear quantum bit (CQUBn). As a result, the first nuclear quantum dot (NV1) of the first nuclear quantum bit (CQUB1) is then entangled with the n-th nuclear quantum dot (NVn) of the n-th nuclear quantum bit (CQUBn). If necessary, quantum dots (NV1 to NVn) of the quantum bits (QUB1 to QUBn) of the quantum bus (QUBUS) should then be reset by means of “green light”.

### Quantum Computer

A quantum computer capable of performing the procedures described above is characterized by typically comprising at least one control device (μC) and typically at least one light source (LED). The light source, which is preferably used to generate the “green light” for resetting the quantum dots (NV1 to NVn) of the quantum bits (QUB1 to QUBn) of the quantum bus (QUBUS), may in particular be an LED and/or a laser and/or a tunable laser, to be able to operate the at least one light source, the quantum computer preferably comprises at least one light source driver (LEDDR). A quantum computer as proposed herein preferably comprises at least one of the following quantum-based sub-devices such as one or preferably more quantum bits (QUB) and/or one or preferably more quantum registers (QUREG) and/or one or preferably more nucleus-electron quantum registers (CEQUREG), and/or one or more nucleus-electron-nucleus-electron quantum registers (CECEQUREG) and/or one or more array of quantum dots (NV) and/or one or more quantum buses (QUBUS).

The at least one light source (LED) is preferably supplied with electrical energy by the at least one light source driver (LEDDR) at times as a function of a control signal from the control device (μC).

Preferably, the at least one light source (LED) is suitable and/or intended to reset at least part of the quantum dots (NV). Preferably, it is shown in that the light source (LED) is suitable and/or intended to irradiate one or more quantum dots with “green light”.

Preferably, the quantum computer (QC) is characterized in that it comprises at least one circuit and/or semiconductor circuit and/or CMOS circuit in particular for controlling the quantum bits and/or nuclear quantum bits and/or quantum registers and/or electron-nuclear quantum registers. Preferably, such a quantum computer comprises at least one of the following quantum-based sub-devices such as one or more quantum bits (QUB) and/or one or more quantum registers (QUREG) and/or one or more nucleus-electron quantum registers (CEQUREG) and/or one or more nucleus-electron-nucleus-electron quantum registers (CECEQUREG) and/or one or more arrays of quantum dots (NV) and/or one or more quantum buses (QUBUS). Preferably, the at least one circuit and/or semiconductor circuit and/or CMOS circuit comprises means which, individually or in groups, are arranged and suitable for carrying out at least one of the methods described above, in particular of the electron-nucleus exchange operation method and/or quantum bit reset method and/or nucleus-electron quantum register reset method and/or quantum bit microwave drive method and/or nucleus-electron quantum register radio wave drive method and/or nucleus-quantum bit radio wave drive method and/or nucleus-electron quantum register radio wave drive method and/or selective quantum bit drive method and/or selective quantum register drive method and/or quantum bit evaluation and/or quantum computer result extraction and/or quantum computing and/or to perform quantum bus operation, as described above.

Preferably, the quantum computer has one or more devices of a magnetic field control (MFC) with at least one or more magnetic field sensors (MFS) and at least one or more actuators, in particular a magnetic field control (MFK), to stabilize the magnetic field in the area of the device by active control. Preferably, the magnetic field control (MFC) in particular is part of the control device. Equally preferably, the magnetic field control (MFC) can be controlled by the control device or a control computer (AC).

### Integrated Circuit for a Quantum Computer

The circuit and/or semiconductor circuit and/or CMOS circuit preferably used for the quantum computer comprises at least one control device (μC). Preferably, it comprises means suitable and/or provided for controlling at least one of the following quantum-based sub-devices with a first quantum bit (QUB1) to be driven. These are exemplarily one or more quantum bits (QUB) and/or one or more quantum registers (QUREG) and/or one or more nucleus-electron quantum registers (CEQUREG) and/or one or more nucleus-electron-nucleus-electron quantum registers (CECEQUREG) and/or one or more arrays of quantum dots (NV) and/or a quantum bus (QUBUS) and/or one or more quantum ALUs (QUALU).

Preferably, for controlling an exemplary first quantum bit to be driven (QUB1), it comprises.
a first horizontal driver stage (HD1) associated with the exemplary first quantum bit (QUB1) to be driven for controlling the first quantum bit (QUB1) to be driven and/or
a first horizontal receiver stage (HS1) associated with the exemplary first quantum bit (QUB1) to be driven, which can form a unit with the first horizontal driver stage (HD1), for controlling the first quantum bit (QUB1) to be driven, and/or
a first vertical driver stage (VD1) associated with the exemplary first quantum bit (QUB1) to be driven for controlling the first quantum bit (QUB1) to be driven and/or
a first vertical receiver stage (VS1) associated with the exemplary first quantum bit (QUB1) to be driven, which can form a unit with the first vertical driver stage (VD1).

Here, the first quantum bit (QUB1) is representative of any quantum bit of the quantum computer or quantum technological device. Therefore, the claims are to be construed for any quantum bit of the quantum computer or the quantum technological device. Thus, the term “first quantum bit (QUB1)” is herein only a designation for any quantum bit of the device. The term “first” is only intended to distinguish it from further quantum bits. The same applies in an analogous manner to the first driver stage (HD1), the first horizontal receiver stage (HS1), the first vertical driver stage (VD1) and the first vertical receiver stage (VS1).

The first horizontal driver stage (HD1) and the first horizontal receiver stage (HS1) preferably drive the exemplary first quantum bit (QUB1) to be driven via the first horizontal line (LH1) of the first quantum bit (QUB1).

The first vertical driver stage (VD1) and the first vertical receiver stage (VS1) preferably drive the exemplary first quantum bit (QUB1) to be driven via the first vertical line (LV1) of the first quantum bit (QUB1).

Preferably, the first horizontal driver stage (HD1) feeds the first horizontal current (IH1) into the first horizontal line (LH1) of the first quantum bit (QUB1).

Preferably, the first vertical driver stage (VD1) feeds the first vertical current (IV1) into the first vertical line (LV1) of the first quantum bit (QUB1).

The first horizontal current (IH1) preferably has a first horizontal current component with a first horizontal modulation with a first frequency (f).

Preferably, the first vertical current (IV1) has a first vertical current component with a first vertical modulation with the first frequency (f).

Preferably, the first vertical modulation of the first vertical current component of the first vertical current (IV1) is at least temporarily out of phase with respect to the first horizontal modulation of the first horizontal current component of the first horizontal current (IH1) by a first temporal phase offset of essentially +/−π/2 of the frequency (f).

Preferably, the first horizontal current component of the first horizontal current (IH1) is pulsed with a first horizontal current pulse having a first pulse duration (τPI) and/or the first vertical current component of the rust vertical current (IV1) is pulsed with a first vertical current pulse having the first pulse duration (τPI).

Preferably, the first vertical current pulse is phase shifted in time by the temporal first phase offset with respect to the first horizontal current pulse and/or the first vertical current pulse is phase shifted in time by the temporal first phase offset of +/−π/2 of the frequency (f) with respect to the first horizontal current pulse.

Preferably, the first frequency (f) has the same effect as one of the following frequencies:
a nucleus-electron microwave resonance frequency (f_{MWCE}) or
an electron-nucleus radio wave resonance frequency (f_{RWEC}) or
an electron1-electron1 microwave resonance frequency (f_{MW}) or
an electron1-electron2 microwave resonance frequency (f_{MWEE}) or
of a nucleus-to-nucleus radio wave resonance frequency (f_{RWCC}).

Preferably, the first pulse duration τP corresponds at least temporarily to an integer multiple of π/4 of the period τRCE of the Rabi oscillation oldie nucleus-electron Rabi oscillation, if the first frequency (f) is effective equal to a nucleus-electron microwave resonance frequency (fMWCE), and/or the first pulse duration τP corresponds at least temporarily to an integer multiple of π/4 of the period τREC of the nucleus-electron Rabi oscillation when the first frequency (f) is effective equal to a nucleus-electron radio wave resonance frequency (fRWEC). Also, the first pulse duration P may correspond, at least at times, to an integer multiple of π/4 of the period τR of the Rabi oscillation of the electron1-electron1-Rabi oscillation, if the first frequency (F) is effective equal to an electron1-electron1 microwave resonance frequency (fMW) and/or at least temporarily correspond to an integer multiple of π/4 of the period τREE of the Rabi oscillation of the electron1-electron2 Rabi oscillation, if the first frequency (f) is effective equal to an electron1-electron2 microwave resonance frequency (fMWEE). Similarly, the first pulse duration τ P may correspond, at least at times, to an integer multiple of π/4 of the period τRCC of the Rabi oscillation of the nucleus-nucleus Rabi oscillation if the first frequency (f) is effectively equal to a nucleus-nucleus radio wave resonance frequency (fRWCC).

Preferably, the circuit and/or semiconductor circuit and/or CMOS circuit has a second horizontal driver stage (HD2) for controlling a second quantum bit (QUB2) to be driven and it has a second horizontal receiver stage (HS2) which can form a unit with the second horizontal driver stage (HD2). These are preferably used for controlling the second quantum bit (QUB2) to be driven.

Said circuit and/or semiconductor circuit and/or CMOS circuit further preferably comprises a second vertical driver stage (VD2) for controlling a second quantum bit (QUB2) to be driven and a second vertical receiver stage (VS2) which can form a unit with the second vertical driver stage (VD2). These are also preferably used for controlling the second quantum bit (QUB2) to be driven.

The first vertical driver stage (VD) is preferably used to drive the second quantum bit (QUB2) to be driven. The first vertical receiver stage (VS1) is preferably used to drive the second quantum bit (QUB2) to be driven.

Here, the second quantum bit (QUB1) is representative of any quantum bit of the quantum computer or quantum technological device that is different from the aforementioned exemplary first quantum bit (QUB1). Therefore, the claims are to be construed for any quantum bit of the quantum computer or quantum technological device different from the aforementioned exemplary first quantum bit (QUB1). Thus, the term “second quantum bit (QUB2)” is herein only a designation for any quantum bit of the device that is different from the aforementioned exemplary first quantum bit (QUB1). The term “second” is only intended to distinguish it from further quantum bits and from said first quantum bit (QUB1). The same applies in an analogous manner to the second driver stage (HD2), the second horizontal receiver stage (HS2), the second vertical driver stage (VD2) and the second vertical receiver stage (VS2).

Preferably, the first horizontal driver stage (HD1) and the first horizontal receiver stage (HS1) are co-used to drive the second quantum bit to be driven (QUB2). (See figures.) Preferably, the first horizontal driver stage (HD1) feeds a first horizontal DC current component as a further horizontal current component into the first horizontal line (LH1). The magnitude of the first horizontal DC current component can be 0A. The second horizontal driver stage (HD2) preferably feeds a second horizontal DC component as a further horizontal current component into the second horizontal line (LH2), where the magnitude of the second horizontal DC component can be 0A. The first vertical driver stage (VD1) preferably feeds a first vertical DC current component as a further vertical current component into the first vertical line (LV1). The magnitude of the first vertical DC current component may be 0A. The second vertical driver stage (HD2) feeds a second vertical DC current component as a further vertical current component into the second vertical line (LV2). The magnitude of the second vertical DC current component can be 0A.

The first horizontal DC component and/or the second horizontal DC component and/or the first vertical DC component and/or the second vertical DC component can be set, that the first nucleus-electron microwave resonance frequency (fMWCE1) of a first nucleus-electron quantum register (CEQUREG1) of a nucleus-electron-nucleus-electron quantum register (CECEQUREG) is different from the second nucleus-electron microwave resonance frequency (fMWCE2) of a second nucleus-electron microwave quantum register (CEQUREG2) of the nucleus-electron quantum register (CECEQUREG). electron quantum register (CEQUREG2) of the nucleus-electron-nucleus-electron quantum register (CECEQUREG) deviates or that the first electron-nucleus radio wave resonance frequency (fRWEC1) of a first nucleus-electron quantum register (CEQUREG1) of a nucleus-electron-nucleus-electron quantum register (CECEQUREG) deviates from the second electron-nucleus radio wave resonance frequency (fRWEC2) of a second nucleus-electron quantum register (CEQUREG2) of the nucleus-electron-nucleus-electron quantum register (CECEQUREG) or that the first electron1-electron1 microwave resonance frequency (fMW1) of a first quantum bit (QUB1) of a quantum register (QUREG) deviates from the second electron1-electron1 microwave resonance frequency (fMW2) of a second quantum bit (QUB2) of the quantum register (QUREG). This enables selective control.

### Manufacturing Process

A method for fabricating a quantum register (QUREG) and/or a quantum bit (QUB) and/or an array of quantum dots and/or an array of quantum bits is now proposed below.

The process comprises providing a substrate (D), in particular a diamond. It comprises the typically subsequent deposition of an epitaxial layer (DEP1) to ensure the perfection of the crystal lattice.

Preferably, an n-doped layer is deposited by CVD methods.

In the exemplary case of diamond as epitaxial layer (DEP1) on a diamond substrate (D), it is preferably an n-doped diamond layer preferably of ¹²C-carbon and/or less well, since radioactive ¹⁴C-carbon. In the case of an epitaxial diamond layer (DEP1), this is preferably already provided with a sulfur doping and/or another n-doping. In this case, however, nitrogen atoms can also be used for n-doping of the epitaxial diamond layer (DEP1), for example in the form of PI centers. Preferably, however, the doping of the epitaxial diamond layer (DEP1) is carried out with ³²S and/or ³³S isotopes.

In the exemplary case of silicon as an epitaxial layer (DEP1) on a silicon substrate (D), it is preferably an n-doped silicon layer, which is preferably made of ²⁸Si isotopes and/or made of silicon isotopes without magnetic moment. In the case of an epitaxial silicon layer, this is preferably already provided with a doping with one or more of the isotopes ¹²⁰Te, ¹²²Te, ¹²⁴Te, ¹²⁶Te, ¹²⁸Te, ¹³⁰Te, ⁴⁶Ti, ⁴⁸Ti, ⁵⁰Ti, ¹²C, ¹⁴C, ⁷⁴Se, ⁷⁶Se, ⁷⁸Se, ⁸⁰Se, ¹³⁰Ba, ¹³²Ba, ¹³⁴Ba, ¹³⁶Ba, ¹³⁸Ba, ³²S, ³⁴S, or ³⁶S and/or other isotopes without nucleus magnetic moment with an n-doping. Here, the carbon atoms in the form of ¹²C or ¹⁴C isotopes can also be used for the n-doping of the epitaxial diamond layer (DEP1), for example in the form of G centers.

The epitaxial layer (DEP1) can have a larger volume than the substrate (D). The substrate (D) can also be only a crystallization nucleus.

If, in the case of diamond as substrate (D), the substrate (D) or the epitaxial layer (DEP1) are not n-doped or sulfur-doped to a sufficient extent, sulfur implantation and/or n-doping of at least parts of the substrate (D) or at least parts of the epitaxial layer (DEP1) is preferably carried out. Furthermore, the radiation damage is preferably cleaned and healed afterwards.

to fabricate the quantum dots in the substrate (D), deterministic single ion implantation is preferably performed to produce paramagnetic centers as quantum dots (NV) in predetermined regions of the substrate (D) or epitaxial layer (DEP1).

In the case of a diamond as substrate (D), for example, single ion implantation of individual nitrogen atoms can be carried out to produce paramagnetic centers as quantum dots (NV) in predetermined areas of the substrate (D) or the epitaxial layer (DEP1). In the case of a diamond as substrate (D), for example, this preferably serves to produce NV centers as quantum dots (NV) in predetermined regions of the diamond serving as substrate (D) or of its epitaxial layer (DEP1), which may have been applied previously.

In the case of silicon as substrate (D), for example, single-ion implantation of individual carbon atoms, in particular, for example, individual ¹²C isotopes, can be carried out to produce paramagnetic centers as quantum dots (NV) in predetermined areas of the substrate (D) or the epitaxial layer (DEP1). In the case of silicon as substrate (D), for example, this preferably serves to produce G centers as quantum dots (NV) in predetermined regions of the silicon crystal serving as substrate (D) or of its epitaxial layer (DEP1), which may have been applied previously.

Preferably, cleaning and temperature treatment are carried out here as well, if necessary.

Preferably, this is followed by a measurement of the function, position and T2 times of the implanted single atoms and, if necessary, a repetition of the two preceding steps if the measurement reveals a failure of the production of the quantum dots.

In the case of NV centers in diamond, their position can be detected by irradiating them with “green light” and detecting the fluorescence position.

To enable the electrical readout of the quantum dots, ohmic contacts to the substrate (D) or to the epitaxial layer (DEP1) are preferably made.

In the case of silicon, if these contacts are sufficiently spaced from the quantum dots (NV) or nuclear quantum dots (CI), the contacts can be made by contact doping with conventional dopants of the III, main group such as B, Ga etc. or V, main group such as P and As can be made, although these have a nucleus magnetic moment μ. Here it is important that the distance of the contact diffusions incl, their out diffusions to the quantum dots (NV) and/or nuclear quantum dots (CI) is larger than the maximum electron-electron coupling range between two quantum dots (NV1, NV2) and larger than the maximum electron-nucleus coupling range between a quantum dot (NV) and a nuclear quantum dot (CI). It has been shown that a distance in the μm range works here. However, the disadvantage of such large distances of the contacts from the quantum dots and/or nuclear quantum dots (CI) is that the photo charge carriers can no longer be extracted in a quantum dot-specific or nuclear quantum dot-specific manner. Therefore, despite the poorer activation energy, it is recommended to dope with isotopes without nucleus magnetic moment μ as listed above.

The horizontal lines (LH1, LH2, LH3) and, if applicable, the horizontal shielding lines (SH1, SH2, SH3, SH4) are produced by means of lithographic steps. Preferably, the horizontal leads (LH1, LH2, LH3) and, if necessary, the horizontal shielding leads (SH1, SH2, SH3, SH4) are made of a material consisting essentially of isotopes without nucleus magnetic moment. The titanium isotope ⁴⁶Ti and/or the titanium isotope ⁴⁸Ti and/or the titanium isotope ⁵⁰Ti are particularly preferred for the production of corresponding titanium lines.

For the production of a multilayer metallization stack, the deposition of an insulation (IS) and, if necessary, the opening of vias is carried out once or several times.

Preferably, the insulation (IS) is made in whole or in part from isotopes without nucleus magnetic moment μ. Particularly preferred is a deposition or sputtering or growth of ²⁸Si¹⁶O² as insulation oxide.

The vertical leads (IV, LV2, LV3) and, if necessary, the vertical shielding leads (SV1, SV2, SV3, SV4) are produced by means of lithographic steps. Preferably, the vertical leads (LV1, LV2, LV3) and, if necessary, the vertical shielding leads (SV1, SV2, SV3, SV4) are made of a material that consists essentially of isotopes without a nucleus magnetic moment. The titanium isotope ⁴⁶Ti and/or the titanium isotope ⁴⁸Ti and/or the titanium isotope are particularly preferred for the production of corresponding titanium lines.

In addition to this basic method for fabricating quantum dots, quantum bits (QUB), quantum registers (QUREG), a method for fabricating a nucleus-electron quantum register (CEQUREG) and/or a quantum bit (QUB) together with a nuclear quantum bit (CQUB) and/or an array of quantum dots (NV) together with an array of nuclear quantum dots (CI) and/or an array of quantum bits (QUB) together with an array of nuclear quantum bits (CQUB) is now described.

These processes comprise the provision of a substrate (D) and, if necessary, the application of an epitaxial layer (DEP1). If the substrate (D) or the epitaxial layer (DEP1) are not doped, said doping of at least pans of the substrate (D) or at least pans of the epitaxial layer (DEP1) and the cleaning and, if necessary, the healing of the radiation damage in the case that the doping was carried out by means of ion implantation. Preferably, the substrate (D) or at least the epitaxial layer (DEP1) comprises essentially only isotopes without a nucleus magnetic moment. In this context, the term “essentially” means that the total fraction K_{IG} of isotopes with magnetic moment of an element that is a component of the substrate (D) or the epitaxial layer (DEP1), relative to 100% of this element that is a component of the substrate (D) or of the isotopes with magnetic moment of an element which is a component of the substrate (D) or of the epitaxial layer (DEN) is reduced to a fraction K_{IG′} of the isotopes with magnetic moment of an element which is a component of the substrate (D) or of the epitaxial layer (DEP1), relative to 100% of this element which is a component of the substrate (D) or of the epitaxial layer (DEP1). Whereby this fraction K_{IG′} is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the respective element of the substrate (D) or of the epitaxial layer (DEP1) in the region of action of the paramagnetic perturbations (NV) used as quantum dots (NV) and/or of the nuclear spins used as nuclear quantum dots (CI).

For the fabrication of the nuclear quantum dots (CI), however, a deterministic single ion implantation of predetermined isotopes having a nucleus magnetic moment μ is now preferably performed for the fabrication of nuclear quantum dots (CI) in predetermined regions of the substrate (D) or the epitaxial layer (DEP1). Preferably, this implantation is also used for simultaneous fabrication of paramagnetic centers as quantum dots (NV).

Preferably, cleaning and temperature treatment are again performed and the function, position and T2 times of the quantum dots (NV) and/or nuclear quantum dots (CI) formed by the implanted single atoms are measured and, if necessary, the two preceding steps are repeated in case of failure.

If necessary, an insulation layer (IS) is deposited on the surface (OF) of the substrate (D) or the epitaxial layer (DEP1). If an epitaxial layer (DEP1) has been deposited, the term surface (OF) refers to the surface of the epitaxial layer (DEP1) and in the other case to the surface of the substrate (D) directly. Preferably, the material of the insulating layer (IS) comprises essentially only isotopes without nucleus magnetic moment. The term “essentially” means here that the total fraction K_{IG} of isotopes with magnetic moment of an element which is a component of the insulation layer (IS), relative to 100% of this element which is a component d of the insulation layer (IS), is reduced compared to the natural total fraction K_{IG} given in the above tables to a fraction K_{IG′} of isotopes with magnetic moment of an element which is a component of the insulation layer (IS), relative to 100% of this element which is a component of the insulation layer (IS). Whereby this fraction K_{IG}′ is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the respective element of the insulation layer (IS) in the region of influence of the paramagnetic impurities (NV) used as quantum dots (NV) and/or the nuclear spins used as nuclear quantum dots (CI).

As before, ohmic contacts are made to the substrate (D) or to the epitaxial layer (DEP1), the horizontal lines (LH1, LH2, LH3) and, if necessary, the horizontal shield lines (SH1, SH2, SH3, SH4) are made, if necessary, a second insulation (IS) is made, if necessary, the vias are opened by the second insulation (IS), and the vertical lines (LV1, LV2, LV3) and, if necessary, the vertical shield lines (LV1, LV2, LV3) are made. (IS), if necessary, the opening of the vial through the second insulation (IS) and the production of the vertical lines (LV1, LV2, LV3) and, if necessary, the vertical shield lines (SV1, SV2, SV3, SV4). If necessary, the metallization stack can include further insulation and metallization levels.

Preferably, the isolations (IS) are essentially made of isotopes without nucleus magnetic moment μ. The term “essentially” means here that the total fraction K_{IG} of isotopes with magnetic moment of an element which is a component of an insulation (IS), based on 100% of this element which is a component of the insulation (IS), is reduced in comparison with the natural total fraction Kin given in the above tables to a fraction K_{IG′} of isotopes with magnetic moment of an element which is a component d of the insulation (IS), based on 100% of this element which is a component of the insulation (IS). Whereby this fraction K_{IG′} is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the respective element d of the isolation (IS) in the action range of the paramagnetic impurities (NV) used as quantum dots (NV) and/or the nuclear spins used as nuclear quantum dots (CI).

Preferably, the horizontal lines (LH1, LH2, LH3) and/or, if applicable, the horizontal shielding lines (SH1, SH2, SH3, SH4) and/or the vertical lines (LV1, LV2, LV3) and, if applicable, the vertical shielding lines (SV1, SV2, SV3, SV4) are essentially made of isotopes without nucleus magnetic moment. The term “essentially” means here that the total fraction KIG of isotopes with magnetic moment of an element which is a component of a horizontal line (LH1, LH2, LH3) and/or, if necessary, of a horizontal shielding line (SH1, SH2, SH3, SH4) and/or of a vertical line (LV1, LV2, LV3) and if necessary of a vertical shielding line (SV1, SV2, SV3, SV4) or a section thereof, with respect to 100% of this element which is part of the horizontal line (LH1, LH2, LH3) and/or, if applicable, of the horizontal shielding line (SH1, SH2, SH3, SH4) and/or of the vertical lines (LV1, LV2, LV3) and, if applicable, of the vertical shielding lines (SV1, SV2, SV3, SV4) or the section of these, compared with the natural total fraction KIG given in the above tables to a fraction KIG′ of the isotopes with magnetic moment of an element which is a component of the horizontal line (LH1, LH2, LH3) and/or, if necessary, of the horizontal shielding line (SH1, SH2, SH3, SH4) and/or of the vertical lines (LV1, LV2, LV3) and, if necessary, of the vertical lines (LV1, LV2, LV3) and, if necessary, of the vertical lines (SV1, SV2, SV3), of the vertical shielding lines (SV1, SV2, SV3, SV4) or of the section thereof is reduced with respect to 100% of this element which is part of the horizontal line (LH1, LH2, LH3) and/or possibly of the horizontal shielding line (SH1, SH2, SH3, SH4) and/or of the vertical lines (LV1, LV2, LV3) and possibly of the vertical shielding lines (SV1, SV2, SV3, SV4) or of the section thereof. Whereby this fraction KIG′ is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction KIG for the respective element d of the isolation (IS) in the area of influence of the paramagnetic impurities (NV) used as quantum dots (NV) and/or the nuclear spins used as nuclear quantum dots (CI).

In the case of a diamond-based device, these processes comprise the provision of a substrate (D), in particular a diamond, and optionally the deposition of an epitaxial layer (DER), optionally already with sulfur doping and/or n-doping. The material under the surface (OF) of the substrate (D) and/or the material of the epitaxial layer (DEP1) preferably comprises, apart from the isotopes of the nuclear quantum dots (CI), essentially only 12C isotopes and/or 14C isotopes. The concentration of the C isotopes with magnetic moment, i.e., for example, the 13C isotopes is preferably lowered. With regard to the interpretation of the term “essentially”, we refer to the above explanations. Provided that the substrate (D) and/or the epitaxial layer (DEP1) are not n-doped or sulfur-doped, said sulfur implantation and/or n-doping of at least pans of the substrate (D) and/or at least parts of the epitaxial layer (DEP1) and the cleaning and healing of the radiation damage preferably take place again, in particular in the case of a diamond material. For doping in the coupling region of quantum dots (NV) or nuclear quantum dots (CI), isotopes of the dopant without nucleus magnetic moment are preferably used. In the case of sulfur doping of diamond, the 32S sulfur isotope is preferably used for n-doping.

In the case of a silicon-based device, these processes comprise the provision of a substrate (D), in particular a silicon wafer, and optionally the deposition of an epitaxial layer (DEP1), optionally already with doping. The material under the surface (OF) of the substrate (D) and/or the material of the epitaxial layer (DEP1) preferably comprises, apart from the isotopes of the nuclear quantum dots (CI), essentially only 28Si isotopes and/or (worse) 30Si isotopes or (even worse) other Si isotopes with a long half-life and without a nucleus magnetic moment. The concentration of Si isotopes with magnetic moment, for example. 29Si isotopes is preferably lowered. With regard to the interpretation of the term “essentially”, we refer to the above explanations. Provided that the substrate (D) reap, the epitaxial layer (DEP1) are not doped, in particular in the case of a silicon material, n-doping is preferably carried out again by means of the isotopes 20Te, 122Te, 124Te, 126Te, 128Te, 130Te, 46Ti, 48Ti, 50Ti, 2C, 14C, 74Se, 76Se, 78Se, 80Se, 130Ba, 132Ba, 134Ba, 136Ba, 138Ba, 32S, 34S, or 36S and/or a p-doping by means of the isotopes 10Be, 102Pd, 104Pd, 106Pd, 108Pd, 110Pd, 204Tl of at least parts of the substrate (D) and/or at least pans of the epitaxial layer (DEP1) and the cleaning and healing of the radiation damage. Thus, for doping in the coupling region of the quantum dots (NV) or the nuclear quantum dots (CI), isotopes of the dopant without nucleus magnetic moment are again preferably used. Outside this coupling region, the conventional dopants (e.g., B, AS, P, In, Ga, etc.) can be used, which typically have a nucleus magnetic moment μ.

In the case of a silicon carbide-based device, these processes comprise the provision of a substrate (D), in particular a silicon carbide wafer, and optionally the deposition of an epitaxial layer (DEP1), optionally already with doping. The material under the surface (OF) of the substrate (D) and/or the material of the epitaxial layer (DEP1) preferably comprises, apart from the isotopes of the nuclear quantum dots (CI), essentially only 12C isotopes and/or 14C isotopes as well as 28Si isotopes and 30Si isotopes. The concentration of the C isotopes with magnetic moment. i.e., for example, 13C isotopes is preferentially lowered in the quantum dot (NV) or nuclear quantum dot (CI) region. The concentration of the Si isotopes with magnetic moment, for example the 29Si isotopes, is preferably reduced in the region of the quantum dots (NV) or the nuclear quantum dots (CI). Regarding the interpretation of the term “essentially” we refer to the above explanations. Provided that the substrate (D) or the epitaxial layer (DEP1) are not n-doped, doping of at least parts of the substrate (D) or at least parts of the epitaxial layer (DEP1) and cleaning and healing of the radiation damage are preferably carried out again, in particular in the case of a silicon carbide material. For doping in the coupling region of the quantum dots (NV) or the nuclear quantum dots (CI), isotopes of the dopant without nucleus magnetic moment are preferably used.

For the fabrication of the nuclear quantum dots (CI) in a substrate (D) or an epitaxial layer (DEP1), however, a deterministic single ion implantation of predetermined isotopes with nucleus magnetic moment μ is now preferably carried out for the fabrication of nuclear quantum dots (CI) in predetermined regions of the substrate (D) or the epitaxial layer (DEP1). Preferably, these isotopes and the single ion implantation conditions are chosen such that the fabrication of nuclear quantum dots (CI) simultaneously leads to the fabrication of quantum dots (NV). Preferably, these predetermined regions of the substrate (D) or epitaxial layer (DEP1) have essentially no isotopes with nucleus magnetic moment μ in their material, except for already fabricated nuclear quantum dots (CI), which can interact with the quantum dots (NV) or nuclear quantum dots (CI). Preferably, they comprise essentially only one isotope, apart from the isotopes of the nuclear quantum dots and the quantum dots. With respect to the interpretation of the term “essentially”, reference is made to the above. Preferably, quantum dots (NV) and nuclear quantum dots are produced simultaneously in the material of the substrate (D) or epitaxial layer (DEP1). It is necessary that the concentration of nuclear quantum dots (CI) in the vicinity of a quantum dot (NV) is not too high and that the distances of these nuclear quantum dots (CI) in the vicinity of a quantum dot (NV), which can couple with the quantum dot (NV), to the quantum dot (NV) in question are different, in order to lead to a different coupling strength between the respective quantum dot (NV) and the respective nuclear quantum dot (CI) and thus to different resonance frequencies for the coupling of the pairs of a nuclear quantum dot (CI) and a quantum dot (NV).

In the case of diamond as the material of the substrate (D) or the epitaxial layer (DEP1), however, a deterministic single-ion implantation of predetermined isotopes is now preferably carried out to produce the nuclear quantum dots (CI) in the diamond substrate (D) or the epitaxial diamond layer (DEP1), for example 15N isotopes with a nucleus magnetic moment, to produce paramagnetic centers as quantum dots (NV) and to produce nuclear quantum dots (CI) in predetermined regions of the substrate (D) or of the epitaxial layer (DEP1). Preferably, these predetermined regions of the substrate (D) or epitaxial layer (DEP1) have essentially no isotopes with nucleus magnetic moment μ in their material except for already fabricated nuclear quantum dots (CI). Preferably, they comprise essentially only 12C isotopes that have no nucleus magnetic moment. Preferably, they comprise essentially only 28Si isotopes having no nucleus magnetic moment. Preferably, these predetermined regions of the substrate (D) or epitaxial layer (DEP1) essentially comprise only one isotope species without nucleus magnetic moment it, for example 12C isotopes, in their material except for already fabricated nuclear quantum dots (CI). With respect to the interpretation of the term “essentially”, reference is made to the above. Preferably, quantum dots (NV) and nuclear quantum dots (CI) are fabricated simultaneously in the diamond material, for example, by implantation of 15N isotopes. Preferably, the fabrication is performed by single ion implantation of 15N nitrogen or corresponding other nitrogen atoms to produce NV centers as quantum dots (NV), and the nitrogen atoms of the NV centers can serve as nuclear quantum dots (CQUB) in the predetermined regions of the substrate (D) or epitaxial layer (DEP1). In addition, carbon isotopes with nucleus magnetic moment μ, for example 13C carbon isotopes, can also be implanted to create additional nuclear quantum dots (CI) that can couple with the quantum dot (NV), i.e., the NV center. However, portions of carbon isotopes with nucleus magnetic moment μ within the relevant region within the nucleus-electron coupling range of a quantum dot (NV) can also be used as further nuclear quantum dots (CI) by incomplete purification of the isotopic composition of the diamond region. These may be, for example, 13C isotopes having nucleus magnetic moment μ. However, it is necessary that their concentration is not too high and that their distances to the quantum dot (NV) are different in order to lead to a different coupling strength between the nuclear quantum dot, i.e., for example the nucleus of the 13C isotope, and the quantum dot, i.e., for example the NV center, thus to different resonance frequencies.

In the case of silicon as the material of the substrate (D) or the epitaxial layer (DEP1), however, a deterministic single-ion implantation of predetermined isotopes is now preferably carried out to produce the nuclear quantum dots (CI) in the silicon substrate (D) or the epitaxial silicon layer (DEP1), for example 13C isotopes with a nucleus magnetic moment, to produce paramagnetic centers as quantum dots (NV), for example G centers, and to produce nuclear quantum dots (CI) in predetermined regions of the substrate (D) or of the epitaxial layer (DEP1). Preferably, these predetermined regions of the substrate (D) or epitaxial layer (DEP1) have essentially no isotopes with nucleus magnetic moment μ in their material except for already fabricated nuclear quantum dots (CI). Preferably, they comprise essentially only 28Si isotopes that have no nucleus magnetic moment. Preferably, these predetermined regions of the substrate (D) or epitaxial layer (DEP1) essentially comprise only one isotope species without nucleus magnetic moment μ, for example 28Si isotopes, in their material, except for already fabricated nuclear quantum dots (CT). With respect to the interpretation of the term “essentially”, reference is made to the above. Preferably, quantum dots (NV) and nuclear quantum dots (CI) are fabricated simultaneously in the silicon material, for example, by implantation of 13C isotopes. Preferably, the fabrication is done by single ion implantation of 13C carbon or corresponding other carbon atoms to produce G-centers as quantum dots (NV), where the carbon atoms of the G-centers can serve as nuclear quantum dots (CQUB) in the predetermined regions of the substrate (D) or epitaxial layer (DEP1). In addition, silicon isotopes with nucleus magnetic moment μ, for example 29Si silicon isotopes, can also be implanted to create additional nuclear quantum dots (CI) that can couple with the quantum dot (NV), i.e., the G center. However, portions of silicon isotopes with nucleus magnetic moment μ within the relevant region within the nucleus-electron coupling range of a quantum dot (NV) can also be used as additional nuclear quantum dots (CI) by incomplete purification of the isotopic composition of the silicon region. These may be, for example, 29Si isotopes having nucleus magnetic moment μ. However, it is necessary that their concentration is not too high and that their distances to the quantum dot (NV) are different in order to lead to a different coupling strength between the nuclear quantum dot, i.e., for example the nucleus of the 29Si isotope, and the quantum dot, i.e., for example the G center, thus to different resonance frequencies.

In the case of silicon carbide as the material of the substrate (D) or the epitaxial layer (DEP1), however, a deterministic single ion implantation of predetermined isotopes is now preferably carried out for the production of the nuclear quantum dots (CI) in the silicon carbide substrate (D) or the epitaxial silicon carbide layer (DEP1), for example 28Si isotopes without magnetic nucleus moment or 29Si isotopes with magnetic nucleus moment, for the production of paramagnetic centers as quantum dots (NV), for example VSi centers, and in the case of implantation of isotopes with magnetic nucleus moment for the simultaneous production of nuclear quantum dots (CI) in predetermined regions of the substrate (D) or of the epitaxial layer (DEP1). For silicon carbide, the fabrication of VSi centers has also been reported by electron irradiation. Refer to the paper Junfeng Wang, Xiaoming Zhang, Yu Zhou, Ke Li, Ziyu Wang, Phani Peddibhotla, Fucai Liu, Sven Bauerdick, Axel Rudzinski, Zheng Liu, Weibo Gao, “Scalable fabrication of single silicon vacancy defect arrays in silicon carbide using focused ion beam” ACS Photonics, 2017, 4 (5), pp 1054-1059, DOI: 10.1021/acsphotonics.7b00230, arXiv:1703.04479 [quant-ph] is referred to in this context. Preferably, the predetermined regions of the substrate (D) or epitaxial layer (DEP1) in which the fabrication of the quantum dots (NV) or nuclear quantum dots (CI) takes place have essentially no isotopes with nucleus magnetic moment μ in their material, except for already fabricated nuclear quantum dots (CI). Preferably, they comprise essentially only 28Si isotopes and 12C isotopes, neither of which has a nucleus magnetic moment. Thus, the silicon carbide is preferably 28Si12C. Preferably, these predetermined regions of the substrate (D) or epitaxial layer (DEP1) have essentially only one isotope species without nucleus magnetic moment μ, for example 28Si isotopes and for example 12C isotopes, in their material except for already fabricated nuclear quantum dots (CI). Regarding the interpretation of the term “essentially”, reference is made to the above. Preferably, quantum dots (NV) and nuclear quantum dots (CI) are fabricated simultaneously in the silicon carbide material, for example, by implanting 29Si isotopes with nucleus magnetic moment in the form of VSi centers preferably in a 28Si12C silicon carbide region. Preferably, the fabrication is performed by single ion implantation of 29Si silicon atoms or corresponding other silicon atoms to produce VSi centers as quantum dots (NV), where the silicon atoms of the VSi centers can serve as nuclear quantum dots (CQUB) in the predetermined regions of the substrate (D) or epitaxial layer (DEP1). In addition, silicon isotopes with nucleus magnetic moment μ, for example 29Si silicon isotopes, and/or also carbon isotopes with nucleus magnetic moment μ, for example 13C carbon isotopes, can also be implanted to create additional nuclear quantum dots (CI) that can couple with the quantum dot (NV), i.e., the VSi center. However, remaining portions of silicon isotopes with nucleus magnetic moment μ and/or remaining portions of carbon isotopes with nucleus magnetic moment μ within the relevant region within the nucleus-electron coupling range of a quantum dot (NV) can also be used as further nuclear quantum dots (CI) by incomplete purification of the isotopic composition of the silicon carbide region. These may be, for example, 29Si isotopes having nucleus magnetic moment μ and/or, for example, 13C isotopes having a nucleus magnetic moment μ. However, it is necessary that their concentration is not too high and that their distances to the quantum dot (NV) are different in order to lead to a different coupling strength between the nuclear quantum dot, i.e., for example the nucleus of the 29Si isotope or the 13C isotope, and the quantum dot, i.e., for example the VSi center, thus to different resonance frequencies.

For the sake of completeness, it should be mentioned here that by n-doping prior to implantations, when creating paramagnetic centers that have a defect, it has proven effective to negatively charge the defects already in the formation phase during implantation by increasing the electron density by raising the Fermi level. This leads to a change in the diffusion process for the defects. While uncharged defects in the crystal of the substrate (D) or within the epitaxial layer (DEP1) tend to agglomerate and thus massively reduce the yield of paramagnetic centers and thus of quantum dots (NV), sometimes to the point of non-usability, n-doping leads to a negative charge of the defects and thus to repulsion of the defects from each other. This reduces the probability of agglomeration and increases the yield to a technically useful range of values.

For the sake of completeness, it should be mentioned here that instead of silicon carbide (e.g., 28Si12C) in various modifications, other mixed crystals of elements of the fourth main group together with the paramagnetic centers to be assigned to these mixed crystals of the fourth main group can also be considered for the processes and devices disclosed in this paper. All of these mixed crystals generally have a smaller band gap than diamond. Examples would include germanium silicide (GeSi), tin silicide (SnSi), germanium carbide (GeC), tin carbide (SnC). Even more complex ternary and quaternary mixed crystals are conceivable, but are not discussed here due to space limitations. Preferably, these crystals are also made essentially of isotopes without nucleus magnetic moment, at least in the regions of the quantum dots and/or nuclear quantum dots of these crystals. Reference is made here by analogy to the isotope lists above and the explanations of the term “essentially”.

Preferably, after the fabrication of the quantum dots (NV) and/or the fabrication of the nuclear quantum dots (CI), a cleaning and temperature treatment and the measurement of the function, position and T2 times of the implanted single atoms take place again and, if necessary, a repetition of the two preceding steps in case of failure.

As before, ohmic contacts are made to the substrate (D) or to the epitaxial layer (DEP1), the horizontal lines (LH1, LH2, LH3) and, if necessary, the horizontal shielding lines (SH1, SH2, SH3, SH4) are made, at least one or more insulations (IS) are deposited and the vias are opened of the horizontal shield lines (SH1, SH2, SH3, SH4), the deposition of at least one or more insulations (IS) and the opening of the vias as well as the fabrication of the vertical lines (LV1, LV2, LV3) and, if necessary, the vertical shield lines (SV1, SV2, SV3, SV4). As before, there are basically two methods for making contacts to the substrate (D) and/or the epitaxial layer (DEP1): First, the substrate (D) and/or the epitaxial layer (DEP1) can be doped with conventional dopants, usually belonging to the III. Main Group or the Vth Main Group, and thus offer the possibility of forming an ohmic contact. However, since these standard dopants have a nucleus magnetic moment in their stable isotopes, a minimum distance of these contacts to the quantum dots (NV) or the nuclear quantum dots (CI) must be maintained, which is larger than the nucleus-nucleus coupling distance between the nucleus magnetic moment of the dopant atom and the nuclear quantum dot (CI) or larger than the nucleus-electron coupling distance between the nucleus magnetic moment of the dopant atom and the quantum dot (NV). Second, the substrate can be doped with isotopes without nucleus magnetic moment μ. For diamond, 32S isotopes are particularly suitable for n-doping. Reference is made again to the above remarks on n-doping of Si and p-doping of Si. For the isolations (IS), isotopes without magnetic nucleus moment are again preferably used if their distance to the quantum dot (NV) is smaller than the nucleus-electron coupling distance between the nucleus of an atom of the isolation (IS) and the quantum dot (NV) or if their distance to the nuclear quantum dot (CI) is smaller than the nucleus-nucleus coupling distance between the nucleus of an atom of the isolation (IS) and the nuclear quantum dot (CI).

Now, we want to give here a general method for making a nucleus-electron quantum register (CEQUREG) and/or a quantum bit (QUB) together with a nuclear quantum bit (CQB) and/or an array of quantum dots (NV) together with an array of nuclear quantum dots (CI) and/or an array of quantum bits (QUB) together with an array of nuclear quantum bits (CQUB). It again comprises providing a substrate (D), in particular a substrate essentially comprising isotopes of the IVth main group, and optionally applying an epitaxial layer (DEP1), optionally already with a doping, preferably an n-doping. If the substrate (D) or the epitaxial layer (DEP1) are not doped, doping, e.g. by means of ion implantation, of at least pans of the substrate (D) or at least pans of the epitaxial layer (DEP1) and cleaning and healing of the radiation damage are again preferably carried out. Now, deterministic single ion implantation of predetermined isotopes, in particular isotopes with/or without nucleus magnetic moment, is preferably performed to produce paramagnetic centers as quantum dots (NV) in predetermined areas of the substrate (D) or epitaxial layer (DEP1). Alternatively, or together with the deterministic single ion implantation described before, a deterministic single ion implantation of predetermined isotopes with magnetic moment of the atomic nucleus can be performed for the fabrication of nuclear quantum dots (CI) in the predetermined regions of the substrate (D) or the epitaxial layer (DEP1). Cleaning and temperature treatment then takes place again. Again, preferably, a measurement of the function, position and T2 times of the implanted single atoms takes place and, if necessary, repetition of the three preceding steps. As before, the process preferably comprises making ohmic contacts to the substrate (D) or to the epitaxial layer (DEP1) and making the horizontal lines (LH1, LH2, LH3) and, if necessary, the horizontal shield lines (SH1, SH2, SH3, SH4), the deposition of an insulation (IS) and opening of the vias and the fabrication of the vertical lines (LV1, LV2, LV3) and, if necessary, the vertical shield lines (SV1, SV2, SV3, SV4). As before, there are basically two methods for making contacts to the substrate (D) and/or the epitaxial layer (DEP1): First, the substrate (D) and/or the epitaxial layer (DEP1) can be doped with conventional dopants, usually belonging to the IIIrd Main Group or the Vth Main Group, and thus offer the possibility of forming an ohmic contact. However, since these standard dopants have a nucleus magnetic moment in their stable isotopes, a minimum distance of these contacts to the quantum dots (NV) or the nuclear quantum dots (CI) must be maintained, which is larger than the nucleus-nucleus coupling distance between the nucleus magnetic moment of the dopant atom and the nuclear quantum dot (CI) or larger than the nucleus-electron coupling distance between the nucleus magnetic moment of the dopant atom and the quantum dot (NV). Second, the substrate can be doped with isotopes without nucleus magnetic moment μ. For diamond, 32S isotopes are particularly suitable for n-doping. Reference is made again to the above remarks on n-doping of Si and p-doping of Si. For the isolations (IS), isotopes without magnetic nucleus moment are again preferably used if their distance to the quantum dot (NV) is smaller than the nucleus-electron coupling distance between the nucleus of an atom of the isolation (IS) and the quantum dot (NV) or if their distance to the nuclear quantum dot (CI) is smaller than the nucleus-nucleus coupling distance between the nucleus of an atom of the isolation (IS) and the nuclear quantum dot (CI).

Now we want to give here a more concrete method for fabricating a nucleus-electron quantum register (CEQUREG) and/or a quantum bit (QUB) together with a nuclear quantum bit (CQB) and/or an way of quantum dots (NV) together with an array of nuclear quantum dots (CI) and/or an array of quantum bits (QUB) together with en array of nuclear quantum bits (CQUB) in diamond. It again comprises providing a substrate (D) in the form of diamond, and optionally depositing an epitaxial layer (DEP1), optionally preferably already with sulfur doping and/or n-doping. If the substrate (D) or the epitaxial layer (DEP1) is not n-doped or sulfur-doped, sulfur implantation and/or other n-doping of at least parts of the substrate (D) or at least parts of the epitaxial layer (DEN) and cleaning and healing of the radiation damage are again preferably performed. Now, a deterministic single ion implantation of predetermined isotopes, in particular, for example, of 14N-nitrogen and/or 15N-nitrogen in diamond, is preferably carried out to produce paramagnetic centers as quantum dots (NV) in predetermined areas of the diamond substrate (D) or the epitaxial diamond layer (DEN), in particular, for example, to produce NV centers as quantum dots (NV) in predetermined areas of a diamond serving as substrate (D). Alternatively or together with the deterministic single ion implantation described above, a deterministic single ion implantation of predetermined isotopes with magnetic moment of the atomic nucleus, in particular of 13C-carbon in diamond, can be carried out to produce nuclear quantum dots (CI) in the predetermined regions of the diamond substrate (D) or epitaxial layer (DEP1), in particular to produce nuclear quantum dots (CQUB) in the predetermined regions of a diamond serving as substrate (D). Cleaning and temperature treatment then takes place again. Again, preferably, a measurement of the function, position and T2 times of the implanted single atoms takes place and, if necessary, repetition of the three preceding steps. As before, the process preferably comprises making ohmic contacts to the substrate (D) or to the epitaxial layer (DEP1) and making the horizontal leads (LH1, LH2, LH3) and, if necessary, the horizontal shield lines (SH1, SH2, SH3, SH4), the deposition of an insulation (IS) and opening of the vias and the fabrication of the vertical lines (LV1, LV2, LV3) and, if necessary, the vertical shield lines (SV1, SV2, SV3, SV4). Reference is made here to the preceding explanations.

Now we want to give here another more concrete method for fabricating a nucleus-electron quantum register (CEQUREG) and/or a quantum bit (QUB) together with a nuclear quantum bit (CQB) and/or an array of quantum dots (NV) together with an array of nuclear quantum dots (CI) and/or an array of quantum bits (QUB) together with an array of nuclear quantum bits (CQUB) in silicon. It again comprises providing a substrate (D) in the form of a silicon crystal, and optionally depositing an epitaxial layer (DEP1), optionally preferably already with n-doping. Reference is made to the above remarks on moping of silicon. If the substrate (D) or the epitaxial layer (DEP1) are not n-doped, doping, in particular preferably n-doping, of at least pans of the substrate (D) or at least pans of the epitaxial layer (DEP1) and cleaning and healing of the radiation damage are again preferably carried out. Now, a deterministic single ion implantation of predetermined isotopes, in particular, for example, of 12C-carbon and/or 13C-carbon in silicon, is preferably carried out to produce paramagnetic centers as quantum dots (NV) in predetermined areas of the diamond substrate (D) or the epitaxial diamond layer (DEP1), in particular, for example, to produce G-centers as quantum dots (NV) in predetermined areas of a silicon crystal serving as substrate (D). Alternatively or together with the deterministic single ion implantation described above, a deterministic single ion implantation of predetermined isotopes with magnetic moment of the atomic nucleus, in particular of 29Si silicon into the silicon crystal, can be used for the fabrication of nuclear quantum dots (CI) in the predetermined regions of the silicon substrate (D) or the epitaxial layer (DEP1), in particular for the production of nuclear quantum dots (CQUB) in the predetermined regions of a silicon crystal serving as substrate (D). Cleaning and temperature treatment then take place again. Again, preferably, a measurement of the function, position and T2 times of the implanted single atoms takes place and, if necessary, repetition of the three preceding steps. As before, the process preferably comprises making ohmic contacts to the substrate (D) or to the epitaxial layer (DEP1) and making the horizontal leads (LH1, LH2, LH3) and possibly of the horizontal shield lines (SH1, SH2, SH3, SH4), the deposition of an insulation (IS) and opening of the vias and the fabrication of the vertical lines (LV1, LV2, LV3) and, if necessary, the vertical shield lines (SV1, SV2, SV3, SV4). As before, there are basically two methods for making contacts to the silicon substrate (D) and/or the epitaxial silicon layer (DEP1): First, the substrate (D) and/or the epitaxial layer (DEP1) can be doped with conventional dopants, usually belonging to the III. Main Group or the Vth Main Group, be highly doped, thus offering the possibility of forming an ohmic contact. However, since these standard dopants have a nucleus magnetic moment in their stable isotopes, a minimum distance of these contacts to the quantum dots (NV) or the nuclear quantum dots (CI) must be maintained, which is larger than the nucleus-nucleus coupling distance between the nucleus magnetic moment of the dopant atom and the nuclear quantum dot (CI) or larger than the nucleus-electron coupling distance between the nucleus magnetic moment of the dopant atom and the quantum dot (NV). Second, the substrate can be doped with isotopes without nucleus magnetic moment μ. For silicon, 32S isotopes are particularly suitable for n-doping. Reference is made again to the above remarks on n-doping of Si and p-doping of Si. For the isolation (IS), isotopes without nucleus magnetic moment are again preferably used if their distance to the quantum dot (NV) is smaller than the nucleus-electron coupling distance between the nucleus of an atom of the isolation (IS) and the quantum dot (NV) or if their distance to the nuclear quantum dot (CI) is smaller than the nucleus-nucleus coupling distance between the nucleus of an atom of the isolation (IS) and the nuclear quantum dot (CI). Preferably, the insulation (Si) is silicon dioxide with isotopes having essentially no nucleus magnetic moment μ. In particular, 28Si16O2 is suitable as insulation (IS).

Quantum Assembler

The operation of a quantum computer requires appropriate microcode programming of the control device (μC). In the preceding sections, various procedures and procedural steps have been presented that are used to manipulate various components of the quantum computer in a predetermined manner. Each of these quantum operations can be symbolized by an operator code.

It is therefore proposed to provide at least the following exemplary microcodes:

| MNEMONIC FOR | | |
|---|---|---|
| QUANTUM OP CODE | MEANING | PARAMETERS FOR QUANTUM OP CODE |
| MFMW | Determination of the common | a)Number of the horizontal line (LH) |
| | Electron-Electron- | b) number of the vertical line (LV) |
| | microwave frequency (fMW) for | c) memory location of the result |
| | a single quantum dot (NV) | d) storage location of the Rabi frequency |
| | e.g. by means of a method | or the Rabi oscillation periodic time |
| | according to the features 298 to 302 | e) if necessary, equal value of the potential |
| | | of the horizontal line (LH) |
| | | f) if necessary, equal value of the potential |
| | | of the vertical line (LV) |
| MFMWE | Determination of the common | a) Number of the first horizontal line (LH1) |
| | electron1-electron2- | b) number of the first vertical line (LV1) |
| | microwave frequency (fMW) | c) Number of the second horizontal Line (LH2) |
| | for the coupling of two | d) number of the second vertical line (LV2) |
| | quantum dots (NV1, NV2) | e) memory location of the result |
| | e.g. by means of a method | f) storage location of the Rabi frequency |
| | according to features 303 to 307 | or of the Rabi oscillation period duration |
| | | g) if necessary, equal value of the potential |
| | | of the first horizontal line (LH1) |
| | | h) if necessary, the equivalent value of |
| | | the potential of the first vertical line (LV1) |
| | | i) if necessary, equal value of the potential |
| | | of the second horizontal line (LH2), if applicable |
| | | j) if necessary, the potential of the second |
| | | of the second vertical line (LV2) |
| MFMWCE | Determination of the | a) Number of the horizontal line (LH) |
| | Nucleus-electron- | b) number of the vertical line (LV) |
| | microwave frequency (f_{MWCE}) | c) memory location of the result |
| | e.g. by means of a method | d) storage location of the Rabi |
| | according to the | frequency or of the Rabi |
| | features 308 to 312 | oscillation period duration |
| | | c) if necessary, equal value of the potential |
| | | of the horizontal line (LH) |
| | | f) if necessary, equal value of the potential |
| | | of the vertical line (LV) |
| MFRWC | Determination of the | a) Number of the first horizontal line (LH1) |
| | nucleus-nucleus | b) Number of the first vertical line (LV1) |
| | radio wave frequency (f_{RWCC}) | a) Number of the second horizontal line (LH2) |
| | e.g. by means of a method | b) number of the second vertical line (LV2) |
| | according to | c) memory location of the result |
| | features 318 to 322 | d) Storage location of the Rabi frequency |
| | | or of the Rabi oscillation period duration |
| | | e) if necessary, the DC value of the potential |
| | | of the first horizontal line (LH1) |
| | | f) if necessary, the equivalent value of |
| | | the potential of the first vertical line (LV1) |
| | | g) if necessary, equal value of the potential |
| | | of the second horizontal line (LH2), if applicable |
| | | h) if necessary, the potential of the second |
| | | of the second vertical line (LV2) |
| MFRWC | Determination of | a) Number of the horizontal line (LH) |
| | electron-nucleus- | b) number of the vertical line (LV) |
| | radio wave frequency (f_{RWEC}) | c) memory location of the result |
| | e.g. by means of a method | d) storage location of the Rabi frequency |
| | according to the | or of the Rabi oscillation period duration |
| | features 313 to 317 | e) if necessary equal value of the potential |
| | | of the horizontal line (LH) |
| | | f) if necessary, equal value of the potential |
| | | of the vertical line (LV) |
| RESQB | Reset the quantum dot (NV) | a) Number of the horizontal line (LH) |
| | e.g., by means of a method | b) number of the vertical line (LV) |
| | according to feature 323 | |
| RESQBR | Reset the quantum dot (NV) | a) Number of the horizontal line (LH) |
| | by relaxation | b) Number of the vertical line (LV) |
| | e.g., by means of a method | |
| | according to feature 324 | |
| RESQRCE | Reset of nucleus-electron | a) Number of the horizontal line (LH) |
| | quantum registers (CEQUREG) | b) number of the vertical line (LV) |
| | e.g., by means of a method | |
| | according to the | |
| | features 325 to 327 | |
| MQBP | Manipulation of a quantum | a) Number of the memory location of the |
| | dot (NV) | frequency to be used |
| | e.g. by means of a method | b) Number of the memory location of the |
| | according to the | Rabi-oscillation period |
| | features 328 to 333 | c) Number of the horizontal line (LH) |
| | | d) number of the vertical line (LV) |
| | | e) pulse length in number of temporal |
| | | pulse lengths of a π/4 pulse of the |
| | | Rabi oscillation. |
| | | f) Polarization of the to be generated |
| | | circularly polarized magnetic field |
| | | g) if necessary, equal value of the potential |
| | | of the horizontal line (LH) |
| | | h) if necessary, the equal value of the |
| | | potential of the vertical line (LV) |
| MCBP | Manipulation of a nuclear | a) Number of the memory location of the |
| | quantum dot (CI) | frequency to be used |
| | e.g. by means of a method | b) Number of the memory location of the |
| | according to the | Rabi oscillation period |
| | features 334 to 338 | c) number of the horizontal line (LH) |
| | | d) number of the vertical line (LV) |
| | | e) pulse length in number of temporal |
| | | pulse lengths of a π/4 pulse of the |
| | | Rabi oscillation. |
| | | f) Polarization of the to be generated |
| | | circularly polarized magnetic field |
| | | g) Pulse length in number of temporal |
| | | pulse lengths of a π/4 pulse of the |
| | | Rabi oscillation. |
| | | h) Polarization of the circularly |
| | | circularly polarized magnetic field |
| | | i) if necessary, equal value of the potential |
| | | of the horizontal line (LH) |
| | | j) if necessary, equal value of the potential |
| | | of the first line (LV) |
| SMQB | Selective manipulation of a | a) Number of the memory location of the |
| | quantum dot (NV) within a | frequency to be used |
| | quantum register (QUREG) | b) Number of the memory location of the |
| | e.g. by means of a | Rabi-oscillation period duration |
| | method according to | c) number of the horizontal line (LH) |
| | the features 339 to 346 | d) Number of the vertical line (LV) |
| | | e) pulse length in number of temporal |
| | | pulse lengths of a π/4 pulse of the |
| | | Rabi oscillation. |
| | | f) Polarization of the |
| | | circularly polarized magnetic field |
| | | g) Equivalent value of the potential |
| | | of the horizontal line (LH) |
| | | h) Equivalent value of the potential |
| | | of the vertical line (LV) |
| | | i) if necessary, equal value of the potential |
| | | of the horizontal lines (LHx), |
| | | which are not the horizontal line (LH) |
| | | j) if necessary, the equivalent of the potential |
| | | of the vertical lines (LVx), |
| | | which are not vertical lines (LV). |
| KQBQB | Coupling of a first quantum | a) Number of the memory location of the |
| | dot (NV1) with a second | frequency to be used |
| | quantum dot (NV2) | b) number of the memory location of the |
| | e.g. by means of a process | Rabi-oscillation period duration |
| | after the features 367 to 385 | c) number of the first horizontal line (LH1) |
| | | d) Number of the first vertical line (LV1) |
| | | e) number of the second horizontal line (LH2) |
| | | f) number of the second vertical line line (LV2) |
| | | g) Pulse length in number of temporal |
| | | pulse lengths of a π/4 pulse of the |
| | | Rabi oscillation. |
| | | h) Polarization of the to be generated |
| | | circularly polarized magnetic field |
| | | i) if necessary, equal value of the potential |
| | | of the horizontal lines (LH1, LH2) |
| | | j) if necessary, equal value of the potential |
| | | of the vertical lines (LV1, LV2)) |
| KQBCB | Coupling of a first quantum | a) Number of the memory location of the |
| | dot (NV) with a nuclear | frequency to be used |
| | quantum dot (CI) | b) number of the memory location of the |
| | e.g. by means of a process | Rabi-oscillation period duration |
| | according to the | c) number of the horizontal line (LH) |
| | features 386 to 390 | d) Number of the vertical line (LV) |
| | | g) pulse length in number of temporal |
| | | pulse lengths of a π/4 pulse of the |
| | | Rabi oscillation |
| | | h) Polarization of the to be generated |
| | | circularly polarized magnetic field |
| | | i) if necessary, equal value of the potential |
| | | of the horizontal line (LH) |
| | | j) if necessary, the equivalent value of the |
| | | potential of the vertical line (LV) |
| CNQBCBACNOT | Linkage of a first quantum | a) Number of the memory location of the |
| | dot (NV) with a nuclear | frequency to be used |
| | quantum dot (CI) | b) number of the memory location of the |
| | e.g. by means of a process | Rabi-oscillation period duration |
| | according to the | c) number of the horizontal line (LH) |
| | features 386 to 390 | d) Number of the vertical line (LV) |
| | | g) pulse length in number of temporal |
| | | pulse lengths of a π/4 pulse of the |
| | | Rabi oscillation. |
| | | h) Polarization of the to be generated |
| | | circularly polarized magnetic field |
| | | i) if necessary, equal value of the potential |
| | | of the horizontal line (LH) |
| | | j) if necessary, the equivalent value of the |
| | | potential of the vertical line (LV) |
| CNQBCBBCNOT | Linkage of a first quantum | a) Number of the memory location of the |
| | dot (NV) with a nuclear | frequency to be used |
| | quantum dot (CI) | b) number of the memory location of the |
| | e.g. by means of a process | Rabi-oscillation period duration |
| | according to the | c) number of the horizontal line (LH) |
| | features 391 to 395 | d) Number of the vertical line (LV) |
| | | g) pulse length in number of temporal |
| | | pulse lengths of a π/4 pulse of the |
| | | Rabi oscillation. |
| | | h) Polarization of the to be generated |
| | | circularly polarized magnetic field |
| | | i) if necessary, equal value of the potential |
| | | of the horizontal line (LH) |
| | | j) if necessary, the equivalent value |
| | | of the potential of the vertical line (LV) |
| CNQBCBCCNOT | Linkage of a first quantum | a) Number of the memory location of the |
| | dot (NV) with a nuclear | frequency to be used |
| | quantum dot (CI) | b) number of the memory location of the |
| | e.g. by means of a method | Rabi oscillation period duration |
| | according to the | c) number of the horizontal line (LH) |
| | features 396 to 412 | d) Number of the vertical line (LV) |
| | | g) pulse length in number of temporal |
| | | pulse lengths of a π/4 pulse of the |
| | | Rabi oscillation |
| | | h) Polarization of the to be generated |
| | | circularly polarized magnetic field |
| | | i) if necessary, equal value of the potential |
| | | of the horizontal line (LH) |
| | | j) if necessary, the equivalent value |
| | | of the potential of the vertical line (LV) |
| VQB | Selective evaluation of a | a) Number of the memory location of the |
| | quantum dot (NV) within a | frequency to be used |
| | quantum register (QUREG) | b) Number of the storage location of the |
| | e.g. by means of a method | Rabi-oscillation period duration |
| | according to the | c) number of the horizontal line (LH) |
| | features 418 to 419 | d) number of the vertical line (LV) |
| | | e) pulse length in number of temporal |
| | | pulse lengths of a π/4 pulse of the |
| | | Rabi oscillation |
| | | f) Polarization of the |
| | | circularly polarized magnetic field |
| | | g) Number of the memory location for the |
| | | evaluation result |
| | | h) Equivalent value of the potential |
| | | of the horizontal line (LH) |
| | | i) Equivalent value of the potential |
| | | of the vertical line (LV) |
| | | j) if necessary, the equal value |
| | | of the potential of the horizontal lines (LHx), |
| | | which are not the horizontal line (LH) |
| | | k) if necessary, the equal value |
| | | of the potential of the vertical lines (LVx), |
| | | which are not vertical lines (LV). |
| SCNQB | Selective CNOT operation of a | a) number of the memory location |
| | quantum dot (NV) within a | frequency to be used |
| | quantum register (QUREG) | b) Number of the memory location of the |
| | e.g. by means of a | Rabi-oscillation period duration |
| | method according to | c) number of the horizontal line (LH) |
| | the features 420 to 421 | d) number of the vertical line (LV) |
| | | e) pulse length in number of temporal |
| | | pulse lengths of a π/4 pulse of the |
| | | Rabi oscillation |
| | | f) Polarization of the to be generated |
| | | circularly polarized magnetic field |
| | | g) Equivalent value of the potential |
| | | of the horizontal line (LH) |
| | | h) Equivalent value of the potential |
| | | of the vertical line (LV) |
| | | i) if necessary, equal value of the potential |
| | | of the horizontal lines (LHx), |
| | | which are not the horizontal line (LH) |
| | | j) if necessary, the equivalent of the potential |
| | | of the vertical lines (LVx), |
| | | which are not vertical lines (LV). |

The procedures according to features 422 to 424 can be composed of the above operations. It is conceivable to provide further operations by possible variants. Furthermore, it makes sense to allow the usual assembler instructions like jumps, branches, conditional jumps, program counter manipulations, move operations, add operations, shift operations (left and right), inversion, bit manipulations, call of subroutines, stack operations, stack pointer operations etc. further.

It is also useful to hard code certain frequently used sequences of MNEMONICs as well and provide separate mnemonics for them.

The corresponding signal sequences are preferably stored in a preferably nonvolatile program memory of the control device (μC).

The memory of the control device (μC) then preferably comprises a table of the resonance frequencies of the quantum dots and the nuclear quantum dots and their couplings and the relevant horizontal and vertical lines to be actuated, as well as the associated Rabi frequencies and the potentials to be applied to the horizontal and vertical lines, if any, or the DC currents to be injected, if any, to detune the resonance frequencies. These data allow the control device (μC) to selectively and specifically address and manipulate the quantum dots, the nuclear quantum dots, the pairs of two and possibly mote quantum dots, the pairs of quantum dot and nuclear quantum dot and possibly the more complex structures.

A program, a Q-assembler, translates a control code in human readable text form in to binary code sequences, which are executed by the control device (μC) on demand, whereby the control device (μC) can then selectively and specifically address and manipulate the quantum information of the quantum dots, the nuclear quantum dots, the pairs of two and possibly more quantum dots, the pairs of quantum dot and nuclear quantum dot and possibly the more complex structures. With the help of this quantum assembler language, it is then possible to develop more complex programs for the quantum computer to operate the devices and to provide a simple interface for software development. The control device (μC) executes the microcode. Microcode in the sense of the proposed project is the connection between a given binary code—the quantum assembler code—received by the control device (μC) from an external supervisory computer (ZSE) via the data bus (DB) on one side, and the concrete sequence of signals and the corresponding waveforms for the control lines, the laser and for the readout circuits. In this sense, the control unit function of the control device μC) is comparable to the microcode programming of a conventional processor. The control device (μC) preferably has the quantum computer program stored in its memory. The quantum computer program consists of sequences of quantum assembler code in binary form located in a memory of the control device (μC). The control device (μC) executes the binary quantum assembler code stored in a memory of the control device (μC) and generates the signals on the vertical lines and horizontal lines with the help of further means (CBA, HD1, HD2, HD3, VD1, VSI, HS1, HS2, HS3, LEDDR, LED, CBB) (see also FIG. 23) depending on these preferentially binary codes. This enables the development of quantum computer software on the hardware disclosed here.

### Quantum Computer System

An external monitoring computer can address a plurality of preferably identically constructed quantum computers via a conventional data bus. The external conventional monitoring computer then forms a quantum computer system with the plurality of quantum computers. Preferably, the quantum computers of the quantum computer system are constructed as described herein. The structure of the quantum computers described herein has the advantage of being very compact and very inexpensive. For example, the quantum computers of the quantum computer system can be operated at room temperature when diamond is used as the material of the substrates (D) or epitaxial layers (DEP1) and NV centers are used as quantum dots (NV). Preferably, a very large number of quantum computers are used for a quantum computing system. Preferably, all quantum computers have the same structure. For example, they may be constructed like the quantum computer of FIG. 23. Preferably, all quantum computers of the quantum computer system perform the same operations at the same time. Since the realizations of the nuclear quantum dots and the quantum dots in detail differ among the quantum computers, minor differences may exist. Importantly, quantum computers behave in a functionally equivalent manner. Nevertheless, not all quantum computers will arrive at the same results when performing quantum operations, since quantum computers only compute certain results with a certain probability. Here, the large number of quantum computers (see also FIG. 38) in the quantum computer system (QUSYS) can be exploited. Since all quantum computers work in parallel in the same way, the quantum computers will most often calculate the correct results. The external monitoring computer, in FIG. 38 the central control equipment (CSE), of the quantum computer system (QUSYS) queries the results of a longer sequence of quantum operations performed in the same way by all quantum computers to all quantum computers concerned via the data line. The external monitoring computer, in FIG. 38 the central control equipment (ZSE), evaluates all results according to frequency of calculation by the quantum computers of the quantum computer system (QUSYS). Using a statistical method, the external monitoring computer of the quantum computer system (QUSYSS) calculates the most probable result from the results of the quantum computers and selects this as a valid intermediate result. Then the external supervising computer, in FIG. 38 the central control unit (CSE), of the quantum computer system (QUSYS) transmits this valid intermediate result to all quantum computers and causes them to first reset their respective quantum bus with the quantum ALUs and then to adjust the Bloch vectors so that they correspond to the intermediate result. After that, the quantum computers then perform the next longer sequence of quantum operations until again a second intermediate result is obtained and then the next error correction loop is performed by the external monitoring computer, in FIG. 38 the central control equipment (CSE), of the quantum computer system (QUSYS).

Such a quantum computer system (QUSYS) is thus characterized by the fact that it comprises a conventional external supervisory computer, in FIG. 38 the central control equipment (CSE), of the quantum computer system (QUSYS), which communicates with the quantum computers (in FIG. 38 QUA1 to QUA16) of the quantum computer system (QUSYS) via one or more preferably conventional data buses (DB). The data buses can be conventional data transmission links of any kind. Preferably, the number of quantum computers in the quantum computer system (QUSYS) is greater than 5, better than 10, better than 20, better than 50, better than 100, better than 200, better than 500, better than 100, better than 200, better than 500, better than 1000, better than 2000, better than 5000, better than 10000, better than 20000, better than 50000, better than 100000, better than 200000, better than 50000, better than 1000000. Here, the more quantum computers that are part of the quantum computer system (QUSYS), the better the error correction resolution. Preferably, each quantum computer (QUC1 to QUC16) comprises a control device (μC), each of which communicates with the external monitoring computer, in FIG. 38 the central control device (ZSE), of the quantum computer system (QUSYS) via the one data bus (DB) or the several, preferably conventional data buses (DB). Preferably, each quantum computer comprises the of the quantum computers (QUC1 to QUC16) means suitable to manipulate and possibly control the states of its quantum dots (NV) and/or its nuclear quantum dots and/or the pairs of quantum dots and/or the pairs of quantum dots and nuclear quantum dots. Furthermore, the quantum computers of these quantum computers (QUC1 to QUC16) each preferably have means (LED, LEDDRV) for generating excitation radiation in the form of “green light”. If necessary, this generation of “green light” can also be performed centrally for one or more or all quantum computers of the quantum computer system (QUSYS). In the latter case, the associated light source (LED) is then controlled by the external monitoring computer of the quantum computer system (QUSYS), in deviation from FIG. 23. In FIG. 38, the external monitoring computer of the quantum computer system (QUSYS) corresponds to the central control unit (CSE).

In order for the quantum computer (QUC) to be able to execute the instructions, the quantum computer (QUC) preferably comprises said control device (μC). Thereby, the control device (μC) should be suitable and arranged to receive, for example, commands and/or codes and/or code sequences via said data bus (DB). The control device (μC) then preferably executes, depending on these received commands and/or received codes and/or received code sequences, at least one of the following quantum operations by the quantum computer (QUC): MFMW, MFMWEE, MFMWCE, MFRWCC, FRWCC, RESQB, RESQBR, RESQRCE, MQBP, MCBP, SMQB, KQBQB, KQBCB, CNQBCBA, CNQBCBB, CNQBCBC, VQB, SCNQB. For this purpose, said control device (μC) generates and modulates the appropriate control signals on the m vertical lines (LV, LV1 to LVm) (where m is an integer positive number), then horizontal lines (LH, LH1 to LHn) (where n is an integer positive number) and the associated shield lines, and for controlling the one light source (LED) or the multiple light sources (LED), depending on the received command. In addition, the control device (μC) detects the photocurrents (Iph), if necessary, and controls the extraction voltage (Vₑₓ₁), if necessary.

This results in a suitable method for operating a quantum computer as presented here:

In a first step, a first file, hereinafter referred to as source code, is provided. Preferably, the source code consists of symbols arranged in an ordered sequence in the source code. In this context, predetermined character strings are assigned to the basic operations that the control device (μC) can perform and which are called quantum assembler instructions in the following. Preferably, these quantum assembler instructions include at least some, preferably all, of the quantum operations of the quantum computer (QUC) already mentioned. i.e., in particular the quantum operations MFMW, MFMWEE, MFMWCE, MFRWCC, FRWCC, RESQB, RESQBR, RESQRCE, MQBP, MCBP, SMQB, KQBQB, KQBCB, CNQBCBA, CNQBCBB, CNQBCBC, VQB, SCNQB. Preferably, however, the quantum assembler instructions also include such assembler instructions as are known from conventional computers.

Such quantum assembler instructions can be, for example, those of a 6502 processor, which can be easily implemented in an FPGA:

| TYPE, | MNEMONIC, | COMMAND, | MEANING |
|---|---|---|---|
| Load commands | LDA | LoaD Accumulator | Load Accumulator |
| Load commands | LDX | LoaD X register | Load X register |
| Load commands | LDY | LoaD Y register | Load Y register |
| Store commands | STA | STore Accumulator | Store Accumulator |
| Store commands | STX | STore X register | Store X register |
| Store commands | STY | STore Y register | Store Y register |
| Transfer Commands | TAX | Transfer Accumulator | Copy Accumulator to X |
| | | to X | |
| Transfer commands | TAY | Transfer Accumulator | Copy accumulator to Y |
| | | to Y | |
| Transfer commands | TXA | Transfer X | Copy X to Accumulator |
| | | to Accumulator | |
| Transfer commands | TYA | Transfer Y | Copy Y to Accumulator |
| | | to Accumulator | |
| Transfer Commands | TSX | Transfer Stack pointer | Copy stack pointer to X |
| | | to X | |
| Transfer commands | TXS | Transfer X | Copy X to stack pointer |
| | | to Stack pointer | |
| Logical operations | AND | AND | Logical “And”. |
| Logical operations | ORA | OR Accumulator | Logical “Or”. |
| Logical operations | EOR | Exclusive OR | Logical “Either/Or” (XOR) |
| Arithmetic Operations | ADC | ADd with Carry | Add with Carry |
| Arithmetic Operations | SBC | SuBtract with Carry | Subtract with Carry |
| Arithmetic Operations | INC | INCrement | Increment memory cell |
| Arithmetic Operations | DEC | DECrement | decrement memory cell |
| Arithmetic Operations | INX | INcrement X | Increment X registers |
| Arithmetic Operations | INY | INcrement Y | Increment Y Registers |
| Arithmetic Operations | DEX | DEcrement X | Decrement X Registers |
| Arithmetic Operations | DEY | DEcrement Y | DEerement Y Registers |
| Bitwise shift | ASL | Arithmetical Shift Left | Bitwise shift left |
| Bitwise shift | LSR | Logical Shift Right | Bitwise shift to the right |
| Bitwise shift | ROL | ROtate Left | Bitwise rotation to the left |
| Bitwise shift | ROR | ROtate Right | Bitwise rotation to the right ROR |
| Comparison operations | CMP | CoMPare | Comparisons with accumulator |
| Compare operations | CPX | ComPare X | Compare with X |
| Comparison operations | CPY | ComPare Y | Comparisons with Y |
| Comparison operations | BIT | BIT test | BIT test with accumulator |
| Jump commands | JMP | JuMP | Unconditional jump |
| (unconditional) | | | |
| Jump commands | JSR | Jump to Sub-Routine | subroutine call |
| (unconditional) | | | |
| Jump commands | RTS | ReTurn from Subroutine | Return from Subroutine |
| (unconditional) | | | |
| Jump commands | RTI | ReTurn from Interrupt | Return from Interrupt |
| (unconditionally) | | | |
| Jump commands | BCC | Branch on Carry Clear | branches when carry flag is cleared |
| (conditional) | | | |
| Jump commands | BCS | Branch on Carry Set | Branches with Carry flag set |
| (conditional) | | | |
| Jump commands | BEQ | Branch on EQual | Branches with zero flag set |
| (conditional) | | | |
| Jump commands | BNE | Branch on Not Equal | Branches with deleted zero flag |
| (conditional) | | | |
| Jump commands | BPL | Branch on PLus | Branches with cleared negative flag |
| (conditional) | | | |
| Jump commands | BMI | Branch on MInus | Branches when negative flag is set. |
| (conditional) | | | |
| Jump commands | BVC | Branch on Overflow | branches with cleared overflow flag |
| (conditional) | | Clear | |
| Jump commands | BVS | Branch on Overflow | branches with set overflow flag |
| (conditional) | | Set | |
| Flag command | SEC | SEt Carry | Set Carry flag |
| Flag Command | CLC | CLear Carry | Clear Carry Flag |
| Flag command | SEI | SEt Interrupt | Set interrupt flag |
| Flag Command | CLI | CLear Interrupt | Clear Interrupt Flag |
| Flag command | CLV | CLear oVerflow | Clear overflow flag |
| Flag command | SED | SEt Decimal | Set Decimal flag |
| Flag command | CLD | CLear Decimal | Clear Decimal flag |
| Stack commands | PHA | PusH Accumulator | Put accumulator contents on stack |
| Stack commands | PLA | PuLl Accumulator | Get accumulator value from stack |
| Stack commands | PHP | PusH Processor status | Set status register on stack |
| Stack instructions | PLP | PuLl Processor status | Get status register from stack |
| Special commands | NOP | No OPeration | No operation |
| Special commands | BRK | BReaK | Software interrupt |

However, this list is only an example of possible quantum assembler commands. Each mnemonic is assigned a specific, unique value, referred to in the following as OP code, which codes the relevant operation for the control device (μC). Also, each quantum operation, in particular the quantum operations corresponding to the mnemonics MFMW, MFMWEE, MFMWCE, MFRWCC, FRWCC, RESQB, RESQBR, RESQRCE, MQBP, MCBP, SMQB, KQBQB, KQBCB, CNQBCBA, CNQBCBB, CNQBCBC, VQB, SCNQB, are typically assigned such specific, unique value. i.e., OP codes and specifically quantum OP codes in this case. If the control device (μC) finds such a predetermined value when executing the program, the control device performs the relevant operation according to the OP code. If the found value encodes a quantum operation by means of a quantum OP code, the control device (μC) executes the quantum operation assigned to this quantum OP code, the mnemonic of which is assigned to the quantum OP code concerned.

In addition to the mnemonics of the possible operations and quantum operations, the source code also includes data in the form of symbol strings. In a second step, a data processor translates the source code in to a second file, called binary file in the following. The binary file comprises an ordered sequence of values. Some of these values thereby preferably correspond to OP codes and quantum OP codes of the respective mnemonics of the source code. In addition, the binary file may include data that were encoded as strings in the source code. If applicable, the source code also comprises control commands for controlling the execution of this second step by the data processing system.

By means of a data link, typically comprising the data bus (DB) of the quantum computer (QUC), and/or a data carrier, the binary file is transferred to a memory of the control device (μC) in a third step.

In a fourth step, the control device (μC) is caused to start executing the OP codes and quantum OP codes at a predetermined location in the memory. In this process, the OP codes and quantum OP codes may be assigned data on which the execution of the OP codes and/or quantum OP codes depends. In the case of quantum OP codes, such data associated with a quantum OP code may be, for example, the quantum OP code parameters mentioned above.

In a fifth step, OP code for OP code is then executed until a stop command is found, if provided. The OP codes may also be quantum OP codes.

### Sensor System

The proposed device and the methods proposed herein can also be used as a sensor system. Preferably, the magnetic field, i.e., the measurable value of the magnetic flux density B and/or the value of the magnetic field strength H, is then no longer stabilized. The interaction with the environment is then detected by the control device (MC) by means of the quantum dots, evaluated and passed on via the data bus (DB). Sensor systems are therefore also explicitly covered by the claims.

In such a sensor system, the value of the intensity of the fluorescence radiation of a quantum dot (NV) and/or the value of the photocurrent generated by a quantum dot (NV) upon irradiation with “green light”, i.e., the excitation radiation suitable for the quantum dot (NV) in question, is detected and output as a measured value. Here, it is exploited that the value of the intensity of the fluorescence radiation of a quantum dot (NV) and/or the value of the photocurrent generated by a quantum dot (NV) upon irradiation with “green light”, i.e., the excitation radiation suitable for the quantum dot (NV) in question, usually depends on external physical parameters. This external physical parameter may be, for example, the magnetic flux density B at the location of the paramagnetic center of the quantum dot (NV), or the temperature, or the electric flux density, or the speed of the device comprising the quantum dot (NV), or its acceleration, or the gravitational field strength, or the rotational speed, or the rotational acceleration. The value acquired in this way can then, after any post-processing by an evaluation device (μC), be output as a measured value for the current value of the external physical parameter concerned, if necessary.

### BRIEF DESCRIPTION OF THE DRAWINGS

FIG. 1 shows a quantum bit (QUB).

FIG. 2 shows a nuclear quantum bit (CQUB).

FIG. 3 shows a quantum register (QUREG).

FIG. 4 shows a nucleus-nuclear quantum register (CCQUREG).

FIG. 5 shows a nucleus-electron quantum register (CEQUREG).

FIG. 6 shows a nucleus-electron-nucleus-electron quantum register (CECEQUREG).

FIG. 7 shows a quantum register (QUREG) with a second vertical shield line (SV2)

FIG. 8 shows a quantum register (QUREG) with a second vertical shield line (SV2) and with a first vertical shield line (SV1) with a third vertical shield line (SV3).

FIG. 9 shows a quantum bit (QUB) with contacts (KHa, KHb, KVa) for electrical readout of the photoelectrons and a symbolic representation of the quantum bit (QUB).

FIG. 10 shows the symbolic representation of a one-dimensional quantum register (QREG1D) with three quantum bits (QUB1, QUB2, QUB3).

FIG. 11 shows the symbolic representation of a one-dimensional nuclear quantum register (CCQREG1D) with three nuclear quantum bits (CQUB1, CQUB2, CQUB3).

FIG. 12 shows the symbolic representation of a two-dimensional quantum register (QREG2D) with nine quantum dots (NV11 to NV33).

FIG. 13 shows the symbolic representation of a two-dimensional nuclear quantum register (CCQREG2D) with nine nuclear quantum dots (CI11 to CI33).

FIG. 14 shows an exemplary time amplitude curve of the horizontal current component of the horizontal current (IH) and the vertical current component of the vertical current (IV) with a phase shift of +/−π/2 for generating a circularly polarized electromagnetic field at the location of the quantum dot (NV) and the nuclear quantum dot (CI), respectively.

FIG. 15 illustrates an optimal current flow using the example of a quantum bit (QUB) with a first vertical shield line (SV1) and a second vertical shield line (SV2).

FIG. 16 illustrates an optimal current flow using the example of a quantum bit (QUB) with a first horizontal shield line (SH1) and a second horizontal shield line (SH2).

FIG. 17 shows the symbolic representation of a three-bit quantum register or nuclear quantum register with shield lines and a common first vertical drive line (IV1).

FIG. 18 shows the symbolic representation of a two-dimensional three-x-three-bit quantum register or nuclear quantum register with shield lines and contacts for reading out the photoelectrons.

FIG. 19 shows an exemplary two-bit quantum register (QUREG) with a common first horizontal line (LH1), several shield lines and two quantum dots (NV1, NV2).

FIG. 20 shows an exemplary two-bit nucleus-electron-nucleus-electron quantum register (CECEQUREG) with a common first horizontal line (LH1), multiple shield lines, and two quantum ALUs (QUALU1, QUALU2).

FIG. 21 is used to explain the quantum bus operation.

FIG. 22 shows an example of the arrangement for an exemplary five-bit quantum register in a highly simplified form in plain view.

FIG. 23 shows the block diagram of an exemplary quantum computer with an exemplary schematically indicated three-bit quantum register, which could possibly also be replaced, for example, by a three-bit nucleus-electron-nucleus-electron quantum register (CECEQUREG) with three quantum ALUs.

FIG. 24 shows an exemplary symbolic horizontal arrangement of a nucleus-electron-nucleus-electron quantum register (CECEQUREG) with two quantum ALUs (QUALU1, QUALU2).

FIG. 25 shows an exemplary symbolic horizontal arrangement of a nucleus-electron-nucleus-electron quantum register (CECEQUREG) with four quantum ALUs (QUALU1, QUALU2, QUALU3, QUALU4).

FIG. 26 shows an exemplary symbolic horizontal arrangement of a nucleus-electron-nucleus-electron quantum register (CECEQUREG) with four quantum ALUs (QUALU11, QUALU12, QUALU13, QUALU23) across corners.

FIG. 27 shows an exemplary symbolic horizontal arrangement of a nucleus-electron-nucleus-electron quantum register (CECEQUREG) with five quantum ALUs (QUALU11, QUALU12, QUALU13, QUALU14, QUALU23) as branching.

FIG. 28 shows an example symbolic horizontal arrangement of a nucleus-electron-nucleus-electron quantum register (CECEQUREG) with eight quantum ALUs (QUALU11, QUALU12, QUALU13, QUALU21, QUALU23, QUALU31, QUALU32, QUALU33,) as a ring.

FIG. 29 shows a device that can be placed inside a substrate (D) or inside an epitaxial layer (DEP1) and thus can be used in the preceding devices and in which in the material of the substrate (D) or of the epitaxial layer (DEP1) is fabricated a radiation source (PL1) that is used as a light source (LED) for the “green light”.

FIG. 30 shows a simplified device of FIG. 1 with a substrate (D) which is preferably diamond in the case of NV centers as paramagnetic centers (NV1) and preferably silicon in the case of G centers and preferably silicon carbide in the case of V_{Si} centers, with one or more paramagnetic centers as quantum dot (NV) resp. quantum dots (NV) in the substrate (D), which interact with a line (LH), which is placed and fixed on the surface (OF) of the substrate (D) and which is preferably electrically insulated from the substrate (D), for example by an insulation (IS), due to a very small first distance (d1) of preferably less than 100 nm with the magnetic field of this line (LH) when an electric current (IH) flows through the line (LH).

FIG. 31 shows the combination of a paramagnetic center as a quantum dot (NV) in a semiconductor material of a semiconducting substrate (D), for example of silicon or silicon carbide, with a MOS transistor in this material, where the horizontal screen lines (SH1, SH2) represent the source and drain contacts, while the first horizontal line (LH1) forms the gate of the MOS transistor and is insulated from the material of the substrate (D) by the gate oxide. The pump radiation (LB) in the form of the “green light” is generated by a center (PZ).

FIG. 32 shows a structure of a substrate (D) with a device for reading the photocurrent (I_{Ph}) of a paramagnetic center as a quantum dot (NV).

FIG. 33 shows a sub-device of FIG. 20 in the form of a quantum ALU, where the sub-device is a transistor.

FIG. 34 shows a simplified top view of the surface of a substrate (D) with, as an example, eight quantum bits (NV1 to NV8), which are arranged and indicated as black circles equally spaced in a vertical line.

FIG. 35 corresponds to FIG. 34 with the difference that no horizontal shield lines are provided.

FIG. 36 shows the substrate of FIG. 35 installed in a control system analogous to FIG. 23.

FIG. 37 shows an exemplary transistor operated as a quantum computer in a simplified schematic view from above.

FIG. 38 shows an exemplary quantum computer system (QUSYS) with an exemplary central control unit (CSE).

### DESCRIPTION

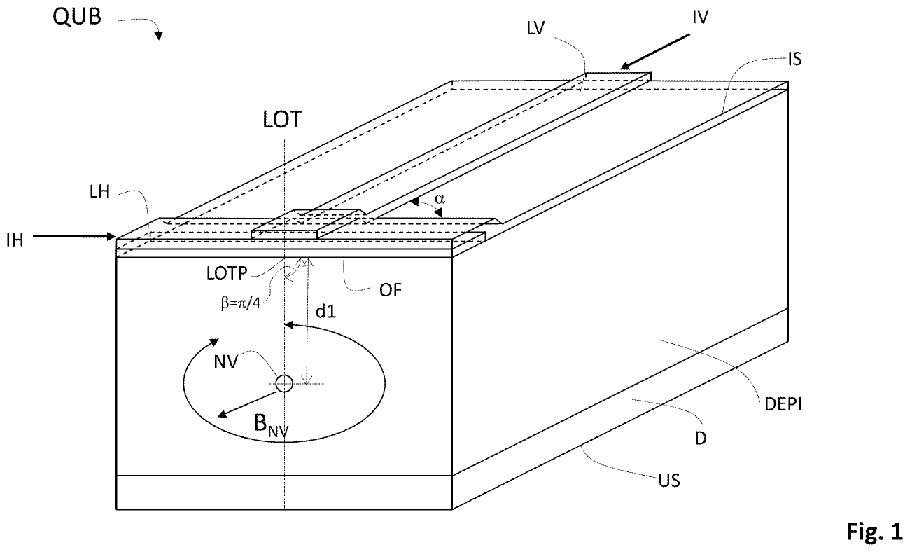

FIG. 1 shows an exemplary quantum bit (QUB). The substrate (D) has an underside (US). Especially preferred is the substrate made of diamond or silicon or silicon carbide or another element of the IV. Main Group of the Periodic Table or a mixed crystal of elements of the IV. Main Group of the Periodic Table. Preferably, the isotopes of the substrate (D) have essentially no nucleus magnetic moment A. An epitaxial layer (DEP1) is deposited on the substrate (D) to improve the electronic properties. Preferably, the substrate (D) and/or the epitaxial layer (DEP1) comprises essentially only isotopes without a nucleus magnetic moment μ. Preferably, the substrate (D) and/or the epitaxial layer (DEP1) comprises essentially only one isotope type of isotope without a nucleus magnetic moment μ. The package of substrate (D) and epitaxial layer (DEP1) has a surface (OF). A horizontal conduction (LH) is deposited on the surface (OF), through which a horizontal electric current (IH) modulated with a horizontal modulation flow. The surface (OF) and the horizontal line (LH) are covered by an insulation (IS). If necessary, there is further insulation between the horizontal line (LH) and the surface (OF) to electrically isolate the horizontal line. A vertical line (LV) is applied on the insulation (IS), through which a vertical electric current (IV) modulated with a vertical modulation flow. The horizontal line (LH) and the vertical line (LV) are preferably electrically insulated from each other. Preferably, the angle α between the horizontal line (LH) and the vertical line (LV) is a right angle. The horizontal line (LH) and the vertical line (LV) cross at the point of passage (LOTP) of a virtual plumb line (LOT) through the surface (OF). Preferably, directly below the crossing point (LOTP), the quantum dot (NV) is located at a first distance (d1) below the surface (OF) in the epitaxial layer (DEP1). For example, in the case of diamond as the material of the epitaxial layer (DEP1), the quantum dot (NV) may be an NV center. In the case of silicon as the material of the epitaxial layer (DEP1), the quantum dot (NV) can be, for example, a G center. In the case of silicon carbide as the epitaxial layer material (DEP1), the quantum dot (NV) can be, for example, a V_{Si} center. If the vertical modulation of the vertical current (IV) is shifted with respect to the horizontal modulation of the horizontal current (IH) by +/−π/2, then a rotating magnetic field (B_{NV}) results at the location of the quantum dot (NV), for example, which influences the quantum dot (NV). This can be used to manipulate the quantum dot (NV). Here, the frequency is chosen so that the quantum dot (NV) resonates with the rotating magnetic field (B_{NV}). The temporal duration of the pulse then determines the rotation angle of the quantum information. The polarization direction determines the direction.

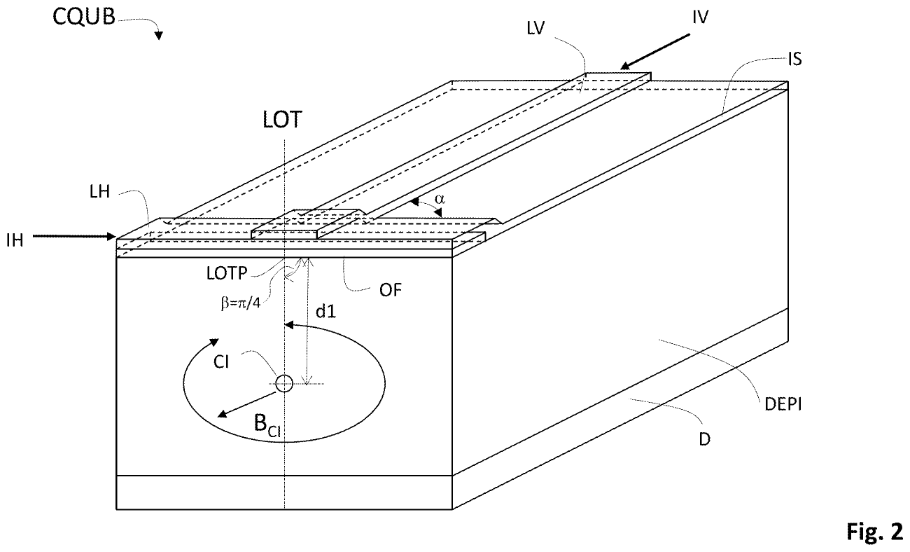

FIG. 2 shows a nuclear quantum bit (CQUB). It corresponds to FIG. 1 with the difference that the quantum dot (NV) of FIG. 1 is replaced by a nuclear quantum dot (CI), which is preferably formed by an isotope with a magnetic nuclear spin. In the case of diamond as the material of the epitaxial layer (DEP1), the nuclear quantum dot (CI) can be, for example, a ¹³C isotope. In the case of silicon as the epitaxial layer material (DEP1), the nuclear quantum dot (CI) may be, for example, a ²⁹Si isotope. In the case of silicon carbide as the epitaxial layer material (DEP1), the nuclear quantum dot (CI) may be, for example, a ²⁹Si isotope or a ¹³C isotope.

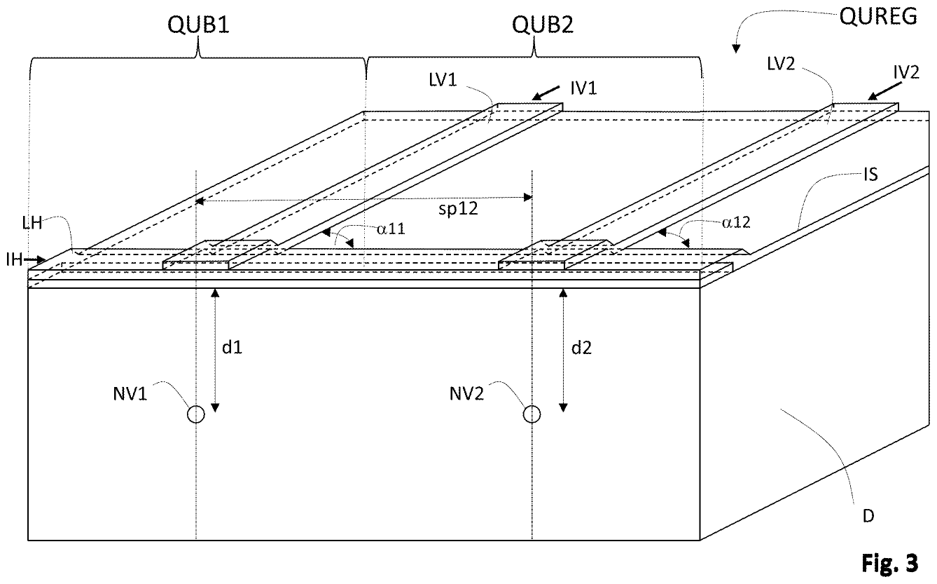

FIG. 3 shows an exemplary quantum register (QUREG) with a first quantum bit (QUB1) and a second quantum bit (QUB2). The quantum bits (QUB1, QUB2) of the quantum register (QUREG) have a common substrate (D) and a common epitaxial layer (DEP1). The horizontal line of the first quantum bit (QUB1) is the horizontal line (LH). The horizontal line of the second quantum bit (QUB2) is also the horizontal line (LH) in this example. The vertical line of the first quantum bit (QUB1) is the first vertical line (LV1). The vertical line of the second quantum bit (QUB2) is the second vertical line (LV2). The horizontal line (LH) and the first vertical line (LV1) preferably cross above the first quantum dot (NV1), which is preferably located at a first distance (d1) below the surface, at a preferably right angle (all). Preferably, the horizontal line (LH) and the second vertical line (LV2) cross above the second quantum dot (NV2), which is preferably at a second distance (d2) below the surface, at a preferably right angle (α12). Preferably, the first distance (d1) and the second distance (d2) are similar to each other. For NV centers in diamond, these distances (d1, d2) are preferably 10 nm to 20 nm. For G centers in silicon, these spacing (d1, d2) are also preferably 10 nm to 20 nm. For VSi centers in silicon carbide, these spacing (d1, d2) are also preferably from 10 nm to 20 nm. The horizontal line (LH) is traversed by a horizontal current (IH) modulated with a horizontal modulation. The first vertical line (LV1) is flowed through by a first vertical current (IV1) modulated with a first vertical modulation. The second vertical line (LV2) is flowed through by a second vertical current (IV2) modulated with a second vertical modulation. The first quantum dot (NV1) is spaced from the second quantum dot (NV2) by a distance (sp12).

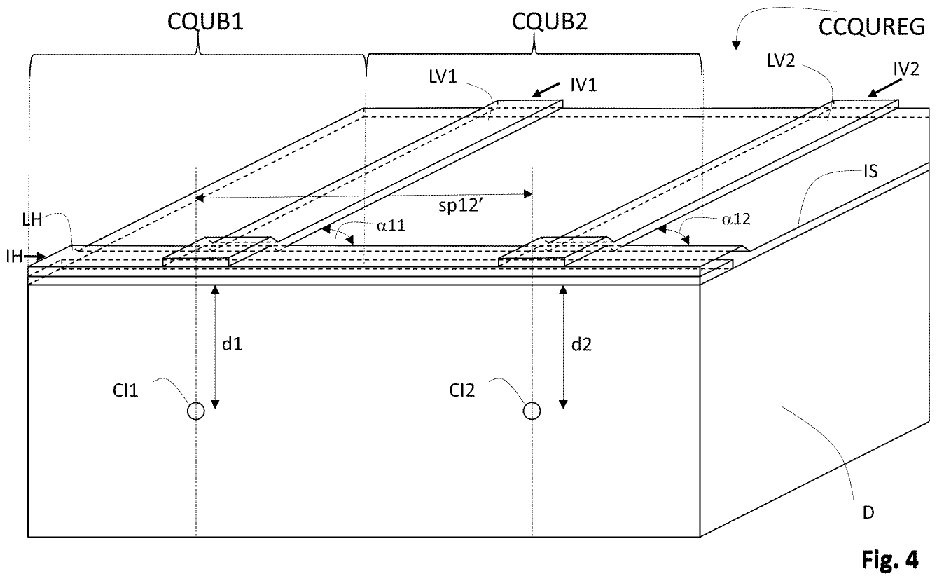

FIG. 4 shows an exemplary nucleus-nuclear quantum register (CCQUREG) with a first nuclear quantum bit (CQUB1) and a second nuclear quantum bit (CQUB2). FIG. 4 corresponds to FIG. 3 except that the first quantum dot (NV1) is replaced by a first nuclear quantum dot (CI11 and that the second quantum dot (NV2) is replaced by a second nuclear quantum dot (CI2). The first nuclear quantum dot (CI1) is spaced from the second nuclear quantum dot (CI2) by a distance (sp12′).

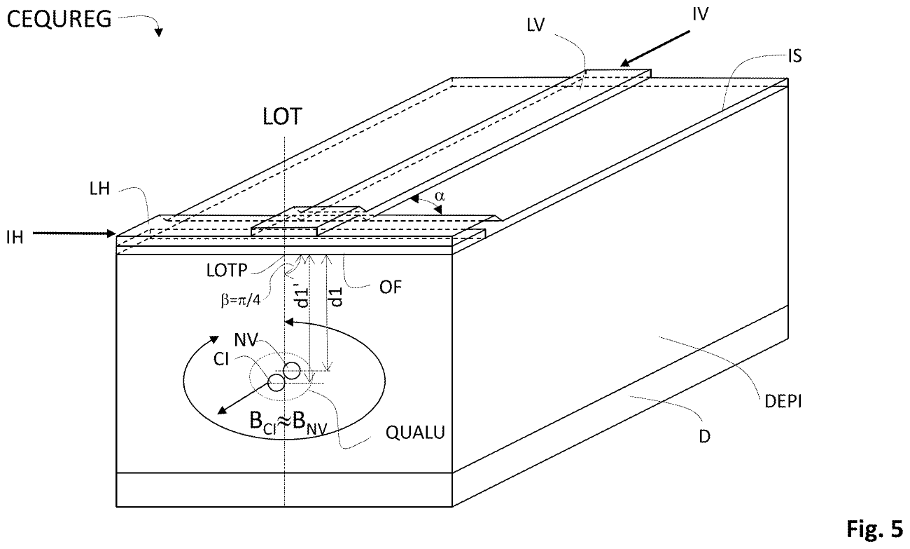

FIG. 5 shows an exemplary nucleus-electron quantum register (CEQUREG). Compared to FIG. 1, the quantum dot (NV) of FIG. 1 is now replaced by the combination of a quantum dot (NV) and a nuclear quantum dot (CI). This combination is also the simplest form of a quantum ALU (QUALU). The quantum dot (NV) is located at a distance (d1) below the surface (OF) in the substrate (D) or epitaxial layer (DEP1). The nuclear quantum dot (NV) is thereby located at a distance (d1′) below the surface (OF) in the substrate (D) or the epitaxial layer (DEP1). The distances (d1, d1′) are preferably approximately equal.

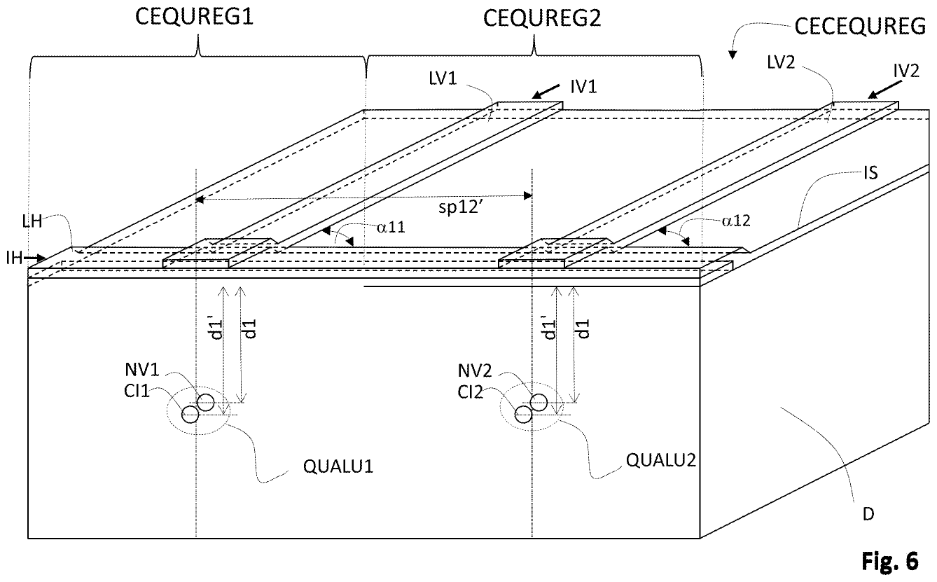

FIG. 6 shows an exemplary nucleus-electron-nucleus-electron quantum register (CECEQUREG). It largely corresponds to a combination of FIGS. 3 and 4 and 5. Compared to FIG. 3, the quantum dots (NV1, NV2) of FIG. 6 are now each replaced by a combination of a quantum dot (NV) and a nuclear quantum dot (CI). This is the simplest form of a quantum bus (QUBUS) with a first quantum ALU (NV1, CI1) and a second quantum ALU (NV2. CI2). Here, the first nuclear quantum dot (CI1) and the second nuclear quantum dot (CI2) can be entangled with each other using the first quantum dot (NV1) and the second quantum dot (NV2). Here, the first quantum dot (NV1) and the second quantum dot (NV2) are preferably used for transporting the dependence and the first nuclear quantum dot (CI1) and the second nuclear quantum dot (CI2) are used for calculations and storage. Exploited here is that the range of the coupling of the quantum dots (NV1. NV2) to each other is larger than the range of the nuclear quantum dots (CI1, CI2) to each other and that the T2 time of the nuclear quantum dots (CI1, CI2) is longer than that of the quantum dots (NV1, NV2). Typically, the distance between the first nuclear quantum dot (CI1) and the second quantum dot (NV2) is larger than the electron-nucleus coupling distance, so that the state of the first nuclear quantum dot (CI1) cannot affect the state of the second quantum dot (NV2) and the state of the second quantum dot (NV2) cannot affect the state of the first nuclear quantum dot (CI1). Typically, the distance between the second nuclear quantum dot (CI2) and the first quantum dot (NV1) is greater than the electron-nucleus coupling distance, so that the state of the second nuclear quantum dot (CI2) cannot affect the state of the first quantum dot (NV1) and the state of the first quantum dot (NV1) cannot affect the state of the second nuclear quantum dot (CI2). Typically, the distance between the first quantum dot (NV1) and the second quantum dot (NV2) is smaller than the electron-electron coupling distance, so that the state of the first quantum dot (NV1) can affect the state of the second quantum dot (NV2) and the state of the second quantum dot (NV2) can affect the state of the first quantum dot (NV1).

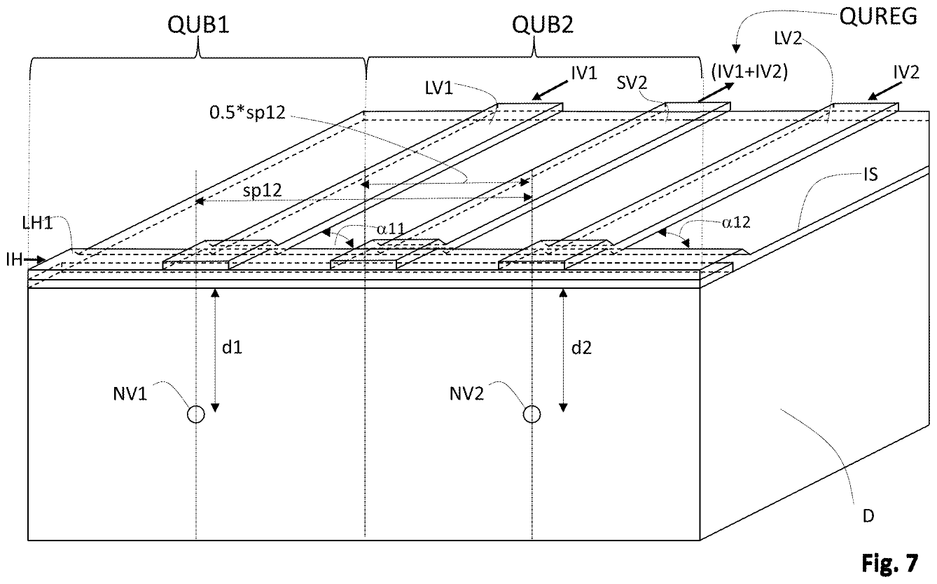

FIG. 7 shows the exemplary quantum register (QUREG) of FIG. 3 with a second vertical shield line (SV2). This technical teaching can also be applied to the registers of FIGS. 4 and 6, if necessary. The shield line allows the injection of another current to improve the selection of quantum dots during the execution of the operations by energizing the vertical and horizontal lines.

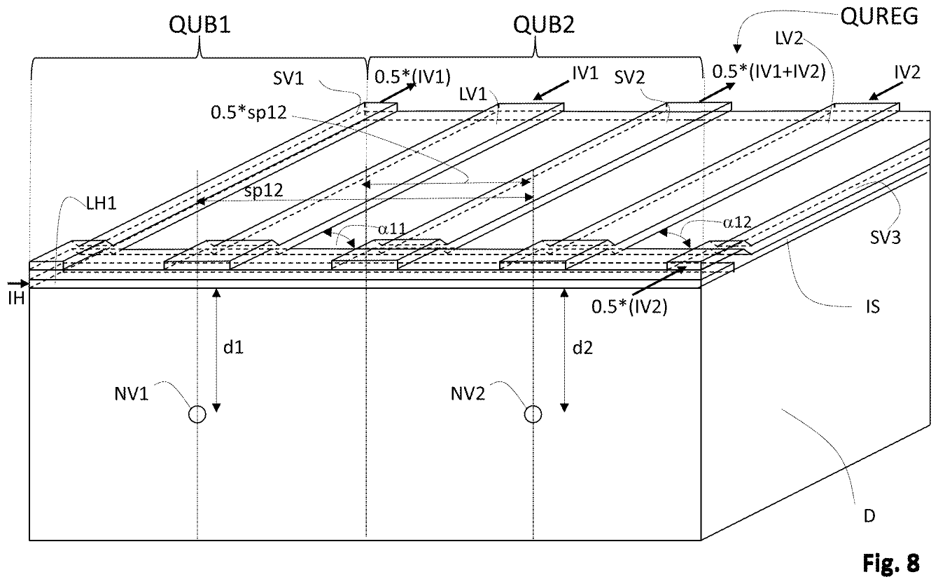

FIG. 8 shows an exemplary quantum register (QUREG) with a second vertical shield line (SV2) and with a first vertical shield line (SV1) with a third vertical shield line (SV3). This technical teaching can also be applied to the registers of FIGS. 4 and 6, if necessary. The additional shield lines allow the injection of further current to improve the selection of quantum dots during the execution of the operations by energizing the vertical and horizontal lines. The two additional lines allow for even better adjustment.

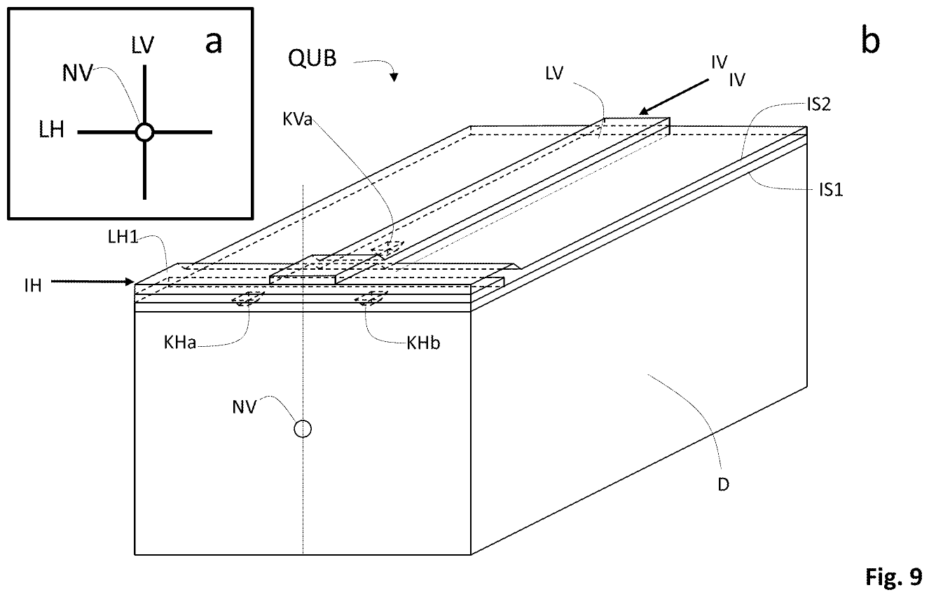

FIG. 9 shows an exemplary quantum bit (QUB) with exemplary contacts (KHa, KHb, KVa) for electrical readout of the photoelectrons in the form of a photocurrent (I_{Ph}) and a symbolic representation of the quantum bit (QUB). The symbolic representation shows the quantum dot (NV) as a circle in the center and the horizontal line (LH) as a horizontal line and the vertical line (LV) as a vertical line. This exemplary symbolic representation is used below to illustrate the construction of more complex interconnections of quantum bits, nuclear quantum bits, and quantum ALUs.

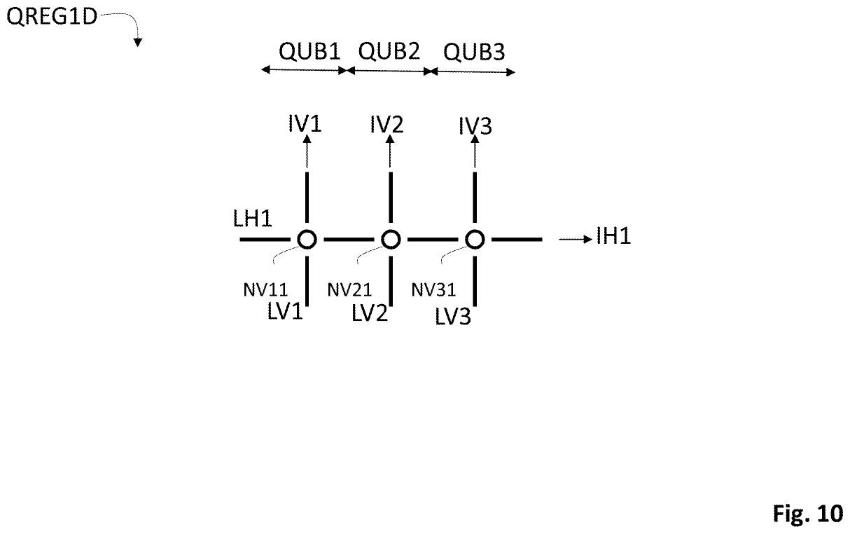

FIG. 10 shows an exemplary symbolic representation of an exemplary one-dimensional quantum register (QREG1D) with three quantum bits (QUB1, QUB2, QUB3).

The first quantum bit (QUB1) of the exemplary one-dimensional quantum register (QREG1D) comprises the first horizontal line (LH1) and the first vertical line (LV1) as well as the first quantum dot of the first heron and first column (NV11).

The second quantum bit (QUB2) of the exemplary one-dimensional quantum register (QREG1D) includes the first horizontal line (LH1) and the second vertical line (LV2) as well as the second quantum dot of the second column and first row (NV21).

The third quantum bit (QUB3) of the exemplary one-dimensional quantum register (QREG1D) includes the first horizontal line (LH1) and the third vertical line (LV3) as well as the third quantum dot of the third column and first row (NV31).

The first horizontal line (LH1) is energized with a first horizontal current (IH1).

The first vertical line (LV1) is energized with a first vertical current (IV1).

The second vertical line (LV2) is energized with a second vertical current (IV2).

The third vertical line (LV3) is energized with a third vertical current (IV3).

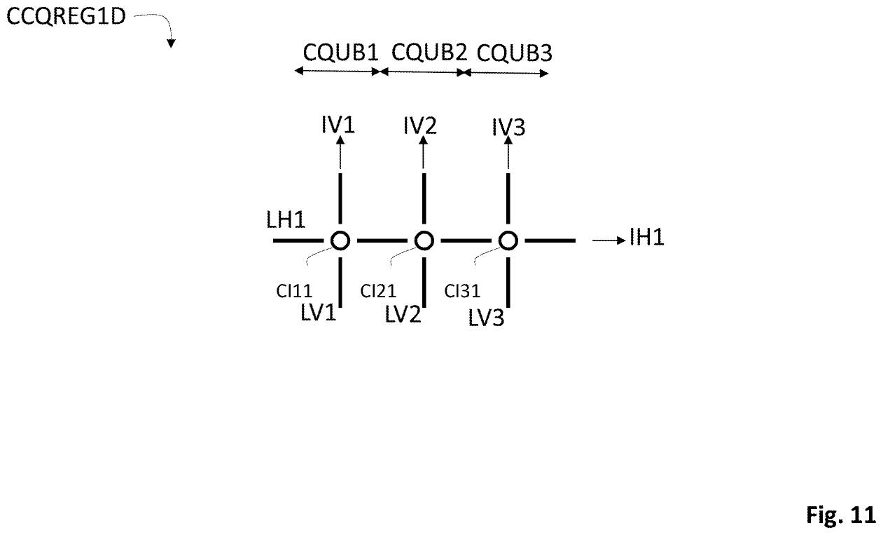

FIG. 11 shows an exemplary symbolic representation of an exemplary one-dimensional nuclear quantum register (CCQREG1D) with three nuclear quantum bits (CQUB1, CQUB2, CQUB3).

The first nuclear quantum bit (CQUB1) of the exemplary one-dimensional nuclear quantum register (CCQREGID) comprises the first horizontal line (LH1) and the first vertical line (LV1) as well as the first nuclear quantum dot of the first row and first column (CI11).

The second nuclear quantum bit (CQUB2) of the exemplary one-dimensional nuclear quantum register (CCQREGID) includes the first horizontal line (LH1) and the second vertical line (LV2) as well as the second nuclear quantum dot of the second column and first row (CI21).

The third nuclear quantum bit (CQUB3) of the exemplary one-dimensional nuclear quantum register (CCQREGID) includes the first horizontal line (LH1) and the third vertical line (LV3) as well as the third nuclear quantum dot of the third column and first row (CI31).

The first horizontal line (LH1) is energized with a first horizontal current (IH1).

The first vertical line (LV1) is energized with a first vertical current (IV1).

The second vertical line (LV2) is energized with a second vertical current (IV2).

The third vertical line (LV3) is energized with a third vertical current (IV3).

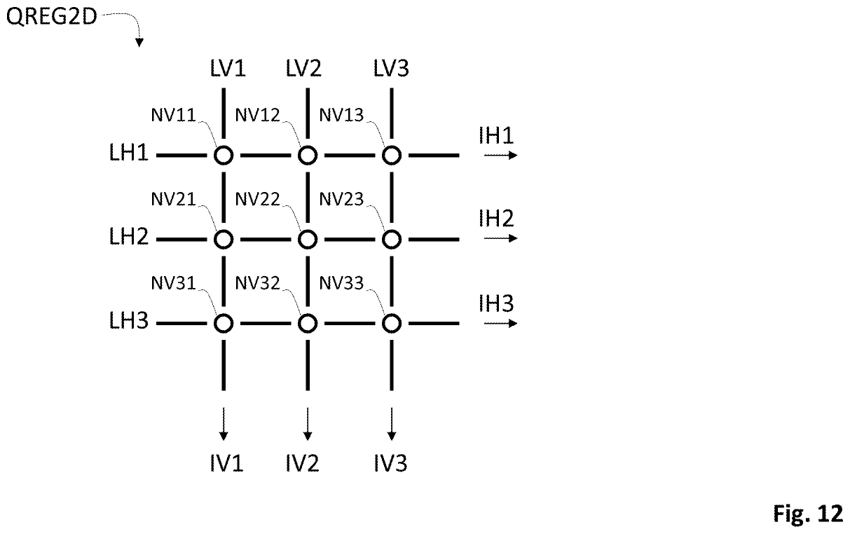

FIG. 12 shows an exemplary symbolic representation of an exemplary two-dimensional quantum register (QREG2D) with three times three quantum bits (QUB11, QUB12, QUB13, QUB21, QUB22, QUB23, QUB31, QUB32, QUB33) and associated three times three quantum dots (NV11, NV12, NV13, NV21, NV22, NV23, NV31, NV32, NV33).

The quantum bit (QUB11) of the exemplary one-dimensional quantum register (QREG1D) in the first row and first column includes the first horizontal line (LH1) and the first vertical line (LV1) as well as the quantum dot of the first row and first column (NV11).

The quantum bit (QUB12) of the exemplary one-dimensional quantum register (QREG1D) in the first row and second column includes the first horizontal line (LH1) and the second vertical line (LV2) as well as the quantum dot of the first row and second column (NV12).

The quantum bit (QUB13) of the exemplary one-dimensional quantum register (QREG1D) in the first row and third column includes the first horizontal line (LH1) and the third vertical line (LV3) as well as the quantum dot of the first row and third column (NV13).

The quantum bit (QUB21) of the exemplary one-dimensional quantum register (QREG1D) in the second row and first column includes the second horizontal line (LH2) and the first vertical line (LV1) as well as the quantum dot of the second row and first column (NV21).

The quantum bit (QUB22) of the exemplary one-dimensional quantum register (QREG1D) in the second row and second column includes the second horizontal line (LH2) and the second vertical line (LV2) as well as the quantum dot of the second row and second column (NV22).

The quantum bit (QUB23) of the exemplary one-dimensional quantum register (QREG1D) in the second row and third column includes the second horizontal line (LH2) and the third vertical line (LV3) as well as the quantum dot of the second row and third column (NV23).

The quantum bit (QUB31) of the exemplary one-dimensional quantum register (QREG1D) in the third row and first column includes the third horizontal line (LH3) and the first vertical line (LV1) as well as the quantum dot of the third row and first column (NV31).

The quantum bit (QUB32) of the exemplary one-dimensional quantum register (QREG1D) in the third row and second column includes the third horizontal line (LH3) and the second vertical line (LV2) as well as the quantum dot of the third row and second column (NV32).

The quantum bit (QUB33) of the exemplary one-dimensional quantum register (QREG1D) in the third row and third column includes the third horizontal line (LH3) and the third vertical line (LV3) as well as the quantum dot of the third row and third column (NV33).

The first horizontal line (LH1) is energized with a first horizontal current (IH1).

The second horizontal line (LH2) is energized with a second horizontal current (IH2).

The third horizontal line (LH3) is energized with a third horizontal current (IH3).

The first vertical line (LV1) is energized with a first vertical current (IV1).

The second vertical line (LV2) is energized with a second vertical current (IV2).

The third vertical line (LV3) is energized with a third vertical current (IV3).

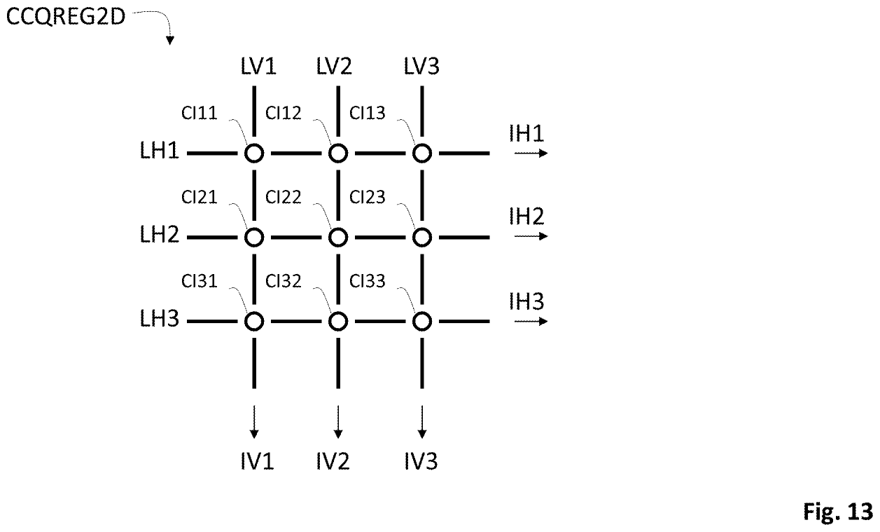

FIG. 13 shows the symbolic representation of a two-dimensional nuclear quantum register (CCQREG2D) with three times three nuclear quantum bits (CQUB11, CQUB12, CQUB13, CQUB21, CQUB22, CQUB23, CQUB31, CQUB32, CQUB33) and corresponding three times three nuclear quantum dots (CI11, CI12, CI13, CI21, CI22, CI23, CI31, CI32, CI33).

The nuclear quantum bit (CQUB11) of the exemplary one-dimensional nuclear quantum register (CCQREG2D) in the first row and first column includes the first horizontal line (LH1) and the first vertical line (LV1) as well as the nuclear quantum dot of the first row and first column (CI11).

The nuclear quantum bit (CQUB12) of the exemplary one-dimensional nuclear quantum register (CCQREG2D) in the first row and second column includes the first horizontal line (LH1) and the second vertical line (LV2) as well as the nuclear quantum dot of the first row and second column (CI12).

The nuclear quantum bit (CQUB13) of the exemplary one-dimensional nuclear quantum register (CCQREG2D) in the first row and third column includes the first horizontal line (LH1) and the third vertical line (LV3) as well as the nuclear quantum dot of the first row and third column (CI13).

The nuclear quantum bit (CQUB21) of the exemplary one-dimensional nuclear quantum register (CCQREG2D) in the second row and first column includes the second horizontal line (LH2) and the first vertical line (LV1) as well as the nuclear quantum dot of the second row and first column (CI21).

The nuclear quantum bit (CQUB22) of the exemplary one-dimensional nuclear quantum register (CCQREG2D) in the second row and second column includes the second horizontal line (LH2) and the second vertical line (LV2) as well as the nuclear quantum dot of the second row and second column (CI22).

The nuclear quantum bit (CQUB23) of the exemplary one-dimensional nuclear quantum register (CCQREG2D) in the second row and third column includes the second horizontal line (LH2) and the third vertical line (LV3) as well as the nuclear quantum dot of the second row and third column (CI23).

The nuclear quantum bit (CQUB3I) of the exemplary one-dimensional nuclear quantum register (CCQREG2D) in the third row and first column includes the third horizontal line (LH3) and the first vertical line (LV1) as well as the nuclear quantum dot of the third row and first column (CI31).

The nuclear quantum bit (QUB32) of the exemplary one-dimensional nuclear quantum register (CCQREG2D) in the third row and second column includes the third horizontal line (LH3) and the second vertical line (LV2) as well as the nuclear quantum dot of the third row and second column (CI32).

The nuclear quantum bit (CQUB33) of the exemplary one-dimensional nuclear quantum register (CCQREG2D) in the third row and third column includes the third horizontal line (LH3) and the third vertical line (LV3) as well as the nuclear quantum dot of the third row and third column (CI33).

The first horizontal line (LH1) is energized with a first horizontal current (IH1).

The second horizontal line (LH2) is energized with a second horizontal current (IH2).

The third horizontal line (LH3) is energized with a third horizontal current (IH3).

The first vertical line (LV1) is energized with a first vertical current (IV1).

The second vertical line (LV2) is energized with a second vertical current (IV2).

The third vertical line (LV3) is energized with a third vertical current (IV3).

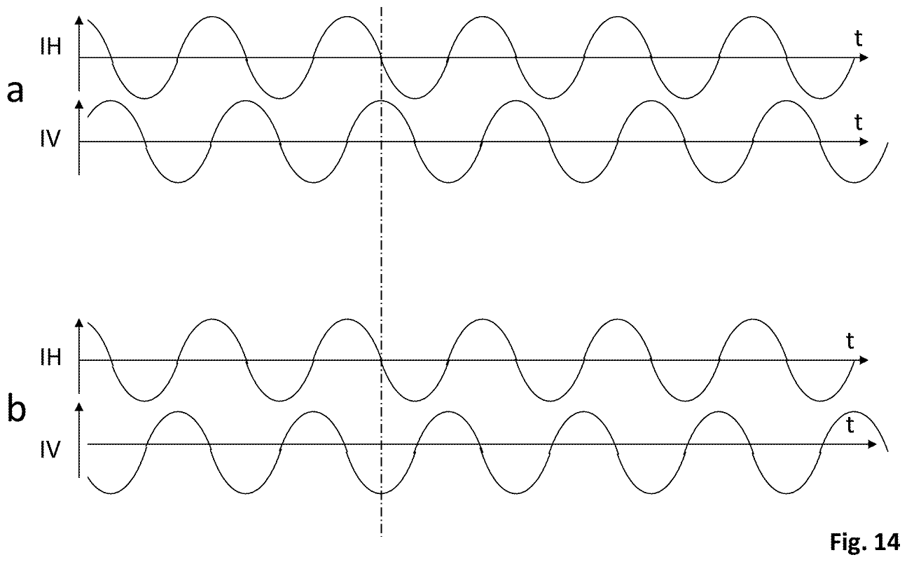

FIG. 14 shows an exemplary time amplitude curve of the horizontal current component of the horizontal current (IH) and the vertical current component of the vertical current (IV) as a function of time (t) with a phase shift of +/−π/2 for the generation of a circularly polarized electromagnetic field at the location of the quantum dot (NV) and the nuclear quantum dot (CI), respectively.

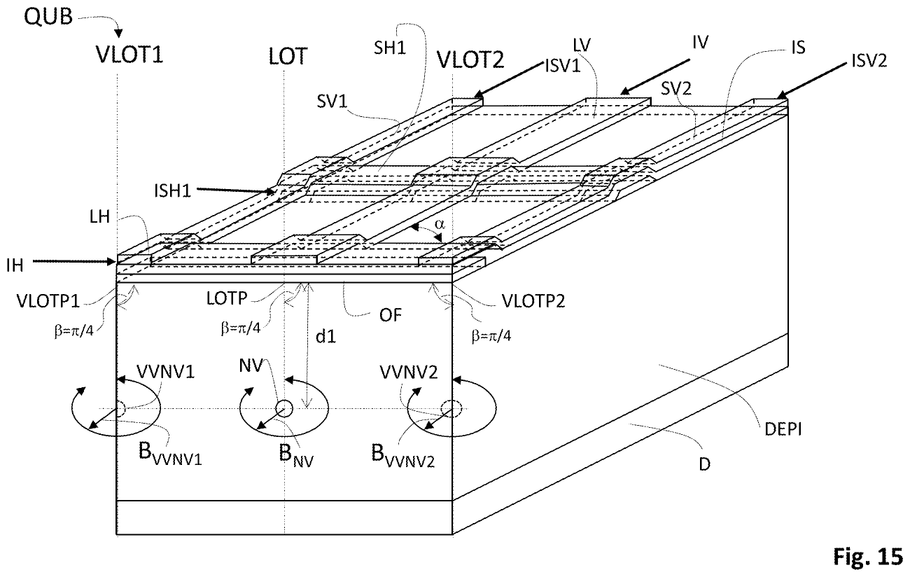

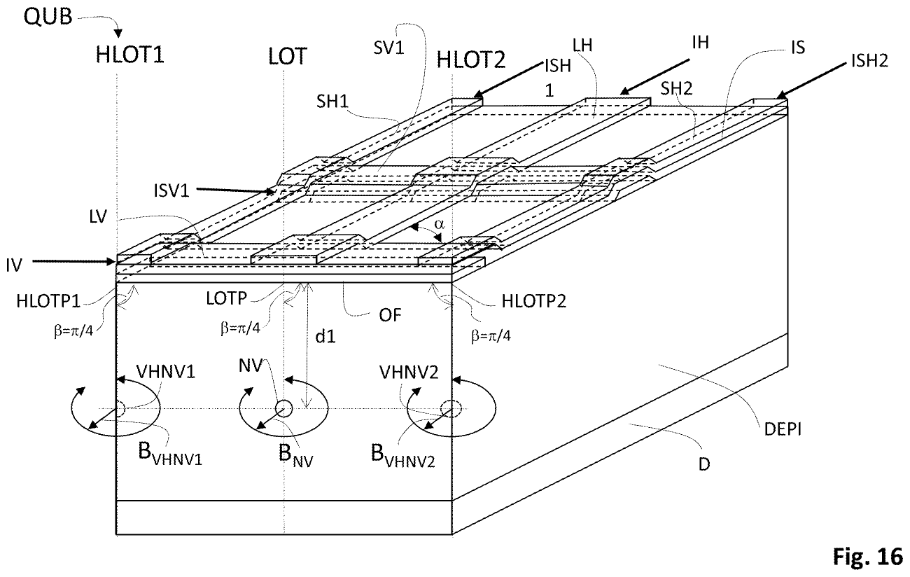

FIGS. 15 and 16 are used to illustrate an optimum current flow. FIG. 15 will be discussed first. The principle is illustrated using the example of a quantum bit (QUB) with a first vertical shield line (SV1) and a second vertical shield line (SV2). The drawing corresponds essentially to FIG. 9. In addition, a first vertical shield line (SV1) and a second vertical shield line (SV2) and a first horizontal shield line (SH1) are drawn. Parallel to a first perpendicular line (LOT) through the quantum dot (NV), a first further perpendicular line (VLOT1) and a second further perpendicular line (VLOT2) can be drawn through the respective crossing points of the corresponding vertical shielding lines (SV1, SV2) with the horizontal line (LH). A first virtual vertical quantum dot (VVNV1) and a second virtual quantum dot (VVNV2) can then be defined at the distance (d1) of the quantum dot (NV) from the surface (OF). The first vertical electric shielding current (ISV1) through the first vertical shielding line (SV1) and the second vertical electric shielding current (ISV2) through the second vertical shielding line (SV2) and the first horizontal electric shielding current (ISH1) through the first horizontal shielding line (SH1) and the second horizontal electrical shielding current (ISH2) through the second horizontal shielding line (SH2), which is not drawn in, as well as the horizontal current (IH) through the horizontal line (IH) and the vertical current (IV) through the vertical line together give six parameters, which can be freely selected. Now, the flux density (B_{NV}) of the circularly polarized electromagnetic wave field can be specified to manipulate the quantum dot (NV) at the location of the quantum dot (NV) and required, that the first virtual horizontal magnetic flux density (B_{VHNV1}) at the location of the first virtual horizontal quantum dot (VHNV1), and the second virtual horizontal magnetic flux density (B_{VHNV2}) at the location of the second virtual horizontal quantum dot (VHNV2) and the first virtual vertical magnetic flux density (B_{VVNV}) at the location of the first virtual vertical quantum dot (VVNV1) and the second virtual vertical magnetic flux density (B_{VVNV2}) at the location of the second virtual vertical quantum dot (VVNV2) vanish. The first virtual horizontal quantum dot (VHNV1) and the second virtual horizontal quantum dot (VHNV2) are not drawn in the figure because the figure represents a cross-section and for visibility the sectional plane must be rotated 90° about the LOT axis. FIG. 16 represents this cross section. FIG. 16 is used to illustrate an optimal current flow using the example of a quantum bit (QUB) with a first horizontal shield line (SH1) and a second horizontal shield line (SH2). This balanced energization can minimize the unintended response of quantum dots.

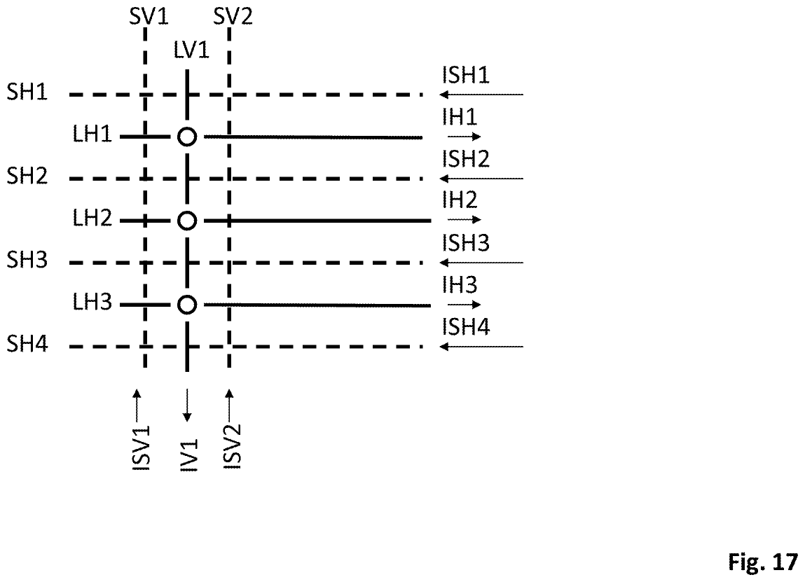

FIG. 17 shows the symbolic representation of a three-bit quantum register or nuclear quantum register with four horizontal shield lines (SH1, SH2, SH3, SH4) and two vertical shield lines (SV1, SV2) and with a common first vertical drive line (LV1) and with three horizontal lines (LH1, LH2, LH3).

The first horizontal shield line (SH1) is energized with the first horizontal shield current (ISH1) flowing through the first horizontal shield line (SH1).

The second horizontal shield line (SH2) is energized with the second horizontal shield current (ISH2) flowing through the second horizontal shield line (SH1).

The third horizontal shield line (SH3) is energized with the third horizontal shield current (ISH3) flowing through the third horizontal shield line (SH3).

The fourth horizontal shield line (SH4) is energized with the fourth horizontal shield current (ISH4) flowing through the fourth horizontal shield line (SH4).

The first vertical shield line (SV1) is energized with the first vertical shield current (ISV1) flowing through the first vertical shield line (SV1).

The second vertical shield line (SV2) is energized with the second vertical shield current (ISV2) flowing through the second vertical shield line (SV2).

The first horizontal line (LH1) is energized with the first horizontal current (IH1) flowing through the first horizontal line (LH1).

The second horizontal line (LH2) is energized with the second horizontal current (IH2) flowing through the second horizontal line (LH2).

The third horizontal line (LH3) is energized with the third horizontal current (IH3) flowing through the third horizontal line (LH3).

The first vertical line (LV1) is energized with the first vertical current (IV1) flowing through the first vertical line (LV1).

As can be easily seen, three scenarios are needed to ensure that only one quantum dot is energized at a time.

We first assume that we are dealing with quantum bits (QUB1, QUB2, QUB3) with three quantum dots (NV1, NV2, NV3).

In the first scenario A, the vertical shielding currents (ISV1, ISV2) and the horizontal shielding currents (ISH1, ISH2, ISH3, ISH4) and the first vertical current (IV1) and the horizontal currents (IH1, IH2, IH3) are chosen such, that the flux density (B_{NV1}) of the circularly polarized electromagnetic wave field for manipulating the first quantum dot (NV1) at the location of the first quantum dot (NV1) is different from zero and the flux density (B_{NV2}) of the circularly polarized electromagnetic wave field for manipulating the second quantum dot (NV2) at the location of the second quantum dot (NV2) is equal or nearly equal to zero and the flux density (B_{NV3}) of the circularly polarized electromagnetic wave field for manipulating the third quantum dot (NV3) at the location of the third quantum dot (NV3) is equal or nearly equal to zero.

In the second scenario B, the vertical shielding currents (ISV1, ISV2) and the horizontal shielding currents (ISH1, ISH2, ISH3, ISH4) and the first vertical current (IV1) and the horizontal currents (IH1, IH2, IH3) are chosen such, that the flux density (B_{NV1}) of the circularly polarized electromagnetic wave field for manipulating the first quantum dot (NV1) at the location of the first quantum dot (NV1) is zero or nearly zero and the flux density (B_{NV2}) of the circularly polarized electromagnetic wave field for manipulating of the second quantum dot (NV2) at the location of the second quantum dot (NV2) is different from zero and the flux density (B_{NV3}) of the circularly polarized electromagnetic wave field for manipulating the third quantum dot (NV3) at the location of the third quantum dot (NV3) is equal to zero or nearly zero.

In the third scenario C, the vertical shielding currents (ISV1, ISV2) and the horizontal shielding currents (ISH1, ISH2, ISH3, ISH4) and the first vertical current (IV1) and the horizontal currents (IH1, IH2, IH3) are chosen such, that the flux density (B_{NV1}) of the circularly polarized electromagnetic wave field for manipulating the first quantum dot (NV1) at the location of the first quantum dot (NV1) is zero or nearly zero and the flux density (B_{NV2}) of the circularly polarized electromagnetic wave field for manipulating of the second quantum dot (NV2) at the location of the second quantum dot (NV2) is equal to zero or nearly zero and the flux density (B_{NV3}) of the circularly polarized electromagnetic wave field for manipulating the third quantum dot (NV3) at the location of the third quantum dot (NV3) is different from zero.

Obviously, then, with scenario A, the first quantum bit (QUB1) with the first quantum dot (NV1) can be selected and manipulated without affecting the other quantum bits (QUB2, QUB3) with the other quantum dots (NV2, NV3).

Obviously, with scenario B, the second quantum bit (QUB2) can then be selected and manipulated with the second quantum dot (NV2) without affecting the other quantum bits (QUB1, QUB3) with the other quantum dots (NV1, NV3).

Obviously, with scenario C, the third quantum bit (QUB3) can then be selected and manipulated with the third quantum dot (NV3) without affecting the other quantum bits (QUB1, QUB2) with the other quantum dots (NV1, NV2).

This scenario can be arbitrarily extended for linear quantum registers as in FIG. 17 for quantum registers of arbitrary length with more than 3 quantum bits.

Now imagine that the points in FIG. 17 are not quantum dots, but nuclear quantum dots.

We first assume that we are dealing with nuclear quantum bits (CQUB1, CQUB2, CQUB3) with three nuclear quantum dots (CI1, CI2, CI3).

In the first scenario A, the vertical shielding currents (ISV1, ISV2) and the horizontal shielding currents (ISH1, ISH2, ISH3, ISH4) and the first vertical current (IV1) and the horizontal currents (IH1, IH2, IH3) are chosen such, that the flux density (Biro) of the circularly polarized electromagnetic wave field for manipulating the first nuclear quantum dot (CI1) at the location of the first nuclear quantum dot (CI1) is different from zero and the flux density (Bets) of the circularly polarized electromagnetic wave field for manipulating the second nuclear quantum dot (CI2) is different from zero, nuclear quantum dot (CI2) at the location of the second nuclear quantum dot (CI2) is equal or nearly equal to zero and the flux density (Box) of the circularly polarized electromagnetic wave field for manipulating the third nuclear quantum dot (CI3) at the location of the third nuclear quantum dot (CI3) is equal or nearly equal to zero.

In the second scenario B, the vertical shielding currents (ISV1, ISV2) and the horizontal shielding currents (ISH1, ISH2, ISH3, ISH4) and the first vertical current (IV1) and the horizontal currents (IH1, IH2, IH3) are chosen such, that the flux density (B_{CI1}) of the circularly polarized electromagnetic wave field for manipulating the first nuclear quantum dot (CI1) at the location of the first nuclear quantum dot (CI1) is zero or nearly zero and the flux density (B_{CI2}) of the circularly polarized electromagnetic wave field for manipulating of the second nuclear quantum dot (CI2) at the location of the second nuclear quantum dot (CI2) is different from zero and the flux density (B_{CI3}) of the circularly polarized electromagnetic wave field for manipulating the third nuclear quantum dot (CI3) at the location of the third nuclear quantum dot (CI3) is equal to zero or nearly zero.

In the third scenario C, the vertical shielding currents (ISV1, ISV2) and the horizontal shielding currents (ISH1, ISH2, ISH3, ISH4) and the first vertical current (IV1) and the horizontal currents (IH1, IH2, IH3) are chosen such, that the flux density (B_{CI1}) of the circularly polarized electromagnetic wave field for manipulating the first nuclear quantum dot (CI1) at the location of the first nuclear quantum dot (CI1) is zero or nearly zero and the flux density (B_{CI2}) of the circularly polarized electromagnetic wave field for manipulating of the second nuclear quantum dot (CI2) at the location of the second nuclear quantum dot (CI2) is zero or nearly zero and the flux density (B_{CI3}) of the circularly polarized electromagnetic wave field for manipulating the third nuclear quantum dot (CI3) at the location of the third nuclear quantum dot (CI3) is different from zero.

Obviously, then, with scenario A, the first nuclear quantum bit (CQUB1) with the first nuclear quantum dot (CI1) can be selected and manipulated without affecting the other nuclear quantum bits (CQUB2, CQUB3) with the other nuclear quantum dots (CI2, CI3).

Obviously, with scenario B, the second nuclear quantum bit (CQUB2) can then be selected and manipulated with the second nuclear quantum dot (CI2) without affecting the other nuclear quantum bits (CQUB1, CQUB3) with the other nuclear quantum dots (CI1, CI3).

Obviously, with scenario C, the third nuclear quantum bit (CQUB3) can then be selected and manipulated with the third nuclear quantum dot (CI3) without affecting the other nuclear quantum bits (CCQUB2) with the other nuclear quantum dots (CI1, CI2).

This scenario can be extended arbitrarily for linear nuclear quantum registers as in FIG. 17 for nuclear quantum registers of arbitrary length with more than 3 nuclear quantum bits.

As can be easily seen, 10 currents can be freely selected. However, only three magnetic flux densities have to be determined. Therefore, the system is provided with very many degrees of freedom. So, theoretically, the shield lines (SH1, SH2, SH3, SH4, SV1, SV2) can be omitted in such a scenario. Provided that more than two metallization layers are provided, it is useful if some shield lines are routed across the quantum dots at an angle other than 0° or 90° in order to be able to locally compensate the magnetic field through the common vertical line (LV1).

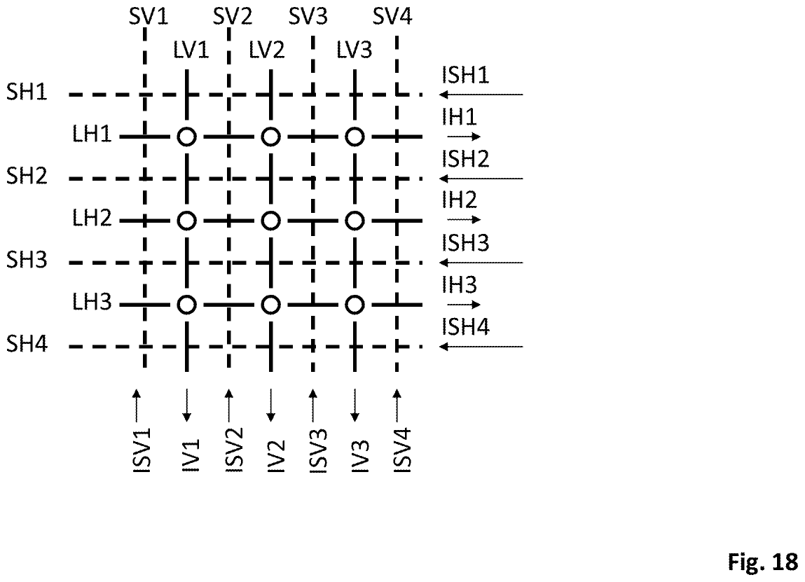

FIG. 18 shows the symbolic representation of a two-dimensional three×three-bit quantum register or nuclear quantum register with shield lines and contacts for reading out the photoelectrons in the form of photocurrents (Iₚₕ).

The device has four horizontal shield lines (SH1, SH2, SH3, SH4) and four vertical shield lines (SV1, SV2, SV3, SV4) and with three vertical drive lines (LV1, LV2, LV3) and with three horizontal lines (LH1, LH2, LH3).

The first horizontal shield line (SH1) is energized with the first horizontal shield current (ISH1) flowing through the first horizontal shield line (SH1).

The second horizontal shield line (SH2) is energized with the second horizontal shield current (ISH2) flowing through the second horizontal shield line (SH1).

The third horizontal shield line (SH3) is energized with the third horizontal shield current (ISH3) flowing through the third horizontal shield line (SH3).

The fourth horizontal shield line (SH4) is energized with the fourth horizontal shield current (ISH4) flowing through the fourth horizontal shield line (SH4).

The first vertical shield line (SV1) is energized with the first vertical shield current (ISV1) flowing through the first vertical shield line (SV1).

The second vertical shield line (SV2) is energized with the second vertical shield current (ISV2) flowing through the second vertical shield line (SV2).

The third vertical shield line (SV3) is energized with the third vertical shield current (ISV3) flowing through the third vertical shield line (SV3).

The fourth vertical shield line (SV4) is energized with the fourth vertical shield current (ISV4) flowing through the fourth vertical shield line (SV4).

The first horizontal line (LH1) is energized with the first horizontal current (IH1) flowing through the first horizontal line (LH1).

The second horizontal line (LH2) is energized with the second horizontal current (IH2) flowing through the second horizontal line (LH2).

The third horizontal line (LH3) is energized with the third horizontal current (IH3) flowing through the third horizontal line (LH3).

The first vertical line (LV1) is energized with the first vertical current (IV1) flowing through the first vertical line (LV1).

The second vertical line (LV2) is energized with the second vertical current (IV2) flowing through the second vertical line (LV2).

The third vertical line (LV3) is energized with the third vertical current (IV3) flowing through the third vertical line (LV3).

As can be easily understood, there are 14 degrees of freedom at 9 points to be solved. Preferably, the grid of the skim lines should be rotated 45° against the horizontal lines and vertical lines, but this requires a difficult lithography process with the necessary dimensions.

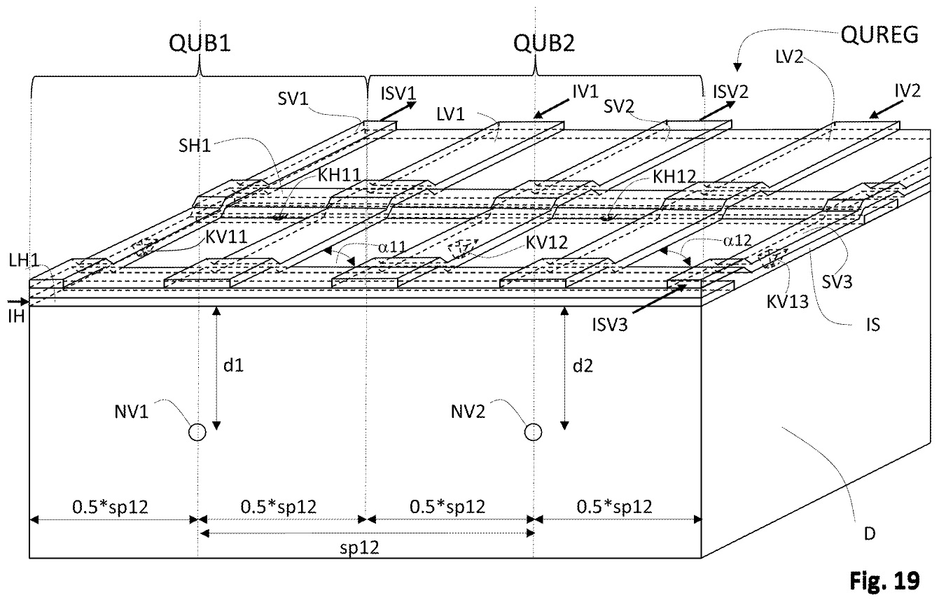

FIG. 19 shows an exemplary two-bit quantum register (QUREG) with a common first horizontal line (LH1), several shield lines and two quantum dots (NV1, NV2). FIG. 19 largely corresponds to FIG. 8. Now, in addition to explain the readout process, a first horizontal shield line (SH1) is drawn parallel to the first horizontal line (LH1). Since this is a cross-sectional view, the corresponding second horizontal shield line (SH2) which runs on the other side of the first horizontal line (LH1), also parallel to it, is not drawn. Through contacts (KV11, KH11, KV12, KH12, KV13) the shielding lines are connected to the substrate in this example. If an extraction field is now applied between two parallel shielding lines by applying an extraction voltage between them, a measurable current flow occurs when the quantum dots (NV1, NV2) are irradiated with green light and these are in the correct quantum state. More can be found, for example, in Petr Siyushev, Milos Nesladek, Emilie Bourgeois, Michal Gulka, Jamslav Hruby, Takashi Yamamoto, Michael Trupke, Tokuyuki Teraji, Junichi soya, Fedor Jelezko, “Photoelectrical imaging and coherent spin-state readout of single nitrogen-vacancy centers in diamond,” Science 363, 728-731 (2019) 15 Feb. 2019.

This design is particularly preferred in linear devices, such as those shown in FIG. 10.

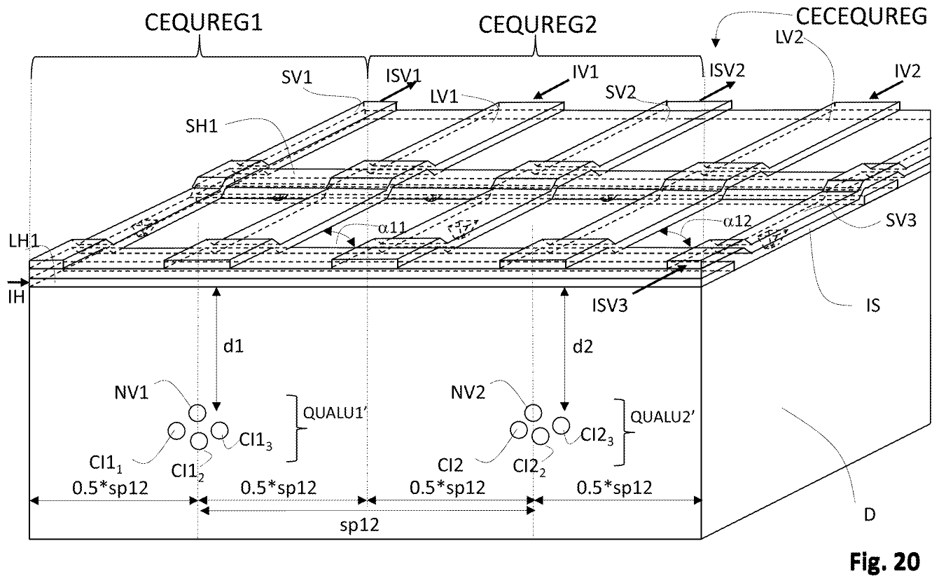

FIG. 20 corresponds to FIG. 19 with the difference that now the quantum dots (NV1. NV2) are each part of several nucleus-electron quantum registers. Each quantum dot (NV1, NV2) is part of a quantum ALU (QUALU1, QUALU2) in the example of FIG. 20.

The first quantum dot (NV1) of the first quantum ALU (QUALU1) can interact with a first nuclear quantum dot (CI11) of the first quantum ALU (QUALU1) in the example of FIG. 20 when the first vertical line (LV1) and the first horizontal line (LH1) are energized with a first vertical current (IV1) and a first horizontal current (IH1), which are modulated with a first electron-nucleus radio wave resonance frequency (f_{RWECI1}) for the first quantum ALU (QUALU1) or a first nucleus-electron-microwave resonance frequency (f_{MWCEI1}) for the first quantum ALU (QUALU1). This first electron-nucleus radio wave resonance frequency (f_{RWECI1}) for the first quantum ALU (QUALU1) and this first nucleus-electron-microwave resonance frequency (f_{MWCEI1}) for the first quantum ALU (QUALU1) are preferably measured once in an initialization step by an OMDR measurement. The measured values are stored in a memory of the control computer of the control device (μC), which the latter retrieves when the corresponding nucleus-electron quantum register (CEQUREG) is to be driven. The control computer of the control device (μC) then sets the frequencies accordingly.

The first quantum dot (NV1) of the first quantum ALU (QUALU1) can interact with a second nuclear quantum dot (CI12) of the first quantum ALU (QUALU1) in the example of FIG. 20 when the first vertical line (LV1) and the first horizontal line (LH1) are energized with a first vertical current (IV1) and a first horizontal current (IH1), which are modulated with a second electron-nucleus radio wave resonance frequency (f_{RWEC21}) for the first quantum ALU (QUALU1) or a second nucleus-electron microwave resonance frequency (f_{MWCE21}) for the first quantum ALU (QUALU1). This second electron-nucleus radio wave resonance frequency (f_{RWEC21}) for the first quantum ALU (QUALU1) and this second nucleus-electron microwave resonance frequency (f_{MWCE21}) for the first quantum ALU (QUALU1) are preferably measured once in said initialization step by another OMDR measurement. The measured values are stored in a memory of the control computer of the control device (μC), which the latter retrieves when the corresponding nucleus-electron quantum register (CEQUREG) is to be driven. The control computer of the control device (μC) then sets the frequencies accordingly.

The first quantum dot (NV1) of the first quantum ALU (QUALU1) can interact with a third nuclear quantum dot (CI13) of the first quantum ALU (QUALU1) in the example of FIG. 20 when the first vertical line (LV1) and the first horizontal line (LH1) are energized with a first vertical current (IV1) and a first horizontal current (IH1), which are modulated with a third electron-nucleus radio wave resonance frequency (f_{RWEC31}) for the fret quantum ALU (QUALU1) or a third nucleus-electron-microwave resonance frequency (f_{MWCE31}) for the first quantum ALU (QUALU1). This third electron-nucleus radio wave resonance frequency (f_{RWEC31}) for the first quantum ALU (QUALU1) and this third nucleus-electron-microwave resonance frequency (f_{MWCE31}) for the first quantum ALU (QUALU1) are preferably measured once in said initialization step by another OMDR measurement. The measured values are stored in a memory of the control computer of the control device (μC), which the latter retrieves when the corresponding nucleus-electron quantum register (CEQUREG) is to be driven. The control computer of the control device (μC) then sets the frequencies accordingly.

The second quantum dot (NV2) of the second quantum ALU (QUALU2) can interact Example of FIG. 20 with a first nuclear quantum dot (CI21) of the second quantum ALU (QUALU2) when the second vertical line (LV2) and the first horizontal line (LH1) are energized with a second vertical current (IV2) and a first horizontal current (IH1), which are modulated with a first electron-nucleus radio wave resonance frequency (f_{RWEC12}) for the second quantum ALU (QUALU2) or a first nucleus-electron microwave resonance frequency (f_{MWCE12}) for the second quantum ALU (QUALU2). This first electron-nucleus radio wave resonance frequency (f_{RWECI2}) for the second quantum ALU (QUALU2) and this first nucleus-electron-microwave resonance frequency (f_{MWCEI2}) for the second quantum ALU (QUALU2) are preferably measured once in an initialization step by an OMDR measurement. The measured values are stored in a memory of the control computer of the control device (μC), which the latter retrieves when the corresponding nucleus-electron quantum register (CEQUREG) is to be driven. The control computer of the control device (μC) then sets the frequencies accordingly.

The second quantum dot (NV2) of the second quantum ALU (QUALU2) can interact with a second nuclear quantum dot (CI22) of the second quantum ALU (QUALU2) in the example of FIG. 20 when the second vertical line (LV2) and the first horizontal line (LH1) are energized with a second vertical current (IV2) and a first horizontal current (IH1), modulated with a second electron-nucleus radio wave resonance frequency (f_{RWEC22}) for the second quantum ALU (QUALU2) or a second nucleus-electron microwave resonance frequency (f_{MWCE22}) for the second quantum ALU (QUALU2). This second electron-nucleus radio wave resonance frequency (f_{RWEC22}) for the second quantum ALU (QUALU2) and this second nucleus-electron-microwave resonance frequency (f_{MWCE22}) for the second quantum ALU (QUALU2) are preferably measured once in said initialization step by another OMDR measurement. The measured values are stored in a memory of the control computer of the control device (μC), which the latter retrieves when the corresponding nucleus-electron quantum register (CEQUREG) is to be driven. The control computer of the control device (μC) then sets the frequencies accordingly.

The second quantum dot (NV2) of the second quantum ALU (QUALU2) can interact with a third nuclear quantum dot (CI23) of the second quantum ALU (QUALU2) in the example of FIG. 20 when the second vertical line (LV2) and the first horizontal line (LH1) are energized with a second vertical current (IV2) and a first horizontal current (IH1), which are modulated with a third electron-nucleus radio wave resonance frequency (f_{RWEC32}) for the second quantum ALU (QUALU2) or a third nucleus-electron-microwave resonance frequency (f_{MWCE32}) for the second quantum ALU (QUALU2). This third electron-nucleus radio wave resonance frequency (f_{RWEC32}) for the second quantum ALU (QUALU2) and this third nucleus-electron microwave resonance frequency (f_{MWCE32}) for the second quantum ALU (QUALU2) are preferably measured once in said initialization step by another OMDR measurement. The measured values are stored in a memory of the control computer of the control device (μC), which the latter retrieves when the corresponding nucleus-electron quantum register (CEQUREG) is to be driven. The control computer of the control device (μC) then sets the frequencies accordingly.

Since the coupling range of the quantum dots (NV1, NV2) is larger, they can be coupled to each other. The second quantum dot (NV2) of the second quantum ALU (QUALU2) can interact with the first quantum dot (NV1) of the first quantum ALU (QUALU1) in the example of FIG. 20, when the first vertical line (LV1) and the second vertical line (LV2) and the first horizontal line (LH1) are energized with a first vertical current (IV1) and a second vertical current (IV2) and a first horizontal current (IH1), which are modulated with an electron1-electron2-microwave resonance frequency (f_{MWEE12}) for the coupling of the first quantum dot (NV1) of the first quantum ALU (QUALU1) with the second quantum dot (NV2) of the second quantum ALU (QUALU2). This electron1-electron2-microwave resonance frequency (f_{MWEE12}) for the coupling of the first quantum dot (NV1) of the first quantum ALU (QUALU1) is preferably measured once in said initialization step by another OMDR measurement. The measured values are stored in a memory of the control computer of the control device (μC), which the latter retrieves when the corresponding electron-electron quantum register (QUREG) comprising the first quantum dot (NV1) and the second quantum dot (NV2) is to be driven. The control computer of the control device (μC) then sets the frequencies accordingly.

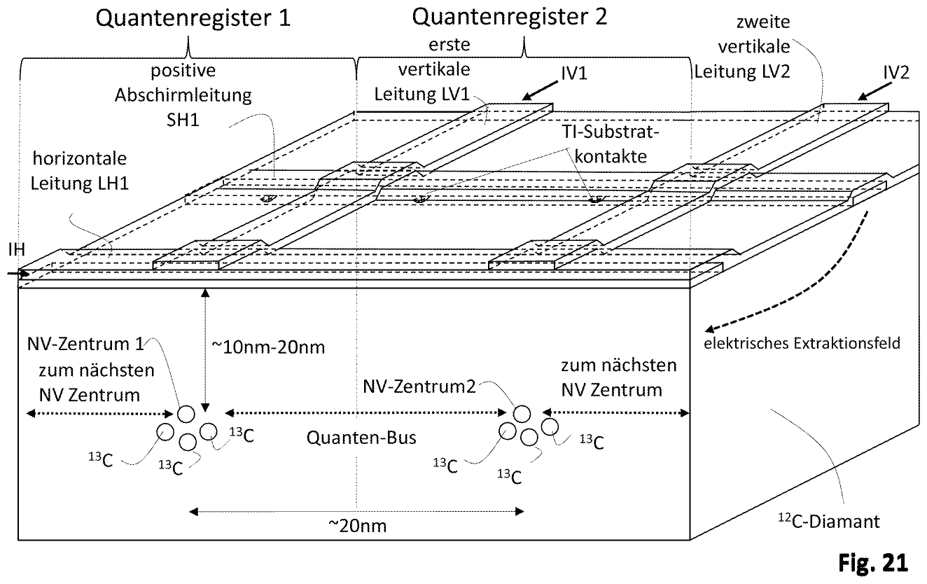

FIG. 21 serves to explain the quantum bus operation again. The quantum dots (NV) can be coupled over longer distances than the nuclear quantum bits (CI). They fulfill the function of the so-called “flying Q-bits”. The quantum dots (NV) are preferably NV centers fabricated in a preferably practically isotopically pure ¹²C diamond layer when diamond is used as the material of the substrate (D) or the material of the epitaxial layer (DEP1). The quantum dots (NV) are preferably G centers fabricated in a preferably practically isotopically pure ²⁸Si silicon layer when silicon is used as the material of the substrate (D) or the material of the epitaxial layer (DEP1). The quantum dots (NV), when silicon carbide is used as the material of the substrate (D) or the material of the epitaxial layer (DEP1), are preferably Vsi centers fabricated in a preferably practically isotopically pure ²⁸Si¹²C silicon carbide layer. The quantum dots (NV) are used to transport dependencies over longer distances within the device, while the actual computation takes place in the nuclear quantum dots (CI). The nuclear quantum dots (CI) are preferably ¹³C isotopes within the diamond material or ¹⁵N isotopes as nitrogen atoms of said NV centers when using diamond as the material of the substrate (D) or the material of the epitaxial layer (DEP1). The nuclear quantum dots (CI), when silicon is used as the material of the substrate (D) or the material of the epitaxial layer (DEP1), are preferably ²⁹Si isotopes within the silicon material or ¹³C isotopes as carbon atoms of said G centers. The nuclear quantum dots (CI) are preferably ¹³C isotopes and/or ²⁹Si isotopes within the silicon carbide material when silicon carbide is used as the material of the substrate (D) or the material of the epitaxial layer (DEP1). The use of nuclear quantum bits (CI) has the advantage that the T2 times in the nuclear quantum bits are then much longer. Thus, the quantum dots (NV1, NV2) play approximately the role of terminals of the quantum ALUs (QUALU1, QUALU2).

This quantum bus (QUBUS) consisting of a more or less branched chain of quantum dots (NV1, NV2) and the local nuclear quantum dots (CI11, CI12, CI13, CI21, CI22, CI23) connected to the actual quantum bus via the quantum dots (NV1, NV2) represents the core of the disclosure and the heart of the quantum computer. In this context, the quantum bus (QUBUS) can become so large that not all nuclear quantum dots (CI11, CI12, CI13, CI21, CI22, CI23) can couple to all quantum dots (NV1, NV2). A quantum bus (QUBUS) can also have more than two quantum dots (NV1, NV2), which can, for example, be arranged one behind the other along an ordered chain, whereby two neighboring quantum dots are always so close to each other that they can couple with each other, while the coupling of a quantum dot with other than its maximum two immediate neighbors in this exemplary linear chain of quantum dots is not directly possible due to a too large distance. In that case, however, the next but one quantum dot in the exemplary chain of quantum dots can be coupled to the quantum dot indirectly by coupling to the next quantum dot that can be coupled to the quantum dot. Coupling can be understood here as entanglement of states.

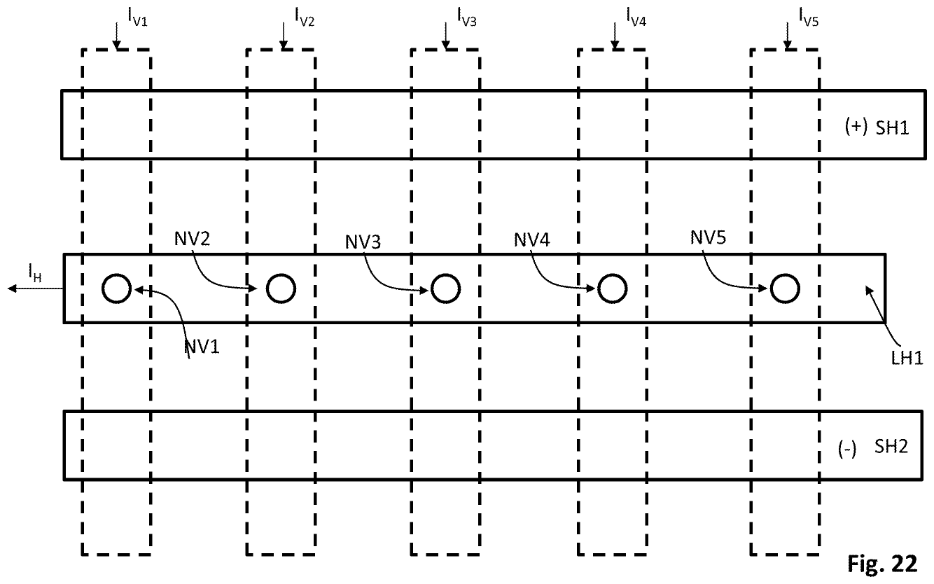

FIG. 22 shows an example of the arrangement for an exemplary five-bit quantum register in a highly simplified form in plain view. The five quantum dots (NV1, NV2, NV3, NV4, NV5) are arranged linearly and can be controlled by a common first horizontal line (LH1). Perpendicular to this, in another metallization plane, the first vertical line (LV1) for controlling the first quantum dot (NV1) and the second vertical line (LV2) for controlling the second quantum dot (NV2) and the third vertical line (LV3) for controlling the third quantum dot (NV3) and the fourth vertical line (LV4) for controlling the fourth quantum dot (NV4) and the fifth vertical line (LV5) for controlling the fifth quantum dot (NV5) are fabricated. The device of the example of FIG. 22 has only a first horizontal shield line (SH1) and a second horizontal shield line (SH2). Vertical shield lines are not provided in the example. By applying an extraction voltage (Vₑₓₜ) between the horizontal shield line (SH1) and the second horizontal shield line (SH2), the photoelectrons can be read out.

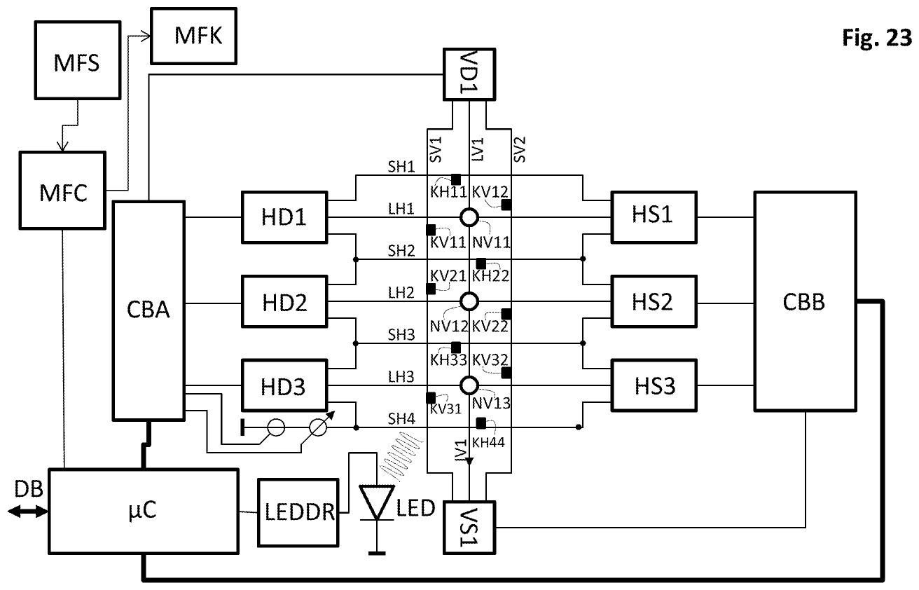

FIG. 23 shows the block diagram of an exemplary quantum computer with an exemplary schematically indicated three-bit quantum register which, if necessary, could also be replaced, for example, by a three-bit nucleus-electron-nucleus-electron quantum register (CECEQUREG) with three quantum ALUs. An extension to an n-bit quantum register is easily possible for the person skilled in the art.

The core of the exemplary control device of FIG. 23 is a control device (μC) which is preferably a control computer. Preferably, the overall device has a magnetic field controller (MFC) which preferably receives its operating parameters from said control device (μC) and preferably returns operating status data to said control device (μC). The magnetic field control (MFC) is preferably a controller whose task is to compensate for an external magnetic field by active counter-control. Preferably, the magnetic field controller (MFC) uses a magnetic field sensor (MFS) for this purpose, which preferably detects the magnetic flux in the device preferably in the proximity of the quantum dots. Preferably, the magnetic field sensor (MFS) is a quantum sensor. Reference is made here to the applications DE 10 2018 127 394.0, DE 10 2019 130 114.9, DE 10 2019 120 076.8 and DE 10 2019 121 137.9. By means of a magnetic field control (MFK) device, the magnetic field controller (MFC) readjusts the magnetic flux density. Preferably, a quantum sensor is used because it has the higher accuracy to sufficiently stabilize the magnetic field.

The control device (μC) preferably drives the horizontal and vertical driver stages via a control unit A (CBA), which preferably energizes the horizontal lines and vertical lines with the respective horizontal and vertical currents and generates the correct frequencies and temporal burst durations.

The control unit A sets the frequency and pulse duration of the first horizontal shield current (ISH1) for the first horizontal shield line (SH1) in the first horizontal driver stage (HD1) according to the specifications of the control device (MC).

The control unit A sets the frequency and the pulse duration of the first horizontal current (IH1) for the first horizontal line (LH1) in the first horizontal driver stage (HD1) according to the specifications of the control device (μC).

The control unit A sets the frequency and the pulse duration of the second horizontal shielding current (ISH2) for the second horizontal shielding line (SH2) in the first horizontal driver stage (HD1) and that in the second horizontal driver stage (HD2) according to the specifications of the control device (μC).

The control unit A sets the frequency and the pulse duration of the second horizontal current (IH2) for the second horizontal line (LH2) in the second horizontal driver stage (HD2) according to the specifications of the control device (μC).

Control unit A sets the frequency and pulse duration of the third horizontal shield current (ISH3) for the third horizontal shield line (SH3) in the second horizontal driver stage (HD2) and that in the third horizontal driver stage (HD3) according to the specifications of the control device (μC).

Control unit A sets the frequency and pulse duration of the third horizontal current (IH3) for the third horizontal line (LH3) in the third horizontal driver stage (HD3) according to the specifications of the control device (μC).

Control unit A sets the frequency and pulse duration of the fourth horizontal shield current (ISH4) for the fourth horizontal shield line (SH4) in the third horizontal driver stage (HD2) and in the fourth horizontal driver stage (HD4), which is only indicated for lack of space, according to the specifications of the control device (μC).

The control unit A sets the frequency and the pulse duration of the first vertical shield current (ISV1) for the first vertical shield line (SV1) in the first vertical driver stage (HV1) according to the specifications of the control device (μC).

The control unit A sets the frequency and the pulse duration of the first vertical current (IV1) for the first vertical line (LV1) in the first vertical driver stage (VD)) according to the specifications of the control device (μC).

Synchronized by control unit A, these driver stages (VD1, HD1, HD2, HD3, HD4) feed their current into the lines (SV1, LV1, SV2, SH1, LH1, SH2, LH2, SH3, LH3, SH4) in a fixed phase ratio with respect to a common synchronization time.

Previously, a control unit B configures a first horizontal receiver stage (HS1) in such a way as to extract the currents injected by the first horizontal driver stage (HD1) on the other side of the lines.

Previously, the control unit B configures a second horizontal receiver stage (HS2) in such a way as to extract the currents injected by the second horizontal driver stage (HD2) on the other side of the lines.

Prior to this, the control unit B configures a third horizontal receiver stage (HS3) in such a way as to extract the currents injected by the third horizontal driver stage (HD3) on the other side of the lines.

Previously, the control unit B configures a first vertical receiver stage (VS1) in such a way as to extract the currents injected by the first vertical driver stage (VD1) on the other side of the lines.

Furthermore, the exemplary system of FIG. 23 has a light source (LED) for “green light” in the sense of this writing. By means of a light source driver (LEDDR) the control device (μC) can irradiate the quantum dots with the “green light”. When irradiated with this “green light”, photoelectrons are produced which can be extracted by the first horizontal receiver stage (HS1) and/or the second horizontal receiver stage (HS2) and/or the third horizontal receiver stage (HS3) and/or the first vertical receiver stage (VS1) by applying an extraction field, for example, to the connected shield lines.

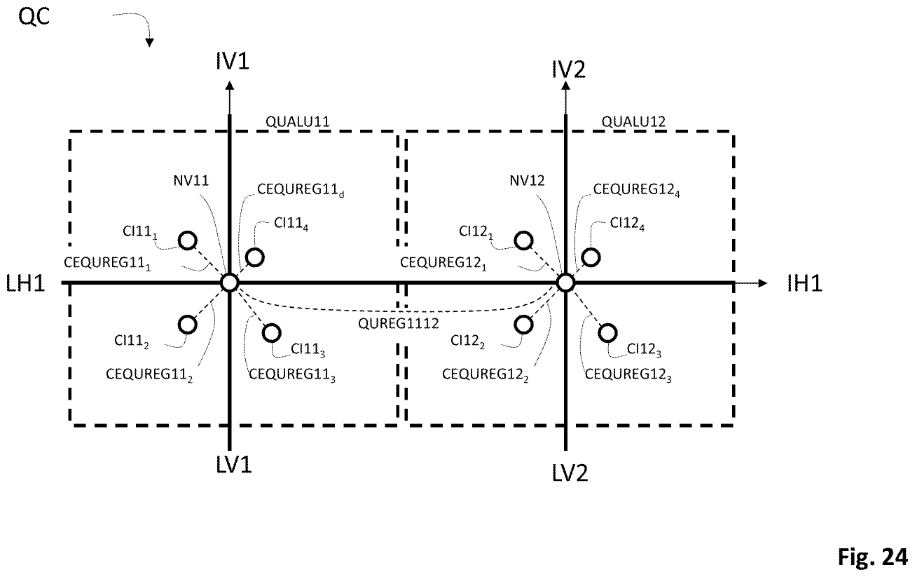

FIG. 24 shows an exemplary symbolic horizontal arrangement of a nucleus-electron-nucleus-electron quantum register (CECEQUREG) with two quantum ALUs (QUALU1, QUALU2). The symbolic representation corresponds to the representation of a quantum bus (QUBUS) with two quantum ALUs (QUALU1, QUALU2) of FIG. 20.

Since we will build the network more and more complex in the following, the indices are already chosen here to cover two-dimensional and not only linear arrangements.

A first quantum dot (NV11) of the first line and first edge of the array and a second quantum dot (NV12) of the first line and second edge of the array are arranged along the first horizontal line (LH1). The first quantum dot (NV11) and the second quantum dot (NV12) form a quantum register (QUREG1112). The first quantum dot (NV11) in the first row and first column is the connection of the first quantum ALU (QUALU11) in the first row and first column. The first quantum dot (NV11) in the first row and first column is the connection of the first quantum ALU (QUALU11) in the first row and first column. The second quantum dot (NV12) in the first row and second column is the connection of the second quantum ALU (QUALU12) in the first row and second column.

A first vertical line (LV1) is assigned to the first quantum dot (NV11) of the first column and first row.

A second vertical line (LV2) is associated with the second quantum dot (NV12) of the second column and first row.

A first nuclear quantum dot (CI111) of the first quantum ALU (QUALU1I) of the first column and first row, together with the first quantum dot (NV11) of the first row and first column, forms a first nucleus-electron quantum register (CEQUREG111) of the first quantum ALU (QUALU11) of the first column and first row.

A second nuclear quantum dot (CI112) of the first quantum ALU (QUALU11) of the first column and first row, together with the first quantum dot (NV11) of the first row and first column, forms a second nucleus-electron quantum register (CEQUREG112) of the first quantum ALU (QUALU11) of the first column and first row.

A third nuclear quantum dot (CI113) of the first quantum ALU (QUALU11) of the first column and first row, together with the first quantum dot (NV11) of the first row and first column, forms a third nucleus-electron quantum register (CEQUREG113) of the first quantum ALU (QUALU11) of the first column and first row.

A fourth nuclear quantum dot (CI114) of the first quantum ALU (QUALU11) of the first column and first row, together with the first quantum dot (NV11) of the first row and first column, forms a fourth nucleus-electron quantum register (CEQUREG114) of the first quantum ALU (QUALU11) of the first column and first row.

The fourth nucleus-electron quantum register (CEQUREG114) of the first quantum ALU (QUALU11) of the first column and first row and the third nucleus-electron quantum register (CEQUREG113) of the first quantum ALU (QUALU11) of the first column and first row and the second nucleus-electron-quantum register (CEQUREG112) of the first quantum ALU (QUALU11) of the first column and first row and the first nucleus-electron quantum register (CEQUREG111) of the first quantum ALU (QUALU11) of the first column and first row form the first quantum ALU of the first row and first column.

A first nuclear quantum dot (CI121) of the second quantum ALU (QUALU12) of the second column and first row, together with the second quantum dot (NV12) of the first row and second column, forms a first nucleus-electron quantum register (CEQUREG121) of the second quantum ALU (QUALU12) of the second column and first row.

A second nuclear quantum dot (CI122) of the second quantum ALU (QUALU12) of the second column and first row, together with the second quantum dot (NV12) of the first row and second column, forms a second nucleus-electron quantum register (CEQUREG122) of the second quantum ALU (QUALU12) of the second column and first row.

A third nuclear quantum dot (CI123) of the second quantum ALU (QUALU12) of the second column and first row, together with the second quantum dot (NV12) of the first row and second column, forms a third nucleus-electron quantum register (CEQUREG123) of the second quantum ALU (QUALU12) of the second column and first row.

A fourth nuclear quantum dot (CI124) of the second quantum ALU (QUALU12) of the second column and first row, together with the second quantum dot (NV12) of the first row and second column, forms a fourth nucleus-electron quantum register (CEQUREG124) of the second quantum ALU (QUALU12) of the second column and first row.

The fourth nucleus-electron quantum register (CEQUREG124) of the second quantum ALU (QUALU12) of the second column and first row and the third nucleus-electron quantum register (CEQUREG123) of the second quantum ALU (QUALU12) of the second column and first row and the second nucleus-electron-quantum register (CEQUREG122) of the second quantum ALU (QUALU12) of the second column and first row and the first nucleus-electron quantum register (CEQUREG121) of the second quantum ALU (QUALU12) of the second column and first row form the second quantum ALU (QUALU12) of the first row and second column.

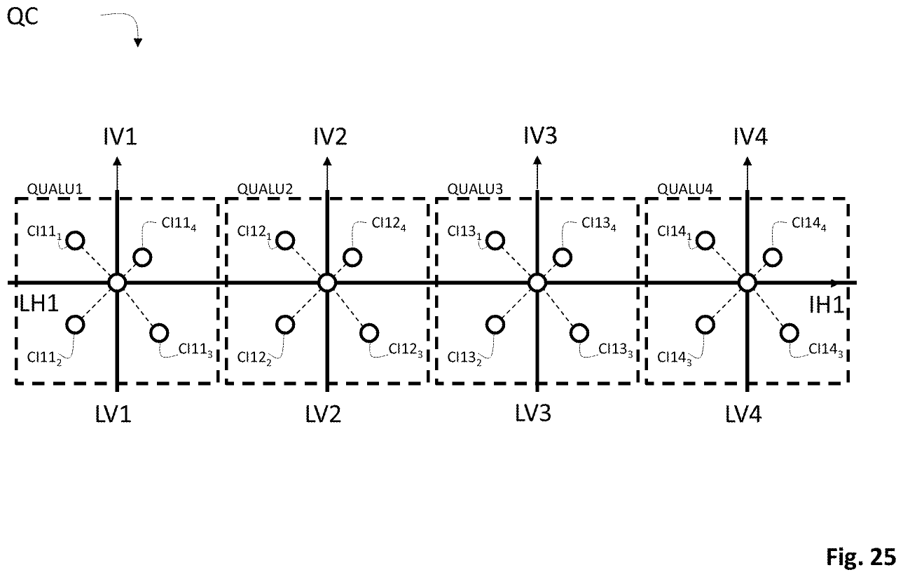

FIG. 25 shows an exemplary symbolic horizontal arrangement of a nucleus-electron-nucleus-electron quantum register (CECEQUREG) with four quantum ALUs (QUALU1, QUALU2, QUALU3, QUALU4). The quantum dots of the quantum ALUs are arranged along the common first horizontal line (LH1).

The first quantum ALU (QUALU11) of the first column and first row comprises four nuclear quantum bits (CI111, CI112, CI113, CI114). It is additionally controlled by a first vertical line (LV1).

The second quantum ALU (QUALU12) of the second column and first row comprises four nuclear quantum bits (CI121, CI122, CI123, CI124). It is additionally controlled by a second vertical line (LV2).

The third quantum ALU (QUALU13) of the third column and first row comprises four nuclear quantum bits (CI131, CI132, CI133, CI134). It is additionally controlled by a third vertical line (LV3).

The fourth quantum ALU (QUALU14) of the fourth column and first row comprises four nuclear quantum bits (CI141, CI142, CI143, CI144). It is additionally controlled by a fourth vertical line (LV4).

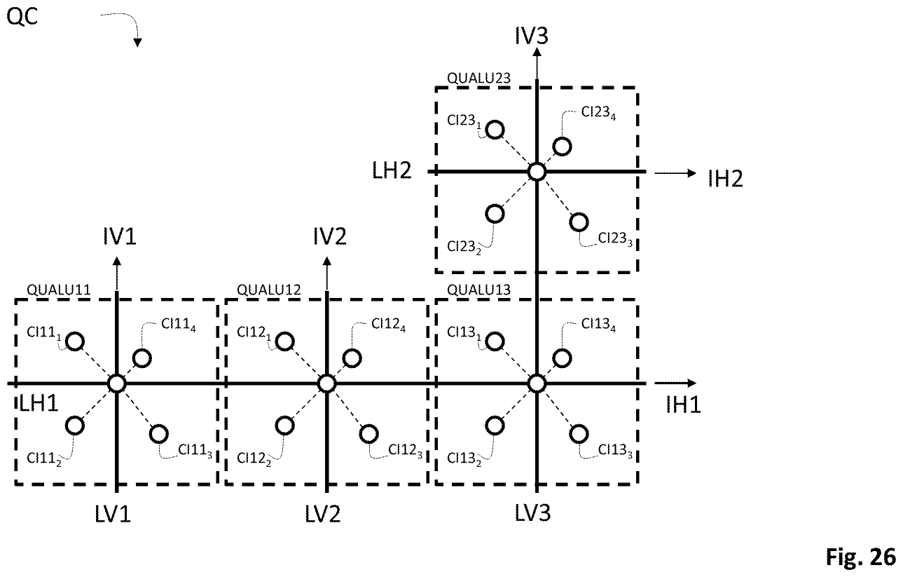

FIG. 26 shows an exemplary symbolic horizontal arrangement of a nucleus-electron-nucleus-electron quantum register (CECEQUREG) with four quantum ALUs (QUALU11, QUALU12, QUALU13, QUALU23) across corners.

The quantum dot (NV11) of the first quantum ALU (QUALU11) of the first row and first column and the quantum dot (NV12) of the second quantum ALU (QUALU12) of the first row and second column and the quantum dot (NV13) of the third quantum ALU (QUALU13) of the first row and third column are arranged along the common first horizontal line (LH1).

The quantum dot (NV13) of the third quantum ALU (QUALU13) of the first row and third column and the quantum dot (NV23) of the fourth quantum ALU (QUALU23) of the second row and third column are arranged along the common third vertical line (LV3).

The first quantum ALU (QUALU11) of the first column and first row comprises four nuclear quantum bits (CI111, CI112, CI113, CI114). It is additionally controlled by a first vertical line (LV1).

The second quantum ALU (QUALU12) of the second column and first row comprises four nuclear quantum bits (CI121, CI122, CI123, CI124). It is additionally controlled by a second vertical line (LV2).

The third quantum ALU (QUALU13) of the third column and first row comprises four nuclear quantum bits (CI131, CI132, CI133, CI134).

The fourth quantum ALU (QUALU23) of the third column and second row comprises four nuclear quantum bits (CI231, CI322, CI233, CI234). It is additionally controlled by a second horizontal line (LH2).

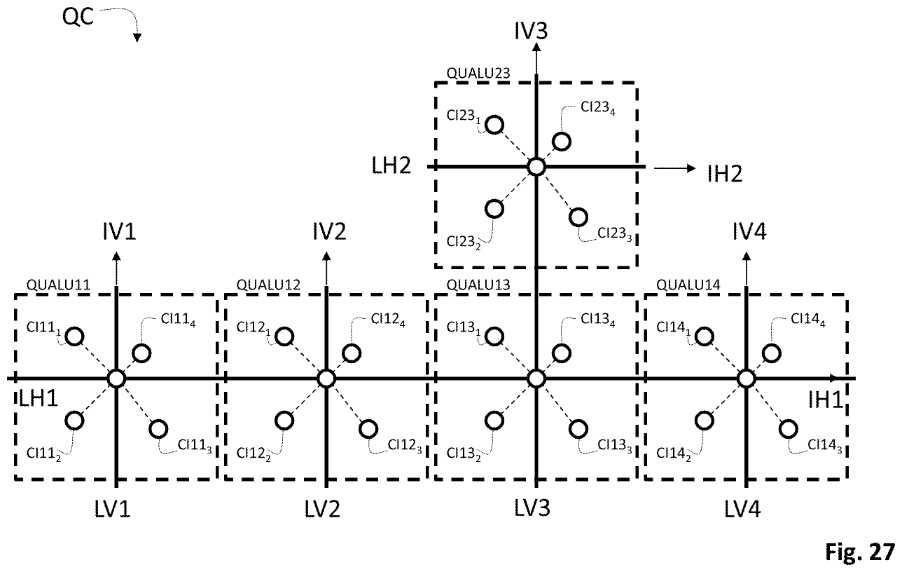

FIG. 27 shows an exemplary symbolic horizontal arrangement of a nucleus-electron-nucleus-electron quantum register (CECEQUREG) with five quantum ALUs (QUALU11, QUALU12, QUALU13, QUALU14, QUALU23) as branches.

The quantum dot (NV11) of the first quantum ALU (QUALU11) of the first row and first column and the quantum dot (NV12) of the second quantum ALU (QUALU12) of the first row and second column and the quantum dot (NV13) of the third quantum ALU (QUALU) 3) of the first row and third column and the quantum dot (NV14) of the fourth quantum ALU (QUALU14) of the first row and fourth column are arranged along the common first horizontal line (LH1).

The quantum dot (NV13) of the third quantum ALU (QUALU13) of the first row and third column and the quantum dot (NV23) of the fifth quantum ALU (QUALU23) of the second row and third column are arranged along the common third vertical line (LV3).

The first quantum ALU (QUALU11) of the first column and first row comprises four nuclear quantum bits (CI11₁, CI11₂, CI11₃, CI11₄). It is additionally controlled by a first vertical line (LV1).

The second quantum ALU (QUALU12) of the second column and first row comprises four nuclear quantum bits (CI12₁, CI12₂, CI12₃, CI12₄). It is additionally controlled by a second vertical line (LV2).

The third quantum ALU (QUALU13) of the third column and first row comprises four nuclear quantum bits (CI13₁, CI13₂, CI13₃, CI13₄).

The fourth quantum ALU (QUALU14) of the fourth column and first row comprises four nuclear quantum bits (CI14₁, CI14₂, CI14₃, CI14₄). It is additionally controlled by a fourth vertical line (LV4).

The fifth quantum ALU (QUALU23) of the third column and second row comprises four nuclear quantum bits (CI23₁, CI32₂, CI23₃, CI23₄). It is additionally controlled by a second horizontal line (LH2).

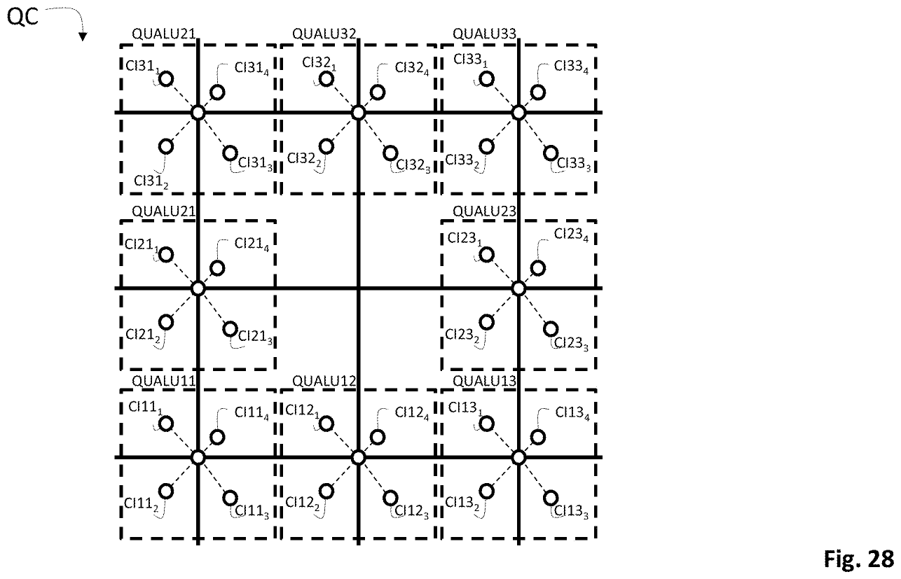

FIG. 28 shows an exemplary symbolic horizontal arrangement of a nucleus-electron-nucleus-electron quantum register (CECEQUREG) with eight quantum ALUs (QUALU11, QUALU12, QUALU13, QUALU21, QUALU23, QUALU31, QUALU32, QUALU33,) as a ring.

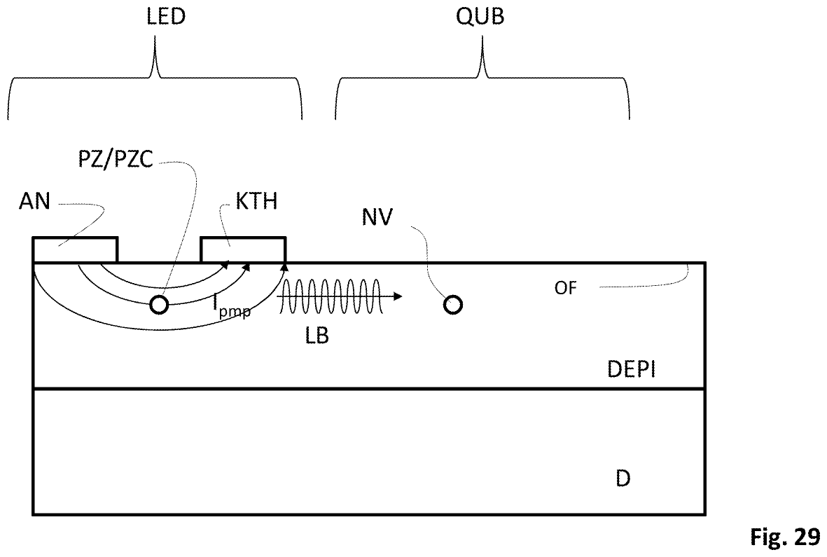

FIG. 29 shows a device that can be placed inside a substrate (D) or inside an epitaxial layer (DEP1) and thus can be used in the preceding devices, and in which a radiation source is fabricated in the material of the substrate (D) or epitaxial layer (DEP1), which is used as a light source (LED) for the “green light”.

In the example of FIG. 29, an anode contact (AN) injects an electric current into the substrate (D) or epitaxial layer (DEN). To B. Burchard “Elektronische and optoelektronische Bauelemente and Bauelementstrukturen auf Diamantbasis” (English: Electronic and optoelectronic components and component structures based on diamond), dissertation, Hagen 1994 and to the document DE 4 322 830 A1 is referred to in this context. A cathode contact (KTH) extracts this electric current again from the substrate (D) or the epitaxial layer (DEP1). This diode has the function of the light source (LED) here. A center (PZ) located in the current path within the substrate (D) or the epitaxial layer (DEP1), serves as the radiation source of this light source (LED). In the case of diamond serving as the substrate (D) or the epitaxial layer (DEP1), this center (PZ) may be, for example, H3 center in the exemplary diamond material serving as the substrate (D) or epitaxial layer (DEP1). In this example, the center (PZ) emits “green light” (LB) upon a current flow of a pump current (1 pmp) in the substrate (D) or epitaxial layer (DEP1). Thus, in the case of diamond as a substrate (D) or as an epitaxial layer (DEP1), the exemplary H3 center emits “green light” (LB) upon a current flow of a pump current (1 pmp) in the diamond as a substrate (D) or as an epitaxial layer (DEP1) from the anode contact (AN) to the cathode contact (KTH). This “green light” (LB) from the center (PZ), for example said H3 center, can then be used to drive and possibly reset one or more quantum dots (NV) in the form of paramagnetic centers. The centers (PZ) and/or the groups (PZC) of centers (PZ) can form a one- or two- or three-dimensional lattice within the substrate (D) or epitaxial layer (DEP1). In the case of a one-dimensional lattice, the centers (PZ) may, for example, be arranged in a circular shape around a common center point, in which case a quantum dot (NV) in the form of a paramagnetic center (NV) or several quantum dots (NV) is preferably located in the center point. Preferably, in one variant, the arrangement of centers PZ or groups (PZC) of centers (PZ) together with the arrangement of quantum dots (NV) in the form of paramagnetic centers (NV) forms a one-two or three-dimensional lattice, the unit cell of the lattice then comprising one or more centers (PZ) and/or one or more groups (PZC) of centers (PZ) on the one hand and one or more quantum dots (NV) in the form of paramagnetic centers (NV). It may be a translational and/or rotational lattice around a common symmetry axis or point.

Finally, it should be mentioned that the structure of FIG. 29 is suitable to interlace the center (PZ) with the quantum dot (NV). If necessary, the optical path between the center (PZ) and the quantum dot (NV) can still be supplemented with optical functional elements of photonics such as optical waveguides, lenses, filters, apertures, photonic crystals, etc. and modified if necessary. Reference is made at this point to the patent applications DE 10 2019 120 076.8, PCT/DE 2020/100 648 and DE 10 2019 121 028.3, which are still unpublished at the time of filing this paper, and the disclosure content of which forms part of this disclosure to the extent legally permissible.

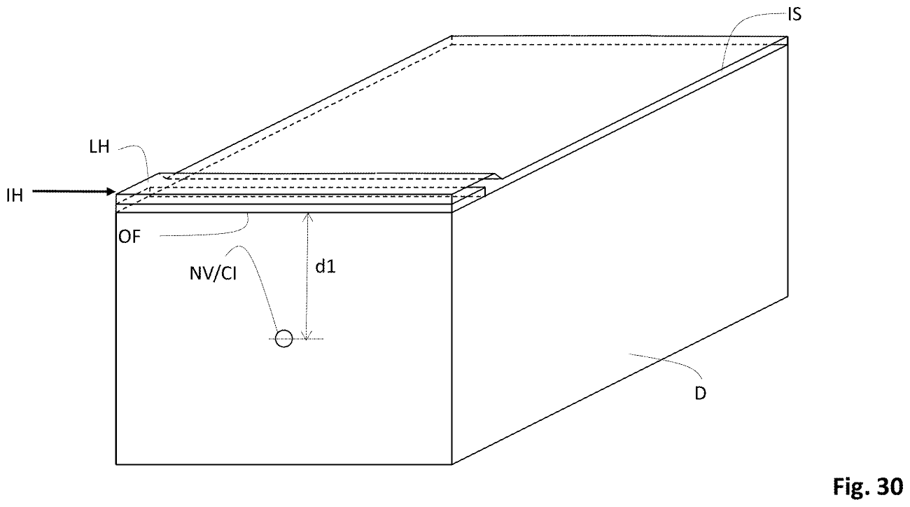

FIG. 30 shows a simplified device of FIG. 1 with a substrate (D) which is preferably diamond in the case of NV centers as paramagnetic centers (NV1) and preferably silicon in the case of G centers and preferably silicon carbide in the case of VSi centers, with one or more paramagnetic centers as quantum dots) (NV), respectively quantum dots (NV) in the substrate (D), which interact with a line (LH), which is placed and fixed on the surface (OF) of the substrate (D) and which is preferably electrically insulated from the substrate (D), for example by an insulation (IS), due to a very small first distance (d1) of preferably less than 100 nm with the magnetic field of this line (LH), when an electric current (IH) flows through the line (LH).

During the elaboration of the disclosure, it was recognized that a coil for coupling a microwave radiation and/or for setting a magnetic bias field in the form of a bias flux density B0, need not necessarily have a winding or an arc. Rather, it is the case that a line can be fabricated, for example, as a micro-structured line (LH, LV), for example, on the surface (OF) of the substrate (D) or epitaxial layer (DEP1). The paramagnetic center of a quantum dot (NV) or the nuclear quantum dot (CI) can be fabricated a few nm below the surface (OF) of the substrate (D) or the epitaxial layer (DEP1). As a result, the quantum dot (NV) or the nuclear quantum dot (CI) can be located in the near magnetic field of the line (LH, LV). Preferably, the quantum dot (NV) and/or the nuclear quantum dot (CI) are located at a first distance (r) of less than 1 μm, preferably less than 500 nm, preferably less than 200 nm, preferably less than 100 nm, preferably less than 50 nm, preferably less than 20 nm from the horizontal line (LH) exemplified herein. In the elaboration of the disclosure, it was assumed that the line (LH) is particularly preferably less than 50 nm away from the quantum dot (NV) in the form of a paramagnetic center. Due to this small distance, significant magnetic flux densities B can be generated at the location of the quantum dot (NV) in the form of the paramagnetic center (NV) or at the location of the nuclear quantum dot (CI) already with very low electric currents (IH) in the line (LH) in terms of magnitude, which influence these among other possibly relevant physical parameters.

In the example of FIG. 30, a current (IH) is applied to a line (LH). In FIG. 30, the line (LH) is preferably insulated from the substrate (D) or the epitaxial layer (DEP1). If necessary, a further insulation is used for this purpose, which is not drawn in FIG. 30 for simplification. Preferably, in the case of a substrate (D) or an epitaxial layer (DEP1) of silicon or silicon carbide, this further insulation, which is not drawn in here, is a layer of silicon dioxide, which preferably has essentially no isotopes with a nucleus magnetic moment. Preferably, in this case, it is a gate oxide. Preferably, in this case, it is ²⁸Si¹⁶O₂. Preferably, the quantum dot (NV) in the form of the paramagnetic center or the nuclear quantum dot (CI) is located directly under the lead (LH) at a distance (d1) below the surface (OF) of the substrate (D) or epitaxial layer (DEP1). In one example, the distance (d1) is preferably chosen to be very small. Preferably, the distance (d1) is smaller than 1 μm, better smaller than 500 nm, better smaller than 250 nm, better smaller than 100 nm, better smaller than 50 nm, better smaller than 25 Nm, possibly smaller than 10 nm. With decreasing distances (d1) to the surface (OF) the influence of the surface states increases. It has therefore proved useful to keep distances (d1) as close as possible to 20 nm and, if necessary, especially in the case of diamond as substrate (D), to raise the surface (OF) again by depositing an epitaxial layer (DEP1) after fabrication of the quantum dots (NV) in the form of paramagnetic centers (NV1) or the nuclear quantum dots (CI), so that the distance (d1) again exceeds such a substrate material-specific minimum distance (d1). The line (LH) is preferably fabricated on the surface (OF) of the substrate (D) or epitaxial layer (DEP1) in the manner shown in FIG. 30 and is attached to this substrate (D) or epitaxial layer (DEP1) and electrically insulated from the substrate (D) or epitaxial layer (DEP1). In particular, as described, modulations of the drive current (IH) can be used to manipulate the spin of the quantum dot (NV) in the form of the paramagnetic center or the spins of the nuclear quantum dot (CI). Preferably, the lead (LH) is firmly attached to the substrate (D) or epitaxial layer (DEP1) and typically forms a single unit with it. Preferably, the line (LH) is fabricated by electron beam lithography or similar high-resolution lithography methods on the substrate (D) or epitaxial layer (DEP1), respectively, or on the surface of an intervening further isolation not drawn here and already described, if quantum dots (NV) and/or nuclear quantum dots (CI) located under different lines (LH) are to couple with each other. If such coupling is not intended, less high-resolution lithography methods may be used. If electrostatic potentials are applied between the substrate (D) or epitaxial layer (DEP1) and this line (LH, LV) by a driver stage (HD) to drive the quantum dot (NV) to be driven as the driver stage of this line (LH), the quantum states of the quantum dot (NV) in the form of the paramagnetic center or the nuclear quantum dot (CI) below the relevant line (LH) can be manipulated and influenced. In this way, for example, a single quantum dot (NV) can be forced to leave a manipulable quantum state or at least change the resonance frequency for quantum state manipulations by locally shifting the Fermi level using an electrical voltage between the line (LH) and the substrate (D) or epitaxial layer (DEP1). In the case of NV centers in diamond, this can mean that an NV center leaves the NV⁻-state as a quantum dot (NV). By detuning the resonance frequencies when a voltage is applied, individual quantum dots (NV) can thus be excluded from manipulations or included in such manipulations in a quantum register, depending on the choice of that voltage. In this way, for example, when NV centers in diamond are used as paramagnetic centers of quantum dots (NVs), individual NV centers can be forced to change resonance frequencies by local shift of the Fermi level and thus no longer participate or be included in quantum manipulations based on electromagnetic forces with certain frequencies depending on the setting of the voltage. Also, if necessary, the charge state of the quantum dot (NV) can be influenced by manipulating the position of the Fermi level by means of the voltage between the substrate (D) or epitaxial layer (DEP1) on the one hand and the line (LH) on the other. For example, a NV center in diamond as substrate (D) or epitaxial layer (DEP1) can be brought in to or removed from the NV-state in this way by means of the choice of the electrical potential of the line (LH). By choosing the electric potential of a line located at such a small distance from a quantum dot (NV), the chain of quantum dots of an n-bit quantum register, for example, can thus be selectively interrupted. Thus, individual quantum dots or entire groups of quantum dots can be excluded from quantum manipulations. This ultimately enables targeted access to individual quantum dots without unintentional manipulation of the targeted detuned quantum dots. Thus, this procedure ultimately enables the addressing of individual quantum dots. Using this design, it is thus possible, for example, in a one-dimensional lattice of quantum dots (NV), to selectively control the participation of individual quantum dots (NV) in quantum operations by suitably adjusting a line-specific electric potential of the horizontal line (LH) in question, which is located above the individual paramagnetic center of the quantum dot (NV) on the surface (OF) of the substrate (D) or of the epitaxial layer (DEP1), on and off, thus achieving line-like resolution by selectively activating and deactivating the participation of individual paramagnetic centers of the quantum dots (NV) in quantum manipulations. Thus, we propose here a system comprising a substrate (D) optionally with an epitaxial layer (DEN), that comprises one or more first means (LH), and one or more second means (HD), to e.g. by means of static potentials of the first means (LH) with respect to the potential of the substrate (D) or the epitaxial layer (DEP1), to influence the Fermi level at the location of individual paramagnetic centers of individual quantum dots (NV) in such a way that these individual quantum dots (NV) are activated for participation in quantum state manipulations of their quantum state, or deactivated, where activated means that the respective quantum dots (NV) participate in manipulations of their quantum state, and where deactivated means that the respective quantum dots (NV) do not participate in manipulations of their quantum state. Preferably, the horizontal line (LH) is made of an optically transparent material, for example indium tin oxide (English abbreviation: ITO). From the paper Marcel Manheller, Stefan Trellenkamp, Rainer Waser, Silvia Karthäuser, “Reliable fabrication of 3 nm gaps between nanoelectrodes by electron-beam lithography”. Nanotechnology, Vol. 23, No. 12, March 2012. DOI: 10.1088/0957-4484/23/12/125302 it is known that the horizontal lines (LH) can be fabricated at a very small distance (e.g., 5 nm and smaller, e.g., 5 nm) from each other. From the paper J. Meijer. B. Burchard, M. Domhan, C. Wittmann. T. Gaebel, I. Pop. F. Jelezko, J. Wrachtrup, “Generation of single-color centers by focused nitrogen implantation” Appl. Opt. Phys. Len. 87, 261909 (2005): https://doi.org/10.1063/1.2103389 highly accurate placement of nitrogen atoms to generate NV centers is known. Measures for yield enhancement in the fabrication of the quantum dots, such as in the fabrication of NV centers in diamond, e.g., by means of sulfur implantation or n-doping of the substrate (D), are mentioned in the paper presented herein. In this respect, precise, yield-safe placement of the paramagnetic centers for fabrication of the quantum dots (NV) under the leads (LH) by means of focused ion implantation is possible without any problems. High spatial resolution fabrication of the leads (LH) is possible using electron beam lithography. The placement can be done so close to each other that two adjacent paramagnetic centers of two quantum dots (NV) under different Brent leads (LH, LH2) can interact with each other and form a quantum register based on the coupling of the electron configurations, which can be controlled via the leads (LH) using microwave signals.

By targeted deterministic and/or focused ion implantation, if necessary, of single or multiple impurity atoms into the material (MPZ) of the substrate (D) of the sensing element, a sufficiently coordinate-true fabrication of single or multiple quantum dots (NV) in the form of corresponding paramagnetic centers is possible. Refer to the paper J. Meijer, B. Burchard, M. Domhan, C. Wittman, T. Gaebel, I. Popa, F. Jelezko, J. Wrachtrup, “Generation of single-color centers by focused nitrogen implantation” Appl. Opt. Phys. Len. 87, 261909 (2005); https://doi.org/10.1063/1.2103389 is referenced here. When using a diamond as substrate (D) or epitaxial layer (DEP1), n-doping, for example with sulfur, can increase the yield of NV centers. Thus, accurate placement of quantum dots (NV) in the form of paramagnetic centers in a predictable manner spatially relative to the lead (LH) is possible and thus feasible. The line (LH) can also be made of doped silicon.

Preferably, the line (LH) is made of a material that is optically transparent at the wavelength of “green light” (LB). For example, this material of the line (LH) can be indium tin oxide, called ITO for short, or a similar, optically transparent and electrically non-conductive material.

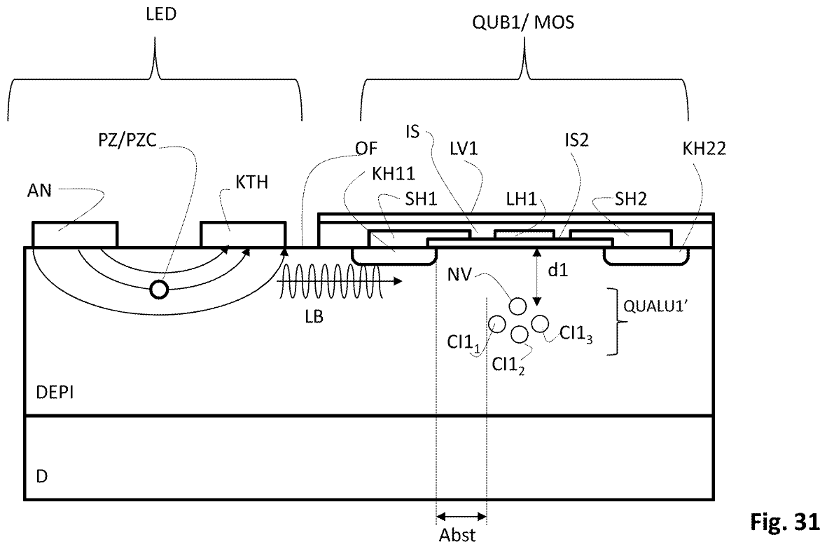

FIG. 31 shows the combination of a paramagnetic center as quantum dot (NV) in a semiconductor material of a preferably semiconducting substrate (D) resp. an epitaxial layer (DEP1), for example of silicon or silicon carbide, with a MOS transistor (MOS) in this material, whereby the horizontal shield lines (SH1, SH2) represent the source and drain contacts of the transistor (MOS), while the first horizontal line (LH1) forms the gate of the MOS transistor (MOS) and is insulated from the material of the substrate (D) or the epitaxial layer (DEP1) by the gate oxide as further insulation (IS2). The pump radiation in the form of the “green light” (LB) is generated by a center (PZ).

FIG. 31 shows a device that can be housed inside a substrate (D) or inside an epitaxial layer (DEP1) and thus can be used in the preceding devices, and in which a light source (LED) is fabricated in the material of the substrate (D) or epitaxial layer (DEP1), which is used as a light source (LED) for the “green light”.

In the example of FIG. 31, an anode contact (AN) injects an electric current in to the substrate (D) or epitaxial layer (DEP1). To B. Burchard “Elektronische and optoelektronische Bauelemente and Bauelementstrukturen auf Diamantbasis” (Electronic and optoelectronic components and component structures based on diamond), dissertation, Hagen 1994 and to the document DE 4 322 830 A1 is referred to in this context. A cathode contact (KTH) extracts this electric current again from the substrate (D) or the epitaxial layer (DEP1). This diode has the function of the light source (LED) here. A center (PZ) located in the current path within the substrate (D) or the epitaxial layer (DEP1), serves as the radiation source of this light source (LED). In the case of diamond serving as the substrate (D) or the epitaxial layer (DEP1), this center (PZ) may be, for example, H3 center in the exemplary diamond material serving as the substrate (D) or epitaxial layer (DEP1). In this example, the center (PZ) emits “green light” (LB) upon a current flow of a pump current (1 pmp) in the substrate (D) or epitaxial layer (DEP1). Thus, in the case of diamond as a substrate (D) or as an epitaxial layer (DEP1), the exemplary H3 center emits “green light” (LB) upon a current flow of a pump current (1 pmp) in the diamond as a substrate (D) or as an epitaxial layer (DEP1) from the anode contact (AN) to the cathode contact (KTH). This “green light” (LB) from the center (PZ), for example said H3 center, can then be used to drive and possibly reset one or more quantum dots (NV) in the form of paramagnetic centers (NV). The centers (PZ) and/or the groups (PZC) of centers (PZ) can form a one- or two- or three-dimensional lattice within the substrate (D) or epitaxial layer (DEP1). In the case of a one-dimensional lattice, the centers (PZ) may, for example, be arranged in a circular shape around a common center point, in which case a quantum dot (NV) in the form of a paramagnetic center (NV) or several quantum dots (NV) is preferably located in the center point. Preferably, in one variant, the arrangement of centers PZ or groups (PZC) of centers (PZ) together with the arrangement of quantum dots (NV) in the form of paramagnetic centers (NV) forms a one-two or three-dimensional lattice, the unit cell of the lattice then comprising one or more centers (PZ) and/or one or more groups (PZC) of centers (PZ) on the one hand and one or more quantum dots (NV) in the form of paramagnetic centers (NV). It may be a translational and/or rotational lattice around a common symmetry axis or point.

It should be mentioned that the structure of FIG. 31 is suitable to interlace the center (PZ) with the quantum dot (NV) and possibly existing nuclear quantum bits (CI1₁, CI1₂, CI1₃). If necessary, the optical path between the center (PZ) and the quantum dot (NV) can still be supplemented with optical functional elements of photonics such as optical waveguides, lenses, filters, apertures, mirrors, photonic crystals, etc., and modified if necessary. Reference is made at this point to the patent applications DE 10 2019 120 076.8, PCT/DE 2020/100 648 and DE 10 2019 121 028.3, which are still unpublished at the time of filing this paper, and the disclosure content of which forms part of this disclosure to the extent legally permissible.

The structure of FIG. 31 is very similar to that of FIG. 29, but in the example of FIG. 31, the quantum dot (NV) is now part of an exemplary quantum ALU (QUALU1′). In the example of FIG. 31, the quantum ALU (QUALU1′) comprises exemplary the quantum dot (NV) and a first nuclear quantum dot (CI11) and a second nuclear quantum dot (CI12) and a third nuclear quantum dot (CI13). The structure of the MOS transistor (MOS) with this quantum ALU (QUALU1′) corresponds exemplarily to the first quantum bit (QUB1) of FIG. 19. The first horizontal shield line (SH1) is connected to the substrate (D) or the epitaxial layer (DEP1) via the first horizontal contact (K11) of the first quantum bit (QUB1). The second horizontal shield line (SH2) is connected to the substrate (D) or the epitaxial layer (DEP1) via the second horizontal contact (K22) of the second quantum bit (QUB2). A further isolation (IS) isolates the horizontal line (LH1) from the substrate (D) or the epitaxial layer (DEP1). Preferably, the substrate (D) or epitaxial layer (DEP1) comprises essentially isotopes without nucleus magnetic moment μ at least in the quantum ALU (QUALU1′) region. Preferably, the substrate (D) or the epitaxial layer (DEP1) comprises, at least in the region of the quantum ALU (QUALU1′), essentially only one isotope type of the possible isotopes without nucleus magnetic moment μ per element.

In the case of diamond as substrate (D) or epitaxial layer (DEN), the substrate (D) or epitaxial layer (DEP1) comprises essentially only isotopes of carbon without magnetic moment μ. Preferably, these are the isotopes ¹²C and ¹⁴C. Preferably, the substrate (D) or the epitaxial layer (DEP1) comprises essentially only the isotope ¹²C.

In the case of silicon as substrate (D) or epitaxial layer (DEP1), the substrate (D) or epitaxial layer (DEP1) comprises essentially only isotopes of silicon without magnetic moment μ. Preferably, these are the isotopes ²⁸Si and ³⁰Si. Preferably, the substrate (D) or the epitaxial layer (DEP1) comprises essentially only the isotope ²⁸Si.

In the case of silicon carbide as substrate (D) or epitaxial layer (DEP1), the substrate (D) or epitaxial layer (DEP1) comprises essentially only isotopes of silicon without magnetic moment μ and only isotopes of carbon without magnetic moment μ. Preferably, these are the isotopes ²⁸Si and ³⁰Si and the isotopes ¹²C and ¹⁴C. Preferably, the substrate (D) or epitaxial layer (DEP1) comprises essentially only the isotope ²⁸Si and the isotope ¹²C.

The term “essentially” means here that the total fraction K_{IG} of isotopes with magnetic moment of an element under consideration, which is part of the substrate (D) or the epitaxial layer (DEP1), based on 100% of this element under consideration, is reduced to a fraction K_{IG′} of isotopes with magnetic moment of an element under consideration, based on 100% of this element under consideration, in comparison with the natural total fraction K_{IG} given in the above tables. Whereby this fraction K_{IG′} is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the element under consideration in the action range of the paramagnetic impurities (NV) used as quantum dots (NV) and/or the nuclear spins used as nuclear quantum dots (CI).

If the contacts (KH11, KH22) are made by doping the substrate (D) or the epitaxial layer (DEP1) with isotopes with a nucleus magnetic moment μ, the distance (spacing) between the nearest of the epitaxial layer (DEP1) with isotopes of nucleus magnetic moment μ, the distance (spacing) between the edge of a contact (KH11, KH22) closest to a component of the quantum ALU (QUALU1′) and this component of the quantum ALU (QUALU1′) should be greater than the nucleus-nucleus coupling distance between a doping atom of the contact in question (KH11, KH22) and the respective nuclear quantum dot (CI11, CI12, CI113) of the quantum ALU (QUALU1′) and greater than the nucleus-electron coupling range between a dopant atom of the respective contact (KH11, KH22) and the quantum dot (NV) of the quantum ALU (QUALU1′). Experience has shown that 500 nm is sufficient in this case. In the elaboration of the disclosure, several μm were used as distance (Abst). If, for whatever reason, this distance (Abst) has to be fallen short of, the doping of the contacts (KH11, KH22) should preferably be carried out essentially by means of isotopes which do not have a nucleus magnetic moment μ.

The term “essentially” means here that the total fraction K_{IG} of isotopes with magnetic moment of an element under consideration, which is part of the contact (KH11, KH22), related to 100% of this element under consideration, is reduced to a fraction K_{IG}′ of isotopes with magnetic moment of an element under consideration, related to 100% of this element under consideration, compared to the natural total fraction K_{IG} given in the above tables. Whereby this fraction K_{IG′} is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction KIG for the element under consideration in the action range of the paramagnetic impurities (NV) used as quantum dots (NV) and/or the nuclear spins used as nuclear quantum dots (CI).

Preferably, in the case of silicon or silicon carbide as the material of the substrate (D) or epitaxial layer (DEP1), the further insulation (IS2) is implemented as a gate oxide. A preferred fabrication method in this case is thermal oxidation. Preferably, the gate oxide is then essentially made of isotopes without magnetic moment.

The term “essentially” means here that the total fraction K_{IG} of isotopes with magnetic moment of an element under consideration, which is part of the further isolation (IS2), related to 100% of this element under consideration, is reduced to a fraction K_{IG′} of isotopes with magnetic moment of an element under consideration related to 100% of this element under consideration, compared to the natural total fraction K_{IG} given in the above tables. Whereby this fraction K_{IG}′ is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the element under consideration in the action range of the paramagnetic impurities (NV) used as quantum dots (NV) and/or the nuclear spins used as nuclear quantum dots (CI).

The line (LH1), which forms the gate of the transistor (MOS), is made of indium tin oxide (ITO), for example. However, this has the disadvantage that it is not possible without nucleus magnetic momentum. In this case, the distance (d1) between the quantum ALU (QUALU1′) or the quantum dot (NV) or the nuclear quantum dots (CI1₁, CI1₂, CI1₃) must be so large that the nucleus magnetic momentum of the corresponding isotopes of the line (LH1) cannot interact with the quantum ALU (QUALU1′) or the quantum dot (NV) or the nuclear quantum dots (CI1₁, CI1₂, CI1₃).

Another possibility for realizing the shielding lines (SH1, SH2) and the line (LH1) is, for example, the use of titanium, whereby isotopes without nucleus magnetic moment μ are preferred. Particularly preferred here are the titanium isotope ⁴⁶Ti and/or the titanium isotope ⁴⁸Ti and/or the titanium isotope ⁵⁰Ti for the production of corresponding titanium lines.

Thus, in case of corresponding spatial proximity of a shielding line (SH1, SH2) or the line (LH), the corresponding line is preferably made essentially of isotopes without nucleus magnetic moment μ. The term “essentially” means here that the total fraction K_{IG} of the isotopes with magnetic moment of an element under consideration, which is part of a line (SH1, SH2, LH1), related to 100% of this element under consideration, is reduced in comparison with the natural total fraction K_{IG} given in the above tables to a fraction K_{IG′} of the isotopes with magnetic moment of an element under consideration related to 100% of this element under consideration. Whereby this fraction K_{IG′} is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the element under consideration in the action range of the paramagnetic impurities (NV) used as quantum dots (NV) and/or the nuclear spins used as nuclear quantum dots (CI).

In the example of FIG. 31, the first vertical line (LV1) of FIG. 19 is drawn and electrically isolated by insulation (IS) from the first shield line (SH1) and the second shield line (SH2) and the first horizontal line (LH1) and thus from the substrate (D) and the epitaxial layer (DEN).

In the case of silicon carbide or silicon as substrate (D) or epitaxial layer (DEP1), for example, the further insulation (IS2) or the insulation (IS) may consist of silicon oxide. In the case, for example, the insulation (IS) and/or the further insulation (IS) preferably comprise essentially only isotopes without nucleus magnetic moment. In the case, for example, the insulation (IS) and/or the further insulation (IS) preferably comprise essentially only isotopes ²⁸Si and ³⁰Si and ¹⁶O and ¹⁸O without nucleus magnetic moment. In the case, for example, the insulation (IS) and/or the further insulation (IS) most preferably comprise essentially only isotopes ²⁸Si and ¹⁶O without nucleus magnetic moment. The term “essentially” means here that the total fraction K_{IG} of isotopes with magnetic moment of an element under consideration, which is pan of the further insulation (IS2) or of a gate oxide, relative to 100% of this element under consideration, is reduced to a fraction KK_{IG′} of isotopes with magnetic moment of an element under consideration relative to 100% of this element under consideration, compared to the natural total fraction K_{IG} given in the above tables. Whereby this fraction KK_{IG′} is smaller than 50%, better smaller than 20%, better smaller than 10%, better smaller than 5%, better smaller than 2%, better smaller than 1%, better smaller than 0.5%, better smaller than 0.2%, better smaller than 0.1% of the total natural fraction K_{IG} for the element under consideration in the action range of the paramagnetic impurities (NV) used as quantum dots (NV) and/or the nuclear spins used as nuclear quantum dots (CI).

As already explained in FIG. 1, the first horizontal line (LH1) and the first vertical line (LV1) cross over the quantum dot (NV). In the case of a semiconducting material as the material of the substrate (D) or the epitaxial layer (DEP1), for example in the case of silicon or silicon carbide as the material of the substrate (D) or the of the epitaxial layer (DEN), the quantum bit (QUB1) forms a MOS transistor (MOS) in which a quantum dot (NV) and/or a nucleus-electron quantum register (CEQUREG) and/or, as here, a quantum ALU (QUALU1′) is located in the channel region of the transistor (MOS). It is also conceivable that more than one quantum dot (NV) and/or more than one nucleus-electron quantum register (CEQUREG) and/or more than one quantum ALU (QUALU1′) is located there. Preferably, the at least two quantum dots (NV1, NV2) then form a two-bit quantum register, but the quantum dots can only be accessed by a construction of crossed lines (LH1, LV1). These crossing lines (LH1, LH2) represent a means for generating a magnetic field with a circularly rotating magnetic flux density vector B at the location of the quantum dot (NV) or at the location of the nuclear quantum dots (CI1₁, CI1₂, CI1₃), which can be used to manipulate the quantum state of the quantum dot (NV) or the nuclear quantum dots (CI1₁, CI1₂, CI1₃). The readout of the state of the quantum dot (NV) is preferably performed by irradiation with “green light” and extraction of the associated quantum state-dependent photocurrent via the contacts (K11, K22) by means of an extraction voltage (Vₑₓₜ).

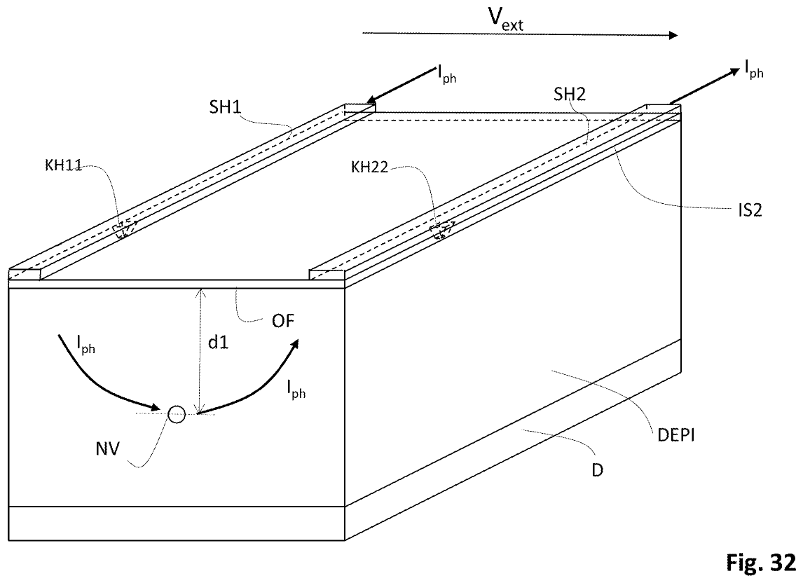

FIG. 32 shows a structure of a substrate (D) with a device for extracting the photocurrent (I_{Ph}) of a paramagnetic center as a quantum dot (NV). An extraction voltage (Von) is applied between a first shield line (SH1) and a second shield line (SH2). The first shield line (SH1) electrically contacts the substrate (D) or epitaxial layer (DEP1) by means of a first contact (KH11). The second shield line (SH2) electrically contacts the substrate (D) or the epitaxial layer (DEP1) by means of a second contact (KH22). The first shield line (SH1) is spaced apart from the second shield line (SH2). Apart from the first contact (KH11) and the second contact (KH22), the first shield line (SH1) and the second shield line (SH2) are otherwise electrically insulated from the substrate (D) and the epitaxial layer (DEP1), respectively, by a further insulation (IS2). Between the first shield line (SH1) and the second shield line (SH2), in the example here, there is a quantum dot (NV) in the form of a paramagnetic center. The quantum dot is located at a depth (d1) below the surface (OF). If the quantum dot is irradiated with “green light”, an electric photocurrent (lph), which depends on the quantum state of the quantum dot (NV), flows between the first shield line (SH1) and the second shield line (SH2) when an extraction voltage (Venn) is applied. If the substrate (D) or epitaxial layer (DEP1) is made of diamond and it is an NV center, a photocurrent (lph) flows when the NV center is in the NV-state. In this context, reference is made to the writings Petr Siyushev, Milos Nesladek. Emilie Bourgeois. Michal Gulka, Jaroslav Hruby, Takashi Yamamoto, Michael Trupke, Tokuyuki Teraji, Junichi Isoya, Fedor Jelezko, “Photoelectrical imaging and coherent spin-state readout of single nitrogen-vacancy centers in diamond” Science Feb. 15, 2019, Vol. 363, Issue 6428, pp. 728-731, DOI: 10.1126/science.aav2789 and Mathias H. Metsch, Katharina Senkalla, Benedikt Tratzmiller, Jochen Scheuer, Michael Kern. Jocelyn Achard, Alexandre Tallaire, Martin B. Plenio, Pew Siyushev, and Fedor Jelezko, “Initialization and Readout of Nuclear spins via a Negatively Charged Silicon-Vacancy Center in Diamond” Phys. Rev. Len. 122, 190503-Published 17 May 2019 pointed.

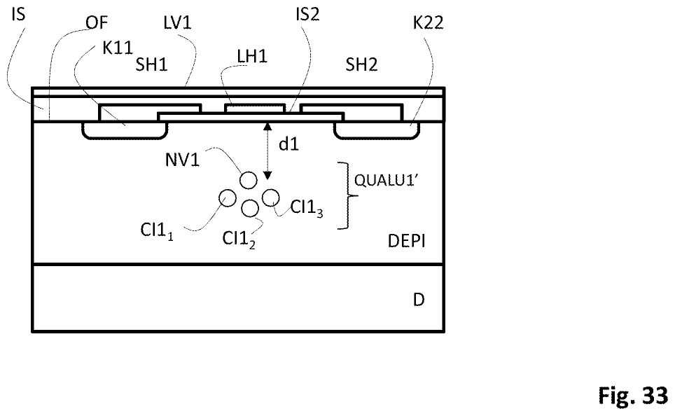

FIG. 33 shows a sub-device of FIG. 20 in the form of a quantum ALU, where the sub-device is a transistor. The transistor corresponds to that of FIG. 31.

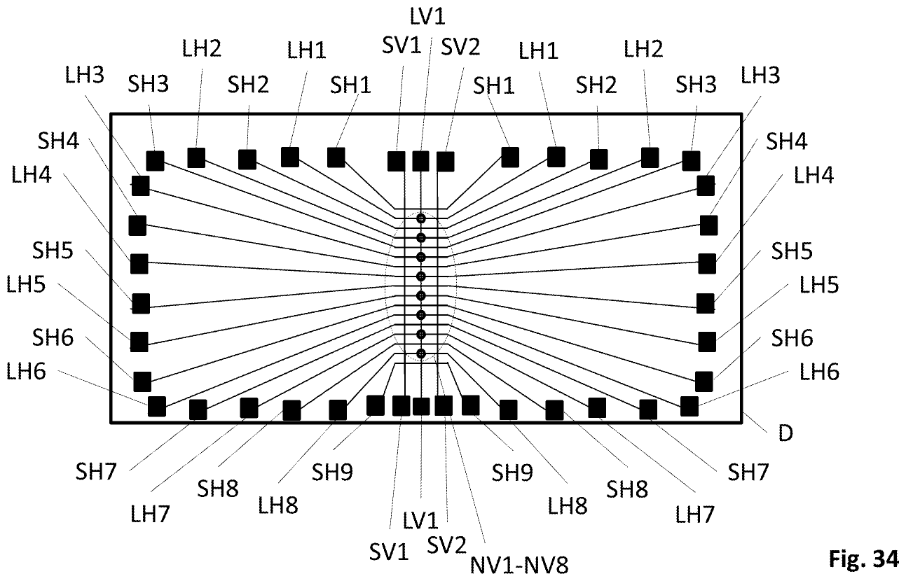

FIG. 34 shows a simplified top view of the surface of a substrate (D) with, as an example, eight quantum bits (NV1 to NV8), which are arranged and indicated as black circles equally spaced in a vertical line. For clarity, the quantum dots are marked with a dashed ellipse and given a common reference sign (NV1-NV8). Common to all eight quantum bits (QUB1 to QUB8) is that the first vertical line (LV1) passes over the respective quantum dots (NV1 to NV8) as drawn in FIG. 1. At the beginning and at the end of the first vertical line (LV1) there is a bond pad (contact area).

To the left and right of the first vertical line (LV1), the first vertical shielding line (SV1) and the second vertical shielding line (SV2) are routed parallel to the first vertical line (LV1) and electrically isolated from each other, as an example. The first vertical shielding line (SV1) and the second vertical shielding line (SV2) each start and end in a bond pad. Perpendicular to the first vertical line (LV1), for each quantum dot of the eight quantum dots (NV1 to NV8), a horizontal line associated with the respective quantum dot of the eight quantum dots (NV1 to NV8), of eight associated horizontal lines (LH1 to LH8) crosses the first vertical line (LV1) and the first vertical shielding line (SV1) and the second vertical shielding line (SH2) exactly above an associated quantum dot of the eight quantum dots (NV1 to NV8). Between each two horizontal lines, one horizontal shield line of the new horizontal shield lines (SH1 to SH9) crosses the first vertical line (LV1) and the first vertical shield line (SV1) and the second vertical shield line (SH2). The first horizontal shield line (SH1) crosses the first vertical line (LV1) and the first vertical shield line (SV1) and the second vertical shield line (SH2) above the first quantum dot (NV1). The ninth horizontal shield line (SH9) crosses the first vertical line (LV1) and the first vertical shield line (SV1) and the second vertical shield line (SH2) below the eighth quantum dot (NV8). Each of these nine horizontal shield lines (SH1 to SH9) and each of the eight horizontal lines (LH1 to LH8) starts with a bond pad and ends with a bond pad. Preferably, this structure is fabricated by electron beam lithography. Preferably, the cross-section of each of the quantum bits corresponds to, for example, FIG. 15.

In the following, it can be assumed that such a substrate (D) is incorporated in to a larger system.

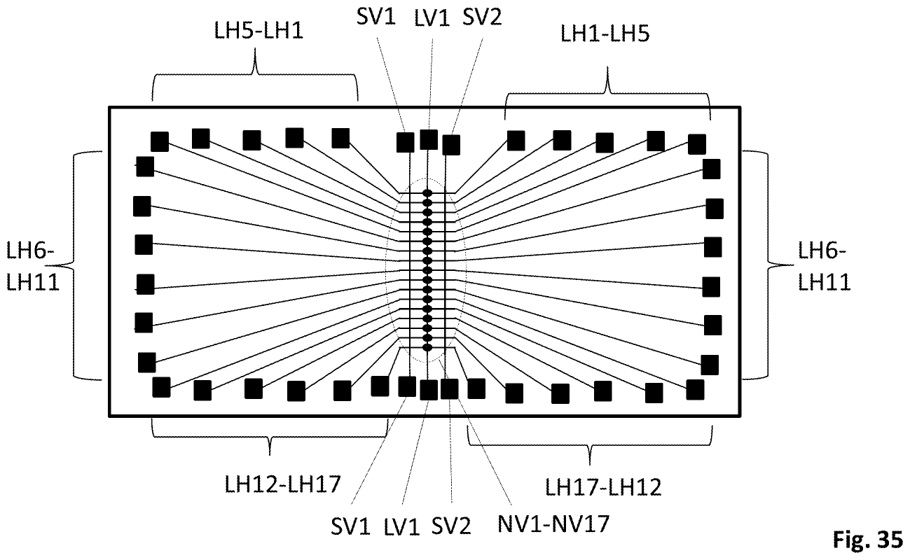

FIG. 35 corresponds to FIG. 34 with the difference that no horizontal shield lines are provided. Instead, the freed spaces are used for further quantum bits, so that seventeen quantum dots (NV1 to NV17) can be controlled with the same space requirement but greater crosstalk.

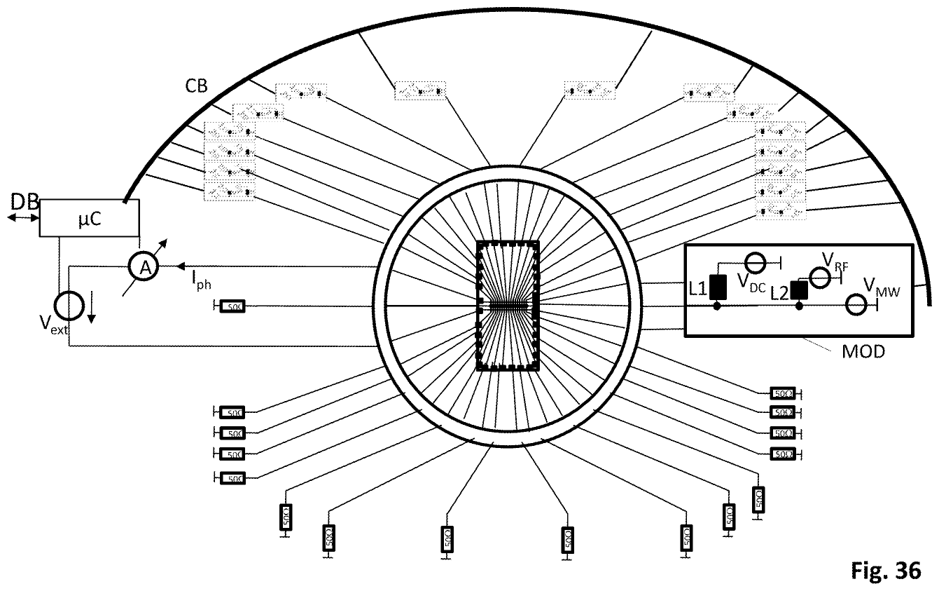

FIG. 36 shows the substrate of FIG. 35 installed in a control system similar to FIG. 23. The system is shown rotated by 90° so that the vertical lines now run horizontally and the horizontal lines now run vertically. The system is greatly simplified. Each of the lines (LV1, LH1 to LH17) is driven by a module (MOD). The modules (MOD) are controlled by the control device (μC) via a control bus (CD). On the other side of the substrate (D), the lines (LV1, LH1 to LH17) are all terminated in the example of FIG. 36 with a resistor (50Ω) corresponding to the characteristic impedance of the respective line to prevent reflections. The first vertical shield line (SH1) and the second vertical shield line contact the substrate (D) above and below the quantum dots of the substrate (D), so that by means of an extraction voltage source (Vₑₓₜ) providing an extraction voltage (Vₑₓₜ), the photoelectrons and photo-charges, respectively, can be extracted. Preferably, the substrate (D) has a backside contact that is at a defined potential. The control device (μC) controls that of an extraction voltage source (Vₑₓₜ) and an amperemeter (A) to measure this photocurrent (Iₚₕ), allowing the evaluation of the states of the quantum dots. The other modules are drawn small. An exemplary module (MOD) is drawn a little bit larger for the modules. A DC voltage source (V_{DC}) is connected to the first vertical line through a first impedance (L1) or filter circuit. The exemplary first impedance (L1) or first filter circuit ensures that the microwave and radio wave signals on the first vertical line are not modified by the DC voltage from the DC voltage source (V_{DC}). The exemplary DC voltage source (V_{DC}) feeds a DC current dependent on the terminating resistor (50Ω) in to the first vertical line (LV1) if required and can thus detune the resonance frequencies of the quantum dots.

A radio wave source feeds a radio wave frequency in to the first vertical line on demand. A second impedance (L2) or a second filter circuit preferably decouples the radio wave source and the other sources (V_{DC}, V_{MW}) of the module from the radio wave source (V_{RF}).

An undrawn third impedance or filter circuit preferentially decouples the microwave source and the other sources (V_{DC}, V_{RW}) of the module from the microwave source (V_{RF}).

Preferably, all lines are controlled from one side by means of such a module and are preferably terminated with a characteristic impedance on the other side. Preferably, all lines are designed as triplate lines with defined characteristic impedance without joints.

The control device (μC) controls the entire device and communicates via a data bus (DB) with a higher-level external computer system that controls the quantum computer system.

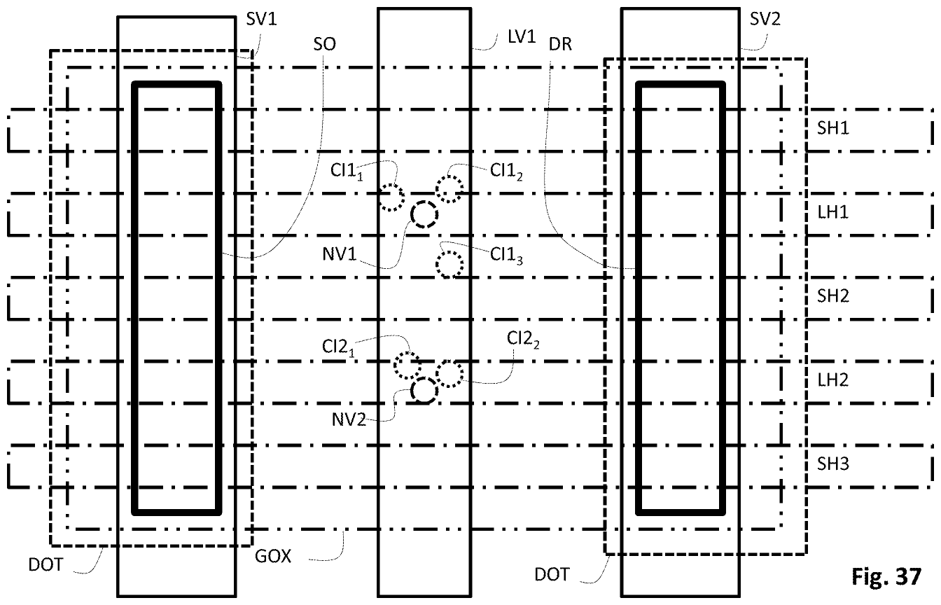

FIG. 37 shows an exemplary transistor operated as a quantum computer in a simplified schematic view from above.

As an example, we assume that the transistor is manufactured in isotopically pure ²⁸Si silicon. A fabrication in other mixed crystals of one or more elements of the IV, main group without a nucleus magnetic moment μ is also conceivable. In this respect, too, the transistor is only exemplary here.

On the left, a first doped region (DOT) is drawn to represent the source region of the transistor. The doping is typically done with isotopes of the III. The doping is typically done with isotopes of the III, main group or the V, main group of the periodic table of the elements. However, these all have a non-zero nucleus magnetic moment it, which can interfere with the quantum dots (NV1, NV2) and the nuclear quantum dots (CI1₁, CI1₂, CI1₃, CI2₁, CI2₂). Therefore, a minimum distance should be maintained between each of the source region doping and the drain region doping on the one hand and the quantum dots (NV1, NV2) and the nuclear quantum dots (CI11, CI12, CI13, CI21, CI22) on the other hand. Spacings of more than 1μ have proven to be effective. The corresponding second doped region (DOT) is drawn on the right to represent the drain region of the transistor. The source contact (SO) connects the left doped source contact region (DOT) to the first vertical shield line (SV1). The drain contact (DR) connects the right doped drain contact region (DOT) to the second vertical shield line (SV2). Between the first vertical shield line (SV1) and the second vertical shield line (SV1) is the first vertical line (LV1). In this example, the first vertical line (LV1) represents the gate of the transistor. The first vertical line is electrically insulated from the substrate (D) by the further insulation (IS2) in the form of the gate oxide. The further insulation is preferably very thin. It preferably has a thickness of less than 10 nm. Preferably, the first vertical line is made transparent to the excitation radiation, the “green light”. Preferably, the first vertical line (LV1), and thus the gate contact of the transistor, is made sufficiently thin for this purpose or is made of indium-zinc oxide or other transparent and electrically conductive materials. The transistor of FIG. 37 comprises exemplarily two quantum ALUs with two quantum dots (NV1, NV2). The first quantum ALU comprises the first quantum dot (NV1) and the first nuclear quantum dot (CI11) of the first quantum ALU and the second nuclear quantum dot (CI12) of the first quantum ALU and the third nuclear quantum dot (CI13) of the first quantum ALU. The second quantum ALU comprises the second quantum dot (NV2) and the first nuclear quantum dot (CI21) of the second quantum ALU and the second nuclear quantum dot (CI22) of the second quantum ALU.

The first horizontal line (LH1) crosses the first vertical line (LV1) in the area of the first quantum dot (NV1).

The second horizontal line (LH2) crosses the first vertical line (LV1) in the area of the second quantum dot (NV2).

The first horizontal line (LH1) also crosses the first vertical shielding line (SV1) and the second vertical shielding line (SV2). The second horizontal line (LH2) also crosses the first vertical shielding line (SH1) and the second vertical shielding line (SH2).

Above the first horizontal line (LH1) runs the first horizontal shielding line (SH1).

Between the first horizontal line (LH1) and the second horizontal line (LH2) runs the second horizontal shielding line (SH2).

Below the second horizontal line (LH2) runs the third horizontal shielding line (SH3).

The horizontal lines (SH1, SH2, SH3, LH1, LH2) are also preferably transparent to the excitation radiation, the “green light”. Preferably, the first horizontal line (LH1), the second horizontal line (LH2), the first horizontal shielding line (SH1), the second horizontal shielding line (SH2) and the third horizontal shielding line (SH2) are made sufficiently thin for this purpose or are made of indium-zinc oxide or other transparent and electrically conductive materials. The first horizontal line (LH1), the second horizontal line (LH2), the first horizontal shielding line (SH1), the second horizontal shielding line (SH2) are electrically insulated by the insulation (IS) from the first vertical line (LV1), the first vertical shielding line (SV1) and the second vertical shielding line (SV2). Preferably, the insulation (IS) is as thin as the further insulation (IS2) in the area of the transistor.

Preferably, crossing lines in the area of this transistor cross at an angle of 90°.

In the region designated GOX, the further insulation (IS2) is typically made thinner than in the rest of the region. Since the vertical distance of the first quantum dot (NV1) from the second quantum dot (NV2) should be very small in the order of 20 nm and at the same time the horizontal distance of the contact dopants (DOT) is typically in the μm range, the drawing is extremely distorted to show the basic principles.

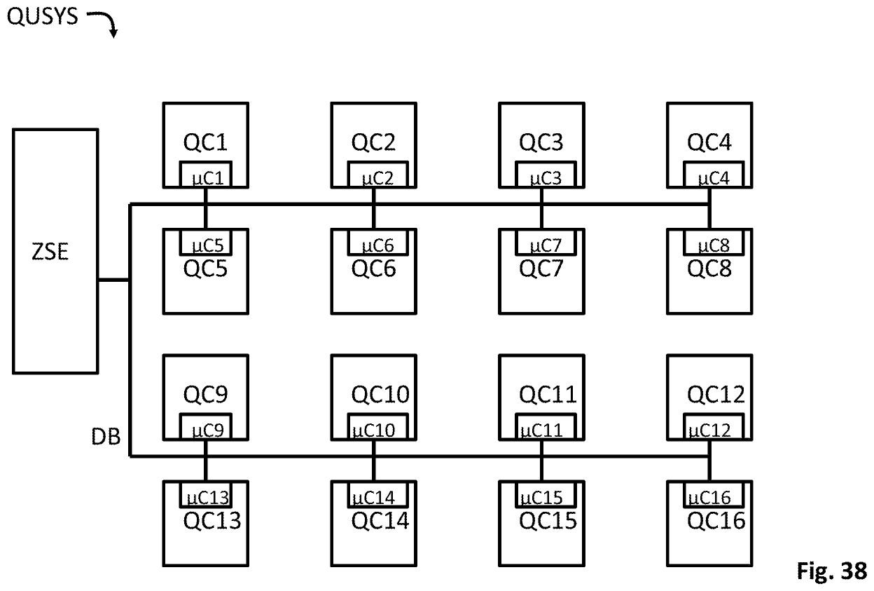

FIG. 38 shows an exemplary quantum computer system (QUSYS) with an exemplary central control unit (ZSE). In this example, the exemplary central control unit (CCU) is connected to a plurality of quantum computers (QC1 to QC16) via a preferably bidirectional data bus (DB). Preferably, such a quantum computing system comprises more than one quantum computer (QC1 to QC16). In the example of FIG. 38, each of the quantum computers (QC1 to QC16) comprises a control device (μC). In the example of FIG. 38. 16 quantum computers (QC1 to QC16) are connected to the central control device (ZSE) via the data bus (DB). The data bus (DB) can be any data transmission system. For example, it can be wired, wireless, fiber optic, optical, acoustic, radio-based. In the case of a wired system, the data bus may be all or part of a single-wire data bus, such as a UN bus, or a two-wire data bus, such as a CAN data bus. The data bus may act, in whole or in subsections, a more complex data bus with multiple conductors and/or multiple logical levels, etc. The data bus may be wholly or in subsections an Ethernet data bus. The data bus may consist entirely of one type of data bus or may be composed of different data transmission links. The data bus (DB) may be arranged in a star configuration as in the example of FIG. 38. The data bus can also be implemented wholly or in pans, for example as in a LIN data bus, as a concatenation of the bus nodes in the form of the quantum computers (QC1 to QC16), in which case each of the control devices of the relevant quantum computers of this part of the quantum computer system preferably has more than one data interface in order to be able to connect more than one data bus to the relevant quantum computer. It is conceivable that one or more quantum computers of the quantum computers (QC1 to QC16) then act as bus masters and thus as central control devices (CSEs) for subordinate sub-networks of the quantum computer system.

It is therefore further conceivable that the central control device (ZSE) of the quantum computer system (QUSYS) is the control device (μC) of a quantum computer and/or that the central control device (ZSE) of the quantum computer system (QUSYS) is a quantum computer with a control device (μC), whereby here, in the case of FIG. 38, reference is made to the “normal” computer properties of the control device (μC) which control the quantum computer system (QUSYS) as the central control device (ZSE). From the perspective of the quantum computers (QC1 to QC16), the central control device (ZSE) corresponds to an external monitoring computer of the quantum computer system (QUSYS).

The data transmission network of the quantum computer system (QSYS) may correspond in whole or in pans to a linear chain of bus nodes in the form of the quantum computers (QC1 to QC16) along pan of the data bus (DB) or along the data bus (DB), which may also be closed to form a ring (keyword token ring).

The data transmission network of the quantum computer system (QSYS) can be entirely or partially a star structure of bus nodes in the form of the quantum computers (QC1 to QC16), which are connected to one or more data lines and/or data transmission media. A star structure is present, for example, in the case of radio transmission of the data. Also, one, several or all quantum computers may be connected to the central control equipment (CSE) via a point-to-point connection. In this case, the central control unit (CSE) must have a separate data interface for each point-to-point connection.

The data transmission network of the quantum computer system (QSYS) can be designed as a tree structure, where individual quantum computers can, for example, have more than one data bus interface and serve as bus masters, i.e., central control equipment (CSE) for subnets of the data transmission network of data buses and quantum computers.

The quantum computer system (QUSYS) can thus be hierarchically structured, with the control devices (μC) of individual quantum computers being Central Control Equipment (CSE) of sub-quantum computer systems. The sub-quantum computer systems are themselves quantum computer systems (QUSYS). The central control device (ZSE) of the sub-quantum computer system is thereby preferably itself a quantum computer, which is itself preferably again part of a higher-level quantum computer system (QUSYS).

This hierarchization allows different computations to be processed in parallel in different sub-quantum computer systems, with the number of quantum computers used being chosen differently depending on the task.

Preferably, the quantum computing system thus comprises multiple computing units coupled together. Such a computing unit may use an artificial intelligence program that may be coupled to the quantum computers and/or the quantum registers and/or the quantum bits. In this regard, both the input to the artificial intelligence program may depend on the state of the quantum dots of these components of the quantum computing system, and the control of the quantum bits and quantum dots of these components of the quantum computing system may depend on the results of the artificial intelligence program. The artificial intelligence program can be executed both in the central control unit (ZSE) and in the control units (μC) of the quantum computer. In this case, only parts of the artificial intelligence program can be executed in the central control device (ZSE), while other parts of the artificial intelligence program are executed in the control devices (μC) of quantum computers within the quantum computer system. Also, in this regard, only parts of the artificial intelligence program may be executed in a control device (μC) of one quantum computer, while other parts of the artificial intelligence program are executed in other control devices (μC) of other quantum computers within the quantum computer system. This execution of an artificial intelligence program can thus be distributed across the quantum computer system or concentrated in one computer unit. In this case, the artificial intelligence program interacts with quantum dots (NV) of the quantum computers. The computer unit can therefore in reality also be a system of computer units. For example, a computing unit may comprise a thus the central control device (ZSE) of a quantum computer system (QSYS) with one or more quantum dots (NV) and/or one or more control devices (μC) of a quantum computer with one or more quantum dots (NV). More complex topologies with additional intermediate computing nodes are conceivable. The computing unit, which may also be a composite of computing units as described, executes an artificial intelligence program. Such an artificial intelligence program can be, for example, a neural network model with neural network nodes. The neural network model typically uses one or more input values and/or one or more input signals. The neural network model, typically provides one or more output values and/or one or more output signals. It is now proposed herein to complement the artificial intelligence program with a program that performs one or more of the above quantum operations on one or more quantum computers. This coupling MAY BE done EXAMPLE IN THE ONE direction by making the control of one or more quantum dots (NV), in particular by means of horizontal lines (LH) and/or vertical lines (LV), depend on one or more output values and/or one or more output signals of the neural network model. IN the other direction, states of one or more quantum dots are read out at a point in time and used as input in the artificial intelligence program, in this example the neural network model. The value of one or more input values and/or one or more input signals of the artificial intelligence program, in this example the neural network model, then depends on the state of one or more of the quantum dots (NV).

### Glossary

### Green Light

Green light is used in the technical teachings of the present disclosure for resetting the quantum dots (NV). It has been shown that in connection with NV centers as quantum dots (NV) in diamond as the substrate (D) and/or the epitaxial layer (DEP1), light with a wavelength of at most 700 nm and at least 500 nm is particularly suitable in principle. In connection with other materials of the substrate (D) and/or the epitaxial layer (DEP1), a completely different wavelength range can fulfill the same functions. In this respect, green light is to be understood here as a function definition, where the function is to be understood as equivalent to the function in the system with NV centers in diamond as quantum dots (NV). In particular, when using a NV center (NV) as a quantum dot (NV), the green light should have a wavelength in a wavelength range of 400 nm to 700 nm wavelength and/or better 450 nm to 650 nm and/or better 500 nm to 550 nm and/or better 515 nm to 540 nm. A wavelength of 532 nm wavelength is preferred. Light that is used when using quantum dot types other than NV centers in diamond to perform the same functions is also referred to as “green light”. In this respect, such examples are encompassed by claims in which “green light” is mentioned.

### Horizontal

The property word “horizontal” is used in this disclosure as part of the name of the device parts and associated quantities unless explicitly stated otherwise. This is done because the quantum bits are numbered consecutively. This makes it easier to distinguish columns (vertical) and rows (horizontal) within two-dimensional quantum bit arrays. Accordingly, a “horizontal line” is a line within such a two- or one-dimensional array that is routed along a row. The associated current is then called, for example. “horizontal line current” in an analogous way to give an example of the naming of a quantity.

### Isotopically Pure

Isotopically pure in the sense of this disclosure is a material when the concentration of isotopes other than the basic isotopes that dominate the material is so low that the technical purpose is achieved to a degree sufficient for the production and sale of products with an economically sufficient production yield. This means that disturbances emanating from such isotopic impurities do not interfere with the functional efficiency of the quantum bits, or at most only to a sufficiently small extent. In terms of diamond, this means that the diamond preferably consists essentially of ¹²C isotopes as basic isotopes, which have no magnetic moment.

### Proximity

When the present disclosure refers, for example, to a “device that is located in the proximity of the perpendicular line point (I.OTP) or at the perpendicular line point (I.OTP) for generating a circularly polarized microwave field,” the term proximity is to be understood as meaning that this device exerts or can exert an intended effect with its polarized microwave field or otherwise on the quantum dot (NV), which is located on the perpendicular line (LOT), an intended effect, where intended is to be understood, in turn, in the context of the disclosure provided herein, to mean that by the intended effect a process step can be performed in the functional steps for the intended use of a device proposed herein.

### Pure Substrate

A pure substrate in the sense of the present disclosure exists if the concentration of atoms other than the base atoms dominating the material of the substrate is so low that the technical purpose is achieved to a degree sufficient for the production and sale of products with an economically sufficient production yield. This means that disturbances emanating from such atomic impurities do not interfere with the functionality of the quantum bits, or at most only to a sufficiently small extent. In terms of diamond, this means that the diamond preferably consists essentially of C atoms and comprises no or only an insignificant number of impurity atoms. Preferably, the substrate contains as few ferromagnetic impurities as possible, such as Fe and/or Ni, since their magnetic fields can interact with the spin of the quantum dot (NV).

### Insignificant Phase Rotation

An insignificant phase rotation of the state vector of a quantum dot, in accordance with the present disclosure, is a phase rotation that can be considered insignificant or correctable for operation and operability. It may therefore be assumed to be, as a first approximation, slightly zero.

### Vertical

The property word “vertical” is used in this disclosure as part of the name of the device parts and associated quantities unless explicitly stated otherwise. This is done because the quantum bits are numbered consecutively. This makes it easier to distinguish columns (vertical) and rows (horizontal) within two-dimensional quantum bit arrays. A “vertical line” is thus a line within such a two- or one-dimensional array, which is routed along a column. The associated current is then referred to, for example, in an analogous manner as “vertical line current” to give an example of the naming of a quantity.

LIST OF REFERENCE SYMBOLS

| | |
|---|---|
| 50Ω | terminating resistor as an example of |
| | realization of a receiver stage (HS1, HS2, HS3, VS3). In the example |
| | shown in FIG. 36, the terminating resistors terminate the horizontal |
| | and vertical lines to prevent reflections. Depending on the |
| | construction of the lines, their characteristic impedance value may |
| | differ. In this case, the value of the terminating resistor should be |
| | adjusted accordingly. |
| α | crossing angle at which the vertical line (LV) and the horizontal line |
| | (LH) cross. This crossing angle preferably has an angular value of π/2. |
| α11 | angle of intersection at which the first vertical line (LV1) and the first |
| | horizontal line (LH1) cross. This crossing angle preferably has an |
| | angular value of π/2. |
| α12 | angle of intersection in which the second vertical line (LV2) and the first |
| | horizontal line (LH1) cross. This crossing angle preferably has an |
| | angular value of π/2. |
| A | amperemeter. In the example of FIG. 36, the amperemeter, which is a |
| | current sensor there, is used to obtain a reading for the photocurrent |
| | generated by the quantum dots of the quantum computer. In the |
| | example of FIG. 36, the amperemeter is controlled and read out by |
| | the control device (μC). |
| β | angle of π/2 (right angle) between perpendicular line (LOT) and surface |
| | (OF) of substrate (D) or epitaxial layer (DEPI); |
| B_{CI} | flux density vector of the circularly polarized electromagnetic wave field |
| | for manipulating the nuclear quantum dot (CI) at the location of the |
| | nuclear quantum dot (CI). In FIG. 2, the rotation of this flux density |
| | vector is drawn for better understanding. In FIG. 2, the rotation of |
| | the flux density vector is achieved by controlling the horizontal line |
| | (LH) with a horizontal current component (IH) modulated with a |
| | horizontal nucleus-nucleus radio wave frequency (f_{RWHCC}) with a |
| | horizontal modulation, and by controlling the vertical line (LV) with |
| | a vertical current component (IV) modulated with a vertical nucleus- |
| | nucleus radio wave frequency (f_{RWVCC}) with a vertical modulation |
| | shifted +/−π/2 in phase with respect to the horizontal modulation. The |
| | vertical nucleus-to-nucleus radio wave frequency (f_{RWVCC}) and the |
| | horizontal nucleus-to-nucleus radio wave frequency (f_{RWHCC}) are |
| | typically equal to each other and thus typically equal to a common |
| | nucleus-to-nucleus radio wave frequency (f_{RWCC}). |
| B_{CI1} | flux density vector of the circularly polarized electromagnetic wave field |
| | for manipulating the first nuclear quantum dot (CI1) at the location of |
| | the first nuclear quantum dot (CI1); |
| B_{CI2} | flux density vector of the circularly polarized electromagnetic wave field |
| | for manipulating the second nuclear quantum dot (CI2) at the second |
| | nuclear quantum dot (CI2) location; |
| B_{CI3} | flux density vector of the circularly polarized electromagnetic wave field |
| | for manipulating the third nuclear quantum dot (CI3) at the third |
| | nuclear quantum dot (CI3) location; |
| B_{NV} | flux density vector of the circularly polarized electromagnetic wave field |
| | for manipulation of the quantum dot (NV) at the location of the |
| | quantum dot (NV). In FIG. 1, the rotation of this flux density vector |
| | is drawn for better understanding. In FIG. 1, the rotation of the flux |
| | density vector is achieved by controlling the horizontal line (LH) with |
| | a horizontal current component (IH) modulated with a horizontal |
| | electron-electron microwave frequency (f_{MWH}) with a horizontal |
| | modulation, and by controlling the vertical line (LV) with a vertical |
| | current component (IV) modulated with a vertical electron-electron |
| | microwave frequency (f_{MWV}) with a vertical modulation shifted +/−π/2 |
| | in phase with respect to the horizontal modulation. The vertical |
| | electron-electron microwave frequency (f_{MWV}) and the horizontal |
| | electron-electron microwave frequency (f_{MWH}) are typically equal to |
| | each other and thus typically equal to a common electron-electron |
| | microwave frequency (f_{MW}). |
| B_{NV1} | flux density vector of the circularly polarized electromagnetic wave field |
| | to manipulate the first quantum dot (NV1) at the location of the first |
| | quantum dot (NV1); |
| B_{NV2} | flux density vector of the circularly polarized electromagnetic wave field |
| | to manipulate the second quantum dot (NV2) at the location of the |
| | second quantum dot (NV2); |
| B_{NV3} | flux density vector of the circularly polarized electromagnetic wave field |
| | to manipulate the third quantum dot (NV3) at the location of the third |
| | quantum dot (NV3); |
| B_{VHNV1} | first virtual horizontal magnetic flux density vector at the location of the |
| | first virtual horizontal quantum dot (VHNV1); |
| B_{VHNV2} | second virtual horizontal magnetic flux density vector at the location of |
| | the second virtual horizontal quantum dot (VHNV2); |
| B_{VVNV1} | first virtual vertical magnetic flux density vector at the location of the |
| | first virtual vertical quantum dot (VVNV1); |
| B_{VVNV2} | second virtual vertical magnetic flux density vector at the location of the |
| | second virtual vertical quantum dot (VVNV2); |
| CB | control bus; |
| CBA | control Unit A; |
| CBB | control Unit B; |
| CI | nuclear quantum dot; |
| CI1 | first nuclear quantum dot; |
| CI1₁ | first nuclear quantum dot (CI1₁) of the first quantum ALU (QUALU1); |
| CI1₂ | second nuclear quantum dot (CI1₂) of the first quantum ALU (QUALU1); |
| CI1₃ | third nuclear quantum dot (CI1₃) of the first quantum ALU (QUALU1); |
| CI11₁ | first nuclear quantum dot (CI11₁) of the quantum ALU (QUALU11) of |
| | the first column and first row; |
| CI11₂ | second nuclear quantum dot (CI11₂) of the quantum ALU (QUALU11) |
| | of the first column and first row; |
| CI11₃ | third nuclear quantum dot (CI11₃) of the quantum ALU (QUALU11) of |
| | the first column and first row; |
| CI11₄ | fourth nuclear quantum dot (CI11₄) of the quantum ALU (QUALU11) of |
| | the first column and first row; |
| CI12₁ | first nuclear quantum dot (CI12₁) of the quantum ALU (QUALU12) of |
| | the second column and first row; |
| CI12₂ | second nuclear quantum dot (CI12₂) of the quantum ALU (QUALU12) |
| | of the second column and first row; |
| CI12₃ | third nuclear quantum dot (CI12₃) of the quantum ALU (QUALU12) of |
| | the second column and first row; |
| CI12₄ | fourth nuclear quantum dot (CI12₄) of the quantum ALU (QUALU12) of |
| | the second column and first row; |
| CI13₁ | first nuclear quantum dot (CI13₁) of the quantum ALU (QUALU13)of |
| | the third column and first row; |
| CI13₂ | second nuclear quantum dot (CI13₂) of the quantum ALU (QUALU13) |
| | of the third column and first row; |
| CI13₃ | third nuclear quantum dot (CI13₃) of the quantum ALU (QUALU13) of |
| | the third column and first row; |
| CI13₄ | fourth nuclear quantum dot (CI13₄) of the quantum ALU (QUALU13) of |
| | the third column and first row; |
| CI14₁ | first nuclear quantum dot (CI14₁) of the quantum ALU (QUALU14) of |
| | the fourth column and first row; |
| CI14₂ | second nuclear quantum dot (CI14₂) of the quantum ALU (QUALU14) |
| | of the fourth column and first row; |
| CI14₃ | third nuclear quantum dot (CI14₃) of the quantum ALU (QUALU14) of |
| | the fourth column and first row; |
| CI14₄ | fourth nuclear quantum dot (CI14₄) of the quantum ALU (QUALU14) of |
| | the fourth column and first row; |
| CI2 | second nuclear quantum dot; |
| CI2₁ | first nuclear quantum dot (CI2₁) of the second quantum ALU (QUALU2); |
| CI2₂ | second nuclear quantum dot (CI2₂) of the second quantum ALU (QUALU2); |
| CI2₃ | third nuclear quantum dot (CI2₃) of the second quantum ALU (QUALU2); |
| CI21₁ | first nuclear quantum dot (CI21₁) of the quantum ALU (QUALU11) of |
| | the first column and second row; |
| CI21₂ | second nuclear quantum dot (CI21₂) of the quantum ALU (QUALU11) |
| | of the first column and second row; |
| CI21₃ | third nuclear quantum dot (CI21₃) of the quantum ALU (QUALU11) of |
| | the first column and second row; |
| CI21₄ | fourth nuclear quantum dot (CI21₄) of the quantum ALU (QUALU11) of |
| | the first column and second row; |
| CI22₁ | first nuclear quantum dot (CI22₁) of the quantum ALU (QUALU12) of |
| | the second column and second row; |
| CI22₂ | second nuclear quantum dot (CI22₂) of the quantum ALU (QUALU12) |
| | of the second column and second row; |
| CI22₃ | third nuclear quantum dot (CI22₃) of the quantum ALU (QUALU12) of |
| | the second column and second row; |
| CI22₄ | fourth nuclear quantum dot (CI22₄) of the quantum ALU (QUALU12) of |
| | the second column and second row; |
| CI23₁ | first nuclear quantum dot (CI23₁) of the quantum ALU (QUALU13) of |
| | the third column and second row; |
| CI23₂ | second nuclear quantum dot (CI23₂) of the quantum ALU (QUALU13) |
| | of the third column and second row; |
| CI23₃ | third nuclear quantum dot (CI23₃) of the quantum ALU (QUALU13) of |
| | the third column and second row; |
| CI23₄ | fourth nuclear quantum dot (CI23₄) of the quantum ALU (QUALU13) of |
| | the third column and second row; |
| CI24₁ | first nuclear quantum dot (CI24₁) of the quantum ALU (QUALU14) of |
| | the fourth column and second row; |
| CI24₂ | second nuclear quantum dot (CI24₂) of the quantum ALU (QUALU14) |
| | of the fourth column and second row; |
| CI24₃ | third nuclear quantum dot (CI24₃) of the quantum ALU (QUALU14) of |
| | the fourth column and second row; |
| CI24₄ | fourth nuclear quantum dot (CI24₄) of the quantum ALU (QUALU14) of |
| | the fourth column and second row; |
| CI3 | third nuclear quantum dot; |
| CI31₁ | first nuclear quantum dot (CI31₁) of the quantum ALU (QUALU11) of |
| | the first column and third row; |
| CI31₂ | second nuclear quantum dot (CI31₂) of the quantum ALU (QUALU11) |
| | of the first column and third row; |
| CI31₃ | third nuclear quantum dot (CI31₃) of the quantum ALU (QUALU11) of |
| | the first column and third row; |
| CI31₄ | fourth nuclear quantum dot (CI31₄) of the quantum ALU (QUALU11) of |
| | the first column and third row; |
| CI32₁ | first nuclear quantum dot (CI32₁) of the quantum ALU (QUALU12) of |
| | the second column and third row; |
| CI32₂ | second nuclear quantum dot (CI32₂) of the quantum ALU (QUALU12) |
| | of the second column and third row; |
| CI32₃ | third nuclear quantum dot (CI32₃) of the quantum ALU (QUALU12) of |
| | the second column and third row; |
| CI32₄ | fourth nuclear quantum dot (CI32₄) of the quantum ALU (QUALU12) of |
| | the second column and third row; |
| CI33₁ | first nuclear quantum dot (CI33₁) of the quantum ALU (QUALU13) of |
| | the third column and third row; |
| CI33₂ | second nuclear quantum dot (CI33₂) of the quantum ALU (QUALU13) |
| | of the third column and third row; |
| CI33₃ | third nuclear quantum dot (CI33₃) of the quantum ALU (QUALU13) of |
| | the third column and third row; |
| CI33₄ | fourth nuclear quantum dot (CI33₄) of the quantum ALU (QUALU13) of |
| | the third column and third row; |
| CI34₁ | first nuclear quantum dot (CI34₁) of the quantum ALU (QUALU14) of |
| | the fourth column and third row; |
| CI34₂ | second nuclear quantum dot (CI34₂) of the quantum ALU (QUALU14) |
| | of the fourth column and third row; |
| CI34₃ | third nuclear quantum dot (CI34₃) of the quantum ALU (QUALU14) of |
| | the fourth column and third row; |
| CI34₄ | fourth nuclear quantum dot (CI34₄) of the quantum ALU (QUALU14) of |
| | the fourth column and third row; |
| D | Substrate. The substrate can preferably be a wide band gap material. |
| | Very preferably, diamond is used. However, it is also suggested here |
| | to try other wide-band-gap materials, such as BN, GaN, etc. Also, the |
| | use of other materials made of elements of the IV. Main Group of the |
| | Periodic Table and their mixed crystals is conceivable. The use of |
| | insulators with high charge carrier mobility is also conceivable. In |
| | this case, attention must be paid to the isotopic composition, since the |
| | material must not have any magnetic nucleus momentum μ. |
| | Preferably, the substrate may be diamond, which is preferably |
| | isotopically pure. It is particularly preferred to use isotopically pure |
| | diamond comprising essentially ¹²C^{isotopes}. Preferably, the diamond |
| | contains preferably no ferromagnetic impurities such as Fe and/or Ni. |
| | Preferably, the substrate (D) and/or the epitaxial layer (DEPI) are |
| | diamond. Preferably, the substrate (D) and/or the epitaxial layer |
| | (DEPI) are of the same material. If silicon is used as the substrate |
| | material, the material of the substrate essentially preferably comprises |
| | ²⁸Si isotopes and/or ³⁰Si isotopes because they do not have nuclear |
| | spin. If silicon carbide is used as substrate material, the material of |
| | the substrate essentially preferably comprises ²⁸Si isotopes and/or ³⁰Si |
| | isotopes and ¹²C isotopes and/or ¹⁴C isotopes, as these do not exhibit |
| | nuclear spin; |
| d1 | distance of the quantum dot (NV) of the quantum bit (QUB) below |
| | the surface (OF) of the substrate (D) and/or the epitaxial layer |
| | (DEPI), which may be present, the first distance being measured |
| | along the plumb line (LOT) from the quantum dot (NV) of the |
| | quantum bit (QUB) to the surface (OF) of the substrate (D) and/or the |
| | epitaxial layer (DEPI), which may be present, and/or |
| | first distance of the first quantum dot (NV1) of the first quantum bit |
| | (QUB1) of the quantum register (QUREG) below the surface (OF) of |
| | the substrate (D) and/or the epitaxial layer (DEPI), if present, is |
| | measured, and/or epitaxial layer (DEPI) present, wherein the first |
| | distance along the plumb line (LOT) from the first quantum dot |
| | (NV1) of the first quantum bit (QUB1) of the quantum register |
| | (QUREG) to the surface (OF) of the substrate (D) and/or the epitaxial |
| | layer (DEPI), if present, is measured; |
| d2 | second distance of the second quantum dot (NV2) of the second |
| | quantum bit (QUB2) of the quantum register (QUREG) below the |
| | surface (OF) of the substrate (D) and/or the epitaxial layer (DEPI), if |
| | any epitaxial layer (DEPI) present, wherein the first distance along |
| | the plumb line (LOT) from the second quantum dot (NV2) of the |
| | second quantum bit (QUB1) of the quantum register (QUREG) to the |
| | surface (OF) of the substrate (D) and/or the epitaxial layer (DEPI), if |
| | present, is measured; |
| DEPI | epitaxial layer deposited on the substrate (D). The epitaxial layer is |
| | preferably deposited by CVD process on one of the oriented surface |
| | of a single crystal. Preferably, the epitaxial layer is isotopically pure. |
| | This allows long coherence times. Also, such a layer is preferably |
| | largely free of impurity atoms. The thickness of the layer is |
| | preferably chosen to minimize interaction between the crystal |
| | perturbations of the substrate(D), for example in the form of isotopic |
| | deviations (e.g., in the form of ¹³C isotopes in the case of diamond as |
| | substrate) or impurity atoms (e.g., Fe or Ni atoms). In the case of NV |
| | centers in diamond, inexpensive diamonds grown in molten metals |
| | can then be used as substrate (D), even though they contain large |
| | amounts of iron atoms (Fe atoms). Provided the quality of the |
| | substrate (D) is sufficient, the epitaxial layer can be dispensed with. |
| | For this reason, this epitaxial layer (DEPI) is not shown in all figures. |
| | Preferably, at least in the region of the quantum dots (NV) or in the |
| | region of the nuclear quantum dots (CI), the epitaxial layer comprises |
| | essentially no isotopes with nucleus magnetic moment. In the case of |
| | diamond as an epitaxial layer, the epitaxial layer preferably comprises |
| | essentially ¹²C isotopes and ¹⁴C isotopes. In the case of diamond as an |
| | epitaxial layer, the epitaxial layer even more preferably comprises |
| | essentially only ¹²C isotopes. In the case of silicon as an epitaxial |
| | layer, the epitaxial layer preferably comprises essentially ²⁸Si |
| | isotopes and ³⁰Si isotopes. In the case of silicon as an epitaxial layer, |
| | the epitaxial layer even more preferably comprises essentially only |
| | ²⁸Si isotopes. In the case of silicon carbide as an epitaxial layer, the |
| | epitaxial layer preferably comprises essentially ²⁸Si isotopes and ³⁰Si |
| | isotopes or ¹²C isotopes and ¹⁴C isotopes. In the case of silicon as the |
| | epitaxial layer, the epitaxial layer even more preferably comprises |
| | essentially only ²⁸Si isotopes or ¹²C isotopes. |
| DOT | Range of contact doping of the substrate (D) or epitaxial layer (DEPI); |
| DR | Drain. The drain in FIG. 37 corresponds to contact KV12 in FIG. 19. |
| f_{MW} | common electron-electron microwave frequency (f_{MW}); |
| f_{MW1} | first electron1-electron1 microwave resonance frequency (f_{MW1}); |
| nucleusf_{MWCF1} | first nucleus-electron microwave resonance frequency; |
| f_{MWCE2} | second nucleus-electron microwave resonance frequency; |
| f_{MWCE1, 1} | first nucleus-electron microwave resonance frequency for the first |
| | quantum ALU (QUALU1) to drive the first nuclear quantum dot |
| | (CI21) of the first quantum ALU (QUALU1); |
| f_{MWCE2, 1} | second nucleus-electron microwave resonance frequency for the first |
| | quantum ALU (QUALU1) to drive the second nuclear quantum dot |
| | (CI22) of the first quantum ALU (QUALU1); |
| f_{MWCE3, 1} | third nucleus-electron microwave resonance frequency for the first |
| | quantum ALU (QUALU1) to drive the third nuclear quantum dot |
| | (CI23) of the first quantum ALU (QUALU1); |
| f_{MWCE1, 2} | first nucleus-electron microwave resonance frequency for the second |
| | quantum ALU (QUALU2) to drive the first nuclear quantum dot |
| | (CI21) of the second quantum ALU (QUALU2); |
| f_{MWCE2, 2} | second nucleus-electron microwave resonance frequency for the second |
| | quantum ALU (QUALU2) to drive the second nuclear quantum dot |
| | (CI22) of the second quantum ALU (QUALU2); |
| f_{MWCE3, 2} | third nucleus-electron microwave resonance frequency for the |
| | second quantum ALU (QUALU2) to drive the third nuclear quantum |
| | dot (CI23) of the second quantum ALU (QUALU2); |
| f_{MW2} | second electron1-electron1 microwave resonance frequency (f_{MW2}); |
| f_{MWH} | horizontal electron-electron microwave frequency. The vertical electron- |
| | electron microwave frequency (f_{MWV}) and the horizontal electron- |
| | electron microwave frequency (f_{MWH}) are typically equal to each |
| | other and thus typically equal to a common electron-electron |
| | microwave frequency (f_{MW}); |
| f_{MWH1} | first horizontal electron-electron microwave frequency. The first vertical |
| | electron-electron microwave frequency (f_{MWV1}) and the first |
| | horizontal electron-electron microwave frequency (f_{MWH1}) are |
| | typically equal to each other and thus typically equal to a common |
| | first electron-electron microwave frequency (f_{MW1}); |
| f_{MWHE1, 1} | first horizontal electron1-electron2 microwave resonance frequency; |
| f_{MWHE1, 2} | second horizontal electron1-electron2 microwave resonance frequency; |
| f_{MWV} | vertical electron-electron microwave frequency. The vertical electron- |
| | electron microwave frequency (f_{MWV}) and the horizontal electron- |
| | electron microwave frequency (f_{MWH}) are typically equal to each |
| | other and thus typically equal to a common electron-electron |
| | microwave frequency (f_{MW}); |
| f_{MWV1} | first vertical electron-electron microwave frequency. The first vertical |
| | microwave frequency (f_{MWV1}) and the first horizontal electron- |
| | electron microwave frequency (f_{MWH1}) are typically equal to each |
| | other and thus typically equal to a common first electron-electron |
| | microwave frequency (f_{MW1}); |
| f_{MWVEE1} | first vertical electron1-electron2 microwave resonance frequency; |
| f_{RWCC} | nucleus-to-nucleus radio wave frequency. The horizontal nucleus-to- |
| | nucleus radio wave frequency (f_{RWHCC}) and the vertical nucleus-to- |
| | nucleus radio wave frequency (f_{RWVCC}) are typically equal to each |
| | other and equal to a common nucleus-to-nucleus radio wave |
| | frequency (f_{RWCC}); |
| f_{RWHCC} | horizontal nucleus -to- nucleus radio wave frequency. The horizontal |
| | nucleus-to-nucleus radio wave frequency (f_{RWHCC}) and the vertical |
| | nucleus-to-nucleus radio wave frequency (f_{RWVCC}) are typically equal |
| | to each other and equal to a common nucleus-to-nucleus radio wave |
| | frequency (f_{RWCC}); |
| f_{RWVCC} | vertical nucleus-to-nucleus radio wave frequency. The horizontal |
| | nucleus-to-nucleus radio wave frequency (f_{RWHCC}) and the vertical |
| | nucleus-to-nucleus radio wave frequency (f_{RWVCC}) are typically equal |
| | to each other and equal to a common nucleus-to-nucleus radio wave |
| | frequency (f_{RWCC}); |
| f_{RWEC1, 1} | first electron-nucleus radio wave resonance frequency for the first |
| | quantum ALU (QUALU1) to drive the first nuclear quantum dot |
| | (CI11) of the first quantum ALU (QUALU1); |
| f_{RWEC2, 1} | second electron-nucleus radio wave resonance frequency for the first |
| | quantum ALU (QUALU1) to drive the second nuclear quantum dot |
| | (CI12) of the first quantum ALU (QUALU1); |
| f_{RWEC3, 1} | third electron-nucleus radio wave resonance frequency for the first |
| | quantum ALU (QUALU1) to drive the third nuclear quantum dot |
| | (CI13) of the first quantum ALU (QUALU1); |
| f_{RWEC1, 2} | first electron-nucleus radio wave resonance frequency for the second |
| | quantum ALU (QUALU2) to drive the first nuclear quantum dot |
| | (CI21) of the second quantum ALU (QUALU2); |
| f_{RWEC2, 2} | second electron nucleus- radio wave resonance frequency for the second |
| | quantum ALU (QUALU2) to drive the second nuclear quantum dot |
| | (CI22) of the second quantum ALU (QUALU2); |
| f_{RWEC3, 2} | third electron nucleus radio wave resonance frequency for the second |
| | quantum ALU (QUALU2) to drive the third nuclear quantum dot |
| | (CI23) of the second quantum ALU (QUALU2); |
| GOX | region of the gate oxide window in which the further insulation (IS2) is |
| | preferably reduced to a minimum level. |
| HD | horizontal driver stage (HD) for controlling the quantum bit (QUB) to be driven; |
| HD1 | first horizontal driver stage (HD1) for controlling the first quantum bit |
| | (QUB1) to be driven; |
| HD2 | second horizontal driver stage (HD2) for controlling the second quantum |
| | bit (QUB2) to be driven; |
| HD3 | third horizontal driver stage (HD3) for controlling the third quantum bit |
| | (QUB3) to be driven; |
| HLOT1 | first further horizontal perpendicular line (HLOT1) parallel to the first |
| | perpendicular line (LOT) from the location of a first virtual horizontal |
| | quantum dot (VHNV1) to the surface (OF) of the substrate (D) and/or |
| | the epitaxial layer (DEPI), if present; |
| HLOT2 | second further horizontal perpendicular line (HLOT2) parallel to the |
| | second perpendicular line (LOT) from the location of a second virtual |
| | horizontal quantum dot (VHNV2) to the surface (OF) of the substrate |
| | (D) and/or the epitaxial layer (DEPI), if present; |
| HS1 | first horizontal receiver stage (HS1). which can form a unit with the first |
| | horizontal driver stage (HD1), for controlling the first quantum bit |
| | (QUB1) to be driven; |
| HS2 | second horizontal receiver stage (HS2), which can form a unit with the |
| | second horizontal driver stage (HD2), for controlling the second |
| | quantum bit (QUB3) to be driven; |
| HS3 | third horizontal receiver stage (HS3), which can form a unit with the |
| | third horizontal driver stage (HD3), for controlling the third quantum |
| | bit (QUB3) to be driven; |
| IH | horizontal current. The horizontal current is the electric current flowing |
| | through the horizontal line (LH). |
| IH1 | first horizontal current. The first horizontal current is the electric current |
| | flowing through the first horizontal line (LH1). |
| IH2 | second horizontal current. The second horizontal current is the electric |
| | current flowing through the second horizontal line (LH2). |
| IH3 | third horizontal current. The third horizontal current is the electric current |
| | flowing through the third horizontal line (LH3). |
| IH4 | fourth horizontal current. The fourth horizontal current is the electric |
| | current flowing through the fourth horizontal line (LH4). |
| IHG1 | first horizontal DC component; |
| IHG2 | second horizontal DC component; |
| IHi | i-th horizontal current. The i-th horizontal current is the electric current |
| | flowing through the i-th horizontal line (LHi). |
| IHm | m-th horizontal current. The m-th horizontal current is the electric |
| | current flowing through the m-th horizontal line (LHm). |
| IHM1 | first horizontal microwave current with which the first horizontal line |
| | (LH1) is energized; |
| IHM2 | second horizontal microwave current with which the second horizontal |
| | line (LH2) is energized; |
| IHQUREG | inhomogeneous quantum register; |
| Iph | photo current; |
| IS | insulation. The preferred insulation has the task of electrically insulating |
| | the horizontal line (LH) from the vertical line (LV). Preferably, it is |
| | an oxide, for example SiO₂, which is preferably sputtered on. |
| | Preferably, the insulation comprises essentially isotopes with no |
| | nucleus magnetic moment. Preferably, ²⁸Si¹⁶O₂. Reference is made |
| | here to the discussion of the term “essentially”. Preferably, the further |
| | isolation comprises essentially only one isotope type per element of |
| | isotopes without nuclear magnetic moment; |
| IS2 | further insulation. The preferred further insulation has the task of |
| | electrically insulating the horizontal line (LH) or the vertical line |
| | (LV) from the substrate (D) or the epitaxial layer (DEPI). Preferably, |
| | this is an oxide, for example SiO₂, which is preferably sputtered on. |
| | Preferably, the further isolation comprises essentially isotopes |
| | without nucleus magnetic moment. Preferably, ²⁸Si¹⁶O₂. Reference is |
| | made here to the discussion of the term “essentially”. Preferably, the |
| | further isolation comprises essentially only one isotope type per |
| | element of isotopes without nucleus magnetic moment; |
| ISH1 | first horizontal shielding current flowing through the first horizontal shielding line (SH1); |
| ISH2 | second horizontal shield current flowing through the second horizontal shield line (SH2); |
| ISH3 | third horizontal shield current flowing through the third horizontal shield line (SH3); |
| ISH4 | fourth horizontal shield current flowing through the fourth horizontal shield line (SH3); |
| ISV1 | first vertical shielding current flowing through the first vertical shielding line (SV1); |
| ISV2 | second vertical shield current flowing through the second vertical shield line (SV2); |
| ISV3 | third vertical shield current flowing through the third vertical shield line (SV3); |
| ISV4 | fourth vertical shield current flowing through the fourth vertical shield line (SV4); |
| IV | vertical current. The vertical current is the electric current flowing through the vertical line (LV); |
| IV1 | first vertical current. The first vertical current is the electric current flowing through the |
| | first vertical line (LV1); |
| IV2 | second vertical current The second vertical current is the electric current flowing through the |
| | second vertical line (LV2); |
| IV3 | third vertical current. The third vertical current is the electric current flowing through the |
| | third vertical line (LV3); |
| IV4 | fourth vertical current. The fourth vertical current is the electric current flowing through the |
| | fourth vertical line (LV4); |
| IVG1 | first vertical direct current; |
| IVG2 | second vertical DC; |
| IVj | j-th vertical current. The j-th vertical current is the electric current |
| | flowing through the j-th vertical line (LVj); |
| IVM1 | first vertical microwave current with which the first vertical line (LV1) is energized; |
| IVM2 | second vertical microwave current with which the second vertical line (LV2) is energized; |
| IVn | n-th vertical current. The n-th vertical current is the electric current |
| | flowing through the n-th vertical line (LVn); |
| ITO | indium tin oxide. This is an exemplary material for manufacturing the |
| | horizontal line (LH) and/or the vertical line (LV) and/or the shielding lines; |
| KH11 | first horizontal contact of the first quantum bit (QUB1). The first |
| | horizontal contact of the first quantum bit (QUB1) electrically |
| | connects the first horizontal shield line (SH1) in the first quantum bit |
| | (QUB1) to the substrate (D) or epitaxial layer (DEPI). Preferably, in |
| | the case of diamond as substrate material, the contact comprises or is |
| | made of titanium; |
| KH12 | first horizontal contact of the second quantum bit (QUB2). The first |
| | horizontal contact of the second quantum bit (QUB2) electrically |
| | connects the first horizontal shield line (SH1) in the second quantum |
| | bit (QUB2) to the substrate (D) or epitaxial layer (DEPI). Preferably, |
| | in the case of diamond as substrate material, the contact comprises or |
| | is made of titanium; |
| KH22 | second horizontal contact of the first quantum bit (QUB1) and first |
| | horizontal contact of the second quantum bit (QUB2). The first |
| | quantum bit (QUB1) and the second quantum bit (QUB2) share this |
| | contact in the example of FIG. 23. The contact electrically connects |
| | the second horizontal shield line (SH2) in the first quantum bit |
| | (QUB1) and the second quantum bit (QUB2), respectively, to the |
| | substrate (D) and an epitaxial layer (DEPI), respectively. Preferably, |
| | in the case of diamond as substrate material, the contact comprises or |
| | is made of titanium; |
| KH33 | second horizontal contact of the second quantum bit (QUB2) and first |
| | horizontal contact of the third quantum bit (QUB3). The second |
| | quantum bit (QUB2) and the third quantum bit (QUB3) share this |
| | contact in the example of FIG. 23. The contact electrically connects |
| | the third horizontal shield line (SH3) in the second quantum bit |
| | (QUB2) or third quantum bit (QUB3) to the substrate (D) or an |
| | epitaxial layer (DEPI). Preferably, in the case of diamond as substrate |
| | material, the contact comprises or is made of titanium; |
| KH44 | second horizontal contact of the third quantum bit (QUB3). The second |
| | horizontal contact of the third quantum bit (QUB3) electrically |
| | connects the fourth horizontal shield line (SH4) in the third quantum |
| | bit (QUB3) to the substrate (D) or an epitaxial layer (DEPI). |
| | Preferably, in the case of diamond as substrate material, the contact |
| | comprises or is made of titanium; |
| KTH | cathode contact; |
| KV11 | first vertical contact of the first quantum bit (QUB1). The first vertical |
| | contact of the first quantum bit (QUB1) electrically connects the first |
| | vertical shield line (SV1) in the first quantum bit (QUB1) to the |
| | substrate (D) or epitaxial layer (DEPI). Preferably, in the case of |
| | diamond as substrate material, the contact comprises or is made of titanium; |
| KV12 | second vertical contact of the first quantum bit (QUB1) and second |
| | quantum bit (QUB2). The first quantum bit (QUB1) and the second |
| | quantum bit (QUB2) preferentially share the second vertical contact. |
| | The second vertical contact of the first quantum bit (QUB1) and |
| | second quantum bit (QUB2) preferably electrically connects the |
| | second vertical shield line (SH2) preferably on the boundary between |
| | the first quantum bit (QUB1) and second quantum bit (QUB2) to the |
| | substrate (D) or epitaxial layer (DEPI). Preferably, in the case of |
| | diamond as substrate material, the contact is one comprising or made of titanium; |
| KV13 | third vertical contact of the second quantum bit (QUB2) and third |
| | quantum bit (QUB3). The second quantum bit (QUB2) and the third |
| | quantum bit (QUB3) preferentially share the third vertical contact. |
| | The third vertical contact of the second quantum bit (QUB2) and the |
| | third quantum bit (QUB3) preferably electrically connects the third |
| | vertical shield line (SH3) preferably on the boundary between the |
| | second quantum bit (QUB2) and the third quantum bit (QUB3) to the |
| | substrate (D) and the epitaxial layer (DEPI), respectively. Preferably, |
| | in the case of diamond as substrate material, the contact is one |
| | comprising or made of titanium; |
| KV21 | first vertical contact of the second quantum bit (QUB2). The first vertical |
| | contact of the second quantum bit (QUB2) electrically connects the |
| | first vertical shield line (SV1) in the second quantum bit (QUB2) to |
| | the substrate (D) or an epitaxial layer (DEPI). Preferably, in the case |
| | of diamond as substrate material, the contact comprises or is made of titanium; |
| KV31 | first vertical contact of the third quantum bit (QUB3). The first vertical |
| | contact of the third quantum bit (QUB3) electrically connects the first |
| | vertical shield line (SV1) in the third quantum bit (QUB13) to the |
| | substrate (D) or an epitaxial layer (DEPI). Preferably, in the case of |
| | diamond as substrate material, the contact comprises or is made of titanium; |
| KV22 | second vertical contact of the second quantum bit (QUB2). The second |
| | vertical contact of the second quantum bit (QUB2) electrically |
| | connects the second vertical shield line (SV2) in the second quantum |
| | bit (QUB2) to the substrate (D) or an epitaxial layer (DEPI). |
| | Preferably, in the case of diamond as substrate material, the contact |
| | comprises or is made of titanium; |
| KV32 | second vertical contact of the third quantum bit (QUB3). The second |
| | vertical contact of the third quantum bit (QUB3) electrically connects |
| | the second vertical shield line (SV2) in the third quantum bit (QUB3) |
| | to the substrate (D) or an epitaxial layer (DEPI). Preferably, in the |
| | case of diamond as substrate material, the contact comprises or is made of titanium; |
| L1 | first blocking inductance. The first blocking inductance is used to feed a |
| | DC voltage in to the horizontal or vertical line concerned. |
| L2 | second blocking inductance. The second blocking inductance is used to |
| | feed the relevant radio frequency signal in to the relevant horizontal |
| | or vertical line. |
| LB | green light. The green light is used in this writing to initialize the |
| | quantum dots (NV). It is pump radiation for the paramagnetic centers |
| | which form the quantum dots (NV). Reference is made to the |
| | explanations in the glossary. |
| LED | light source. The light source is preferentially used to generate the “green |
| | light” as defined in this paper. Note that only when NV centers in |
| | diamond are used as quantum dots (NV) in the substrate (D) does the |
| | “green light” actually preferentially have a color that appears green to |
| | humans. This may be considerably different for other impurity sites |
| | in other substrate crystals. Reference is made to a design possibility |
| | corresponding to FIG. 29. Therefore, this is a functional definition. |
| | Preferably, an LED or a laser or a laser LED or the like is used. |
| | Typically, relatively high illuminance levels are used. Therefore, the |
| | light source may also include optical functional elements such as |
| | filters, lenses, mirrors, apertures, photonic crystals, etc. for beam |
| | shaping and steering and filtering. |
| LEDDR | Light Source Driver; |
| LH | horizontal line; |
| LH1 | first horizontal line; |
| LH2 | second horizontal line; |
| LH3 | third horizontal line; |
| LH4 | fourth horizontal line; |
| LH5 | fifth horizontal line; |
| LH6 | sixth horizontal line; |
| LH7 | seventh horizontal line; |
| LH8 | eighth horizontal line; |
| LH9 | ninth horizontal line; |
| LH10 | tenth horizontal line; |
| LH11 | eleventh horizontal line; |
| LH12 | twelfth horizontal line; |
| LH13 | thirteenth horizontal line; |
| LH14 | fourteenth horizontal line; |
| LH15 | fifteenth horizontal line; |
| LH16 | sixteenth horizontal line; |
| LH17 | seventeenth horizontal line; |
| LHi | i-th horizontal line; |
| LHj | j-th horizontal line; |
| LHm | m-th horizontal line; |
| LHn | n-th horizontal line; |
| LOT | perpendicular line (LOT) of the solder from the location of the quantum |
| | dot (NV) to the surface (OF) of the substrate (D) and/or the epitaxial |
| | layer (DEPI), if present. It is an imaginary line; |
| LOTP | perpendicular point where the perpendicular line (LOT), which is an |
| | imaginary line, pierces the surface (OF) of the substrate (D) and/or |
| | the epitaxial layer (DEPI), if present. It is therefore an imaginary point; |
| LV | vertical line; |
| LV1 | first vertical line; |
| LV2 | second vertical line; |
| LV3 | third vertical line; |
| LV4 | fourth vertical line; |
| LVj | j-th vertical line; |
| LVn | n-th vertical line; |
| PC | control device; |
| MFC | magnetic field control; |
| MFK | magnetic field control device (actuator); |
| MFS | magnetic field sensor; |
| MOD | module for controlling the horizontal lines and the vertical lines. The |
| | module is controlled by the control device (μC) via a control bus |
| | (CB). The module provides the DC voltage for and, if necessary, the |
| | DC current for adjusting or detuning the resonance frequencies of the |
| | respective quantum dots or the respective nuclear quantum dots, or |
| | the pairs of quantum dots or the pairs of nuclear quantum dot and |
| | quantum dot. Further, the module provides the radio frequency and |
| | microwave frequency signals for controlling the same. Preferably, the |
| | output of the module has the same characteristic impedance as the |
| | relevant line being driven. If tri-plate lines are used, the module |
| | preferably provides all three lines. The module preferably includes |
| | the driver stage (HD1, HD2, HD3, VD1). If necessary, the control |
| | unit (CBA, CBB) can be fully or partially part of the module. |
| MOS | MOS transistor; |
| NV | quantum dot. The quantum dot is preferably a paramagnetic center. |
| | Typically, the paramagnetic center is an impurity center in the |
| | substrate (D) and/or in the epitaxial layer (DEPI). If the paramagnetic |
| | center is in the substrate (D) and/or in the epitaxial layer (DEPI), the |
| | paramagnetic center is preferably one of the known paramagnetic |
| | centers in diamond. For this, reference is made to the book Alexander |
| | Zaitsev, “Optical Properties of Diamond”, Springer; Edition: 2001 |
| | (Jun. 20, 2001). |
| NV1 | first quantum dot of the first quantum bit (QUB1); |
| NV2 | second quantum dot of the second quantum bit (QUB2); |
| NV3 | third quantum dot of the third quantum bit (QUB3); |
| NV4 | fourth quantum dot of the fourth quantum bit (QUB4); |
| NV5 | fifth quantum dot of the fifth quantum bit (QUB5); |
| NV6 | sixth quantum dot of the sixth quantum bit (QUB6); |
| NV7 | seventh quantum dot of the seventh quantum bit (QUB7); |
| NV8 | eighth quantum dot of the eighth quantum bit (QUB8); |
| NV9 | ninth quantum dot of the ninth quantum bit (QUB9); |
| NV10 | tenth quantum dot of the tenth quantum bit (QUB10); |
| NV11 | quantum dot of the quantum bit (QUB11) in the first vertical column and |
| | in the first horizontal row of a one-dimensional quantum register |
| | (QREG1D) or a two-dimensional quantum register (QREG2D). In |
| | FIG. 35, this reference sign exceptionally has the meaning of the |
| | eleventh quantum dot of the eleventh quantum bit. (QUB11); |
| NV12 | twelfth quantum dot of the twelfth quantum bit (QUB12); |
| NV13 | thirteenth quantum dot of the thirteenth quantum bit (QUB13); |
| NV14 | fourteenth quantum dot of the fourteenth quantum bit (QUB14); |
| NV15 | fifteenth quantum dot of the fifteenth quantum bit (QUB15); |
| NV16 | sixteenth quantum dot of the sixteenth quantum bit (QUB16); |
| NV17 | seventeenth quantum dot of the seventeenth quantum bit (QUB17); |
| OF | surface of the substrate (D) or epitaxial layer (DEPI). For purposes of this |
| | disclosure, the surface is formed by the surface of the stack of |
| | epitaxial layer (DEPI) and substrate (D). If no epitaxial layer is |
| | present, the surface is formed by the surface of the substrate (D) |
| | alone within the meaning of this disclosure. |
| φ1 | first phase angle of the Rabi oscillation of the first quantum dot (NV1) of |
| | the first quantum bit (QUB1) of the quantum register (QUREG); |
| φ2 | second phase angle of the Rabi oscillation of the second quantum dot |
| | (NV2) of the second quantum bit (QUB2) of the quantum register (QUREG); |
| QC | quantum computer; |
| QUALU | quantum ALU. For the purposes of this paper, a quantum ALU |
| | consists of at least one quantum dot (NV), preferably exactly one |
| | quantum dot (NV), and at least one nuclear quantum dot (CI), |
| | preferably multiple nuclear quantum dots; |
| QUALU1 | first quantum ALU. The exemplary first quantum ALU consists of a first |
| | quantum dot (NV1) and a first nuclear quantum dot (CI1); |
| QUALU1′ | first quantum ALU. The exemplary first quantum ALU consists of a first |
| | quantum dot (NV1) and a first nuclear quantum dot (CI1₁) of the first |
| | quantum ALU and a second nuclear quantum dot (CI1₂) of the first |
| | quantum ALU and a third nuclear quantum dot (CI1₃) of the first |
| | quantum ALU (FIG. 20); |
| QUALU11 | quantum ALU in the first row and first column; |
| QUALU12 | quantum ALU in the first row and second column; |
| QUALU13 | quantum ALU in the first row and third column; |
| QUALU21 | quantum ALU in the second row and first column; |
| QUALU22 | quantum ALU in the second row and second column; |
| QUALU23 | quantum ALU in the second row and third column; |
| QUALU31 | quantum ALU in the third row and first column; |
| QUALU32 | quantum ALU in the third row and second column; |
| QUALU33 | quantum ALU in the third row and third column; |
| QUALU2 | second quantum ALU. The exemplary second quantum ALU consists of |
| | a second quantum dot (NV2) and a second nuclear quantum dot (CI2); |
| QUALU2′ | second quantum ALU. The exemplary second quantum ALU consists of |
| | a second quantum dot (NV2) and a first nuclear quantum dot (CI2₁) |
| | of the second quantum ALU and a second nuclear quantum dot (CI2₂) |
| | of the second quantum ALU and a third nuclear quantum dot (CI2₃) |
| | of the second quantum ALU (FIG. 20); |
| QUREG | quantum register; |
| QUREG1D | one dimensional quantum register; |
| QUREG2D | two-dimensional quantum register; |
| QUB | quantum bit; |
| QUB1 | first quantum bit of the quantum register (QUREG); |
| QUB2 | second quantum bit of the quantum register (QUREG); |
| QUB3 | third quantum bit of the quantum register (QUREG); |
| QUB4 | fourth quantum bit of the quantum register (QUREG); |
| QUB5 | fifth quantum bit of the quantum register (QUREG); |
| QUB6 | sixth quantum bit of the quantum register (QUREG); |
| QUB7 | seventh quantum bit of the quantum register (QUREG); |
| QUB8 | eighth quantum bit of the quantum register (QUREG); |
| QUB9 | ninth quantum bit of the quantum register (QUREG); |
| QUB10 | tenth quantum bit of the quantum register (QUREG); |
| QUB11 | eleventh quantum bit of the quantum register (QUREG); |
| QUB12 | twelfth quantum bit of the quantum register (QUREG); |
| QUB13 | thirteenth quantum bit of the quantum register (QUREG); |
| QUB14 | fourteenth quantum bit of the quantum register (QUREG); |
| QUB15 | fifteenth quantum bit of the quantum register (QUREG); |
| QUB16 | sixteenth quantum bit of the quantum register (QUREG); |
| QUB17 | seventeenth quantum bit of the quantum register (QUREG); |
| QUBi | i-th quantum bit of the quantum register (QUREG); |
| QUBj | j-th quantum bit of the quantum register (QUREG); |
| QUBn | n-th quantum bit of the quantum register (QUREG); |
| SH1 | first horizontal shield line; |
| SH2 | second horizontal shield line; |
| SH3 | third horizontal shield line; |
| SH4 | fourth horizontal shield line; |
| SH5 | fifth horizontal shield line; |
| SH6 | sixth horizontal shield line; |
| SH7 | seventh horizontal shield line; |
| SH8 | eighth horizontal shield line; |
| SH9 | ninth horizontal shield line; |
| SHi | i-th horizontal shield line |
| SHm | m-th horizontal shield line; |
| SO | source. The source in FIG. 37 corresponds to contact KV11 in FIG. 19. |
| sp12 | distance between the first quantum dot (NV1) of the first quantum bit |
| | (QUB1) and the second quantum dot (NV2) of the second quantum bit |
| | (QUB2) of the exemplary quantum register (QUREG); |
| SV1 | first vertical shield line; |
| SV2 | second vertical shield line; |
| SV3 | third vertical shield line; |
| SV4 | fourth vertical shield line; |
| SVj | j-th vertical shield line; |
| SVn | n-th vertical shield line; |
| SW1 | first threshold; |
| VD | vertical driver stage for controlling tire quantum bit (QUB) to be driven; first |
| VD1 | vertical driver stage for controlling the first quantum bit (QUB1) to be driven; |
| VD2 | second vertical driver stage for controlling the second quantum bit (QUB2) to be driven; |
| VD3 | third vertical driver stage for controlling the third quantum bit (QUB3) to be driven; |
| V_{DC} | DC voltage source of the relevant line. This DC voltage source is used to |
| | adjust or detune the resonance frequencies of the quantum dots or |
| | nuclear quantum dots of the quantum bits or nuclear quantum bits of |
| | which the powered relevant line is a part. |
| Vₑₓₜ | extraction voltage or extraction voltage source that supplies the |
| | extraction voltage. The extraction voltage is needed to extract the |
| | photo-charge carriers of the quantum dots in case of electrical |
| | readout. In the example of FIG. 36, the extraction voltage source is |
| | controlled by the control device (μC). |
| VHNV1 | first virtual horizontal quantum dot; |
| VHNV2 | second virtual horizontal quantum dot; |
| VLOT1 | first further vertical plumb line parallel to the plumb line (LOT) from the |
| | location of a first virtual vertical nuclear quantum dot (VVCI1) |
| | and/or a first vertical quantum dot (VVNV1) to the surface (OF) of |
| | the substrate (D) and/or the epitaxial layer (DEPI), if present; |
| VLOT2 | second further vertical perpendicular line parallel to the perpendicular |
| | line (LOT) from the location of a second virtual vertical nuclear |
| | quantum dot (VVCI2) and/or a second vertical quantum dot |
| | (VVNV2) to the surface (OF) of the substrate (D) and/or the epitaxial |
| | layer (DEPI), if present; |
| VLOTP1 | first further vertical perpendicular point; |
| VLOTP2 | second additional vertical perpendicular point; |
| V_{MW} | microwave source. In the example of FIG. 36, the microwave source |
| | generates the microwave signal to drive the quantum dots, nuclear |
| | quantum dots and pairs of quantum dots and pairs of quantum dots on |
| | the one hand and nuclear quantum dots on the other hand. |
| VS1 | first vertical receiver stage, which can form a unit with the first vertical |
| | driver stage (VD1), for controlling the first quantum bit (QUB1) to be driven; |
| VS2 | second vertical receiver stage, which can form a unit with the second |
| | vertical driver stage (VD2), for controlling the second quantum bit |
| | (QUB2) to be driven; |
| VS3 | third vertical receiver stage, which can form a unit with the third vertical |
| | driver stage (VD3), for controlling the third quantum bit (QUB3) to be driven; |
| VVNV1 | first virtual vertical quantum dot; |
| VVNV2 | second virtual vertical quantum dot; |

### LIST OF CITED DOCUMENTS

### Patent Literature

DE A14322830
EN 4 322 830 A1

### Non-Patent Literature

Alexander Zaitsev, “Optical Properties of Diamond,” Springer; Edition: 2001 (Jun. 20, 2001).
Mathias H. Metsch, Katharina Senkalla, Benedikt Tratzmiller, Jochen Scheuer, Michael Kern, Jocelyn Achard, Alexandre Tallaire, Martin B. Plenio, Petr Siyushev, and Fedor Jelezko. “Initialization and Readout of Nuclear spins via a Negatively Charged Silicon-Vacancy Center in Diamond” Phys. Rev. Lett. 122, 190503—Published 17 May 2019
Unden T. Tomek N, Weggler T, Frank F. London P. Zopes J, Degen C, Raatz N. Meijer J. Watanabe H. Itoh K M. Plenio M B. Naydenov B & Jelezko F. “Coherent control of solid-state nuclear spin nano-ensemble”, npj Quantum Information 4, Article number: 39 (2018)
Häuβler S. Thiering G. Dietrich A, Wasson N, Teraji T, soya J. Iwasaki T, Hatano M. Jelezko F. Gali A. Kubanek A. “Photoluminescence excitation spectroscopy of SiV- and GeV-color center in diamond”, New Journal of Physics. Volume 19 (2017)
Petr Siyushev, Milos Nesladek, Emilie Bourgeois, Michal Gulka, Jaroslav Hruby, Takashi Yamamoto. Michael Trupke, Tokuyuki Teraji, Junichi soya, Fedor Jelezko, “Photoelectrical imaging and coherent spin-state readout of single nitrogen-vacancy centers in diamond”. Science 363, 728-731 (2019) 15 Feb. 2019
Matthias Pfender, Nabeel Aslam, Patrick Simon, Denis Antonov, Gergö Thiering, Sins Burk, Felipe F\dot{a}varo de Oliveira. Andrej Denisenko, Helmut Fedder, Jan Meijer, Jose A. Garrido, Adam Gall, Tokuyuki Teraji, Junichi (soya, Marcus William Doherty, Audrius Alkauskas, Alejandro Gallo. Andreas Grüneis, Philipp Neumann. and Jörg Wrachtrup,
“Protecting a Diamond Quantum Memory by Charge State Control”. DOI: 10.1021/acs.nanolett.7b01796, Nano Len. 2017, 17.5931-5937
Petr Siyushev, Milos Nesladek, Emilie Bourgeois. Michal Gulka, Jaroslav Hruby, Takashi Yamamoto, Michael Trupke, Tokuyuki Teraji, Junichi (soya, Fedor Jelezko, “Photoelectrical imaging and coherent spin-state readout of single nitrogen-vacancy centers in diamond”. Science 15 Feb. 2019: Vol. 363. Issue 6428, pp. 728-731. DOI: 10.1126/science.aav2789
A. M. Tyryshkin, S. Tojo, J. J. L. Morton. H. Riemann, N. V. Abrosimov, P. Becker. H.-J. Pohl. Th. Schenkel, Mi. L. W. Thewalt, K. M. Itoh, S. A. Lyon, “Electron spin coherence exceeding seconds in high-purity silicon” NatureMat. 11, 143 (2012)
D. Riedel. F. Fuchs, H. Kraus, S. Vath, A. Sperlich, V. Dyakonov, A. A. Soltamova, P. G. Baranov, V. A. Ilyin, G. V. Astakhov, “Resonant addressing and manipulation of silicon vacancy qubits in silicon carbide” arXiv:1210.0505v1 [coed-mat.mtrl-sci] 1 Oct. 2012
D. D. Berhanuddin, “Generation and characterisation of the carbon G-centre in silicon”. PhD-thesis URN: 1456601S, University of Surrey, March 2015
C. Beaufils. W. Redjem. E. Rousseau, V. Jacques, A. Yu. Kuznetsov, C. Raynaud, C. Voisin. A. Benali, T. Herzig, S. Pezzagna, J. Meijer. M. Abbarchi. and G. Cassabois, “Optical properties of an ensemble of G-centers in silicon”, Phys. Rev. B 97, 035303, Jan. 9, 2018
H. R. Vydyanath, J. S. Lorenzo, F. A. Kröger, “Defect pairing diffusion, and solubility studies in selenium-doped silicon”, Journal of Applied Physics 49.5928 (1978). HTTPS://DOI.ORG/10.1063/1.324560
Stefania Castelletto and Alberto Boretti, “Silicon carbide color centers for quantumapplications” 2020 J. Phys. Photonics2 022001.
M. K. Bhaskar, D. D. Sukachev, A. Sipahigil, R. E. Evans, M. J. Burek. C. T. Nguyen, L. J. Rogers, P. Siyushev, M. H. Metsch, H. Park. F. Jelezko, M. Loncar, and M. D. Lukin “Quantum Nonlinear Optics with a Germanium-Vacancy Color Centerin a Nanoscale Diamond Waveguide”, Phys. Rev. Lett. 118 223603, DOI: 10.1103/PhysRevLett. 118.223603, arXiv:1612.03036 [quant-ph]
D. D. Sukachev, A. Sipahigil. C. T. Nguyen, M. K. Bhaskar, R. E. Evans, F. Jelezko, M. D. Lukin “Silicon-vacancy spin qubit in diamond: a quantum memory exceeding 10 ms with single-shot state readout” 2017, Phys. Rev. Lett. 119 223602
Marina Radulaski, Matthias Widmann, Matthias Niethammer, Jingyuan Linda Zhang. Sang-Yun Lee. Torsten Rendler, Konstantinos G. Lagoudakis, Nguyen Tien Son, Erik Janzén, Takeshi Ohshima, Jörg Wrachtrup, Jelena Vučković, “Scalable Quantum Photonics with Single Color Centers in Silicon Carbide”, Nano Letters 17 (3), 1782-1786 (2017), DOI: 10.1021/acs.nanolett.6.b05102, arXiv:1612.02874
C. Wang, C. Kurtsiefer, H. Weinfurter, and B. Burchard, “Single photon emissionfrom SiV centres in diamond produced by ion implantation” J. Phys. B: At. Mol. Opt. Phys. 39(37). 2006
Björn Tegetmeyer, “Luminescence properties of SiV-centers in diamond diodes” PhD thesis, University of Freiburg. Jan. 30, 2018.
Carlo Bradac. Weibo Gao. Jacopo Fomeris, Matt Trusheim. Igor Aharonovich. “Quantum Nanophotonics with Group IV defects in Diamond”, DOI: 10.1038/s41467-020-14316-x, arXiv:1906.10992
Rasmus Høy Jensen, Erika Janitz, Yannik Fontana, Yi He, Olivier Gobron, Ilya P. Radko, Mihir Bhaskar, Ruffin Evans. Cesar Daniel Rodriguez Rosenblueth. Lilian Childress, Alexander Huck, Ulrik Lund Andersen, “Cavity-Enhanced Photon Emission from a Single Germanium-Vacancy Center in a Diamond Membrane”, arXiv: 1912.05247v3 [quant-ph] 25 May 2020
Takayuki Iwasaki, Yoshiyuki Miyamoto, Takashi Taniguchi, Petr Siyushev, Mathias H. Metsch, Fedor Jelezko, Mutsuko Natant). “Tin-Vacancy Quantum Emitters in Diamond.” Phys. Rev. Lett. 119, 253601 (2017), DOI: 10.1103/PhysRevLett.119.253601, arXiv:1708.03576 [quart-ph].
Matthew E. Trusheim, Noel H. Wan. Kevin C. Chen. Christopher J. Ciccarino, Ravishankar Sundararaman, Girish Malladi, Eric Bersin. Michael Walsh. Benjamin Lienhard, Hassaram Bakhru, Prineha Narang, Dirk Englund. “Lead-Related Quantum Emitters in Diamond” Phys. Rev. B 99, 075430 (2019), DOI: 10.1103/PhysRevB.99.075430, arXiv:1805.12202 [quant-ph]
M. Hollenbach, Y. Berencen, U. Kentsch. M. Helm. G. V. Astakhov “Engineering telecom single-photon emitters in silicon for scalable quantum photonics” Opt. Express 28, 26111 (2020), DOI: 10.1364/OE.397377, arXiv:2008.09425 [physics.app-ph]
Castelletto and Alberto Boreal, “Silicon carbide color centers for quantum applications” 2020 J. Phys. Photonics2 022001.
V. Ivády. J. Davidsson. N. T. Son. T. Ohshima, I. A. Abrikosov, A. Gali, “Identification of Si-vacancy related room-temperature qubits in 4H silicon carbide”. Phys. Rev. B, 2017, 96.161114
J. Davidsson, V. Ivády, R. Armiento, N. T. Son, A. Gali, I. A. Abrikosov, “First principles predictions of magneto-optical data forsemiconductor point defect identification: the case of divacancy defects in 4H—SiC”, New J. Phys., 2018, 20, 023035
J. Davidsson. V. Ivády, R. Armiento, T. Ohshima, N. T. Son, A. Gali. I. A. Abrikosov “Identification of divacancy and silicon vacancy qubits in 6H—SiC”. Appl. Phys. Lett. 2019, 114, 112107
S. A. Zargaleh, S. Hameau, B. Eble, F. Margaillan, H. J. von Bardeleben, J. L. Cantin, W. Gao. “Nitrogen vacancy center in cubic silicon carbide: a promising qubit in the 1.5 μm spectral range for photonic quantum networks” Phys. Rev. B, 2018, 98, 165203
S. A. Zargaleh et al “Evidence for near-infrared photoluminescence of nitrogen vacancy centers in 4H—SiC” Phys. Rev. B, 2016, 94, 060102
Junfeng Wang, Xiaoming Zhang, Yu Zhou, Ke Li. Ziyu Wang, Phani Peddibhotla, Fucai Liu, Sven Bauerdick, Axel Rudzinski, Zheng Liu, Weibo Gao, “Scalable fabrication of single silicon vacancy defect arrays in silicon carbide using focused ion beam” ACS Photonics, 2017, 4 (5), pp 1054-1059, DOI: 10.1021/acsphotonics.7b00230, arXiv:1703.04479 [quant-ph]
Marcel Manheller, Stefan Trellenkamp, Rainer Waser, Silvia Karthäuser, “Reliable fabrication of 3 nm gaps between nanoelectrodes by electron-beam lithography”. Nanotechnology, Vol. 23. No. 12. March 2012, DOI: 10.1088/0957-4484/23/12/125302
J. Meijer, B. Burchard, M. Domhan, C. Wittmann, T. Gaebel, I. Popa, F. Jelezko, J. Wrachtrup, “Generation of single-color centers by focused nitrogen implantation” Appl. Phys. Lett. 87, 261909 (2005); HTTPS://DOI.ORG/10.1063/1.2103389
Gurudev Dun. Liang Jiang, Jeronimo R. Maze, A. S. Zibrov “Quantum Register Based on Individual Electronic and Nuclear spin Qubits in Diamond”, Science, Vol. 316, 1312-1316. Jun. 1, 2007, DOI: 10.1126/science.1139831
Thiago P. Mayer Alegre, Antonio C. Torrezan de Souza. Gilberto Medeiros-Ribeiro, “Microstrip resonator for microwaves with controllable polarization,” arXiv:0708.0777v2 [cond-mat.othcr] Oct. 11, 2007.
Benjamin Smeltzer, Jean McIntyre, Lilian Childress “Robust control of individual nuclear spins in diamond”, Phys. Rev. A 80, 050302(R)-25 Nov. 2009
Pew Siyushev, Milos Nesladek, Emilie Bourgeois. Michal Gulka, Jaroslav Hruby, Takashi Yamamoto, Michael Trupke, Tokuyuki Teraji, Junichi soya, Fedor Jelezko, “Photoelectrical imaging and coherent spin-state readout of single nitrogen-vacancy centers in diamond” Science 15 Feb. 2019, Vol. 363, Issue 6428, pp. 728-731, DOI: 10.1126/science.aav2789
Timothy J. Proctor, Erika Andersson. Viv Kendon “Universal quantum computation by the unitary control of ancilla qubits and using a fixed ancilla-register interaction”, Phys. Rev. A 88, 042330-24 Oct. 2013.
Charles George Tahan. “Silicon in the quantum limit: Quantum computing and decoherence in silicon architectures” PhD Thesis, University of Wisconsin-Madison, 2005
M. Abanto, L. Davidovich, Belita Koiller, R. L. de Matos Filho, “Quantum computation with doped silicon cavities.” arXiv:0811.3865v1 [cond-mat.mes-hall] 24 Nov. 2008.
T. Schenkel, C. C. Lob. C. D. Weis, A. Schuh. A. Persaud. J. Bokor “Critical issues in the formation of quantum computer test structures by ion implantation”, NIM B, Proceedings of the 23rd International Conference on Atomic Collisions in Solids, ICACS-23, Phalaborwa, South Africa, Aug. 17-22, '08
G. D. Sanders, K. W. Kim, W. C. Holton, “A scalable solid-state quantum computer based on quantum dot pillar structures”, DOI: 10.1103/PhysRevB.61.7526 arXiv:cond-mat/0001124
Matias Urdampilkta, Anasua Chattetjee, Cheuk Chi Lo, Takashi Kobayashi, John Mansir, Sylvain Barraud, Andreas C. Betz. Sven Rogge, M. Fernando Gonzalez-Zalba, John J. L. Morton, “Charge dynamics and spin blockade in a hybrid double quantum dot in silicon”, arXiv: 1503.01049v2 [cord-mat.mes-hall] 19 Mar. 2015
Tobias Gras, Maciej Lewenstein, “Hybrid annealing using a quantum simulator coupled to a classical computer”, arXiv:1611.09729v1 [quant-ph] 29 Nov. 2016
T. F. Watson, S. G. J. Philips, E. Kawakami, D. R. Ward, P. Scarlino, M. Veldhorst, D. E. Savage. M. G. Lagally, Mark Friesen, S. N. Coppersmith, M. A. Eriksson, and L. M. K. Vandersypen, “A programmable two-qubit quantum processor in silicon”. arXiv:1708.04214v2 [cond-mat.mes-hall] 31 May 2018
C. H. Yang, R. C. C. Leon, J. C. C. Hwang. A. Saraiva. T. Tanttu, W. Huang, J. Camirand Lemyre, K. W. Chan, K. Y. Tan, F. E. Hudson, K. M. Itoh, A. Morello, M. Pioro-Ladrière. A. Laucht, A. S. Dzurakl, “Silicon quantum processor unit cell operation above one Kelvin,” arXiv:1902.09126v2 [cond-mat.mes-hall] 19 Jun. 2019
A. J. Sigillito, M. J. Gullans, L. F. Edge. M. Borselli, and J. R. Petta, “Coherent transfer of quantum information in silicon using resonant SWAP gates”, arXiv:1906.04512v1 [coed-mat.mes-hall] 11 Jun. 2019 . . .
A. A. Larionov, L. E. Fedichkin, A. A. Kokin, K. A. Valiev, “Nucleus magnetic resonance spectrum of 31P donors in silicon quantum computer”, arXiv:quant-ph/0012005v1 Dec. 1, 2000.
J. L. O'Brien. S. R. Schofield, M. Y. Simmons, R. G. Clark. A. S. Dzurak, N. J. Curson, B. E. Kane. N. S. McAlpine. M. E. Hawley, G. W. Brown. “Towards the fabrication of phosphorus qubits for a silicon quantum computer”, Phys. Rev. B 64, 161401(R) (2001), DOI: 10.1103/PhysRevB.64.161401, arXiv:cond-mat/0104569
T. D. Ladd, J. R. Goldman. F. Yamaguchi. and Y. Yamamoto. “An all-silicon quantum computer,” Phys. Rev. Lett. 89, 017901 (2002), DOI: 10.1103/PhysRevLett.89.017901, arXiv:quant-ph/0109039.
Belita Koiller, Xuedong Hu. S. Das Sarma, “Strain effects on silicon donor exchange: Quantum computer architecture Considerations”. Phys. Rev. B 66, 115201 (2002), DOI: 10.1103/PhysRevB.66.115201, arXiv:cond-mat/0112078 [cond-mat.mes-hall]
T. Schenkel, J. Meijer, A. Persaud, J. W. McDonald. J. P. Holder, D. H. Schneider. “Single Ion Implantation for Solid State Quantum Computer Development” Journal of Vacuum Science & Technology B: Microelectronics and Nanometer Structures Processing. Measurement. and Phenomena 20, 2819 (2002); https://doi.org/10.1116/1.1518016,
Xuedong Hu, S. Das Sarma, “Gate errors in solid state quantum computer architectures”. Phys. Rev. A 66.012312 (2002), DOI: 10.1103/PhysRevA.66.012312, arXiv:cond-mat/0202152 [cond-mat.mes-hall],
L. Oberbeck, N. J. Curson, M. Y. Simmons, R. Brenner, A. R. Hamilton, S. R. Schofield, R. G. Clark, “Encapsulation of phosphorus dopants in silicon for the fabrication of a quantum computer”. Appl. Phys. Lett. 81, 3197 (2002): https://doi.org/10.1063/1.1516859
T. M. Buehler, R. P. McKinnon, N. E. Lumpkin, R. Brenner. Di. Reilly, L. D. Macke. A. R. Hamilton, A. S. Dzurak and R. G. Clark. “Self-aligned fabrication process for silicon quantum computer devices”, DOI: 10.1088/0957-4484/13/5/330, arXiv:cond-mat/0208374
L. C. L. Hollenberg, A. S. Dzurak, C. Wellard, A. R. Hamilton. D. J. Reilly, G. J. Milburn, R. G. Clark. “Charge-based quantum computing using single donors in semiconductors”, Phys. Rev. B 69, 113301, Mar. 11, 2004, DOI:https://doi.org/10.1103/PhysRevB.69.113301
A. S. Dzurak, L. C. L. Hollenberg, D. N. Jamieson, F. E. Stanley, C. Yang, T. M. BOhler. V. Chan, D. J. Reilly, C. Wellard, R. Hamilton, C. I. Pekes. A. G. Ferguson. E. Gauja, S. Primer, J. Milburn. R. G. Clark. “Charge-based silicon quantum computer architectures using controlled single-ion implantation” arXiv:cond-mat/0306265
S.-J. Park. A. Persaud, J. A. Liddle, J. Nilsson, J. Bokor, D. H. Schneider, I. Rangelow. T. Schenkel, “Processing Issues in Top-Down Approaches to Quantum Computer Development in Silicon”, DOI: 10.1016/j.mee.2004.03.037, arXiv:cond-mat/0310195
L. M. Kettle, H.-S. Goan, Sean C. Smith, L. C. L. Hollenberg, C. J. Wellard, “Effects of J-gate potential and interfaces on donor exchange coupling in the Kane quantum computer architecture”, J. Phys.: Cond. Matter, 16, 1011, (2004), DOI:10.1088/0953-8984/16/7/001, arXiv:cond-mat/0402183 [coed-mat.mtrl-sci]
Issai Shlimak, “Isotopically engineered silicon nanostructures in quantum computation and communication”, HAIT Journal of Science and Engineering, vol. 1, pp. 196-206 (2004), arXiv:cond-mat/0403421 [cond-mat.mtrl-sci]
Xuedong Hu, Belita Koiller, S. Das Sarnia. “Charge qubits in semiconductor quantum computer architectures: Tunnel coupling and decoherence”, Phys. Rev. B 71.235332 (2005), DOI: 10.1103/PhysRevB.71.235332, arXiv:cond-mat/0412340 [cond-mat.mes-hall]
Angbo Fang, Yia-Chung Chang, J. R. Tucker. “Simulation of Si:P spin-based quantum computer architecture”, Phys. Rev. B 72, 075355—Published 24 Aug. 2005. DOI:https://doi.org/10.1103/PhysRevB.72.075355
W. M. Witzel, S. Das Sarma, “Quantum theory for electron spin decoherence induced by nuclear spin dynamics in semiconductor quantum computer architectures: Spectral diffusion of localized electron spins in the nucleus solid-state environment” Phys. Rev. B 74, 035322 (2006). DOI: 10.1103/PhysRevB.74.035322, arXiv:cond-mat/0512323 [cond-mat.mes-hall]

### Features of the Disclosure

### Introduction

The list of features reflects the characteristics of the disclosure. The features and their sub-features can be combined with each other and with other features and sub-features of this proposal and with features of the description, as far as the result of this combination is meaningful. For this purpose, in case of combination, it is not necessary to include all sub-features of a feature in one feature.

Quantum Bit Constructions 1-102

### General Quantum Bit (Qub) 1-102

Feature 1. Quantum bit (QUB)
comprising a device for controlling a quantum dot (NV)
with a substrate (D) and
if necessary, with an epitaxial layer (DEP1) and
with a quantum dot (NV) and
with a device suitable for generating an electromagnetic wave field, in particular a microwave field (B_{MW}) and/or a radio wave field (B_{RW}), at the location of the quantum dot (NV),
wherein the epitaxial layer (DEP1), if present, is deposited on the substrate (D), and
wherein the substrate (D) and/or the epitaxial layer (DEP1), if present, has a surface (OF) and
wherein the quantum dot (NV) is a paramagnetic center in the substrate (D) and/or in the epitaxial layer (DEP1), if present, and
wherein the quantum dot (NV) has a quantum dot type, and
wherein a solder can be precipitated along a perpendicular line (LOT) from the location of the quantum dot (NV) to the surface (OF) of the substrate (D) and/or the epitaxial layer (DEP1), if present, and
wherein the perpendicular line (LOT) pierces the surface (OF) of the substrate (D) and/or the epitaxial layer (DEP1), if present, at a perpendicular point (LOTP), and
wherein the device suitable for generating an electromagnetic wave field is located on the surface of the substrate (D) and/or the epitaxial layer (DEP1), if present, and
wherein the device used to generate an electromagnetic wave field is located near the plumb point (LOTP) or at the plumb point (LOTP).

Feature 2. Quantum bit (QUB) according to feature 1,
wherein the device used for generating an electromagnetic wave field, in particular a microwave field (B_{MW}) and/or a radio wave field (B_{RW}), is a device used for generating a circularly polarized electromagnetic wave field.

Feature 3. Quantum bit (QUB) according to feature 1 or 2,
wherein the device suitable for generating an electromagnetic wave field (BRW) is firmly connected to the substrate (D) and/or the epitaxial layer (DEP1) directly or indirectly by means of an intermediate further insulation (IS2).

Feature 4. Quantum bit (QUB), in particular according to one or more of the preceding features 1 to 3,
comprising a device for controlling a quantum dot (NV)
with a substrate (D) and
if necessary, with an epitaxial layer (DEP1) and
with a quantum dot (NV) and
with a horizontal line (LH) and
with a vertical line (LV),
wherein the epitaxial layer (DEP1), if present, is deposited on the substrate (D), and
wherein the substrate (D) and/or the epitaxial layer (DEP1), if present, has a surface (OF) and
wherein the quantum dot (NV) is a paramagnetic center in the substrate (D) and/or in the epitaxial layer (DEP1), if present, and
wherein the quantum dot (NV) has a quantum dot type, and
wherein a solder can be precipitated along a perpendicular line (LOT) from the location of the quantum dot (NV) to the surface (OF) of the substrate (D) and/or the epitaxial layer (DEP1), if present, and
wherein the perpendicular line (LOT) pierces the surface (OF) of the substrate (D) and/or the epitaxial layer (DEP1), if present, at a perpendicular point (LOTP), and
wherein the horizontal line (LH) and the vertical line (LV) are located on the surface of the substrate (D) and/or the epitaxial layer (DEP1), if present, and
wherein the horizontal line (LH) and the vertical line (LV) cross near the plumb point (LOTP) or at the plumb point (LOTP) at a non-zero crossing angle (a).

Feature 5. Quantum bit (QUB) after the preceding feature and feature 4,
wherein the horizontal line (LH) is electrically isolated from the vertical line (LV).

Feature 6. Quantum bit (QUB) after the preceding feature and feature 4,
wherein the horizontal line (LH) is electrically isolated from the vertical line (LV) by means of electrical insulation (IS).

Feature 7. Quantum bit (QUB), in particular according to one or more of the preceding features 1 to 6.
with a horizontal line (LH) and
with a vertical line (LV),
wherein the horizontal line (LH) and the vertical line (LV) are located on the surface of the substrate (D) and/or the epitaxial layer (DEP1), if present.

Feature 8. Quantum bit (QUB), in particular according to one or more of the preceding features 1 to 7.
with a horizontal line (LH) and
with a vertical line (LV),
wherein the horizontal line (LH) and the vertical line (LV) are located on the surface of the substrate (D) and/or the epitaxial layer (DEP1), if present, and
wherein the horizontal line (LH) and the vertical line (LV) are firmly connected to the substrate (D) and/or the epitaxial layer (DEP1), if present, directly or indirectly via a further insulation (IS2).

Feature 9. Quantum bit according to one or more of the preceding features,
the horizontal line (LH) and/or the vertical line (LV) being made of material which is superconductive below a critical temperature and which is intended and/or designed in particular to be operated at this temperature.

Feature 10. Quantum bit according to the previous features
the horizontal line (LH) and/or the vertical line (LV) having openings or being designed as lines guided in parallel in sections, in particular to reduce so-called pinning.

Feature 11. Quantum bit (QUB) according to one or more of the preceding features and feature 4,
wherein the horizontal line (LH) and/or the vertical line (LV) for “green light” is transparent and/or
wherein in particular the horizontal line (LH) and/or the vertical line (LV) is made of an electrically conductive material that is optically transparent to green light, in particular indium tin oxide (common abbreviation ITO).

Feature 12. Quantum bit (QUB) according to one or more of the preceding features 1 to 11 and the preceding feature 7 or 8
wherein the horizontal line (LH) and/or the vertical line (LV) is made of a material essentially comprising isotopes having no nucleus magnetic moment μ.

Feature 13. Nuclear quantum bit (CQUB) according to one or more of the preceding features 1 to 12 and the preceding feature 7 or 8,
wherein the horizontal line (LH) and/or the vertical line (LV) is made of a material essentially comprising ⁴⁶Ti isotopes and/or ⁴⁸Ti isotopes and/or ⁵⁰Ti isotopes with no nucleus magnetic moment μ.

Feature 14. Quantum bit (QUB) according to one or more of the preceding features and feature 4,
wherein the quantum bit (QUB) has a surface (OF) with the horizontal line (LH) and with the vertical line (LV); and
wherein the quantum bit (QUB) has a bottom surface (US) opposite the surface (OF), and
wherein the quantum bit (QUB) is mounted such that the bottom side (US) of the quantum bit (QUB) can be irradiated with “green light” such that the “green light” can reach and affect the quantum dot (NV) of the quantum bit (QUB).

Feature 15. Quantum bit (QUB) according to one or more of the preceding features and feature 4,
wherein an angle (α) is essentially a right angle.

Feature 16. Quantum bit (QUB) according to one or more of the preceding features and feature 4,
wherein the horizontal line (LH) and the vertical line (LV) have an angle of 45° with respect to the axis of the quantum dot (NV) to add the magnetic field lines of the horizontal line and the vertical line (LV).

Feature 17. Quantum bit (QUB) according to one or more of the preceding features,
wherein the quantum dot type of quantum bit is characterized by a quantum dot (NV) being a paramagnetic center.

Feature 18. Quantum bit according to one or more of the preceding features,
wherein the quantum dot is negatively charged.

Feature 19. Quantum bit (QUB) according to one or more of the preceding features.
wherein the substrate (D) is doped with nuclear spin-free isotopes in the quantum dot (NV) region.

Feature 20. Quantum bit (QUB) according to one or more of the preceding features,
wherein the quantum dot (NV) is located at a first distance (d1) along the perpendicular line (LOT) below the surface (OF) of the substrate (D) and/or the epitaxial layer (DEP1), if present, and
wherein the first distance (d1) is 2 nm to 60 nm and/or is 5 nm to 30 nm and/or is 10 nm to 20 nm, with a first distance (d1) of 5 nm to 30 nm being particularly preferred.

Feature 21. Quantum bit (QUB) according to one or more of the preceding features.
wherein the horizontal line (LH, LH1) is part of a microstrip line and/or part of a tri-plate line, and/or
wherein the vertical line (LV, LV1) is part of a microstrip line and/or part of a tri-plate line (SV1, LH, SV2).

Feature 22. Quantum bit (QUB) according to feature 21,
wherein the microstrip line comprises a first vertical shield line (SV1) and the vertical line (LV) or
wherein the microstrip line includes a first horizontal shield line (SH1) and the horizontal line (LV).

Feature 23. Quantum bit (QUB) according to feature 21.
wherein the tri-plate line comprises a first vertical shield line (SV1) and a second vertical shield line (SV2) and the vertical line (LV) extending at least partially between the first vertical shield line (SV1) and the second vertical shield line (SV2), or
wherein the tri-plate line comprises a first horizontal shield line (SH1) and a second horizontal shield line (SH2) and the horizontal line (LV) extending at least partially between the first horizontal shield line (SH1) and the second horizontal shield line (SH2).

Feature 24. Quantum bit (QUB) according to one or more of the preceding features 21 and 23,
wherein the sum of the currents (ISV1, IV, ISV2) through the tri-plate line (SV1, LV, SV2) is zero.

Feature 25. Quantum bit (QUB) according to one or more of the preceding features 21 and 23.
wherein a first further vertical solder can be precipitated along a first further vertical perpendicular line (VLOT1) parallel to the first perpendicular line (LOT) from the location of a first virtual vertical quantum dot (VVNV1) to the surface (OF) of the substrate (D) and/or the epitaxial layer (DEP1), if present, and
wherein the first virtual vertical quantum dot (VVNV1) is located at the first distance (d1) from the surface (OF), and
wherein the first further vertical perpendicular line (VLOT1) pierces the surface (OF) of the substrate (D) and/or the epitaxial layer (DEP1), if present, at a first further vertical perpendicular point (VLOTP1), and
wherein the horizontal line (LH) and the first vertical shielding line (SV1) are located on the surface of the substrate (D) and/or the epitaxial layer (DEP1), if present, and
wherein the horizontal line (LH) and the first vertical shield line (SV1) cross near the first vertical plumb point (VLOTP1) or at the first vertical plumb point (VLOTP1) at the non-zero crossing angle (α), and
wherein a second further vertical solder can be precipitated along a second further vertical perpendicular line (VLOT2) parallel to the first perpendicular line (LOT) from the location of a second virtual vertical quantum dot (VVNV2) to the surface (OF) of the substrate (D) and/or the epitaxial layer (DEP1), if present, and
wherein the second virtual vertical quantum dot (VVNV2) is located at the first distance (d1) from the surface (OF), and
wherein the second further vertical perpendicular line (VLOT2) pierces the surface (OF) of the substrate (D) and/or the epitaxial layer (DEP1), if present, at a second further vertical perpendicular point (VLOTP2), and
wherein the horizontal line (LH) and the second vertical shielding line (SV2) are located on the surface of the substrate (D) and/or the epitaxial layer (DEP1), if present, and
wherein the horizontal line (LH) and the second vertical shield line (SV2) cross near the second vertical plumb point (VLOTP2) or at the second vertical plumb point (VLOTP2) at the non-zero crossing angle (α), and
where the individual currents (ISV1, IV, ISV2) through the individual lines (SV1, LV, SV2) of the tri-plate line are so selected,
   that the magnitude of the first virtual vertical magnetic flux density vector (B_{VVNV1}) at the location of the first virtual vertical quantum dot (VVNV1) is nearly zero, and
   that the magnitude of the second virtual vertical magnetic flux density vector (B_{VVNV2}) at the location of the second virtual vertical quantum dot (VVNV2) is nearly zero, and
that the magnitude of the magnetic flux density vector (B_{NV}) at the location of the quantum dot (NV) is different from zero.

Feature 26. Quantum bit (QUB) according to one or more of the preceding features 21 to 25,
wherein a first further horizontal plumb line can be precipitated along a first further horizontal plumb line (HLOT1) parallel to the first plumb line (LOT) from the location of a first virtual horizontal quantum dot (VHNV1) to the surface (OF) of the substrate (D) and/or the epitaxial layer (DEP1), if present, and
wherein the first virtual horizontal quantum dot (VHNV1) is located at the first distance (d1) from the surface (OF), and
wherein the first further horizontal perpendicular line (VLOT1) pierces the surface (OF) of the substrate (D) and/or the epitaxial layer (DEP1), if present, at a first further horizontal perpendicular point (HLOTP1), and
wherein the vertical line (LV) and the first horizontal shielding line (SH1) are located on the surface of the substrate (D) and/or the epitaxial layer (DEP1), if present, and
wherein the vertical line (LV) and the first horizontal shield line (SH1) cross near the first horizontal plumb point (HLOTP1) or at the first horizontal plumb point (HLOTP1) at the non-zero crossing angle (α), and
wherein a second further horizontal plumb line can be precipitated along a second further horizontal plumb line (HLOT2) parallel to the first plumb line (LOT) from the location of a second virtual horizontal quantum dot (VHNV2) to the surface (OF) of the substrate (D) and/or the epitaxial layer (DEP1), if present, and
wherein the second virtual horizontal quantum dot (VHNV2) is located at the first distance (d1) from the surface (OF), and
wherein the second further horizontal perpendicular line (HLOT2) pierces the surface (OF) of the substrate (D) and/or the epitaxial layer (DEP1), if present, at a second further horizontal perpendicular point (HLOTP2), and
wherein the vertical line (LV) and the second horizontal shielding line (SH2) are located on the surface of the substrate (D) and/or the epitaxial layer (DEP1), if present, and
wherein the vertical line (LV) and the second horizontal shield line (SH2) cross near the second horizontal plumb point (HLOTP2) or at the second horizontal plumb point (HLOTP2) at the non-zero crossing angle (α), and
where the individual currents (ISH1, IH, ISH2) through the individual lines (SH1, LH, SH2) of the triplate line are so selected,
that the magnitude of the first virtual horizontal magnetic flux density vector (B_{VHNV1}) at the location of the first virtual horizontal quantum dot (VHNV1) is nearly zero, and
that the magnitude of the second virtual horizontal magnetic flux density vector (B_{VHNV2}) at the location of the second virtual horizontal quantum dot (VHNV2) is nearly zero, and that the magnitude of the magnetic flux density vector (B_{NV}) at the location of the quantum dot (NV) is different from zero.

Feature 27. Quantum bit (QUB) according to one or more of the preceding features 21 to 25.
wherein in the region or in the vicinity of the perpendicular point (LOTP) the substrate (D) is connected by means of at least one first horizontal ohmic contact (KH11) to the first horizontal shield line (SH1), and/or
wherein in the region or in the vicinity of the perpendicular point (LOTP) the substrate (D) is connected by means of at least one second horizontal ohmic contact (KH12) to the second horizontal shield line (SH2), and/or
wherein in the region or in the vicinity of the perpendicular point (LOTP) the substrate (D) is connected to the first vertical shield line (SV1) by means of at least one first vertical ohmic contact (KV11), and/or
wherein in the region or in the vicinity of the perpendicular point (LOTP) the substrate (D) is connected by means of at least one second vertical ohmic contact (KV12) to the second vertical shield line (SV2) and/or
wherein in the region or in the vicinity of the perpendicular point (LOTP) the substrate (D) is connected to an exhaust line by means of at least one second vertical ohmic contact (KV12).

Feature 28. Quantum bit (QUB) according to the previous features
wherein a resistive contact (KV11, KV12, KH11, KH12) and in particular its metallization comprises titanium.

### Diamond Based Quantum Bit (QUB) 29-49

Feature 29. Diamond-based quantum bit (QUB) according to one or more of the preceding features 1 to 28 and feature 4,
wherein the horizontal line (LH) and the vertical line (LV) have an angle of 45° with respect to the axis of the quantum dot (NV11n the form of, in particular, the NV center (NV) to add the magnetic field lines of the horizontal line and the vertical line (LV).

Feature 30. Diamond-based quantum bit (QUB) according to one or more of the preceding features 1 to 28 and/or according to feature 29,
wherein the quantum dot type of quantum bit (QUB) is characterized in that the substrate (D) or epitaxial layer (DEP1) comprises a diamond material.

Feature 31. Diamond based quantum bit (QUB) according to the previous feature,
wherein the surface normal of the diamond material points in one of the directions (111) or (100) or (113).

Feature 32. Diamond-based quantum bit (QUB) according to one or more of the preceding features 1 to 28 and/or according to one or more of the preceding features 29 to 31.
wherein the quantum dot type of quantum bit (QUB) is characterized in that the substrate (D) or epitaxial layer (DEP1) comprises a diamond material and a quantum dot (NV) is a NV center in the diamond material.

Feature 33. Diamond-based quantum bit (QUB) according to one or more of the preceding features 1 to 28 and/or according to one or more of the preceding features 29 to 32,
wherein the quantum dot type of quantum bit (QUB) is characterized in that the substrate (D) or epitaxial layer (DEP1) comprises a diamond martial and a quantum dot (NV) is a SiV center in the diamond material.

Feature 34. Diamond-based quantum bit (QUB) according to one or more of the preceding features 1 to 28 and/or according to one or more of the preceding features 29 to 33,
wherein the quantum dot type of quantum bit (QUB) is characterized in that the substrate (D) or epitaxial layer (DEP1) comprises a diamond material and a quantum dot (NV) is an L2 center or ST1 center in the diamond material.

Feature 35. Diamond based quantum bit (QUB) according to one or more of the preceding features. 1 to 28 and/or according to one or more of the preceding features 29 to 34
whereby the quantum dot type of the quantum bit (QUB) is characterized by,
that the substrate (D) or epitaxial layer (DEP1) comprises a diamond material, and
that the quantum dot (NV) comprises a vacancy in the diamond material.

Feature 36. Diamond based quantum bit (QUB) according to one or more of the preceding features 1 to 28 and/or according to one or more of the preceding features 29 to 35
whereby the quantum dot type of the quantum bit (QUB) is characterized by,
that the substrate (D) or epitaxial layer (DEP1) comprises a diamond material, and
that the quantum dot (NV) comprises a Si atom or a Ge atom or a N atom or a P atom or an As atom or a Sb atom or a Bi atom or a Sn atom or a Mn atom or an F atom or any other atom that generates a paramagnetic impurity center in the diamond material.

Feature 37. Diamond based quantum bit (QUB) according to one or more of the preceding features 1 to 28 and/or according to one or more of the preceding features 29 to 36
wherein the quantum dot type of the quantum bit (QUB) is characterized in,
that the substrate (D) or epitaxial layer (DEP1) comprises a diamond material, and
that a quantum dot (NV) is an NV center with an ¹⁴N isotope as the nitrogen atom.

Feature 38. Diamond based quantum bit (QUB) according to one or more of the preceding features 1 to 28 and/or according to one or more of the preceding features 29 to 37
whereby the quantum dot type of the quantum bit (QUB) is characterized by,
that the substrate (D) or epitaxial layer (DEP1) comprises a diamond material, and
that a quantum dot (NV) is an NV center in the diamond material with an ¹⁵N isotope as the nitrogen atom.

Feature 39. Diamond-based quantum bit (QUB) according to one or more of the preceding features 1 to 28 and/or according to one or more of the preceding features 29 to 38,
wherein the quantum dot type of the quantum bit (QUB) is characterized by,
that the substrate (D) or epitaxial layer (DEP1) comprises a diamond material, and
that the quantum dot (NV) is an NV center and/or other paramagnetic impurity center in the diamond material and
that a ¹³C isotope and/or an ¹⁵N isotope and/or another isotope with a non zero nucleus magnetic moment μ is located in the immediate proximity in coupling range to the NV center or the paramagnetic impurity center, respectively.

Feature 40. Diamond-based quantum bit (QUB) according to one or more of the preceding features 1 to 28 and/or according to one or more of the preceding features 29 to 38
wherein the quantum dot type of the quantum bit (QUB) is characterized in that the substrate (D) or epitaxial layer (DEP1) comprises a diamond material, and
wherein one or more ¹³C isotopes and/or one or more other carbon isotopes having a non-zero nucleus magnetic moment μ is located in the vicinity of the quantum dot (NV), and
where proximity is to be understood here as meaning that the magnetic field of the nuclear spin of the one or more ¹³C atoms or of the one or more other silicon isotopes with a non-zero nucleus magnetic moment can influence the spin of an electron configuration of the quantum dot (NV) and that the spin of the electron configuration of the quantum dot (NV) can influence the nuclear spin of one or more of these ¹³C isotopes or of the one or more other silicon isotopes with a non-zero nucleus magnetic moment μ.

Feature 41. Diamond-based quantum bit (QUB) according to one or more of the preceding features 1 to 28 and/or according to one or more of the preceding features 29 to 39,
wherein the quantum dot type of the quantum bit is characterized in that the substrate (D) or epitaxial layer (DEP1) comprises a diamond material, and
wherein in the diamond material, one or more isotopes having a non-zero nucleus magnetic moment μ are arranged as a nuclear quantum dot (CI) in the vicinity of the quantum dot (NV); and
wherein proximity here is to be understood as meaning that the magnetic field of the nucleus magnetic moment μ of the one or more isotopes can influence the spin of an electron configuration of the quantum dot (NV), and that the spin of the electron configuration of the quantum dot (NV) can influence the nuclear spin of the one or more of these isotopes by means of the non-zero nucleus magnetic moment μ of this one isotope or the non-zero nucleus magnetic momentum p of the several isotopes.

Feature 42. Diamond based quantum bit (QUB) according to one or more of the preceding features 1 to 28 and/or according to one or more of the preceding features 29 to 41
wherein the quantum dot type of quantum bit (QUB) is characterized in that the substrate (D) or epitaxial layer (DEP1) comprises a diamond material, and
wherein the diamond material comprises an epitaxially grown layer (DEP1) having substantially ¹²C isotopes and/or ¹⁴C isotopes.

Feature 43. Diamond based quantum bit (QUB) according to one or more of the preceding features 1 to 28 and/or according to one or more of the preceding features 29 to 42
wherein the quantum dot type of quantum bit (QUB) is characterized in that the substrate (D) or epitaxial layer (DEP1) comprises a diamond material, and
wherein the diamond material comprises an epitaxially grown layer (DEP1) having essentially ¹²C isotopes and/or ¹⁴C isotopes.

Feature 44. Diamond-based quantum bit (QUB) according to one or more of the preceding features 1 to 28 and/or according to one or more of the preceding features 29 to 43
wherein the substrate (D) or epitaxial layer (DEP1) comprises a diamond material, and
where the substrate (D) or epitaxial layer (DEP1) is n-doped in the quantum dot (NV) region.

Feature 45. Diamond-based quantum bit (QUB) according to one or more of the preceding features 1 to 28 and/or according to one or more of the preceding features 29 to 45.
wherein the substrate (D) or epitaxial layer (DEP1) comprises a diamond material, and
wherein the substrate (D) or epitaxial layer (DEP1) is doped with sulfur in the quantum dot (NV) region.

Feature 46. Diamond-based quantum bit according to one or more of the features 46 to 47,
wherein the quantum dot (NV) of the quantum bit (QUB) is negatively charged and is an NV center or other paramagnetic impurity center.

Feature 47. Diamond-based quantum bit (QUB) according to one or more of the preceding features 1 to 28 and/or according to one or more of the preceding features 29 to 46,
wherein the substrate (D) or epitaxial layer (DEP1) is doped with nuclear spin-free sulfur in the quantum dot (NV) region.

Feature 48. Diamond-based quantum bit (QUB) according to one or more of the preceding features 1 to 28 and/or according to one or more of the preceding features 29 to 47,
wherein the substrate (D) or epitaxial layer (DEP1) doped with ³²S isotopes in the quantum dot (NV) region.

Feature 49. Diamond-based quantum bit (QUB) according to one or more of the preceding features 1 to 28 and/or according to one or more of the preceding features 29 to 48.
wherein a resistive contact (KV11, KV12, KH11, KH12) and in particular its metallization comprises titanium.

### Silicon-Based Quantum Bit (QUB) 50-67

Feature 50. Silicon-based quantum bit (QUB) according to one or more of the preceding features 1 to 28 and feature 4
wherein the horizontal line (LH) and the vertical line (LV) have an angle of 45° with respect to the axis of the quantum dot (NV) in the form of a G-center (NV) to add the magnetic field lines of the horizontal line and the vertical line (LV).

Feature 51. Silicon-based quantum bit (QUB) according to one or more of the preceding features 1 to 28 and/or according to feature 50,
wherein the quantum dot type of quantum bit (QUB) is characterized in that the substrate (D) or epitaxial layer (DEP1) comprises a silicon material, in particular a silicon crystal.

Feature 52. Silicon based quantum bit (QUB) according to the previous feature,
wherein the surface normal of the silicon crystal points in one of the directions (111) or (100) or (113).

Feature 53. Silicon-based quantum bit (QUB) according to one or more of the preceding features 1 to 28 and/or according to one or more of the preceding features 50 to 52
wherein the quantum dot type of quantum bit (QUB) is characterized in that the substrate (D) or epitaxial layer (DEP1) comprises a silicon material, in particular a silicon crystal, and a quantum dot (NV) is a G center in the silicon material.

Feature 54. Silicon-based quantum bit (QUB) according to one or more of the preceding features 1 to 28 and/or according to one or more of the preceding features 50 to 53
whereby the quantum dot type of the quantum bit (QUB) is characterized by,
that the substrate (D) or the epitaxial layer (DEP1) comprises a silicon material, in particular a silicon crystal, and
that the quantum dot (NV) includes a vacancy.

Feature 55. Silicon-based quantum bit (QUB) according to one or more of the preceding features 1 to 28 and/or according to one or more of the preceding features 50 to 54
whereby the quantum dot type of the quantum bit (QUB) is characterized by,
that the substrate (D) or the epitaxial layer (DEN) comprises a silicon material, in particular a silicon crystal, and
that the quantum dot (NV) comprises a C isotope or a Ge isotope or an N isotope or a P isotope or an As isotope or an Sb isotope or a Bi isotope or a Sn isotope or an Mn isotope or an F isotope or any other atom that generates an impurity center with a paramagnetic behavior in the silicon material.

Feature 56. Silicon-based quantum bit (QUB) according to one or more of the preceding features 1 to 28 and/or according to one or more of the preceding features 50 to 55,
wherein the quantum dot type of the quantum bit (QUB) is characterized by,
that the substrate (D) or the epitaxial layer (DEP1) comprises a silicon material, in particular a silicon crystal, and
that a quantum dot (NV) is a G-center with a ¹²C isotope as carbon atom.

Feature 57. Silicon-based quantum bit (QUB) according to one or more of the preceding features 1 to 28 and/or according to one or more of the preceding features 50 to 56,
wherein the quantum dot type of the quantum bit (QUB) is characterized by,
that the substrate (D) or the epitaxial layer (DEP1) comprises a silicon material, in particular a silicon crystal, and
that a quantum dot (NV) is a G-center in the silicon material with a ¹³C isotope as a carbon atom.

Feature 58. Silicon-based quantum bit (QUB) according to one or more of the preceding features 1 to 28 and/or according to one or more of the preceding features 50 to 57.
wherein the quantum dot type of the quantum bit (QUB) is characterized by,
that the substrate (D) or the epitaxial layer (DEP1) comprises a silicon material, in particular a silicon crystal, and
that the quantum dot (NV) is a G-center and/or other paramagnetic impurity center in the silicon material: and
that a ²⁹Si isotope and/or another isotope with a non-zero nucleus magnetic moment μ is located in immediate proximity within coupling range of the G-center or the paramagnetic impurity center, respectively.

Feature 59. Silicon-based quantum bit (QUB) according to one or more of the preceding features 1 to 28 and/or according to one or more of the preceding features 50 to 58,
wherein the quantum dot type of quantum bit (QUB) is characterized in that the substrate (D) or epitaxial layer (DEP1) comprises a silicon material, in particular a silicon crystal, and
nucleus-wherein one or more ²⁹Si isotopes and/or one or more other silicon isotopes having a non-zero nucleus magnetic moment μ is located in the vicinity of the quantum dot (NV), and
wherein proximity is to be understood here as meaning that the magnetic field of the nuclear spin of the one or more ²⁹Si isotopes or of the one or more other silicon isotopes with a non-zero nucleus magnetic moment μ can influence the spin of an electron configuration of the quantum dot (NV) and that the spin of the electron configuration of the quantum dot (NV) can influence the nuclear spin of one or more of these ²⁹Si isotopes or of the one or more other silicon isotopes with a non-zero nucleus magnetic moment μ.

Feature 60. Silicon-based quantum bit (QUB) according to one or more of the preceding features 1 to 28 and/or according to one or more of the preceding features 50 to 59,
wherein the quantum dot type of the quantum bit is characterized in that the substrate (D) or epitaxial layer (DEP1) comprises a silicon material, in particular a silicon crystal, and
wherein in the silicon material one or more isotopes having a non-zero nucleus magnetic moment μ are arranged as a nuclear quantum dot (CI) in the vicinity of the quantum dot (NV), and
wherein proximity here is to be understood as meaning that the magnetic field of the nucleus magnetic moment of the one or more isotopes can influence the spin of an electron configuration of the quantum dot (NV) and that the spin of the electron configuration of the quantum dot (NV) can influence the nuclear spin of the one or more of these isotopes by means of the non-zero nucleus magnetic moment μ of this isotope or by means of the non-zero nucleus magnetic momentum μ of these isotopes.

Feature 61. Silicon-based quantum bit (QUB) according to one or more of the preceding features 1 to 28 and/or according to one or more of the preceding features 50 to 60,
wherein the quantum dot type of quantum bit (QUB) is characterized in that the substrate (D) or epitaxial layer (DEP1) comprises a silicon material, in particular a silicon crystal, and
wherein the silicon material comprises an epitaxially grown layer (DEP1) having essentially ²⁸Si isotopes and/or ²⁹Si isotopes.

Feature 62. Silicon-based quantum bit (QUB) according to one or more of the preceding features 1 to 28 and/or according to one or more of the preceding features 50 to 61
wherein the quantum dot type of quantum bit (QUB) is characterized in that the substrate (D) or epitaxial layer (DEP1) comprises a silicon material, in particular a silicon crystal, and
wherein the diamond material comprises a substantially isotopically pure epitaxially grown layer (DEP1) essentially of ²⁸Si isotopes.

Feature 63. Silicon-based quantum bit (QUB) according to one or more of the preceding features 1 to 28 and/or according to one or more of the preceding features 50 to 62
wherein the substrate (D) or epitaxial layer (DEP1) comprises a silicon material, in particular a silicon crystal, and
wherein the substrate (D) or the epitaxial layer (DEP1) is doped, in particular n-doped, in the region of the quantum dot (NV)

Feature 64. Silicon-based quantum bit (QUB) according to one or more of the preceding features 1 to 28 and/or according to one or more of the preceding features 50 to 63
wherein the substrate (D) or epitaxial layer (DEP1) comprises a silicon material, in particular a silicon crystal, and
wherein the substrate (D) or epitaxial layer (DEP1) is doped in the region of the quantum dot (NV) with one or more of the following isotopes and namely.
for n-doping with ²⁰Te, ¹²²Te, ¹²⁴Te, ¹²⁶Te, ¹²⁶Te, ¹³⁰Te, ⁴⁶Ti, ⁴⁸Ti, ⁵⁰Ti, ¹²C ¹⁴C, ⁷⁴Se, ⁷⁶Se, ⁷⁸Se, ⁸⁰Se, ¹³⁰Ba, ¹³²Ba, ¹³⁴Ba, ¹³⁶Ba, ¹³⁸Ba, ³²S, ³⁴S, and ³⁶S or
for p-doping with ¹⁰Be, ¹⁰²Pd, ¹⁰⁴Pd, ¹⁰⁶Pd, ¹⁰⁸Pd, ¹¹⁰Pd, ²⁰⁴Tl.

Feature 65. Silicon-based quantum bit according to one or more of the features 63 to 64,
wherein the quantum dot (NV) of the quantum bit (QUB) is charged and is a G center or other paramagnetic impurity center.

Feature 66. Silicon-based quantum bit (QUB) according to one or more of the preceding features 1 to 28 and/or according to one or more of the preceding features 50 to 65,
where the substrate (D) or epitaxial layer (DEP1) in the quantum dot (NV) region is doped with isotopes without nucleus magnetic moment μ or with nuclear spin-free isotopes.

Feature 67. Silicon-based quantum bit (QUB) according to one or more of the preceding features 1 to 28 and/or according to one or more of the preceding features 50 to 66,
wherein a resistive contact (KV11, KV12, KH11, KH12) and in particular its metallization comprises titanium.

### Silicon Carbide Based Quantum Bit (QUB) 68-102

Feature 68. Silicon carbide-based quantum bit (QUB) according to one or more of the preceding features 1 to 28 and feature 4
wherein the horizontal line (LH) and the vertical line (LV) have an angle of 45° with respect to the axis of the of the quantum dot (NV) in the form of a V_{Si} center (NV) or a DV center and/or a V_{C}V_{SI} center or a CAV_{Si} center or a N_{C}V_{SI} center to add the magnetic field lines of the horizontal line and the vertical line (LV).

Feature 69. Silicon carbide-based quantum bit (QUB) according to one or more of the preceding features 1 to 28 and/or according to feature 68,
wherein the quantum dot type of quantum bit (QUB) is characterized in that the substrate (D) or epitaxial layer (DEN) comprises silicon carbide, in particular a silicon carbide crystal.

Feature Feature 70. Silicon carbide-based quantum bit (QUB) according to the previous feature.
wherein the surface normal of the silicon carbide crystal points in one of the directions (111) or (100) or (113).

Feature 71. Silicon carbide-based quantum bit (QUB) according to one or more of the preceding features 1 to 28 and/or according to one or more of the preceding features 68 to 70,
wherein the quantum dot type of quantum bit (QUB) is characterized in that the substrate (D) or epitaxial layer (DEP1) comprises a silicon carbide material, in particular a silicon carbide crystal, and a quantum dot (NV) is a Vₛᵢ center and/or a DV center and/or a V_{C}V_{SI} center or a CAV_{Si} center or a N_{C}V_{SI} center in the silicon carbide material.

Feature 72. Silicon carbide-based quantum bit (QUB) according to one or more of the preceding features 1 to 28 and/or according to one or more of the preceding features 68 to 71,
wherein the quantum dot type of the quantum bit (QUB) is characterized by,
that the substrate (D) or the epitaxial layer (DEP1) comprises silicon carbide, in particular a silicon carbide crystal, and
that the quantum dot (NV) includes a vacancy.

Feature 73. Silicon carbide-based quantum bit (QUB) according to one or more of the preceding features 1 to 28 and/or according to one or more of the preceding features 68 to 72,
wherein the quantum dot type of the quantum bit (QUB) is characterized by,
that the substrate (D) or the epitaxial layer (DEP1) comprises silicon carbide, in particular a silicon carbide crystal, and
that the quantum dot (NV) comprises a vacancy or a C atom at a non-C position or a Si atom at a non-Si position or a Ge atom or a N atom or a P atom or an As atom or a Sb atom or a Bi atom or a Sn atom or a Mn atom or a F atom or any other atom that generates a paramagnetic impurity center in silicon carbide.

Feature 74. Silicon carbide-based quantum bit (QUB) according to one or more of the preceding features 1 to 28 and/or according to one or more of the preceding features 68 to 73,
wherein the quantum dot type of the quantum bit (QUB) is characterized by,
that the substrate (D) or the epitaxial layer (DEP1) comprises silicon carbide, in particular a silicon carbide crystal, and
that a quantum dot (NV) is a V_{Si} center with a ¹²C isotope as the carbon atom of the V_{Si} center

Feature 75. Silicon carbide-based quantum bit (QUB) according to one or more of the preceding features 1 to 28 and/or according to one or more of the preceding features 68 to 74,
wherein the quantum dot type of the quantum bit (QUB) is characterized by,
that the substrate (D) or the epitaxial layer (DEP1) comprises a silicon carbide material, in particular a silicon carbide crystal, and
that a quantum dot (NV) is a VSi center and/or a DV center and/or a V_{C}V_{SI} center and/or a CAV_{SI} center and/or a N_{C}V_{SI} center and/or another paramagnetic impurity center in the silicon carbide material, and
that a ¹³C isotope and/or a ²⁹Si isotope and/or another isotope having a non zero nucleus magnetic moment μ in immediately adjacent within coupling range to the V_{Si} center or to the DV center or to the V_{C}V_{SI} center or to the CAV_{Si} center or to the N_{C}V_{SI} center or to the paramagnetic impurity center, respectively.

Feature 76. Silicon carbide-based quantum bit (QUB) according to one or more of the preceding features 1 to 28 and/or according to one or more of the preceding features 68 to 75.
wherein the quantum dot type of quantum bit (QUB) is characterized in that the substrate (D) or epitaxial layer (DEP1) comprises a silicon carbide material, in particular a silicon carbide crystal, and
wherein one or more ²⁹Si isotopes and/or one or more other silicon isotopes having a non-zero nucleus magnetic moment μ are located in the vicinity of the quantum dot (NV) and/or
wherein one or more ¹³C isotopes and/or one or more other carbon isotopes having a non-zero nucleus magnetic moment μ are located in the vicinity of the quantum dot (NV), and
whereby proximity is to be understood here in such a way that the magnetic field of the nuclear spin of the one or more ²⁹Si isotopes or of the one or more other silicon isotopes with a non-zero nucleus magnetic moment it or of the one or more ¹³C isotopes or of the one or more other carbon isotopes with a non-zero nucleus magnetic moment μ can influence the spin of an electron configuration of the quantum dot (NV) and that the spin of the electron configuration of the quantum dot (NV) can influence the nuclear spin of one or more of these ²⁹Si isotopes or of one or more other silicon isotopes having a non-zero nucleus magnetic moment μ or one or more of said ¹³C isotopes or one or more other carbon isotopes having a non-zero nucleus magnetic moment μ.

Feature 77. Silicon carbide-based quantum bit (QUB) according to one or more of the preceding features 1 to 28 and/or according to one or more of the preceding features 68 to 76,
wherein the quantum dot type of the quantum bit is characterized in that the substrate (D) or epitaxial layer (DEP1) comprises a silicon carbide material, in particular a silicon carbide crystal, and
wherein in the silicon carbide material, one or more isotopes having a non zero nucleus magnetic moment μ are arranged as a nuclear quantum dot (CI) in the vicinity of the quantum dot (NV), and
wherein proximity here is to be understood as the magnetic field of the nucleus magnetic moment μ of the one or more isotopes can influence the spin of an electron configuration of the quantum dot (NV) and the spin of the electron configuration of the quantum dot (NV) can influence the nuclear spin of the one or more of these isotopes by means of their nucleus magnetic momentum μ.

Feature 78. Silicon carbide-based quantum bit (QUB) according to one or more of the preceding features 1 to 28 and/or according to one or more of the preceding features 68 to 77,
wherein the quantum dot type of quantum bit (QUB) is characterized in that the substrate (D) or epitaxial layer (DEP1) comprises a silicon carbide material, in particular a silicon carbide crystal, and
wherein the silicon material is an epitaxially grown layer (DEP1) that is essentially
   ²⁸Si isotopes and/or ²⁹Si isotopes and
   ¹²C isotope and/or ¹⁴C isotope includes.

Feature 79. Silicon carbide-based quantum bit (QUB) according to one or more of the preceding features 1 to 28 and/or according to one or more of the preceding features 68 to 78,
wherein the quantum dot type of quantum bit (QUB) is characterized in that the substrate (D) or epitaxial layer (DEP1) comprises a silicon carbide material, in particular a silicon carbide crystal, and
wherein the silicon carbide material comprises an epitaxially grown layer (DEP1) of essentially isotopically pure ²⁸Si isotopes and essentially isotopically pure ¹²C isotopes, i.e., essentially comprises ²⁸Si¹²C.

Feature 80. Silicon carbide-based quantum bit (QUB) according to one or more of the preceding features 1 to 28 and/or according to one or more of the preceding features 68 to 79,
wherein the substrate (D) or epitaxial layer (DEP1) comprises a silicon carbide material, in particular a silicon carbide crystal, and
wherein the substrate (D) or the epitaxial layer (DEP1) is doped, in particular n-doped, in the region of the quantum dot (NV).

Feature 81. Silicon carbide-based quantum bit (QUB) according to one or more of the preceding features 1 to 28 and/or according to one or more of the preceding features 68 to 80,
wherein the substrate (D) or epitaxial layer (DEP1) comprises a silicon carbide material, in particular a silicon carbide crystal, and
where the substrate (D) or epitaxial layer (DEP1) in the quantum dot (NV) region is doped with isotopes that have no nucleus magnetic moment μ.

Feature 82. Silicon carbide-based quantum bit according to one or more of the features 63 to 64
wherein the quantum dot (NV) of the quantum bit (QUB) is charged and is a V_{Si} center or a DV center or a V_{C}V_{SI} center or a CAV_{Si} center or a N_{C}V_{SI} center or another paramagnetic impurity center.

Feature 83. Silicon carbide-based quantum bit (QUB) according to one or more of the preceding features 1 to 28 and/or according to one or more of the preceding features 68 to 81,
wherein the substrate (D) or epitaxial layer (DEP1) in the quantum dot (NV) region is doped with isotopes without nucleus magnetic moment μ or with nuclear spin-free isotopes.

Feature 84. Silicon carbide-based quantum bit (QUB) according to one or more of the preceding features 1 to 28 and/or according to one or more of the preceding features 68 to 82,
wherein a resistive contact (KV11, KV12, KH11, KH12) and in particular its metallization comprises titanium.

### Mixed Crystal Based Quantum Bit (QUB) 68

Feature 85. Mixed crystal-based quantum bit (QUB) according to one or more of the preceding features 1 to 28 and feature 4
wherein, apart from quantum dots (NV) and nuclear quantum dots (CI) and dopants, the mixed crystal comprises essentially one element of the IV main group of the periodic table, i.e., is only a crystal without mixture with other elements, or
wherein, apart from quantum dots (NV) and nuclear quantum dots (CI) and dopants, the mixed crystal essentially comprises several elements of the IVth —main group of the periodic table.

Feature 86. Mixed crystal-based quantum bit (QUB) according to one or more of the preceding features 1 to 28 and according to feature 85
wherein, apart from quantum dots (NV) and nuclear quantum dots (CI) and dopants, the mixed crystal essentially comprises atoms of two different elements of the IV^{th} main group of the periodic table, or
wherein, apart from quantum dots (NV) and nuclear quantum dots (CI) and dopants, the mixed crystal essentially comprises atoms of three different elements of main group IV of the periodic table, or
the mixed crystal essentially comprising, apart from quantum dots (NV) and nuclear quantum dots (CI) and dopants, atoms of four different elements of the IV main group of the periodic table.

Feature 87. Mixed crystal based quantum bit (QUB) according to one or more of the preceding features 1 to 28 and/or according to one or more of the features 85 to 86 and according to feature 85.
where the quantum dot (NV) has an axis, and
where the horizontal line (LH) and the vertical line (LV) have an angle of 45° with respect to the axis of the quantum dot (NV) to add the magnetic field lines of the horizontal line and the vertical line (LV).

Feature 88. Mixed crystal based quantum bit (QUB) according to one or more of the preceding features 1 to 28 and/or according to one or more of the features 85 to 87 and according to feature 85,
wherein the quantum dot type of quantum bit (QUB) is characterized in that the substrate (D) or epitaxial layer (DEP1) comprises a mixed crystal according to feature 85.

Feature 89. Mixed crystal-based quantum bit (QUB) according to the previous feature.
wherein the surface normal of the mixed crystal points in one of the directions (111) or (100) or (113).

Feature 90. Mixed crystal based quantum bit (QUB) according to one or more of the preceding features 1 to 28 and according to feature 85 and/or according to one or more of the features 85 to 89 feature 85,
wherein the quantum dot type of the quantum bit (QUB) is characterized by,
that the substrate (D) or epitaxial layer (DEP1) comprises a mixed crystal according to feature 85, and
that the quantum dot (NV) includes a vacancy.

Feature 91. Mixed crystal based quantum bit (QUB) according to one or more of the preceding features 1 to 28 and according to feature 85 and/or according to one or more of the features 85 to 90 and according to feature 85,
wherein the quantum dot type of the quantum bit (QUB) is characterized by,
that the substrate (D) or epitaxial layer (DEP1) comprises a mixed crystal according to feature 85, and
that the quantum dot (NV) is a defect or an atom of the IV^{th} main group or an atom of the II^{nd} main group or the III^{rd} main group, main group, in particular a C atom or a Si atom or a Ge atom or Sn atom or a Pb atom or a N atom or a P atom or an As atom or an Sb atom or a Bi atom or a B atom or an Al atom or a Ga atom or a Tl atom or a Mn atom or an F atom or another atom which generates a paramagnetic impurity center in the mixed crystal.

Feature 92. Mixed crystal based quantum bit (QUB) according to one or more of the preceding features 1 to 28 and according to feature 85 and/or according to one or more of the features 85 to 91 and according to feature 85,
whereby the quantum dot type of the quantum bit (QUB) is characterized by,
in that the substrate (D) or the epitaxial layer (DEP1) comprises a mixed crystal according to feature 85, and
in that a quantum dot (NV) in the mixed crystal comprises one isotope of the isotopes or a plurality of isotopes of the isotopes ¹²C, ¹⁴C, ²⁸Si, ⁷⁰Ge, ⁷²Ge, ⁷⁴Ge, ⁷⁶Ge, ¹¹²Sn, ¹¹⁴Sn, ¹¹⁶Sn, ¹¹⁸Sn, ¹²⁰Sn, ¹²²Sn, ¹²⁴Sn, ²⁰⁴Pb, ²⁰⁶Pb, ²⁰⁸Pb and/or one isotope of the isotopes or a plurality of isotopes of the isotopes WITHOUT a nucleus magnetic moment,
   wherein the one or more isotopes form the quantum dot (NV) in the form of a paramagnetic impurity center, and
   whereas said one or more isotopes being located at a position or positions within said impurity center that are not regular lattice positions for said one or more isotopes within said mixed crystal.

Feature 93. Mixed crystal based quantum bit (QUB) according to one or more of the preceding features 1 to 28 and according to feature 85 and/or according to one or more of the features 85 to 92 and according to feature 85
whereas the quantum dot type of the quantum bit (QUB) is characterized by,
in that the substrate (D) or the epitaxial layer (DEP1) comprises a mixed crystal according to feature 85, and
that a quantum dot (NV) in the mixed crystal comprises one or more isotopes of the isotopes ¹³C, ²⁹Si, ⁷³Ge, ¹¹⁵Sn, ¹¹⁷Sn, ¹¹⁹Sn, ²⁰⁷Pb and/or one or more isotopes of the isotopes WITH a non-zero nucleus magnetic moment μ,
   where the one isotope or the several isotopes are
      form the quantum dot (NV) in the form of a paramagnetic impurity center and/or
      are in the immediate vicinity within coupling range of the fault center.

Feature 94. Mixed crystal based quantum bit (QUB) according to one or more of the preceding features 1 to 28 and according to feature 85 and/or according to one or more of the features 85 to 93 and according to feature 85,
wherein the quantum dot type of the quantum bit (QUB) is characterized by,
   that the substrate (D) or epitaxial layer (DEP1) comprises a mixed crystal according to feature 83, and
   wherein one or more ¹³C isotopes and/or one or more ²⁹Si isotopes and/or one or more ⁷³Ge isotopes and/or one or more ¹¹⁵Sn isotopes and/or one or more ¹¹⁷Sn isotopes and/or one or more ¹¹⁹Sn isotopes and/or one or more ²⁰⁷Pb isotopes and/or one or more other isotopes having a non-zero nucleus magnetic moment μ is located in the vicinity of the quantum dot (NV) and/or
   wherein proximity is to be understood here as meaning that the magnetic field of the nuclear spin of said one isotope or said plurality of isotopes having a non-zero nucleus magnetic moment μ can influence the spin of an electron configuration of the quantum dot (NV) and that the spin of the electron configuration of the quantum dot (NV) can influence the nuclear spin of said one isotope or said plurality of isotopes having non-zero nucleus magnetic momentum μ.

Feature 95. Mixed crystal based quantum bit (QUB) according to one or more of the preceding features 1 to 28 and according to feature 85 and/or according to one or more of the features 85 to 94 and according to feature 85,
wherein the quantum dot type of quantum bit (QUB) is characterized in that the substrate (D) or epitaxial layer (DEP1) comprises a mixed crystal according to feature 85, and
wherein in the material of the mixed crystal, one or more isotopes having a non-zero nucleus magnetic moment μ are arranged as a nuclear quantum dot (CI) in the vicinity of the quantum dot (NV), and
wherein proximity here is to be understood as the magnetic field of the nucleus magnetic moment μ of the one or more isotopes can influence the spin of an electron configuration of the quantum dot (NV) and the spin of the electron configuration of the quantum dot (NV) can influence the nuclear spin of the one or more of these isotopes by means of their nucleus magnetic momentum μ.

Feature 96. Mixed crystal based quantum bit (QUB) according to one or more of the preceding features 1 to 28 and according to feature 85 and/or according to one or more of the features 85 to 95 and according to feature 85
wherein the quantum dot type of the quantum bit (QUB) is characterized in that the substrate (D) or epitaxial layer (DEP1) comprises a mixed crystal according to feature 85, and
wherein the material of the mixed crystal comprises an epitaxially grown layer (DEP1) essentially comprising one or more isotopic types from the following isotopic list:
¹²C, ¹⁴C, ²⁸Si, ³⁰Si, ⁷²Ge, ⁷⁴Ge, ⁷⁶Ge, ¹¹²Sn, ¹¹⁴Sn, ¹¹⁶Sn, ¹¹⁸Sn, ¹²⁰Sn, ¹²²Sn, ¹²⁴Sn, ²⁰⁴Pb, ²⁰⁶Pb, ²⁰⁸Pb.

Feature 97. Mixed crystal-based quantum bit (QUB) according to one or more of the preceding features 1 to 28 and according to feature 85 and/or according to one or more of the features 85 to 96 and according to feature 85 and according to feature 96
wherein an isotope comprising the material of the mixed crystal is essentially isotopically pure.

Feature 98. Mixed crystal based quantum bit (QUB) according to one or more of the preceding features 1 to 28 and according to feature 85 and/or according to one or more of the features 85 to 97 and according to feature 85
wherein the quantum dot type of the quantum bit (QUB) is characterized in that the substrate (D) or epitaxial layer (DEP1) comprises a mixed crystal according to feature 85, and
wherein the substrate (D) or the epitaxial layer (DEP1) is doped, in particular n-doped, in the region of the quantum dot (NV).

Feature 99. Mixed crystal based quantum bit (QUB) according to one or more of the preceding features 1 to 28 and according to feature 85 and/or according to one or more of the features 85 to 98 and according to feature 85
wherein the quantum dot type of the quantum bit (QUB) is characterized in that the substrate (D) or epitaxial layer (DEP1) comprises a mixed crystal according to feature 85, and
where the substrate (D) or epitaxial layer (DEP1) in the quantum dot (NV) region is doped with isotopes that have no nucleus magnetic moment μ.

Feature 100. Mixed crystal-based quantum bit (QUB) according to one or more of the features 98 to 99,
wherein the quantum dot (NV) of the quantum bit (QUB) is charged, in particular negatively charged, and is an impurity center.

Feature 101. Mixed crystal based quantum bit (QUB) according to one or more of the preceding features 1 to 28 and according to feature 85 and/or according to one or more of the features 85 to 100 and according to feature 85,
wherein the substrate (D) or epitaxial layer (DEP1) in the quantum dot (NV) region is doped with isotopes without magnetic moment μ or with nuclear spin-free isotopes.

Feature 102. Mixed crystal based quantum bit (QUB) according to one or more of the preceding features 1 to 28 and according to feature 85 and/or according to one or more of the features 85 to 101 and according to feature 85,
wherein a resistive contact (KV11, KV12, KH11, KH12) and in particular its metallization comprises titanium.

Nuclear Quantum Bit Constructions 103-202

### General Nucleus (Spin) Quantum Bit (CQUB) 103-202

Feature 103 Nuclear quantum bit (CQUB)
comprising a device for controlling a nuclear quantum dot (CI)
with a substrate (D) and
if necessary, with an epitaxial layer (DEP1) and
with a nuclear quantum dot (CI) and
using a device capable of generating a circularly polarized wave (B_{RW}) electromagnetic field at the location of the nuclear quantum dot (CI).
wherein the epitaxial layer (DEP1), if present, is deposited on the substrate (D), and
wherein the substrate (D) and/or the epitaxial layer (DEP1), if present, has a surface (OF) and
wherein the nuclear quantum dot (CI) has a magnetic moment, in particular a nuclear spin, and
wherein the device suitable for generating an electromagnetic wave field (B_{RW}) is located on the surface (OF) of the substrate (D) and/or the epitaxial layer (DEP1), if present.

Feature 104. Nuclear quantum bit (CQUB) according to feature 103,
wherein the device suitable for generating an electromagnetic wave field (Blew) is suitable for generating an electromagnetic circularly polarized wave field (Baw).

Feature 105. Nuclear quantum bit (CQUB) according to feature 103 or 104,
wherein the device suitable for generating an electromagnetic wave field (B_{RW}) firmly connected to the substrate (D) and/or to the epitaxial layer (DEP1) and/or to the surface (OF) of the substrate (D) and/or to the surface (OF) of the epitaxial layer (DEP1) directly or indirectly by means of an insulation (IS) or an intermediate further insulation (IS2).

Feature 106. Nuclear quantum bit (CQUB) according to one or more of the features 103 to 105
wherein a solder can be precipitated along a perpendicular line (LOT) from the location of the nuclear quantum dot (CI) to the surface (OF) of the substrate (D) and/or the epitaxial layer (DEP1), if present, and
wherein the perpendicular line (LOT) pierces the surface (OF) of the substrate (D) and/or the epitaxial layer (DEP1), if present, at a perpendicular point (LOTP), and
wherein the device used to generate an electromagnetic wave field, in particular a circularly polarized electromagnetic wave field, in particular a radio wave field (Blew), is located near the plumb point (LOTP) or at the plumb point (LOTP).

Feature 107. Nuclear quantum bit (CQUB), in particular according to one or more of the preceding features 103 to 106,
with a horizontal line (LH) and
with a vertical line (LV),
wherein the horizontal line (LH) and the vertical line (LV) are located on the surface of the substrate (D) and/or the epitaxial layer (DEP1), if present.

Feature 108. Nuclear quantum bit (CQUB), in particular according to one or more of the preceding features 103 to 107,
with a horizontal line (LH) and
with a vertical line (LV),
wherein the horizontal line (LH) and the vertical line (LV) are located on the surface of the substrate (D) and/or the epitaxial layer (DEP1), if present, and
wherein the horizontal line (LH) and the vertical line (LV) are firmly connected to the substrate (D) and/or the epitaxial layer (DEP1), if present, directly or indirectly via a further insulation (IS2).

Feature 109. Nuclear quantum bit (CQUB) according to one or more of the preceding features 103 to 107,
wherein the horizontal line (LH) and the vertical line (LV) constitute the device suitable for generating an electromagnetic wave field, in particular a circularly polarized electromagnetic wave field, in particular a radio wave field (B_{RW}), at the location of the nuclear quantum dot (CI).

Feature 110. A nuclear quantum bit (CQUB) according to one or more of the preceding features 103 to 109 and the preceding feature 107 or 108
wherein a solder can be precipitated along a perpendicular line (LOT) from the location of the nuclear quantum dot (CI) to the surface (OF) of the substrate (D) and/or the epitaxial layer (DEP1), if present, and
wherein the perpendicular line (LOT) pierces the surface (OF) of the substrate (D) and/or the epitaxial layer (DEP1), if present, at a perpendicular point (LOTP), and
wherein the horizontal line (LH) and the vertical line (LV) cross near the plumb point (LOTP) or at the plumb point (LOTP) at a non-zero crossing angle (α).

Feature 111. Nuclear quantum bit (CQUB) according to one or more of the preceding features 103 to 110 and feature 107 or 108,
wherein the horizontal line (LH) is electrically isolated from the vertical line (LV).

Feature 112. A nuclear quantum bit (CQUB) according to one or more of the preceding features 103 to 111 and the preceding feature 107 or 108,
wherein the horizontal line (LH) is electrically isolated from the vertical line (LV) by means of electrical insulation (IS).

Feature 113. A nuclear quantum bit (CQUB) according to one or more of the preceding features 103 to 112 and the preceding feature 107 or 108,
wherein the horizontal line (LH) and/or the vertical line (LV) is transparent to green light, and
wherein in particular the horizontal line (LH) and/or the vertical line (LV) is made of an electrically conductive material that is optically transparent to green light, in particular of indium tin oxide (common abbreviation ITO).

Feature 114. A nuclear quantum bit (CQUB) according to one or more of the preceding features 103 to 113 and the preceding feature 107 or 108,
wherein the horizontal line (LH) and/or the vertical line (LV) is made of a material essentially comprising isotopes having no nucleus magnetic moment μ.

Feature 115. A nuclear quantum bit (CQUB) according to one or more of the preceding features 103 to 114 and the preceding feature 107 or 108,
wherein the horizontal lead (LH) and/or the vertical lead (LV) is made of a material essentially comprising ⁴⁶Ti isotopes and/or ⁴⁸Ti isotopes and/or ⁵⁰Ti isotopes with no nucleus magnetic moment μ.

Feature 116. Nuclear quantum bit (CQUB) according to one or more of the preceding features 103 to 113 and feature 110,
where an angle (α) is essentially a right angle.

Feature 117. A nuclear quantum bit (CQUB) according to one or more of the preceding features 103 to 116,
wherein the substrate (D) comprises a paramagnetic center.

Feature 118. A nuclear quantum bit (CQUB) according to one or more of the preceding features 103 to 117,
wherein the substrate (D) comprises a quantum dot (NV).

Feature 119. Nuclear quantum bit (CQUB) according to one or more of the preceding features 103 to 118,
wherein a paramagnetic center having a charge carrier or charge carrier configuration is located near the nuclear quantum dot (CI); and
wherein the charge carrier or charge carrier configuration has a charge carrier spin state; and
wherein the nuclear quantum dot (CI) has a nuclear spin state and
where proximity here is to be understood in this way,
   that the nuclear spin state can influence the charge carrier spin state and/or
   that the carrier spin state can affect the nuclear spin state.

Feature 120. A nuclear quantum bit (CQUB) according to one or more of the preceding features 103 to 119.
wherein the substrate (D) is doped with nuclear spin-free isotopes in the region of the nuclear quantum dot (CI).

Feature 121. Nuclear quantum bit (CQUB) according to one or more of the preceding features 103 to 120,
wherein the nuclear quantum dot (CI) is located at a first nucleus distance (d1′) along the perpendicular line (LOT) below the surface (OF) of the substrate (D) and/or the epitaxial layer (DEP1), if present, and
wherein the first nucleus spacing (d1′) is 2 nm to 60 nm and/or is 5 nm to 30 nm and/or is 10 nm to 20 nm, with a first nucleus spacing (d1′) of 5 nm to 30 nm being particularly preferred.

Feature 122. A nuclear quantum bit (CQUB) according to one or more of the preceding features 103 to 121,
wherein the horizontal line (LH, LH1) is part of a microstrip line and/or part of a tri-plate line, and/or
wherein the vertical line (LV. LV1) is pan of a microstrip line and/or part of a tri-plate line (SV1, LH, SV2).

Feature 123. Nuclear quantum bit (CQUB) according to feature 122,
wherein microstrip line comprises a first vertical shield line (SV1) and the vertical line (LV) or
wherein microstrip line includes a first horizontal shield line (SH1) and the horizontal line (LH).

Feature 124. Nuclear quantum bit (CQUB) according to feature 122,
wherein tri-plate line comprises a first vertical shield line (SV1) and a second vertical shield line (SV2) and the vertical line (LV) extending between the first vertical shield line (SV1) and the second vertical shield line (SV2), or
wherein tri-plate line comprises a first horizontal shield line (SH1) and a second horizontal shield line (SH2) and the horizontal line (LV) extending between the first horizontal shield line (SH1) and the second horizontal shield line (SH2).

Feature 125. Nuclear quantum bit (CQUB) according to one or more of the preceding features 103 to 124,
wherein the sum of the currents through the tri-plate line (SV1, LV, SV2) is zero.

Feature 126. A nuclear quantum bit (CQUB) according to one or more of the preceding features 103 to 125,
wherein a first further vertical solder can be precipitated along a first further vertical perpendicular line (VLOT1) parallel to the first perpendicular line (LOT) from the location of a first virtual vertical nuclear quantum dot (VVCI1) to the surface (OF) of the substrate (D) and/or the epitaxial layer (DEP1), if present, and
wherein the first virtual vertical nuclear quantum dot (VVCI1) is located at the first distance (d1) from the surface (OF), and
wherein the first further vertical perpendicular line (VLOT1) pierces the surface (OF) of the substrate (D) and/or the epitaxial layer (DEP1), if present, at a first further vertical perpendicular point (VLOTP1), and
wherein the horizontal line (LH) and the first vertical shielding line (SV1) are located on the surface of the substrate (D) and/or the epitaxial layer (DEP1), if present, and
wherein the horizontal line (LH) and the first vertical shield line (SV1) cross near the first vertical plumb point (VLOTP1) or at the first vertical plumb point (VLOTP1) at the non-zero crossing angle (α), and
wherein a second further vertical solder can be precipitated along a second further vertical perpendicular line (VLOT2) parallel to the first perpendicular line (LOT) from the location of a second virtual vertical nuclear quantum dot (VVCI2) to the surface (OF) of the substrate (D) and/or the epitaxial layer (DEP1), if present, and
wherein the second virtual vertical nuclear quantum dot (VVCI2) is located at the first distance (d1) from the surface (OF), and
wherein the second further vertical perpendicular line (VLOT2) pierces the surface (OF) of the substrate (D) and/or the epitaxial layer (DEP1), if present, at a second further vertical perpendicular point (VLOTP2), and
wherein the horizontal line (LH) and the second vertical shielding line (SV2) are located on the surface of the substrate (D) and/or the epitaxial layer (DER), if present, and
wherein the horizontal line (LH) and the second vertical shield line (SV2) cross near the second vertical plumb point (VLOTP2) or at the second vertical plumb point (VLOTP2) at the non-zero crossing angle (α), and
wherein the individual currents (ISV1, IV, ISV2) through the individual lines (SV1, LV, SV2) of the tri-plate line are so selected,
   that the magnitude of the first virtual vertical magnetic flux density vector (B_{VVCI1}) at the location of the first virtual vertical nuclear quantum dot (VVCI1) is nearly zero, and
   that the magnitude of the second virtual vertical magnetic flux density vector (B_{VVCI2}) at the location of the second virtual vertical nuclear quantum dot (VVCI2) is nearly zero, and
   that the magnitude of the magnetic flux density vector (BCI) at the location of the nuclear quantum dot (CI) is different from zero.

Feature 127. A nuclear quantum bit (CQUB) according to one or more of the preceding features 103 to 126,
wherein a first further horizontal plumb line can be precipitated along a first further horizontal plumb line (HLOT1) parallel to the first plumb line (LOT) from the location of a first virtual horizontal nuclear quantum dot (VHCI1) to the surface (OF) of the substrate (D) and/or the epitaxial layer (DEP1), if present, and
wherein the first virtual horizontal nuclear quantum dot (VHCIV1) is located at the first distance (d1) from the surface (OF), and
wherein the first further horizontal perpendicular line (HLOT1) pierces the surface (OF) of the substrate (D) and/or the epitaxial layer (DEP1), if present, at a first further horizontal perpendicular point (HLOTP1), and
wherein the vertical line (LV) and the first horizontal shielding line (SH1) are located on the surface of the substrate (D) and/or the epitaxial layer (DEP1), if present, and
wherein the vertical line (LV) and the first horizontal shield line (SH1) cross near the first horizontal plumb point (HLOTP1) or at the first horizontal plumb point (HLOTP1) at the non-zero crossing angle (α), and
wherein a second further horizontal plumb line can be precipitated along a second further horizontal plumb line (HLOT2) parallel to the first plumb line (LOT) from the location of a second virtual horizontal nuclear quantum dot (VHCI2) to the surface (OF) of the substrate (D) and/or the epitaxial layer (DEP1), if present, and
wherein the second virtual horizontal nuclear quantum dot (VHCI2) is located at the first distance (d1) from the surface (OF), and
wherein the second further horizontal perpendicular line (HLOT2) pierces the surface (OF) of the substrate (D) and/or the epitaxial layer (DEP1), if present, at a second further horizontal perpendicular point (HLOTP2), and
wherein the vertical line (LV) and the second horizontal shielding line (SH2) are located on the surface of the substrate (D) and/or the epitaxial layer (DEP1), if present, and
wherein the vertical line (LV) and the second horizontal shield line (SH2) cross near the second horizontal plumb point (HLOTP2) or at the second horizontal plumb point (HLOTP2) at the non-zero crossing angle (α), and
wherein the individual currents (ISH1, IH, ISH2) through the individual lines (SH1, LH, SH2) of the Tri-Plate line are so selected,
that the magnitude of the first virtual horizontal magnetic flux density vector (B_{VHCI1}) at the location of the first virtual horizontal nuclear quantum dot (VHCI1) is nearly zero, and
that the magnitude of the second virtual horizontal magnetic flux density vector (B_{VHCI2}) at the location of the second virtual horizontal quantum dot (VHCI2) is nearly zero, and
that the magnitude of the magnetic flux density vector (B_{NV}) at the location of the nuclear quantum dot (CI) is different from zero.

Feature 128. A nuclear quantum bit (CQUB) according to one or more of the preceding features 103 to 127,
wherein in the region or in the vicinity of the perpendicular point (LOTP) the substrate (D) is connected by means of at least one first horizontal ohmic contact (KH11) to the first horizontal shield line (SH1), and/or
wherein in the region or in the vicinity of the perpendicular point (LOTP) the substrate (D) is connected by means of at least one second horizontal ohmic contact (KH12) to the second horizontal shield line (SH2), and/or
wherein in the region or in the vicinity of the perpendicular point (LOTP) the substrate (D) is connected to the first vertical shield line (SV1) by means of at least one first vertical ohmic contact (KV11), and/or
wherein, in the region or vicinity of the perpendicular point (LOTP), the substrate (D) is connected to the second vertical shield line (SV2) by means of at least one second vertical ohmic contact (KV12).

Feature 129. A nuclear quantum bit (CQUB) according to one or more of the preceding features 103 to 128,
wherein a resistive contact (KV11, KV12, KH11, KH12) and in particular its metallization comprises titanium.

### Diamond-Based Nucleus (Spin) Quantum Bit (CQUB) 130-202

Feature 130. Diamond nuclear quantum bit (CQUB) according to one or more of the preceding features 103 to 129,
wherein the substrate (D) and/or the epitaxial layer (DEP1) comprises a diamond material.

Feature 131. Diamond Nuclear quantum bit (CQUB) Feature 130
wherein the substrate (D) and/or epitaxial layer (DEP1) comprises a diamond material having a NV center in the diamond material or another paramagnetic impurity center the diamond material as a quantum dot (NV).

Feature 132. Diamond nuclear quantum bit (CQUB) according to one or more of the preceding features 130 to 131,
wherein the substrate (D) and/or the epitaxial layer (DEP1) comprises a diamond material and a quantum dot (NV) in the diamond material, and
wherein a quantum dot (NV) is a SiV center.

Feature 133. A diamond nuclear quantum bit (CQUB) according to one or more of the preceding features 130 to 132,
wherein the substrate (D) and/or the epitaxial layer (DEP1) comprises a diamond material and a quantum dot (NV) in the diamond material, and
wherein the quantum dot (NV) comprises a vacancy.

Feature 134. Diamond nuclear quantum bit (CQUB) according to one or more of the preceding features 130 to 133,
wherein the substrate (D) and/or the epitaxial layer (DEP1) comprises a diamond material and a quantum dot (NV) in the diamond material, and
wherein the quantum dot (NV) comprises a Si atom or a Ge atom or a N atom or a P atom or an As atom or a Sb atom or a Bi atom or a Sn atom or a Mn atom or an F atom or any other atom that generates an impurity center with a paramagnetic behavior in the diamond material.

Feature 135. Diamond nuclear quantum bit (CQUB) according to one or more of the preceding features 130 to 134,
wherein the substrate (D) and/or the epitaxial layer (DEP1) comprises a diamond material, and a nuclear quantum dot (CI) in the diamond material is the nucleus of a ¹³C isotope or a ²⁹Si isotope or a ¹⁴N isotope or a ¹⁵N isotope or another atom whose nucleus has a magnetic moment.

Feature 136. Diamond nuclear quantum bit (CQUB) according to one or more of the preceding features 130 to 135,
wherein the substrate (D) and/or the epitaxial layer (DEP1) comprises a diamond material and a nuclear quantum dot (CI) is the nucleus of a ¹⁴N isotope or a ¹⁵N isotope of the nitrogen atom of a NV center in the diamond material.

Feature 137. Diamond nuclear quantum bit (CQUB) according to one or more of the preceding features 130 to 136,
wherein the substrate (D) and/or the epitaxial layer (DEP1) comprises a diamond material, and
wherein the nuclear quantum dot (CI) is the nucleus of a ¹³C isotope, and
wherein in the diamond material a NV center or a ST1 center or a L2 center or another paramagnetic center is located near the ¹³C isotope.
wherein proximity here is understood to mean that the magnetic field of the nuclear spin of the ¹³C isotope can affect the spin of the electron configuration of the NV center or the ST1 center or the L2 center or the other paramagnetic center, and that the spin of the electron configuration of the NV center or the ST1 center or the L2 center or the other paramagnetic center can affect the nuclear spin of the ¹³C isotope.

Feature 138. Diamond nuclear quantum bit (CQUB) according to one or more of the preceding features 130 to 137,
wherein the substrate (D) and/or the epitaxial layer (DEP1) comprises a diamond material, and
wherein the nuclear quantum dot (CI) is an isotope with a nuclear spin in the diamond material, and
wherein in the diamond material a NV center or a ST1 center or a L2 center or other paramagnetic center is located near the isotope with the nuclear spin,
wherein proximity here is to be understood as the magnetic field of the isotope's nuclear spin can affect the spin of the NV center's electron configuration, and the spin of the NV center's electron configuration or the ST1 center or the L2 center or the other paramagnetic center can affect the isotope's nuclear spin.

Feature 139. Diamond nuclear quantum bit (CQUB) according to one or more of the preceding features 130 to 138,
wherein the substrate (D) and/or the epitaxial layer (DEP1) comprises a diamond material, and
wherein the nuclear quantum dot (CI) is an isotope with a nuclear spin in the diamond material, and
wherein at least one other nuclear quantum dot (CI′) is an isotope having a nuclear spin in the diamond material, and
wherein in the diamond material, an NV center or an ST1 center or an L2 center or other paramagnetic center is located in the vicinity of the nuclear quantum dot (CI); and
wherein the NV center or the ST1 center or the L2 center or the other paramagnetic center is located near the at least one, further nuclear quantum dot (CI′) in the diamond material,
wherein proximity here is to be understood in this way,
   that the magnetic field of the nuclear quantum dot (CI) can influence the spin of the electron configuration of the NV center or the ST1 center or the L2 center or the other paramagnetic center, respectively; and
   that the magnetic field of the at least one, further nuclear quantum dot (CI′) can influence the spin of the electron configuration of the NV center or the ST1 center or the L2 center or the other paramagnetic center, and
   that the spin of the electron configuration of the NV center or the ST1 center or the L2 center or the other paramagnetic center can influence the nuclear spin of the nuclear quantum dot (CI), and
   that the spin of the electron configuration of the NV center or the ST1 center or the L2 center or the other paramagnetic center can influence the nuclear spin of the at least one, further nuclear quantum dot (Cr).

Feature 140. Diamond nuclear quantum bit (CQUB) according to feature 139,
wherein the coupling strength between a nuclear quantum bit (CI, CI′) and the electron configuration of the NV center or the ST1 center or the L2 center or the other paramagnetic center is in a range of 1 kHz to 200 GHz and/or 10 kHz to 20 GHz and/or 100 kHz to 2 GHz and/or 0.2 MHz to 1 GHz and/or 0.5 MHz to 100 MHz and/or 1 MHz to 50 MHz, in particular preferably 10 MHz.

Feature 141. Diamond nuclear quantum bit (CQUB) according to one or more of the preceding features 130 to 140,
wherein the substrate (D) and/or the epitaxial layer (DEP1) comprises a diamond material, and
wherein the diamond material has an epitaxially grown, essentially isotopically pure layer (DEP1) containing ¹²C isotopes.

Feature 142. Diamond nuclear quantum bit (CQUB) according to one or more of the preceding features 130 to 141,
wherein the substrate (D) and/or the epitaxial layer (DEP1) is doped, in particular n-doped, in the region of the nuclear quantum dot (CI).

Feature 143. A diamond nuclear quantum bit (CQUB) according to one or more of the preceding features 130 to 142,
wherein the substrate (D) and/or the epitaxial layer (DEP1) comprises a diamond material, and
wherein the substrate (D) and/or the epitaxial layer (DEP1) is doped with sulfur in the region of the nuclear quantum dot (CI).

Feature 144. Diamond nuclear quantum bit (CQUB) according to one or more of features 130 to 143,
wherein the substrate (D) and/or the epitaxial layer (DEP1) is doped with nuclear spin-free sulfur in the region of the nuclear quantum dot (CI).

Feature 145. Diamond nuclear quantum bit (CQUB) according to one or more of the preceding features 130 to 144,
wherein the substrate (D) and/or the epitaxial layer (DEP1) is essentially doped with ³²S isotopes in the region of the nuclear quantum dot (CI).

Feature 146. Diamond nuclear quantum bit (CQUB) according to one or more of the preceding features 130 to 145,
wherein the substrate (D) and/or the epitaxial layer (DEP1) in the region of the nuclear quantum dot (CI) is essentially doped with isotopes having no nucleus magnetic moment.

Feature 147. Diamond nuclear quantum bit (CQUB) according to one or more of the preceding features 130 to 146,
wherein the substrate (D) and/or the epitaxial layer (DEP1) comprises a diamond material, and
wherein the diamond material comprises essentially carbon isotopes having no nucleus magnetic moment it and/or
wherein the diamond material comprises essentially only ¹²C isotopes and/or ¹⁴C carbon isotopes with no nucleus magnetic moment μ and/or
wherein the diamond material essentially comprises only ¹²C isotopes with no nucleus magnetic moment μ.

Feature 148. Diamond nuclear quantum bit (CQUB) according to one or more of the preceding features 130 to 147,
wherein a resistive contact (KV11, KV12, KH11, KH12) and in particular its metallization comprises titanium.

### Silicon-Based Nucleus (Spin) Quantum Bit (CQUB) 130-166

Feature 149. Silicon nuclear quantum bit (CQUB) according to one or more of the preceding features 103 to 129,
wherein the substrate (D) and/or the epitaxial layer (DEP1) comprises a silicon material, in particular a silicon crystal.

Feature 150. Silicon-nuclear quantum bit (CQUB) according to feature 149,
wherein the substrate (D) and/or the epitaxial layer (DEP1) comprises a silicon material, in particular a silicon crystal, having a G center in the silicon material or another paramagnetic impurity center in the silicon material as a quantum dot (NV).

Feature 151. Silicon-nuclear quantum bit (CQUB) according to one or more of the preceding features 149 to 150,
wherein the substrate (D) and/or the epitaxial layer (DEP1) comprises a silicon material, in particular a silicon crystal, and a quantum dot (NV) in the silicon material, and
where the quantum dot (NV) comprises a vacancy in the silicon material.

Feature 152. Silicon nuclear quantum bit (CQUB) according to one or more of the preceding features 149 to 151,
wherein the substrate (D) and/or the epitaxial layer (DEP1) comprises a silicon material, in particular a silicon crystal, and a quantum dot (NV) in the silicon material, and
wherein the quantum dot (NV) comprises a C isotope or a Ge isotope or an N isotope or a P isotope or an As isotope or an Sb isotope or a Bi isotope or a Sn isotope or an Mn isotope or an F isotope or any other isotope that generates an impurity center with a paramagnetic behavior in the silicon material.

Feature 153. Silicon nuclear quantum bit (CQUB) according to one or more of the preceding features 149 to 152,
wherein the substrate (D) and/or the epitaxial layer (DEP1) comprises a silicon material, in particular a silicon crystal, and
where a nuclear quantum dot (CI) in the silicon material is the nucleus of a ²⁹Si isotope or other atom whose nucleus has a nonzero nucleus magnetic moment μ.

Feature 154. Silicon nuclear quantum bit (CQUB) according to one or more of the preceding features 149 to 153,
wherein the substrate (D) and/or the epitaxial layer (DEP1) comprises a silicon material, in particular a silicon crystal, and
wherein a nuclear quantum dot (CI) in the silicon material is the nucleus of a ²⁹Si isotope or other atom whose nucleus has a nonzero nucleus magnetic moment μ, and
wherein the ²⁹Si isotope or the other isotope having a non-zero nucleus magnetic moment μ is located immediately adjacent within coupling range to a G center in the silicon material or a paramagnetic impurity center, respectively, and
whereby the G-center or the paramagnetic perturbation center is a quantum dot (NV) in the sense of this writing.

Feature 155. Silicon nuclear quantum bit (CQUB) according to one or more of the preceding features 149 to 154,
wherein the substrate (D) and/or the epitaxial layer (DEP1) comprises a silicon material, in particular a silicon crystal, and a nuclear quantum dot (CI) is the nucleus of a ¹³C isotope or a ²⁹Si isotope of a G center in the silicon material.

Feature 156. Silicon nuclear quantum bit (CQUB) according to one or more of the preceding features 149 to 155,
wherein the substrate (D) and/or the epitaxial layer (DEP1) comprises a silicon material, in particular a silicon crystal, and
wherein the nuclear quantum dot (CI) is the nucleus of a ²⁹Si isotope, and
in which silicon material a G center or other paramagnetic center is located as a quantum dot (NV) near the ²⁹Si isotope,
wherein proximity here is understood to mean that the magnetic field of the nuclear spin of the ²⁹Si isotope can affect the spin of the electron configuration of the G center or the other paramagnetic center, and that the spin of the electron configuration of the G center or the other paramagnetic center can affect the nuclear spin of the ²⁹Si isotope.

Feature 137. Silicon nuclear quantum bit (CQUB) according to one or more of the preceding features 149 to 156,
wherein the substrate (D) and/or the epitaxial layer (DEP1) comprises a silicon material, in particular a silicon crystal, and
wherein the nuclear quantum dot (CI) is an isotope with a nonzero nucleus magnetic moment μ in the silicon material, and
wherein silicon material a G center or another paramagnetic center, in particular as a quantum dot (NV), is located near the isotope with nucleus magnetic moment μ.
wherein proximity here is to be understood as meaning that the nucleus magnetic moment μ of the nuclear spin of the isotope can influence the spin of the electron configuration of the G center or the other paramagnetic center, and that the spin of the electron configuration of the G center or the other paramagnetic center can influence the nuclear spin of the isotope.

Feature 158. Silicon nuclear quantum bit (CQUB) according to one or more of the preceding features 149 to 157,
wherein the substrate (D) and/or the epitaxial layer (DEP1) comprises a silicon material, in particular a silicon crystal, and
wherein the nuclear quantum dot (CI) is an isotope with a nuclear spin in the silicon material, and
wherein at least one other nuclear quantum dot (CI′) is an isotope having a nuclear spin in the silicon material, and
wherein a G center or other paramagnetic center is located in the silicon material in the vicinity of the nuclear quantum dot (CI); and
wherein the G center or the other paramagnetic center is located in the vicinity of the at least one, further nuclear quantum dot (CI′) in the silicon material,
wherein proximity hertz is to be understood in this way,
   that the magnetic field of the nuclear quantum dot (CI) can influence the spin of the electron configuration of the G center or the other paramagnetic center, and
   that the magnetic field of the at least one, further nuclear quantum dot (CI′) can influence the spin of the electron configuration of the G center or the other paramagnetic center, and
   that the spin of the electron configuration of the G center or the other paramagnetic center can influence the nuclear spin of the nuclear quantum dot (CI), and
   that the spin of the electron configuration of the G center or the other paramagnetic center can influence the nuclear spin of the at least one, further nuclear quantum dot (CI′).

Feature 159. Silicon-nuclear quantum bit (CQUB) according to feature 159,
wherein the coupling strength between a nuclear quantum bit (CI, CI′) and the electron configuration of the G center or the other paramagnetic center is in a range from 1 kHz to 200 GHz and/or 10 kHz to 20 GHz and/or 100 kHz to 2 GHz and/or 0.2 MHz to 1 GHz and/or 0.5 MHz to 100 MHz and/or 1 MHz to 50 MHz, in particular preferably 10 MHz.

Feature 160. Silicon-nuclear quantum bit (CQUB) according to one or more of the preceding features 149 to 159.
wherein the substrate (D) and/or the epitaxial layer (DEP1) comprises a silicon material, in particular a silicon crystal, and
wherein the silicon material comprises an epitaxially grown layer (DEP1) having essentially ²⁸Si isotopes and/or ³⁰Si isotopes.

Feature 161. Silicon-nuclear quantum bit (CQUB) according to one or more of the preceding features 149 to 160,
wherein the substrate (D) and/or the epitaxial layer (DEP1) comprises a silicon material, in particular a silicon crystal, and
wherein the silicon material comprises an essentially isotopically pure epitaxially grown layer (DEP1) essentially of ²⁸Si isotopes.

Feature 162. Silicon nuclear quantum bit (CQUB) according to one or more of the preceding features 149 to 161,
wherein the substrate (D) and/or the epitaxial layer (DEP1) is doped, in particular n-doped, in the region of the nuclear quantum dot (CI).

Feature 163. Silicon nuclear quantum bit (CQUB) according to one or more of the preceding features 149 to 142,
wherein the substrate (D) and/or the epitaxial layer (DEP1) comprises a silicon material, in particular a silicon crystal, and
wherein the substrate (D) or the epitaxial layer (DEP1) is doped in the region of the nuclear quantum dot (CI) with one or more of the following isotopes, namely
for n-doping with ²⁰Te, ¹²²Te, ¹²⁴Te, ¹²⁶Te, ¹²⁸Te, ¹³⁰Te, ⁴⁶Ti, ⁴⁸Ti, ⁵⁰Ti, ¹²C, ¹⁴C, ⁷⁴Se, ⁷⁶Se, ⁷⁸Se, ⁸⁰Se, ¹³⁰Ba, ¹³²Ba, ¹³⁴Ba, ¹³⁶Ba, ¹³⁸Ba, ³²S, ³⁴S, and ³⁶S or
for p-doping with ¹⁰Be, ¹⁰²Pd, ¹⁰⁴Pd, ¹⁰⁶Pd, ¹⁰⁸Pd, ¹¹⁰Pd, ²⁰⁴Tl.

Feature 164. Silicon nuclear quantum bit (CQUB) according to one or more of the preceding features 149 to 163.
wherein the substrate (D) and/or the epitaxial layer (DEP1) in the region of the nuclear quantum dot (CI) is essentially doped with isotopes having no nucleus magnetic moment.

Feature 165. Silicon nuclear quantum bit (CQUB) according to one or more of the preceding features 149 to 164,
wherein the substrate (D) and/or the epitaxial layer (DEP1) comprises a silicon material, in particular a silicon crystal, and
wherein the silicon material comprises essentially silicon isotopes having no nucleus magnetic moment μ and/or
wherein the silicon material comprises essentially only ²⁸Si isotopes and/or ³⁰Si silicon isotopes without nucleus magnetic moment μ and/or
where the silicon material essentially comprises only ²⁸Si isotopes with no nucleus magnetic moment μ.

Feature 166. Silicon nuclear quantum bit (CQUB) according to one or more of the preceding features 149 to 165,
wherein a resistive contact (KV11, KV12, KH11, KH12) and in particular its metallization comprises titanium.

### Silicon Carbide-Based Nucleus (Spin) Quantum Bit (CQUB) 167-184

Feature 167. Silicon carbide nuclear quantum bit (CQUB) according to one or more of the preceding features 103 to 129,
wherein the substrate (D) and/or the epitaxial layer (DEP1) comprises a silicon carbide material, in particular a silicon carbide crystal.

Feature 168. Silicon carbide-nuclear quantum bit (CQUB) according to feature 167,
wherein the substrate (D) and/or the epitaxial layer (DEP1) comprises a silicon carbide material, in particular a silicon carbide crystal, having a V_{Si} center and/or having a DV center and/or having a V_{C}V_{SI} center and/or having a CAV_{SI} center and/or having a N_{C}V_{SI} center in the silicon carbide material or another paramagnetic impurity center in the silicon carbide material as a quantum dot (NV).

Feature 169. Silicon carbide nuclear quantum bit (CQUB) according to one or more of the preceding features 167 to 168,
wherein the substrate (D) and/or the epitaxial layer (DEP1) comprises a silicon carbide material, in particular a silicon carbide crystal, and a quantum dot (NV) in the silicon carbide material, and
wherein the quantum dot (NV) comprises a vacancy in the silicon carbide material.

Feature 170. Silicon carbide nuclear quantum bit (CQUB) according to one or more of the preceding features 167 to 169,
wherein the substrate (D) and/or the epitaxial layer (DEP1) comprises a silicon carbide material, in particular a silicon crystal, and a quantum dot (NV) in the silicon carbide material, and
wherein the quantum dot (NV) comprises a vacancy or a C atom at a non-C position or a Si atom at a non-Si position or a Ge atom or a N atom or a P atom or an As atom or a Sb atom or a Bi atom or a Sn atom or a Mn atom or a F atom or any other atom which generates a paramagnetic impurity center in silicon carbide.

Feature 171. Silicon carbide nuclear quantum bit (CQUB) according to one or more of the preceding features 167 to 170,
wherein the substrate (D) and/or the epitaxial layer (DEP1) comprises a silicon carbide material, in particular a silicon carbide crystal, and
wherein a nuclear quantum dot (CI) in the silicon carbide material is the nucleus of a ¹³C isotope or the nucleus of a ²⁹Si isotope or other atom whose nucleus has a nonzero nucleus magnetic moment μ.

Feature 172. Silicon carbide nuclear quantum bit (CQUB) according to one or more of the preceding features 167 to 171,
wherein the substrate (D) and/or the epitaxial layer (DEP1) comprises a silicon carbide material, in particular a silicon carbide crystal, and
wherein a nuclear quantum dot (CI) in the silicon carbide material is the nucleus of a ¹³C isotope or the nucleus of a ²⁹Si isotope or another atom whose nucleus has a non-zero nucleus magnetic moment μ, and
wherein the ¹³C isotope or the ²⁹Si isotope or the other isotope having a non zero nucleus magnetic moment μ in is located immediately adjacent within coupling range to a V_{Si} center and/or a DV center and/or a V_{C}V_{SI} center or a CAV_{Si} center or a N_{C}V_{SI} center in the silicon carbide material or a paramagnetic impurity center, respectively, and
wherein the V_{Si} center or the DV center or the V_{C}V_{SI} center or the CAV_{Si} center or the N_{C}V_{SI} center or the paramagnetic impurity center, respectively, is a quantum dot (NV) in the sense of this writing.

Feature 173. Silicon carbide nuclear quantum bit (CQUB) according to one or more of the preceding features 167 to 172,
wherein the substrate (D) and/or the epitaxial layer (DEP1) comprises a silicon carbide material, in particular a silicon carbide crystal, and a nuclear quantum dot (CI) is the nucleus of a ¹³C isotope or a ²⁹Si isotope of a N_{C}V_{SI} center or a DV center or a V_{C}V_{SI} center or a CAV_{Si} center, respectively, in the silicon carbide material.

Feature 174. Silicon carbide nuclear quantum bit (CQUB) according to one or more of the preceding features 167 to 173,
wherein the substrate (D) and/or the epitaxial layer (DEP1) comprises a silicon carbide material, in particular a silicon carbide crystal, and a nuclear quantum dot (CI) is the nucleus of a ¹³C isotope or a ²⁹Si isotope or a ¹⁴N isotope or a ¹⁵N isotope of an N_{C}V_{SI} center in the silicon carbide material.

Feature 175. Silicon carbide nuclear quantum bit (CQUB) according to one or more of the preceding features 149 to 174,
wherein the substrate (D) and/or the epitaxial layer (DEP1) comprises a silicon carbide material, in particular a silicon carbide crystal, and
wherein the nuclear quantum dot (CI) is the nucleus of a ²⁹Si isotope or a ¹³C isotope, and
wherein in the silicon material a V_{Si} center or a DV center or a the V_{C}V_{SI} center or a CAV_{Si} center or a N_{C}V_{SI} center or another paramagnetic center is located as a quantum dot (NV) in the vicinity of the ²⁹Si isotope or the ¹³C isotope,
wherein proximity is to be understood here in such a way that the magnetic field of the nuclear spin of the ²⁹Si isotope or the ¹³C isotope can influence the spin of the electron configuration of the V_{Si} center or the DV center or the V_{C}V_{SI} center or the CAV_{Si} center or the N_{C}V_{SI} center or the other paramagnetic center, respectively, of the other paramagnetic center, respectively, and that the spin of the electron configuration of the V_{Si} center or the DV center or the V_{C}V_{SI} center or the CAV_{Si} center or the N_{C}V_{SI} center or the other paramagnetic center, respectively, can influence the nuclear spin of the ²⁹Si isotope or the ¹³C isotope, respectively.

Feature 176. Silicon carbide nuclear quantum bit (CQUB) according to one or more of the preceding features 167 to 175,
wherein the substrate (D) and/or the epitaxial layer (DEP1) comprises a silicon carbide material, in particular a silicon carbide crystal, and
wherein the nuclear quantum dot (CI) is an isotope with a nonzero nucleus magnetic moment μ in the silicon carbide material, and
wherein in the silicon carbide material a V_{Si} center or a DV center or a the V_{C}V_{SI} center or a CAV_{Si} center or a N_{C}V_{SI} center or another paramagnetic center, in particular as a quantum dot (NV), is located in the vicinity of the isotope with the nucleus magnetic moment μ.
wherein proximity is to be understood here in such a way that the nucleus magnetic moment μ of the nuclear spin of the isotope can influence the spin of the electron configuration of the V_{Si} center or the DV center or the V_{C}V_{SI} center or the CAV_{Si} center or the N_{C}V_{SI} center or the other paramagnetic center, respectively of the other paramagnetic center, respectively, and that the spin of the electron configuration of the V_{Si} center or the DV center or the V_{C}V_{SI} center or the CAV_{Si} center or the N_{C}V_{SI} center or the other paramagnetic center, respectively, can influence the nuclear spin of the isotope.

Feature 177. Silicon carbide nuclear quantum bit (CQUB) according to one or more of the preceding features 167 to 176
wherein the substrate (D) and/or the epitaxial layer (DEP1) comprises a silicon carbide material, in particular a silicon carbide crystal, and
wherein the nuclear quantum dot (CI) is an isotope with a nuclear spin in the silicon carbide material, and
wherein at least one other nuclear quantum dot (CI′) is an isotope having a nuclear spin in the silicon carbide material, and
wherein in the silicon material a V_{Si} center or a DV center or a V_{C}V_{SI} center or a CAV_{Si} center or a N_{C}V_{SI} center or another paramagnetic center is located in the vicinity of the nuclear quantum dot (CI), and
wherein the Vs center or the DV center or the V_{C}V_{SI} center or the CAV_{Si} center or the N_{C}V_{SI} center or the other paramagnetic center is located in the vicinity of the at least one, further nuclear quantum dot (CI′) in the silicon carbide material,
wherein proximity here is to be understood in this way,
   that the magnetic field of the nuclear quantum dot (CI) can influence the spin of the electron configuration of the V_{Si} center or the DV center or the V_{C}V_{SI} center or the CAV_{Si} center or the N_{C}V_{SI} center or the other paramagnetic center, and
   that the magnetic field of the at least one, further nuclear quantum dot (CI′) can influence the spin of the electron configuration of the V_{Si} center or the DV center or the V_{C}V_{SI} center or the CAV_{Si} center or the N_{C}V_{SI} center or the other paramagnetic center, and
   that the spin of the electron configuration of the V_{Si} center or the DV center or the V_{C}V_{SI} center or the CAV_{Si} center or the N_{C}V_{SI} center or the other paramagnetic center can influence the nuclear spin of the nuclear quantum dot (CI), and
   that the spin of the electron configuration of the V_{Si} center or the DV center or the V_{C}V_{SI} center or the CAV_{Si} center or the N_{C}V_{SI} center or the other paramagnetic center, respectively, can influence the nuclear spin of the at least one, further nuclear quantum dot (CI′).

Feature 178. Silicon carbide-nuclear quantum bit (CQUB) according to feature 177
wherein the coupling strength between a nuclear quantum bit (CI, CI′) and the electron configuration of the Vsi center or the DV center or the V_{C}V_{SI} center or the CAV_{Si} center or the N_{C}V_{SI} center or of the other paramagnetic center lies in a range from 1 kHz to 200 GHz and/or 10 kHz to 20 GHz and/or 100 kHz to 2 GHz and/or 0.2 MHz to 1 GHz and/or 0.5 MHz to 100 MHz and/or 1 MHz to 50 MHz, in particular preferably 10 MHz.

Feature 179. Silicon carbide nuclear quantum bit (CQUB) according to one or more of the preceding features 167 to 178,
wherein the substrate (D) and/or the epitaxial layer (DEP1) comprises a silicon carbide material, in particular a silicon carbide crystal, and
wherein the silicon carbide material comprises an epitaxially grown layer (DEP1) having essentially ²⁸Si isotopes and/or ³⁰Si isotopes and essentially ¹²C isotopes and/or ¹⁴C isotopes.

Feature 180. Silicon carbide nuclear quantum bit (CQUB) according to one or more of the preceding features 167 to 179,
wherein the substrate (D) and/or the epitaxial layer (DEP1) comprises a silicon carbide material, in particular a silicon carbide crystal, and
wherein the silicon carbide material comprises an essentially isotopically pure epitaxially grown layer (DEP1) essentially of ²⁸Si isotopes and ¹²C isotopes.

Feature 181. Silicon carbide nuclear quantum bit (CQUB) according to one or more of the preceding features 167 to 180,
wherein the substrate (D) and/or the epitaxial layer (DEP1) is doped, in particular n-doped, in the region of the nuclear quantum dot (CI).

Feature 182. Silicon carbide nuclear quantum bit (CQUB) according to one or more of the preceding features 167 to 181,
wherein the substrate (D) and/or the epitaxial layer (DEP1) in the region of the nuclear quantum dot (CI) is essentially doped with isotopes having no nucleus magnetic moment.

Feature 183. A silicon carbide nuclear quantum bit (CQUB) according to any one or more of the preceding features 167 to 182.
wherein the substrate (D) and/or the epitaxial layer (DEP1) comprises a silicon carbide material, in particular a silicon carbide crystal, and
wherein the silicon carbide material comprises essentially silicon isotopes or carbon without a nucleus magnetic moment μ, and/or
wherein the silicon carbide material comprises essentially only ²⁸Si isotopes and/or ³⁰Si silicon isotopes having no nucleus magnetic moment μ and/or
wherein the silicon carbide material comprises essentially only ¹²C isotopes and/or ¹⁴C silicon isotopes having no nucleus magnetic moment μ and/or
wherein the silicon material comprises essentially only ²⁸Si isotopes having no nucleus magnetic moment μ and essentially only ¹²C isotopes having no nucleus magnetic moment μ.

Feature 184. Silicon carbide nuclear quantum bit (CQUB) according to one or more of the preceding features 167 to 183,
wherein a resistive contact (KV11, KV12, KH11, KH12) and in particular its metallization comprises titanium.

### Solid Mix Crystal Based Nucleus (Spin) Quantum Bit (CQUB) 185-202

Feature 185. A mixed crystal based nuclear quantum bit (CQUB) according to one or more of the preceding features 103 to 129,
whereas the mixed crystal comprising, apart from quantum dots (NV) and nuclear quantum dots (CI) and dopants, essentially one element of main group IV of the periodic table, i.e., being only a crystal without mixture with other elements, or
whereby, apart from quantum dots (NV) and nuclear quantum dots (CI) and dopants, the mixed crystal essentially comprises atoms of several different elements of the IV main group of the periodic table.

Feature 186. Mixed crystal based nuclear quantum bit (CQUB) by feature 185,
wherein the mixed crystal essentially comprising, apart from quantum dots (NV) and nuclear quantum dots (CI) and dopants, atoms of two different elements of main group IV of the periodic table, or
wherein, apart from quantum dots (NV) and nuclear quantum dots (CI) and dopants, the mixed crystal essentially comprises atoms of three different elements of main group IV of the periodic table, or
wherein the mixed crystal essentially comprising, apart from quantum dots (NV) and nuclear quantum dots (CI) and dopants, atoms of four different elements of the IV^{th} main group of the periodic table.

Feature 187. A mixed crystal based nuclear quantum bit (CQUB) according to one or more of the preceding features 185 to 186 and according to feature 185,
wherein the substrate (D) or epitaxial layer (DEP1) comprises a mixed crystal according to feature 185, and
wherein the substrate (D) and/or the epitaxial layer (DEP1) comprises a paramagnetic impurity center in the mixed crystal as a quantum dot (NV).

Feature 188. A mixed crystal based nuclear quantum bit (CQUB) according to one or more of the preceding features 185 to 186 and according to feature 185,
wherein the substrate (D) and/or the epitaxial layer (DEP1) comprises a mixed crystal and a quantum dot (NV) in the mixed crystal, and
wherein the quantum dot (NV) comprises a vacancy in the mixed crystal.

Feature 189. A mixed crystal based nuclear quantum bit (CQUB) according to one or more of the preceding features 183 to 188 and according to feature 185,
wherein the substrate (D) and/or the epitaxial layer (DEP1) comprises a mixed crystal according to feature 185 and a quantum dot (NV) in the mixed crystal, and
wherein the quantum dot (NV) comprises a vacancy or a C atom at a non-C position or a Si atom at a non-Si position or a Ge atom or a N atom or a P atom or an As atom or a Sb atom or a Bi atom or a Sn atom or a Mn atom or a F atom or any other atom that generates a paramagnetic impurity center in silicon carbide.

Feature 190. A mixed crystal based nuclear quantum bit (CQUB) according to one or more of the preceding features 185 to 189 and according to feature 185,
wherein the substrate (D) and/or the epitaxial layer (DEP1) comprises a mixed crystal according to feature 185, and
wherein a nuclear quantum dot (CI) in the mixed crystal is one or more isotopes of the isotopes ¹³C, ²⁹Si, ⁷³Ge, ¹¹⁵Sn, ¹¹⁷Sn, ¹¹⁹Sn, ²⁰⁷Pb and/or one or more isotopes of the isotopes WITH a non-zero nucleus magnetic moment μ.

Feature 191. A mixed crystal based nuclear quantum bit (CQUB) according to one or more of the preceding features 185 to 190 and according to feature 185,
wherein the substrate (D) and/or the epitaxial layer (DEP1) comprises a mixed crystal according to feature 185, and
wherein a nuclear quantum dot (CI) in the mixed crystal is the nucleus of a ¹³C isotope or the nucleus of a ²⁹Si isotope and/or a ⁷³Ge isotope and/or a ¹¹⁵Sn isotope and/or a ¹¹⁷Sn isotope and/or a ¹¹⁹Sn isotope and/or a ²⁰⁷Pb isotope or another isotope whose nucleus has a non-zero nucleus magnetic moment μ, and
wherein said nucleus with a non-zero nucleus magnetic moment μ is located in immediately adjacent coupling range to a paramagnetic impurity center in the mixed crystal, and
whereby the paramagnetic perturbation center is a quantum dot (NV) for the purposes of this writing.

Feature 192. A mixed crystal based nuclear quantum bit (CQUB) according to one or more of the preceding features 185 to 191 and according to feature 185,
wherein the substrate (D) and/or the epitaxial layer (DEP1) comprises a mixed crystal according to feature 185, and
wherein a nuclear quantum dot (CI) is the atomic nucleus isotope with a nonzero nucleus magnetic moment μ that is part of a paramagnetic center of a quantum dot (N) in the mixed crystal.

Feature 193. A mixed crystal based nuclear quantum bit (CQUB) according to one or more of the preceding features 185 to 192 and according to feature 185,
wherein the substrate (D) and/or the epitaxial layer (DEP1) comprises a mixed crystal according to feature 185, and
wherein a nuclear quantum dot (CI) is the atomic nucleus isotope with a nonzero nucleus magnetic moment μ in the mixed crystal.

Feature 194. A mixed crystal based nuclear quantum bit (CQUB) according to one or more of the preceding features 185 to 193 and according to feature 185,
wherein the substrate (D) and/or the epitaxial layer (DEP1) comprises a mixed crystal according to feature 185, and
wherein the nuclear quantum dot (CI) is the nucleus of an isotope having a non-zero nucleus magnetic moment μ in the mixed crystal, and
wherein in the mixed crystal a paramagnetic center is arranged as a quantum dot (NV) near the atomic nucleus,
wherein proximity here is to be understood as the magnetic field of the nuclear spin of the nucleus can influence the spin of the electron configuration of the paramagnetic center, and the spin of the electron configuration of the paramagnetic center can influence the nuclear spin of the nucleus.

Feature 195. A mixed crystal based nuclear quantum bit (CQUB) according to one or more of the preceding features 185 to 194 and according to feature 185,
wherein the substrate (D) and/or the epitaxial layer (DEP1) comprises a mixed crystal according to feature 185, and
wherein the nuclear quantum dot (CI) is an isotope having a non-zero nucleus magnetic moment in the mixed crystal, and
wherein in the mixed crystal a paramagnetic center, in particular as a quantum dot (NV), is located near the isotope with nucleus magnetic moment μ,
where proximity here is to be understood as the nucleus magnetic moment μ of the nuclear spin of the isotope can influence the spin of the electron configuration of the paramagnetic center and the spin of the electron configuration of the paramagnetic center can influence the nuclear spin of the isotope.

Feature 196. A mixed crystal based nuclear quantum bit (CQUB) according to one or more of the preceding features 185 to 195 and according to feature 185,
wherein the substrate (D) and/or the epitaxial layer (DEP1) comprises a mixed crystal according to feature 185, and
wherein the nuclear quantum dot (CI) is an isotope having a nuclear spin in the mixed crystal, and
wherein at least one other nuclear quantum dot (CI′) is an isotope having a nuclear spin in the mixed crystal, and
wherein in the mixed crystal a paramagnetic center is located near the nuclear quantum dot (CI), and
wherein the paramagnetic center is located near the at least one, further nuclear quantum dot (CI′) in the mixed crystal.
wherein proximity here is to be understood in this way,
   that the magnetic field of the nuclear quantum dot (CI) can influence the spin of the electron configuration of the paramagnetic center, and
   that the magnetic field of the at least one, further nuclear quantum dot (CI′) can influence the spin of the electron configuration of the paramagnetic center, and
   that the spin of the electron configuration of the paramagnetic center can influence the nuclear spin of the nuclear quantum dot (CI), and that the spin of the electron configuration of the paramagnetic center can influence the nuclear spin of the at least one, further nuclear quantum dot (CI′).

Feature 197. Mixed crystal based nuclear quantum bit (CQUB) according to feature 196,
wherein the coupling strength between a nuclear quantum bit (CI, CI′) and the electron configuration of the paramagnetic center is in a range from 1 kHz to 200 GHz and/or 10 kHz to 20 GHz and/or 100 kHz to 2 GHz and/or 0.2 MHz to 1 GHz and/or 0.5 MHz to 100 MHz and/or 1 MHz to 50 MHz, in particular preferably 10 MHz.

Feature 198. A mixed crystal based nuclear quantum bit (CQUB) according to one or more of the preceding features 185 to 197 and according to feature 185,
wherein the substrate (D) and/or the epitaxial layer (DEP1) comprises a mixed crystal according to feature 185, and
wherein the silicon carbide material comprises an epitaxially grown layer (DEP1) essentially comprising isotopes of the IV^{th} main group without magnetic moment and/or essentially comprising one or more isotopes of the following list: ²⁸Si, ³⁰Si, ¹²C, ¹⁴C, ⁷⁰Ge, ⁷²Ge, ⁷⁴Ge, ⁷⁶Ge, ¹¹²Sn, ¹¹⁴Sn, ¹¹⁶Sn, ¹¹⁸Sn, ¹²⁰Sn, ¹²²Sn, ¹²⁴Sn.

Feature 199. A mixed crystal based nuclear quantum bit (CQUB) according to one or more of the preceding features 185 to 198 and according to feature 185,
wherein the substrate (D) and/or the epitaxial layer (DEP1) comprises a mixed crystal according to feature 185, and
wherein the mixed crystal comprises an essentially isotopically pure epitaxially grown layer (DEP1) of essentially ²⁸Si isotopes and/or ¹²C isotopes and/or ⁷⁰Ge isotopes and/or ⁷²Ge isotopes and/or ⁷⁴Ge isotopes and/or ¹¹⁶Sn isotopes and/or ¹¹⁸Sn isotopes and/or ¹²⁰Sn isotopes, the term isotopically pure referring only to the atoms of the respective element of the mixture of elements forming the mixed crystal.

Feature 200. A mixed crystal based nuclear quantum bit (CQUB) according to one or more of the preceding features 185 to 199 and according to feature 185,
wherein the substrate (D) and/or the epitaxial layer (DEP1) is doped, in particular n-doped, in the region of the nuclear quantum dot (CI).

Feature 201. A mixed crystal based nuclear quantum bit (CQUB) according to one or more of the preceding features 185 to 200 according to feature 185,
whereby the substrate (D) and/or the epitaxial layer (DEP1) in the region of the nuclear quantum dot (CI) is essentially doped with isotopes having no nucleus magnetic moment.

Feature 202. A mixed crystal based nuclear quantum bit (CQUB) according to one or more of the preceding features 185 to 201 and according to feature 185,
wherein a resistive contact (KV11, KV12, KH11, KH12) and in particular its metallization comprises titanium.

Register Constructions 203-215

### Nucleus-Electron Quantum Register (CEQUREG) 203-215

Feature 203. Nucleus-electron quantum register (CEQUREG).
comprising a nuclear quantum bit (CQUB) according to one or more of features 103 to 202 and
comprising a quantum bit (QUB) according to one or more of the features 1 to 102 and
wherein the substrate (D) or epitaxial layer (DEP1) of the nuclear quantum bit (CQUB) and the quantum bit (QUB) are the same.

Feature 204. Nucleus-electron quantum register (CEQUREG) according to feature 203,
wherein the device for controlling a nuclear quantum dot (CI) nuclear quantum bit (CQUB) comprises a sub-device (LH, LV) which is also a sub-device (LH, LV) of the device for controlling a quantum dot (NV) of the quantum bit (QUB).

Feature 205. Nucleus-electron quantum register (CEQUREG) according to one or more of features 203 to 204,
comprising a device for controlling the nuclear quantum dot (CI) of the nuclear quantum bit (CQUB) and for simultaneously controlling the quantum dot (NV) of the quantum bit (QUB),
with a common substrate (D) of the nuclear quantum bit (CQUB) and the quantum bit (QUB), and
if necessary, with a common epitaxial layer (DEP1) of the nuclear quantum bit (CQUB) and the quantum bit (QUB), and
with a common device of the nuclear quantum bit (CQUB) and the quantum bit (QUB),
   suitable for generating an electromagnetic wave field (nay, maw) at the location of the nuclear quantum dot (CI) and at the location of the quantum dot (CI),
wherein the common epitaxial layer (DEN), if present, is deposited on the common substrate (D), and
wherein the common substrate (D) and/or the common epitaxial layer (DEP1), if present, has a surface (OF) and
wherein the nuclear quantum dot (CI) has a magnetic moment, and
wherein the quantum dot (NV) is a paramagnetic center in the common substrate (D) and/or in the common epitaxial layer (DEP1), if present, and
wherein the common device suitable for generating an electromagnetic wave field (B_{RW}, B_{MW}) is located on the surface of the common substrate (D) and/or the common epitaxial layer (DEP1), if present, and

Feature 206. Nucleus-electron quantum register (CEQUREG) according to one or more of features 203 to 205,
wherein the common device suitable for generating an electromagnetic wave field (B_{RW}, B_{MW}) is firmly connected to the surface (OF) of the common substrate (D) and/or the common epitaxial layer (DEP1), if present, directly or indirectly via one or more insulations (IS, IS2).

Feature 207. Nucleus-electron quantum register (CEQUREG) according to one or more of features 203 to 206,
wherein the device suitable for generating a circularly polarized electromagnetic wave field (B_{RW}, B_{MW}) is suitable for generating a circularly polarized electromagnetic wave field (B_{RW}, B_{MW}).

Feature 208. Nucleus-electron quantum register (CEQUREG) according to one or more of features 203 to 205,
wherein a solder can be precipitated along a perpendicular line (LOT) from the location of the nuclear quantum dot (CI) and/or from the location of the quantum dot (NV) to the surface (OF) of the substrate (D) and/or the epitaxial layer (DEP1), if present, and
wherein the perpendicular line (LOT) pierces the surface (OF) of the substrate (D) and/or the epitaxial layer (DEP1), if present, at a perpendicular point (LOTP), and
wherein the device used to generate a circularly polarized radio wave field is located near the plumb point (LOTP) or at the plumb point (LOTP).

Feature 209. Nucleus-electron quantum register (CEQUREG) according to one or more of features 205 to 208,
with a horizontal line (LH) and
with a vertical line (LV),
where the horizontal line (LH) and the vertical line (LV) are located on the surface of the substrate (D) and/or the epitaxial layer (DEP1), if present.

Feature 210. Nucleus-electron quantum register (CEQUREG) according to feature 209,
wherein the horizontal line (LH) and the vertical line (LV) cross near the plumb point (LOTP) or at the plumb point (LOTP) at a non-zero crossing angle (α).

Feature 211. Nucleus-electron quantum register (CEQUREG) according to one or more of features 209 to 210,
wherein the horizontal line (LH) is electrically isolated from the vertical line (LV).

Feature 212. Nucleus-electron quantum register (CEQUREG) according to one or more of features 209 to 211,
wherein the horizontal line (LH) is electrically isolated from the vertical line (LV) by means of electrical insulation (IS).

Feature 213. Nucleus-electron quantum register (CEQUREG) according to one or more of features 209 to 212,
wherein the horizontal line (LH) and/or the vertical line (LV) is transparent to green light, and
wherein in particular the horizontal line (LH) and/or the vertical line (LV) is made of an electrically conductive material that is optically transparent to green light, in particular of indium tin oxide (common abbreviation ITO).

Feature 214. Nucleus-electron quantum register (CEQUREG) according to one or more of features 210 to 213,
wherein an angle (α) is essentially a right angle.

Feature 215. Nucleus-electron quantum register (CEQUREG) according to one or more of features 209 to 214,
wherein the substrate (D) comprises diamond
wherein the nuclear quantum dot (CI) is the nucleus of a ¹³C isotope, and
wherein the quantum dot (NV) is located near the ¹³C isotope, and
wherein the quantum dot (NV) is in particular an NV center or another paramagnetic impurity center, and
wherein proximity here is to be understood as the magnetic field of the nuclear spin of the ¹³C isotope can influence the spin of an electron configuration of the quantum dot (NV), in particular via a dipole-dipole interaction, and the spin of an electron configuration of the quantum dot (NV) can influence the nuclear spin of the ¹³C isotope, in particular via a dipole-dipole interaction.

Feature 216. Nucleus-electron quantum register (CEQUREG) according to one or more of features 209 to 214,
wherein the substrate (D) comprises a silicon material, in particular a silicon crystal
wherein the nuclear quantum dot (CI) is the nucleus of a ²⁹Si isotope, and
wherein the quantum dot (NV) is located near the ²⁹Si isotope, and
wherein the quantum dot (NV) is in particular a G-center or other paramagnetic perturbation center, and
wherein proximity here is to be understood as the magnetic field of the nuclear spin of the ²⁹Si isotope can influence the spin of an electron configuration of the quantum dot (NV), in particular via a dipole-dipole interaction, and that the spin of an electron configuration of the quantum dot (NV) can influence the nuclear spin of the ²⁹Si isotope, in particular via a dipole-dipole interaction.

Feature 217. Nucleus-electron quantum register (CEQUREG) according to one or more of features 209 to 214,
wherein the substrate (D) comprises a silicon carbide material, in particular a silicon carbide crystal
wherein the nuclear quantum dot (CI) is the nucleus of a ²⁹Si isotope or the nucleus of a ¹³C isotope; and
wherein the quantum dot (NV) is located near the ²⁹Si isotope or the ¹³C isotope, and
wherein the quantum dot (NV) is in particular a V_{Si} center and/or a DV center and/or a V_{C}V_{SI} center and/or a CAV_{Si} center and/or a N_{C}V_{SI} center in the silicon carbide material or another paramagnetic impurity center in the silicon carbide material, and
wherein proximity here is to be understood as meaning that the magnetic field of the nuclear spin of the ²⁹Si isotope or the IT isotope can influence the spin of an electron configuration of the quantum dot (NV), in particular via a dipole-dipole interaction, and that the spin of an electron configuration of the quantum dot (NV) can influence the nuclear spin of the ²⁹Si isotope, or the ¹³C isotope, in particular via a dipole-dipole interaction.

Feature 218. Nucleus-electron quantum register (CEQUREG) according to one or more of features 209 to 214,
wherein the substrate (D) comprises a mixed crystal essentially comprising one or more elements of the IV, main group of the periodic table
wherein the nuclear quantum dot (CI) is the nucleus of an element of main group IV of the periodic table with nonzero nucleus magnetic moment μ, and
whereby the quantum dot (NV) is located near this atomic nucleus, and
wherein the quantum dot (NV) is in particular a paramagnetic impurity center in the mixed crystal, and
wherein proximity here is to be understood as meaning that the magnetic field of the nuclear spin of the atomic nucleus can influence the spin of an electron configuration of the quantum dot (NV), in particular via a dipole-dipole interaction, and that the spin of an electron configuration of the quantum dot (NV) can influence the nuclear spin of the atomic nucleus via a dipole-dipole interaction.

Feature 219. Nucleus-electron quantum register (CEQUREG) according to one or more of features 209 to 218,
wherein the quantum dot (NV) is a paramagnetic center with a charge carrier or charge carrier configuration and is located in the vicinity of the nuclear quantum dot (CI), and
wherein the charge carrier or charge carrier configuration has a charge carrier spin state; and
wherein the nuclear quantum dot (CI) has a nuclear spin state and
wherein proximity here is to be understood in this way,
   that the nuclear spin state can influence the charge carrier spin state and/or
   that the charge carrier spin state can influence the nuclear spin state and/or
   that the frequency range of the coupling strength is at least 1 kHz and/or at least 1 MHz and less than 20 MHz and/or.
   in that the frequency range of the coupling strength is 1 kHz to 200 GHz and/or 10 kHz to 20 GHz and/or 100 kHz to 2 GHz and/or 0.2 MHz to 1 GHz and/or 0.5 MHz to 100 MHz and/or 1 MHz to 50 MHz, in particular preferably 10 MHz.

### Quantum Alu (QUALU) 220-221

Feature 220. Quantum ALU (QUALU)
comprising a first nuclear quantum bit (CQUB1) according to one or more of features 103 to 202 and
comprising at least one second nuclear quantum bit (CQUB2) according to one or more of features 103 to 202 and
comprising a quantum bit (QUB) according to one or more of the features 1 to 102,
wherein the first nuclear quantum bit (CQUB1) forms with the quantum bit (QUB) a first nucleus-electron quantum register (CEQUREG1) according to one or more of features 203 to 215 and
wherein the second nuclear quantum bit (CQUB2) forms with the quantum bit (QUB) a second nucleus-electron quantum register (CEQUREG2) according to one or more of features 203 to 215.

Feature 221. Quantum ALU (QUALU) according to feature 220,
wherein the device for controlling the first nuclear quantum dot (CI1) of the first nuclear quantum bit (CQUB1) of the first nucleus-electron quantum register (CEQUREG1) comprises a sub-device (LH, LV) which is also the sub-device (LH, LV) of the device for controlling the quantum dot (NV) of the quantum bit (QUB) of the first nucleus-electron quantum register (CEQUREG1), and
wherein the-device for controlling the second nuclear quantum dot (CI2) of the second nuclear quantum bit (CQUB2) of the second nucleus-electron quantum register (CEQUREG2) comprises the sub-device (LH, LV) which is also the sub-device (LH, LV) of the device for controlling the quantum dot (NV) of the quantum bit (QUB) of the second nucleus-electron quantum register (CEQUREG2), and
wherein the device for controlling the second nuclear quantum dot (CI2) of the second nuclear quantum bit (CQUB2) of the second nucleus-electron quantum register (CEQUREG2) comprises the sub-device (LH, LV) which is also the sub-device (LH, LV) of the device of the first nuclear quantum dot (CI1) of the first nuclear quantum bit (CQUB1) of the first nucleus-electron quantum register (CEQUREG1).

### Electron-A1-Electron-A2-Quantum Register (QUREG) 222-240

Feature 222. Quantum Register (QUREG)
with a first quantum bit (QUB1) according to one or more of the preceding features 1 to 102 and
with at least one second quantum bit (QUB2) according to one or more of the preceding features 1 to 102,
wherein the first quantum dot type of the first quantum dot (NV1) of the first quantum bit (QUB1) is equal to the second quantum dot type of the second quantum dot (NV2) of the second quantum bit (QUB2).

Feature 223. Quantum register (QUREG) according to the previous feature
wherein the substrate (D) or epitaxial layer (DEP1) is common to the first quantum bit (QUB1) and the second quantum bit (QUB2); and
wherein the quantum dot (NV) of the first quantum bit (QUB1) is the first quantum dot (NV1), and
wherein the quantum dot (NV) of the second quantum bit (QUB2) is the second quantum dot (QUB2) and
whereby the horizontal line (LH) of the first quantum bit (QUB)) is referred to as the first horizontal line (LH1) in the following, and
where the horizontal line (LH) of the second quantum bit (QUB2) is the said first horizontal line (LH1) and
whereby the vertical line (LV) of the first quantum bit (QUB1) is referred to as the first vertical line (LV1) in the following, and
whereby the vertical line (LV) of the second quantum bit (QUB2) will be referred to as the second vertical line (LV2) in the following.

Feature 224. Quantum register (QUREG) according to one or more of the features 222 to 223,
wherein the magnetic field and/or the state of the second quantum dot (NV2) of the second quantum bit (QUB2) influences the behavior of the first quantum dot (NV1) of the first quantum bit (QUB1) at least temporarily and/or
wherein the magnetic field and/or the state of the first quantum dot (NV1) of the first quantum bit (QUB1) influences the behavior of the second quantum dot (NV2) of the second quantum bit (QUB2) at least temporarily.

Feature 225. Quantum register (QUREG) according to one or more of the features 222 to 224,
wherein the spatial distance (sp12) between the first quantum dot (NV1) of the first quantum bit (QUB1) and the second quantum dot (NV2) of the second quantum bit (QUB2) is so small.
that the magnetic field and/or the state of the second quantum dot (NV2) of the second quantum bit (QUB2) influences the behavior of the first quantum dot (NV1) of the first quantum bit (QUB1) at least temporarily, and/or
that the magnetic field and/or the state of the first quantum dot (NV1) of the first quantum bit (QUB1) influences the behavior of the second quantum dot (NV2) of the second quantum bit (QUB2) at least temporarily.

Feature 226. Quantum register (QUREG) according to one or more of the features 222 to 225,
wherein the spatial distance (sp12) between the first quantum dot (NV1) of the first quantum bit (QUB1) and the second quantum dot (NV2) of the second quantum bit (QUB2) is less than 50 nm and/or less than 30 nm and/or less than 20 nm and/or less than 10 nm and/or less than 5 nm and more than 2 nm.

Feature 227. Quantum register (QUREG) according to one or more of the features 222 to 226,
with at least a third quantum bit (QUB3) according to one or more of the preceding features 1 to 102.

Feature 228. Quantum register (QUREG) according to feature 207
wherein the first quantum dot type of the first quantum dot (NV1) of the first quantum bit (QUB1) is equal to the third quantum dot type of the third quantum dot (NV3) of the third quantum bit (QUB3).

Feature 229. Quantum register (QUREG) according to one or more of features 227 to 228 and according to feature 223,
wherein the substrate (D) or epitaxial layer (DEP1) is common to the first quantum bit (QUB1) and the third quantum bit (QUB3); and
wherein the quantum dot (NV) of the third quantum bit (QUB3) is the third quantum dot (NV3) and
where the horizontal line (LH) of the third quantum bit (QUB3) is the said first horizontal line (LH1) and
whereby the vertical line (LV) of the third quantum bit (QUB3) will be refereed to as the third vertical line (LV3) in the following.

Feature 230. Quantum register (QUREG) according to one or more of the features 227 to 229,
wherein the magnetic field and/or the state of the second quantum dot (NV2) of the second quantum bit (QUB2) influences the behavior of the third quantum dot (NV3) of the third quantum bit (QUB3) at least temporarily and/or
wherein the magnetic field and/or the state of the third quantum dot (NV3) of the third quantum bit (QUB3) influences the behavior of the second quantum dot (NV2) of the second quantum bit (QUB2) at least temporarily.

Feature 231. Quantum register (QUREG) according to one or more of the features 227 to 230
wherein the magnetic field and/or the state of the first quantum dot (NV1) of the first quantum bit (QUB1) essentially does not influence the behavior of the third quantum dot (NV3) of the third quantum bit (QUB3) at least temporarily, and/or
wherein the magnetic field and/or the state of the third quantum dot (NV3) of the third quantum bit (QUB3) essentially does not affect the behavior of the first quantum dot (NV1) of the first quantum bit (QUB1), at least temporarily,
whereby “essentially” is to be understood here in such a way that the influencing that does take place is insignificant for the technical result in the majority of cases.

Feature 232. Quantum register (QUREG) according to one or more of the features 222 to 231,
wherein the spatial distance (sp13) between the first quantum dot (NV1) of the first quantum bit (QUB1) and the third quantum dot (NV3) of the third quantum bit (QUB3) is.
that the magnetic field and/or the state of the third quantum dot (NV3) of the third quantum bit (QUB3) essentially does not directly influence the behavior of the first quantum dot (NV1) of the first quantum bit (QUB1), at least at times, and/or
that the magnetic field and/or the state of the first quantum dot (NV1) of the first quantum bit (QUB1) essentially does not directly influence the behavior of the third quantum dot (NV3) of the third quantum bit (QUB3) at least temporarily,
wherein “essentially” is to be understood here as meaning that the influencing that does take place is insignificant for the technical result in the majority of cases, and
wherein “not directly” means that an influence, if any, can only occur indirectly by means of ancilla quantum dots or ancilla quantum bits.

Feature 233. Quantum register (QUREG) according to one or more of features 227 to 232,
wherein the spatial distance (sp23) between the third quantum dot (NV3) of the third quantum bit (QUB3) and the second quantum dot (NV2) of the second quantum bit (QUB2) is so small,
that the magnetic field and/or the state of the second quantum dot (NV2) of the second quantum bit (QUB2) influences the behavior of the third quantum dot (NV3) of the third quantum bit (QUB3) at least temporarily, and/or
that the magnetic field and/or the state of the third quantum dot (NV3) of the third quantum bit (QUB3) influences the behavior of the second quantum dot (NV2) of the second quantum bit (QUB2) at least temporarily.

Feature 234. Quantum register (QUREG) according to one or more of the features 227 to 233,
wherein the spatial distance (sp23) between the third quantum dot (NV3) of the third quantum bit (QUB3) and the second quantum dot (NV2) of the second quantum bit (QUB2) is less than 50 nm and/or less than 30 nm and/or less than 20 nm and/or less than 10 nm and/or less than 5 nm and more than 2 nm.

Feature 235. Quantum register (QUREG) according to one or more of the features 222 to 234,
wherein the device (LH1, LV1) of the first quantum bit (QUB1) for controlling the first quantum dot (NV1) of the first quantum bit (QUB1) can influence the first quantum dot (NV1) of the first quantum bit (QUB1) with a first probability, and
wherein the device (LH1, LV1) of the first quantum bit (QUB1) for controlling the first quantum dot (NV1) of the first quantum bit (QUB1) can influence the second quantum dot (NV2) of the second quantum bit (QUB2) with a second probability, and
wherein the device (LH2, LV2) of the second quantum bit (QUB2) for controlling the second quantum dot (NV2) of the second quantum bit (QUB2) can influence the first quantum dot (NV1) of the first quantum bit (QUB1) with a third probability, and
wherein the device (LH2, LV2) of the second quantum bit (QUB2) for controlling the second quantum dot (NV2) of the second quantum bit (QUB2) can influence the second quantum dot (NV2) of the second quantum bit (QUB2) with a fourth probability, and
wherein the first probability is greater than the second probability, and
wherein the first probability is greater than the third probability, and
wherein the fourth probability is greater than the second probability, and
wherein the fourth probability is greater than the third probability.

Feature 236. Quantum register (QUREG) according to one or more of the features 222 to 235,
wherein the device (LH1, LV1) of the first quantum bit (QUB1) for controlling the first quantum dot (NV1) of the first quantum bit (QUB1) can selectively influence the quantum state of the first quantum dot (NV1) of the first quantum bit (QUB1) with respect to the quantum state of the second quantum dot (NV2) of the second quantum bit (QUB2), and
wherein the device (LH2, LV2) of the second quantum bit (QUB2) for controlling the second quantum dot (NV2) of the second quantum bit (QUB2) can selectively influence the quantum state of the second quantum dot (NV2) of the second quantum bit (QUB2) with respect to the quantum state of the first quantum dot (NV1) of the first quantum bit (QUB1).

Feature 237. Quantum register (QUREG) according to one or more of the features 222 to 236,
wherein the first quantum dot (NV1) is spaced from the second quantum dot (NV2) by a distance (sp12) such that features 235 and/or 236 apply.

Feature 238. Quantum register (QUREG) according to one or more of features 222 to 237 and according to feature 237,
wherein the spacing (sp12) is less than 100 nm and/or wherein the spacing (sp12) is less than 50 nm and/or wherein the spacing (sp12) is less than 20 nm and/or wherein the spacing (sp12) is less than 10 nm and/or wherein the spacing (sp12) is greater than 5 nm and/or wherein the spacing (sp12) is greater than 2 nm, a spacing (sp12) of 20 nm being particularly preferred.

Feature 239. Quantum register (QUREG) according to one or more of the features 222 to 238,
wherein the quantum bits of the quantum register (QUREG) are arranged in a one- or two-dimensional lattice.

Feature 240. Quantum register (QUREG) according to feature 239,
wherein the quantum bits of the quantum register (QUREG) are arranged in a one- or two-dimensional lattice of elementary cells of arrays of one or more quantum bits with a spatial spacing (sp12) as the lattice constant for the respective elementary cell.

### Electron-A1-Electron-B2-Quantum-Register (IHQUREG) 241-252

Feature 241. Inhomogeneous Quantum Register (IHQUREG).
with a first quantum bit (QUB1) according to one or more of the preceding features 1 to 102 and
with at least one second quantum bit (QUB2) according to one or more of the preceding features 1 to 102,
where the first quantum dot type of the first quantum dot (NV1) of the first quantum bit (QUB1) is different from the second quantum dot type of the second quantum dot (NV2) of the second quantum bit (QUB2).

Feature 242. Inhomogeneous quantum register (IHQUREG) according to the previous feature,
wherein the first quantum bit (QUB1) is pan of a quantum register (QUREG) according to one or more of features 222 to 240 and/or
wherein the second quantum bit (QUB2) is part of a quantum register (QUREG) according to one or more of features 222 to 240.

Feature 243. Inhomogeneous quantum register (IHQUREG) according to one or more of the features 241 to 242,
wherein the substrate (D) or epitaxial layer (DEP1) is common to the first quantum bit (QUB1) and the second quantum bit (QUB2) and
wherein the quantum dot (NV) of the first quantum bit (QUB1) is the first quantum dot (NV1) and
wherein the quantum dot (NV) of the second quantum bit (QUB2) is the second quantum dot (NV2) and
whereby the horizontal line (LH) of the first quantum bit (QUB1) is referred to as the first horizontal line (LH1) in the following, and
where the horizontal line (LH) of the second quantum bit (QUB2) is the said first horizontal line (LH1) and
whereby the vertical line (LV) of the first quantum bit (QUB1) is referred to as the first vertical line (LV1) in the following and
whereby the vertical line (LV) of the second quantum bit (QUB2) will be
referred to as the second vertical line (LV2) in the following.

Feature 244. Inhomogeneous quantum register (IHQUREG) according to one or more of features 241 to 243,
wherein the magnetic field and/or the state of the second quantum dot (NV2) of the second quantum bit (QUB2) influences the behavior of the first quantum dot (NV1) of the first quantum bit (QUB1) at least temporarily and/or
wherein the magnetic field and/or the state of the first quantum dot (NV1) of the first quantum bit (QUB1) influences the behavior of the second quantum dot (NV2) of the second quantum bit (QUB2) at least temporarily.

Feature 245. Inhomogeneous quantum register (IHQUREG) according to one or more of features 241 to 244,
wherein the spatial distance (sp12) between the first quantum dot (NV1) of the first quantum bit (QUB11 and the second quantum dot (NV2) of the second quantum bit (QUB2) is so small.
that the magnetic field and/or the state of the second quantum dot (NV2) of the second quantum bit (QUB2) influences the behavior of the first quantum dot (NV1) of the first quantum bit (QUB1) at least temporarily, and/or
that the magnetic field and/or the state of the first quantum dot (NV1) of the first quantum bit (QUB1) influences the behavior of the second quantum dot (NV2) of the second quantum bit (QUB2) at least temporarily.

Feature 246. Inhomogeneous quantum register (IHQUREG) according to one or more of features 241 to 245,
wherein the second distance (sp12) between the first quantum dot (NV1) of the first quantum bit (QUB1) and the second quantum dot (NV2) of the second quantum bit (QUB2) is less than 50 nm and/or less than 30 nm and/or less than 20 nm and/or less than 10 nm and/or less than 10 nm and/or less than 5 nm and more than 2 nm.

Feature 247. Inhomogeneous quantum register (IHQUREG) according to one or more of features 241 to 246,
wherein the device (LH1. LV1) of the first quantum bit (QUB1) for controlling the first quantum dot (NV1) of the first quantum bit (QUB1) can influence the first quantum dot (NV1) of the first quantum bit (QUB1) with a first probability, and
wherein the device (LH1, LV1) of the first quantum bit (QUB1) for controlling the first quantum dot (NV) of the first quantum bit (QUB1) can influence the second quantum dot (NV2) of the second quantum bit (QUB2) with a second probability, and
wherein the device (LH2, LV2) of the second quantum bit (QUB2) for controlling the second quantum dot (NV2) of the second quantum bit (QUB2) can influence the first quantum dot (NV1) of the first quantum bit (QUB1) with a third probability, and
wherein the device (LH2. LV2) of the second quantum bit (QUB2) for controlling the second quantum dot (NV2) of the second quantum bit (QUB2) can influence the second quantum dot (NV2) of the second quantum bit (QUB2) with a fourth probability, and
wherein the first probability is greater than the second probability, and
wherein the first probability is greater than the third probability, and
wherein the fourth probability is greater than the second probability, and
wherein the fourth probability is greater than the third probability.

Feature 248. Inhomogeneous quantum register (IHQUREG) according to one or more of the features 241 to 247
wherein the device (LH1, LV1) of the first quantum bit (QUB1) for controlling the first quantum dot (NV1) of the first quantum bit (QUB1) can selectively influence the quantum state of the first quantum dot (NV1) of the first quantum bit (QUB1) with respect to the quantum state of the second quantum dot (NV2) of the second quantum bit (QUB2), and
wherein the device (LH2, LV2) of the second quantum bit (QUB2) for controlling the second quantum dot (NV2) of the second quantum bit (QUB2) can selectively influence the quantum state of the second quantum dot (NV2) of the second quantum bit (QUB2) with respect to the quantum state of the first quantum dot (NV1) of the first quantum bit (QUB1).

Feature 249. Inhomogeneous quantum register (IHQUREG) according to one or more of features 241 to 248
wherein the first quantum dot (NV1) is spaced from the second quantum dot (NV2) by a distance (sp12) such that features 247 and/or 248 apply.

Feature 250. Inhomogeneous quantum register (IHQUREG) according to one or more of features 241 to 249 and according to feature 249.
wherein the spacing (sp12) is less than 100 nm and/or wherein the spacing (sp12) is less than 30 nm and/or wherein the spacing (sp12) is less than 20 nm and/or wherein the spacing (sp12) is less than 10 nm and/or wherein the spacing (sp12) is greater than 5 nm and/or wherein the spacing (sp12) is greater than 2 nm, a spacing (sp12) of 20 nm being particularly preferred.

Feature 251. Inhomogeneous quantum register (IHQUREG) according to one or more of the features 241 to 250,
wherein the quantum bits of the inhomogeneous quantum register (IHQUREG) are arranged in from elementary cells of arrangements of two or more quantum bits a one or two-dimensional lattice for the respective unit cell.

Feature 252. Inhomogeneous quantum register (IHQUREG) according to feature 251
wherein the quantum bits of the inhomogeneous quantum register (IHQUREG) are arranged in a one- or two-dimensional lattice of unit cells of arrays of one or more quantum bits with a second spacing (sp12) as the lattice constant for the respective unit cell.

### Nuclear Spin1-Nuclear Spin2 Quantum Register (CCQUREG) 253-271

Feature 253. Nucleus-nuclear quantum register (CCQUREG).
with a first nuclear quantum bit (CQUB1) according to one or more of the preceding features 103 to 202, and
with at least a second nuclear quantum bit (CQUB2) according to one or more of the preceding features 103 to 202.

Feature 254. Nucleus-nuclear quantum register (CCQUREG) according to the previous feature 253,
wherein the substrate (D) or epitaxial layer (DEP1) is common to the first nuclear quantum bit (CQUB1) and the second nuclear quantum bit (CQUB2); and
wherein the nuclear quantum dot (CI) of the first nuclear quantum bit (CQUB1) in the following is the first nuclear quantum dot (CI1), and
wherein the nuclear quantum dot (CI) of the second quantum bit (CQUB2) in the following is the second nuclear quantum dot (CI2), and
wherein the horizontal line (LH) of the first nuclear quantum bit (CQUB1) will be referred to as the first horizontal line (LH1) in the following; and
wherein the horizontal line (LH) of the second nuclear quantum bit (CQUB2) is the said first horizontal line (LH1) and
wherein the vertical line (LV) of the first nuclear quantum bit (CQUB1) is referred to as the first vertical line (LV1) in the following, and
wherein the vertical line (LV) of the second nuclear quantum bit (CQUB2) will be referred to as the second vertical line (LV2) in the following.

Feature 255. Nucleus-nuclear quantum register (CCQUREG) according to one or more of the features 253 to 254,
wherein the magnetic field and/or the state of the second nuclear quantum dot (CI2) of the second nuclear quantum bit (CQUB2) influences the behavior of the first nuclear quantum dot (CI1) of the first nuclear quantum bit (CQUB1) at least temporarily and/or
wherein the magnetic field and/or the state of the first nuclear quantum dot (CI) of the first nuclear quantum bit (CQUB1) influences the behavior of the second nuclear quantum dot (CI2) of the second nuclear quantum bit (CQUB2) at least temporarily.

Feature 256. Nucleus-nuclear quantum register (CCQUREG) according to one or more of features 253 to 255,
wherein the spatial distance (sp12) between the first nuclear quantum dot (CI1) of the first nuclear quantum bit (CQUB1) and the second nuclear quantum dot (CI2) of the second nuclear quantum bit (CQUB2) is so small,
that the magnetic field and/or the state of the second nuclear quantum dot (CI2) of the second nuclear quantum bit (CQUB2) influences the behavior of the first nuclear quantum dot (CI1) of the first nuclear quantum bit (CQUB1) at least temporarily, and/or
that the magnetic field and/or the state of the first nuclear quantum dot (CI1) of the first nuclear quantum bit (CQUB1) influences the behavior of the second nuclear quantum dot (CI2) of the second quantum bit (CQUB2) at least temporarily.

Feature 257. Nucleus-nuclear quantum register (CCQUREG) according to one or more of the features 253 to 256,
wherein the fourth distance (sp12′) between the first nuclear quantum dot (CI1) of the first nuclear quantum bit (CQUB1) and the second nuclear quantum dot (CI2) of the second nuclear quantum bit (CQUB2) is less than 100 pm and/or less than 50 pm and/or less than 30 pm and/or less than 20 pm and/or less than 10 pm.

Feature 258. Nucleus-nuclear quantum register (CCQUREG) according to one or more of the features 253 to 257,
with at least a third nuclear quantum bit (CQUB3) according to one or more of the preceding features 103 to 202.

Feature 259. Nucleus-nuclear quantum register (CCQUREG) of one or more of features 253 to 258 and according to feature 258 and according to feature 254,
wherein the substrate (D) or epitaxial layer (DEP1) is common to the first nuclear quantum bit (CQUB1) and the third nuclear quantum bit (CQUB3), and
wherein the nuclear quantum dot (CI) of the third nuclear quantum bit (CQUB3) is the third nuclear quantum dot (CI3), and
wherein the horizontal line (LH) of the third nuclear quantum bit (CQUB3) is the said first horizontal line (LH1), and
wherein the vertical line (LV) of the third nuclear quantum bit (CQUB3) will be referred to as the third vertical line (LV3) in the following.

Feature 260. Nucleus-nuclear quantum register (CCQUREG) according to one or more of the features 258 to 259,
wherein the magnetic field and/or the state of the second nuclear quantum dot (CI2) of the second nuclear quantum bit (CQUB2) influences the behavior of the third nuclear quantum dot (CI3) of the third nuclear quantum bit (CQUB3) at least temporarily and/or
wherein the magnetic field and/or the state of the third nuclear quantum dot (CI3) of the third nuclear quantum bit (CQUB3) influences the behavior of the second nuclear quantum dot (CI2) of the second nuclear quantum bit (CQUB2) at least temporarily.

Feature 261. Nucleus-nuclear quantum register (CCQUREG) according to one or more of the features 258 to 260,
wherein the magnetic field and/or the state of the first nuclear quantum dot (CI1) of the first nuclear quantum bit (CQUB1) essentially does not affect the behavior of the third nuclear quantum dot (CI3) of the third nuclear quantum bit (CQUB3) at least temporarily, and/or
wherein the magnetic field and/or the state of the third nuclear quantum dot (CI3) of the third nuclear quantum bit (CQUB3) essentially does not affect the behavior of the first nuclear quantum dot (CI1) of the first nuclear quantum bit (CQUB1), at least temporarily.
wherein “essentially” is to be understood here in such a way that the influencing that does take place is insignificant for the technical result in the majority of cases.

Feature 262. Nucleus-nuclear quantum register (CCQUREG) according to one or more of features 258 to 262
wherein the spatial distance (sp13′) between the first nuclear quantum dot (CI1) of the first nuclear quantum bit (CQUB1) and the third nuclear quantum dot (CI3) of the third nuclear quantum bit (CQUB3) is,
that the magnetic field and/or the state of the third nuclear quantum dot (CI3) of the third nuclear quantum bit (CQUB3) essentially does not directly influence the behavior of the first nuclear quantum dot (CI1) of the first nuclear quantum bit (CQUB1), at least at times, and/or
that the magnetic field and/or the state of the first nuclear quantum dot (CI1) of the first nuclear quantum bit (CQUB1) essentially does not directly influence the behavior of the third nuclear quantum dot (CI3) of the third nuclear quantum bit (CQUB3) at least temporarily,
wherein “essentially” is to be understood here as meaning that the influencing that does take place is insignificant for the technical result in the majority of cases, and
wherein “not directly” means that an influence, if any, can only occur indirectly by means of ancilla quantum dots or ancilla quantum bits.

Feature 263. Nucleus-nuclear quantum register (CCQUREG) according to one or more of features 258 to 262,
wherein the spatial distance (sp23′) between the third nuclear quantum dot (CI3) of the third nuclear quantum bit (CQUB3) and the second nuclear quantum dot (CI2) of the second nuclear quantum bit (CQUB2) is so small,
that the magnetic field and/or the state of the second nuclear quantum dot (CI2) of the second nuclear quantum bit (CQUB2) influences the behavior of the third nuclear quantum dot (CI3) of the third nuclear quantum bit (CQUB3) at least temporarily, and/or
that the magnetic field and/or the state of the third nuclear quantum dot (CI3) of the third nuclear quantum bit (CQUB3) influences the behavior of the second nuclear quantum dot (CI2) of the second nuclear quantum bit (CQUB2) at least temporarily.

Feature 264. Nucleus-nuclear quantum register (CCQUREG) according to one or more of the features 258 to 263,
wherein the spatial distance (sp23′) between the third nuclear quantum dot (CI3) of the third nuclear quantum bit (CQUB3) and the second nuclear quantum dot (CI2) of the second nuclear quantum bit (CQUB2) is less than 100 pm and/or less than 50 pm and/or less than 30 pm and/or less than 20 pm and/or less than 10 pm, and/or
wherein the spatial distance (sp12′) between the first nuclear quantum dot (CI1) of the first nuclear quantum bit (CQUB1) and the second nuclear quantum dot (CI2) of the second nuclear quantum bit (CQUB2) is less than 100 pm and/or less than 50 pm and/or less than 30 pm and/or less than 20 pm and/or less than 10 pm.

Feature 265. Nucleus-nuclear quantum register (CCQUREG) according to one or more of features 253 to 264,
wherein the device (LH1, LV1) of the first nuclear quantum bit (CQUB1) for controlling the first nuclear quantum dot (CI1) of the first nuclear quantum bit (CQUB1) can influence the first nuclear quantum dot (CI1) of the first nuclear quantum bit (CQUB1) with a first probability and
wherein the device (LH1, LV1) of the first nuclear quantum bit (CQUB1) for controlling the first nuclear quantum dot (CI1) of the first nuclear quantum bit (CQUB1) can influence the second nuclear quantum dot (CI2) of the second nuclear quantum bit (CQUB2) with a second probability and
wherein the device (LH2, LV2) of the second nuclear quantum bit (CQUB2) for controlling the second nuclear quantum dot (CI2) of the second nuclear quantum bit (CQUB2) can influence the first nuclear quantum dot (CI1) of the first nuclear quantum bit (CQUB1) with a third probability and
wherein the device (LH2, LV2) of the second nuclear quantum bit (CQUB2) for controlling the second nuclear quantum dot (CI2) of the second nuclear quantum bit (CQUB2) can influence the second nuclear quantum dot (CI2) of the second nuclear quantum bit (CQUB2) with a fourth probability and
wherein the first probability is greater than the second probability and
wherein the first probability is greater than the third probability and
wherein the fourth probability is greater than the second probability and
wherein the fourth probability is greater than the third probability.

Feature 266. Nucleus-nuclear quantum register (CCQUREG) according to one or more of features 258 to 267
wherein the device (LH1, LV1) of the first nuclear quantum bit (CQUB1) for controlling the first nuclear quantum dot (CI1) of the first nuclear quantum bit (CQUB1) can selectively influence the quantum state of the first nuclear quantum dot (CI1) of the first nuclear quantum bit (CQUB1) with respect to the quantum state of the second nuclear quantum dot (CI2) of the second nuclear quantum bit (CQUB2), and
wherein the device (LH2. LV2) of the second nuclear quantum bit (CQUB2) for controlling the second nuclear quantum dot (CI2) of the second nuclear quantum bit (CQUB2) can selectively influence the quantum state of the second nuclear quantum dot (CI2) of the second nuclear quantum bit (CQUB2) with respect to the quantum state of the first nuclear quantum dot (CI1) of the first nuclear quantum bit (CQUB1).

Feature 267. Nucleus-nuclear quantum register (CCQUREG) according to one or more of features 258 to 266,
wherein the first nuclear quantum dot (CI1) is spaced from the second nuclear quantum dot (CI2) by a distance (sp12′) such that features 265 and/or 266 apply.

Feature 268. Nucleus-nuclear quantum register (CCQUREG) according to one or more of features 258 to 267 and according to feature 267,
wherein the spacing (sp12′) is less than 100 nm and/or wherein the spacing (spin) is less than 30 nm and/or wherein the spacing (sp12′) is less than 20 nm and/or wherein the spacing (sp12′) is less than 10 nm and/or wherein the spacing (sp12′) is greater than 5 nm and/or wherein the spacing (sp12′) is greater than 2 nm, a spacing (sp12) of 20 nm being particularly preferred.

Feature 269. Nucleus-nuclear quantum register (CCQUREG) according to one or more of features 253 to 264,
wherein the nuclear quantum bits of the nucleus-nuclear quantum register (CCQUREG) are arranged in a one- or two-dimensional lattice.

Feature 270. Nucleus-nuclear quantum register (CCQUREG) according to feature 269,
wherein the nuclear quantum bits of the nucleus-nuclear quantum register (CCQUREG) are arranged in a one- or two-dimensional lattice of unit cells of arrays of one or more nuclear quantum bits with a second spacing (sp12) as the lattice constant for the respective unit cell.

Feature 271. Nucleus-nuclear quantum register (CCQUREG) according to one or more of the features 233 to 270,
wherein at least one nuclear quantum dot has a different isotope than another nuclear quantum dot of the nucleus-nuclear quantum register (CCQUREG).

### Nucleus-Elecltron_Nucleus-Electron Quantum Register (CECEQUREG) 272-278

Feature 272. Nucleus-electron-nuclear quantum register (CECEQUREG)
with a first nuclear quantum bit (CQUB1) according to one or more of the preceding features 103 to 202, and
with at least one second nuclear quantum bit (CQUB2) according to one or more of the preceding features 103 to 202, and
with a first quantum bit (QUB1) according to one or more of the preceding features 1 to 102 and
with at least a second quantum bit (QUB2) according to one or more of the preceding features 1 to 102.

Feature 273. Nucleus-electron-nucleus-electron quantum register (CECEQUREG) according to feature 272,
wherein the first nuclear quantum bit (CQUB1) comprises a first nuclear quantum dot (CI1) and
wherein the second nuclear quantum bit (CQUB2) comprises a second nuclear quantum dot (CI2), characterized in that
that the first nuclear quantum dot (CI1) of the first nuclear quantum bit (CQUB1) cannot directly influence the state of the second nuclear quantum dot (CI2) of the second nuclear quantum bit (CQUB2), and
that the first nuclear quantum dot (CI1) of the first nuclear quantum bit (CQUB1) can influence the state of the second nuclear quantum dot (CI2) of the second nuclear quantum bit (CQUB2) with the aid of the first quantum bit (QUB1), in particular as a first ancilla quantum bit.

Feature 274. Nucleus-electron-nucleus-electron quantum register (CECEQUREG) according to feature 272 or feature 273,
wherein the first nuclear quantum bit (CQUB1) comprises a first nuclear quantum dot (CI1); and
wherein the second nuclear quantum bit (CQUB2) comprises a second nuclear quantum dot (CI2), characterized in that
that the first nuclear quantum dot (CI1) of the first nuclear quantum bit (CQUB1) cannot directly influence the state of the second nuclear quantum dot (CI2) of the second nuclear quantum bit (CQUB2) and
that the first nuclear quantum dot (CI1) of the first nuclear quantum bit (CQUB1) cannot influence the state of the second nuclear quantum dot (CI2) of the second nuclear quantum bit (CQUB2) even with the sole aid of the first quantum bit (QUB1),
but that the first nuclear quantum dot (CI1) of the first nuclear quantum bit (CQUB1) can influence the state of the second nuclear quantum dot (CI2) of the second nuclear quantum bit (CQUB2) only with the aid of the first quantum bit (QUB1), in particular as a first ancilla quantum bit, and only with the additional aid of at least the second quantum bit (QUB2), in particular as a second ancilla quantum bit.

Feature 275. Nucleus-electron-nucleus-electron quantum register (CECEQUREG) according to one or more of features 272 to 274,
wherein the first nuclear quantum bit (CQUB1) and the first quantum bit (QUB1) form a nucleus-electron quantum register (CEQUREG), hereinafter referred to as first nucleus-electron quantum register (CEQUREG1), according to one or more of features 203 to 215 and
wherein the second nuclear quantum bit (CQUB2) and the second quantum bit (QUB2) form a nucleus-electron quantum register (CEQUREG), hereinafter referred to as second nucleus-electron quantum register (CEQUREG2), according to one or more of features 203 to 215.

Feature 276. Nucleus-electron-nucleus-electron quantum register (CECEQUREG) according to feature 272,
wherein the first nuclear quantum bit (CQUB1) and the second nuclear quantum bit (CQUB2) form a nucleus-nuclear quantum register (CCQUREG) according to one or more of features 253 to 271.

Feature 277. Nucleus-electron-nucleus-electron quantum register (CECEQUREG) according to feature 272,
wherein the first quantum bit (QUB1) and the second quantum bit (CQUB2) form an electron-electron quantum register (QUREG) according to one or more of features 222 to 235.

Feature 278. Nucleus-electron-nucleus-electron quantum register (CECEQUREG) characterized in that it is a nucleus-electron-nucleus-electron quantum register (CECEQUREG) according to feature 276 and according to feature 277.

Quantum Dot Arrays

### Quantum Dot Array (QREG1D, QREG2D) 279-286

Feature 279. Arrangement of quantum dots (QREG1D, QREG2D)
where the quantum dots (NV11, NV12, NV13, NV21, NV22, NV23, NV31, NV32, NV33) are arranged in a one-dimensional grid (QREG1D) or in a two-dimensional grid (QREG2D).

Feature 280. Arrangement of quantum dots (NV) according to the previous feature,
wherein the distance (sp12) of two immediately adjacent quantum dots of the quantum dots (NV11, NV12, NV13, NV21, NV22, NV23, NV31, NV32, NV33) is smaller than 100 nm and/or is smaller than 50 nm and/or is smaller than 30 nm and/or is smaller than 20 nm and/or is smaller than 10 nm.

Feature 281. Arrangement of quantum dots (NV11, NV12, NV13, NV21, NV22, NV23, NV31, NV32, NV33) according to one or more of the preceding two features.
wherein at least two quantum dots of the quantum dots (NV11, NV12, NV13, NV21, NV22, NV23, NV31, NV32, NV33) are each individually pan of exactly one quantum bit according to one or more of features 1 to 13.

Feature 282. Arrangement of quantum dots (NV11, NV12, NV13, NV21, NV22, NV23, NV31, NV32, NV33) according to one or more of features 279 to 281,
where a quantum dot of the quantum dots (NV11, NV12, NV13, NV21, NV22, NV23, NV31, NV32, NV33) is a paramagnetic center.

Feature 283. Arrangement of quantum dots (NV1I, NV12, NV13, NV21, NV22, NV23, NV31, NV32, NV33) according to one or more of features 279 to 281,
wherein one of the quantum dots (NV11, NV12, NV13, NV21, NV22, NV23, NV31, NV32, NV33) is a V_{Si} center and/or a DV center and/or a V_{C}V_{SI} center and/or a CAV_{Si} center and/or a N_{C}V_{SI} center in a silicon carbide material or another paramagnetic impurity center in a silicon carbide material, in particular a silicon carbide crystal.

Feature 284. Arrangement of quantum dots (NV11, NV12, NV13, NV21, NV22, NV23, NV31, NV32, NV33) according to one or more of features 279 to 281,
wherein a quantum dot of the quantum dots (NV11, NV12, NV13, NV21, NV22, NV23, NV31, NV32, NV33) is a paramagnetic impurity center in a mixed crystal of elements of the IV^{th} main group of the periodic table.

Feature 285. Arrangement of quantum dots (NV11, NV12, NV13, NV21, NV22, NV23, NV31, NV32, NV33) according to one or more of features 279 to 281,
wherein one quantum dot of the quantum dots (NV11, NV12, NV13, NV21, NV22, NV23, NV31, NV32, NV33) is a G-center in a silicon material, especially in a silicon crystal.

Feature 286. Arrangement of quantum dots (NV11, NV12, NV13, NV21, NV22, NV23, NV31, NV32, NV33) according to one or more of features 279 to 281,
where a quantum dot of the quantum dots (NV11, NV12, NV13, NV21, NV22, NV23, NV31, NV32, NV33) is an NV center in diamond.

### Nuclear Quantum Dot Array (CQREG1D, CQREG2D) 287-297

Feature 287. Arrangement of nuclear quantum dots (CQREG1D, CQREG2D)
where the nuclear quantum dots (CI11, CI12, CI13, CI21, CI22, CI23, CI31, CI32, CI33) are arranged in a one-dimensional lattice (CQREG1D) or in a two-dimensional lattice (CQREG2D).

Feature 288. Nuclear quantum dot (CI) arrangement according to feature 287,
wherein the nucleus spacing (sp12′) of two immediately adjacent nuclear quantum dots of the nuclear quantum dots (CI11, CI12, CI13, CI21, CI22, CI23, CI31, CI32, CI33) is less than 200 pm and/or is less than 100 pm and/or is less than 50 pm and/or is less than 30 pm and/or is less than 20 pm and/or is less than 10 pm.

Feature 289. Arrangement of nuclear quantum dots(CI11, CI12, CI13, CI21, CI22, CI23, CI31, CI32, CI33) according to one or more of features 287 to 288.
wherein at least two nuclear quantum dots of the nuclear quantum dots (CI11, CI12, CI13, CI21, CI22, CI23, CI31, CI32, CI33) are each individually part of exactly one nuclear quantum bit according to one or more of the features 103 to 202

Feature 290. Arrangement of nuclear quantum dots (CI11, CI12, CI13, CI21, CI22, CI23, CI31, CI32, CI33) according to one or more of features 287 to 289,
where a nuclear quantum dot of the nuclear quantum dots (CI11, CI12, CI13, CI21, CI22, CI23, CI31, CI32, CI33) is a nucleus isotope with a nonzero nucleus magnetic moment μ.

Feature 291. Arrangement of nuclear quantum dots (CI11, CI12, CI13, CI21, CI22, CI23, CI31, CI32, CI33) according to feature 290
wherein a nuclear quantum dot of the nuclear quantum dots (CI11, CI12, CI13, CI21, CI22, CI23, CI31, CI32, CI33) is an atomic nucleus isotope having a nonzero nucleus magnetic moment μ in a crystal of one or more elements of the IV^{th} main group of the periodic table.

Feature 292. Arrangement of nuclear quantum dots (CI11, CI12, CI13, CI21, CI22, CI23, CI31, CI32, CI33) according to feature 291,
wherein a nuclear quantum dot of the nuclear quantum dots (CI11, CI12, CI13, CI21, CI22, CI23, CI31, CI32, CI33) is an atomic nucleus isotope having a nonzero nucleus magnetic moment μ in a crystal of one or more elements, but at least two elements of the IV^{th} main group of the periodic table.

Feature 293. Arrangement of nuclear quantum dots (CI11, CI12, CI13, CI21, CI22, CI23, CI31, CI32, CI33) according to feature 291,
wherein a nuclear quantum dot of the nuclear quantum dots (CI11, CI12, CI13, CI21, CI22, CI23, CI31, CI32, CI33) is an atomic nucleus isotope having a nonzero nucleus magnetic moment μ in a crystal of one or more elements, but at least three elements of the IV^{th} main group of the periodic table.

Feature 294. Arrangement of nuclear quantum dots (CI11, CI12, CI13, CI21, CI22, CI23, CI31, CI32, CI33) according to feature 291.
wherein a nuclear quantum dot of the nuclear quantum dots (CI11, CI12, CI13, CI21, CI22, CI23, CI31, CI32, CI33) is an atomic nucleus isotope having a nonzero nucleus magnetic moment μ in a crystal of one or more elements, but at least four elements of the IV^{th} main group of the periodic table.

Feature 295. Arrangement of nuclear quantum dots (CI11, CI12, CI13, CI21, CI22, CI23, CI31, CI32, CI33) according to one or more of features 287 to 289,
wherein a nuclear quantum dot of the nuclear quantum dots (CI11, CI12, CI13, CI21, CI22, CI23, CI31, CI32, CI33) is an atomic nucleus of a ¹³C isotope in diamond or in silicon or in silicon carbide or in a mixed crystal of elements of the IV^{th} main group of the periodic table as substrate (D) and/or as epitaxial layer (DEP1).

Feature 296. Arrangement of nuclear quantum dots (CI11, CI12, CI13, CI21, CI22, CI23, CI31, CI32, CI33) according to one or more of features 287 to 295,
wherein a nuclear quantum dot of the nuclear quantum dots (CI11, CI12, CI13, CI21, CI22, CI23, CI31, CI32, CI33) is an atomic nucleus of a ¹⁵N isotope in diamond or in silicon or in silicon carbide or in a mixed crystal of elements of the IV^{th} main group of the periodic table as substrate (D) and/or as epitaxial layer (DEP1).

Feature 297. Arrangement of nuclear quantum dots (CI11, CI12, CI13, CI21, CI22, CI23, CI31, CI32, CI33) according to one or more of features 287 to 296.
wherein a nuclear quantum dot of the nuclear quantum dots (CI11, CI12, CI13, CI21, CI22, CI23, CI31, CI32, CI33) is an atomic nucleus of a ¹⁴N isotope in diamond or in silicon or in silicon carbide or in a mixed crystal of elements of the IV^{th} main group of the periodic table as substrate (D) and/or as epitaxial layer (DEP1).

Preparation Operations

### Frequency Determination Method 298-318

Feature 298. Procedure
to prepare the change of the quantum information of a first quantum dot (NV1), in particular of the electron configuration of the quantum dot (NV1), of a first quantum bit (QUB1) according to one or more of the features 1 to 102 depending on the quantum information of this first quantum dot (NV1), in particular of the first spin of the first electron configuration of the first quantum dot (NV1), of the first quantum bit (QUB1) with the step:
determining the energy shift of the first quantum dot (NV1), in particular its first electron configuration, especially when the spin of the first electron configuration is spin-up or when the spin of the first electron configuration is spin-down, by means of an ODMR experiment by tuning the frequency (f) and determining an electron1-electron1 microwave resonance frequency (f_{MW}).

Feature 299. Procedure according to feature 298
with the additional step
Storing the determined microwave resonance frequency (f_{MW}) in a memory cell of a memory of a control device (μC) as a stored microwave resonance frequency (f_{MW}).

Feature 300. Method according to one or more of the features 298 to 299
with the additional step
changing the quantum information of a first quantum dot (NV1), in particular the electron configuration of the quantum dot (NV1), of a first quantum bit (QUB1) according to one or more of features 1 to 102 function of the quantum information of this first quantum dot (NV1), in particular the first spin of the first electron configuration of the first quantum dot (NV1), of the first quantum bit (QUB1),
where this change is made using the stored microwave resonance frequency (f_{MW}).

Feature 301. Procedure according to feature 300
wherein this change is made by means of an electromagnetic field with the stored microwave resonance frequency (f_{MW}).

Feature 302. Method according to one or more of the features 298 to 301,
wherein the electromagnetic field is generated by one or more devices (LH, LV) for generating a circularly polarized magnetic field (B_{CI}), 302

Feature 303 Procedure
for preparing the change of the quantum information of a first quantum dot (NV1), in particular of the spin of the electron configuration of the quantum dot (NV1), of a first quantum bit (QUB1) of a quantum register (QUREG) according to one or more of the features 222 to 235 dependence on the quantum information of a second quantum dot (NV2), in particular of the second spin of the second electron configuration of the second quantum dot (NV2), of a second quantum bit (QUB2) of this quantum register (QUREG) with the step:
determining the energy shift of the first quantum dot (NV1), in particular its first electron configuration, especially when the spin of the second electron configuration is spin-up or when the spin of the second electron configuration is spin-down, by means of an ODMR experiment by tuning the frequency (f) and determining an electron1-electron2 microwave resonance frequency (f_{MWEE}).

Feature 304. Method according to feature 303 with the additional step
storing the determined electron1-electron2 microwave resonance frequency (f_{MWEE}) in a memory cell of a memory of a control device (μC) as a stored electron1-electron2 microwave resonance frequency (f_{MWEE}).

Future 305. The method according to feature 304 comprising the additional step of
changing the quantum information of a first quantum dot (NV1), in particular the spin of the electron configuration of the quantum dot (NV1), of a first quantum bit (QUB1) of a quantum register (QUREG) according to one or more of the features 222 to 235 function of the quantum information of a second quantum dot (NV2), in particular from the second spin of the second electron configuration of the second quantum dot (NV2), of a second quantum bit (QUB2) of this quantum register (QUREG),
wherein this change is made using the stored electron1-electron2 microwave resonance frequency (f_{MWEE}).

Future 306. Procedure according to feature 305,
wherein this change occurs by means of an electromagnetic field with the stored electron1-electron2 microwave resonance frequency (f_{MWEE}).

Feature 307. Procedure according to feature 306,
wherein the electromagnetic field is generated by one or more devices (LH, LV) for generating a circularly polarized magnetic field (B_{CI}).

Feature 308. Procedure for the preparation of the amendment
the quantum information of a quantum dot (NV), in particular the spin of its electron configuration, of a quantum bit (QUB) of a nucleus-electron quantum register (CEQUREG) according to one or more of the features 203 to 215 as a function of the quantum information of a nuclear quantum dot (CI), in particular the nuclear spin of its atomic nucleus, of a nuclear quantum bit (CQUB) of this nucleus-electron quantum register (CEQUREG) with the step:
determining the energy shift of the quantum dot (NV), in particular its electron, especially when the nuclear spin is spin-up or when the nuclear spin is spin-down, by means of an ODMR experiment by tuning the frequency (f) and determining a nucleus-electron microwave resonance frequency (f_{MWCE}).

Feature 309. Procedure according to feature 308,
with the additional step:
storing the determined nucleus-electron microwave resonance frequency (f_{MWCE}) in a memory cell of a memory of a control device (μC) as a stored nucleus-electron microwave resonance frequency (f_{MWCE}).

Feature 310. Method according to one or more of the features 308 to 309
with the additional step
changing the quantum information of a quantum dot (NV), in particular the spin of its electron configuration, of a quantum bit (QUB) of a nucleus-electron quantum register (CEQUREG) according to one or more of the features 203 to 215 as a function of the quantum information of a nuclear quantum dot (CI), in particular the nuclear spin of its atomic nucleus, of a nuclear quantum bit (CQUB) of this nucleus-electron quantum register (CEQUREG),
wherein this change is made using the stored nucleus-electron microwave resonance frequency (f_{MWCE}).

Feature 311. Procedure according to feature 310,
whereby this change occurs by means of an electromagnetic field with the stored nucleus-electron microwave resonance frequency (f_{MWCE}).

Feature 312. Method according to one or more of the features 308 to 311,
wherein the electromagnetic field is generated by one or more devices (LH, LV) for generating a circularly polarized magnetic field (B_{CI}).

Feature 313. Procedure
for preparing the change of the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 215 as a function of the quantum information of a quantum dot (NV), in particular the spin of its electron configuration, of a quantum bit (QUB) of this nucleus-electron quantum register (CEQUREG) with the step:
Determination of the energy shift of a quantum dot (NV), in particular its electron configuration, especially when the nuclear spin is spin-up or when the nuclear spin is spin-down, by means of an ODMR experiment by tuning the frequency (f) and determining the electron-nucleus radio wave resonance frequencies (f_{RWEC}).

Feature 314. Procedure according to feature 313,
with the additional step
Storing the determined electron-nucleus radio wave resonance frequencies (f_{RWEC}) in one or more memory cells of a memory of a control device (μC) as a stored electron-nucleus radio wave resonance frequency (f_{RWEC}).

Feature 315. Method according to one or more of the features 313 to 314,
with the additional step
changing the quantum information of a quantum dot (NV), in particular the spin of its electron configuration, of a quantum bit (QUB) of a nucleus-electron quantum register (CEQUREG) according to one or more of the features 203 to 215 as a function of the quantum information of a nuclear quantum dot (CI), in particular the nuclear spin of its atomic nucleus, of a nuclear quantum bit (CQUB) of this nucleus-electron quantum register (CEQUREG),
wherein this change is made using one or more of the stored nucleus-electron-radio wave resonance frequencies (f_{RWEC}).

Feature 316. Procedure according to feature 315.
whereby this change takes place by means of an electromagnetic field with the stored nucleus electron radio wave resonance frequency (f_{RWCE}).

Feature 317. Method according to one or more of the features 313 to 316,
wherein the electromagnetic field is generated by one or more devices (LH, LV) for generating a circularly polarized magnetic field (B_{CI}).

Feature 318. Procedure
for preparing the change of the quantum information of a first nuclear quantum dot (CI1), in particular of the nuclear spin of its nucleus, of a first nuclear quantum bit (CQUB) of a nucleus-nuclear quantum register (CCQUREG) according to one or more of the features 253 to 269 function of the quantum information of a second nuclear quantum dot (CI2), in particular the nuclear spin of the second nuclear quantum dot (Ci2), of a second nuclear quantum bit (CQUB2) of this nucleus-nuclear quantum register (CCQUREG) with the step:
determining the energy shift of a first nuclear quantum dot (CI1), in particular its first nuclear spin, especially when the second nuclear spin of the second nuclear quantum dot (CI2) is spin-up or when the second nuclear spin is spin-down, by means of an ODMR experiment by tuning the frequency (f) and determining the nucleus-nucleus radio wave resonance frequencies (f_{RWCC}).

Feature 319. Procedure according to feature 318,
with the additional step
Storing the determined nucleus-nucleus radio wave resonance frequencies (f_{RWCC}) in one or more memory cells of a memory of a control device (μC) as stored nucleus-nucleus radio wave resonance frequencies (f_{RWCC}).

Feature 320. Method according to one or more of the features 318 to 319
with the additional step
changing the quantum information of a quantum dot (NV), in particular the spin of its electron configuration, of a quantum bit (QUB) of a nucleus-electron quantum register (CEQUREG) according to one or more of the features 203 to 215 as a function of the quantum information of a nuclear quantum dot (CI), in particular the nuclear spin of its atomic nucleus, of a nuclear quantum bit (CQUB) of this nucleus-electron quantum register (CEQUREG),
wherein this change is made using one or more of the stored nucleus-to-nucleus radio wave resonance frequencies (f_{RWCC}).

Feature 321. Procedure according to feature 320,
wherein this change occurs by means of an electromagnetic field with the stored nucleus-nucleus radio wave resonance frequencies (f_{RWCC}).

Feature 322. Method according to one or more of the features 318 to 321,
wherein the electromagnetic field is generated by one or more devices (LH, LV) for generating a circularly polarized magnetic field (B_{CI}).

Single Operations

### Quantum Bit Reset Method 323

Feature 323. A method of resetting a quantum dot (NV) of a quantum bit (QUB) according to one or more of the preceding features 1 to 102
irradiating at least one quantum dot (NV) of the quantum dots (NV1, NV2) with light functionally equivalent to irradiation of an NV center in the use of this NV center in diamond as quantum dots (NV) with green light with respect to the effect of this irradiation on the quantum dot (NV),
wherein in particular the use of a NV center (NV) in diamond as a quantum dot (NV), the green light has a wavelength in a wavelength range of 400 nm to 700 nm wavelength and/or 450 nm to 650 nm and/or 500 nm to 550 nm and/or 515 nm to 540 nm, preferably 532 nm wavelength, and
wherein this function-equivalent light is referred to as “green light” in the following and in this feature. Reference is made here to the section “green light as excitation radiation” on function-equivalent excitation wavelengths.

Feature 324. A method of resetting a quantum dot (NV) of a quantum bit (QUB) according to one or more of the preceding features 1 to 102
irradiating at least one quantum dot (NV) of the quantum dots (NV1, NV2) with excitation radiation having an excitation wavelength,
wherein the excitation wavelength is shorter than the wavelength of the ZPL (zero-phonon-line) of the paramagnetic center serving as quantum dot (NV). Reference is made here to the section “green light as excitation radiation” on function-equivalent excitation wavelengths.

### Nucleus-Electron Quantum Register Reset Method 325-327

Feature 325. A method of resetting a nucleus-electron quantum register (CEQUREG) according to one or more of features 203 to 215

comprising the steps of
resetting the quantum dot (NV) of the quantum bit (QUB) of the nucleus-electron quantum register (CEQUREG), in particular according to a method according to feature 323 and/or feature 324;
change of the quantum information of the nuclear quantum dot (CI), in particular of the nuclear spin of its nucleus, of the nuclear quantum bit (CQUB) of the nucleus-electron quantum register (CEQUREG) as a function of the quantum information of the quantum dot (NV), in particular of its electron, of the quantum bit (QUB) of this nucleus-electron quantum register (CEQUREG).

Feature 326. Method for resetting the nucleus-electron quantum register (CEQUREG) according to feature 325,
wherein resetting the quantum dot (NV) of the quantum bit (QUB) of the nucleus-electron quantum register (CEQUREG) is performed using a method according to feature 323 and/or feature 324.

Feature 327. Method for resetting the nucleus-electron quantum register (CEQUREG) according to feature 325 or 326,
wherein the change of the quantum information of the nuclear quantum dot (CI), in particular of the nuclear spin of its atomic nucleus, of the nuclear quantum bit (CQUB) of the nucleus-electron quantum register (CEQUREG) is carried out as a function of the quantum information of the quantum dot (NV), in particular of its electron, of the quantum bit (QUB) of this nucleus-electron quantum register (CEQUREG) by means of a method according to one or more of the features 391 to 400.

Quantum Bit Manipulations

### Quantum Bit Manipulation Methods 328-333

Feature 328. Method for manipulating a quantum bit (QUB),
wherein the quantum bit (QUA) is a quantum bit (QUB) according to one or more of features 1 to 102
with the steps
temporary energization of the horizontal line (LH) with a horizontal current (IH) having a horizontal current component modulated with an electron1-electron1 microwave resonance frequency (f_{mw}) with a horizontal modulation:
temporary energization of the vertical line (LV) with a vertical current (IV) with a vertical current component modulated with the electron-electron microwave resonance frequency (NO with a vertical modulation.

Feature 329. Method according to feature 328,
wherein the horizontal modulation of the horizontal current component is phase shifted by +/−90° with respect to the vertical modulation of the vertical current component.

Feature 330. Method according to feature 328 or 329,
wherein the vertical current component is pulsed with a vertical current pulse having a pulse duration, and
where the horizontal current component is pulsed with a horizontal current pulse with a pulse duration.

Feature 331. Method according to one or more of the features 328 to 330,
where the vertical current pulse is out of phase with respect to the horizontal current pulse by +/−π/2 of the period of the electron-electron microwave resonance frequency (f_{MW}).

Feature 332. Method according to one or more of the features 328 to 331.
wherein the temporal pulse duration of the horizontal current pulse and the vertical current pulse has the pulse duration corresponding to a phase difference of π/4 or π/2 (Hadamard gate) or 3π/4 or π (not-gate) of the Rabi oscillation of the quantum dot (NV), or
wherein the temporal pulse duration of the horizontal current pulse and the vertical current pulse has the pulse duration corresponding to a phase difference of an integer multiple of π/4 of the period of the Rabi oscillation of the quantum dot (NV).

Feature 333. Method according to one or more of the features 328 to 331,
where the current pulse has a transient phase and a decay phase, and
where the current pulse has an amplitude envelope, and
where the pulse duration refers to the time interval of the time points of the 70% amplitude of the maximum amplitude envelope.

### Nuclear Quantum Bit Manipulation Methods 334-338

Feature 334. Method for manipulating a nuclear quantum bit (QUB),
wherein the nuclear quantum bit (CQUB) is a nuclear quantum bit (CQUB) according to one or more of features 103 to 202 with the steps
energizing the horizontal line (LH) of the nuclear quantum bit (CQUB) with a horizontal current (IH) having a horizontal current component modulated with a first nucleus-nucleus radio wave frequency (f_{RWCC}) and/or with a second nucleus-nucleus radio wave frequency (f_{RWCC2}) as a modulation frequency with a horizontal modulation;
energizing the vertical line (LV) of the nuclear quantum bit (CQUB) is modulated with a vertical current (IV) with a vertical current component modulated with the modulation frequency with a vertical modulation,
whereby the horizontal modulation of the horizontal current component is phase shifted by +/−90° with respect to the vertical modulation of the vertical current component.

Feature 335. Procedure according to feature 334,
wherein the vertical current component is pulsed with a vertical current pulse having a pulse duration, and
wherein the horizontal current component is pulsed with a horizontal current pulse with a pulse duration

Feature 336. Method according to one or more of the features 334 to 335,
wherein the vertical current pulse is phase shifted relative to the horizontal current pulse by +/−π/2 of the period of the first nucleus-to-nucleus radio wave frequency (f_{RWCC}) or by +/−π/2 of the period of the second nucleus-to-nucleus radio wave frequency (f_{RWCC2}).

Feature 337. Method according to one or more of the features 335 to 336,
wherein the temporal pulse duration of the horizontal current pulse and the vertical current pulse has the pulse duration corresponding to a phase difference of π/4 or π/2 (Hadamard gate) or 3π/4 or π (not-gate) of the period of the Rabi oscillation nuclear quantum dot (CI) of the first nuclear quantum bit (CQUB), or
wherein the temporal pulse duration of the horizontal current pulse and the vertical current pulse has the pulse duration corresponding to a phase difference of an integer multiple of π/4 of the period of the Rabi oscillation nuclear quantum dot (CI) of the first nuclear quantum bit (CQUB).

Feature 338. Method according to one or more of the features 335 to 336,
wherein the current pulse has a transient phase and a decay phase, and
wherein the current pulse has an amplitude envelope, and
wherein the pulse duration refers to the time interval of the time points of the 70% amplitude of the maximum amplitude envelope.

Quantum Register Single Operations 339-417

### Selective Manipulation Methods for Individual Quantum Bits in Quantum Registers 339-122

### Selective NV1 Quantum Bit Drive Method 339-346

Feature 339. Method for selectively controlling a first quantum bit (QUB1) of a quantum register (QUREG) according to one or more of the features 222 to 240,
with the steps
temporary energization of the first horizontal line (LH1) of the quantum register (QUREG) with a first horizontal current component of the first horizontal current (IH1) modulated with a first horizontal electron1-electron1 microwave resonance frequency (f_{MWHI1}) with a first horizontal modulation;
temporary energization of the first vertical line (LV1) of the quantum register (QUREG) with a first vertical current component of the first vertical current (IV1) is modulated with the first vertical electron1-electron1 microwave resonance frequency (f_{MWV1}) with a first vertical modulation.
additionally energizing the first horizontal line (LH1) with a first horizontal DC component (IHG1) of the first horizontal current (IH1),
where the first horizontal DC component (IHG1) may have a first horizontal current value of 0A;
additionally energizing the first vertical line (LV1) with a first vertical DC component (IVG1) of the first vertical current (IV).
wherein the first vertical DC component (IVG1) may have a first vertical current value of 0A;
additional energization of the second vertical line (LV2) with a second vertical DC component (IVG2),
wherein the first horizontal current (IH1) in the first horizontal line (LH1) is a sum of at least the first horizontal direct current component (IHG1) of the first horizontal current (IH1) plus the first horizontal current component of the first horizontal current (IH1), and
wherein the first vertical current (IV1) in the first vertical line (LV1) is a sum of at least the first vertical direct current component (IVG1) of the first vertical current (IV1) plus the first vertical current component of the first vertical current (IV1), and
wherein the second vertical current (IV2) in the second vertical line (LV2) is a sum of at least the second vertical direct current component (IVG2) of the second vertical current (IV2) plus the second vertical current component of the second vertical current (IV2), and
wherein the second vertical direct current component (IVG2) has a second vertical current value that differs from the first vertical current value of the first vertical direct current component (IVG1).

Feature 340. Method according to feature 339 with the step
temporary energization of the second vertical line (LV2) of the quantum register (QUREG) with a second vertical current component of the second vertical current (IV2) is modulated with the second vertical electron1-electron1 microwave resonance frequency (f_{MWV2}) with a second vertical modulation.

Feature 341. Procedure according to feature 339,
wherein the method according to feature 339 is used to select the first quantum bit (QUB1) or the second quantum bit (QUB2) by detuning the first vertical electron1-electron1 microwave resonance frequency (f_{MWV1}) with respect to the second vertical electron1-electron1 microwave resonance frequency (f_{MWV2}).

Feature 342. Method according to feature 339 or 341,
wherein the first horizontal modulation is phase shifted by +/−π/2 of the period of the first horizontal electron1-electron1 microwave resonance frequency (f_{MWHI1}) with respect to the first vertical modulation.

Feature 343. Method according to feature 339 or 342,
wherein the first vertical electron1-electron1 microwave resonance frequency (f_{MWV1}) is equal to the first horizontal electron1-electron1 microwave resonance frequency (f_{MWH1}).

Feature 344. Method according to one or more of the features 339 to 343,
wherein the first vertical current component is pulsed with a first vertical current pulse having a first pulse duration; and
wherein the first horizontal current component is pulsed with a first horizontal current pulse having the first pulse duration

Feature 345. Method according to one or more of features 339 to 344 and feature 344,
wherein the first vertical current pulse is phase shifted from the first horizontal current pulse by +/−π/2 of the period of the first horizontal electron1-electron1 microwave resonance frequency (f_{MWH1}).

Feature 346. Method according to one or more of the features 339 to 345,
wherein the first temporal pulse duration has a first pulse duration corresponding to a phase difference of π/4 or π/2 (Hadamard gate) or 3π/4 or π (not-gate) of the Rabi oscillation of the first quantum dot (NV1) and/or
wherein the first temporal pulse duration has a first pulse duration corresponding to a phase difference of an integer multiple of π/4 of the period of the Rabi oscillation of the first quantum dot (NV1).

### Selective NV2 SEP. LH2 LTG Quantum Register Drive Method 347-354

Feature 347. Method for differentially controlling a first quantum bit (QUB1) and a second quantum bit (QUB2) of a quantum register (QUREG) according to one or more of the preceding features 339 to 346 comprising the additional steps of
additionally energizing the second horizontal line (LH2) with a second horizontal current component of the second horizontal current (IH2) modulated with a second horizontal electron1-electron1 microwave resonance frequency (f_{MWH2}) with a second horizontal modulation,
additionally energizing the second vertical line (LV2) with a second vertical current component of the second vertical current (IV2) modulated with a second vertical electron1-electron1 microwave resonance frequency (f_{MWV2}) with a second vertical modulation.

Feature 348. Method according to feature 347,
additionally energizing the second horizontal line (LH2) with a second horizontal DC component (IHG2) of the second horizontal current (IH2),
wherein the second horizontal DC component (IHG2) may have a second horizontal current value of 0A; and
wherein the second horizontal current (IH2) in the second horizontal line (LH2) is a sum of at least the second horizontal direct current component (IHG2) of the second horizontal current (IH2) plus the second horizontal current component of the second horizontal current (IH2).

Feature 349. Method according to feature 347 or 348,
wherein the second horizontal modulation is phase shifted by +/−π/2 of the period of the second horizontal electron1-electron1 microwave resonance frequency (f_{MWH2}) with respect to the second vertical modulation.

Feature 350. Method according to feature 347 to 349,
wherein the second vertical electron1-electron1 microwave resonance frequency (f_{MWV2}) is equal to the second horizontal electron1-electron1 microwave resonance frequency (f_{MWH2}).

Feature 351. Method according to one or more of the features 347 to 350,
wherein the second vertical current component is pulsed with a second vertical current pulse having a second pulse duration; and
wherein the first horizontal current component is pulsed with a second horizontal current pulse having the second pulse duration

Feature 352. Method according to one or more of features 347 to 351 and feature 351,
wherein the second vertical current pulse is phase shifted with respect to the second horizontal current pulse by +/−π/2 of the period of the second vertical electron1-electron1 microwave resonance frequency (f_{MWV2}).

Feature 353. Method according to one or more of the features 351 to 352,
wherein the quantum register (QUREG) comprises more than two quantum bits.

Feature 354. Method according to one or more of the features 351 to 353,
wherein the second temporal pulse duration has a second pulse duration corresponding to a phase difference of π/4 or π/2 (Hadamard gate) or 3π/4 or π (not-gate) of the Rabi oscillation of the second quantum dot (NV2) and/or
where the second temporal pulse duration has a second pulse duration corresponding to a phase difference of an integer multiple of π/4 of the period of the Rabi oscillation of the second quantum dot (NV2).

### Selective NV2 ACC. LV1 Quantum Register Drive Method 355-360

Feature 355. Method for differentially controlling a first quantum bit (QUB1) and a second quantum bit (QUB2) of a quantum register (QUREG) according to one or more of the preceding features 339 to 346 comprising the additional steps of
additionally energizing the second horizontal line (LH2) with a second horizontal current component of the second horizontal current (IH2) modulated with a second horizontal electron1-electron1 microwave resonance frequency (f_{MWH2}) with a second horizontal modulation,
additionally energizing the first vertical line (LV1) with a second vertical current component of the first vertical current (IV1 modulated with a second vertical electron1-electron1 microwave resonance frequency (f_{MWV2}) with a second vertical modulation.

Feature 356. Method according to feature 355,
wherein the second horizontal modulation is phase shifted by +/−π/2 of the period of the second horizontal electron1-electron1 microwave resonance frequency (f_{MWH2}) with respect to the second vertical modulation.

Feature 357. Method according to features 355 and 355,
wherein the second vertical electron1-electron1 microwave resonance frequency (f_{MWV2}) is equal to the second horizontal electron1-electron1 microwave resonance frequency (f_{MWH2}).

Feature 358. Method according to one or more of the features 355 to 357,
wherein the second vertical current component is pulsed with a second vertical current pulse having a second pulse duration and
wherein the first horizontal current component is pulsed with a second horizontal current pulse having the second pulse duration

Feature 359. Method according to one or more of features 355 to 358 and feature 358,
wherein the second vertical current pulse is phase shifted with respect to the second horizontal current pulse by +/−π/2 of the period of the second vertical electron1-electron1 microwave resonance frequency (f_{MWV2}).

Feature 360. Method according to one or more of the features 358 to 359,
wherein the second temporal pulse duration has a second pulse duration corresponding to a phase difference of π/4 or π/2 (Hadamard gate) or 3π/4 or π (not-gate) of the Rabi oscillation of the second quantum dot (NV2) and/or
wherein the second temporal pulse duration has a second pulse duration corresponding to a phase difference of an integer multiple of π/4 of the period of the Rabi oscillation of the second quantum dot (NV2).

### Selective NV2 Mixed LH1 Line Quantum Register Drive Method 361-366

Feature 361. Method for differentially controlling a first quantum bit (QUB1) and a second quantum bit (QUB2) of a quantum register (QUREG) according to one or more of the preceding features 339 to 346 comprising the additional steps of
additionally energizing the first horizontal line (LH1) with a second horizontal current component of the first horizontal current (IH1) modulated with a second horizontal electron1-electron1 microwave resonance frequency (f_{MWH2}) with a second horizontal modulation,
additionally energizing the second vertical line (LV2) with a second vertical current component of the second vertical current (IV2) modulated with a second vertical electron1-electron1 microwave resonance frequency (f_{MWV2}) with a second vertical modulation.

Feature 362. Method according to feature 361,
wherein the second horizontal modulation is +/−90° out of phase with the second vertical modulation.

Feature 363. Method according to feature 361 to 362,
wherein the second vertical electron1-electron1 microwave resonance frequency (f_{MWV2}) is equal to the second horizontal electron1-electron1 microwave resonance frequency (f_{MWH2}).

Feature 364. Method according to one or more of the features 361 to 363,
wherein the second vertical current component is pulsed with a second vertical current pulse having a second pulse duration; and
wherein the first horizontal current component is pulsed with a second horizontal current pulse having the second pulse duration

Feature 365. Method according to one or more of features 361 to 364 and feature 364,
wherein the second vertical current pulse is phase shifted with respect to the second horizontal current pulse by +/−π/2 of the period of the second vertical electron1-electron1 microwave resonance frequency (f_{MWV2}).

Feature 366. Method according to one or more of the features 364 to 365
wherein the second temporal pulse duration has a second pulse duration corresponding to a phase difference of π/4 or π/2 (Hadamard gate) or 3π/4 or π (not-gate) of the Rabi oscillation of the second quantum dot (NV2) and/or
where the second temporal pulse duration has a second pulse duration corresponding to a phase difference of an integer multiple of π/4 of the period of the Rabi oscillation of the second quantum dot (NV2).

### Electron1-Electron2-Exchange-Operation 367-383

### Non-Selective NV1 NV2 Quantum Bit Coupling Method 367-381

Feature 367. Method of controlling the pair of a first quantum bit (QUB1) and a second quantum bit (QUB2) of a quantum register (QUREG) of said quantum register (QUREG) according to one or more of features 222 to 240.
with the steps
temporary energization of the first horizontal line (LH1) of the quantum register (QUREG) with a first horizontal current component of the first horizontal current (IH1) modulated with a first horizontal electron1-electron2 microwave resonance frequency (f_{MWHEE1}) with a first horizontal modulation;
temporary energization of the first vertical line (LV1) of the quantum register (QUREG) with a first vertical current component of the first vertical current (IV1) modulated with a first vertical electron1-electron2 microwave resonance frequency (f_{MWVEE1}) with a first vertical modulation;
temporary energization of the second horizontal line (LH2) of the quantum register (QUREG) with a second horizontal current component of the second horizontal current (IH2) modulated with the first horizontal electron1-electron2 microwave resonance frequency (f_{MWHEE1}) with the second horizontal modulation;
temporary energization of the second vertical line (LV2) of the quantum register (QUREG) with a second vertical current component of the second vertical current (IV2) modulated with the first vertical electron1-electron2 microwave resonance frequency (f_{MWVEE1}) with the second vertical modulation
wherein the second horizontal line (LH2) may be equal to the first horizontal line (LH1) and wherein then the second horizontal current (IH2) is equal to the first horizontal current (IH1) and wherein then the second horizontal current (IH2) is already injected with the injection of the first horizontal current (IH1), and
wherein the second vertical line (LV2) can be equal to the first vertical line (LV2) and wherein then the second vertical current (IV2) is equal to the first vertical current (IV1) and wherein then the second vertical current (IV2) is already injected with the injection of the first vertical current (IV1).

Feature 368. Method according to feature 367,
wherein the first horizontal modulation is phase shifted by +/−π/2 of the period of the first horizontal electron1-electron2 microwave resonance frequency (f_{MWHEE1}) with respect to the first vertical modulation, and
wherein the second horizontal modulation is phase shifted by +/−π/2 of the period of the second horizontal electron1-electron2 microwave resonance frequency (f_{MWHEE2}) with respect to the second vertical modulation.

Feature 369. Method according to feature 367,
additionally energizing the first horizontal line (LH1) with a first horizontal DC component (IHG1) of the first horizontal current (IH1),
wherein the first horizontal DC component (IHG1) has a first horizontal current value;
wherein the first horizontal DC component (IHG1) may have a first horizontal current value of 0A;
additionally energizing the first vertical line (LV1) with a first vertical DC component (IVG1) of the first vertical current (IV1),
wherein the first vertical DC component (IVG1) has a first vertical current value;
wherein the first vertical DC component (IVG1) may have a first vertical current value of 0A;
additionally energizing the second horizontal line (LH2) with a second horizontal DC component (IHG2) of the second horizontal current (IH2),
wherein the second horizontal DC component (IHG2) has a second horizontal current value;
wherein the second horizontal DC component (IHG2) may have a second horizontal current value of 0A;
additionally energizing the second vertical line (LV2) with a second vertical DC component (IVG2) of the second vertical current (IV2),
wherein the second vertical DC component (IVG2) has a second vertical current value;
wherein the second vertical DC component (IVG2) may have a first vertical current value of 0A;

Feature 370. Method according to one or more of the features 367 to 368,
wherein the first horizontal current value is equal to the second horizontal current value.

Feature 371. Method according to one or more of the features 367 to 370,
wherein the first vertical current value is equal to the second vertical current value.

Feature 372. Method according to one or more of the features 367 to 371,
wherein the first vertical electron1-electron1 microwave resonance frequency (f_{MWV1}) is equal to the first horizontal electron1-electron2 microwave resonance frequency (f_{MWHEE1}).

Feature 373. Method according to one or more of the features 367 to 372,
wherein the first vertical current component is pulsed with a first vertical current pulse having a first pulse duration; and
wherein the first horizontal current component is pulsed with a first horizontal current pulse having the first pulse duration

Feature 374. Method according to one or more of the features 367 to 373,
wherein the second vertical current component is pulsed with a second vertical current pulse having a second pulse duration; and
wherein the second horizontal current component is pulsed with a second horizontal current pulse having the second pulse duration.

Feature 375. Method according to one or more of the features 367 to 374,
wherein the first vertical current component is pulsed with a first vertical current pulse having a first pulse duration and
wherein the first horizontal current component is pulsed with a first horizontal current pulse having the first pulse duration.

Feature 376. Method according to one or more of the features 367 to 375,
wherein the second vertical current component is pulsed with a second vertical current pulse having a second pulse duration and
wherein the second horizontal current component is pulsed with a second horizontal current pulse having the second pulse duration.

Feature 377. Method according to one or more of features 367 to 376 and feature 375
wherein the first vertical current pulse is phase shifted with respect to the first horizontal current pulse by +/−π/2 of the period of the first electron1-electron2 microwave resonance frequency (f_{MWHEE1}).

Feature 378. Method according to one or more of features 367 to 377 and feature 376,
wherein the second vertical current pulse is phase shifted with respect to the second horizontal current pulse by +/−π/2 of the period of the second electron1-electron2 microwave resonance frequency (f_{MWHEE2}).

Feature 379. Method according to one or more of the features 367 to 378,
wherein the first temporal pulse duration has a first pulse duration corresponding to a phase difference of π/4 or π/2 (Hadamard gate) or 3π/4 or π (not-gate) of the Rabi oscillation of the quantum dot pair of the first quantum dot (NV1) and the second quantum dot (NV2) and/or
wherein the first temporal pulse duration has a first pulse duration corresponding to a phase difference of an integer multiple of π/4 of the period of the Rabi oscillation of the quantum dot pair of the first quantum dot (NV1) and the second quantum dot (NV2).

Feature 380. Method according to one or more of the features 367 to 377,
wherein the second temporal pulse duration has a second pulse duration corresponding to a phase difference of π/4 or π/2 (Hadamard gate) or 3π/4 or π (not-gate) of the Rabi oscillation of the quantum dot pair of the first quantum dot (NV1) and the second quantum dot (NV2) and/or
wherein the second temporal pulse duration has a second pulse duration corresponding to a phase difference of an integer multiple of π/4 of the period of the Rabi oscillation of the quantum dot pair of the first quantum dot (NV1) and the second quantum dot (NV2).

Feature 381. Method according to feature 377 and 380,
wherein the first temporal pulse duration is equal to the second temporal pulse duration.

### Selective NV1 NV2 Quantum Bit Coupling Method 382-383

Feature 382. Method according to one or more of the features 367 to 381 for controlling the pair of a first quantum bit (QUB1) and a second quantum bit (QUB2) of a quantum register (QUREG) according to one or more of the features 222 to 240,
wherein the gating is selective with respect to further quantum bits (QUBj) of this quantum register (QUREG),
with the steps
additionally energizing the first horizontal line (LH1) with a first horizontal DC component (IHG1) of the first horizontal current (IH1),
wherein the first horizontal DC component (IHG1) has a first horizontal current value:
wherein the first horizontal DC component (IHG1) may have a first horizontal current value of 0A;
additionally energizing the first vertical line (LV1) with a first vertical DC component (IVG1) of the first vertical current (IV1),
wherein the first vertical DC component (IVG1) has a first vertical current value:
wherein the first vertical DC component (IVG1) may have a first vertical current value of 0A;
additionally energizing the second horizontal line (LH2) with a second horizontal DC component (IHG2) of the second horizontal current (IH2),
wherein the second horizontal DC component (IHG2) has a second horizontal current value:
wherein the second horizontal DC component (IHG2) may have a second horizontal current value of 0A:
additionally energizing the second vertical line (LV2) with a second vertical DC component (IVG2) of the second vertical current (IV2),
wherein the second vertical DC component (IVG2) has a second vertical current value;
wherein the second vertical DC component (IVG2) may have a first vertical current value of 0A:
additional energization of the j-th horizontal line (LHj) of a further j-th quantum bit (QUBj), if present, of the quantum register (QUREG) with a j-th horizontal direct current component (IHGj),
wherein the j-th horizontal DC component (IHGj) has a j-th horizontal current value;
additional energization of the j-th vertical line (LVj) of a further j-th quantum bit (QUBj), if present, of the quantum register (QUREG) with a j-th vertical direct current component (IVGj).
wherein the j-th vertical DC component (IHGj) has a j-th vertical current value.

Feature 383. Procedure according to feature 382.
wherein the first vertical current value is different from the j-th vertical current value and/or.
wherein the second vertical current value is different from the j-th vertical current value and/or.
wherein the first horizontal current value is different from the j-th horizontal current value and/or.
wherein the second horizontal current value is different from the j-th horizontal current value.

### General Entanglement (Electron-Electron Entanglement) 384-385

Feature 384. Method for entangling the quantum information of a first quantum dot (NV1), in particular the spin of its electron configuration, of a first quantum bit (QUB1) of a quantum register (QUREG) according to one or more of the features 222 to 240 an inhomogeneous quantum register (IQUREG) according to one or more of the features 241 to 252 with the quantum information of a second quantum dot (NV2), in particular the first spin of the first electron configuration of the second quantum dot (QUB2), of a second quantum bit (QUB2) of this quantum register (QUREG) or of said inhomogeneous quantum register (IQUREG), hereinafter referred to as electron-entanglement operation, characterized in that.
that it comprises a method for resetting the electron-electron quantum register (CEQUREG) or the inhomogeneous quantum register (IQUREG), and
that it comprises a method for executing a Hadamard gate: and
that it comprises a method for executing a CNOT gate.
that it comprises another method for entangling the quantum information of the first quantum dot (NV1), in particular the first spin of the first electron configuration of the first quantum dot (NV1), the first quantum bit (QUB1) of the quantum register (QUREG) according to one or more of the features 222 to 240 or of the inhomogeneous quantum register (IQUREG) according to one or more of the features 241 to 252 with the quantum information of a second quantum dot (NV2), in particular of the second spin of the second electron configuration of this second quantum dot (NV2), of a second quantum bit (QUB2) of this electron-electron quantum register (QUREG) or of this inhomogeneous quantum register (IQUREG).

Feature 385. Method for entangling the quantum information of a first quantum dot (NV1), in particular of the first spin of the first electron configuration, of a first quantum bit (QUB1) of a quantum register (QUREG) according to one or more of the features 222 to 240 or of an inhomogeneous quantum register (IQUREG) according to one or more of the features 241 to 252 with the quantum information of a second quantum dot (NV2), in particular of the second spin of the second electron configuration of the second quantum dot (QUB2), of a second quantum bit (QUB2) of this quantum register (QUREG) or of said inhomogeneous quantum register (IQUREG), hereinafter referred to as electron-entanglement operation, characterized in that,
that it comprises a method for resetting the electron-electron quantum register (CEQUREG) or the inhomogeneous quantum register (IQUREG) according to feature 323 and/or feature 324 and
that it comprises a method of performing a Hadamard gate according to one or more of features 328 to 333 and
that it comprises a method for executing a CNOT gate according to feature 420
that it comprises another method for entangling the quantum information of the first quantum dot (NV1), in particular the first spin of the first electron configuration of the first quantum dot (NV11, the first quantum bit (QUB1) of the quantum register (QUREG) according to one or more of the features 222 to 240 or of the inhomogeneous quantum register (IQUREG) according to one or more of the features 241 to 252 with the quantum information of a second quantum dot (NV2), in particular of the second spin of the second electron configuration of this second quantum dot (NV2), of a second quantum bit (QUB2) of this electron-electron quantum register (QUREG) or of this inhomogeneous quantum register (IQUREG).

### Electron-Nucleus Exchange Operation 386-410

### Nucleus-Elektron-CNOT (Nucleus-Electron-CNOT-Operation) 386-390

Feature 386. NUCLEUS-ELECTRON-CNOT operation for changing the quantum information of a quantum dot (NV), in particular its electron or electron configuration thereof, of a quantum bit (QUB) of a nucleus-electron quantum register (CEQUREG) according to one or more of the features 203 to 215 function of the quantum information of a nuclear quantum dot (CI), in particular of the nuclear spin of its atomic nucleus, of a nuclear quantum bit (CQUB) of this nucleus-electron quantum register (CEQUREG), hereinafter referred to as nucleus-electron CNOT operation, comprising the step of
injecting a horizontal current component of the horizontal current (IH) in to the horizontal line (LH) of the quantum bit (QUB),
wherein the horizontal current component has a horizontal modulation with the nucleus-electron microwave resonance frequency (f_{MWCE}), and
injecting a vertical current component of the vertical current (IV) in to the vertical line (LV) of the quantum bit (QUB).
where the vertical current component exhibits vertical modulation with the nucleus-electron microwave resonance frequency (f_{MWCE}).

Feature 387. Method according to feature 386,
wherein the vertical modulation is shifted relative to the horizontal modulation by +/−π/2 of the period of the nucleus-electron microwave resonance frequency (f_{MWCE}).

Feature 388. Method according to feature 386 and 387,
wherein the first vertical current component is pulsed with a first vertical current pulse having a first pulse duration; and
wherein the first horizontal current component is pulsed with a first horizontal current pulse having the first pulse duration.

Feature 389. Method according to one or more of the features 386 to 388,
wherein the first vertical current pulse is out of phase with respect to the horizontal current pulse by +/−π/2 of the period of the microwave resonance frequency (f_{MWCE}).

Feature 390. Method according to one or more of the features 386 to 389,
wherein the first temporal pulse duration has a first pulse duration corresponding to a phase difference of π/4 or π/2 (Hadamard gate) or 3π/4 or π (not-gate) of the Rabi oscillation of the quantum pair of the quantum dot (NV1) nucleus-electron quantum register (CEQUREG) and the nuclear quantum dot (CQUB) of the nucleus-electron quantum register (CEQUREG) and/or
wherein the first temporal pulse duration has a first pulse duration corresponding to a phase difference of an integer multiple of π/4 of the period of the Rabi oscillation of the quantum pair of the quantum dot (NV1) nucleus-electron quantum register (CEQUREG) and the nuclear quantum dot (CQUB) of the nucleus-electron quantum register (CEQUREG).

### Elektron-CNOT (Electron-Nucleus Cnot Operation) 391-395

Feature 391. ELECTRON-NUCLEUS CNOT operation for changing the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 215 function of the quantum information of a quantum dot (NV), in particular its electron or electron configuration thereof, of a quantum bit (QUB) of this nucleus-electron quantum register (CEQUREG), hereinafter referred to as electron-nucleus CNOT operation, with the step:
injecting a horizontal current component of the horizontal current (IH) in to the horizontal line (LH) of the quantum bit (QUB),
wherein the horizontal current component has horizontal modulation at the electron-nucleus radio wave resonance frequency (f_{RWEC}), and
injecting a current component of the vertical current (IV) in to the vertical line (LV) of the quantum bit (QUB),
wherein the vertical current component exhibits vertical modulation with the electron-nucleus radio wave resonance frequency (f_{RWEC}).

Feature 392. Method according to feature 391,
wherein the vertical modulation is shifted by +/−π/2 with respect to the horizontal modulation with respect to the period of the electron-nucleus radio wave resonance frequency (f_{RWEC}).

Feature 393. Method according to feature 391 to 392,
wherein the vertical current component is pulsed with a vertical current pulse having a pulse duration, and
wherein the horizontal current component is pulsed with a horizontal current pulse with the pulse duration.

Feature 394. Method according to one or more of the features 391 to 393,
where the vertical current pulse is out of phase with respect to the horizontal current pulse by +/−π/2 of the period of the electron-nucleus radio wave resonance frequency (f_{RWEC}).

Feature 395. Method according to one or more of the features 391 to 394,
wherein the first temporal pulse duration has a first pulse duration corresponding to a phase difference of π/4 or π/2 (Hadamard) or 3π/4 or π (not-gate) of the Rabi oscillation of the quantum pair of the quantum dot (NV1) nucleus-electron quantum register (CEQUREG) and the nuclear quantum dot (CQUB) of the nucleus-electron quantum register (CEQUREG) and/or
wherein the first temporal pulse duration has a first pulse duration corresponding to a phase difference of an integer multiple of π/4 of the period of the Rabi oscillation of the quantum pair of the quantum dot (NV1) nucleus-electron quantum register (CEQUREG) and the nuclear quantum dot (CQUB) of the nucleus-electron quantum register (CEQUREG).

### Spin Exchange Nucleus-Elektron (Electron-Nucleus Exchange Operation) 396-398

Feature 396. Method for entangling the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 213 with the quantum information of a quantum dot (NV), in particular its electron, of a quantum bit (QUB) of this nucleus-electron quantum register (CEQUREG), hereinafter referred to as electron-nucleus exchange operation, with the steps of
performing an ELECTRON-NUCLEUS CNOT operation;
subsequent performance of a NUCLEUS-ELEKTRON-CNOT operation;
subsequent performance of an ELEKTRON NUCLEUS CNOT operation.

Feature 397. Procedure according to feature 396,
wherein the method of performing an ELECTRON-NUCLEUS CNOT operation is a method according to one or more of features 391 to 395.

Feature 398. Method according to one or more of the features 396 to 397,
wherein the method of performing a NUCLEUS-ELECTRON CNOT operation is a method according to one or more of features 386 to 390.

### Alternative Nucleus-Electron Spin Exchange Procedure 399

Feature 399. Method for entangling the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 215 with the quantum information of a quantum dot (NV), in particular its electron, of a quantum bit (QUB) of this nucleus-electron quantum register (CEQUREG), hereinafter referred to as an electron-nucleus exchange delay operation, having the following steps
change the quantum information of the quantum dot (NV), especially the quantum information of the spin state of the electron configuration of the quantum dot (NV);
subsequent waiting for a magnetic resonance relaxation time TK.

### General Nucleus Entanglement (Nucleus-Electron Entanglement) 400

Feature 400. Method for entangling the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 215 with the quantum information of a quantum dot (NV), in particular that of the spin of the electron configuration of the quantum dot (NV), of a quantum bit (QUB) of this nucleus-electron quantum register (CEQUREG), hereinafter referred to as nucleus-electron ENTANGLEMENT operation, characterized,
In that it comprises a method for resetting a nucleus-electron quantum register (CEQUREG); and
that it comprises a method for executing a Hadamard gate and
that it comprises a method for executing a CNOT gate and
that it is another method for entangling the quantum information of a nuclear quantum dot (CI), in particular the nuclear spin of its nucleus, of a nuclear quantum bit (CQUB) of a nucleus-electron quantum register (CEQUREG) according to one or more of the features 203 to 215 with the quantum information of a quantum dot (NV), in particular that of the spin of the electron configuration of a quantum dot (NV), of a quantum bit (QUB) of this nucleus-electron quantum register (CEQUREG)nucleus).

Feature 401. Method for entangling the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 215 with the quantum information of a quantum dot (NV), in particular that of the spin of the electron configuration of the quantum dot (NV), of a quantum bit (QUB) of this nucleus-electron quantum register (CEQUREG), hereinafter referred to as nucleus-electron-ENTANGLEMENT operation, characterized in that,
that it comprises a method of resetting a nucleus electron quantum register (CEQUREG) according to one or more of the features 325 to 327 and
that it comprises a method of performing a Hadamard gate according to one or more of features 328 to 333 and
that it comprises a method for executing a CNOT gate according to feature 418 or
that it is another method for entangling the quantum information of a nuclear quantum dot (CI), in particular the nuclear spin of its nucleus, of a nuclear quantum bit (CQUB) of a nucleus-electron quantum register (CEQUREG) according to one or more of the features 203 to 215 with the quantum information of a quantum dot (NV)), in particular that of the spin of the electron configuration of the quantum dot (NV), of a quantum bit (QUB) of this nucleus-electron quantum register (CEQUREG).

### General Entanglement (Nucleus-Electron Entanglement) 400

Feature 402. Method for exchanging the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 215 with the quantum information of a quantum dot (NV), in particular of its electron or its electron configuration, of a quantum bit (QUB) of this nucleus-electron quantum register (CEQUREG), hereinafter referred to as nucleus-electron exchange operation, characterized in that,
that it is an electron-nucleus exchange delay operation, or
that it is an electron-nucleus exchange operation or
that it is another method for entangling the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 215 with the quantum information of a quantum dot (NV), in particular its electron, of a quantum bit (QUB) of this nucleus-electron quantum register (CEQUREG).

### Electron-Nuclear Quantum Register Radio Wave Drive Method 403-407

Feature 403. Method for changing the quantum information of a nuclear quantum dot (CI), in particular the nuclear spin of its atomic nucleus, of a nuclear quantum bit (CQUB) of a nucleus-electron quantum register (CEQUREG) according to one or more of the features 203 to 215 function of the quantum information of a quantum dot (NV), in particular its electron or its electron configuration, of a quantum bit (QUB) of this nucleus-electron quantum register (CEQUREG)
with the steps
controlling the horizontal line (LH) of the quantum bit (QUB) with a horizontal current (IH) with a horizontal current component modulated with an electron-nucleus radio wave resonance frequency (f_{RWEC}) with a horizontal modulation;
The vertical conduction (LV) of the quantum bit (QUB) is modulated by a vertical current (IV) with a vertical current component modulated by the electron-nucleus radio wave resonance frequency (f_{RWEC}) with a vertical modulation.

Feature 404. Method according to feature 403,
wherein the horizontal modulation of the horizontal current component is out of phase in time by +/−π/2 of the period of the electron-nucleus radio wave resonance frequency (f_{RWEC}) with respect to the vertical modulation of the vertical current component.

Feature 405. Method according to feature 403 to 404.
wherein the vertical current component is pulsed with a vertical current pulse, and
wherein the horizontal current component is pulsed with a horizontal current pulse

Feature 406. Method according to one or more of features 403 to 405 and feature 405,
wherein the second vertical current pulse is out of phase with respect to the second horizontal current pulse by +/−π/2 of the period of the electron-nucleus radio wave resonance frequency (f_{RWEC}).

Feature 407. Method according to one or more of features 403 to 406 and feature 405
wherein the temporal pulse duration τ_{RCE} of the horizontal current pulse and the vertical current pulse is the pulse duration corresponding to a phase difference of π/4 or π/2 (Hadamard gate) or 3π/4 or π (not-gate) of the period duration of the Rabi oscillation of the system consisting of the quantum dot (NV) of the quantum bit (QUB) of the nucleus-electron quantum register (CEQUREG) and the nuclear quantum dot (CI) of the nuclear quantum bit (CQUB) of the nucleus-electron quantum register (CEQUREG) and/or
wherein the temporal pulse duration τ_{RCE} of the horizontal current pulse and the vertical current pulse has the pulse duration corresponding to a phase difference of an integer multiple of π/4 of the period of the Rabi oscillation of the system consisting of the quantum dot (NV) of the quantum bit (QUB) of the nucleus-electron quantum register (CEQUREG) and the nuclear quantum dot (CI) of the nuclear quantum bit (CQUB) of the nucleus-electron quantum register (CEQUREG).

### Nucleus-Electron-Quantum-Register-Microwave-Control-Method 408-412

Feature 408. Method for changing the quantum information of a quantum dot (NV), in particular of its electron or its electron configuration, of a quantum bit (QUB) of a nucleus-electron quantum register (CEQUREG) according to one or more of the features 203 to 215 function of the quantum information of a nuclear quantum dot (CI), in particular of the nuclear spin of its atomic nucleus, of a nuclear quantum bit (CQUB) of this nucleus-electron quantum register (CEQUREG)
with the steps
energizing the horizontal line (LH) of the quantum bit (QUB) with a horizontal current (IH) with a horizontal current component modulated with a nucleus-electron microwave resonance frequency (f_{MWCE}) with a horizontal modulation;
energizing the vertical conduction (LV) of the quantum bit (QUB) with a vertical current (IV) with a vertical current component modulated by the nucleus-electron microwave resonance frequency (f_{MWCE}) with a vertical modulation.

Feature 409. Method according to feature 408,
where the horizontal modulation of the horizontal current component is phase shifted in time by +/−π/2 of the period of the nucleus-electron microwave resonance frequency (f_{MWCE}) relative to the vertical modulation of the vertical current component.

Feature 410. Method according to feature 408 to 409
wherein the vertical current component is pulsed with a vertical current pulse, and
where the horizontal current component is pulsed with a horizontal current pulse

Feature 411. Method according to one or more of features 408 to 410 and feature 410,
wherein the second vertical current pulse is out of phase with respect to the second horizontal current pulse by +/−π/2 of the period of the nucleus-electron microwave resonance frequency (Goya).

Feature 412. Method according to one or more of the features 408 to 411,
wherein the temporal pulse duration τ_{CE} of the horizontal current pulse and the vertical current pulse is the pulse duration corresponding to a phase difference of π/4 or π/2 (Hadamard gate) or 3π/4 or π (not-gate) of the period duration of the Rabi oscillation of the quantum pair of the quantum dot (NV) of the quantum bit (QUB) of the nucleus-electron quantum register (CEQUREG) and the nuclear quantum dot (CI) of the nuclear quantum bit (CQUB) of the nucleus-electron quantum register (CEQUREG) and/or
wherein the temporal pulse duration τ_{CE} of the horizontal current pulse and the vertical current pulse has the pulse duration corresponding to a phase difference of an integer multiple of π/4 of the period of the Rabi oscillation of the quantum pair of the quantum dot (NV) of the quantum bit (QUB) of the nucleus-electron quantum register (CEQUREG) and the nuclear quantum dot (CI) of the nuclear quantum bit (CQUB) of the nucleus-electron quantum register (CEQUREG).

### Nucleus-Nuclear Quantum Register Radio Wave Drive Method 413-417

Feature 413. Method for changing the quantum information of a first nuclear quantum dot (CI1), in particular the nuclear spin of its atomic nucleus, of a first nuclear quantum bit (CQUB) of a nucleus-nuclear quantum register (CCQUREG) according to one or more of the features 253 to 269 function of the quantum information of a second nuclear quantum dot (CI2), in particular the nuclear spin of the second nuclear quantum dot (Ci2), of a second nuclear quantum bit (CQUB2) of this nucleus-nuclear quantum register (CCQUREG)
with the steps
energizing the first horizontal line (LH1) of the first nuclear quantum bit (CQUB1) with a first horizontal current component (IH1) modulated with a first nucleus radio wave resonance frequency (f_{RWECC}) with a horizontal modulation;
energizing the first vertical line (LV1) of the first nuclear quantum bit (CQUB1) with a first vertical current component (IV1) modulated with the first nucleus radio wave resonance frequency (f_{RWECC}) with a vertical modulation.

Feature 414. Method according to the preceding feature
where the horizontal modulation is out of phase in time by +/−π/2 of the period of the first nucleus-to-nucleus radio wave resonance frequency (f_{RWECC}) relative to the vertical modulation.

Feature 415. Method according to one or more of the preceding features
wherein the horizontal current component is at least temporarily pulsed with a horizontal current pulse component, and
wherein the vertical current component is at least temporarily pulsed with a vertical current pulse component.

Feature 416. Method according to one or more of features 413 to 415 and feature 415,
wherein the second vertical current pulse is out of phase with respect to the second horizontal current pulse by +/−π/2 of the period of the first nucleus-to-nucleus radio wave resonance frequency (f_{RWECC}).

Feature 417. Method according to one or more of the features 413 to 416,
wherein the temporal pulse duration τ_{RCC} of the horizontal and vertical current pulse component has the duration corresponding to a phase difference of π/4 or π/2 (Hadamard gate) or 3π/4 or π (not-gate) of the period Rabi oscillation of the quantum pair of first nuclear quantum dot (CI1) of the first nuclear quantum bit (CQUB1) and of the second nuclear quantum dot (CI2) of the second nuclear quantum bit (CQUB2) and/or
wherein the temporal pulse duration τ_{RCC} of the horizontal and vertical current pulse components has the duration corresponding to a phase difference of an integer multiple of π/4 of the period of the Rabi oscillation of the quantum pair of first nuclear quantum dot (CI1) of the first nuclear quantum bit (CQUB1) and of the second nuclear quantum dot (CI2) of the second nuclear quantum bit (CQUB2).

Composite Methods 418

### Quantum Bit Evaluation 418

Feature 418. Method for evaluating the quantum information, in particular the spin state, of the first quantum dot (NV1) of a first quantum bit (QUB1) to be read out of a nucleus-electron-nucleus-electron quantum register (CECEQUREG) according to one or more of the features 272 to 278 comprising the steps of
irradiating the quantum dot (NV1) of the quantum bit to be read out (QUB1) of the nucleus-electron-nucleus-electron quantum register (CECEQUREG) with green light, in particular with light of 500 nm wavelength to 700 nm wavelength, typically with 532 nm wavelength;
simultaneous application of a voltage between at least one first electrical extraction line, in particular a shielding line (SH1, SV1) used as the first electrical extraction line, and a second electrical extraction line, in particular a further shielding line (SH2, SV2) used as the second electrical extraction line and adjacent to the shielding line (SH1, SV1) used,
wherein the quantum dot (NV1) of the quantum bit (QUB1) of the nucleus-electron-nucleus-electron quantum register (CECEQUREG) to be read out is located in the electric field between these two electric exhaust lines, and
wherein the unreadable quantum dots (NV2) of the remaining quantum bits (QUB2) of the nucleus-electron-nucleus-electron quantum register (CECEQUREG) are not located in the electric field between these two electric exhaust lines; and
Selectively controlling the quantum dot (NV1) to be read out of the quantum bit (QUB1) to be read out of the nucleus-electron-nucleus-electron quantum register (CECEQUREG), in particular according to one or more of features 339 to 366;
generating photoelectrons by means of a two-photon process by the quantum dot (NV1) to be read out of the quantum bit (QUB1) to be read out of the nucleus-electron-nucleus-electron quantum register (CECEQUREG) as a function of the nuclear spin of the nuclear quantum dot (CI1) of the nuclear quantum bit (CQUB1), which forms a nucleus-electron quantum register (CQUREG) with the quantum bit (QUB1) to be read out according to one or more of the features 203 to 215
suction of the electrons, if any, of the quantum dot (NV1) to be read out of the quantum bit (QUB1) to be read out of the quantum register (QUREG) via a contact (KV11, KH11) between the first electrical suction line, in particular the shielding line (SH1, SV1), and the substrate (D) or the epitaxial layer (DEP1) as electron current;
suction of the holes, if any, of the quantum dot (NV1) to be read out of the quantum bit (QUB1) to be read out of the quantum register (QUREG) via a contact (KV12, KH22) between the second electrical suction line, in particular the further shielding line (SH2, SV2), and the substrate (D) or the epitaxial layer (DEP1) as hole current;
generating an evaluation signal with a first logic value if the total current of hole current and electron current has a total current amount of the current value below a first threshold value (SW1), and
generating an evaluation signal with a second logic value if the total current of hole current and electron current has a total current amount of the current value above the first threshold value (SW1)
wherein the second logical value is different from the first logical value.

### Quantum Computer Result Extraction 419

Feature 419. A method for reading out the state of a quantum dot (NV) of a quantum bit (QUB) according to one or more of features 1 to 102 comprising the steps of
evaluation of the charge state of the quantum dot (NV);
generation of an evaluation signal with a first logic level provided that the quantum dot (NV) is negatively charged at the start of the evaluation:
generating an evaluation signal with a second logic level different from the first logic level, provided that the quantum dot (NV) is not negatively charged at the start of the evaluation.

### Electron-Electron-Cnot Operation 420-421

Feature 420. A method of performing a quantum register (QUREG) CNOT manipulation, hereinafter referred to as ELEKTRON-ELEKTRON-CNOT, according to one or more of features 222 to 235,
wherein the substrate (D) of the quantum register (QUREG) is common to the first quantum bit (QUB1) of the quantum register (QUREG) and the second quantum bit (QUB2) of the quantum register (QUREG), and
wherein the quantum dot (NV) of the first quantum bit (QUB1) of the quantum register (QUREG) is the first quantum dot (NV1), and
wherein the quantum dot (NV) of the second quantum bit (QUB2) of the quantum register (QUREG) is the second quantum dot (NV2); and
whereby the horizontal line (LH) of the first quantum bit (QUB1) of the quantum register (QUREG) is referred to as the first horizontal line (LH1) in the following; and
wherein the horizontal line (LH) of the second quantum bit (QUB2) of the quantum register (QUREG) is hereinafter referred to as the second horizontal line (LH2); and
wherein the vertical line (LV) of the first quantum bit (QUB1) of the quantum register (QUREG) is hereinafter referred to as the first vertical line (LV1); and
wherein the vertical line (LV) of the second quantum bit (QUB2) of the quantum register (QUREG) is hereinafter referred to as the second vertical line (LV2); and
wherein the first horizontal line (LH1) can be equal to the second horizontal line (LH2) and
wherein the first vertical line (LV1) can be equal to the second vertical line (LH2) if the first horizontal line (LH1) is not equal to the second horizontal line (LH2),
with the steps
energizing the first horizontal line (LH1) with a first horizontal current component of the first horizontal current (IH1) for a time duration corresponding to a first phase angle of φ1, in particular of π/4 or π/2 (Hadamard gate) or 3π/4 or π (not-gate) or an integer multiple of π/4, of the period of the Rabi oscillation of the first quantum dot (NV1) of the first quantum bit (QUB1),
wherein the first horizontal current component is modulated with a first microwave resonance frequency (f_{MW1}) with a first horizontal modulation;
energizing of the first vertical line (LV1) with a first vertical current component of the first vertical current (IV1) for a time duration corresponding to the first phase angle of φ1, in particular of π/4 or π/2 (Hadamard gate) or 3π/4 or π (not-gate) or an integer multiple of π/4, of the period of the Rabi oscillation of the first quantum dot (NV1) of the first quantum bit (QUB1),
wherein the first vertical current component is modulated with a first microwave resonance frequency (f_{MW1}) with a first vertical modulation,
wherein the energization of the first horizontal line (LH1), except for said phase shift, occurs in parallel with the energization of the first vertical line (LV1), and
energizing the first horizontal line (LH1) with a first horizontal direct current (IHG1) having a first horizontal current value, wherein the first horizontal current value may have a magnitude of 0A:
energizing the first vertical line (LV1) with a first vertical direct current (IVG1) having a first vertical current value, wherein the first vertical current value may have a magnitude of 0A;
energizing of the second horizontal line (LH2) with a second horizontal direct current (IHG2) with the first horizontal current value, where the first horizontal current value can have an amount of 0A;
energizing the second vertical line (IV2) with a second vertical direct current (IVG2), whose second vertical current value differs from the first vertical current value;
wherein the second vertical current value and the first vertical current value are so selected,
that the phase vector of the first quantum dot (NV1) of the first quantum bit (QUB1) performs a phase rotation about the first phase angle φ1, in particular of π/4 or π/2 (Hadamard gate) or 3π/4 or π (not-gate) or an integer multiple of π/4, when the phase vector of the second quantum dot (NV2) of the second quantum bit (QUB2) is in a first position, and
that the phase vector of the first quantum dot (NV1) of the first quantum bit (QUB1) does not perform a phase rotation about the phase angle (pi, in particular of π/4 or π/2 (Hadamard gate) or 3π/4 or π (not-gate) or an integer multiple of π/4, if the phase vector of the second quantum dot (NV2) of the second quantum bit (QUB2) is not in the first position but in a second position, and
that the phase vector of the second quantum dot (NV2) of the second quantum bit (QUB2) does not perform any or only an insignificant phase rotation;
subsequent energization of the second horizontal line (LH2) with a second horizontal current component (IHM2) for a time duration corresponding to a phase angle of φ2, in particular of π/4 or π/2 (Hadamard gate) or 3π/4 or π (not-gate) or an integer multiple of π/4, of the Rabi oscillation of the second quantum dot (NV2) of the second quantum bit,
wherein the second horizontal current component (IHM2) is modulated with a second microwave resonance frequency (f_{MW2}) with a second horizontal modulation;
current of the second vertical line (LV2) with a second vertical current component (IVM2) for a time duration corresponding to a phase angle of φ2, in particular of π/4 or π/2 (Hadamard gate) or 3π/4 or π (not-gate) or an integer multiple of π/4 of the period of the Rabi oscillation of the second quantum dot (NV2) of the second quantum bit,
wherein the second vertical current component (IVM2) is modulated with a second vertical microwave resonance frequency (f_{MW2}) with a second vertical modulation.
whereby the energization of the second horizontal line (LH2), except for the said phase shift, takes place in parallel in time with the energization of the second vertical line (LV2), and
energizing the second horizontal line (LH2) with a second horizontal DC current component (IHG2) having a second horizontal current value, wherein the second horizontal current value may be from 0A;
energizing the second vertical line (LV2) with a second vertical DC current component (IVG2) with a second vertical current value, where the second vertical current value can be from 0A;
energizing the first horizontal line (LH1) with a first horizontal DC current component (IHG1) with a first horizontal current value, where the first horizontal current value can be from 0A;
energizing the first vertical line (LV1) with a first vertical DC current component (IVG1) with a first vertical current value, wherein the first vertical current value differs from the second vertical current value;
wherein the first vertical current value and the second vertical current value are now so selected,
that the phase vector of the second quantum dot (NV2) of the second quantum bit (QUB2) performs a phase rotation by angle tin, in particular of π/4 or π/2 (Hadamard gate) or 3π/4 or π (not-gate) or an integer multiple of π/4, when the phase vector of the first quantum dot (NV1) of the first quantum bit (QUB1) is in a first position, and
that the phase vector of the second quantum dot (NV2) of the second quantum bit (QUB2) does not perform a phase rotation by the angle φ2, in particular of π/4 or π/2 (Hadamard gate) or 3π/4 or π (not-gate) or an integer multiple of π/4, if the phase vector of the first quantum dot (NV1) of the first quantum bit (QUB1) is not in the first position but in a second position, and
that the phase vector of the first quantum dot (NV1) of the first quantum bit (QUB1) then does not perform a phase rotation.

Feature 421. Method according to feature 420,
wherein the first horizontal modulation is phase shifted by +/−π/2 of the period of the first microwave resonance frequency (f_{MW1}) with respect to the first vertical modulation, and/or
wherein the second horizontal modulation is phase shifted by +/−π/2 of the period of the second microwave resonance frequency (f_{MW2}) with respect to the second vertical modulation.

### Quantum Computing 422-424

Feature 422. A method of operating a nucleus-electron-nucleus-electron quantum register (CECEQUREG) comprising the steps of.
resetting the quantum dots (NV) of the quantum bits (QUB1, QUB2) of the nucleus-electron-nucleus-electron quantum register (CECEQUREG);
single or multiple manipulation of the quantum dots (NV) of the quantum bits (QUB1, QUB2) of the nucleus-electron-nucleus-electron quantum register (CECEQUREG);
saving the manipulation result;
resetting the quantum dots (NV) of the quantum bits (QUB1, QUB2) of the nucleus-electron-nucleus-electron quantum register (CECEQUREG);
reading back the stored tamper results;
reading the state of the quantum dots (NV) of the quantum bits (QUB1, QUB2) of the nucleus-electron-nucleus-electron quantum register (CECEQUREG).

Feature 423. Method of operating a quantum register and/or a quantum bit according to feature 422.
wherein the resetting of the quantum dots (NV) of the quantum bits (QUB1, QUB2) of the nucleus-electron-nucleus-electron quantum register (CECEQUREG) is performed by means of one or more methods according to one or more of features 323 to 327 and/or
wherein the single or multiple manipulation of the quantum states of the quantum dots (NV) of the quantum bits (QUB1, QUB2) of the nucleus-electron-nucleus-electron quantum register (CECEQUREG) is performed by means of a method according to one or more of the features 328 to 333 and/or 339 to 383 and/or
wherein storing the manipulation result is performed by means of a method according to one or more of features 386 to 407 and/or
wherein the second resetting of the quantum dots (NV) of the quantum bits (QUB1, QUB2) of the nucleus-electron-nucleus-electron quantum register (CECEQUREG) is performed by means of one or more methods according to one or more of features 323 to 327 and/or
wherein the backreading of the stored manipulation results is performed by means of a method according to one or more of the features 386 to 407 and/or
wherein reading out the state of the quantum dots (NV) of the quantum bits (QUB1, QUB2) of the quantum register (QUREG) and/or the quantum dot (NV) of the quantum bit (QUB) is performed by means of a method according to one or more of features 418 to 419.

Feature 424. A method of operating a quantum register (QUREG) and/or a quantum bit (QUB) comprising the steps of.
resetting the quantum dots (NV) of the quantum bits (QUB1, QUB2) of the nucleus-electron-nucleus-electron quantum register (CECEQUREG) by means of one or more methods according to one or more of features 323 to 327;
A single or multiple manipulation of the quantum states of the quantum dots (NV) of the quantum bits (QUB1, QUB2) of the nucleus-electron-nucleus-electron quantum register (CECEQUREG) by means of a method according to one or more of the features 328 to 333 and/or 339 to 383
storing the manipulation result using a method of one or more of features 386 to 407;
resetting the quantum dots (NV) of the quantum bits (QUB1, QUB2) of the nucleus-electron-nucleus-electron quantum register (CECEQUREG) by means of one or more methods according to one or more of features 323 to 327;
Reading back the stored manipulation resuLTs by means of a method according to one or more of features 386 to 407;
reading out the state of the of the quantum dots (NV) of the quantum bits (QUB1, QUB2) of the quantum register (QUREG) and/or the quantum dot (NV) of the quantum bit (QUB) by means of a method according to one or more of features 418 to 419.

Quantum Hardware 425

### Quantum Bus 425-440

Feature 425. Quantum Bus (QUBUS)
with n quantum bits (QUB1 to QUBn),
with n as a positive integer, with n≥2,
with a first nuclear quantum bit (CQUB1),
with an n-th nuclear quantum bit (CQUBn).
wherein the n quantum bits (QUB1 to QUBn) can be numbered from 1 to n,
wherein a j-th quantum bit (QUBj) is any one of these n quantum bits (QUB1 to QUBn) with 1<j<n, to be considered only if n>2, and
wherein every j-th quantum bit (QUBj) has a predecessor quantum bit (QUB(j−1)) and
wherein every j-th quantum bit (QUBj) has a successor quantum bit (QUB(j+1)) and
wherein the first quantum bit (QUB1) forms with the first nuclear quantum bit (CQUB1) a first nucleus-electron quantum register (CEQUREG1) according to one or more of features 203 to 215 and
wherein the n-th quantum bit (QUBn) forms with the n-th nuclear quantum bit (CQUBn) an n-th nucleus-electron quantum register (CEQUREGn) according to one or more of features 203 to 215 and
wherein the first quantum bit (QUB1) forms a first electron-electron quantum register (QUREG1) with the second quantum bit (QUB2), and
where the n-th quantum bit (QUBn) forms an (n−1)-th electron-electron quantum register (QUREG(n−1)) with the (n−1)-th quantum bit (QUB(n−1)), and
wherein each of the other n−2 quantum bits, denoted hereafter as j-th quantum bit (QUBj) with 1<j<n when n>2,
   forms with its predecessor quantum bit (QU B(j−1)) a (j−1)-th quantum register (QUREG(j−1)) and
   with its successor quantum bit (QUB(j+1)) forms a j-th quantum register (QUREGj)
resulting in a closed chain with two nucleus-electron quantum registers (CEQUREG1, CEQUREGn) and n−1 quantum registers (QUREG1 to QUREG(n−1)) between the first nuclear quantum bit (CQUB1) and the n-th nuclear quantum bit (CQUBn).

Feature 426. Quantum bus (QUBUS), in particular according to feature 225,
with n quantum bits (QUB) to QUBn) each with one quantum dot (NV1 to NVn),
with n as a positive integer, with n≥2,
with a first nuclear quantum bit (CQUB1),
with an n-th nuclear quantum bit (CQUBn),
wherein the n quantum bits (QUB1 to QUBn) can be numbered from 1 to n,
wherein a j-th quantum bit (QUBj) is any one of these n quantum bits (QUB1 to QUBn) with 1<j<n, to be considered only if n>2, and
wherein every j-th quantum bit (QUBj) has a predecessor quantum bit (QUB(j−1)) and
wherein every j-th quantum bit (QUBj) has a successor quantum bit (QUB(j+1)) and
wherein the first quantum bit (QUB1) forms a first nucleus-electron quantum register (CEQUREG1) with the first nuclear quantum bit (CQUB1); and
wherein the n-th quantum bit (QUBn) forms with the n-th nuclear quantum bit (CQUBn) an n-th nucleus-electron quantum register (CEQUREGn); and
wherein the first quantum bit (QUB1) forms a first electron-electron quantum register (QUREG1) with the second quantum bit (QUB2); and
wherein the n-th quantum bit (QUBn) forms an (n−1)-th electron-electron quantum register (QUREG(n−1)) with the (n−1)-th quantum bit (QUB(n−1)), and
wherein each of the other n−2 quantum bits, hereafter referred to as the j-th quantum bit (QUBj) is 1<j<n when n>2,
   forms with its predecessor quantum bit (QUB(j−1)) a (j−1)-th quantum register (QUREG(j−1)) and
   with its successor quantum bit (QUB(j+1)) forms a j-th quantum register (QUREGj)
resulting in a closed chain with two nucleus-electron quantum registers (CEQUREG1, CEQUREGn) and n−1 quantum registers (QUREG1 to QUREG(n−1)) between the first nuclear quantum bit (CQUB1) and the n-th nuclear quantum bit (CQUBn) and
wherein the distance between the first nuclear quantum dot (CI1) and the first quantum dot (NV1) is small enough to allow coupling or entanglement of the state of the first quantum dot (NV1) and the state first nuclear quantum dot (CI1), and
wherein the distance between the n-th nuclear quantum dot (CIn) and the n th quantum dot (NVn) is so small that coupling or entanglement of the state of the n-th quantum dot (NVn) and the state of the n-th nuclear quantum dot (CIn) is possible, and
wherein the distance between a j-th quantum dot (NVj) and the (j+1)-th quantum dot is so small with 1≤j<n that coupling or entanglement of the state of the j-th quantum dot (NVj) and the state of the (j+1)-th quantum dot (NV(j+1)) is possible,
characterized by,
that the distance between the first nuclear quantum dot (CI1) and the n-th nuclear quantum dot (CIn) is such that coupling or entanglement of the state of the first nuclear quantum dot (CI1) and the state of the n-th nuclear quantum dot (CIn) is not possible, and
that the distance between the first quantum dot (NV1) and the n-th quantum dot (NVn) is such that coupling or entanglement of the state of the first quantum dot (NV1) and the state of the n-th quantum dot (NVn) is not possible, and
that the distance between the n-th nuclear quantum dot (CIn) and the first quantum dot (NV1) is such that coupling or entanglement of the state of the first quantum dot (NV1) and the state of the n-th nuclear quantum dot (CIn) is not possible, and
that the distance between the first nuclear quantum dot (CI1) and the n-th quantum dot (NVn) is such that coupling or entanglement of the state of the n-th quantum dot (NVn) and the state first nuclear quantum dot (CI1) is not possible, and
that each quantum bit of the n quantum bits (QUB1 to QUBn) has a device for selectively controlling the quantum dot of that quantum bit, and
that each of the devices for selectively controlling the quantum dot of that quantum bit has a vertical line (LV) and a horizontal line (LV), respectively.

Feature 427. Quantum bus (QUBUS) according to feature 425 or feature 426,
wherein the first nuclear quantum bit (CQUB1) comprises a first nuclear quantum dot (CI1); and
wherein the n-th nuclear quantum bit (CQUBn) comprises an n-th nuclear quantum dot (CIn), and
wherein the magnetic field and/or the state of the first nuclear quantum dot (CI1) of the first nuclear quantum bit (CQUB1) does not essentially directly affect the n-th nuclear quantum dot (CIn) of the n-th nuclear quantum bit (CQUBn) without the aid of an ancilla quantum bit and/or
wherein the magnetic field and/or the state of the n-th nuclear quantum dot (CIn) of the n-th nuclear quantum bit (CQUBn) does not essentially directly affect the first nuclear quantum dot (CI1) of the first nuclear quantum bit (CQUB1) without the aid of an ancilla quantum bit,
wherein “essentially” is to be understood here as meaning that the influence that may nevertheless take place is insignificant for the technical result in the majority of cases.

Feature 428. Quantum bus (QUBUS) according to one or more of the features 425 to 427,
wherein the first nuclear quantum bit (CQUB1) comprises a first nuclear quantum dot (CI1); and
wherein the n-th quantum bit (QUBn) comprises an n-th quantum dot (NVn), and
wherein the magnetic field and/or the state of the first nuclear quantum dot (CI1) of the first nuclear quantum bit (CQUB1) does not essentially directly affect the n-th quantum dot (NVn) of the n-th quantum bit (QUBn) without the aid of an ancilla quantum bit and/or
wherein the magnetic field and/or the state of the n-th quantum dot (NVn) of the n-th quantum bit (QUBn) does not essentially affect the first nuclear quantum dot (CI1) of the first nuclear quantum bit (CQUB1) directly without the aid of an ancilla quantum bit.
wherein “essentially” is to be understood here as meaning that the influence that may nevertheless take place is insignificant for the technical result in the majority of cases.

Future 429. Quantum bus (QUBUS) according to one or more of the features 425 to 428,
wherein the first quantum bit (QUB1) comprises a first quantum dot (NV1); and
wherein the n-th nuclear quantum bit (CQUBn) comprises an n-th nuclear quantum dot (CIn), and
wherein the magnetic field and/or the state of the first quantum dot (NV1) of the first quantum bit (QUB1) does not essentially directly affect the n-th nuclear quantum dot (CIn) of the n-th nuclear quantum bit (CQUBn) without the aid of an ancilla quantum bit and/or
wherein the magnetic field and/or the state of the n-th nuclear quantum dot (CIn) of the n-th nuclear quantum bit (CQUBn) essentially does not directly affect the first quantum dot (NV1) of the first quantum bit (QUB11 without the aid of an ancilla quantum bit,
wherein “essentially” is to be understood here as meaning that the influence that may nevertheless take place is insignificant for the technical result in the majority of cases.

Feature 430. Quantum bus (QUBUS) according to one or more of the features 425 to 429,
wherein the first quantum bit (QUB1) comprises a first quantum dot (NV1); and
wherein the n-th quantum bit (CQUBn) comprises an n-th quantum dot (NVn), and
wherein the magnetic field and/or the state of the first quantum dot (NV1) of the first quantum bit (QUB1) does not essentially directly affect the n-th quantum dot (NVn) of the n-th quantum bit (QUBn) without the aid of an ancilla quantum bit and/or
wherein the magnetic field and/or the state of the n-th quantum dot (NVn) of the n-th quantum bit (QUBn) essentially does not directly affect the first quantum dot (NV1) of the first quantum bit (QUB1) without the aid of an ancilla quantum bit,
wherein “essentially” is to be understood here as meaning that the influence that may nevertheless take place is insignificant for the technical result in the majority of cases.

Feature 431. Quantum bus according to feature 430,
wherein the magnetic field and/or the state of the n-th quantum dot (NVn) of the n-th quantum bit (QUBn) influences the first quantum dot (NV1) of the first quantum bit (QUB1) essentially indirectly by accessing quantum dots of the n quantum dots (NV1 to NVn) of the n quantum bits (QUB1 to QUBn) as ancilla quantum bits and/or
wherein the magnetic field and/or the state of the first quantum dot (NV1) of the first quantum bit (QUBn) influences the n-th quantum dot (NVn) of the n th quantum bit (QUBn) essentially indirectly by accessing quantum dots of the n quantum dots (NV1 to NVn) of then quantum bits (QUB1 to QUBn) as ancilla quantum bits.

Feature 432. Quantum Bus (QUBUS)
with n quantum bits (QUB1 to QUBn),
with n as a positive integer,
with n≥2,
with a first quantum ALU (QUALU1),
with an n-th quantum ALU (QUALUn),
wherein the n quantum bits (QUB1 to QUBn) can be numbered from 1 to n.
wherein the first quantum bit (QUB1) is the quantum bit (QUB1) of the first quantum ALU (QUALU1) and
wherein the n-th quantum bit (QUBn) is the quantum bit (QUBn) of the n-th quantum ALU (QUALUn) and
wherein a j-th quantum bit (QUBj) is any one of these n quantum bits (QUB1 to QUBn) with 1<j<n, to be considered only if n>2, and
wherein every j-th quantum bit (QUBj) has a predecessor quantum bit (QUB(j−1)) and
wherein every j-th quantum bit (QUBj) has a successor quantum bit (QUB(j+1)) and
wherein the first quantum bit (QUB1) forms a first electron-electron quantum register (QUREG1) with the second quantum bit (QUB2), and
wherein the n-th quantum bit (QUBn) forms an (n−1)-th electron-electron quantum register (QUREG(n−1)) with the (n−1)-th quantum bit (QUB(n−1)), and
wherein each of the other n−2 quantum bits, denoted hereafter as j-th quantum bit (QUBj) with 1<j<n when n>2.
   forms with its predecessor quantum bit (QUB(j−1)) a (j−1)-th quantum register (QUREG(j−1)) and
   with its successor quantum bit (QUB(j+1)) forms a j-th quantum register (QUREGj)
resulting in a closed chain of n−1 quantum registers (QUREG1 to QUREG(n−1)) between the first nuclear quantum bit (CQUB1) and the n-th nuclear quantum bit (CQUBn).

Feature 433. Quantum bus (QUBUS) according to feature 432,
wherein the first quantum ALU (QUALU1) comprises a first nuclear quantum dot (CI1), and
wherein n-th quantum ALU (QUALUn) comprises an n-th nuclear quantum dot (CIn), and
wherein the magnetic field and/or the state of the first nuclear quantum dot (CI1) of the first quantum ALU (QUALU1) does not essentially directly affect the n-th nuclear quantum dot (CIn) of the n-th quantum ALU (QUALUn) without the aid of an ancilla quantum bit and/or
wherein the magnetic field and/or the state of the n-th nuclear quantum dot (CIn) of the n-th quantum ALU (QUALUn) does not essentially affect the first nuclear quantum dot (CI1) of the first quantum ALU (QUALU1) directly without the aid of an ancilla quantum bit,
wherein “essentially” is to be understood here in such a way that the influencing that does take place is insignificant for the technical result in the majority of cases.

Feature 434. Quantum bus (QUBUS) according to one or more of the features 432 to 433
wherein the first quantum ALU (QUALU1) comprises a first nuclear quantum dot (CI1), and
wherein the n-th quantum ALU (QUALUn) comprises an n-th quantum dot (NVn), and
wherein the magnetic field and/or the state of the first nuclear quantum dot (CI1) of the first quantum ALU (QUALU1) does not essentially directly affect the n-th quantum dot (NVn) of the n-th quantum ALU (QUALUn) without the aid of an ancilla quantum bit and/or
wherein the magnetic field and/or the state of the n-th quantum dot (NVn) of the n-th quantum ALU (QUALUn) does not essentially affect the first nuclear quantum dot (CI1) of the first quantum ALUs (QUALU1) directly without the aid of an ancilla quantum bit,
wherein “essentially” is to be understood here as meaning that the influence that may nevertheless take place is insignificant for the technical result in the majority of cases.

Feature 435. Quantum bus (QUBUS) according to one or more of the features 425 to 434
wherein the first quantum ALU (QUALU1) comprises a first quantum dot (NV1), and
wherein the n-th quantum ALU (QUALUn) comprises an n-th nuclear quantum dot (CIn), and
wherein the magnetic field and/or the state of the first quantum dot (NV1) of the first quantum ALU (QUALU1) does not essentially directly affect the n-th nuclear quantum dot (CIn) of the n-th quantum ALU (QUALUn) without the aid of an ancilla quantum bit and/or
wherein the magnetic field and/or the state of the n-th nuclear quantum dot (CIn) of the n-th quantum ALU (QUALUn) does not essentially affect the first quantum dot (NV1) of the first quantum ALU (QUALU1) directly without the aid of an ancilla quantum bit,
wherein “essentially” is to be understood here as meaning that the influence that may nevertheless take place is insignificant for the technical result in the majority of cases.

Feature 436. Quantum bus (QUBUS) according to one or more of the features 425 to 435,
wherein the first quantum ALU (QUALU1) comprises a first quantum dot (NV1), and
wherein the n-th quantum ALU (QUALUn) comprises an n-th quantum dot (NVn), and
wherein the magnetic field and/or the state of the first quantum dot (NV1) of the first quantum ALUs (QUALU1) does not essentially directly affect the n th quantum dot (NVn) of the n-th quantum ALU (QUALUn) without the aid of an ancilla quantum bit and/or
wherein the magnetic field and/or the state of the n-th quantum dot (NVn) of the n-th quantum ALU (QUALUn) essentially does not directly affect the first quantum dot (NV1) of the first quantum ALU (QUALU1) without the aid of an ancilla quantum bit,
wherein “essentially” is to be understood here as meaning that the influence that may nevertheless take place is insignificant for the technical result in the majority of cases.

Feature 437. Quantum bus (QUBUS) according to feature 436,
wherein the magnetic field and/or the state of the n-th quantum dot (NVn) of the n-th quantum ALU (QUALUn) influences the first quantum dot (NV1) of the first quantum ALU (QUB1) essentially indirectly by accessing quantum dots of the n quantum dots (NV1 to NVn) of the n quantum bits (QUB1 to QUBn) as ancilla quantum bits and/or
wherein the magnetic field and/or the state of the first quantum dot (NV1) of the first quantum ALU (QUALU1) influences the n-th quantum dot (NVn) of the n-th quantum ALU (QUBn) essentially indirectly by accessing quantum dots of the n quantum dots (NV1 to NVn) of the a quantum bits (QUB1 to QUBn) as ancilla quantum bits.

Feature 438. Quantum bus (QUBUS) according to one or more of features 425 to 437,
wherein the quantum bus has linear sections (FIG. 27) and/or a branch (FIG. 29) and/or a kink (FIG. 28) or a loop (FIG. 30).

Feature 439. Quantum bus (QUBUS) according to one or more of the 425 to 438
wherein the quantum bus is provided with means (HD1 to HDn, HS1 to HSn, and HD1 to VDn, VS1 to VSn, CBA, CBB, μC, LH1, LH2, LH3, LH4 to LHn, LV1 to LVm, SH1, SH2, SH3, SH4 to SH(n+1), SV1 to SV(m+1)), in order to determine the spin of the electron configuration of the n-th quantum dot (NVn) of the n-th Quantum ALU (QUALUn) and/or the nuclear spin of a nuclear quantum dot (CIn) of the n-th quantum ALU (QUALUn) as a function of the electron configuration of the first quantum dot (NV1) of the first quantum ALU (QUALU1) and/or to change the nuclear spin of a nuclear quantum dot (CI1) of the first quantum ALU (QUALUn) by means of quantum bits of the n quantum bits (QUB1 to QUBn).

Feature 440. Quantum bus (QUBUS) according to one or more of the features 425 to 439
wherein the quantum bus is provided with means (HD1 to HDn, HS1 to HSn, and HD1 to VDn, VS1 to VSn, CBA, CBB, MC, LH1, LH2, LH3, LH4 to LHn, LV1 to LVm, SH1, SH2, SH3, SH4 to SH(n+1), SV1 to SV(m+1)),
to detune individual or multiple quantum bits of the quantum bits (QUB1 to QUBn) of the quantum bus (QUBUS) such that a resonance frequency of the resonance frequencies of these quantum bits no longer matches the corresponding stored resonance frequency,
wherein the other quantum bits typically then still have this stored resonance frequency, and
wherein this detuning of the resonance frequency occurs in one or more of the following ways:
   um by means of electrical DC potentials on vertical lines of the m vertical lines (LV1 to LVm) and/or
   um by means of equal triangulation of the vertical currents in vertical lines of the m vertical lines (LV1 to LVm) and/or
   urn by means of electrical DC potentials on horizontal lines of the n horizontal lines (LH1 to LHn) and/or
   um by means of equal triangular parts of the horizontal currents in horizontal lines of the n horizontal lines (LH1 to LHn).
(Note: In FIG. 23, m=1 is selected).

### Quantum Network

Feature 441. Quantum network (QUNET) characterized in that.
that it comprises at least two different interconnected quantum buses (QUBUS), in particular according to one or more of the features 425 to 440.

Feature 442. Quantum network (QUNET) according to feature 441,
wherein the quantum network (QUNET) comprises a first quantum bus (QUBUS1); and
wherein the quantum network (QUNET) comprises a second quantum bus
(QUBUS2), and
wherein the first quantum bus (QUBUS1) comprises a first quantum bit (QUB1) having a first quantum dot (NV1); and
wherein the second quantum bus (QUBUS2) comprises an n-th quantum bit (QUBn) having an n-th quantum dot (NVn); and
wherein the first quantum bus ((QUBUS1)) and/or the second quantum bus (QUBUS2) comprise at least one further j-th quantum bit (QUBj) having a further, j-th quantum dot (NVj), and
wherein the first quantum dot (NV1) can be coupled or entangled with the n th quantum dot (NVn) only with the aid of the at least one, further j-th quantum dot (NVj) of the at least one, further j-th quantum bit (QUBj) as an ancilla quantum bit, and
wherein the first quantum dot (NV1) can be coupled or entangled with the n-th quantum dot (NVn) without such assistance of the at least one, further j-th quantum dot (NVj) of the at least one, further j-th quantum bit (QUBj) as an ancilla quantum bit only with a low probability. i.e., essentially not.
so that in this way the at least one, further j-th quantum dot (NVj) of the at least one, further j-th quantum bit (QUBj) connects the first quantum bus ((QUBUS1)) to the second quantum bus (QUBUS2) by this indirect coupling/entanglement possibility via this at least one ancilla quantum bit.

### Quantum Bus Operation

Feature 443. Method for exchanging, in particular spin-exchanging, the quantum information, in particular the spin information, of the j-th quantum dot (NVj) of a j-th quantum bit (QUBj) with the quantum information, in particular the spin information, of the (j+1)-th quantum dot (NV(j+1)) of the subsequent (j+1)-th quantum bit (QUB(j+1)) of a quantum bus (QUBUS) according to one or more features of the features 425 to 440
performing an ELEKTRON-ELEKTRON-CNOT operation according to feature 420
   with the j-th quantum bit (QUBj) as the first quantum bit (QUB1) of the ELEKTRON-ELEKTRON-CNOT operation according to feature 420 and
   with the (j+1)-th quantum bit (QUB(j+1)) as the second quantum bit (QUB2) of the ELEKTRON-ELEKTRON-CNOT operation according to feature 420.

Feature 444. Method for entangling the first quantum dot (NV1) of the first quantum bit (QUB1) with the first nuclear quantum dot (CI1) of the first nuclear quantum bit (CQUB1) of a quantum bus (QUBUS) according to one or more features of features 425 to 440
performing an electron-nucleus exchange operation, in particular according to one or more of features 386 to 402, in particular a nucleus-electron-ENTANGLEMENT operation according to feature 400 and/or 401:
   with the first quantum bit (QUB1) as the quantum bit (QUB) of the said electron-nucleus exchange operation, and
with the first nuclear quantum bit (CQUB1) as the nuclear quantum bit (CQUB) of said electron-nucleus exchange operation.

11308) Feature 445. Method for entangling the n-th quantum dot (NVn) of the n-th quantum bit (QUBn) with the n-th nuclear quantum dot (CIn) of the n-th nuclear quantum bit (CQUBn) of a quantum bus (QUBUS) according to one or more features of features 425 to 440
performing an electron-nucleus exchange operation, in particular according to one or more of features 386 to 402, in particular a nucleus-electron-ENTANGLEMENT operation according to feature 400 and/or 401:
   with the n-th quantum bit (QUBn) as the quantum bit (QUB) of said electron-nucleus exchange operation, and
   with the n-th nuclear quantum bit (CQUBn) as the nuclear quantum bit (CQUB) of said electron-nucleus exchange operation.

Feature 446. Method for entangling the first nuclear quantum bit (CQUB1) with the n-th nuclear quantum bit (CQUBn) of a quantum bus (QUBUS) according to one or more features of features 425 to 440
if necessary, preceding erasure of the n quantum bits (QUB1 to QUBn) of the quantum bus (QUBUS), in particular by means of one or more methods according to feature 323 and/or feature 324 for initialization of the quantum bus (QUBUS);
subsequent entanglement of the first quantum dot (NV1) of the first quantum bit (QUB1) with the first nuclear quantum dot (CI1) of the first nuclear quantum bit (CQUB1) of the quantum bus (QUBUS), in particular by using a method according to feature 444,
then repeating the following step until all n−1 quantum dots (NV2 to NVn) are entangled with their predecessor quantum dot (NV1 to NV(n−1)),
wherein the following step is the interleaving of the j-th quantum dot (NVj) of a j-th quantum bit (QUBj) with the (j+1)-th quantum dot (NV(j+1)) of the following (j+1)-th quantum bit (QUB(j+1)) of the quantum bus (QUBUS), in particular according to a method according to feature 443 and wherein in the first application of this step j=1 is selected and wherein in the subsequent applications of this step until the previously named loop termination condition of j=n is reached the new index j=j+1 is selected;
subsequent entanglement of the n-th quantum dot (NVn) of the n-th quantum bit (QUBn) with the n-th nuclear quantum dot (CIn) of the n-th nuclear quantum bit (CQUBn) of the quantum bus (QUBUS), in particular by using a method according to feature 445.

Feature 447. Method for entangling the first nuclear quantum bit (CQUB1) with the n-th nuclear quantum bit (CQUBn) of a quantum bus (QUBUS) according to one or more features of features 425 to 440 and according to feature 446
performing a procedure according to feature 446
then repeating the following step until all n−1 quantum dots (NV2 to NVn) are entangled with their predecessor quantum dot (Nv1 to NV(n−1)),
wherein the following step is the spin exchange of the j-th quantum dot (NVj) of a j-th quantum bit (QUBj) with the (j+1)-th quantum dot (NV(j+1)) of the following (j+1)-th quantum bit (QUB(j+1)) of the quantum bus (QUBUS), in particular according to a method according to feature 443 and wherein in the first application of this step j=n is selected and wherein in the subsequent applications of this step until the previously named loop termination condition of j=1 is reached the new index j=j−1 is selected;
subsequent spin exchange of the first quantum dot (NV1) of the first quantum bit (QUB1) with the first nuclear quantum dot (CI1) of the first nuclear quantum bit (CQUB1) of the quantum bus (QUBUS), in particular by using a method according to feature 444.

Feature 448. Method for entangling the first nuclear quantum bit (CQUB1) with the n-th nuclear quantum bit (CQUBn) of a quantum bus (QUBUS) according to one or more features of features 425 to 440 and according to feature 446 and/or and according to feature 447
performing a procedure according to feature 446
if necessary, perform a procedure according to feature 447
final erasure of the n quantum bits (QUB1 to QUBn) of the quantum bus (QUBUS), in particular by means of a method according to feature 323 and/or feature 324, to neutralize the quantum bus (QUBUS).

Feature 449. Method for entangling the first nuclear quantum bit (CQUB1) with the n-th nuclear quantum bit (CQUBn) of a quantum bus (QUBUS) according to one or more features of features 425 to 440
if necessary, preceding erasure of the n quantum bits (QUB1 to QUBn) of the quantum bus (QUBUS), in particular by means of a method according to feature 323 and/or feature 324 for initialization of the quantum bus (QUBUS);
if necessary, preceding erasure of the first nuclear quantum bit (CQUB1), in particular by means of a method according to one or more of features 325 to 327;
if necessary, preceding erasure of the n-th nuclear quantum bit (CQUBn), in particular by means of a method according to one or more of features 325 to 327;
if necessary, preceding repeated erasure of the first quantum bit (QUB1) and of the n-th quantum bit up to QUBn) of the quantum bus (QUBUS), in particular by means of one or more methods according to feature 323 and/or feature 324 for initialization of the quantum bus (QUBUS);
performing a Hadamard gate, in particular according to one or more of features 328 to 333 with the first quantum bit (QUB1) as quantum bit (QUB) of said Hadamard gate, and
performing an ELECTRON-NUCLEUS CNOT operation, in particular according to one or more of features 391 to 395 with the first quantum bit (QUB1) and the first nuclear quantum bit (CQUB1), and
repeating the following step until all n−1 quantum dots (NV2 to NVn) are entangled with their predecessor quantum dot (NV1 to NV(n−1)).
wherein the following step comprises entangling the j-th quantum dot (NVj) of a j-th quantum bit (QUBj) with the (j+1)-th quantum dot (NV(j+1)) of the subsequent (j+1)-th quantum bit (QUB(j+1)) of the quantum bus (QUBUS), in particular by means of an ELECTRON-ELECTRON-CNOT according to one or more of the features 420 to 421, and wherein, in particular in the first application of this step, j=1 is selected and wherein then, in particular in the subsequent applications of this step, the new index j=j+1 is selected until the aforementioned loop termination condition of j=n is reached;
performing an ELECTRON-NUCLEUS CNOT operation, in particular according to one or more of features 391 to 395 with the n-th quantum bit (QUBn) and the n-th nuclear quantum bit (CQUBn).

### Quantum Computer 450-468

Feature 450. Device characterized in that,
that it comprises at least one control device (μC) and
in that it comprises at least one light source (LED), which may in particular be an LED and/or a laser and/or a tunable laser, and
in that it comprises at least one light source driver (LEDDR), and
that it comprises at least one of the following quantum-based sub-devices such as
   a quantum bit (QUB), in particular according to one or more of the features 1 to 102 and/or
   a quantum register (QUREG), in particular according to one or more of the features 222 to 235 and/or
   a nucleus-electron quantum register (CEQUREG), in particular according to one or more of the features 203 to 215 and/or
   a nucleus-electron-nucleus-electron quantum register (CECEQUREG), in particular according to one or more of features 272 to 278 and/or
   comprises an arrangement of quantum dots (NV), in particular according to one of the features 279 to 286 and/or
   a quantum bus (QUBUS), in particular according to one or more features of features 425 to 440,
includes and
in that the light source (LED) is temporarily supplied with electrical energy by the light source driver (LEDDR) as a function of a control signal from the control device (μC), and
that the light source (LED) is suitable and intended to reset, in particular by means of one or more methods according to one or more of the features 323 to 327 least a part of the quantum dots (NV).

Feature 451. Device characterized in that,
in that it comprises at least one circuit and/or semiconductor circuit and/or CMOS circuit, and
that it comprises at least one of the following quantum-based sub-devices such as
   a quantum bit (QUB), in particular according to one or more of the features 1 to 102 and/or
   a quantum register (QUREG), in particular according to one or more of the features 222 to 235 and/or
   a nucleus-electron quantum register (CEQUREG), in particular according to one or more of the features 203 to 215 and/or
   a nucleus-electron-nucleus-electron quantum register (CECEQUREG), in particular according to one or more of features 272 to 278 and/or
   an arrangement of quantum dots (NV), in particular according to any one of features 279 to 286, and/or
   a quantum bus (QUBUS), in particular according to one or more features of features 425 to 440,
includes and
in that the at least one circuit and/or semiconductor circuit and/or CMOS circuit has means which, individually or as a plurality in combination, are set up and suitable for carrying out at least one of the processes, in particular according to features 298 to 424 of the process groups
   Electron-nucleus exchange operation,
   Quantum bit reset method,
   Nucleus-electron quantum register reset method,
   Quantum bit microwave actuation method,
   Nucleus-electron quantum register radio wave controlling method,
   Nuclear quantum bit radio wave drive method,
   Nucleus-nuclear quantum register radio wave controlling method,
   selective quantum bit gating, selective quantum register gating,
   Quantum Bit Assessment,
   Quantum computing result extraction,
   Quantum Computing
and/or,
in particular as a method according to features 443 to 446, a quantum bus operation
to execute.

Feature 452. Device, in particular a quantum computer,
with at least one control device (μC), in particular a circuit and/or semiconductor circuit and/or CMOS circuit, and
having at least one of the following quantum-based sub-devices such as
   a quantum bit (QUB), in particular according to one or more of the features 1 to 102 and/or
   a quantum register (QUREG), in particular according to one or more of the features 222 to 235 and/or
   a nucleus-electron quantum register (CEQUREG), in particular according to one or more of the features 203 to 215 and/or
   a nucleus-electron-nucleus-electron quantum register (CECEQUREG), in particular according to one or more of features 272 to 278 and/or
   a quantum ALU (QUALU) according to one or more of the features 220 to 221 and/or
   an arrangement of quantum dots (NV), in particular according to one of the features 279 to 286, and/or
   a quantum bus (QUBUS), in particular according to one or more features of features 425 to 440,
includes and
the control device (μC) having means which, individually or in groups of several, are set up and suitable for carrying out at least one of the processes, in particular according to features 298 to 424, of the groups of processes
   Electron-nucleus exchange operation.
   Quantum bit reset method.
   Nucleus-electron quantum register reset method,
   Quantum bit microwave controlling method,
   Nucleus-electron quantum register radio wave controlling method.
   Nuclear quantum bit radio wave drive method,
   Nucleus-nuclear quantum register radio wave controlling method
   selective quantum bit controlling method, selective quantum register controlling method,
   Quantum bit evaluation,
   Quantum computer result extraction.
   Quantum Computing
and/or
   in particular as a method according to features 443 to 446, a quantum bus operation
to execute and
wherein the device comprises a magnetic field control (MFC) with at least one magnetic field sensor (MFS) and at least one actuator, in particular a magnetic field control device (MFK), to stabilize the magnetic field in the area of the device by active control and
Whereby in particular the magnetic field control (MFC) is a part of the control device (μC) or is controlled by the control device (μC).

Feature 453. Quantum computer (QUC), in particular according to one or more of features 4.30 to 452,
wherein the quantum computer (QUC) comprises a control device (μC); and
wherein the control device (MC) is suitable and arranged for this purpose,
in that the control device (μC) receives commands and/or codes and/or code sequences via a data bus (DB), and
in that the control device (μC) initiates and/or controls the execution of at least one of the following quantum operations by the quantum computer (QUC) as a function of these received instructions and/or received codes and/or received code sequences: MFMW, MFMWEE, MFMWCE, MFRWCC, FRWCC, RESQB, RESQBR, RESQRCE, MQBP, MCBP, SMQB, KQBQB, KQBCB, CNQBCBA, CNQBCBB, CNQBCBC, VQB, SCNQB.

### IC for Quantum Computers 454

Feature 454. Circuit and/or semiconductor circuit and/or CMOS circuit, in particular for a device according to one or more of features 450 to 451,
that it comprises at least one control device (μC) and
in that it comprises means which are suitable and/or provided for controlling at least one of the following quantum-based sub-devices with a first quantum bit (QUB1) to be driven, namely
   a quantum bit (QUB) according to one or more of the features 1 to 102 and/or
   a quantum register (QUREG) according to one or more of features 222 to 235 and/or
   a nucleus-electron quantum register (CEQUREG) according to one or more of the features 203 to 219 and/or
   A nucleus-electron-nucleus-electron quantum register (CECEQUREG) according to one or more of features 272 to 278 and/or
   a quantum ALU according to one or more of the features 220 to 221 and/or
   an arrangement of quantum dots (NV) according to any one of features 279 to 286 and/or
   a quantum bus (QUBUS) according to one or more features of features 425 to 440,
wherein it comprises a first horizontal driver stage (HD1) for controlling the first quantum bit (QUB1) to be driven, and
wherein it comprises a first horizontal receiver stage (HS1), which may form a unit with the first horizontal driver stage (HD1), for controlling the first quantum bit (QUB1) to be driven, and
wherein it comprises a first vertical driver stage (VD1) for controlling the first quantum bit (QUB1) to be driven, and
wherein it comprises a first vertical receiver stage (VS1), which may form a unit with the first vertical driver stage (VD), for controlling the first quantum bit (QUB1) to be driven.

Feature 455. Circuit and/or semiconductor circuit and/or CMOS circuit according to feature 454
wherein the first horizontal driver stage (HD1) and the first horizontal receiver stage (HS1) drive the first quantum bit (QUB1) to be driven via the first horizontal line (LH1) of the first quantum bit (QUB1), and
wherein the first vertical driver stage (VD1) and the first vertical receiver stage (VS1) drive the first quantum bit (QUB1) to be driven via the first vertical line (LV1) of the first quantum bit (QUB1).

Feature 456. Circuit and/or semiconductor circuit and/or CMOS circuit according to feature 455,
wherein the first horizontal driver stage ((HD1)) injects the first horizontal current (IH1) into the first horizontal line (LH1) of the first quantum bit (QUB1), and
wherein the first vertical driver stage (VD1) injects the first vertical current (IV1) into the first vertical line (LV1) of the first quantum bit (QUB1).

Feature 457. Circuit and/or semiconductor circuit and/or CMOS circuit according to feature 456,
wherein the first horizontal current (IH1) has a first horizontal current component with a first horizontal modulation with a first frequency (f) and
wherein the first vertical current (IV1) has a first vertical current component with a first vertical modulation with the first frequency (f), and
wherein the first vertical modulation of the first vertical current component of the first vertical current (IV1) is at least temporarily out of phase with respect to the first horizontal modulation of the first horizontal current component of the first horizontal current (IH1) by a first temporal phase offset of essentially +/−π/2 of the frequency (f).

Feature 458. Circuit and/or semiconductor circuit and/or CMOS circuit according to feature 457,
wherein the first horizontal current component of the first horizontal current (IH1) is pulsed with a first horizontal current pulse having a first pulse duration (τ_{PI}), and
wherein the first vertical current component of the first vertical current (IV1) is pulsed with a first vertical current pulse having the first pulse duration (τ_{PI}).

Feature 459. Circuit and/or semiconductor circuit and/or CMOS circuit according to feature 458,
whereby the first vertical current pulse is out of phase with respect to the first horizontal current pulse by the first phase offset in time.

Feature 460. Circuit and/or semiconductor circuit and/or CMOS circuit according to feature 459,
whereby the first vertical current pulse is phase shifted in time by the first phase offset of +/−π/2 of the frequency (f) with respect to the first horizontal current pulse.

Feature 461. Circuit and/or semiconductor circuit and/or CMOS circuit according to one or more of the features 457 to 460,
where the first frequency (f) is effective at one of the following frequencies:
   a nucleus-electron microwave resonance frequency (f_{MWCE}) or
   an electron-nucleus radio wave resonance frequency (f_{RWEC}) or
   an electron1-electron1 microwave resonance frequency (f_{MW}) or
   an electron1-electron2 microwave resonance frequency (f_{MWEE}) or
   of a nucleus-nucleus radio wave resonance frequency (f_{RWCC}).

Feature 462. Circuit and/or semiconductor circuit and/or CMOS circuit according to one or more of the features 458 to 461,
wherein the first pulse duration τ_{P} corresponds at least temporarily to an integer multiple of π/4 of the period τ_{RCE} of the Rabi oscillation of the nucleus-electron Rabi oscillation, if the first frequency (f) is effectively equal to a nucleus-electron microwave resonance frequency (f_{MWCE}) and/or
wherein the first pulse duration τ_{P} corresponds at least temporarily to an integer multiple of π/4 of the period τ_{REC} of the Rabi oscillation of the electron-nucleus Rabi oscillation, if the first frequency (f) is effectively equal to an electron-nucleus radio wave resonance frequency (f_{RWEC}) and/or
wherein the first pulse duration τ_{P} corresponds at least temporarily to an integer multiple of π/4 of the period τ_{R} of the Rabi oscillation of the electron1-electron1 Rabi oscillation, if the first frequency (f) is effectively equal to an electron1-electron1 microwave resonance frequency (f_{MW}) and/or
wherein the first pulse duration τ_{P} corresponds at least temporarily to an integer multiple of π/4 of the period τ_{REE} of the Rabi oscillation of the electron1-electron2 Rabi oscillation, if the first frequency (f) is effectively equal to an electron1-electron2 microwave resonance frequency (f_{MWEE}) and/or
wherein the first pulse duration τ_{P} corresponds, at least temporarily, to an integer multiple of π/4 of the period τ_{RCC} of the Rabi oscillation of the nucleus-nucleus Rabi oscillation when the first frequency (f) is effectively equal to a nucleus-nucleus radio wave resonance frequency (f_{RWCC}).

Feature 463. Circuit and/or semiconductor circuit and/or CMOS circuit according to one or more of the features 454 to 462, in particular for a device according to one or more of the features 450 to 451,
wherein it comprises a second horizontal driver stage (HD2) for controlling a two-quantum bit to be driven (QUB2), and
wherein it comprises a second horizontal receiver stage (HS2), which may be integral with the second horizontal driver stage (HD2), for controlling the second quantum bit (QUB2) to be driven.

Feature 464. Circuit and/or semiconductor circuit and/or CMOS circuit according to one or more of the features 454 to 463, in particular for a device according to one or more of the features 450 to 451,
wherein it comprises a second vertical driver stage (VD2) for controlling a two-quantum bit (QUB2) to be driven, and
wherein it comprises a second vertical receiver stage (VS2), which may form a unit with the second vertical driver stage (VD2), for controlling the second quantum bit (QUB2) to be driven.

Feature 465. Circuit and/or semiconductor circuit and/or CMOS circuit according to feature 463, in particular for a device according to one or more of features 450 to 453,
wherein the first vertical driver stage (VD1) is used to drive the second quantum bit (QUB2) to be driven, and
wherein the first vertical receiver stage (VS1) is used to drive the second quantum bit (QUB2) to be driven.

Feature 466. Circuit and/or semiconductor circuit and/or CMOS circuit according to feature 464, in particular for a device according to one or more of features 450 to 453,
wherein the first horizontal driver stage (HD1) is used to drive the second quantum bit (QUB2) to be driven, and
wherein the first horizontal receiver stage (HS1) is used to drive the second quantum bit (QUB2) to be driven.

Feature 467. Circuit and/or semiconductor circuit and/or CMOS circuit according to one or more of the features 454 to 466, in particular for a device according to one or more of the features 450 to 453,
wherein the first horizontal driver stage (HD1) injects a first horizontal DC current component as a further horizontal current component into the first horizontal line (LH1) and/or
wherein the magnitude of the first horizontal DC component can be 0A and
wherein the second horizontal driver stage (HD2) injects a second horizontal DC current component as a further horizontal current component into the second horizontal line (LH2) and/or
wherein the magnitude of the second horizontal DC component can be 0A and
wherein the first vertical driver stage (VD1) injects a first vertical DC current component as a further vertical current component into the first vertical line (LV1) and/or
wherein the magnitude of the first vertical DC component can be 0A and
whereby the second vertical driver stage (HD2) injects a second vertical DC current component as a further vertical current component into the second vertical line (LV2),
wherein the magnitude of the second vertical DC component can be 0A.

Feature 468. Circuit and/or semiconductor circuit and/or CMOS circuit according to feature 467,
wherein the first horizontal DC component and/or the second horizontal DC component and/or the first vertical DC component and/or the second vertical DC component may be so adjusted,
that the first nucleus-electron microwave resonance frequency (f_{MWCE1}) of a first nucleus-electron quantum register (CEQUREG1) of a nucleus-electron-nucleus-electron quantum register (CECEQUREG) differs from the second nucleus-electron microwave resonance frequency (f_{MWCE2}) of a second nucleus-electron quantum register (CEQUREG2) of the nucleus-electron-nucleus-electron quantum register (CECEQUREG), or
that the first electron-nucleus radio wave resonance frequency (f_{RWEC1}) of a first nucleus-electron quantum register (CEQUREG1) of a nucleus-electron-nucleus-electron quantum register (CECEQUREG) differs from the second electron-nucleus radio wave resonance frequency (f_{RWEC2}) of a second nucleus-electron quantum register (CEQUREG2) of the nucleus-electron-nucleus-electron quantum register (CECEQUREG); or
that the first electron1-electron1 microwave resonance frequency (f_{MW1}) of a first quantum bit (QUB1) of a quantum register (QUREG) differs from the second electron1-electron1 microwave resonance frequency (f_{MW2}) of a second quantum bit (QUB2) of the quantum register (QUREG).

Manufacturing Processes 469-473

Feature 469. Method for producing a quantum register (QUREG) and/or a quantum bit (QUB) and/or an array of quantum dots and/or an array of quantum bits
with the steps
providing a substrate (D), in particular a diamond or a silicon crystal or a silicon carbide crystal or a mixed crystal of elements of the IV, Main group;
if necessary, application of an epitaxial layer (DEP1), if necessary, already with a doping corresponding to the material of the substrate (D), in particular, if necessary, in the case of diamond with a sulfur doping and/or an n-doping;
if the substrate (D) or the epitaxial layer (DEP1) are not suitably doped—in the case of diamond not n- or sulfur-doped, implantation of suitable dopants, in particular in the case of diamond of sulfur and/or of dopants for n-doping at least parts of the substrate (D) or at least parts of the epitaxial layer (DEP1) and cleaning and healing of the radiation damage;
Deterministic single ion implantation, in particular in the case of diamond as the material of the substrate (D) or the epitaxial layer (DEP1) of nitrogen in diamond, for the production of paramagnetic centers as quantum dots (NV) in predetermined areas of the substrate (D) or the epitaxial layer (DEP1), in particular for the production of
   of NV centers as quantum dots (NV) in predetermined regions of a diamond serving as substrate (D) and/or as epitaxial layer (DEP1) and/or
   of SiV centers as quantum dots (NV) in predetermined areas of a diamond serving as substrate (D) and/or as epitaxial layer (DEP1) and/or
   of GeV centers as quantum dots (NV) in predetermined regions of a diamond serving as substrate (D) and/or as epitaxial layer (DEP1) and/or
   of SnV centers as quantum dots (NV) in predetermined areas of a diamond serving as substrate (D) and/or as epitaxial layer (DEP1) and/or
   of PbV centers as quantum dots (NV) in predetermined areas of a diamond serving as substrate (D) and/or epitaxial layer (DEP1) and/or of G centers as quantum dots (NV) in predetermined regions of a silicon material serving as substrate (D) and/or as epitaxial layer (DEP1), in particular of a silicon crystal, and/or
   of V_{Si} centers as quantum dots (NV) in predetermined regions of a silicon carbide material, in particular a silicon carbide crystal, serving as substrate (D) and/or as epitaxial layer (DEP1), and/or
   of DV centers as quantum dots (NV) in predetermined areas of a silicon carbide material serving as substrate (D) and/or as epitaxial layer (DEP1), in particular of a silicon carbide crystal, and/or
   of V_{C}V_{SI} centers as quantum dots (NV) in predetermined regions of a silicon carbide material, in particular a silicon carbide crystal, serving as substrate (D) and/or as epitaxial layer (DEP1), and/or
   of CAV_{Si} centers as quantum dots (NV) in predetermined regions of a silicon carbide material serving as substrate (D) and/or as epitaxial layer (DEP1), in particular of a silicon carbide crystal, and/or
   of N_{C}V_{Si} centers as quantum dots (NV) in predetermined regions of a silicon carbide material serving as substrate (D) and/or as epitaxial layer (DEP1), in particular of a silicon carbide crystal and/or
   of paramagnetic centers as quantum dots (NV) in predetermined regions of a mixed crystal serving as substrate (D) and/or as epitaxial layer (DEP1) of one or more elements of the IV. Main Group of the Periodic Table:
Cleaning and temperature treatment;
Measure the function, position and T2 times of the implanted single atoms and repeat the two previous steps if necessary;
making ohmic contacts to the substrate (D) or to the epitaxial layer (DEP1);
making the horizontal lines (LH1, LH2, LH3) and, if necessary, the horizontal shielding lines (SH1, SH2, SH3, SH4);
depositing an insulation (IS) and opening the vias;
if necessary, production of the contact dopants, in particular by ion implantation if necessary:
making the vertical lines (LV1, LV2, LV3) and, if necessary, the vertical shielding lines (SV1, SV2, SV3, SV4);

Feature 470. Method of fabricating a nucleus-electron quantum register (CEQUREG) and/or a quantum bit (QUB) together with a nuclear quantum bit (CQUB) and/or an array of quantum dots (NV) together with an array of nuclear quantum dots (CI) and/or an array of quantum bits (QUB) together with an array of nuclear quantum bits (CQUB)
with the steps
providing a substrate (D), in particular a diamond or a silicon crystal or a silicon carbide crystal or a mixed crystal of elements of the IV, Main group:
if necessary, application of an epitaxial layer (DEP1), if necessary, already with a doping corresponding to the material of the substrate (D), in particular, if necessary, in the case of diamond with a sulfur doping and/or an n-doping;
insofar as the substrate (D) or the epitaxial layer (DEP1) are not suitably doped—in the case of diamond not n- or sulfur-doped—implantation of suitable dopants, in particular in the case of diamond of sulfur and/or of dopants for n-doping, at least of parts of the substrate (D) or at least of parts of the epitaxial layer (DEP1) and cleaning and healing of the radiation damage;
Deterministic single ion implantation of predetermined isotopes, in particular in the case of diamond as the material of the substrate (D) or of the epitaxial layer (DEP1) of ¹⁵N nitrogen in diamond, for the production of paramagnetic centers as quantum dots (NV) and for the simultaneous production of nuclear quantum dots (CI) in predetermined areas of the substrate (D) or of the epitaxial layer (DEP1), in particular in the case of diamond as the material of the substrate (D) or of the epitaxial layer (DEP1) for the production of NV centers as quantum dots (NV) with nitrogen atoms as nuclear quantum dots (CI), in predetermined regions of the substrate (D) or of the epitaxial layer (DEP1);
Cleaning and temperature treatment;
If necessary, measure the function, position and T2 times of the implanted single atoms and repeat the two preceding steps if necessary;
making ohmic contacts to the substrate (D) or to the epitaxial layer (DEP1);
making the horizontal lines (LH1, LH2, LH3) and, if necessary, the horizontal shielding lines (SH1, SH2, SH3, SH4);
deposit at least one insulation (IS) and open the vias;
making the vertical lines (LV1, LV2, LV3) and, if necessary, the vertical shielding lines (SV1, SV2, SV3, SV4):

Feature 471. Method of fabricating a nucleus-electron quantum register (CEQUREG) and/or a quantum bit (QUB) together with a nuclear quantum bit (CQB) and/or an array of quantum dots (NV) together with an array of nuclear quantum dots (CI) and/or an array of quantum bits (QUB) together with an array of nuclear quantum bits (CQUB)
with the steps
providing a substrate (D), in particular a diamond or a silicon crystal or a silicon carbide crystal or a mixed crystal of elements of the IV, Main group;
if necessary, application of an epitaxial layer (DEP1), if necessary, already with a doping corresponding to the material of the substrate (D), in particular, if necessary, in the case of diamond with a sulfur doping and/or n-doping:
if the substrate (D) or the epitaxial layer (DEP1) are not suitably doped—in the case of diamond not n- or sulfur-doped, implantation of suitable dopants, in particular in the case of diamond of sulfur and/or of dopants for n-doping at least parts of the substrate (D) or at least parts of the epitaxial layer (DEP1) and cleaning and healing of the radiation damage;
Deterministic single ion implantation of predetermined isotopes, in particular in the case of diamond as the material of the substrate (D) or of the epitaxial layer (DEP1) of ¹⁴N-nitrogen and/or ¹⁵N-nitrogen in diamond, for the production of paramagnetic centers as quantum dots (NV) in predetermined areas of the substrate (D) or of the epitaxial layer (DEP1), in particular in the case of diamond as the material of the substrate (D) or of the epitaxial layer (DEP1), for producing NV centers as quantum dots (NV) in predetermined regions of the substrate (D) or of the epitaxial layer (DEP1);
Deterministic single ion implantation of predetermined isotopes with magnetic moment of the atomic nucleus, in particular.
   in the case of diamond or silicon carbide of ¹³C-carbon or
   in the case of silicon from ²⁹Si silicon or
   of isotopes with a non-zero nucleus magnetic moment λ,
for producing nuclear quantum dots (CI) in the predetermined areas of the substrate (D) or the epitaxial layer (DEP1), in particular for producing nuclear quantum dots (CI) in the predetermined areas of the substrate (D) or the epitaxial layer (DEP1);
Cleaning and temperature treatment;
If necessary, measure the function, position and T2 times of the implanted single atoms and repeat the three preceding steps if necessary;
making ohmic contacts to the substrate (D) or to the epitaxial layer (DEP1);
making the horizontal lines (LH1, LH2, LH3) and, if necessary, the horizontal shielding lines (SH1, SH2, SH3, SH4);
depositing an insulation (IS) and opening the vias;
making the vertical lines (LV1, LV2, LV3) and, if necessary, the vertical shielding lines (SV1, SV2, SV3, SV4):

Feature 472. A method for producing a quantum ALU comprising the step of
Implanting a carton-containing molecule in to the substrate (D),
wherein the substrate is a diamond and
wherein the molecule comprises at least one or two or three or four or five or six or seven ¹³C isotopes, and
wherein the molecule comprises at least one nitrogen atom.

Feature 473. A method for producing a quantum ALU comprising the step of
Implanting a molecule in to the substrate (D),
wherein the substrate (D) is a crystal essentially comprising elements of the IV, main group of the periodic table, and
wherein the molecule has one or two or three or four or five or six or seven isotopes of the elements of the substrate (D), and
wherein these isotopes have a nucleus magnetic moment μ whose magnitude is different from zero, and
wherein the molecule comprises at least one isotope capable of forming a paramagnetic center in the material of the substrate (D) after implantation.

Transistor

Feature 474. Transistor
with a substrate (D) and
with one source contact (SO) and
with a drain contact (DR) and
with an insulation (IS) and
with a further insulation (IS2), in particular a gate oxide, and
with a first quantum dot (NV1) and
with a first gate electrode, hereinafter referred to as first vertical line (LV1), and
with a first horizontal line (LH1),
wherein the first quantum dot (NV1) is located in a region of the substrate (D) between the drain contact (DR) and the source contact (SO), and
wherein the first horizontal line (LH1) is electrically isolated from the first vertical line (LV1) by the insulation (IS) in the region of the transistor, and
wherein the first horizontal line (LH1) and the first vertical line (LV1) being electrically insulated from the substrate (D) in the region of the transistor by a further insulation (IS2), and
wherein the first horizontal line (LH1) crosses the first vertical line (LV1) in a region of the transistor in the vicinity of the first quantum dot (NV1) between source contact (SO) and drain contact (DR), in particular above the first quantum dot (NV).

Feature 475. Transistor according to feature 474,
wherein the substrate (D) of the transistor in the region of the transistor, apart from nuclear quantum dots, comprises essentially only isotopes without nucleus magnetic moment μ.

Feature 476. Transistor according to one or more of the features 474 to 475,
wherein the transistor comprises at least one nuclear quantum dot (CI); and
wherein the nuclear quantum dot is formed by an isotope with a magnetic moment.

Feature 477. Transistor according to one or more of the features 474 to 476,
with a second quantum dot (NV2) and
with a second horizontal line (LH2).
wherein the second quantum dot (NV2) is different from the first quantum dot (NV1), and
wherein the second quantum dot (NV2) is located in a region of the substrate (D) between the drain contact (DR) and the source contact (SO), and
wherein the second horizontal line (LH2) is electrically isolated from the first vertical line (LV1) in the region of the transistor by the insulation (IS) and
wherein the first horizontal line (LH1) is electrically isolated from the second horizontal line (LV1) in the region of the transistor, and
wherein the second horizontal line (IH2) being electrically insulated from the substrate (D) by a further insulation (IS2) in the region of the transistor, and
wherein the second horizontal line (LH2) crosses the first vertical line (LV1) in a region of the transistor in the proximity of the second quantum dot (NV2) between source contact (SO) and drain contact (DR), in particular above the second quantum dot (NV2).

Feature 478. Transistor according to feature 477,
wherein the distance (sp12) between the first quantum dot (NV1) and the second quantum dot (NV2) is so small that the first quantum dot (NV1) forms a quantum register (QUREG) with the second quantum dot (NV2) and/or can be coupled and/or entangled.

### Quantum Computer System (QUSYS) 479-485

Feature 479. Quantum Computer System (QUSYS)
with a central control unit (CSE) and
with one or more data buses (DB) and
with a quantum computers (QUC1 to QUC16), where n is a positive integer greater than 1, and
characterized by,
that the central control unit (CSE) causes at least two or more quantum computers of the n quantum computers (QUC1 to QUC16), hereinafter the quantum computers concerned, to perform the same quantum operations by means of one or more signals via the one data bus (DB) or via the plurality of data buses (DB), and
that after the relevant quantum computers have performed these quantum operations, the central control unit (CSE) queries the results of these quantum operations of the relevant quantum computers via the one data bus (DB) or via the plurality of data buses (DB).

Feature 480. Quantum computer system (QUSYS) according to feature 479,
wherein the central control unit (CCU) has a memory, and
wherein the central control unit (CSE) stores the results of these quantum operations of the respective quantum computers in this memory.

Feature 481. Quantum computer system (QUSYS) according to one or more of features 479 to 480,
wherein one or more or all of the quantum computers of the quantum computer system (QUSYS) each have a control device (μC) that is a conventional computer system; and
wherein this control device (μC) is connected to the central control unit (CSE) via one or more data buses (DB), which may also be data links.

Feature 482. Quantum computer system (QUSYS) according to one or more of the features 479 to 481,
wherein the data bus (DB) of the quantum computer system (QUSYS) is in whole or in part, a linear data bus, and/or
wherein the data bus (DB) of the quantum computer system (QUSYS) is in whole or in part, a linear data bus forming a ring, and/or
wherein the data bus (DB) of the quantum computer system (QUSYS) has a tree structure in whole or in pan, and/or
wherein the data bus (DB) of the quantum computer system (QUSYS) has a star structure in whole or in part.

Feature 483. Quantum computer system (QUSYS) according to one or more of the features 479 to 482,
wherein the data bus (DB) of the quantum computer system (QUSYS) is bidirectional.

Feature 484. Quantum computer system (QUSYS) according to one or more of the features 479 to 482
wherein the quantum computer system (QUSYS) comprises at least a first sub-quantum computer system; and
wherein the first sub-quantum computer system is a quantum computer system according to one or more of features 479 to 482 and
wherein a quantum computer of the first sub-quantum computer system is connected to the central control unit (CSE) of the quantum computer system (QUSYS) via one or more data buses (DB), hereinafter referred to as the sub-quantum computer master, and
wherein the control device (MC) of the sub-quantum computer master of the first sub-quantum computer system is the central control unit (CSE) of the first sub-quantum computer system.

Feature 485. Quantum computer system (QUSYS) according to feature 484,
wherein the quantum computer system (QUSYS) comprises at least a second sub-quantum computer system; and
wherein the second subquantum computer system is different from the first subquantum computer system, and
wherein the second sub-quantum computer system is a quantum computer system according to any one or more of features 479 to 482 and
wherein a quantum computer of the second sub-quantum computer system is connected to the central control unit (CSE) of the quantum computer system (QUSYS) via one or more data buses (DB), hereinafter referred to as the second sub-quantum computer master; and
wherein the control device (μC) of the second sub-quantum computer master of the second sub-quantum computer system is the central control unit (CSE) of the second sub-quantum computer system.

Feature 486. Method for operating a quantum computer (QUC) with a control device (μC)
Providing a source code;
Providing a data processing facility;
Processing the source code in the data processing system and generating a binary file,
At least partially transferring the contents of the binary file in to an ordered memory of the control device (μC) in an ordered sequence, said contents being referred to hereinafter as a program;
starting the execution of the program by the control device (μC) and
executing the OP codes in the memory of the control device (μC) depending on the ordered sequence in the memory of the control device,
characterized in,
that the OP codes in the binary file include one or more quantum OP codes and, if applicable, OP codes that are not quantum OP codes; and
that a quantum OP code symbolizes an instruction to manipulate at least one quantum dot (NV) or is an instruction to perform one or more of the quantum operations MFMW, MFMWEE, MFMWCE, MFRWCC, FRWCC, RESQB, RESQBR, RESQRCE, MQBP, MCBP, SMQB, KQBQB, KQBCB, CNQBCBA, CNQBCBB, CNQBCBC, VQB, SCNQB, and
that the execution of the OR codes is the execution of a quantum OR code, if the OR code is a quantum OR code.

Feature 487. Computer unit
whereas the computer unit comprises
   a central control unit (ZSE) of a quantum computer system (QSYS) with one or more quantum dots (NV) and/or
   a quantum computer control device (μC) with one or more quantum dots (NV)
and
whereas the computer unit runs a neural network model with neural network nodes, and
wherein the neural network model uses one or more input values and/or one or more input signals, and
wherein the neural network model generates one or more output values and/or one or more output signals
characterized by,
wherein the control of one or more quantum dots (NV), in particular by means of horizontal lines (LH) and/or vertical lines (LV), depends on one or more output values and/or one or more output signals of the neural network model and/or
wherein the value of one or more input values and/or one or more input signals of the neuronal network model depends on the state of one or more of the quantum dots (NV).

1-50. (canceled)

51. A quantum bit, comprising:
a device for controlling at least one NV center;
a substrate;
optionally, an epitaxial layer; and
the at least one NV center; wherein:
the device for driving the at least one NV center is configured to generate an electromagnetic wave field at a location of the at least one NV center;
the epitaxial layer, when present, is deposited on the substrate;
the substrate, or, the epitaxial layer, when present, has a surface;
the NV center is a paramagnetic center in the substrate or in the epitaxial layer, when present;
the device for controlling the at least one NV center is located on the surface;
a distance from the device for controlling the at least one NV center to the at least one NV center is less than a maximum distance, wherein
the maximum distance is 100 nm;
the substrate comprises diamond;
the substrate is n-doped in an NV region of the at least one NV center;
the substrate is doped with nuclear spin-free isotopes in the NV region of the at least one NV center; and
a Fermi level is above an energy level of the at least one NV center in a band gap in the NV region of the at least one NV center.

52. The quantum bit of claim 51, wherein the electromagnetic wave field is a microwave field and/or a radio wave field.

53. The quantum bit of claim 51, wherein the device for controlling the at least one NV center is firmly connected to the surface.

54. The quantum bit of claim 51, wherein the device for controlling the at least one NV center comprises an electrical horizontal line.

55. The quantum bit of claim 54, wherein a virtual line perpendicular to the surface extends through the electrical horizontal line and the at least one NV center.

56. The quantum bit of claim 55, wherein the maximum distance from the horizontal line to the at least one NV center along the virtual line perpendicular to the surface is 20 nm.

57. The quantum bit of claim 51, wherein the NV region is an area that includes at least two NV centers, and in which a direct or indirect interaction occurs between the at least two NV centers, including a first NV center and a second NV center.

58. The quantum bit of claim 57, wherein a distance between the first NV center and the second NV center is less than or equal to 100 nm.

59. The quantum bit of claim 57, wherein a distance between the first NV center and the second NV center is less than or equal to 20 nm.

60. The Quantum bit according to claim 54, wherein the NV region of the at least one NV center is doped with one of following isotopes: ¹⁶O, ¹⁸O, ³²S, ³⁴S, ³⁶S.

61. The quantum bit according to claim 51, wherein the at least one NV center is fabricated by a single ion implantation in predetermined areas of the substrate or, when present, in the epitaxial layer.

62. A nuclear quantum bit, comprising:
a device for controlling at least one nuclear quantum dot;
a substrate;
optionally, an epitaxial layer; and
the at least one nuclear quantum dot; wherein:
the device for controlling the at least one nuclear quantum dot is configured to generate an electromagnetic wave field at respective locations of the at least one nuclear quantum dot;
the epitaxial layer, when present, is deposited on the substrate;
the substrate, or the epitaxial layer when present, has a surface;
the nuclear quantum dots comprise isotopes having a magnetic moment in a form of a nuclear spin; and
the device for controlling the at least one nuclear quantum dot is located on the surface, and further wherein:
the device for driving the plurality of nuclear quantum dots comprises an electrical horizontal line.

63. The nuclear quantum bit of claim 62, wherein the device for controlling the plurality of nuclear quantum dots is firmly connected to the surface.

64. A nuclear electron quantum register, comprising:
the nuclear quantum bit according to claim 62; and
a quantum bit, comprising:
the device for controlling at least one NV center;
the substrate;
optionally, the epitaxial layer; and
the at least one NV center; wherein:
the device for driving the at least one NV center is configured to generate an electromagnetic wave field at a location of the at least one NV center;
the epitaxial layer, when present, is deposited on the substrate;
the substrate, or, the epitaxial layer, when present, has a surface;
the NV center is a paramagnetic center in the substrate or in the epitaxial layer, when present;
the device for controlling the at least one NV center is located on the surface;
the device for controlling the at least one NV center is located near the at least one NV center;
the substrate comprises diamond;
the substrate is n-doped in an NV region of the at least one NV center;
the substrate is doped with nuclear spin-free isotopes in the NV region of the at least one NV center; and
a Fermi level is above an energy level of the at least one NV center in a band gap in the NV region of the at least one NV center.

65. The nuclear electron quantum register according to claim 64, wherein:
the at least one nuclear quantum dot is fabricated using single ion implantation of isotopes with magnetic moment of an atomic nucleus associated with the at least one nuclear quantum dot.

66. The nuclear electron quantum register according to claim 65, wherein the isotopes with the magnetic moment of the atomic nucleus include one or more of ¹³C-carbon, ¹⁴N-nitrogen, ¹⁵N-nitrogen or isotopes with a non-zero nucleus magnetic moment μ.

67. A quantum computer, comprising:
the nuclear quantum register according to claim 64;
a light source;
a light source driver; and
a control device; wherein:
a control signal from the control device determines at which times the light source driver supplies the light source with electrical energy; and
the quantum bit has a bottom surface opposite the surface; and further wherein:
the control device performs in dependency of at least one quantum OP code in its memory a method of resetting a quantum dot of the quantum bit with a step of irradiating at least one quantum dot of the quantum dots with light with a wavelength in a wavelength range of 400 nm to 700 nm wavelength and/or 450 nm to 650 nm and/or 500 nm to 550 nm and/or 515 nm to 540 nm, preferably 532 nm wavelength, or
the OP codes in a binary file in the memory of the control device include one or more quantum OP codes and, if applicable, OP codes that are not quantum OP codes,
the control device executes at least a quantum OP code symbolizing an instruction to manipulate at least one quantum dot, or
the control device executes at least a quantum OP code that is an instruction to perform one or more of quantum operations MFMW, MFMWEE, MFMWCE, MFRWCC, FRWCC, RESQB, RESQBR, RESQRCE, MQBP, MCBP, SMQB, KQBQB, KQBCB, CNQBCBA, CNQBCBB, CNQBCBC, VQB, SCNQB.

68. The quantum computer according to claim 67, wherein:
the quantum bit is mounted such that the bottom surface of the quantum bit can be irradiated with green light such that the green light can reach and affect the quantum dot of the quantum bit.

69. A quantum computer system, comprising:
a central control unit;
one or more data buses; and
n quantum computers according to claim 67, where n is a positive integer; wherein:
one or more or all the quantum computers of the quantum computer system have a respective control device that is a conventional computer system; and
the respective control devices are connected to the central control unit via one or more data buses, which may also be data links.

70. The quantum computer system according to claim 69, wherein:
the central control unit has a memory; and
the central control unit stores results of quantum operations of the respective quantum computers in this memory.
